(19) United States
(12) Patent Application Publication
(10) Pub. No.: US 2022/0021290 A1
(43) Pub. Date: Jan. 20, 2022

(54) MAGNETOHYDRODYNAMIC HYDROGEN ELECTRICAL POWER GENERATOR

(71) Applicant: Brilliant Light Power, Inc., Cranbury, NJ (US)

(72) Inventor: Randell L. MILLS, Cranbury, NJ (US)

(73) Assignee: Brilliant Light Power, Inc., Cranbury, NJ (US)

(21) Appl. No.: 17/359,385

(22) Filed: Jun. 25, 2021

Related U.S. Application Data
(63) Continuation of application No. PCT/IB2020/050360, filed on Jan. 16, 2020.
(60) Provisional application No. 62/794,515, filed on Jan. 18, 2019.
(60) Provisional application No. 62/803,283, filed on Feb. 8, 2019.
(60) Provisional application No. 62/823,541, filed on Mar. 25, 2019.
(60) Provisional application No. 62/828,341, filed on Apr. 2, 2019.
(60) Provisional application No. 62/839,617, filed on Apr. 27, 2019.
(60) Provisional application No. 62/844,643, filed on May 7, 2019.
(60) Provisional application No. 62/851,010, filed on May 21, 2019.
(60) Provisional application No. 62/868,838, filed on Jun. 28, 2019.
(60) Provisional application No. 62/871,664, filed on Jul. 8, 2019.
(60) Provisional application No. 62/879,389, filed on Jul. 26, 2019.
(60) Provisional application No. 62/883,047, filed on Aug. 5, 2019.
(60) Provisional application No. 62/890,007, filed on Aug. 21, 2019.
(60) Provisional application No. 62/897,161, filed on Sep. 6, 2019.
(60) Provisional application No. 62/903,528, filed on Sep. 20, 2019.
(60) Provisional application No. 62/929,265, filed on Nov. 1, 2019.
(60) Provisional application No. 62/935,559, filed on Nov. 14, 2019.
(60) Provisional application No. 62/948,173, filed on Dec. 13, 2019.
(60) Provisional application No. 62/954,355, filed on Dec. 27, 2019.

(51) Int. Cl. H02K 44/08; H02K 44/10; H02S 10/30; G21B 3/00

(52) U.S. Cl. CPC H02K 44/085; H02K 44/10; C01B 3/00; G21B 3/004; H02S 10/30

(57) ABSTRACT

A power generator is described that provides at least one of electrical and thermal power comprising (i) at least one reaction cell for reactions involving atomic hydrogen hydrogen products identifiable by unique analytical and spectroscopic signatures, (ii) a molten metal injection system comprising at least one pump such as an electromagnetic pump that provides a molten metal stream to the reaction cell and at least one reservoir that receives the molten metal stream, and (iii) an ignition system comprising an electrical power source that provides low-voltage, high-current electrical energy to the at least one steam of molten metal to ignite a plasma to initiate rapid kinetics of the reaction and an energy gain. In some embodiments, the power generator may comprise: (v) a source of H₂ and O₂ supplied to the plasma, (vi) a molten metal recovery system, and (vii) a power converter capable of (a) converting the high-power light output from a blackbody radiator of the cell into electricity using concentrator thermophotovoltaic cells or (b) converting the energetic plasma into electricity using a magnetohydrodynamic converter.

### CROSS REFERENCE TO RELATED APPLICATIONS

The present application is a continuation of and claims priority to Int'l App No PCT/IB2020/050360, filed Jan. 16, 2020, which claims priority to U.S. App. No. 62/794,515, filed Jan. 18, 2019, U.S. App. No. 62/803,283, filed Feb. 8, 2019, U.S. App. No. 62/823,541, filed Mar. 25, 2019, U.S. App. No. 62/828,341, filed Apr. 2, 2019, U.S. App. No. 62/839,617, filed Apr. 27, 2019, U.S. App. No. 62/844,643, filed May 7, 2019, U.S. App. No. 62/851,010, filed May 21, 2019, U.S. App. No. 62/868,838, filed Jun. 28, 2019, U.S. App. No. 62/871,664, filed Jul. 8, 2019, U.S. App. No. 62/879,389, filed Jul. 26, 2019, U.S. App. No. 62/883,047, filed Aug. 5, 2019, U.S. App. No. 62/890,007, filed Aug. 21, 2019, U.S. App. No. 62/897,161, filed Sep. 6, 2019, U.S. App. No. 62/903,528, filed Sep. 20, 2019, U.S. App. No. 62/929,265, filed Nov. 1, 2019, U.S. App. No. 62/935,559, filed Nov. 14, 2019, U.S. App. No. 62/948,173, filed Dec. 13, 2019, and U.S. App. No. 62/954,355, filed Dec. 27, 2019, each of which is hereby incorporated by reference in its entirety.

### FIELD OF DISCLOSURE

The present disclosure relates to the field of power generation and, in particular, to systems, devices, and methods for the generation of power. More specifically, embodiments of the present disclosure are directed to power generation devices and systems, as well as related methods, which produce optical power, plasma, and thermal power and produces electrical power via a magnetohydrodynamic power converter, an optical to electric power converter, plasma to electric power converter, photon to electric power converter, or a thermal to electric power converter. In addition, embodiments of the present disclosure describe systems, devices, and methods that use the ignition of a water or water-based fuel source to generate optical power, mechanical power, electrical power, and/or thermal power using photovoltaic power converters. These and other related embodiments are described in detail in the present disclosure.

### BACKGROUND

Power generation can take many forms, harnessing the power from plasma. Successful commercialization of plasma may depend on power generation systems capable of efficiently forming plasma and then capturing the power of the plasma produced.

Plasma may be formed during ignition of certain fuels. These fuels can include water or water-based fuel source. During ignition, a plasma cloud of electron-stripped atoms is formed, and high optical power may be released. The high optical power of the plasma can be harnessed by an electric converter of the present disclosure. The ions and excited state atoms can recombine and undergo electronic relaxation to emit optical power. The optical power can be converted to electricity with photovoltaics.

### SUMMARY

The present disclosure is directed to power systems that generates at least one of electrical energy and thermal energy comprising:
at least one vessel capable of maintaining a pressure below atmospheric;
reactants capable of undergoing a reaction that produces enough energy to form a plasma in the vessel comprising:
   a) a mixture of hydrogen gas and oxygen gas, and/or water vapor, and/or
      a mixture of hydrogen gas and water vapor;
   b) a molten metal;
a mass flow controller to control the flow rate of at least one reactant into the vessel; a vacuum pump to maintain the pressure in the vessel below atmospheric pressure when one or more reactants are flowing into the vessel;
a molten metal injector system comprising at least one reservoir that contains some of the molten metal, a molten metal pump system (e.g., one or more electromagnetic pumps) configured to deliver the molten metal in the reservoir and through an injector tube to provide a molten metal stream, and at least one non-injector molten metal reservoir for receiving the molten metal stream;
at least one ignition system comprising a source of electrical power or ignition current to supply electrical power to the at least one stream of molten metal to ignite the reaction when the hydrogen gas and/or oxygen gas and/or water vapor are flowing into the vessel;
a reactant supply system to replenish reactants that are consumed in the reaction;
   a power converter or output system to convert a portion of the energy produced from the reaction (e.g., light and/or thermal output from the plasma) to electrical power and/or thermal power.

The power system may comprise a blackbody radiator and a window to output light from the blackbody radiator. Such embodiments may be used to generate light (e.g., used for lighting).

In some embodiments, the power system may further comprise a gas mixer for mixing the hydrogen and oxygen gases and a hydrogen and oxygen recombiner and/or a hydrogen dissociator. For example, the power system may comprise a hydrogen and oxygen recombiner wherein the hydrogen and oxygen recombiner comprises a recombiner catalytic metal supported by an inert support material.

The power system may be operated with parameters that maximize reactions, and specifically, reactions capable of outputting enough energy to sustain plasma generation and net energy output. For example, in some embodiments, the pressure of the vessel during operation is in the range of 0.1 Torr to 50 Torr. In certain implementations, the hydrogen mass flow rate exceeds that of the oxygen mass flow rate by a factor in the range of 1.5 to 1000. In some embodiments, the pressure may be over 50 Torr and may further comprise a gas recirculation system.

In some embodiments, an inert gas (e.g., argon) is injected into the vessel. The inert gas may be used to prolong the lifetime of certain in situ formed reactants (such as nascent water).

The power system may comprise a water micro-injector configured to inject water into the vessel such that the plasma produced from the energy output from the reaction comprises water vapor. In some embodiments, the micro-injector injects water into the vessel. In some embodiments, the H₂ molar percentage is in the range of 1.5 to 1000 times the molar percent of the water vapor (e.g., the water vapor injected by the micro-injector).

The power system may further comprise a heater to melt a metal (e.g., gallium or silver or copper or combinations thereof) to form the molten metal. The power system may further comprise a molten metal recovery system configured to recover molten metal after the reaction comprising a molten metal overflow channel which collects overflow from the non-injector molten metal reservoir.

The molten metal injection system may further comprise electrodes in the molten metal reservoir and the non-injection molten metal reservoir; and the ignition system comprises a source of electrical power or ignition current to supply opposite voltages to the injector and non-injector reservoir electrodes; wherein the source of electrical power supplies current and power flow through the stream of molten metal to cause the reaction of the reactants to form a plasma inside of the vessel.

The source of electrical power typically delivers a high-current electrical energy sufficient to cause the reactants to react to form plasma. In certain embodiments, the source of electrical power comprises at least one supercapacitor. In various implementations, the current from the molten metal ignition system power is in the range of 10 A to 50,000 A.

Typically, the molten metal pump system is configured to pump molten metal from a molten metal reservoir to a non-injection reservoir, wherein a stream of molten metal is created therebetween. In some embodiments, the molten metal pump system is one or more electromagnetic pumps and each electromagnetic pump comprises one of a
a) DC or AC conduction type comprising a DC or AC current source supplied to the molten metal through electrodes and a source of constant or in-phase alternating vector-crossed magnetic field, or
b) induction type comprising a source of alternating magnetic field through a shorted loop of molten metal that induces an alternating current in the metal and a source of in-phase alternating vector-crossed magnetic field.
   In some embodiments, the circuit of the molten metal ignition system is closed by the molten metal stream to cause ignition to further cause ignition (e.g., with an ignition frequency less than 10,000 Hz). The injector reservoir may comprise an electrode in contact with the molten metal therein, and the non-injector reservoir comprises an electrode that makes contact with the molten metal provided by the injector system.

In various implementations, the non-injector reservoir is aligned above (e.g., vertically with) the injector and the injector is configured to produce the molten stream orientated towards the non-injector reservoir such that molten metal from the molten metal stream may collect in the reservoir and the molten metal stream makes electrical contact with the non-injector reservoir electrode; and wherein the molten metal pools on the non-injector reservoir electrode. In certain embodiments, the ignition current to the non-injector reservoir may comprise:
a) a hermitically sealed, high-temperature capable feed though that penetrates the vessel;
b) an electrode bus bar, and
c) an electrode.

The ignition current density may be related to the vessel geometry for at least the reason that the vessel geometry is related to the ultimate plasma shape. In various implementations, the vessel may comprise an hourglass geometry (e.g., a geometry wherein a middle portion of the internal surface area of the vessel has a smaller cross section than the cross section within 20% or 10% or 5% of each distal end along the major axis) and oriented in a vertical orientation (e.g., the major axis approximately parallel with the force of gravity) in cross section wherein the injector reservoir is below the waist and configured such that the level of molten metal in the reservoir is about proximal to the waist of the hourglass to increase the ignition current density. In some embodiments, the vessel is symmetric about the major longitudinal axis. In some embodiments, the vessel may be an hourglass geometry and comprise a refractory metal liner. In some embodiments, the injector reservoir of the vessel having an hourglass geometry may comprise the positive electrode for the ignition current.

The molten metal may comprise at least one of silver, gallium, silver-copper alloy, copper, or combinations thereof. In some embodiments, the molten metal has a melting point below 700° C. For example, the molten metal may comprise at least one of bismuth, lead, tin, indium, cadmium, gallium, antimony, or alloys such as Rose's metal, Cerrosafe, Wood's metal, Field's metal, Cerrolow 136, Cerrolow 117, Bi—Pb—Sn—Cd—In—Tl, and Galinstan. In certain aspects, at least one of component of the power generation system that contacts that molten metal (e.g., reservoirs, electrodes) comprises, is clad with, or is coated with one or more alloy resistant material that resists formation of an alloy with the molten metal. Exemplary alloy resistant material are tungsten, tantalum, SS 347, and a ceramic. In some embodiments, at least a portion of the vessel is composed of a ceramic and/or a metal. The ceramic may comprise at least one of a metal oxide, quartz, alumina, zirconia, magnesia, hafnia, silicon carbide, zirconium carbide, zirconium diboride, silicon nitride, and a glass ceramic. In some embodiments, the metal of the vessel comprises at least one of a stainless steel and a refractory metal.

The molten metal may react with water to form atomic hydrogen in situ. In various implementations, the molten metal is gallium and the power system further comprises a gallium regeneration system to regenerate gallium from gallium oxide (e.g., gallium oxide produced in the reaction). The gallium regeneration system may comprise a source of at least one of hydrogen gas and atomic hydrogen to reduce gallium oxide to gallium metal. In some embodiments, hydrogen gas is delivered to the gallium regeneration system from sources external to the power generation system. In some embodiments, hydrogen gas and/or atomic hydrogen are generated in situ. The gallium regeneration system may comprise an ignition system that delivers electrical power to gallium (or gallium/gallium oxide combinations) produced in the reaction. In several implementations, such electrical power may electrolyze gallium oxide on the surface of gallium to gallium metal. In some embodiments, the gallium regeneration system may comprise an electrolyte (e.g., an electrolyte comprising an alkali or alkaline earth halide). In some embodiments, the gallium regeneration system may comprise a basic pH aqueous electrolysis system, a means to transport gallium oxide into the system, and a means to return the gallium to the vessel (e.g., to the molten metal reservoir). In some embodiments, the gallium regeneration system comprises a skimmer and a bucket elevator to remove gallium oxide from the surface of gallium. In various implementations, the power system may comprise an exhaust line to the vacuum pump to maintain an exhaust gas stream and further comprising an electrostatic precipitation system in the exhaust line to collect gallium oxide particles in the exhaust gas stream.

In some embodiment, the power system may further comprise at least one heat exchanger (e.g., a heat exchanger coupled to a wall of the vessel, a heat exchanger which may transfer heat to or from the molten metal or to or from the molten metal reservoir).

In some embodiments, the power system comprises at least one power converter or output system of the reaction power output comprises at least one of the group of a thermophotovoltaic converter, a photovoltaic converter, a photoelectronic converter, a magnetohydrodynamic converter, a plasmadynamic converter, a thermionic converter, a thermoelectric converter, a Sterling engine, a supercritical CO₂ cycle converter, a Brayton cycle converter, an external-combustor type Brayton cycle engine or converter, a Rankine cycle engine or converter, an organic Rankine cycle converter, an internal-combustion type engine, and a heat engine, a heater, and a boiler. The vessel may comprise a light transparent photovoltaic (PV) window to transmit light from the inside of the vessel to a photovoltaic converter and at least one of a vessel geometry and at least one baffle comprising a spinning window. The spinning window comprises a system to reduce gallium oxide comprising at least one of a hydrogen reduction system and an electrolysis system. In some embodiments the spinning window comprises or is composed of quartz, sapphire, magnesium fluoride, or combinations thereof. In several implementations, the spinning window is coated with a coating that suppresses adherence of at least one of gallium and gallium oxide. The spinning window coating may comprise at least one of diamond like carbon, carbon, boron nitride, and an alkali hydroxide.

The power converter or output system may comprise a magnetohydrodynamic (MHD) converter comprising a nozzle connected to the vessel, a magnetohydrodynamic channel, electrodes, magnets, a metal collection system, a metal recirculation system, a heat exchanger, and optionally a gas recirculation system. In some embodiments, the molten metal may comprise silver. In embodiments with a magnetohydrodynamic converter, the magnetohydrodynamic converter may deliver oxygen gas to form silver nanoparticles (e.g., of size in the molecular regime such as less than about 10 nm or less than about 1 nm) upon interaction with the silver in the molten metal stream, wherein the silver nanoparticles are accelerated through the magnetohydrodynamic nozzle to impart a kinetic energy inventory of the power produced from the reaction. The reactant supply system may supply and control delivery of the oxygen gas to the converter. In various implementations, at least a portion of the kinetic energy inventory of the silver nanoparticles is converted to electrical energy in a magnetohydrodynamic channel. Such version of electrical energy may result in coalescence of the nanoparticles. The nanoparticles may coalesce as molten metal which at least partially absorbs the oxygen in a condensation section of the magnetohydrodynamic converter (also referred to herein as an MHD condensation section) and the molten metal comprising absorbed oxygen is returned to the injector reservoir by a metal recirculation system. In some embodiments, the oxygen may be released from the metal by the plasma in the vessel. In some embodiments, the plasma is maintained in the magnetohydrodynamic channel and metal collection system to enhance the absorption of the oxygen by the molten metal.

The molten metal pump system may comprise a first stage electromagnetic pump and a second stage electromagnetic pump, wherein the first stage comprises a pump for a metal recirculation system, and the second stage comprises the pump of the metal injector system.

The reaction induced by the reaction produces enough energy inorder to initiate the formation of a plasma in the vessel. These reactions may produce a hydrogen product characterized as one or more of
a) a hydrogen product with a Raman peak at one or more range of 1900 to 2000 cm⁻¹ and 5500 to 6100 cm⁻¹;
b) a hydrogen product with a plurality of Raman peaks spaced at an integer multiple of 0.23 to 0.25 eV;
c) a hydrogen product with an infrared peak at 1900 to 2000 cm⁻¹;
d) a hydrogen product with a plurality of infrared peaks spaced at an integer multiple of 0.23 to 0.25 eV;
e) a hydrogen product with a plurality of UV fluorescence emission spectral peaks in the range of 200 to 300 nm having a spacing at an integer multiple of 0.23 to 0.3 eV;
f) a hydrogen product with a plurality of electron-beam emission spectral peaks in the range of 200 to 300 nm having a spacing at an integer multiple of 0.2 to 0.3 eV;
g) a hydrogen product with a plurality of Raman spectral peaks in the range of 5000 to 20,000 cm⁻¹ having a spacing at an integer multiple of 1000±200 cm⁻¹; h) a hydrogen product with a continuum Raman spectrum in the range of 40 to 8000 cm⁻¹;
i) a hydrogen product with a Raman peak in the range of 1500 to 2000 cm⁻¹ due to at least one of paramagnetic and nanoparticle shifts;
j) a hydrogen product with a X-ray photoelectron spectroscopy peak at an energy in the range of 490 to 525 eV;
k) a hydrogen product that causes an upfield MAS NMR matrix shift;
l) a hydrogen product that has an upfield MAS NMR or liquid NMR shift of greater than −5 ppm relative to TMS;
m) a hydrogen product comprising macro-aggregates or polymers Hₙ(n is an integer greater than 3);
n) a hydrogen product comprising macro-aggregates or polymers Hₙ(n is an integer greater than 3) having a time of flight secondary ion mass spectroscopy (ToF-SIMS) peak of 16.12 to 16.13;
o) a hydrogen product comprising at least one of a metal hydride and a metal oxide further comprising hydrogen wherein the metal comprises at least one of Zn, Fe, Mo, Cr, Cu, and W;
p) a hydrogen product comprising at least one of H₁₆ and H₂₄;
q) a hydrogen product comprising an inorganic compound MₓX_{y} and H₂ wherein M is a cation and X is an anion having at least one of electrospray ionization time of flight secondary ion mass spectroscopy (ESI-ToF) and time of flight secondary ion mass spectroscopy (ToF-SIMS) peaks of M(MₓX_{y}H₂)n wherein n is an integer;
r) a hydrogen product comprising at least one of K₂CO₃H₂ and KOHH₂ having at least one of electrospray ionization time of flight secondary ion mass spectroscopy (ESI-ToF) and time of flight secondary ion mass spectroscopy (ToF-SIMS) peaks of K(K₂H₂CO₃) and K(KOHH₂), respectively;
s) a magnetic hydrogen product comprising at least one of a metal hydride and a metal oxide further comprising hydrogen wherein the metal comprises at least one of Zn, Fe, Mo, Cr, Cu, W, and a diamagnetic metal;
t) a hydrogen product comprising at least one of a metal hydride and a metal oxide further comprising hydrogen wherein the metal comprises at least one of Zn, Fe, Mo, Cr, Cu, W, and a diamagnetic metal that demonstrates magnetism by magnetic susceptometry;
u) a hydrogen product comprising a metal that is not active in electron paramagnetic resonance (EPR) spectroscopy wherein the EPR spectrum comprises at least one of a g factor of about 2.0046±20% and proton splitting such as a proton-electron dipole splitting energy of about 1.6×10⁻² eV±20%;
v) a hydrogen product comprising a hydrogen molecular dimer [H₂]₂ wherein the EPR spectrum shows at least an electron-electron dipole splitting energy of about 9.9×10⁻⁵ eV±20% and a proton-electron dipole splitting energy of about 1.6×10⁻² eV±20%;
w) a hydrogen product comprising a gas having a negative gas chromatography peak with hydrogen or helium carrier;
x) a hydrogen product having a quadrupole moment/e of

$$\frac{1.70127 {a}_{0}^{2}}{{p}^{2}} \pm 10 \%$$

P wherein p is an integer;
y) a protonic hydrogen product comprising a molecular dimer having an end over end rotational energy for the integer J to J+1 transition in the range of (J+1)44.30 cm⁻¹±20 cm⁻¹ wherein the corresponding rotational energy of the molecular dimer comprising deuterium is ½ that of the dimer comprising protons;
z) a hydrogen product comprising molecular dimers having at least one parameter from the group of (i) a separation distance of hydrogen molecules of 1.028 Å±10%, (ii) a vibrational energy between hydrogen molecules of 23 cm⁻¹±10%, and (iii) a van der Waals energy between hydrogen molecules of 0.0011 eV±10%;
aa) a hydrogen product comprising a solid having at least one parameter from the group of (i) a separation distance of hydrogen molecules of 1.028 Å±10%, (ii) a vibrational energy between hydrogen molecules of 23 cm⁻¹±10%, and (iii) a van der Waals energy between hydrogen molecules of 0.019 eV±10%;
bb) a hydrogen product having FTIR and Raman spectral signatures of (i) (J+1)44.30 cm⁻¹±20 cm⁻¹, (ii) (J+1)22.15 cm⁻¹±10 cm⁻¹ and (iii) 23 cm⁻¹±10% and/or an X-ray or neutron diffraction pattern showing a hydrogen molecule separation of 1.028 Å±10% and/or a calorimetric determination of the energy of vaporization of 0.0011 eV±10% per molecular hydrogen;
cc) a solid hydrogen product having FTIR and Raman spectral signatures of (i) (J+1)44.30 cm⁻¹±20 cm⁻¹, (ii) (J+1)22.15 cm⁻¹±10 cm⁻¹ and (iii) 23 cm⁻¹+10% and/or an X-ray or neutron diffraction pattern showing a hydrogen molecule separation of 1.028 Å±10% and/or a calorimetric determination of the energy of vaporization of 0.019 eV±10% per molecular hydrogen;
dd) a hydrogen product comprising a hydrogen hydride ion that is magnetic and links flux in units of the magnetic flux quantum in its bound-free binding energy region;
ee) a hydrogen product wherein the high pressure liquid chromatography (HPLC) shows chromatographic peaks having retention times longer than that of the carrier void volume time using an organic column with a solvent comprising water wherein the detection of the peaks by mass spectroscopy such as ESI-ToF shows fragments of at least one inorganic compound.
   In some embodiments, the hydrogen product may be characterized as:
a) a hydrogen product with a continuum Raman spectrum in the range of 40 to 8000 cm⁻¹;
b) a hydrogen product with a Raman peak in the range of 1500 to 2000 cm⁻¹ due to at least one of paramagnetic and nanoparticle shifts;
c) a hydrogen product with a X-ray photoelectron spectroscopy peak at an energy in the range of 490 to 525 eV;
d) a hydrogen product comprising a metal that is not active in electron paramagnetic resonance (EPR) spectroscopy wherein the EPR spectrum comprises at least one of a g factor of about 2.0046±20% and proton splitting such as a proton-electron dipole splitting energy of about 1.6×10⁻² eV±20%;
e) a hydrogen product comprising a hydrogen molecular dimer [H₂]₂ wherein the EPR spectrum shows at least an electron-electron dipole splitting energy of about 9.9×10⁻⁵ eV±20% and a proton-electron dipole splitting energy of about 1.6×10⁻² eV±20%;
f) a hydrogen product comprising a hydrogen hydride ion that is magnetic and links flux in units of the magnetic flux quantum in its bound-free binding energy region.
   In certain implementations, the reaction produces H₂ which may be characterized as one or more of:
a) having a Fourier transform infrared spectrum (FTIR) comprising at least one of the H₂ rotational energy at 1940 cm⁻¹±10% and libation bands in the finger print region wherein other high energy features are absent;
b) having a proton magic-angle spinning nuclear magnetic resonance spectrum (¹H MAS NMR) comprising an upfield matrix peak;
c) having a thermal gravimetric analysis (TGA) result showing the decomposition of at least one of a metal hydride and a hydrogen polymer in the temperature region of 100° C. to 1000° C.;
d) having an e-beam excitation emission spectrum comprising the H₂ ro-vibrational band in the 260 nm region comprising a plurality of peaks spaced at 0.23 eV to 0.3 eV from each other;
e) having an e-beam excitation emission spectrum comprising the H₂ ro-vibrational band in the 260 nm region comprising a series of peaks spaced at 0.23 eV to 0.3 eV from each other wherein the peaks decrease in intensity at cryo-temperatures in the range of 0 K to 150 K;
f) having a photoluminescence Raman spectrum comprising the second order of the H₂ ro-vibrational band in the 260 nm region comprising a plurality of peaks spaced at 0.23 eV to 0.3 eV from each other;
g) having a photoluminescence Raman spectrum comprising the second order of the H₂ ro-vibrational band comprising a plurality of peaks in the range of 5000 to 20,000 cm⁻¹ having a spacing at an integer multiple of 1000±200 cm⁻¹;
h) having a Raman spectrum comprising the H₂ rotational peak at one or more of 1940 cm⁻¹±10% and 5820 cm⁻¹±10%;
i) having a continuum Raman spectrum in the range of 40 to 8000 cm⁻¹;
j) having a Raman peak in the range of 1500 to 2000 cm⁻¹ due to at least one of paramagnetic and nanoparticle shifts;
k) having an X-ray photoelectron spectrum (XPS) comprising the total energy of H₂ at 490-500 eV;
l) the hydrogen product interacts K₂CO₃H(¼)₂ and KOHH₂ (e.g., in embodiments comprising a getter) and at least one of the electrospray ionization time of flight secondary ion mass spectrum (ESI-ToF) and the time of flight secondary ion mass spectrum (ToF-SIMS) comprises peaks of K(K₂H₂CO₃)ₙ⁺ and K(KOHH₂)ₙ⁺, respectively;
m) having a quadrupole moment/e of

$$\frac{1.70127 {a}_{0}^{2}}{{p}^{2}} \pm 10 ;$$

and
n) having an end over end rotational energy for the integer J to J+1 transition in the range of (J+1)44.30 cm⁻¹±20 cm⁻¹ and (J+1)22.15 cm⁻¹±10 cm⁻¹, respectively;
o) having at least one parameter from the group of (i) a separation distance of H₂ molecules of 1.028 Å±10%, (ii) a vibrational energy between H₂ molecules of 23 cm⁻¹±10%, and (iii) a van der Waals energy between H₂ molecules of 0.0011 eV±10%;
p) having FTIR and Raman spectral signatures of (i) (J+1)44.30 cm⁻¹±20 cm⁻¹, (ii) (J+1)22.15 cm⁻¹±10 cm⁻¹ and (iii) 23 cm⁻¹±10% and/or an X-ray or neutron diffraction pattern showing a H₂ molecule separation of 1.028 Å±10% and/or a calorimetric determination of the energy of vaporization of 0.0011 eV±10% per H₂.
   In some embodiments, the hydrogen product may be formed into a solid H₂ and be characterized as:
a) having at least one parameter from the group of (i) a separation distance of H₂ molecules of 1.028 Å±10%, (ii) a vibrational energy between H₂ molecules of 23 cm⁻¹±10%, and (iii) a van der Waals energy between H₂(¼) molecules of 0.019 eV±10%;
b) having FTIR and Raman spectral signatures of (i) (J+1)44.30 cm⁻¹±20 cm⁻¹, (ii) (J+1)22.15 cm⁻¹±10 cm⁻¹ and (iii) 23 cm⁻¹±10% and/or an X-ray or neutron diffraction pattern showing a hydrogen molecule separation of 1.028 Å±10% and/or a calorimetric determination of the energy of vaporization of 0.019 eV±10% per H₂.
   In various implementations, the hydrogen product may be characterized similarly as products formed from various hydrino reactors such as those formed by wire detonation in an atmosphere comprising water vapor. Such products may:
a) comprise macro-aggregates or polymers Hₙ(n is an integer greater than 3);
b) comprise macro-aggregates or polymers Hₙ(n is an integer greater than 3) having a time of flight secondary ion mass spectroscopy (ToF-SIMS) peak of 16.12 to 16.13;
c) comprise at least one of a metal hydride and a metal oxide further comprising hydrogen wherein the metal comprises at least one of Zn, Fe, Mo, Cr, Cu, and W and the hydrogen comprises H;
d) comprise at least one of H₁₆ and H₂₄;
e) comprise an inorganic compound MₓX_{y} and H₂ wherein M is a metal cation and X is an anion and at least one of the electrospray ionization time of flight secondary ion mass spectrum (ESI-ToF) and the time of flight secondary ion mass spectrum (ToF-SIMS) comprises peaks of M(MₓX_{y}H(¼)₂)n wherein n is an integer;
f) be magnetic and comprise at least one of a metal hydride and a metal oxide further comprising hydrogen wherein the metal comprises at least one of Zn, Fe, Mo, Cr, Cu, W, and a diamagnetic metal, and the hydrogen is H(¼);
g) comprise at least one of a metal hydride and a metal oxide further comprising hydrogen wherein the metal comprises at least one of Zn, Fe, Mo, Cr, Cu, W, and a diamagnetic metal and H is H(¼) wherein the product demonstrates magnetism by magnetic susceptometry;
h) comprise a metal that is not active in electron paramagnetic resonance (EPR) spectroscopy wherein the EPR spectrum shows a g factor of about 2.0046±20% and proton splitting such as a proton-electron dipole splitting energy of about 1.6×10⁻² eV±20%;
i) comprise a hydrogen molecular dimer [H₂]₂ wherein the EPR spectrum shows at least an electron-electron dipole splitting energy of about 9.9×10⁻⁵ eV±20% and a proton-electron dipole splitting energy of about 1.6×10⁻² eV±20%;
j) comprise or releases H₂ gas (e.g., the hydrogen product) having a negative gas chromatography peak with hydrogen or helium carrier;

In some embodiments, the hydrogen product formed by the reaction comprises the hydrogen product complexed with at least one of (i) an element other than hydrogen, (ii) an ordinary hydrogen species comprising at least one of H⁺, ordinary H₂, ordinary H⁻, and ordinary H₃⁺, an organic molecular species, and (iv) an inorganic species. In some embodiments, the hydrogen product comprises an oxyanion compound. In various implementations, the hydrogen product (or a recovered hydrogen product from embodiments comprising a getter) may comprise at least one compound having the formula selected from the group of:
a) MH, MH₂, or M₂H₂, wherein M is an alkali cation and H or H₂ is the hydrogen product;
b) MHₙ wherein n is 1 or 2, M is an alkaline earth cation and H is the hydrogen product;
c) MHX wherein M is an alkali cation, X is one of a neutral atom such as halogen atom, a molecule, or a singly negatively charged anion such as halogen anion, and H is the hydrogen product;
d) MHX wherein M is an alkaline earth cation, X is a singly negatively charged anion, and H is hydrogen product;
e) MHX wherein M is an alkaline earth cation, X is a double negatively charged anion, and H is the hydrogen product;
f) M₂HX wherein M is an alkali cation, X is a singly negatively charged anion, and H is the hydrogen product;
g) MHₙ wherein n is an integer, M is an alkaline cation and the hydrogen content Hₙ of the compound comprises at least one of the hydrogen products;
h) M₂Hₙ wherein n is an integer, M is an alkaline earth cation and the hydrogen content Hₙ of the compound comprises at least one of the hydrogen products;
i) M₂XHₙ wherein n is an integer, M is an alkaline earth cation, X is a singly negatively charged anion, and the hydrogen content Hₙ of the compound comprises at least one of the hydrogen products;
j) M₂X₂Hₙ wherein n is 1 or 2, M is an alkaline earth cation, X is a singly negatively charged anion, and the hydrogen content Hₙ of the compound comprises at least one of the hydrogen products;
k) M₂X₃H wherein M is an alkaline earth cation, X is a singly negatively charged anion, and H is the hydrogen product;
l) M₂XHₙ wherein n is 1 or 2, M is an alkaline earth cation, X is a double negatively charged anion, and the hydrogen content Hₙ of the compound comprises at least one of the hydrogen products;
m) M₂XX′H wherein M is an alkaline earth cation, X is a singly negatively charged anion, X′ is a double negatively charged anion, and H is the hydrogen product;
n) MM¹Hₙ wherein n is an integer from 1 to 3, M is an alkaline earth cation, M′ is an alkali metal cation and the hydrogen content Hₙ of the compound comprises at least one of the hydrogen products;
o) MM′XHₙ wherein n is 1 or 2, M is an alkaline earth cation, M′ is an alkali metal cation, X is a singly negatively charged anion and the hydrogen content Hₙ of the compound comprises at least one of the hydrogen products;
p) MM′XH wherein M is an alkaline earth cation, M′ is an alkali metal cation, X is a double negatively charged anion and H is the hydrogen products;
q) MM′XX′H wherein M is an alkaline earth cation, M′ is an alkali metal cation, X and X′ are singly negatively charged anion and H is the hydrogen product;
r) MXX¹Hₙ wherein n is an integer from 1 to 5, M is an alkali or alkaline earth cation, X is a singly or double negatively charged anion, X′ is a metal or metalloid, a transition element, an inner transition element, or a rare earth element, and the hydrogen content Hₙ of the compound comprises at least one of the hydrogen products;
s) MHₙ wherein n is an integer, M is a cation such as a transition element, an inner transition element, or a rare earth element, and the hydrogen content Hₙ of the compound comprises at least one of the hydrogen products;
t) MXHₙ wherein n is an integer, M is an cation such as an alkali cation, alkaline earth cation, X is another cation such as a transition element, inner transition element, or a rare earth element cation, and the hydrogen content Hₙ of the compound comprises at least one of the hydrogen products;
u) (MHₘMCO₃)ₙ wherein M is an alkali cation or other +1 cation, m and n are each an integer, and the hydrogen content Hₘ of the compound comprises at least one of the hydrogen products;
v) (MHₘMNO₃)ₙ⁺nX⁻ wherein M is an alkali cation or other +1 cation, m and n are each an integer, X is a singly negatively charged anion, and the hydrogen content Hₘ of the compound comprises at least one of the hydrogen products;
w) (MHMNO₃) wherein M is an alkali cation or other +1 cation, n is an integer and the hydrogen content H of the compound comprises at least one of the hydrogen products;
x) (MHMOH) wherein M is an alkali cation or other +1 cation, n is an integer, and the hydrogen content H of the compound comprises at least one of the hydrogen products;
y) (MHₘM′X)ₙ wherein m and n are each an integer, M and M′ are each an alkali or alkaline earth cation, X is a singly or double negatively charged anion, and the hydrogen content Hₘ of the compound comprises at least one of the hydrogen products; and
z) (MHₘM′X′)ₙ⁺nX⁻ wherein m and n are each an integer, M and M′ are each an alkali or alkaline earth cation, X and X′ are a singly or double negatively charged anion, and the hydrogen content Hₘ of the compound comprises at least one of the hydrogen products.
   The anion of the hydrogen product formed by the reaction may be one or more singly negatively charged anions including a halide ion, a hydroxide ion, a hydrogen carbonate ion, a nitrate ion, a double negatively charged anion, a carbonate ion, an oxide, and a sulfate ion. In some embodiments, the hydrogen product is embedded in a crystalline lattice (e.g., with the use of a getter such as K₂CO₃ located, for example, in the vessel or in an exhaust line). For example, the hydrogen product may be embedded in a salt lattice. In various implementations, the salt lattice may comprise an alkali salt, an alkali halide, an alkali hydroxide, alkaline earth salt, an alkaline earth halide, an alkaline earth hydroxide, or combinations thereof.

Electrode systems are also provided comprising:
a) a first electrode and a second electrode;
b) a stream of molten metal (e.g., molten silver, molten gallium) in electrical contact with said first and second electrodes;
c) a circulation system comprising a pump to draw said molten metal from a reservoir and convey it through a conduit (e.g., a tube) to produce said stream of molten metal exiting said conduit;
d) a source of electrical power configured to provide an electrical potential difference between said first and second electrodes;
   wherein said stream of molten metal is in simultaneous contact with said first and second electrodes to create an electrical current between said electrodes. In some embodiments, the electrical power is sufficient to create a current in excess of 100 A.

Electrical circuits are also provided which may comprise:
a) a heating means for producing molten metal;
b) a pumping means for conveying said molten metal from a reservoir through a conduit to produce a stream of said molten metal exiting said conduit;
c) a first electrode and a second electrode in electrical communication with a power supply means for creating an electrical potential difference across said first and second electrode;
   wherein said stream of molten metal is in simultaneous contact with said first and second electrodes to create an electrical circuit between said first and second electrodes. For example, in an electrical circuit comprising a first and second electrode, the improvement may comprise passing a stream of molten metal across said electrodes to permit a current to flow there between.

Additionally, systems for producing a plasma (which may be used in the power generation systems described herein) are provided. These systems may comprise:
a) a molten metal injector system configured to produce a stream of molten metal from a metal reservoir;
b) an electrode system for inducing a current to flow through said stream of molten metal;
c) at least one of a (i) water injection system configured to bring a metered volume of water in contact with said molten metal, wherein a portion of said water and a portion of said molten metal react to form an oxide of said metal and hydrogen gas, (ii) a mixture of excess hydrogen gas and oxygen gas, and (iii) a mixture of excess hydrogen gas and water vapor, and
d) a power supply configured to supply said current;
   wherein said plasma is produced when current is supplied through said metal stream. In some embodiments, the system may further comprise:
   a pumping system configured to transfer metal collected after the production of said plasma to said metal reservoir. In some embodiments, the system may comprise:
a metal regeneration system configured to collect said metal oxide and convert said metal oxide to said metal; wherein said metal regeneration system comprises an anode, a cathode, electrolyte; wherein an electrical bias is supplied between said anode and cathode to convert said metal oxide to said metal. In certain implementations, the system may comprise:
a) a pumping system configured to transfer metal collected after the production of said plasma to said metal reservoir; and
b) a metal regeneration system configured to collect said metal oxide and convert said metal oxide to said metal; wherein said metal regeneration system comprises an anode, a cathode, electrolyte; wherein an electrical bias is supplied between said anode and cathode to convert said metal oxide to said metal;
   wherein metal regenerated in said metal regeneration system is transferred to said pumping system. In certain implementations, the metal is gallium, silver, or combinations thereof. In some embodiments, the electrolyte is an alkali hydroxide (e.g., sodium hydroxide, potassium hydroxide).

### BRIEF DESCRIPTION OF THE DRAWINGS

The accompanying drawings, which are incorporated in and constitute a part of this specification, illustrate several embodiments of the disclosure and together with the description, serve to explain the principles of the disclosure. In the drawings:

FIG. 1 is a schematic drawing of magnetohydrodynamic (MHD) converter components of a cathode, anode, insulator, and bus bar feed-through flange in accordance with an embodiment of the present disclosure.

FIGS. 2-3 are schematic drawings of a SunCell® power generator comprising dual EM pump injectors as liquid electrodes showing tilted reservoirs and a magnetohydrodynamic (MHD) converter comprising a pair of MHD return EM pumps in accordance with an embodiment of the present disclosure.

FIG. 4 is schematic drawings of a single-stage induction injection EM pump in accordance with an embodiment of the present disclosure.

FIG. 5 is schematic drawings of magnetohydrodynamic (MHD) SunCell® power generators comprising dual EM pump injectors as liquid electrodes showing tilted reservoirs, a spherical reaction cell chamber, a straight magnetohydrodynamic (MHD) channel, gas addition housing, and single-stage induction EM pumps for injection and either single-stage induction or DC conduction MHD return EM pumps in accordance with an embodiment of the present disclosure.

FIG. 6 is schematic drawings of a two-stage induction EM pump wherein the first stage serves as the MHD return EM pump and the second stage serves as the injection EM pump in accordance with an embodiment of the present disclosure.

FIG. 7 is schematic drawings of a two-stage induction EM pump wherein the first stage serves as the MHD return EM pump and the second stage serves as the injection EM pump wherein the Lorentz pumping force is more optimized in accordance with an embodiment of the present disclosure.

FIG. 8 is schematic drawings of an induction ignition system in accordance with an embodiment of the present disclosure.

FIGS. 9-10 are schematic drawings of a magnetohydrodynamic (MHD) SunCell® power generator comprising dual EM pump injectors as liquid electrodes showing tilted reservoirs, a spherical reaction cell chamber, a straight magnetohydrodynamic (MHD) channel, gas addition housing, two-stage induction EM pumps for both injection and MHD return each having a forced air cooling system, and an induction ignition system in accordance with an embodiment of the present disclosure.

FIG. 11 is schematic drawings of a magnetohydrodynamic (MHD) SunCell® power generator comprising dual EM pump injectors as liquid electrodes showing tilted reservoirs, a spherical reaction cell chamber, a straight magnetohydrodynamic (MHD) channel, gas addition housing, two-stage induction EM pumps for both injection and MHD return each having a forced liquid cooling system, an induction ignition system, and inductively coupled heating antennas on the EM pump tubes, reservoirs, reaction cell chamber, and MHD return conduit in accordance with an embodiment of the present disclosure.

FIGS. 12-19 are schematic drawings of a magnetohydrodynamic (MHD) SunCell® power generator comprising dual EM pump injectors as liquid electrodes showing tilted reservoirs, a spherical reaction cell chamber, a straight magnetohydrodynamic (MHD) channel, gas addition housing, two-stage induction EM pumps for both injection and MHD return each having an air cooling system, and an induction ignition system in accordance with an embodiment of the present disclosure.

FIG. 20 is schematic drawings showing an exemplary helical-shaped flame heater of the SunCell® and a flame heater comprising a series of annular rings in accordance with an embodiment of the present disclosure.

FIG. 21 is schematic drawings showing an electrolyzer in accordance with an embodiment of the present disclosure.

FIG. 22 is a schematic drawing of a SunCell® power generator comprising dual EM pump injectors as liquid electrodes showing tilted reservoirs and a magnetohydrodynamic (MHD) converter comprising a pair of MHD return EM pumps and a pair of MHD return gas pumps or compressors in accordance with an embodiment of the present disclosure.

FIG. 23 is a schematic drawing of the silver-oxygen phase diagram from Smithells Metals Reference Book-8^{th} Edition, 11-20 in accordance with an embodiment of the present disclosure.

FIG. 24 shows schematic drawings of SunCell® thermal power generators, one comprising a half-spherical-shell-shaped radiant thermal absorber heat exchanger having walls with embedded coolant tubes to receive the thermal power from reaction cell comprising a blackbody radiator and transfer the heat to the coolant and another comprising a circumferential cylindrical heat exchanger and boiler in accordance with an embodiment of the present disclosure.

FIG. 25 is schematic drawings showing details of the SunCell® thermal power generator comprising a single EM pump injector in an injector reservoir and an inverted pedestal as liquid electrodes in accordance with an embodiment of the present disclosure.

FIGS. 26-28 are schematic drawings showing details of the SunCell® thermal power generator comprising a single EM pump injector in an injector reservoir and a partially inverted pedestal as liquid electrodes and a tapered reaction cell chamber to suppress metallization of a PV window in accordance with an embodiment of the present disclosure.

FIG. 29 is a schematic drawing showing details of the SunCell® thermal power generator comprising a single EM pump injector in an injector reservoir, a partially inverted pedestal as liquid electrodes, an induction ignition system, and a PV window in accordance with an embodiment of the present disclosure.

FIG. 30 is a schematic drawing showing details of the SunCell® thermal power generator comprising a cube-shaped reaction cell chamber with a liner and a single EM pump injector in an injector reservoir and an inverted pedestal as liquid electrodes in accordance with an embodiment of the present disclosure.

FIG. 31 is a schematic drawing showing details of the SunCell® thermal power generator comprising an hour-glass-shaped reaction cell chamber liner and a single EM pump injector in an injector reservoir and an inverted pedestal as liquid electrodes in accordance with an embodiment of the present disclosure.

FIG. 32 is a schematic drawing showing details of the SunCell® thermal power generator comprising a single EM pump injector in an injector reservoir, a partially inverted pedestal as liquid electrodes, an induction ignition system, and a bucket elevator gallium oxide skimmer in accordance with an embodiment of the present disclosure.

FIG. 33 is a schematic drawing of a hydrino reaction cell chamber comprising a means to detonate a wire to serve as at least one of a source of reactants and a means to propagate the hydrino reaction to form lower-energy hydrogen species such as molecular hydrino in accordance with an embodiment of the present disclosure.

FIG. 34 is the electron paramagnetic resonance spectroscopy (EPR) spectrum of a hydrino reaction product comprising lower-energy hydrogen comprising a white polymeric compound formed by dissolving Ga₂O₃ collected from a hydrino reaction run in the SunCell® in aqueous KOH, allowing fibers to grow, and float to the surface where they were collected by filtration.

FIG. 35A is a Fourier transform infrared (FTIR) spectrum of the reaction product comprising lower-energy hydrogen species such as molecular hydrino formed by the detonation of Zn wire in an atmosphere comprising water vapor in air in accordance with an embodiment of the present disclosure.

FIG. 35B is a Raman spectrum obtained using a Thermo Scientific DXR SmartRaman spectrometer and a 780 nm laser on a white polymeric compound formed by dissolving Ga₂O₃ collected from a hydrino reaction run in the SunCell® in aqueous KOH, allowing fibers to grow, and float to the surface where they were collected by filtration.

FIGS. 35C-D are Raman spectra obtained using a Horiba Jobin Yvon LabRam ARAMIS spectrometer and a 325 nm laser on a white polymeric compound formed by dissolving Ga₂O₃ collected from a hydrino reaction run in the SunCell® in aqueous KOH, allowing fibers to grow, and float to the surface where they were collected by filtration.

FIG. 36 is an ¹H MAS NMR spectrum relative to external TMS of KCl getter exposed to hydrino gas that shows upfield shifted matrix peak at −4.6 ppm due to the magnetism of molecular hydrino in accordance with an embodiment of the present disclosure.

FIG. 37 is a vibrating sample magnetometer recording of the reaction product comprising lower-energy hydrogen species such as molecular hydrino formed by the detonation of Mo wire in an atmosphere comprising water vapor in air in accordance with an embodiment of the present disclosure.

FIG. 38 is an absolute spectrum in the 5 nm to 450 nm region of the ignition of a 80 mg shot of silver comprising absorbed H₂ and H₂O from gas treatment of silver melt before dripping into a water reservoir showing an average NIST calibrated optical power of 1.3 MW, essentially all in the ultraviolet and extreme ultraviolet spectral region in accordance with an embodiment of the present disclosure.

FIG. 39 is a spectrum (100 nm to 500 nm region with a cutoff at 180 nm due to the sapphire spectrometer window) of the ignition of a molten silver pumped into W electrodes in atmospheric argon with an ambient H₂O vapor pressure of about 1 Torr showing UV line emission that transitioned to 5000K blackbody radiation when the atmosphere became optically thick to the UV radiation with the vaporization of the silver in accordance with an embodiment of the present disclosure.

FIG. 40 is a high resolution visible spectrum of the 800 Torr argon-hydrogen plasma maintained by the hydrino reaction in a Pyrex SunCell® showing a Stark broadening of 1.3 nm corresponding to an electron density of 3.5×10²³/m³ and a 10% ionization fraction requiring about 8.6 GW/m³ to maintain in accordance with an embodiment of the present disclosure.

FIG. 41 is an ultraviolet emission spectrum from electron beam excitation of argon/H₂(¼) gas comprising the ro-vibrational P branch of H₂(¼) in accordance with an embodiment of the present disclosure.

FIG. 42 is an ultraviolet emission spectrum from electron beam excitation of argon/H₂(¼) gas wherein the ro-vibrational P branch of H₂(¼) was greatly enhanced in intensity by flowing the gas mixture through a HayeSep® D chromatographic column cooled to liquid argon temperature in accordance with an embodiment of the present disclosure.

FIG. 43 is an ultraviolet emission spectrum from electron beam excitation of KCl that was impregnated with hydrino reaction product gas showing the H₂(¼) ro-vibrational P branch in the crystalline lattice in accordance with an embodiment of the present disclosure.

FIG. 44 is an ultraviolet emission spectrum from electron beam excitation of KCl that was impregnated with hydrino showing the H₂(¼) ro-vibrational P branch in the crystalline lattice that changed intensity with temperature confirming the H₂(¼) ro-vibration assignment in accordance with an embodiment of the present disclosure.

FIG. 45 is a Raman-mode second-order photoluminescence spectrum of KCl getter exposed to gas from the thermal decomposition of Ga₂O₃:H₂(¼) collected from the SunCell® wherein the spectrum was recorded with a Horiba Jobin Yvon LabRam ARAMIS spectrometer with a 325 nm laser and a 1200 grating over a range of 8000-19,000 cm⁻¹ Raman shift.

FIG. 46 is a Raman spectrum obtained using a Thermo Scientific DXR SmartRaman spectrometer and a 780 nm laser on a In metal foil exposed to the product gas from a series of solid fuel ignitions under argon, each comprising 100 mg of Cu mixed with 30 mg of deionized water showing an inverse Raman effect peak at 1982 cm⁻¹ that matches the free rotor energy of H₂(¼) (0.2414 eV).

FIG. 47, panels A-B are Raman spectra obtained using the Thermo Scientific DXR SmartRaman spectrometer and the 780 nm laser on copper electrodes pre and post ignition of a 80 mg silver shot comprising 1 mole % H₂O, wherein the detonation was achieved by applying a 12 V 35,000 A current with a spot welder, and the spectra showed an inverse Raman effect peak at about 1940 cm⁻¹ that matches the free rotor energy of H₂(¼) (0.2414 eV) in accordance with an embodiment of the present disclosure.

FIG. 48, panels A-B are XPS spectra recorded on the indium metal foil exposed to gases from sequential argon-atmosphere ignitions of the solid fuel 100 mg Cu+30 mg deionized water sealed in the DSC pan in accordance with an embodiment of the present disclosure. (A) A survey spectrum showing only the elements In, C, 0, and trace K peaks were present. (B) High-resolution spectrum showing a peak at 498.5 eV assigned to H₂(¼) wherein other possibilities were eliminated based on the absence of any other corresponding primary element peaks in the survey scan.

FIG. 49, panels A-B are XPS spectra of the Mo hydrino polymeric compound having a peak at 496 eV assigned to H₂(¼) wherein other possibilities such as Na, Sn, and Zn were eliminated since only Mo, O, and C peaks are present and other peaks of the candidates are absent. Mo 3s which is less intense than Mo3p was at 506 eV with additional samples that also showed the H₂(¼) 496 eV peak in accordance with an embodiment of the present disclosure. (A) Survey scan. (B) High resolution scan in the region of the 496 eV peak of H₂(¼).

FIG. 50, panels A-B are XPS spectra on copper electrodes post ignition of a 80 mg silver shot comprising 1 mole % H₂O, wherein the detonation was achieved by applying a 12 V 35,000 A current with a spot welder in accordance with an embodiment of the present disclosure. The peak at 496 eV was assigned to H₂(¼) wherein other possibilities such as Na, Sn, and Zn were eliminated since the corresponding peaks of these candidates are absent. Raman post detonation spectra (FIGS. 46A-B) showed an inverse Raman effect peak at about 1940 cm¹ that matches the free rotor energy of H₂(¼) (0.2414 eV).

FIGS. 51A-E are control gas chromatographs recorded with a HP 5890 Series II gas chromatograph using an Agilent molecular sieve column with helium carrier gas and a thermal conductivity detector (TCD) set at 60° C. so that any H₂ peak was positive in accordance with an embodiment of the present disclosure. (A) Gas chromatograph of 1000 Torr hydrogen showing a positive peak at 10 minutes. (B) Gas chromatograph of 1000 Torr methane showing a small positive H₂O contamination peak at 17 minutes and a positive methane peak at 50.5 minutes. (C) Gas chromatograph of 1000 Torr hydrogen (90%) and methane (10%) mixture showing a positive hydrogen peak at 10 minutes and a positive methane peak at 50.2 minutes. (D) Gas chromatograph of 760 Torr air showing a very small positive H₂O peak at 17.1 minutes, a positive oxygen peak at 17.6 minutes, and a positive nitrogen peak at 35.7 minutes. (E) Gas chromatograph of gas from heating gallium metal to 950° C. showing no peaks.

FIGS. 52A-B are gas chromatographs of hydrino gas evolved from NaOH-treated Ga₂O₃ collected from a hydrino reaction run in the SunCell® and heated to 950° C. The gas chromatographs were immediately recorded following gas release with a HP 5890 Series II gas chromatograph using an Agilent molecular sieve column with helium carrier gas and a thermal conductivity detector (TCD) set at 60° C. so that any H₂ peak was positive in accordance with an embodiment of the present disclosure. (A) Gas chromatograph of hydrino gas evolved from NaOH-treated Ga₂O₃ collected from a hydrino reaction run in the SunCell® showing a known positive hydrogen peak at 10 minutes and a novel negative peak at 9 minutes assigned to H₂(¼) having positive leading and trailing edges at 8.9 minutes and 9.3 minutes, respectively. No known gas has a faster migration time and higher thermal conductivity than H₂ or He which is characteristic of and identifies hydrino since it has a much greater mean free path due to exemplary H₂(¼) having 64 times smaller volume and 16 times smaller ballistic cross section. (B) Expanded view of negative peak assigned to H₂(¼).

FIG. 53 is a gas chromatograph of gas evolved from NaOH-treated Ga₂O₃ collected from a hydrino reaction run in the SunCell® and heated to 950° C. that was recorded after allowing the gas in the vessel to stand for over 24 hours following the time of the recording of the gas chromatograph shown in FIGS. 52A-B in accordance with an embodiment of the present disclosure. The hydrogen peak was observed again at 10 minutes, but the novel negative peak with shorter retention time than hydrogen was absent, consistent with the smaller size and corresponding high diffusivity of H₂(¼) even compared to H₂. The positive peak at 37 minutes corresponded to trace nitrogen contamination.

FIGS. 54A-B are gas chromatographs of hydrino gas evolved from NaOH-treated Ga₂O₃ collected from a second hydrino reaction run in the SunCell® and heated to 950° C. The gas chromatographs were recorded with a HP 5890 Series II gas chromatograph using an Agilent molecular sieve column with helium carrier gas and a thermal conductivity detector (TCD) set at 60° C. so that any H₂ peak was positive in accordance with an embodiment of the present disclosure. (A) Gas chromatograph of hydrino gas evolved from NaOH-treated Ga₂O₃ collected from a hydrino reaction run in the SunCell® showing a known positive hydrogen peak at 10 minutes, a positive unknown peak at 42.4 minutes, a positive methane peak at 51.8 minutes, and a novel negative peak at 8.76 minutes assigned to H₂(¼) having positive leading and trailing edges at 8.66 minutes and 9.3 minutes, respectively. No known gas has a faster migration time and higher thermal conductivity than H₂ or He which is characteristic of and identifies hydrino since it has a much greater mean free path due to exemplary H₂(¼) having 64 times smaller volume and 16 times smaller ballistic cross section. (B) Expanded view of negative peak assigned to H₂(¼).

FIGS. 55A-B are gas chromatographs of hydrino gas evolved from NaOH-treated Ga₂O₃ collected from a third hydrino reaction run in the SunCell® and heated to 950° C. The gas chromatographs were recorded with a HP 5890 Series II gas chromatograph using an Agilent molecular sieve column with helium carrier gas and a thermal conductivity detector (TCD) set at 60° C. so that any H₂ peak was positive in accordance with an embodiment of the present disclosure. (A) Gas chromatograph of hydrino gas evolved from NaOH-treated Ga₂O₃ collected from a hydrino reaction run in the SunCell® showing a known positive hydrogen peak at 10 minutes, and positive methane peak at 51.9 minutes and a novel negative peak at 8.8 minutes assigned to H₂(¼) having positive leading and trailing edges at 8.7 minutes and 9.3 minutes, respectively. No known gas has a faster migration time and higher thermal conductivity than H₂ or He which is characteristic of and identifies hydrino since it has a much greater mean free path due to exemplary H₂(¼) having 64 times smaller volume and 16 times smaller ballistic cross section. (B) Expanded view of negative peak assigned to H₂(¼).

FIG. 56 is a mass spectrum of gas evolved from NaOH-treated Ga₂O₃ collected from a hydrino reaction run in the SunCell® and heated to 950° C. that was recorded after the recording of the gas chromatograph shown in FIGS. 55A-B that confirmed the presence of hydrogen and methane in accordance with an embodiment of the present disclosure. The formation of methane is extraordinary and attributed to the energetic hydrino plasma causing reaction of hydrogen with trace CO₂ or carbon from the stainless steel reactor.

FIG. 57 is a gas chromatograph of gas evolved from NaOH-treated Ga₂O₃ collected from the third hydrino reaction run in the SunCell® and heated to 950° C. that was recorded after allowing the gas vessel to stand for over 24 hours following the time of the recording of the gas chromatograph shown in FIGS. 55A-B in accordance with an embodiment of the present disclosure. The hydrogen peak at 10 minutes and the methane peak at 53.7 minutes were observed again, but the novel negative peak with shorter retention time than hydrogen was absent, consistent with the smaller size and corresponding high diffusivity of H₂(¼) even compared to H₂.

FIG. 58 is a gas chromatograph of hydrino gas evolved from NaOH-treated Ga₂O₃ collected from a fourth hydrino reaction run in the SunCell® showing a known positive hydrogen peak at 10 minutes, and a novel positive peak at 7.4 minutes assigned to H₂(¼) since no known gas has a faster migration time than H₂ or He in accordance with an embodiment of the present disclosure. The positive nature of the H₂(¼) peak was indicative of a lower concentration of hydrino gas in the helium carrier gas.

FIG. 59 is a gas chromatograph of hydrino gas flowed from the SunCell®, absorbed into liquid argon as a solvent, and then released by allowing liquid argon to vaporize upon warming to 27° C. The hydrino peak was observed at 8.05 minutes compared to hydrogen that was observed at 12.58 minutes on the Agilent column using a second HP 5890 Series II gas chromatograph with a thermal conductivity detector and argon carrier gas.

FIG. 60 is a gas chromatograph of molecular hydrino gas enriched using a HayeSep® D chromatographic column cooled to liquid argon temperature, liquified with trace air using a valved microchamber cooled to 55 K by a cryopump system, vaporized by warming to room temperature to achieve 1000 Torr chamber pressure, and injected on to the Agilent column using a HP 5890 Series II gas chromatograph with a thermal conductivity detector and argon carrier gas. Oxygen and nitrogen were observed at 19 and 35 minutes, respectively, and H₂(¼) was observed at 6.9 minutes.

FIG. 61 is a wavelength-calibrated spectrum (3900-4090 Å) of a hydrino-reaction-plasma formed by heating KNO₃ and dissociating H₂ using a tungsten filament overlaid with a hydrogen microwave plasma. Due to the requirement that flux is linked by H(½) in integer units of the magnetic flux quantum, the energy is quantized, and the emission due to H⁻(½) formation comprises a series of hyperfine lines in the corresponding bound-free band with energies given by the sum of the fluxon energy E_{Φ}, the spin-spin energy Eₛₛ, and the observed binding energy peak E_{B}*, E_{HF}=(j²3.00213×10⁻⁵+3.0563) eV, wherein the spectra in the region of 4000 Å to 4060 Å matched the predicted emission lines and other species such as nitrogen were ruled out in accordance with an embodiment of the present disclosure.

### DETAILED DESCRIPTION

Disclosed herein are power generation systems and methods of power generation which convert the energy output from reactions involving atomic hydrogen into electrical and/or thermal energy. These reactions may involve catalyst systems which release energy from atomic hydrogen to form lower energy states wherein the electron shell is at a closer position relative to the nucleus. The released power is harnessed for power generation and additionally new hydrogen species and compounds are desired products. These energy states are predicted by classical physical laws and require a catalyst to accept energy from the hydrogen in order to undergo the corresponding energy-releasing transition.

Classical physics gives closed-form solutions of the hydrogen atom, the hydride ion, the hydrogen molecular ion, and the hydrogen molecule and predicts corresponding species having fractional principal quantum numbers. Atomic hydrogen may undergo a catalytic reaction with certain species, including itself, that can accept energy in integer multiples of the potential energy of atomic hydrogen, m·27.2 eV, wherein m is an integer. The predicted reaction involves a resonant, nonradiative energy transfer from otherwise stable atomic hydrogen to the catalyst capable of accepting the energy. The product is H(1/p), fractional Rydberg states of atomic hydrogen called “hydrino atoms,” wherein n=½, ⅓, ¼, . . . , 1/p (p≤137 is an integer) replaces the well-known parameter n=integer in the Rydberg equation for hydrogen excited states. Each hydrino state also comprises an electron, a proton, and a photon, but the field contribution from the photon increases the binding energy rather than decreasing it corresponding to energy desorption rather than absorption. Since the potential energy of atomic hydrogen is 27.2 eV, m H atoms serve as a catalyst of m·27.2 eV for another (m+1)th H atom [R. Mills, The Grand Unified Theory of Classical Physics; September 2016 Edition, posted at https.//brilliantlightpower.com/book-download-and-streaming/(“Mills GUTCP”)]. For example, a H atom can act as a catalyst for another H by accepting 27.2 eV from it via through-space energy transfer such as by magnetic or induced electric dipole-dipole coupling to form an intermediate that decays with the emission of continuum bands with short wavelength cutoffs and energies of

$${m}^{2} \cdot 13.6 eV ( \frac{91.2}{{m}^{2}} nm ) .$$

In addition to atomic H, a molecule that accepts m·27.2 eV from atomic H with a decrease in the magnitude of the potential energy of the molecule by the same energy may also serve as a catalyst. The potential energy of H₂O is 81.6 eV. Then, by the same mechanism, the nascent H₂O molecule (not hydrogen bonded in solid, liquid, or gaseous state) formed by a thermodynamically favorable reduction of a metal oxide is predicted to serve as a catalyst to form H(¼) with an energy release of 204 eV, comprising an 81.6 eV transfer to HOH and a release of continuum radiation with a cutoff at 10.1 nm (122.4 eV).

In the H-atom catalyst reaction involving a transition to the

$$H [ \frac{{a}_{H}}{p = m + 1} ]$$

state, m H atoms serve as a catalyst of m·27.2 eV for another (m+1)th H atom. Then, the reaction between m+1 hydrogen atoms whereby m atoms resonantly and nonradiatively accept m·27.2 eV from the (m+1)th hydrogen atom such that mH serves as the catalyst is given by

$$\begin{matrix}m \cdot 27.2 eV + mH + H \to {mH}_{fast}^{+} + {me}^{-} + H * [ \frac{{a}_{H}}{m + 1} ] + m \cdot 27.2 eV & ( 1 ) \\ H * [ \frac{{a}_{H}}{m + 1} ] \to H [ \frac{{a}_{H}}{m + 1} ] + [ {( m - 1 )}^{2} - {1}^{2} ] \cdot 13.6 eV - m \cdot 27.2 eV & ( 2 ) \\ {mH}_{fast}^{+} + {me}^{-} \to mH + m \cdot 27.2 eV & ( 3 )\end{matrix}$$

And, the overall reaction is

$$H \to H [ \frac{{a}_{H}}{p = m + 1} ] + [ {( m + 1 )}^{2} - {1}^{2} ] \cdot 13.6 eV \qquad ( 4 )$$

The catalysis reaction (m=3) regarding the potential energy of nascent H₂O [R. Mills, The Grand Unified Theory of Classical Physics; September 2016 Edition, posted at https://brilliantlightpower.com/book-download-and-streaming/] is

$$\begin{matrix}81.6 eV + {H}_{2} O + H [ {a}_{H} ] = 2 {H}_{fast}^{+} + {O}^{-} + {e}^{-} + H * [ \frac{{a}_{H}}{4} ] + 81.6 eV & ( 5 ) \\ H * [ \frac{{a}_{H}}{4} ] \to H [ \frac{{a}_{H}}{4} ] + 122.4 eV & ( 6 ) \\ 2 {H}_{fast}^{+} + {O}^{-} + {e}^{-} \to {H}_{2} O + 81.6 eV & ( 7 )\end{matrix}$$

And, the overall reaction is

$$H [ {a}_{H} ] \to H [ \frac{{a}_{H}}{4} ] + 81.6 eV + 122.4 eV \qquad ( 8 )$$

After the energy transfer to the catalyst (Eqs. (1) and (5)), an intermediate

$$H * [ \frac{{a}_{H}}{m + 1} ]$$

is formed having the radius of the H atom and a central field of m+1 times the central field of a proton. The radius is predicted to decrease as the electron undergoes radial acceleration to a stable state having a radius of 1/(m+1) the radius of the uncatalyzed hydrogen atom, with the release of m²·13.6 eV of energy. The extreme-ultraviolet continuum radiation band due to the

$$H * [ \frac{{a}_{H}}{4} ]$$

intermediate (e.g. Eq. (2) and Eq. (6)) is predicted to have a short wavelength cutoff and energy

$${E}_{( H \to H [ \frac{{a}_{H}}{p = m + 1} ] )}$$

given by

$${E}_{( H \to H [ \frac{{a}_{H}}{p = m + 1} ] )} = {m}^{2} \cdot 13.6 eV ; {λ}_{( H \to H [ \frac{{a}_{H}}{p = m + 1} ] )} = \frac{91.2}{{m}^{2}} nm \qquad ( 9 )$$

and extending to longer wavelengths than the corresponding cutoff. Here the extreme-ultraviolet continuum radiation band due to the decay of the H*[a_{H}/4] intermediate is predicted to have a short wavelength cutoff at E=m² 13.6=9-13.6=122.4 eV (10.1 nm) [where p=m+1=4 and m=3 in Eq. (9)] and extending to longer wavelengths. The continuum radiation band at 10.1 nm and going to longer wavelengths for the theoretically predicted transition of H to lower-energy, so called “hydrino” state H(¼), was observed only arising from pulsed pinch gas discharges comprising some hydrogen. Another observation predicted by Eqs. (1) and (5) is the formation of fast, excited state H atoms from recombination of fast H⁺. The fast atoms give rise to broadened Balmer α emission. Greater than 50 eV Balmer α line broadening that reveals a population of extraordinarily high-kinetic-energy hydrogen atoms in certain mixed hydrogen plasmas is a well-established phenomenon wherein the cause is due to the energy released in the formation of hydrinos. Fast H was previously observed in continuum-emitting hydrogen pinch plasmas.

Additional catalyst and reactions to form hydrino are possible. Specific species (e.g. He⁺, Ar⁺, Sr⁺, K, Li, HCl, and NaH, OH, SH, SeH, nascent H₂O, nH (n=integer)) identifiable on the basis of their known electron energy levels are required to be present with atomic hydrogen to catalyze the process. The reaction involves a nonradiative energy transfer followed by q·13.6 eV continuum emission or q·13.6 eV transfer to H to form extraordinarily hot, excited-state H and a hydrogen atom that is lower in energy than unreacted atomic hydrogen that corresponds to a fractional principal quantum number. That is, in the formula for the principal energy levels of the hydrogen atom:

$$\begin{matrix}{E}_{n} = - \frac{{e}^{2}}{{n}^{2} 8 {πɛ}_{0} {a}_{H}} = - \frac{13.598 eV}{{n}^{2}} . & ( 10 ) \\ n = 1 , 2 , 3 , … & ( 11 )\end{matrix}$$

where a_{H} is the Bohr radius for the hydrogen atom (52.947 pm), e is the magnitude of the charge of the electron, and ε is the vacuum permittivity, fractional quantum numbers:

$$n = 1 , \frac{1}{2} , \frac{1}{3} , \frac{1}{4} , … , \frac{1}{p} ; where p \leq 137 is an integer \qquad ( 12 )$$

replace the well known parameter n=integer in the Rydberg equation for hydrogen excited states and represent lower-energy-state hydrogen atoms called “hydrinos.” The n=1 state of hydrogen and the

$$n = \frac{1}{integer}$$

states of hydrogen are nonradiative, but a transition between two nonradiative states, say n=1 to n=½, is possible via a nonradiative energy transfer. Hydrogen is a special case of the stable states given by Eqs. (10) and (12) wherein the corresponding radius of the hydrogen or hydrino atom is given by

$$r = \frac{{a}_{H}}{p} , \qquad ( 13 )$$

where p=1, 2, 3, . . . . In order to conserve energy, energy must be transferred from the hydrogen atom to the catalyst in units of an integer of the potential energy of the hydrogen atom in the normal n=1 state, and the radius transitions to

$$\frac{{a}_{H}}{m + p} .$$

Hydrinos are formed by reacting an ordinary hydrogen atom with a suitable catalyst having a net enthalpy of reaction of

m·27.2 eV (14)

where m is an integer. It is believed that the rate of catalysis is increased as the net enthalpy of reaction is more closely matched to m·27.2 eV. It has been found that catalysts having a net enthalpy of reaction within ±10%, preferably ±5%, of m·27.2 eV are suitable for most applications.

The catalyst reactions involve two steps of energy release: a nonradiative energy transfer to the catalyst followed by additional energy release as the radius decreases to the corresponding stable final state. Thus, the general reaction is given by

$$\begin{matrix}m \cdot 27.2 eV + {Cat}^{q +} + H [ \frac{{a}_{H}}{p} ] = {Cat}^{( q + r ) +} + {re}^{-} + H * [ \frac{{a}_{H}}{( m + p )} ] + m \cdot 27.2 eV & ( 15 ) \\ H * [ \frac{{a}_{H}}{( m + p )} ] = H [ \frac{{a}_{H}}{( m + p )} ] + [ {( p + m )}^{2} - {p}^{2} ] \cdot 13.6 eV - m \cdot 27.2 eV & ( 16 ) \\ {Cat}^{( q + r ) +} + {re}^{-} \to {Cat}^{q +} + m \cdot 27.2 eV and & ( 17 )\end{matrix}$$

the overall reaction is

$$H [ \frac{{a}_{H}}{p} ] = H [ \frac{{a}_{H}}{( m + p )} ] + [ {( p - m )}^{2} - {p}^{2} ] \cdot 13.6 eV \qquad ( 18 )$$

q, r, m, and p are integers.

$$H * [ \frac{{a}_{H}}{( m + p )} ]$$

has the radius of the hydrogen atom (corresponding to the 1 in the denominator) and a central field equivalent to (m+p) times that of a proton, and

$$H * [ \frac{{a}_{H}}{( m + p )} ]$$

is the corresponding stable state with the radius of

$$\frac{1}{( m + p )}$$

that of H.

The catalyst product, H (1/p), may also react with an electron to form a hydrino hydride ion H⁻ (1/p), or two H (1/p) may react to form the corresponding molecular hydrino H₂ (1/p). Specifically, the catalyst product, H(1/p), may also react with an electron to form a novel hydride ion H⁻ (1/p) with a binding energy E_{B}:

$${E}_{B} = \frac{{ℏ}^{2} \sqrt{s ( s + 1 )}}{8 {μ}_{e} {{a}_{0}^{2} [ \frac{1 + \sqrt{s ( s + 1 )}}{p} ]}^{2}} - \frac{{πμ}_{0} {e}^{2} {ℏ}^{2}}{{m}_{e}^{2}} ( \frac{1}{{a}_{H}^{3}} + \frac{{2}^{2}}{{{a}_{0}^{3} [ \frac{1 + \sqrt{s ( s + 1 )}}{p} ]}^{3}} ) \qquad ( 19 )$$

where p=integer >1, s=½, ℏ is Planck's constant bar, μₒ is the permeability of vacuum, mₑ is the mass of the electron, μₑ is the reduced electron mass given by

$${μ}_{e} = \frac{{m}_{e} {m}_{p}}{\frac{{m}_{e}}{\sqrt{\frac{3}{4}}} + {m}_{p}}$$

where mₚ is the mass of the proton, aₒ is the Bohr radius, and the ionic radius is

$${r}_{1} = \frac{{a}_{0}}{p} ( 1 + \sqrt{s ( s + 1 )} ) .$$

From Eq. (19), the calculated ionization energy of the hydride ion is 0.75418 eV, and the experimental value is 6082.99±0.15 cm⁻¹ (0.75418 eV). The binding energies of hydrino hydride ions may be measured by X-ray photoelectron spectroscopy (XPS).

Upfield-shifted NMR peaks are direct evidence of the existence of lower-energy state hydrogen with a reduced radius relative to ordinary hydride ion and having an increase in diamagnetic shielding of the proton. The shift is given by the sum of the contributions of the diamagnetism of the two electrons and the photon field of magnitude p (Mills GUTCP Eq. (7.87)): PGP 245,

$$\frac{Δ {B}_{T}}{B} = - {μ}_{0} \frac{{pe}^{2}}{12 {m}_{e} {a}_{0} ( 1 + \sqrt{s ( s + 1 )} )} ( 1 + p {α}^{2} ) = - ( p29 .9 + {p}^{2} 1.59 \times {10}^{- 3} ) ppm \qquad ( 20 )$$

where the first term applies to H⁻ with p=1 and p=integer >1 for H⁻(1/p) and α is the fine structure constant. The predicted hydrino hydride peaks are extraordinarily upfield shifted relative to ordinary hydride ion. In an embodiment, the peaks are upfield of TMS. The NMR shift relative to TMS may be greater than that known for at least one of ordinary H⁻, H, H₂, or H⁺ alone or comprising a compound. The shift may be greater than at least one of 0, −1, −2, −3, −4, −5, −6, −7, −8, −9, −10, −11, −12, −13, −14, −15, −16, −17, −18, −19, −20, −21, −22, −23, −24, −25, −26, −27, −28, −29, −30, −31, −32, −33, −34, −35, −36, −37, −38, −39, and −40 ppm. The range of the absolute shift relative to a bare proton, wherein the shift of TMS is about −31.5 relative to a bare proton, may be −(p29.9+p²2.74) ppm (Eq. (20)) within a range of about at least one of ±5 ppm, ±10 ppm, ±20 ppm, ±30 ppm, ±40 ppm, ±50 ppm, ±60 ppm, ±70 ppm, ±80 ppm, ±90 ppm, and ±100 ppm. The range of the absolute shift relative to a bare proton may be −(p29.9+p²1.59×10⁻³) ppm (Eq. (20)) within a range of about at least one of about 0.1% to 99%, 10% to 50%, and 1% to 10%. In another embodiment, the presence of a hydrino species such as a hydrino atom, hydride ion, or molecule in a solid matrix such as a matrix of a hydroxide such as NaOH or KOH causes the matrix protons to shift upfield. The matrix protons such as those of NaOH or KOH may exchange. In an embodiment, the shift may cause the matrix peak to be in the range of about −0.1 ppm to −5 ppm relative to TMS. The NMR determination may comprise magic angle spinning ¹H nuclear magnetic resonance spectroscopy (MAS ¹H NMR).

H (1/p) may react with a proton and two H (1/p) may react to form H₂ (1/p)⁺ and H₂(1/p), respectively. The hydrogen molecular ion and molecular charge and current density functions, bond distances, and energies were solved from the Laplacian in ellipsoidal coordinates with the constraint of nonradiation.

$$( η - ζ ) {R}_{ξ} \frac{\partial }{\partial ξ} ( {R}_{ξ} \frac{\partial ϕ}{\partial ξ} ) + ( ζ - ξ ) {R}_{η} \frac{\partial }{\partial η} ( {R}_{η} \frac{\partial ϕ}{\partial η} ) + ( ξ - η ) {R}_{ζ} \frac{\partial }{\partial ζ} ( {R}_{ζ} \frac{\partial ϕ}{\partial ζ} ) = 0 \qquad ( 21 )$$

The total energy E_{T} of the hydrogen molecular ion having a central field of +pe at each focus of the prolate spheroid molecular orbital is

$$\begin{matrix}{E}_{T} = - {p}^{2} \{ \begin{matrix}\frac{{e}^{2}}{8 {πɛ}_{o} {a}_{H}} ( 4 ln 3 - 1 - 2 ln 3 ) [ 1 + p \sqrt{\frac{2 ℏ \sqrt{\frac{2 {e}^{2}}{\frac{4 {{πɛ}_{o} ( 2 {a}_{H} )}^{3}}{{m}_{e}}}}}{{m}_{e} {c}^{2}}} ] - \\ \frac{1}{2} ℏ \sqrt{\frac{\frac{{pe}^{2}}{4 {{πɛ}_{o} ( \frac{2 {a}_{H}}{p } )}^{3}} - \frac{{pe}^{2}}{8 {{πɛ}_{o} ( \frac{3 {a}_{H}}{p} )}^{3}}}{μ}} \end{matrix} \} \\ = - {p}^{2} 16.13392 eV - {p}^{3} 0.118755 eV\end{matrix} \qquad ( 22 )$$

where p is an integer, c is the speed of light in vacuum, and μ is the reduced nuclear mass. The total energy of the hydrogen molecule having a central field of +pe at each focus of the prolate spheroid molecular orbital is

$$\begin{matrix}{E}_{T} = - {p}^{2} \{ \begin{matrix}\frac{{e}^{2}}{8 {πɛ}_{o} {a}_{H}} [ ( 2 \sqrt{2} - \sqrt{2} + \frac{\sqrt{2}}{2} ) ln \frac{\sqrt{2} + 1}{\sqrt{2} - 1} - \sqrt{2} ] [ 1 + p \sqrt{\frac{2 ℏ \sqrt{\frac{{e}^{2}}{\frac{4 {πɛ}_{o} {a}_{0}^{3}}{{m}_{e}}}}}{{m}_{e} {c}^{2}}} ] - \\ \frac{1}{2} ℏ \sqrt{\frac{\frac{{pe}^{2}}{8 {{πɛ}_{o} ( \frac{{a}_{0}}{p } )}^{3}} - \frac{{pe}^{2}}{8 {{πɛ}_{o} ( \frac{( 1 + \frac{1}{\sqrt{2}} ) {a}_{o}}{p} )}^{3}}}{μ}} \end{matrix} \} \\ = - {p}^{2} 31.351 eV - {p}^{3} 0.326469 eV\end{matrix} \qquad ( 23 )$$

The bond dissociation energy, E_{D}, of the hydrogen molecule H₂(1/p) is the difference between the total energy of the corresponding hydrogen atoms and E_{T}

$$\begin{matrix}{E}_{D} = E ( 2 H ( 1 \text{/} p ) ) - {E}_{T} \\ where & ( 24 ) \\ E ( 2 H ( 1 \text{/} p ) ) = - {p}^{2} 27.20 eV \\ {E}_{D} is given by Eqs . ( 23 \text{-} 25 ) \text{:} & ( 24 ) \\ \begin{matrix}{E}_{D} = - {p}^{2} 27.20 eV - {E}_{T} \\ = - {p}^{2} 27.20 eV - ( - {p}^{2} 31.351 eV - {p}^{3} 0.326469 eV ) \\ = {p}^{2} 4.151 eV + {p}^{3} 0.326469 eV\end{matrix} & ( 26 )\end{matrix}$$

H_{z}(1/p) may be identified by X-ray photoelectron spectroscopy (XPS) wherein the ionization product in addition to the ionized electron may be at least one of the possibilities such as those comprising two protons and an electron, a hydrogen (H) atom, a hydrino atom, a molecular ion, hydrogen molecular ion, and H₂ (1/p)⁺ wherein the energies may be shifted by the matrix.

The NMR of catalysis-product gas provides a definitive test of the theoretically predicted chemical shift of H₂ (1/p). In general, the ¹H NMR resonance of H₂ (1/p) is predicted to be upfield from that of H, due to the fractional radius in elliptic coordinates wherein the electrons are significantly closer to the nuclei. The predicted shift,

$$\frac{Δ {B}_{T}}{B} ,$$

for H₂ (1/p) is given by the sum of the contributions of the diamagnetism of the two electrons and the photon field of magnitude p (Mills GUTCP Eqs. (11.415-11.416)):

$$\begin{matrix}\frac{Δ {B}_{T}}{B} = - {μ}_{0} ( 4 - \sqrt{2} ln \frac{\sqrt{2} + 1}{\sqrt{2} - 1} ) \frac{{pe}^{2}}{36 {a}_{0} {m}_{e}} ( 1 + p {α}^{2} ) & ( 27 ) \\ \frac{Δ {B}_{T}}{B} = - ( p 28.01 + {p}^{2} 1.49 \times {10}^{- 3} ) ppm & ( 28 )\end{matrix}$$

where the first term applies to H₂ with p=1 and p=integer >1 for H_{z}(1/p). The experimental absolute H₂ gas-phase resonance shift of −28.0 ppm is in excellent agreement with the predicted absolute gas-phase shift of −28.01 ppm (Eq. (28)). The predicted molecular hydrino peaks are extraordinarily upfield shifted relative to ordinary H₂. In an embodiment, the peaks are upfield of TMS. The NMR shift relative to TMS may be greater than that known for at least one of ordinary H⁻, H, H₂, or H⁺ alone or comprising a compound. The shift may be greater than at least one of 0, −1, −2, −3, −4, −5, −6, −7, −8, −9, −10, −11, −12, −13, −14, −15, −16, −17, −18, −19, −20, −21, −22, −23, −24, −25, −26, −27, −28, −29, −30, −31, −32, −33, −34, −35, −36, −37, −38, −39, and −40 ppm. The range of the absolute shift relative to a bare proton, wherein the shift of TMS is about −31.5 ppm relative to a bare proton, may be −(p28.01+p²2.56) ppm (Eq. (28)) within a range of about at least one of 5 ppm, +10 ppm, +20 ppm, +30 ppm, +40 ppm, +50 ppm, +60 ppm, +70 ppm, +80 ppm, +90 ppm, and +100 ppm. The range of the absolute shift relative to a bare proton may be −(p28.01+p²1.49×10⁻³) ppm (Eq. (28)) within a range of about at least one of about 0.1% to 99%, 1% to 50%, and 1% to 10%.

The vibrational energies, E_{vib}, for the ν=0 to ν=1 transition of hydrogen-type molecules H₂(1/p) are

E_{vib}=p²0.515902 eV (29)

where p is an integer.

The rotational energies, Eᵣₒₜ, for the J to J+1 transition of hydrogen-type molecules H₂(1/p) are

$${E}_{rot} = {E}_{J + 1} - {E}_{J} = \frac{{ℏ}^{2}}{I} [ J + 1 ] = {p}^{2} ( J + 1 ) 0.01509 eV \qquad ( 30 )$$

where p is an integer and I is the moment of inertia. Ro-vibrational emission of H₂ (¼) was observed on e-beam excited molecules in gases and trapped in solid matrix.

The p² dependence of the rotational energies results from an inverse p dependence of the internuclear distance and the corresponding impact on the moment of inertia I. The predicted internuclear distance 2c′ for H₂(1/p) is

$$2 {c}^{′} = \frac{{a}_{o} \sqrt{2}}{p} \qquad ( 31 )$$

At least one of the rotational and vibration energies of H₂(1/p) may be measured by at least one of electron-beam excitation emission spectroscopy, Raman spectroscopy, and Fourier transform infrared (FTIR) spectroscopy. H₂(1/p) may be trapped in a matrix for measurement such as in at least one of MOH, MX, and M₂CO₃ (M=alkali; X=halide) matrix.

In an embodiment, the molecular hydrino product is observed as an inverse Raman effect (IRE) peak at about 1950 cm⁻¹. The peak is enhanced by using a conductive material comprising roughness features or particle size comparable to that of the Raman laser wavelength that supports a Surface Enhanced Raman Scattering (SERS) to show the IRE peak.

I. Catalysts

In the present disclosure the terms such as hydrino reaction, H catalysis, H catalysis reaction, catalysis when referring to hydrogen, the reaction of hydrogen to form hydrinos, and hydrino formation reaction all refer to the reaction such as that of Eqs. (15-18) of a catalyst defined by Eq. (14) with atomic H to form states of hydrogen having energy levels given by Eqs. (10) and (12). The corresponding terms such as hydrino reactants, hydrino reaction mixture, catalyst mixture, reactants for hydrino formation, reactants that produce or form lower-energy state hydrogen or hydrinos are also used interchangeably when referring to the reaction mixture that performs the catalysis of H to H states or hydrino states having energy levels given by Eqs. (10) and (12).

The catalytic lower-energy hydrogen transitions of the present disclosure require a catalyst that may be in the form of an endothermic chemical reaction of an integer m of the potential energy of uncatalyzed atomic hydrogen, 27.2 eV, that accepts the energy from atomic H to cause the transition. The endothermic catalyst reaction may be the ionization of one or more electrons from a species such as an atom or ion (e.g. m=3 for Li→Li²⁺) and may further comprise the concerted reaction of a bond cleavage with ionization of one or more electrons from one or more of the partners of the initial bond (e.g. m=2 for NaH→Na²⁺+H). He⁺ fulfills the catalyst criterion—a chemical or physical process with an enthalpy change equal to an integer multiple of 27.2 eV since it ionizes at 54.417 eV, which is 2·27.2 eV. An integer number of hydrogen atoms may also serve as the catalyst of an integer multiple of 27.2 eV enthalpy. catalyst is capable of accepting energy from atomic hydrogen in integer units of one of about 27.2 eV±0.5 eV and

$$\frac{27.2}{2} eV \pm 0.5 eV .$$

In an embodiment, the catalyst comprises an atom or ion M wherein the ionization of t electrons from the atom or ion M each to a continuum energy level is such that the sum of ionization energies of the t electrons is approximately one of m·27.2 eV and

$$m \cdot \frac{27.2}{2} eV$$

where m is an integer.

In an embodiment, the catalyst comprises a diatomic molecule MH wherein the breakage of the M-H bond plus the ionization of t electrons from the atom M each to a continuum energy level is such that the sum of the bond energy and ionization energies of the t electrons is approximately one of m·27.2 eV and

$$m \cdot \frac{27 , 2}{2} eV$$

where m is an integer.

In an embodiment, the catalyst comprises atoms, ions, and/or molecules chosen from molecules of AlH, AsH, BaH, BiH, CdH, ClH, CoH, GeH, InH, NaH, NbH, OH, RhH, RuH, SH, SbH, SeH, SiH, SnH, SrH, TlH, C₂, N₂, O₂, CO₂, NO₂, and NO₃ and atoms or ions of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, Kr, 2K⁺, He⁺, Ti²⁺, Na, Rb⁺, Sr⁺, Fe³⁺, Mo²⁺, Mo⁴⁺, In³⁺, He⁺, Ar⁺, Xe⁺, Ar²⁺ and H⁺, and Ne⁺ and H⁺.

In other embodiments, MH⁻ type hydrogen catalysts to produce hydrinos provided by the transfer of an electron to an acceptor A, the breakage of the M-H bond plus the ionization of t electrons from the atom M each to a continuum energy level such that the sum of the electron transfer energy comprising the difference of electron affinity (EA) of MH and A, M-H bond energy, and ionization energies of the t electrons from M is approximately m·27.2 eV where m is an integer. MH⁻ type hydrogen catalysts capable of providing a net enthalpy of reaction of approximately m·27.2 eV are OH⁻, SiH⁻, CoH⁻, NiH⁻, and SeH⁻

In other embodiments, MH⁺ type hydrogen catalysts to produce hydrinos are provided by the transfer of an electron from a donor A which may be negatively charged, the breakage of the M-H bond, and the ionization of t electrons from the atom M each to a continuum energy level such that the sum of the electron transfer energy comprising the difference of ionization energies of MH and A, bond M-H energy, and ionization energies of the t electrons from M is approximately m·27.2 eV where m is an integer.

In an embodiment, at least one of a molecule or positively or negatively charged molecular ion serves as a catalyst that accepts about m·27.2 eV from atomic H with a decrease in the magnitude of the potential energy of the molecule or positively or negatively charged molecular ion by about m·27.2 eV. Exemplary catalysts are H₂O, OH, amide group NH₂, and H₂S.

O₂ may serve as a catalyst or a source of a catalyst. The bond energy of the oxygen molecule is 5.165 eV, and the first, second, and third ionization energies of an oxygen atom are 13.61806 eV, 35.11730 eV, and 54.9355 eV, respectively. The reactions O₂→O+O²⁺, O₂→O+O³⁺, and 2O→2O⁺ provide a net enthalpy of about 2, 4, and 1 times Eₕ, respectively, and comprise catalyst reactions to form hydrino by accepting these energies from H to cause the formation of hydrinos.

### II. Hydrinos

A hydrogen atom having a binding energy given by

$${E}_{B} = \frac{13.6 eV}{{( 1 \text{/} p )}^{2}}$$

where p is an integer greater than 1, preferably from 2 to 137, is the product of the H catalysis reaction of the present disclosure. The binding energy of an atom, ion, or molecule, also known as the ionization energy, is the energy required to remove one electron from the atom, ion or molecule. A hydrogen atom having the binding energy given in Eqs. (10) and (12) is hereafter referred to as a “hydrino atom” or “hydrino.” The designation for a hydrino of radius

$$\frac{{a}_{H}}{p} ,$$

where a_{H} is the radius of an ordinary hydrogen atom and p is an integer, is

$$H [ \frac{{a}_{H}}{p} ] .$$

A hydrogen atom with a radius a_{H} is hereinafter referred to as “ordinary hydrogen atom” or “normal hydrogen atom.” Ordinary atomic hydrogen is characterized by its binding energy of 13.6 eV.

According to the present disclosure, a hydrino hydride ion (H⁻) having a binding energy according to Eq. (19) that is greater than the binding energy of ordinary hydride ion (about 0.75 eV) for p=2 up to 23, and less for p=24 (H⁻) is provided. For p=2 to p=24 of Eq. (19), the hydride ion binding energies are respectively 3, 6.6, 11.2, 16.7, 22.8, 29.3, 36.1, 42.8, 49.4, 55.5, 61.0, 65.6, 69.2, 71.6, 72.4, 71.6, 68.8, 64.0, 56.8, 47.1, 34.7, 19.3, and 0.69 eV. Exemplary compositions comprising the novel hydride ion are also provided herein.

Exemplary compounds are also provided comprising one or more hydrino hydride ions and one or more other elements. Such a compound is referred to as a “hydrino hydride compound.”

Ordinary hydrogen species are characterized by the following binding energies (a) hydride ion, 0.754 eV (“ordinary hydride ion”); (b) hydrogen atom (“ordinary hydrogen atom”), 13.6 eV; (c) diatomic hydrogen molecule, 15.3 eV (“ordinary hydrogen molecule”); (d) hydrogen molecular ion, 16.3 eV (“ordinary hydrogen molecular ion”); and (e) H₃⁻, 22.6 eV (“ordinary trihydrogen molecular ion”). Herein, with reference to forms of hydrogen, “normal” and “ordinary” are synonymous.

According to a further embodiment of the present disclosure, a compound is provided comprising at least one increased binding energy hydrogen species such as (a) a hydrogen atom having a binding energy of about

$$\frac{13.6 eV}{{( \frac{1}{p} )}^{2}} ,$$

such as within a range of about 0.9 to 1.1 times

$$\frac{13.6 eV}{{( \frac{1}{p} )}^{2}}$$

where p is an integer from 2 to 137; (b) a hydride ion (H⁻) having a binding energy of about

$$Binding Energy = \frac{{ℏ}^{2} \sqrt{s ( s + 1 )}}{8 {μ}_{e} {{a}_{0}^{2} [ \frac{1 + \sqrt{s ( s + 1 )}}{p} ]}^{2}} - \frac{{πμ}_{0} {e}^{2} {ℏ}^{2}}{{m}_{e}^{2}} ( \frac{1}{{a}_{H}^{3}} + \frac{{2}^{2}}{{{a}_{0}^{3} [ \frac{1 + \sqrt{s ( s + 1 )}}{p} ]}^{3}} ) ,$$

within a range of about 0.9 to 1.1 times

$$Binding Energy = \frac{{ℏ}^{2} \sqrt{s ( s + 1 )}}{8 {μ}_{e} {{a}_{0}^{2} [ \frac{1 + \sqrt{s ( s + 1 )}}{p} ]}^{2}} - \frac{{πμ}_{0} {e}^{2} {ℏ}^{2}}{{m}_{e}^{2}} ( \frac{1}{{a}_{H}^{3}} + \frac{{2}^{2}}{{{a}_{0}^{3} [ \frac{1 + \sqrt{s ( s + 1 )}}{p} ]}^{3}} )$$

where p is an integer from 2 to 24; (c) H₄⁺, 1/p; (d) a trihydrino molecular ion, H₃⁺ (1/p), having a binding energy of about

$$\frac{22.6}{{( \frac{1}{p} )}^{2}} eV$$

such as within a range of about 0.9 to 1.1 times

$$\frac{22.6}{{( \frac{1}{p} )}^{2}} eV$$

eV where p is an integer from 2 to 137; (e) a dihydrino having a binding energy of about

$$\frac{15.3}{{( \frac{1}{p} )}^{2}} eV$$

such as within a range of about 0.9 to 1.1 times

$$\frac{15.3}{{( \frac{1}{p} )}^{2}} eV$$

where p is an integer from 2 to 137; (f) a dihydrino molecular ion with a binding energy of about

$$\frac{16.3}{{( \frac{1}{p} )}^{2}} eV$$

such as within a range of about 0.9 to 1.1 times

$$\frac{16.3}{{( \frac{1}{p} )}^{2}} eV$$

where p is an integer, preferably an integer from 2 to 137.

According to a further embodiment of the present disclosure, a compound is provided comprising at least one increased binding energy hydrogen species such as (a) a dihydrino molecular ion having a total energy of about

$$\begin{matrix}{E}_{T} = - {p}^{2} \{ \begin{matrix}\frac{{e}^{2}}{8 {πɛ}_{o} {a}_{H}} ( 4 ln 3 - 1 - 2 ln 3 ) [ 1 + p \sqrt{\frac{2 ℏ \sqrt{\frac{2 {e}^{2}}{\frac{4 {{πɛ}_{o} ( 2 {a}_{H} )}^{3}}{{m}_{e}}}}}{{m}_{e} {c}^{2}}} ] - \\ \frac{1}{2} ℏ \sqrt{\frac{\frac{{pe}^{2}}{4 {{πɛ}_{o} ( \frac{2 {a}_{H}}{p} )}^{3}} - \frac{{pe}^{2}}{8 {{πɛ}_{o} ( \frac{3 {a}_{H}}{p} )}^{3}}}{μ}} \end{matrix} \} \\ = - {p}^{2} 16.13392 eV - {p}^{3} 0.118755 eV\end{matrix}$$

such as within a range of about 0.9 to 1.1 times

$$\begin{matrix}{E}_{T} = - {p}^{2} \{ \begin{matrix}\frac{{e}^{2}}{8 π {ɛ}_{o} {a}_{H}} ( 4 ln 3 - 1 - 2 ln 3 ) [ 1 + p \sqrt{\frac{2 ℏ \sqrt{\frac{\frac{2 {e}^{2}}{4 π {{ɛ}_{o} ( 2 {a}_{H} )}^{3}}}{{m}_{e}}}}{{m}_{e} {c}^{2}}} ] - \\ \frac{1}{2} ℏ \sqrt{\frac{\frac{{pe}^{2}}{4 π {{ɛ}_{o} ( \frac{2 {a}_{H}}{p} )}^{3}} - \frac{{pe}^{2}}{8 π {{ɛ}_{o} ( \frac{3 {a}_{H}}{p} )}^{3}}}{μ}}\end{matrix} \} \\ = - {p}^{2} 16.13392 eV - {p}^{3} 0.118755 eV\end{matrix}$$

where p is an integer, ℏ is Planck's constant bar, mₑ is the mass of the electron, c is the speed of light in vacuum, and μ is the reduced nuclear mass, and (b) a dihydrino molecule having a total energy of about

$$\begin{matrix}{E}_{T} = - {p}^{2} \{ \begin{matrix}\frac{{e}^{2}}{8 {πɛ}_{o} {a}_{H}} [ ( 2 \sqrt{2} - \sqrt{2} + \frac{\sqrt{2}}{2} ) ln \frac{\sqrt{2} + 1}{\sqrt{2} - 1} - \sqrt{2} ] [ 1 + p \sqrt{\frac{2 ℏ \sqrt{\frac{{e}^{2}}{\frac{4 {πɛ}_{o} {a}_{0}^{3}}{{m}_{e}}}}}{{m}_{e} {c}^{2}}} ] - \\ \frac{1}{2} ℏ \sqrt{\frac{\frac{{pe}^{2}}{8 {{πɛ}_{o} ( \frac{{a}_{0}}{p} )}^{3}} - \frac{{pe}^{2}}{8 {{πɛ}_{o} ( \frac{( 1 + \frac{1}{\sqrt{2}} ) {a}_{0}}{p} )}^{3}}}{μ}} \end{matrix} \} \\ = - {p}^{2} 31.351 eV - {p}^{3} 0.326469 eV\end{matrix}$$

such as within a range of about 0.9 to 1.1 times

$$\begin{matrix}{E}_{T} = - {p}^{2} \{ \begin{matrix}\frac{{e}^{2}}{8 {πɛ}_{o} {a}_{0}} [ ( 2 \sqrt{2} - \sqrt{2} + \frac{\sqrt{2}}{2} ) ln \frac{\sqrt{2} + 1}{\sqrt{2} - 1} - \sqrt{2} ] [ 1 + p \sqrt{\frac{2 ℏ \sqrt{\frac{{e}^{2}}{\frac{4 {πɛ}_{o} {a}_{0}^{3}}{{m}_{e}}}}}{{m}_{e} {c}^{2}}} ] - \\ \frac{1}{2} ℏ \sqrt{\frac{\frac{{pe}^{2}}{8 {{πɛ}_{o} ( \frac{{a}_{0}}{p} )}^{3}} - \frac{{pe}^{2}}{8 {{πɛ}_{o} ( \frac{( 1 + \frac{1}{\sqrt{2}} ) {a}_{0}}{p} )}^{3}}}{μ}} \end{matrix} \} \\ = - {p}^{2} 31.351 eV - {p}^{3} 0.326469 eV\end{matrix}$$

where p is an integer and aₒ is the Bohr radius.

According to one embodiment of the present disclosure wherein the compound comprises a negatively charged increased binding energy hydrogen species, the compound further comprises one or more cations, such as a proton, ordinary H₂⁺, or ordinary H₃⁺.

A method is provided herein for preparing compounds comprising at least one hydrino hydride ion. Such compounds are hereinafter referred to as “hydrino hydride compounds.” The method comprises reacting atomic hydrogen with a catalyst having a net enthalpy of reaction of about

$$\frac{m}{2} \cdot 27 eV ,$$

where m is an integer greater than 1, preferably an integer less than 400, to produce an increased binding energy hydrogen atom having a binding energy of about

$$\frac{13.6 eV}{{( \frac{1}{p} )}^{2}}$$

where p is an integer, preferably an integer from 2 to 137.
A further product of the catalysis is energy. The increased binding energy hydrogen atom can be reacted with an electron source, to produce an increased binding energy hydride ion. The increased binding energy hydride ion can be reacted with one or more cations to produce a compound comprising at least one increased binding energy hydride ion.

In an embodiment, at least one of very high power and energy may be achieved by the hydrogen undergoing transitions to hydrinos of high p values in Eq. (18) in a process herein referred to as disproportionation as given in Mills GUTCP Chp. 5 which is incorporated by reference. Hydrogen atoms H (1/p) p=1, 2, 3, . . . 137 can undergo further transitions to lower-energy states given by Eqs. (10) and (12) wherein the transition of one atom is catalyzed by a second that resonantly and nonradiatively accepts m·27.2 eV with a concomitant opposite change in its potential energy. The overall general equation for the transition of H(1/p) to H(1/(p+m)) induced by a resonance transfer of m·27.2 eV to H(1/p′) given by Eq. (32) is represented by

H(1/p′)+H(1/p)→H+H(1/(p+m))+[2pm+m²−p′²+1]·13.6 eV (32)

The EUV light from the hydrino process may dissociate the dihydrino molecules and the resulting hydrino atoms may serve as catalysts to transition to lower energy states. An exemplary reaction comprises the catalysis of H to H( 1/17) by H(¼) wherein H(¼) may be a reaction product of the catalysis of another H by HOH. Disproportionation reactions of hydrinos are predicted to give rise to features in the X-ray region. As shown by Eqs. (5-8) the reaction product of HOH catalyst is

$$H [ \frac{{a}_{H}}{4} ] .$$

Consider a likely transition reaction in hydrogen clouds containing H₂O gas wherein the first hydrogen-type atom

$$H [ \frac{{a}_{H}}{p} ]$$

is an H atom and the second acceptor hydrogen-type atom

$$H [ \frac{{a}_{H}}{{p}^{′}} ]$$

serving as a catalyst is

$$H [ \frac{{a}_{H}}{4} ]$$

Since the potential energy of

$$H [ \frac{{a}_{H}}{4} ]$$

is 4²·27.2 eV=16·27.2 eV=435.2 eV, the transition reaction is represented by

$$\begin{matrix}16 \cdot 27.2 eV + H [ \frac{{a}_{H}}{4} ] + H [ \frac{{a}_{H}}{1} ] \to {H}_{fast}^{+} + {e}^{-} + H * [ \frac{{a}_{H}}{17} ] + 16 \cdot 27.2 eV & ( 33 ) \\ H * [ \frac{{a}_{H}}{17} ] \to H [ \frac{{a}_{H}}{17} ] + 3481.6 eV & ( 34 ) \\ {H}_{fast}^{+} + {e}^{-} \to H [ \frac{{a}_{H}}{1} ] + 231.2 eV & ( 35 )\end{matrix}$$

And, the overall reaction is

$$H [ \frac{{a}_{H}}{4} ] + H [ \frac{{a}_{H}}{1} ] \to H [ \frac{{a}_{H}}{1} ] + H [ \frac{{a}_{H}}{17} ] + 3712.8 eV \qquad ( 36 )$$

The extreme-ultraviolet continuum radiation band due to the

$$H * [ \frac{{a}_{H}}{p + m} ]$$

intermediate (e.g. Eq. (16) and Eq. (34)) is predicted to have a short wavelength cutoff and energy

$${E}_{( H \to H [ \frac{{a}_{H}}{4} ] )}$$

given by

$${E}_{( H \to H [ \frac{{a}_{H}}{p + m} ] )} = [ {( p + m )}^{2} - {p}^{2} ] \cdot 13.6 eV - m \cdot 27.2 eV \\ {λ}_{( H \to H [ \frac{{a}_{H}}{p + m} ] )} = \frac{91.2}{[ {( p + m )}^{2} - {p}^{2} ] \cdot 13.6 eV - m \cdot 27.2 eV} nm \qquad ( 37 )$$

and extending to longer wavelengths than the corresponding cutoff. Here the extreme-ultraviolet continuum radiation band due to the decay of the

$$H * [ \frac{{a}_{H}}{17} ]$$

intermediate is predicted to have a short wavelength cutoff at E=3481.6 eV; 0.35625 nm and extending to longer wavelengths. A broad X-ray peak with a 3.48 keV cutoff was observed in the Perseus Cluster by NASA's Chandra X-ray Observatory and by the XMM-Newton [E. Bulbul, M. Markevitch, A. Foster, R. K. Smith, M. Loewenstein, S. W. Randall, “Detection of an unidentified emission line in the stacked X-Ray spectrum of galaxy clusters,” The Astrophysical Journal, Volume 789, Number 1, (2014); A. Boyarsky, O. Ruchayskiy, D. Iakubovskyi, J. Franse, “An unidentified line in X-ray spectra of the Andromeda galaxy and Perseus galaxy cluster,” (2014), arXiv:1402.4119 [astro-ph.CO]] that has no match to any known atomic transition. The 3.48 keV feature assigned to dark matter of unknown identity by BulBul et al. matches the

$$H [ \frac{{a}_{H}}{4} ] + H [ \frac{{a}_{H}}{1} ] \to H [ \frac{{a}_{H}}{17} ]$$

transition and further confirms hydrinos as the identity of dark matter.

The novel hydrogen compositions of matter can comprise:

(a) at least one neutral, positive, or negative hydrogen species (hereinafter “increased binding energy hydrogen species”) having a binding energy

(i) greater than the binding energy of the corresponding ordinary hydrogen species, or

(ii) greater than the binding energy of any hydrogen species for which the corresponding ordinary hydrogen species is unstable or is not observed because the ordinary hydrogen species' binding energy is less than thermal energies at ambient conditions (standard temperature and pressure, STP), or is negative; and

(b) at least one other element. Typically, the hydrogen products described herein are increased binding energy hydrogen species.

By “other element” in this context is meant an element other than an increased binding energy hydrogen species. Thus, the other element can be an ordinary hydrogen species, or any element other than hydrogen. In one group of compounds, the other element and the increased binding energy hydrogen species are neutral. In another group of compounds, the other element and increased binding energy hydrogen species are charged such that the other element provides the balancing charge to form a neutral compound. The former group of compounds is characterized by molecular and coordinate bonding; the latter group is characterized by ionic bonding.

Also provided are novel compounds and molecular ions comprising

(a) at least one neutral, positive, or negative hydrogen species (hereinafter “increased binding energy hydrogen species”) having a total energy

(i) greater than the total energy of the corresponding ordinary hydrogen species, or

(ii) greater than the total energy of any hydrogen species for which the corresponding ordinary hydrogen species is unstable or is not observed because the ordinary hydrogen species' total energy is less than thermal energies at ambient conditions, or is negative; and

(b) at least one other element.

The total energy of the hydrogen species is the sum of the energies to remove all of the electrons from the hydrogen species. The hydrogen species according to the present disclosure has a total energy greater than the total energy of the corresponding ordinary hydrogen species. The hydrogen species having an increased total energy according to the present disclosure is also referred to as an “increased binding energy hydrogen species” even though some embodiments of the hydrogen species having an increased total energy may have a first electron binding energy less than the first electron binding energy of the corresponding ordinary hydrogen species. For example, the hydride ion of Eq. (19) for p=24 has a first binding energy that is less than the first binding energy of ordinary hydride ion, while the total energy of the hydride ion of Eq. (19) for p=24 is much greater than the total energy of the corresponding ordinary hydride ion.

Also provided herein are novel compounds and molecular ions comprising

(a) a plurality of neutral, positive, or negative hydrogen species (hereinafter “increased binding energy hydrogen species”) having a binding energy

(i) greater than the binding energy of the corresponding ordinary hydrogen species, or

(ii) greater than the binding energy of any hydrogen species for which the corresponding ordinary hydrogen species is unstable or is not observed because the ordinary hydrogen species' binding energy is less than thermal energies at ambient conditions or is negative; and

(b) optionally one other element. The compounds of the present disclosure are hereinafter referred to as “increased binding energy hydrogen compounds.”

The increased binding energy hydrogen species can be formed by reacting one or more hydrino atoms with one or more of an electron, hydrino atom, a compound containing at least one of said increased binding energy hydrogen species, and at least one other atom, molecule, or ion other than an increased binding energy hydrogen species.

Also provided are novel compounds and molecular ions comprising

(a) a plurality of neutral, positive, or negative hydrogen species (hereinafter “increased binding energy hydrogen species”) having a total energy

(i) greater than the total energy of ordinary molecular hydrogen, or

(ii) greater than the total energy of any hydrogen species for which the corresponding ordinary hydrogen species is unstable or is not observed because the ordinary hydrogen species' total energy is less than thermal energies at ambient conditions or is negative; and

(b) optionally one other element. The compounds of the present disclosure are hereinafter referred to as “increased binding energy hydrogen compounds.”

In an embodiment, a compound is provided comprising at least one increased binding energy hydrogen species chosen from (a) hydride ion having a binding energy according to Eq. (19) that is greater than the binding energy of ordinary hydride ion (about 0.8 eV) for p=2 up to 23, and less for p=24 (“increased binding energy hydride ion” or “hydrino hydride ion”); (b) hydrogen atom having a binding energy greater than the binding energy of ordinary hydrogen atom (about 13.6 eV) (“increased binding energy hydrogen atom” or “hydrino”); (c) hydrogen molecule having a first binding energy greater than about 15.3 eV (“increased binding energy hydrogen molecule” or “dihydrino”); and (d) molecular hydrogen ion having a binding energy greater than about 16.3 eV (“increased binding energy molecular hydrogen ion” or “dihydrino molecular ion”). In the disclosure, increased binding energy hydrogen species and compounds is also referred to as lower-energy hydrogen species and compounds. Hydrinos comprise an increased binding energy hydrogen species or equivalently a lower-energy hydrogen species.

### III. Chemical Reactor

The present disclosure is also directed to other reactors for producing increased binding energy hydrogen species and compounds of the present disclosure, such as dihydrino molecules and hydrino hydride compounds. Further products of the catalysis are power and optionally plasma and light depending on the cell type. Such a reactor is hereinafter referred to as a “hydrogen reactor” or “hydrogen cell.” The hydrogen reactor comprises a cell for making hydrinos. The cell for making hydrinos may take the form of a chemical reactor or gas fuel cell such as a gas discharge cell, a plasma torch cell, or microwave power cell, and an electrochemical cell. In an embodiment, the catalyst is HOH and the source of at least one of the HOH and H is ice. The ice may have a high surface area to increase at least one of the rates of the formation of HOH catalyst and H from ice and the hydrino reaction rate. The ice may be in the form of fine chips to increase the surface area. In an embodiment, the cell comprises an arc discharge cell that comprises ice and at least one electrode such that the discharge involves at least a portion of the ice.

In an embodiment, the arc discharge cell comprises a vessel, two electrodes, a high voltage power source such as one capable of a voltage in the range of about 100 V to 1 MV and a current in the range of about 1 A to 100 kA, and a source of water such as a reservoir and a means to form and supply H₂O droplets. The droplets may travel between the electrodes. In an embodiment, the droplets initiate the ignition of the arc plasma. In an embodiment, the water arc plasma comprises H and HOH that may react to form hydrinos. The ignition rate and the corresponding power rate may be controlled by controlling the size of the droplets and the rate at which they are supplied to the electrodes. The source of high voltage may comprise at least one high voltage capacitor that may be charged by a high voltage power source. In an embodiment, the arc discharge cell further comprises a means such as a power converter such as one of the present invention such as at least one of a PV converter and a heat engine to convert the power from the hydrino process such as light and heat to electricity.

Exemplary embodiments of the cell for making hydrinos may take the form of a liquid-fuel cell, a solid-fuel cell, a heterogeneous-fuel cell, a CIHT cell, and an SF-CIHT or SunCell® cell. Each of these cells comprises: (i) reactants including a source of atomic hydrogen; (ii) at least one catalyst chosen from a solid catalyst, a molten catalyst, a liquid catalyst, a gaseous catalyst, or mixtures thereof for making hydrinos; and (iii) a vessel for reacting hydrogen and the catalyst for making hydrinos. As used herein and as contemplated by the present disclosure, the term “hydrogen,” unless specified otherwise, includes not only protium (¹H), but also deuterium (²H) and tritium (³H). Exemplary chemical reaction mixtures and reactors may comprise SF-CIHT, CIHT, or thermal cell embodiments of the present disclosure. Additional exemplary embodiments are given in this Chemical Reactor section. Examples of reaction mixtures having H₂O as catalyst formed during the reaction of the mixture are given in the present disclosure. Other catalysts may serve to form increased binding energy hydrogen species and compounds. The reactions and conditions may be adjusted from these exemplary cases in the parameters such as the reactants, reactant wt %'s, H₂ pressure, and reaction temperature. Suitable reactants, conditions, and parameter ranges are those of the present disclosure. Hydrinos and molecular hydrino are shown to be products of the reactors of the present disclosure by predicted continuum radiation bands of an integer times 13.6 eV, otherwise unexplainable extraordinarily high H kinetic energies measured by Doppler line broadening of H lines, inversion of H lines, formation of plasma without a breakdown field, and anomalously plasma afterglow duration as reported in Mills Prior Publications. The data such as that regarding the CIHT cell and solid fuels has been validated independently, off site by other researchers. The formation of hydrinos by cells of the present disclosure was also confirmed by electrical energies that were continuously output over long-duration, that were multiples of the electrical input that in most cases exceed the input by a factor of greater than 10 with no alternative source. The predicted molecular hydrino H₂(¼) was identified as a product of CIHT cells and solid fuels by MAS H NMR that showed a predicted upfield shifted matrix peak of about −4.4 ppm, ToF-SIMS and ESI-ToFMS that showed H₂(¼) complexed to a getter matrix as m/e=M+n2 peaks wherein M is the mass of a parent ion and n is an integer, electron-beam excitation emission spectroscopy and photoluminescence emission spectroscopy that showed the predicted rotational and vibration spectrum of H₂(¼) having 16 or quantum number p=4 squared times the energies of H₂, Raman and FTIR spectroscopy that showed the rotational energy of H₂(¼) of 1950 cm¹, being 16 or quantum number p=4 squared times the rotational energy of H₂, XPS that showed the predicted total binding energy of H₂(¼) of 500 eV, and a ToF-SIMS peak with an arrival time before the m/e=1 peak that corresponded to H with a kinetic energy of about 204 eV that matched the predicted energy release for H to H(¼) with the energy transferred to a third body H as reported in Mills Prior Publications and in R. Mills X Yu, Y. Lu, G Chu, J. He, J. Lotoski, “Catalyst Induced Hydrino Transition (CIHT) Electrochemical Cell”, International Journal of Energy Research, (2013) and R. Mills, J. Lotoski, J. Kong, G Chu, J. He, J. Trevey, “High-Power-Density Catalyst Induced Hydrino Transition (CIHT) Electrochemical Cell” (2014) which are herein incorporated by reference in their entirety.

Using both a water flow calorimeter and a Setaram DSC 131 differential scanning calorimeter (DSC), the formation of hydrinos by cells of the present disclosure such as ones comprising a solid fuel to generate thermal power was confirmed by the observation of thermal energy from hydrino-forming solid fuels that exceed the maximum theoretical energy by a factor of 60 times. The MAS H NMR showed a predicted H₂(¼) upfield matrix shift of about −4.4 ppm. A Raman peak starting at 1950 cm¹ matched the free space rotational energy of H₂(¼) (0.2414 eV). These results are reported in Mills Prior Publications and in R. Mills, J. Lotoski, W. Good, J. He, “Solid Fuels that Form HOH Catalyst”, (2014) which is herein incorporated by reference in its entirety.

### IV. SunCell and Power Converter

Power system (also referred to herein as “SunCell”) that generates at least one of electrical energy and thermal energy may comprise:

a vessel capable of maintaining a pressure below atmospheric;

reactants capable of undergoing a reaction that produces enough energy to form a plasma in the vessel comprising:

a) a mixture of hydrogen gas and oxygen gas, and/or water vapor, and/or
a mixture of hydrogen gas and water vapor;

b) a molten metal;

a mass flow controller to control the flow rate of at least one reactant into the vessel;

a vacuum pump to maintain the pressure in the vessel below atmospheric pressure when one or more reactants are flowing into the vessel;

a molten metal injector system comprising at least one reservoir that contains some of the molten metal, a molten metal pump system (e.g., one or more electromagnetic pumps) configured to deliver the molten metal in the reservoir and through an injector tube to provide a molten metal stream, and at least one non-injector molten metal reservoir for receiving the molten metal stream;

at least one ignition system comprising a source of electrical power or ignition current to supply electrical power to the at least one stream of molten metal to ignite the reaction when the hydrogen gas and/or oxygen gas and/or water vapor are flowing into the vessel;

a reactant supply system to replenish reactants that are consumed in the reaction; and

a power converter or output system to convert a portion of the energy produced from the reaction (e.g., light and/or thermal output from the plasma) to electrical power and/or thermal power.

In some embodiments, the power system may comprise an optical rectenna such as the one reported by A. Sharma, V. Singh, T. L. Bougher, B. A. Cola, “A carbon nanotube optical rectenna”, Nature Nanotechnology, Vol. 10, (2015), pp. 1027-1032, doi:10.1038/nnano.2015.220 which is incorporated by reference in its entirety, and at least one thermal to electric power converter. In a further embodiment, the vessel is capable of a pressure of at least one of atmospheric, above atmospheric, and below atmospheric. In another embodiment, the at least one direct plasma to electricity converter can comprise at least one of the group of plasmadynamic power converter, \vec{E}×\vec{B} direct converter, magnetohydrodynamic power converter, magnetic mirror magnetohydrodynamic power converter, charge drift converter, Post or Venetian Blind power converter, gyrotron, photon bunching microwave power converter, and photoelectric converter. In a further embodiment, the at least one thermal to electricity converter can comprise at least one of the group of a heat engine, a steam engine, a steam turbine and generator, a gas turbine and generator, a Rankine-cycle engine, a Brayton-cycle engine, a Stirling engine, a thermionic power converter, and a thermoelectric power converter. Exemplary thermal to electric systems that may comprise closed coolant systems or open systems that reject heat to the ambient atmosphere are supercritical CO₂, organic Rankine, or external combustor gas turbine systems.

In addition to UV photovoltaic and thermal photovoltaic of the current disclosure, the SunCell® may comprise other electric conversion means known in the art such as thermionic, magnetohydrodynamic, turbine, microturbine, Rankine or Brayton cycle turbine, chemical, and electrochemical power conversion systems. The Rankine cycle turbine may comprise supercritical CO₂, an organic such as hydrofluorocarbon or fluorocarbon, or steam working fluid. In a Rankine or Brayton cycle turbine, the SunCell® may provide thermal power to at least one of the preheater, recuperator, boiler, and external combustor-type heat exchanger stage of a turbine system. In an embodiment, the Brayton cycle turbine comprises a SunCell® turbine heater integrated into the combustion section of the turbine. The SunCell® turbine heater may comprise ducts that receive airflow from at least one of the compressor and recuperator wherein the air is heated and the ducts direct the heated compressed flow to the inlet of the turbine to perform pressure-volume work. The SunCell® turbine heater may replace or supplement the combustion chamber of the gas turbine. The Rankine or Brayton cycle may be closed wherein the power converter further comprises at least one of a condenser and a cooler.

The converter may be one given in Mills Prior Publications and Mills Prior Applications. The hydrino reactants such as H sources and HOH sources and SunCell® systems may comprise those of the present disclosure or in prior US Patent Applications such as Hydrogen Catalyst Reactor, PCT/US08/61455, filed PCT 4/24/2008; Heterogeneous Hydrogen Catalyst Reactor, PCT/US09/052072, filed PCT 7/29/2009; Heterogeneous Hydrogen Catalyst Power System, PCT/US10/27828, PCT filed Mar. 18, 2010; Electrochemical Hydrogen Catalyst Power System, PCT/US11/28889, filed PCT 3/17/2011; H₂O-Based Electrochemical Hydrogen-Catalyst Power System, PCT/US12/31369 filed Mar. 30, 2012; CIHT Power System, PCT/US13/041938 filed May 21, 2013; Power Generation Systems and Methods Regarding Same, PCT/IB2014/058177 filed PCT 1/10/2014; Photovoltaic Power Generation Systems and Methods Regarding Same, PCT/US14/32584 filed PCT 4/1/2014; Electrical Power Generation Systems and Methods Regarding Same, PCT/US2015/033165 filed PCT 5/29/2015; Ultraviolet Electrical Generation System Methods Regarding Same, PCT/US2015/065826 filed PCT 12/15/2015; Thermophotovoltaic Electrical Power Generator, PCT/US16/12620 filed PCT 1/8/2016; Thermophotovoltaic Electrical Power Generator Network, PCT/US2017/035025 filed PCT 12/7/2017; Thermophotovoltaic Electrical Power Generator, PCT/US2017/013972 filed PCT 1/18/2017; Extreme and Deep Ultraviolet Photovoltaic Cell, PCT/US2018/012635 filed PCT 01/05/2018; Magnetohydrodynamic Electric Power Generator, PCT/US18/17765 filed PCT 2/12/2018; Magnetohydrodynamic Electric Power Generator, PCT/US2018/034842 filed PCT 5/29/18; and Magnetohydrodynamic Electric Power Generator, PCT/IB2018/059646 filed PCT 12/05/18 (“Mills Prior Applications”) herein incorporated by reference in their entirety.

In an embodiment, H₂O is ignited to form hydrinos with a high release of energy in the form of at least one of thermal, plasma, and electromagnetic (light) power. (“Ignition” in the present disclosure denotes a very high reaction rate of H to hydrinos that may be manifest as a burst, pulse or other form of high power release.) H₂O may comprise the fuel that may be ignited with the application of a high current such as one in the range of about 10 A to 100,000 A. This may be achieved by the application of a high voltage such as about 5,000 to 100,000 V to first form highly conducive plasma such as an arc. Alternatively, a high current may be passed through a conductive matrix such as a molten metal such as silver further comprising the hydrino reactants such as H and HOH, or a compound or mixture comprising H₂O wherein the conductivity of the resulting fuel such as a solid fuel is high. In the present disclosure a solid fuel is used to denote a reaction mixture that forms a catalyst such as HOH and H that further reacts to form hydrinos. The plasma voltage may be low such as in the range of about 1 V to 100V. However, the reaction mixture may comprise other physical states than solid. In embodiments, the reaction mixture may be at least one state of gaseous, liquid, molten matrix such as molten conductive matrix such as a molten metal such as at least one of molten silver, silver-copper alloy, and copper, solid, slurry, sol gel, solution, mixture, gaseous suspension, pneumatic flow, and other states known to those skilled in the art.) In an embodiment, the solid fuel having a very low resistance comprises a reaction mixture comprising H₂O. The low resistance may be due to a conductor component of the reaction mixture. In embodiments, the resistance of the solid fuel is at least one of in the range of about 10⁻⁹ ohm to 100 ohms, 10⁻⁸ ohm to 10 ohms, 10⁻³ ohm to 1 ohm, 10⁻⁴ ohm to 10⁻¹ ohm, and 10⁻⁴ ohm to 10⁻² ohm. In another embodiment, the fuel having a high resistance comprises H₂O comprising a trace or minor mole percentage of an added compound or material. In the latter case, high current may be flowed through the fuel to achieve ignition by causing breakdown to form a highly conducting state such as an arc or arc plasma.

In an embodiment, the reactants can comprise a source of H₂O and a conductive matrix to form at least one of the source of catalyst, the catalyst, the source of atomic hydrogen, and the atomic hydrogen. In a further embodiment, the reactants comprising a source of H₂O can comprise at least one of bulk H₂O, a state other than bulk H₂O, a compound or compounds that undergo at least one of react to form H₂O and release bound H₂O. Additionally, the bound H₂O can comprise a compound that interacts with H₂O wherein the H₂O is in a state of at least one of absorbed H₂O, bound H₂O, physisorbed H₂O, and waters of hydration. In embodiments, the reactants can comprise a conductor and one or more compounds or materials that undergo at least one of release of bulk H₂O, absorbed H₂O, bound H₂O, physisorbed H₂O, and waters of hydration, and have H₂O as a reaction product. In other embodiments, the at least one of the source of nascent H₂O catalyst and the source of atomic hydrogen can comprise at least one of: (a) at least one source of H₂O; (b) at least one source of oxygen, and (c) at least one source of hydrogen.

In an embodiment, the hydrino reaction rate is dependent on the application or development of a high current. In an embodiment of a SunCell®, the reactants to form hydrinos are subject to a low voltage, high current, high power pulse that causes a very rapid reaction rate and energy release. In an exemplary embodiment, a 60 Hz voltage is less than 15 V peak, the current ranges from 100 A/cm² and 50,000 A/cm² peak, and the power ranges from 1000 W/cm² and 750,000 W/cm². Other frequencies, voltages, currents, and powers in ranges of about 1/100 times to 100 times these parameters are suitable. In an embodiment, the hydrino reaction rate is dependent on the application or development of a high current. In an embodiment, the voltage is selected to cause a high AC, DC, or an AC-DC mixture of current that is in the range of at least one of 100 A to 1,000,000 A, 1 kA to 100,000 A, 10 kA to 50 kA. The DC or peak AC current density may be in the range of at least one of 100 A/cm² to 1,000,000 A/cm², 1000 A/cm² to 100,000 A/cm², and 2000 A/cm² to 50,000 A/cm². The DC or peak AC voltage may be in at least one range chosen from about 0.1 V to 1000 V, 0.1 V to 100 V, 0.1 V to 15 V, and 1 V to 15 V. The AC frequency may be in the range of about 0.1 Hz to 10 GHz, 1 Hz to 1 MHz, 10 Hz to 100 kHz, and 100 Hz to 10 kHz. The pulse time may be in at least one range chosen from about 10⁻⁶ s to 10 s, 10⁻⁵ s to 1 s, 10⁻⁴ s to 0.1 s, and 10⁻³ s to 0.01 s.

In an embodiment, the transfer of energy from atomic hydrogen catalyzed to a hydrino state results in the ionization of the catalyst. The electrons ionized from the catalyst may accumulate in the reaction mixture and vessel and result in space charge build up. The space charge may change the energy levels for subsequent energy transfer from the atomic hydrogen to the catalyst with a reduction in reaction rate. In an embodiment, the application of the high current removes the space charge to cause an increase in hydrino reaction rate. In another embodiment, the high current such as an arc current causes the reactant such as water that may serve as a source of H and HOH catalyst to be extremely elevated in temperature. The high temperature may give rise to the thermolysis of the water to at least one of H and HOH catalyst. In an embodiment, the reaction mixture of the SunCell® comprises a source of H and a source of catalyst such as at least one of nH (n is an integer) and HOH. The at least one of nH and HOH may be formed by the thermolysis or thermal decomposition of at least one physical phase of water such as at least one of solid, liquid, and gaseous water. The thermolysis may occur at high temperature such as a temperature in at least one range of about 500K to 10,000K, 1000K to 7000K, and 1000K to 5000K. In an exemplary embodiment, the reaction temperature is about 3500 to 4000K such that the mole fraction of atomic H is high as shown by J. Lede, F. Lapicque, and J Villermaux [J. Lede, F. Lapicque, J. Villermaux, “Production of hydrogen by direct thermal decomposition of water”, International Journal of Hydrogen Energy, 1983, V8, 1983, pp. 675-679; H. H. G. Jellinek, H. Kachi, “The catalytic thermal decomposition of water and the production of hydrogen”, International Journal of Hydrogen Energy, 1984, V9, pp. 677-688; S. Z. Baykara, “Hydrogen production by direct solar thermal decomposition of water, possibilities for improvement of process efficiency”, International Journal of Hydrogen Energy, 2004, V29, pp. 1451-1458; S. Z. Baykara, “Experimental solar water thermolysis”, International Journal of Hydrogen Energy, 2004, V29, pp. 1459-1469 which are herein incorporated by reference]. The thermolysis may be assisted by a solid surface such as one of the cell compoments. The solid surface may be heated to an elevated temperature by the input power and by the plasma maintained by the hydrino reaction. The thermolysis gases such as those down stream of the ignition region may be cooled to prevent recombination or the back reaction of the products into the starting water. The reaction mixture may comprise a cooling agent such as at least one of a solid, liquid, or gaseous phase that is at a lower temperature than the temperature of the product gases. The cooling of the thermolysis reaction product gases may be achieved by contacting the products with the cooling agent. The cooling agent may comprise at least one of lower temperature steam, water, and ice.

In an embodiment, the fuel or reactants may comprise at least one of a source of H, H₂, a source of catalyst, a source of H₂O, and H₂O. Suitable reactants may comprise a conductive metal matrix and a hydrate such as at least one of an alkali hydrate, an alkaline earth hydrate, and a transition metal hydrate. The hydrate may comprise at least one of MgCl₂.6H₂O, BaI₂.2H₂O, and ZnCl₂.4H₂O. Alternatively, the reactants may comprise at least one of silver, copper, hydrogen, oxygen, and water.

In an embodiment, the reaction cell chamber 5b31 may be operated under low pressure to achieve high gas temperature. Then the pressure may be increased by a reaction mixture gas source and controller to increase reaction rate wherein the high temperature maintains nascent HOH and atomic H by thermolysis of at least one of H bonds of water dimers and H₂ covalent bonds. An exemplary threshold gas temperature to achieve thermolysis is about 3300° C. A plasma having a higher temperature than about 3300° C. may break H₂O dimer bonds to form nascent HOH to serve as the hydrino catalyst. At least one of the reaction cell chamber H₂O vapor pressure, H₂ pressure, and O₂ pressure may be in at least one range of about 0.01 Torr to 100 atm, 0.1 Torr to 10 atm, and 0.5 Torr to 1 atm. The EM pumping rate may be in at least one range of about 0.01 ml/s to 10,000 ml/s, 0.1 ml/s to 1000 ml/s, and 0.1 ml/s to 100 ml/s. In embodiment, at least one of a high ignition power and a low pressure may be maintained initially to heat the plasma and the cell to achieve thermolysis. The initial power may comprise at least one of high frequency pulses, pulses with a high duty cycle, higher voltage, and higher current, and continuous current. In an embodiment, at least one of the ignition power may be reduced, and the pressure may be increased following heating of the plasma and cell to achieve thermolysis. In another embodiment, the SunCell® may comprise an additional plasma source such as a plasma torch, glow discharge, microwave, or RF plasma source for heating of the hydrino reaction plasma and cell to achieve thermolysis.

In an embodiment, the ignition system comprises a switch to at least one of initiate the current and interrupt the current once ignition is achieved. The flow of current may be initiated by the contact of the molten metal streams. The switching may be performed electronically by means such as at least one of an insulated gate bipolar transistor (IGBT), a silicon-controlled rectifier (SCR), and at least one metal oxide semiconductor field effect transistor (MOSFET). Alternatively, ignition may be switched mechanically. The current may be interrupted following ignition in order to optimize the output hydrino generated energy relative to the input ignition energy. The ignition system may comprise a switch to allow controllable amounts of energy to flow into the fuel to cause detonation and turn off the power during the phase wherein plasma is generated. In an embodiment, the source of electrical power to deliver a short burst of high-current electrical energy comprises at least one of the following:

a voltage selected to cause a high AC, DC, or an AC-DC mixture of current that is in the range of at least one of 100 A to 1,000,000 A, 1 kA to 100,000 A, 10 kA to 50 kA;

a DC or peak AC current density in the range of at least one of 1 A/cm² to 1,000,000 A/cm², 1000 A/cm² to 100,000 A/cm², and 2000 A/cm² to 50,000 A/cm²;

wherein the voltage is determined by the conductivity of the solid fuel wherein the voltage is given by the desired current times the resistance of the solid fuel sample;

the DC or peak AC voltage is in the range of at least one of 0.1 V to 500 kV, 0.1 V to 100 kV, and 1 V to 50 kV, and

the AC frequency is in range of at least one of 0.1 Hz to 10 GHz, 1 Hz to 1 MHz, 10 Hz to 100 kHz, and 100 Hz to 10 kHz.

The system further comprises a startup power/energy source such as a battery such as a lithium ion battery. Alternatively, external power such as grid power may be provided for startup through a connection from an external power source to the generator. The connection may comprise the power output bus bar. The startup power energy source may at least one of supply power to the heater to maintain the molten metal conductive matrix, power the injection system, and power the ignition system.

The SunCell® may comprise a high-pressure water electrolyzer such as one comprising a proton exchange membrane (PEM) electrolyzer having water under high pressure to provide high-pressure hydrogen. Each of the H₂ and O₂ chambers may comprise a recombiner to eliminate contaminant O₂ and H₂, respectively. The PEM may serve as at least one of the separator and salt bridge of the anode and cathode compartments to allow for hydrogen to be produced at the cathode and oxygen at the anode as separate gases. The cathode may comprise a dichalcogenide hydrogen evolution catalyst such as one comprising at least one of niobium and tantalum that may further comprise sulfur. The cathode may comprise one known in the art such as Pt or Ni. The hydrogen may be produced at high pressure and may be supplied to the reaction cell chamber 5b31 directly or by permeation through a hydrogen permeable memebrane. The SunCell® may comprise an oxygen gas line from the anode compartment to the point of delivery of the oxygen gas to a storage vessel or a vent. In an embodiment, the SunCell® comprises sensors, a processor, and an electrolysis current controller.

In another embodiment, hydrogen fuel may be obtained from electrolysis of water, reforming natural gas, at least one of the syngas reaction and the water-gas shift reaction by reaction of steam with carbon to form H₂ and CO and CO₂, and other methods of hydrogen production known by those skilled in the art.

In another embodiment, the hydrogen may be produced by thermolysis using supplied water and the heat generated by the SunCell®. The thermolysis cycle may comprise one of the disclosure or one known in the art such as one that is based on a metal and its oxide such as at least one of SnO/Sn and ZnO/Zn. In an embodiment wherein the inductively coupled heater, EM pump, and ignition systems only consume power during startup, the hydrogen may be produced by thermolysis such that the parasitic electrical power requirement is very low. The SunCell® may comprise batteries such as lithium ion batteries to provide power to run systems such as the gas sensors and control systems such as those for the reaction plasma gases.

### Magnetohydrodynamic (MHD) Converter

Charge separation based on the formation of a mass flow of ions or an electrically conductive medium in a crossed magnetic field is well known art as magnetohydrodynamic (MHD) power conversion. The positive and negative ions undergo Lorentzian deflection in opposite directions and are received at corresponding MHD electrode to affect a voltage between them. The typical MHD method to form a mass flow of ions is to expand a high-pressure gas seeded with ions through a nozzle to create high-speed flow through the crossed magnetic field with a set of MHD electrodes crossed with respect to the deflecting field to receive the deflected ions. In an embodiment, the pressure is typically greater than atmospheric, and the directional mass flow may be achieved by hydrino reaction to form plasma and highly conductive, high-pressure-and-temperature molten metal vapor that is expanded to create high-velocity flow through a cross magnetic field section of the MHD converter. The flow may be through an MHD converter may be axial or radial. Further directional flow may be achieved with confining magnets such as those of Helmholtz coils or a magnetic bottle.

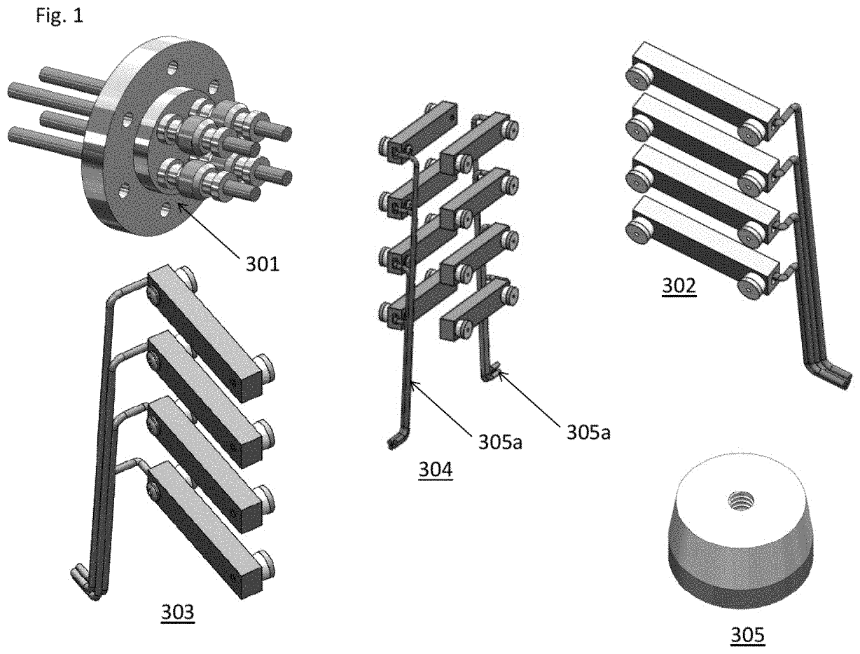

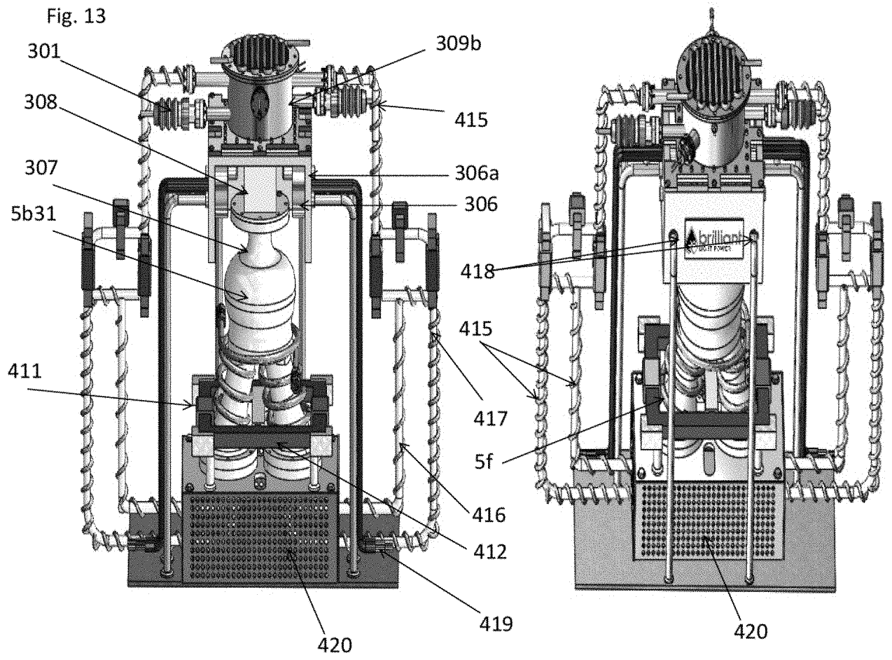

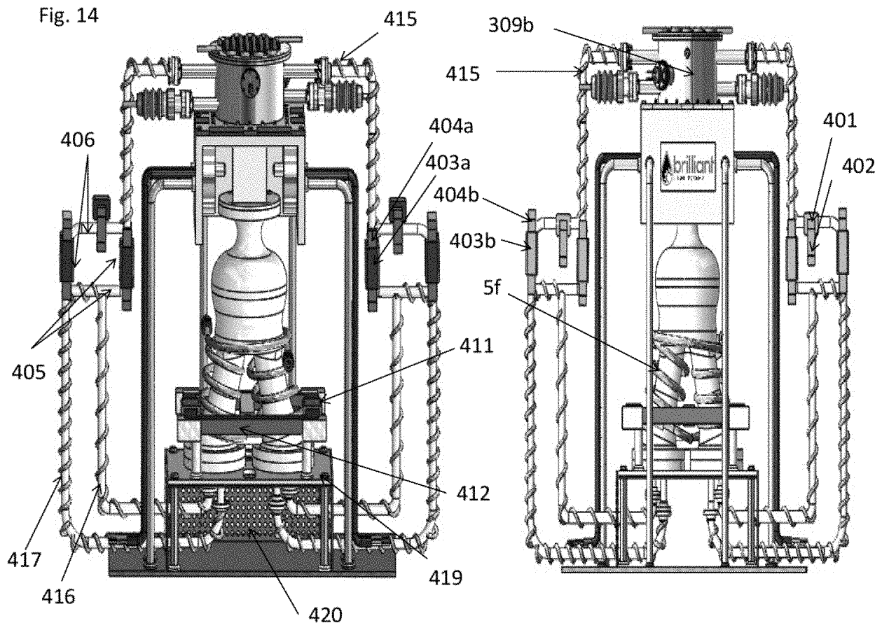

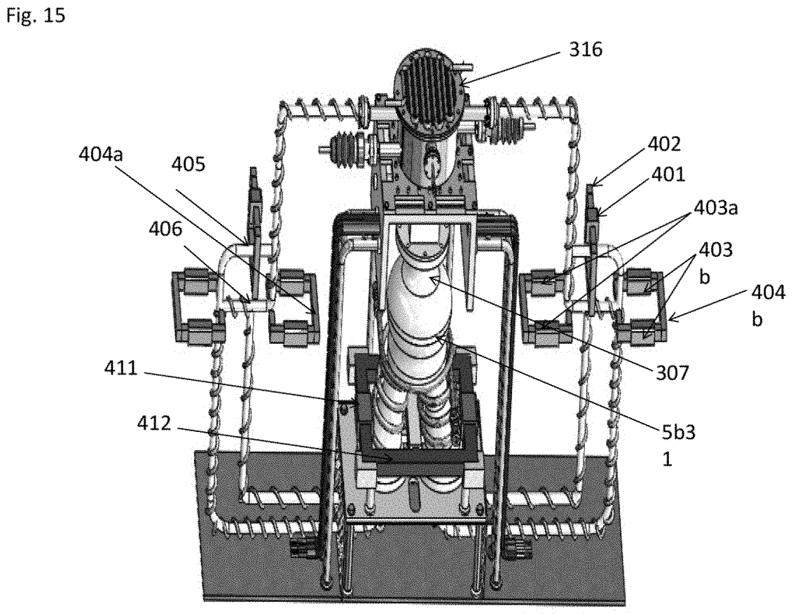

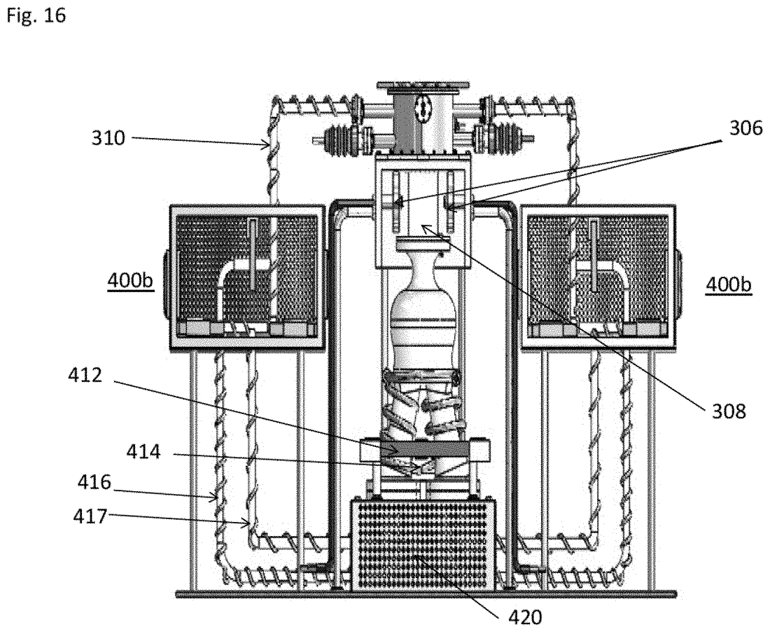

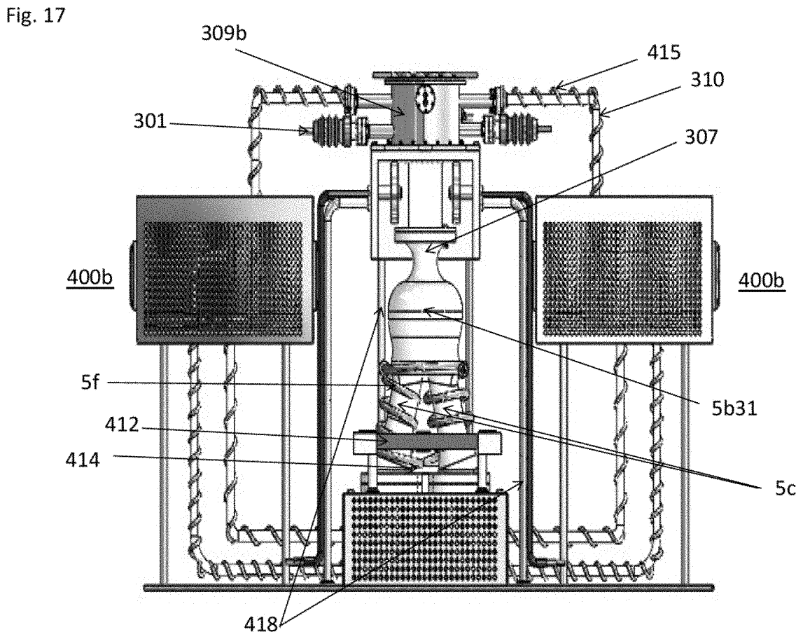

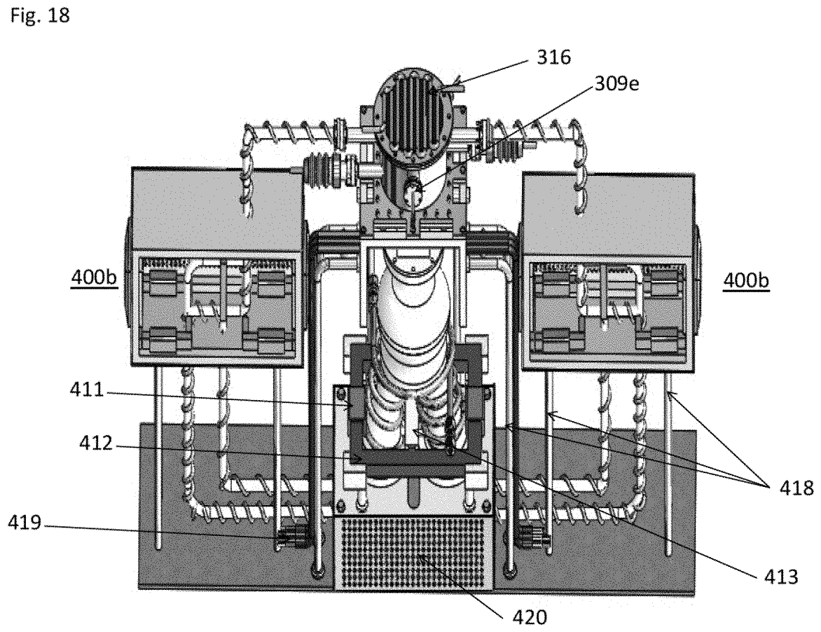

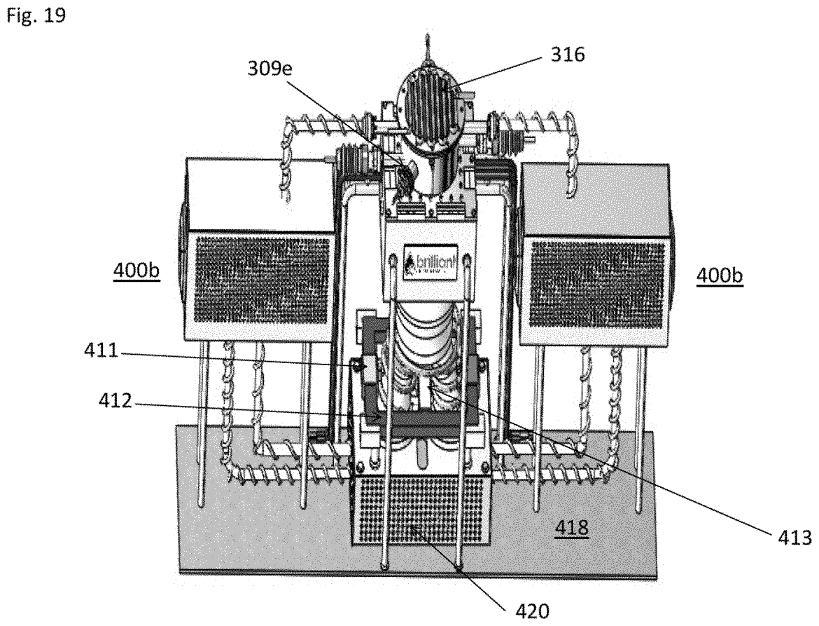

Specifically, the MHD electric power system shown in FIGS. 1-22 may comprise a hydrino reaction plasma source of the disclosure such as one comprising an EM pump 5ka, at least one reservoir 5c, at least two electrodes such as ones comprising dual molten metal injectors 5k61, a source of hydrino reactants such as a source of HOH catalyst and H, an ignition system comprising a source of electrical power 2 to apply voltage and current to the electrodes to form a plasma from the hydrino reactants, and a MHD electric power converter. In an embodiment, the ignition system may comprise a source of voltage and current such as a DC power supply and a bank of capacitor to deliver pulsed ignition with the capacity for high current pulses. In a dual molten metal injector embodiment, current flows through the injected molten metal streams to ignite plasma when the streams connect. The components of the MHD power system comprising a hydrino reaction plasma source and a MHD converter may be comprised of at least one of oxidation resistant materials such as oxidation resistant metals, metals comprising oxidation resistant coatings, and ceramics such that the system may be operated in air.

The magnetohydrodynamic power converter shown in FIGS. 1-22 may comprise a source of magnetic flux transverse to the z-axis, the direction of axial molten metal vapor and plasma flow through the MHD converter 300. The conductive flow may have a preferential velocity along the z-axis due to the expansion of the gas along the z-axis. Further directional flow may be achieved with confining magnets such as those of Helmholtz coils or a magnetic bottle. Thus, the metal electrons and ions propagate into the region of the transverse magnetic flux. The Lorentzian force on the propagating electrons and ions is given by

$$F = e v \times B \qquad ( 38 )$$

The force is transverse to the charge's velocity and the magnetic field and in opposite directions for positive and negative ions. Thus, a transverse current forms. The source of transverse magnetic field may comprise components that provide transverse magnetic fields of different strengths as a function of position along the z-axis in order to optimize the crossed deflection (Eq. (38)) of the flowing charges having parallel velocity dispersion.

The reservoir 5c molten metal may be in at least one state of liquid and gaseous. The reservoir 5c molten metal may defined as the MHD working medium and may be referred to as such or referred to as the molten metal wherein it is implicit that the molten metal may further be in at least one state of liquid and gaseous. A specific state such as molten metal, liquid metal, metal vapor, or gaseous metal may also be used wherein another physical state may be present as well. An exemplary molten metal is silver that may be in at least one of liquid and gaseous states. The MHD working medium may further comprise an additive comprising at least one of an added metal that may be in at least one of a liquid and a gaseous state at the operating temperature range, a compound such as one of the disclosure that may be in at least one of a liquid and a gaseous state at the operating temperature range, and a gas such as at least one of a noble gas such as helium or argon, water, H₂, and other plasma gas of the disclosure. The MHD working medium additive may be in any desired ratio with the MHD working medium. In an embodiment, the ratios of the medium and additive medium are selected to give the optional electrical conversion performance of the MHD converter. The working medium such as silver or silver-copper alloy may be run under supersaturated conditions.

In an embodiment, the MHD electrical generator 300 may comprise at least one of a Faraday, channel Hall, and disc Hall type. In a channel Hall MHD embodiment, the expansion or generator channel 308 may be oriented vertically along the z-axis wherein the molten metal plasma such as silver vapor and plasma flow through an accelerator section such as a restriction or nozzle throat 307 followed by an expansion section 308. The channel may comprise solenoidal magnets 306 such as superconducting or permanent magnets such as a Halbach array transverse to the flow direction along the x-axis. The optimal magnetic field on duct-shaped MHD generators may comprise a sort of saddle shape. The magnets may be secured by MHD magnet mounting bracket 306a. The magnet may comprise a liquid cryogen or may comprise a cryo-refrigerator with or without a liquid cryogen. The cryo-refrigerator may comprise a dry dilution refrigerator. The magnets may comprise a return path for the magnetic field such as a yoke such as a C-shaped or rectangular back yoke. An exemplary permanent magnet material is SmCo, and an exemplary yoke material is magnetic CRS, cold rolled steel, or iron. The generator may comprise at least one set of electrodes such as segmented electrodes 304 along the y-axis, transverse to the magnetic field (B) to receive the transversely Lorentzian deflected ions that creates a voltage across the MHD electrodes 304. In another embodiment, at least one channel such as the generator channel 308 may comprise geometry other than one with planar walls such as a cylindrically walled channel. Magnetohydrodynamic generation is described by Walsh [E. M. Walsh, Energy Conversion Electromechanical, Direct, Nuclear, Ronald Press Company, NY, NY, (1967), pp. 221-248] the complete disclosure of which is incorporated herein by reference. The Lorentz force may be increased to that desired by increasing the magnetic field strength. The magnetic flux of the MHD magnets 306 may be increased. In an embodiment, the magnetic flux may be in at least one range of about 0.01 T to 15 T, 0.05 T to 10 T, 0.1 T to 5 T, 0.1 T to 2 T, and 0.1 T to 1 T.

In an embodiment. the disc generator comprises a plasma inlet to maintain plasma flowing from the reaction cell chamber into the center of a disc, a duct wrapped around the edge to collect the molten metal and possibly gases that are recirculated to the reaction cell chamber by a recirculator, and the recirculator. The magnetic excitation field may comprise a pair of circular Helmholtz coils above and below the disk. The magnet may supply simple parallel field lines that may be relatively closer to the plasma compared to other designs, and magnetic field strengths increase as the 3rd power of distance. The Faraday currents may flow, in about a dead short around the periphery of the disk. The disc MHD generator may further comprise ring electrodes wherein the Hall effect currents may flow between ring electrodes near the center and ring electrodes near the periphery.

To avoid MHD electrode electrical shorting by the molten metal vapor, the electrodes 304 (FIG. 1) may comprise conductors, each mounted on an electrical-insulator-covered conducting post 305 that serves as a standoff for lead 305a and may further serve as a spacer of the electrode from the wall of the generator channel 308. The electrodes 304 may be segmented and may comprise a cathode 302 and anode 303. Except for the standoffs 305, the electrodes may be freely suspended in the generator channel 308. The electrode spacing along the vertical axis may be sufficient to prevent molten metal shorting. The electrodes may comprise a refractory conductor such as W or Mo. The leads 305a may be connected to wires that may be insulated with a refractory insulator such as BN. The wires may join in a harness that penetrates the channel at a MHD bus bar feed through flange 301 that may comprise a metal. Outside of the MHD converter, the harness may connect to a power consolidator and inverter. In an embodiment, the MHD electrodes 304 comprise liquid electrodes such as liquid silver electrodes. In an embodiment, the ignition system may comprise liquid electrodes. The ignition system may be DC or AC. The reactor may comprise a ceramic such as quartz, alumina, zirconia, hafnia, or Pyrex. The liquid electrodes may comprise a ceramic frit that may further comprise micro-holes that are loaded with the molten metal such as silver.

In an embodiment, the hydrino reaction mixture may comprise at least one of oxygen, water vapor, and hydrogen. The MHD components may comprise materials such as ceramics such as metal oxides such as at least one of zirconia and hafnia, or silica or quartz that are stable under an oxidizing atmosphere. The seals between ceramic components may comprise graphite or a ceramic weave. In an embodiment, at least one component of the power system may comprise ceramic wherein the ceramic may comprise at least one of a metal oxide, alumina, zirconia, magnesia, hafnia, silicon carbide, zirconium carbide, zirconium diboride, silicon nitride, and a glass ceramic such as Li₂O×Al₂O₃×nSiO₂ system (LAS system), the MgO×Al₂O₃×nSiO₂ system (MAS system), the ZnO×Al₂O₃×nSiO₂ system (ZAS system). Ceramic parts of SunCell® may be joined by means of the disclosure such as by ceramic glue of two or more ceramic parts, braze of ceramic to metallic parts, slip nut seals, gasket seals, and wet seals. The gasket seal may comprise two flanges sealed with a gasket. The flanges may be drawn together with fasteners such as bolts. In an embodiment, the MHD electrodes 304 may comprise a material that may be less susceptible to corrosion or degradation during operation. In an embodiment, the MHD electrodes 304 may comprise a conductive ceramic such as a conductive solid oxide. In another embodiment, the MHD electrodes 304 may comprise liquid electrodes. The liquid electrodes may comprise a metal that is liquid at the electrode operating temperature. The liquid metal may comprise the working medium metal such as molten silver. The molten electrode metal may comprise a matrix impregnated with the molten metal. The matrix may comprise a refectory material such as a metal such as W, carbon, a ceramic that may be conductive or another refractory material of the disclosure. The negative electrode may comprise a solid refractory metal. The negative polarity may protect the negative electrode from oxidizing. The positive electrode may comprise a liquid electrode.

In an embodiment, the conductive ceramic electrodes may comprise one of the disclosure such as a carbide such as ZrC, HfC, or WC or a boride such as ZrB₂ or composites such as ZrC—ZrB₂, ZrC—ZrB₂—SiC, and ZrB₂ with 20% SiC composite that may work up to 1800° C. The electrodes may comprise carbon. In an embodiment, a plurality of liquid electrodes may be supplied liquid metal through a common manifold. The liquid metal may be pumped by an EM pump. The liquid electrodes may comprise molten metal impregnated in a non-reactive matrix such as a ceramic matrix such as a metal oxide matrix. Alternatively, the liquid metal may be pumped through the matrix to continuous supply molten metal. In an embodiment, the electrodes may comprise continuously injected molten metal such as the ignition electrodes. The injectors may comprise a non-reactive refractory material such as a metal oxide such as ZrO₂. In an embodiment, each of the liquid electrodes may comprise a flow stream of molten metal that is exposed to the MHD channel plasma.

The MHD magnets 306 may comprise at least one of permanent and electromagnets. The electromagnet(s) 306 may be at least one of uncooled, water cooled, and superconducting magnets with a corresponding cryogenic management. Exemplary magnets are solenoidal or saddle coils that may magnetize a MHD channel 308 and racetrack coils that may magnetize a disc channel. The superconducting magnet may comprise at least one of a cryo-refrigerator and a cryogen-dewar system. The superconducting magnet system 306 may comprise (i) superconducting coils that may comprise superconductor wire windings of NbTi or NbSn wherein the superconductor may be clad on a normal conductor such as copper wire to protect against transient local quenches of the superconductor state induced by means such as vibrations, or a high temperature superconductor (HTS) such as YBa₂Cu₃O₇, commonly referred to as YBCO-123 or simply YBCO, (ii) a liquid helium dewar providing liquid helium on both sides of the coils, (iii) liquid nitrogen dewars with liquid nitrogen on the inner and outer radii of the solenoidal magnet wherein both the liquid helium and liquid nitrogen dewars may comprise radiation baffles and radiation shields that may be comprise at least one of copper, stailess steel, and aluminum and high vacuum insulation at the walls, and (iv) an inlet for each magnet that may have attached a cyropump and compressor that may be powered by the power output of the SunCell® generator through its output power terminals.

In one embodiment, the magnetohydrodynamic power converter is a segmented Faraday generator. In another embodiment, the transverse current formed by the Lorentzian deflection of the ion flow undergoes further Lorentzian deflection in the direction parallel to the input flow of ions (z-axis) to produce a Hall voltage between at least a first MHD electrode and a second MHD electrode relatively displaced along the z-axis. Such a device is known in the art as a Hall generator embodiment of a magnetohydrodynamic power converter. A similar device with MHD electrodes angled with respect to the z-axis in the xy-plane comprises another embodiment of the present invention and is called a diagonal generator with a “window frame” construction. In each case, the voltage may drive a current through an electrical load. Embodiments of a segmented Faraday generator, Hall generator, and diagonal generator are given in Petrick [J. F. Louis, V. I. Kovbasyuk, Open-cycle Magnetohydrodynamic Electrical Power Generation, M Petrick, and B. Ya Shumyatsky, Editors, Argonne National Laboratory, Argonne, Ill., (1978), pp. 157-163] the complete disclosure of which is incorporated by reference.

The SunCell® may comprise at least one MHD working medium return conduit 310, one return reservoir 311, and corresponding pump 312. The pump 312 may comprise an electromagnetic (EM) pump. The SunCell® may comprise dual molten metal conduits 310, return reservoirs 311, and corresponding EM pumps 312. A corresponding inlet riser tube 5qa comprising an inlet with an opening at the height of the lowest reservoir molten metal level may control the molten metal level in each return reservoir 311. The return EM pumps 312 may pump the MHD working medium from the end of the MHD condenser channel 309 to return reservoirs 311 and then to the corresponding injector reservoirs 5c. In an embodiment, the MHD channel 308 walls may be maintained at a temperature such as greater than the melting point of silver to avoid liquid solidification. In another embodiment, molten metal return flow is through the return conduit 310 directly to the corresponding return EM pumps 312 and then to the corresponding injector reservoirs 5c. In an embodiment, the MHD working medium such as silver is pumped against a pressure gradient such as about 10 atm to complete a molten metal flow circuit comprising injection, ignition, expansion, and return flow. To achieve the high pressure, the EM pump may comprise a series of stages. The SunCell® may comprise a dual molten metal injector system comprising a pair of reservoirs 5c, each comprising an EM pump injector 5ka and 5k61 and an inlet riser tube 5qa to control the molten metal level in the corresponding reservoir 5c. The return flow may enter the base of the corresponding EM pump assembly 5kk.

The MHD generator may comprise a condenser channel section 309 that receives the expansion flow and the generator further comprises return flow channels or conduits 310 wherein the MHD working medium such as silver vapor cools as it loses at least one of temperature, pressure, and energy in the condenser section and flows back to the reservoirs through the channels or conduits 310. The generator may comprise at least one return pump 312 and return pump tube 313 to pump the return flow to the reservoirs 5c and EM pump injectors 5ka. The return pump and pump tube may pump at least one of liquid, vapor, and gas. The return pump 312 and return pump tube 313 may comprise an electromagnetic (EM) pump and EM pump tube. The inlet to the EM pump may have a greater diameter than the outlet pump tube diameter to increase the pump outlet pressure. In an embodiment, the return pump may comprise the injector of the EM pump-injector electrode 5ka. In a dual molten metal injector embodiment, the generator comprises return reservoirs 311 each with a corresponding return pump such as a return EM pump 312. The return reservoir 311 may at least one of balance the return molten metal such as molten silver flow and condense or separate silver vapor mixed in with the liquid silver. The reservoir 311 may comprise a heat exchanger to condense the silver vapor. The reservoir 311 may comprise a first stage electromagnetic pump to preferentially pump liquid silver to separate liquid from gaseous silver. In an embodiment, the liquid metal may be selectively injected into the return EM pump 312 by centrifugal force. The return conduit or return reservoir may comprise a centrifuge section. The centrifuge reservoir may be tapered from inlet to outlet such that the centrifugal force is greater at the top than at the bottom to force the molten metal to the bottom and separate it from gas such as metal vapor and any working medium gas. Alternatively, the SunCell® may be mounted on a centrifuge table that rotates about the axis perpendicular to the flow direction of the return molten metal to produce centrifugal force to separate liquid and gaseous species.

In an embodiment, the condensed metal vapor flows into the two independent return reservoirs 311, and each return EM pumps 312, pumps the molten metal into the corresponding reservoir 5c. In an embodiment, at least one of the two return reservoirs 311 and EM pump reservoirs 5c comprises a level control system such as one of the disclosure such as an inlet riser 5qa. In an embodiment, the return molten metal may be sucked into a return reservoir 311 due at a higher or lower rate depending on the level in the return reservoir wherein the sucking rate is controlled by the corresponding level control system such as the inlet riser.

In an embodiment, the MHD converter 300 may further comprise at least one heater such as an inductively coupled heater. The heater may preheat the components that are in contact with the MHD working medium such as at least one of the reaction cell chamber 5b31, MHD nozzle section 307, MHD generator section 308, MHD condensation section 309, return conduits 310, return reservoirs 311, return EM pumps 312, and return EM pump tube 313. The heater may comprise at least one actuator to engage and retract the heater. The heater may comprise at least one of a plurality of coils and coil sections. The coils may comprise one known in the art. The coil sections may comprise at least one split coil such as one of the disclosure. In an embodiment, the MHD converter may comprise at least one cooling system such as heat exchanger 316. The MHD converter may comprise coolers for at least one cell and MHD component such as at least one of the group of chamber 5b31, MHD nozzle section 307, MHD magnets 306, MHD electrodes 304, MHD generator section 308, MHD condensation section 309, return conduits 310, return reservoirs 311, return EM pumps 312, and return EM pump tube 313. The cooler may remove heat lost from the MHD flow channel such as heat lost from at least one of the chamber 5b31, MHD nozzle section 307, MHD generator section 308, and MHD condensation section 309. The cooler may remove heat from the MHD working medium return system such as at least one of the return conduits 310, return reservoirs 311, return EM pumps 312, and return EM pump tube 313. The cooler may comprise a radiative heat exchanger that may reject the heat to ambient atmosphere.

In an embodiment, the cooler may comprise a recirculator or recuperator that transfers energy from the condensation section 309 to at least one of the reservoirs 5c, the reaction cell chamber 5b31, the nozzle 307, and the MHD channel 308. The transferred energy such as heat may comprise that from at least one of the remaining thermal energy, pressure energy, and heat of vaporization of the working medium such as one comprising at least one of a vaporized metal, a kinetic aerosol, and a gas such as a noble gas. Heat pipes are passive two-phase devices capable of transferring large heat fluxes such as up to 20 MW/m² over a distances of meters with a few tenths of degree temperature drop; thus, reducing dramatically the thermal stresses on material, using only a small quantity of working fluid. Sodium and lithium heat pipes can transfer large heat fluxes and remain nearly isothermal along the axial direction. The lithium heat pipe can transfer up to 200 MW/m². In an embodiment, a heat pipe such as molten metal one such as liquid alkali metal such as sodium or lithium encased in a refractory metal such as W may transfer the heat from the condenser 309 and recirculate it to the reaction cell chamber 5b31 or nozzle 307. In an embodiment, at least one heat pipe recovers the silver heat of vaporization and recirculates it such that the recovered heat power is part of the power input to the MHD channel 308.

In an embodiment, at least one of component of the SunCell® such as one comprising a MHD converter may comprise a heat pipe to at least one of transfer heat from one part of the SunCell® power generator to another and transfer heat from a heater such as an inductively coupled heater to a SunCell® component such as the EM pump tube 5k6, the reservoirs 5c, the reaction cell chamber 5b31, and the MHD molten metal return system such as the MHD return conduit 310, MHD return reservoir 311, MHD return EM pump 312, and MHD return EM tube. Alternatively, the SunCell® or at least one component may be heated within an oven such as one known in the art. In an embodiment, at least one SunCell® component may be heated for at least startup of operation.

The SunCell® heater 415 may be a resistive heater or an inductively coupled heater. An exemplary SunCell® heater 415 comprises Kanthal A-1 (Kanthal) resistive heating wire, a ferritic-chromium-aluminum alloy (FeCrAl alloy) capable of operating temperatures up to 1400° C. and having high resistivity and good oxidation resistance. Additional FeCrAl alloys for suitable heating elements are at least one of Kanthal APM, Kanthal A F, Kanthal D, and Alkrothal. The heating element such as a resistive wire element may comprise a NiCr alloy that may operate in the 1100° C. to 1200° C. range such as at least one of Nikrothal 80, Nikrothal 70, Nikrothal 60, and Nikrothal 40. Alternatively, the heater 415 may comprise molybdenum disilicide (MoSi2) such as at least one of Kanthal Super 1700, Kanthal Super 1800, Kanthal Super 1900, Kanthal Super RA, Kanthal Super ER, Kanthal Super HT, and Kanthal Super NC that is capable of operating in the 1500° C. to 1800° C. range in an oxidizing atmosphere. The heating element may comprise molybdenum disilicide (MoSi₂) alloyed with Alumina. The heating element may have an oxidation resistant coating such as an Alumina coating. The heating element of the resistive heater 415 may comprise SiC that may be capable of operating at a temperature of up to 1625° C.

The SunCell® heater 415 may comprise an internal heater that may be introduced through thermowells or indentations of the component wall that are open to the outside, but closed to the inside of the SunCell® component. The SunCell® heater 415 may comprise an internal resistive heater wherein power may be coupled to the internal heater by magnetic induction across the wall of the heated SunCell® component or by liquid electrodes that penetrate the wall of the heated SunCell® component.

The SunCell® heater may comprise insulation to increase at least one of its efficiency and effectiveness. The insulation may comprise a ceramic such as one known by those skilled in the art such as an insulation comprising alumina-silicate. The insulation may be at least one of removable or reversible. The insulation may be mechanically removed. The insulation may comprise a vacuum capable chamber and a pump, wherein the insulation is applied by pulling a vacuum, and the insulation is reversed by adding a heat transfer gas such as a noble gas such as helium. A vacuum chamber with a heat transfer gas such as helium that can be added or pumped off may serve as adjustable insulation. The SunCell® may comprise a gas circulation system to cause force convection heat transfer with its activation to switch from a thermally insulating to non-thermally insulating mode.

In another embodiment, the SunCell® may comprise a particle insulation and at least one insulation reservoir having at least one chamber about the component to be thermally insulated to house the insulation during warm-up of the SunCell®. Exemplary particulate insulation comprises at least one of sand and ceramic beads such as alumina or alumina-silicate beads such as Mullite beads. The beads may be removed following warm up. The beads may be removed by gravity flow wherein the housing may comprise a shoot for bead removal. The beads may also be removed mechanically with a bead transporter such as an auger, conveyor, or pneumatic pump. The particulate insulation may further comprise a fluidizer such as a liquid such as water to increase the flow when filling the insulation reservoir. The liquid may be removed before heating and added during insulation transport. The insulation-liquid mixture may comprise slurry. The SunCell® may comprise at least one additional reservoir to fill or empty the insulation from the insulation reservoir. The fill reservoir may comprise a means to maintain slurry such as an agitator.

In an embodiment, the SunCell® may further comprise a liquid insulation reservoir circumferential to the components to be insulated, liquid insulation, and a pump wherein the reversible insulation may comprise the liquid that may be drained or pumped away following startup. The liquid insulation reservoir may comprise thin-walled quartz. An exemplary liquid insulation is gallium having a heat transfer coefficient of 29 W/m K, and another is mercury having a heat transfer coefficient of 8.3 W/m K. The liquid insulation may comprise at least one radiation shield wherein the liquid such as gallium reflects radiation. In another embodiment, the liquid insulation may comprise a molten salt such as a molten eutectic mixture of salts such as a mixture of a plurality of at least two of alkali and alkaline earth halides, carbonates, hydroxides, oxides, sulfates, and nitrates. The liquid insulation may comprise a pressurized liquid or supercritical liquid such as CO₂ or water.

In an embodiment, the reversible insulation may comprise a material that significantly increases its thermal conductivity with temperature over at least the range of about the melting of the molten metal such as silver to about the SunCell® operating temperature. The reversible insulation may comprise a solid compound that may be insulating during heat up and becomes thermally conductive at a temperature above the desired startup temperature. Quartz is an exemplary insulating material that has a significant increase in thermal conductivity over the temperature range of the melting point of silver to a desired operating temperature of a quartz SunCell® of about 1000° C. to 1600° C. The quartz insulation thickness may be adjusted to achieve the desired behavior of insulation during startup and heat transfer to a load during operation. Another exemplary embodiment comprises a highly porous semitransparent ceramic material.

In another embodiment, heat is loss from the heated SunCell® is predominantly by radiation. The insulation may comprise at least one of a vacuum chamber housing the SunCell® and radiation shields. The radiation shields may be removed following startup. The SunCell® may comprise a mechanism to at least one of rotate and translate the heat shields. The heat shields may further comprise a backing layer of insulation such as silica or alumina insulation. In an exemplary embodiment, the radiation shields may be turned to decrease the reflecting surface area. In another embodiment, the radiation shields may further comprise heating elements such as MoSi₂ heating elements.

In an embodiment, the inductive current such as that induced in the EM pump tube sections 405 and 406 may cause the silver in the EM pump section 405 to melt by resistive heating. The current may be induced by EM pump transformer winding 401. The EM pump tube section 405 may be pre-loaded with silver before startup. In an embodiment, the heat of the hydrino reaction may heat at one SunCell® component. In an exemplary embodiment, a heater such as an inductively coupled heater heats the EM pump tube 5k6, the reservoirs 5c, and at least the bottom portion of the reaction cell chamber 5b31. At least one other component may be heated by the heat release of the hydrino reaction such as at least one of the top of the reaction cell chamber 5b31, the MHD nozzle 307, MHD channel 308, MHD condensation section 309, and MHD molten metal return system such as the MHD return conduit 310, MHD return reservoir 311, MHD return EM pump 312, and MHD return EM tube.

A source of hydrino reactant such as at least one of H₂O, H₂, and O₂, may be permeated through a permeable cell components such as at least one of the cell chamber 5b31, the reservoirs 5c, the MHD expansion channel 308, and the MHD condensation section 309. The hydrino reaction gases may be introduced into the molten metal stream in at least one location such as through the EM pump tube 5k6, the MHD expansion channel 308, the MHD condensation section 309, the MHD return conduit 310, the return reservoir 311, the MHD return pump 312, the MHD return EM pump tube 313. The gas injector such as a mass flow controller may be capable of injecting at high pressure on the high-pressure side of the MHD converter such as through at least one of the EM pump tube 5k6, the MHD return pump 312, and the MHD return EM pump tube 313. The gas injector may be capable of injection of the hydrino reactants at lower pressure on the low-pressure side of the MHD converter such as at least one location such as through the MHD condensation section 309, the MHD return conduit 310, and the return reservoir 311. In an embodiment at least one of water and water vapor may be injected through the EM pump tube 5k4 by a flow controller that may further comprise a pressure arrestor and a back-flow check valve to present the molten metal from flowing back into the water supplier such as the mass flow controller. Water may be injected through a selectively permeable membrane such as a ceramic or carbon membrane.

In an embodiment, the converter may comprise a PV converter wherein the hydrino reactant injector is capable of supplying reactants by at least one of means such as by permeation or injection at the operating pressure of the site of delivery. In another embodiment, the SunCell® may further comprise a source of hydrogen gas and a source of oxygen gas wherein the two gases are combined to provide water vapor in the reaction cell chamber 5b31. The source of hydrogen and the source of oxygen may each comprise at least one of a corresponding tank, a line to flow the gas into reaction cell chamber 5b31 directly or indirectly, a flow regulator, a flow controller, a computer, a flow sensor, and at least one valve. In the latter case, the gas may be flowed into a chamber in gas continuity with the reaction cell chamber 5b31 such as at least one of the EM pump 5ka, the reservoir 5c, the nozzle 307, the MHD channel 308, and other MHD converter components such as any return lines 310a, conduits 313a, and pumps 312a. In an embodiment, at least one of the H₂ and O₂ may be injected into the injection section the EM pump tube 5k61. O₂ and H₂ may be injected through separate EM pump tubes of the dual EM pump injectors. Alternatively, a gas such as at least one of oxygen and hydrogen may be added to the cell interior through an injector in a region with lower silver vapor pressure such as the MHD channel 308 or MHD condensation section 309. At least one of hydrogen and oxygen may be injected through a selective membrane such as a ceramic membrane such as a nano-porous ceramic membrane. The oxygen may be supplied through an oxygen permeable membrane such as one of the disclosure such as BaCo_{0.7}Fe_{0.2} Nb_{0.1} O_{3-δ} (BCFN) oxygen ipeable membrane that may be coated with Bi₂₆Mo₁₀O₆₉ to increase the oxygen permeation rate. The hydrogen may be supplied through a hydrogen permeable membrane such as a palladium-silver alloy membrane. The SunCell® may comprise an electrolyzer such as a high-pressure electrolyzer. The electrolyzer may comprise a proton exchange membrane where pure hydrogen may be supplied by the cathode compartment. Pure oxygen may be supplied by the anode compartment. In an embodiment, the EM pump parts are coated with a non-oxidizing coating or oxidation protective coating, and hydrogen and oxygen are injected separately under controlled conditions using two mass flow controllers wherein the flows may be controlled based on the cell concentrations sensed by corresponding gas sensors.

The hydrino reaction mixture of the reaction cell chamber 5b31 may further comprise a source of oxygen such as at least one of H₂O and a compound comprising oxygen. The source of oxygen such as the compound comprising oxygen may be in excess to maintain a near constant oxygen source inventory wherein during cell operation a small portion reversibly reacts with the supplied source of H such as H₂ gas to form HOH catalyst. Exemplary compounds comprising oxygen are hydroxides such as Ga(OH)₃, hydrated gallium oxide, Al(OH)₃, oxyhydroxides such as GaOOH, AlOOH, and FeOOH, oxides such as MgO, CaO, SrO, BaO, ZrO₂, HfO₂, Al₂O₃, Li₂O, LiVO₃, Bi₂O₃, Al₂O₃, WO₃, and others of the disclosure. The oxygen source compound may be the one used to stabilize the oxide ceramic such as yttria or hafnia such as yttrium oxide (Y₂O₃), magnesium oxide (MgO), calcium oxide (CaO), strontium oxide (SrO), tantalum oxide (Ta₂O₅), boron oxide (B₂O₃), TiO₂, cerium oxide (Ce₂O₃), strontium zirconate (SrZrO₃), magnesium zirconate (MgZrO₃), calcium zirconate (CaZrO₃), and barium zirconate (BaZrO₃).

In an embodiment, the hydrogen may be injected as a gas through a gas injector. The hydrogen gas may be maintained at an elevated pressure such as in the range of 1 to 100 atm to decrease the required flow rate to maintain a desired power. In another embodiment, hydrogen may be supplied to the reaction cell chamber 5b31 by permeation or diffusion across a permeable membrane. The membrane may comprise a ceramic such as polymers, silica, zeolite, alumina, zirconia, hafnia, carbon, or a metal such as Pd—Ag alloy, niobium, Ni, Ti, stainless steel or other hydrogen permeable material known in the art such as one reported by McLeod [L. S. McLeod, “Hydrogen permeation through microfabricated palladium-silver alloy membranes”, PhD thesis Georgia Institute of Technology, December, (2008), https://smartech.gatech.edu/bitstream/handle/1853/31672/mcleod_logan_s_200812_phd.pdf] which is incorporate by reference in its entirety. The H₂ permeation rate may be increased by at least one of increasing the pressure differential between the supply side of the H₂ permeable membrane such as a Pd or Pd—Ag membrane and the reaction cell chamber 5b31, increasing the area of the membrane, decreasing the thickness of the membrane, and elevating the temperature of the membrane. The membrane may comprise a grating or perforated backing to provide structural support to operate under at least one condition of higher pressure differential such as in the range of about 1 to 500 atm, larger area such as in the range of about 0.01 cm² to 10 m², decreased thickness such as in the range of 10 nm to 1 cm, and elevated temperature such as in the range of about 30° C. to 3000° C. The grating may comprise a metal that does not react with hydrogen. The grating may be resistant to hydrogen embrittlement. An exemplary embodiment, a Pd—Ag alloy membrane having a permeation coefficient of 5×10⁻¹¹ m m⁻² s⁻¹ Pa⁻¹, an area of 1×10⁻³ m², and a thickness of 1×10⁻⁴ m operates at a pressure differential of 1×10⁷ Pa and a temperature of 300° C. to provide a H₂ flow rate of about 0.01 moles/s. In an embodiment, the hydrogen permeation rate may be increased by maintaining a plasma on the outer surface of the permeable membrane.

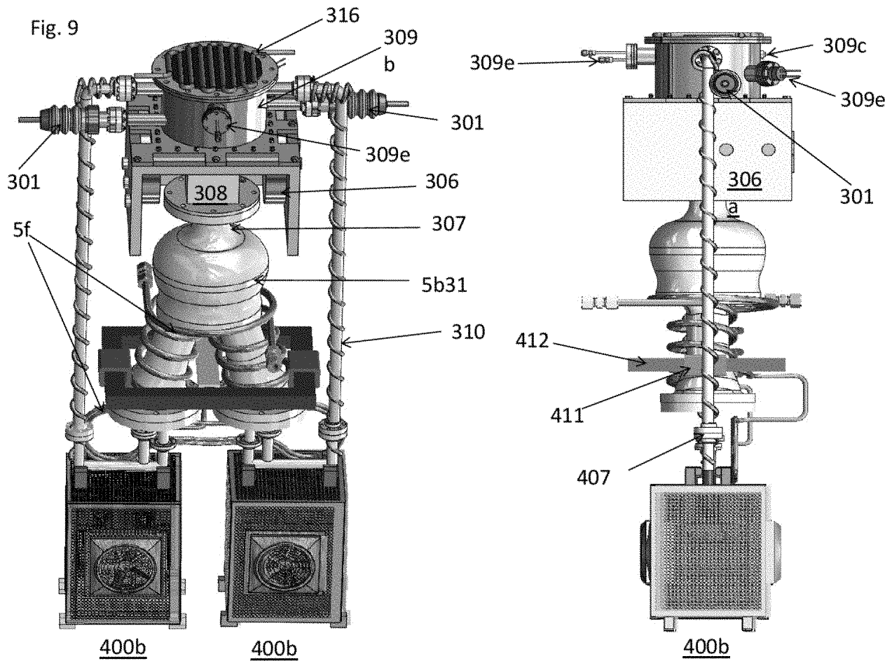

In an embodiment, at least one component of the SunCell® and MHD converter comprising an interior compartment such as the reservoirs 5c, the reaction cell chamber 5b31, the nozzle 307, the MHD channel 308, the MHD condensation section 309, and other MHD converter components such as any return lines 310a, conduits 313a, and pumps 312a are housed in a gas-sealed housing or chamber wherein the gases in the chamber equilibrate with the interior cell gas by diffusion across a membrane permeable to gases and impermeable to silver vapor. The gas selective membrane may comprise a semipermeable ceramic such as one of the disclosure. The cell gases may comprise at least one of hydrogen, oxygen, and a noble gas such as argon or helium. The outer housing may comprise a pressure sensor for each gas. The SunCell® may comprise a source and controller for each gas. The source of noble gas such as argon may comprise a tank. The source for at least one of hydrogen and oxygen may comprise an electrolyzer such as a high-pressure electrolyzer. The gas controller may comprise at least one of a flow controller, a gas regulator, and a computer. The gas pressure in the housing may be controlled to control the gas pressure of each gas in the interior of the cell such as in the reservoirs, reaction cell chamber, and MHD converter components. The pressure of each gas may be in the range of about 0.1 Torr to 20 atm. In an exemplary embodiment shown in FIGS. 9-21, the MHD channel 308 which may be straight, diverging, or converging and MHD condensation section 309 comprises a gas housing 309b, a pressure gauge 309c, and gas supply and evacuation assembly 309e comprising a gas inlet line, a gas outlet line, and a flange wherein the gas permeable membrane 309d may be mounted in the wall of the MHD condensation section 309. The mount may comprise a sintered joint, a metalized ceramic joint, a brazed joint, or others of the disclosure. The gas housing 309b may further comprise an access port. The gas housing 309b may comprise a metal such as an oxidation resistant metal such as SS 625 or an oxidation resistant coating on a metal such as an iridium coating on a metal of suitable CTE such as molybdenum. Alternatively, the gas housing 309b may comprise ceramic such as a metal oxide ceramic such as zirconia, alumina, magnesia, hafnia, quartz, or another of the disclosure. Ceramic penetrations through a metal gas housing 309b such as those of the MHD return conduits 310 may be cooled. The penetration may comprise a carbon seal wherein the seal temperature is below the carbonization temperature of the metal and the carbo-reduction temperature of the ceramic. The seal may be removed for the hot molten metal to cool it. The seal may comprise cooling such as passive or forced air or water-cooling.

In an exemplary embodiment, the blackbody plasma initial and final temperatures during MHD conversion to electricity are 3000K and 1300K. In an embodiment, the MHD generator is cooled on the low-pressure side to maintain the plasma flow. The Hall or generator channel 308 may be cooled. The cooling means may be one of the disclosure. The MHD generator 300 may comprise a heat exchanger 316 such as a radiative heat exchanger wherein the heat exchanger may be designed to radiate power as a function of its temperature to maintain a desired lowest channel temperature range such as in a range of about 1000° C. to 1500° C. The radiative heat exchanger may comprise a high surface are to minimize at least one of its size and weight. The radiative heat exchanger 316 may comprise a plurality of surfaces that may be configured in pyramidal or prismatic facets to increase the radiative surface area. The radiative heat exchanger may operate in air. The surface of the radiative heat exchanger may be coated with a material that has at least one property of the group of (i) capable of high temperature operation such as a refractory material, (ii) possesses a high emissivity, (iii) stable to oxidation, and provides a high surface area such as a textured surface with unimpeded or unobstructed emission. Exemplary materials are ceramics such as oxides such as MgO, ZrO₂, HfO₂, Al₂O₃, and other oxidative stabilized ceramics such as ZrC—ZrB₂ and ZrC—ZrB₂—SiC composite.

The generator may further comprise a regenerator or regenerative heat exchanger. In an embodiment, flow is returned to the injection system after passing in a counter current manner to receive heat in the expansion section 308 or other heat loss region to preheat the metal that is injected into the cell reaction chamber 5b31 to maintain the reaction cell chamber temperature. In an embodiment, at least one of working medium such as at least one of silver and a noble gas, a cell component such as the reservoirs 5c, the reaction cell chamber 5b31, and an MHD converter component such as at least one of the MHD condensation section 309 or other hot component such as at least one of the group of the reservoirs 5c, reaction cell chamber 5b31, MHD nozzle section 307, MHD generator section 308, and MHD condensation section 309 may be heated by a heat exchanger that receives heat from at least one other cell or MHD component such as at least one of the group of the reservoirs 5c, reaction cell chamber 5b31, MHD nozzle section 307, MHD generator section 308, and MHD condensation section 309. The regenerator or regenerative heat exchanger may transfer the heat from one component to another.

In an embodiment, the SunCell® may further comprise a molten metal overflow system such as one comprising an overflow tank, at least one pump, a cell molten metal inventory sensor, a molten metal inventory controller, a heater, a temperature control system, and a molten metal inventory to store and supply molten metal as required to the SunCell® as may be determined by at least one sensor and controller. A molten metal inventory controller of the overflow system may comprise a molten metal level controller of the disclosure such as an inlet riser tube and an EM pump. The overflow system may comprise at least one of the MHD return conduit 310, return reservoir 311, return EM pump 312, and return EM pump tube 313.

The electromagnetic pumps may each comprise one of two main types of electromagnetic pumps for liquid metals: an AC or DC conduction pump in which an AC or DC magnetic field is established across a tube containing liquid metal, and an AC or DC current is fed to the liquid through electrodes connected to the tube walls, respectively; and induction pumps, in which a travelling field induces the required current, as in an induction motor wherein the current may be crossed with an applied AC electromagnetic field. The induction pump may comprise three main forms: annular linear, flat linear, and spiral. The pumps may comprise others know in the art such as mechanical and thermoelectric pumps. The mechanical pump may comprise a centrifugal pump with a motor driven impeller. The power to the electromagnetic pump may be constant or pulsed to cause a corresponding constant or pulsed injection of the molten metal, respectively. The pulsed injection may be driven by a program or function generator. The pulsed injection may maintain pulsed plasma in the reaction cell chamber.

In an embodiment, the EM pump tube 5k6 comprises a flow chopper to cause intermittent or pulsed molten metal injection. The chopper may comprise a valve such as an electronically controlled valve that further comprises a controller. The valve may comprise a solenoid valve. Alternatively, the chopper may comprise a rotating disc with at least one passage that rotates periodically to intersect the flow of molten metal to allow the molten metal to flow through the passage wherein the flow in blocked by sections of the rotating disc that do not comprise a passage.

The molten metal pump may comprise a moving magnet pump (MMP) such as that described in M. G. Hvasta, W. K. Nollet, M. H. Anderson” Designing moving magnet pumps for high-temperature, liquid-metal systems”, Nuclear Engineering and Design, Volume 327, (2018), pp. 228-237 which is incorporated in its entirety by reference. The MMP may MMP's generate a travelling magnetic field with at least one of a spinning array of permanent magnets and polyphase field coils. In an embodiment, the MMP may comprise a multistage pump such as a two-stage pump for MHD recirculation and ignition injection. A two-stage MMP pump may comprise a motor such as an electric motor that turns a shaft. The two-stage MMP may further comprise two drums each comprising a set of circumferentially mounted magnets of alternating polarity fixed over the surface of each drum and a ceramic vessel having a U-shaped portion housing the drum wherein each drum may be rotated by the shaft to cause a flow of molten metal in the ceramic vessel. In another MMP embodiment, the drum of alternating magnets is replaced by two discs of alternating polarity magnets on each disc surface on opposite sites of a sandwiched strip ceramic vessel containing the molten metal that is pumped by rotation of the discs. In another embodiment, the vessel may comprise a magnetic field permeable material such as a non-ferrous metal such as stainless steel or ceramic such as one of the disclosure. The magnets may be cooled by means such as air-cooling or water-cooling to permit operation at elevated temperature.

An exemplary commercial AC EM pump is the CMI Novacast CA15 wherein the heating and cooling systems may be modified to support pumping molten silver. The heater of the EM pump tube comprising the inlet and outlet sections and the vessel containing the silver may be heated by a heater of the disclosure such as a resistive or inductively coupled heater. The heater such as a resistive or inductively coupled heater may be external to the EM pump tube and further comprise a heat transfer means to transfer heat from the heater to the EM pump tube such as a heat pipe. The heat pipe may operate at high temperature such as one with a lithium working fluid. The electromagnets of the EM pump may be cooled by systems of the disclosure such as by water-cooling loops and chiller.

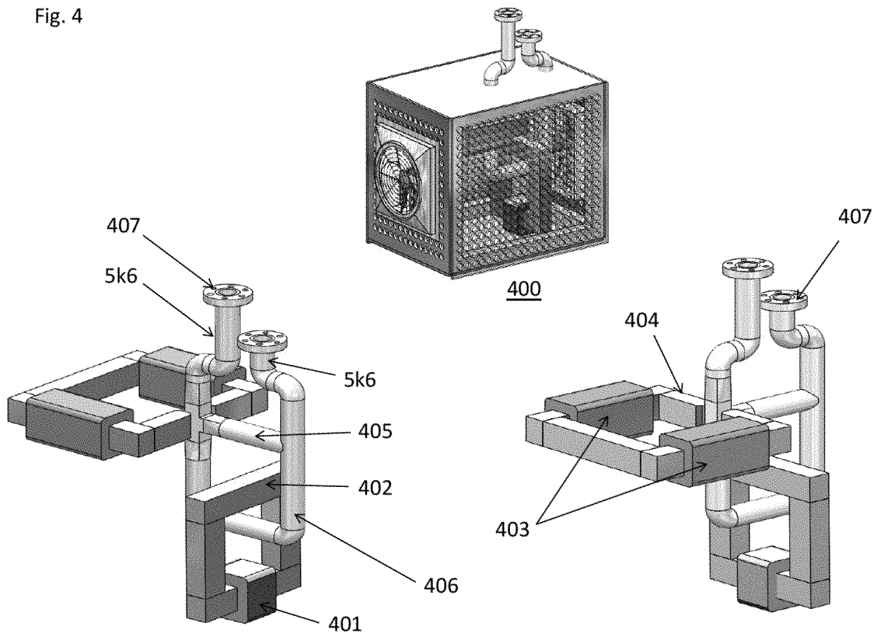

In an embodiment (FIGS. 4-22), the EM pump 400 may comprise an AC, inductive type wherein the Lorentz force on the silver is produced by a time-varying electric current through the silver and a crossed synchronized time-varying magnetic field. The time-varying electric current through the silver may be created by Faraday induction of a first time-varying magnetic field produced by an EM pump transformer winding circuit. The source of the first time-varying magnetic field may comprise a primary transformer winding 401, and the silver may serve as a secondary transformer winding such as a single turn shorted winding comprising an EM pump tube section of a current loop 405 and a EM pump current loop return section 406. The primary winding 401 may comprise an AC electromagnet wherein the first time-varying magnetic field is conducted through the circumferential loop of silver 405 and 406, the induction current loop, by a magnetic circuit or EM pump transformer yoke 402. The silver may be contained in a vessel such as a ceramic vessel such as one comprising a ceramic of the disclosure such as silicon nitride (MP 1900° C.), quartz, alumina, zirconia, magnesia, or hafnia. A protective SiO₂ layer may be formed on silicon nitrite by controlled passive oxidation. The vessel may comprise channels 405 and 406 that enclose the magnetic circuit or EM pump transformer yoke 402. The vessel may comprise a flattened section 405 to cause the induced current to have a component of flow in a perpendicular direction to the synchronized time-varying magnetic field and the desired direction of pump flow according to the corresponding Lorentz force. The crossed synchronized time-varying magnetic field may be created by an EM pump electromagnetic circuit or assembly comprising AC electromagnets 403 and EM pump electromagnetic yoke 404. The magnetic yoke 404 may have a gap at the flattened section of the vessel containing the silver. The electromagnet 401 of the EM pump transformer winding circuit 401a and the electromagnet 403 of the EM pump electromagnetic assembly 403c may be powered by a single-phase AC power source or other suitable power source known in the art. The magnet may be located close to the loop bend such that the desired current vector component is present. The phase of the AC current powering the transformer winding 401 and electromagnet winding 403 may be synchronized to maintain the desired direction of the Lorentz pumping force. The power supply for the transformer winding 401 and electromagnet winding 403 may be the same or separate power supplies. The synchronization of the induced current and B field may be through analog means such as delay line components or by digital means that are both known in the art. In an embodiment, the EM pump may comprise a single transformer with a plurality of yokes to provide induction of both the current in the closed current loop 405 and 406 and serve as the electromagnet and yoke 403 and 404. Due to the use of a single transformer, the corresponding inducted current and the AC magnetic field may be in phase.

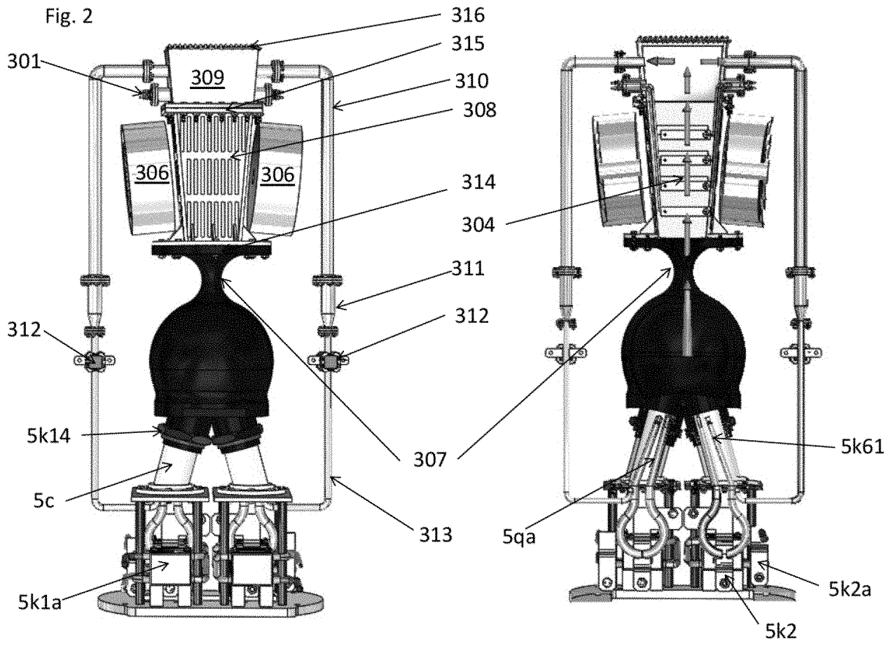

In an embodiment (FIGS. 2-22), the induction current loop may comprise the inlet EM pump tube 5k6, the EM pump tube section of the current loop 405, the outlet EM pump tube 5k6, and the path through the silver in the reservoir 5c that may comprise the walls of the inlet riser 5qa and the injector 561 in embodiments that comprise these components. The EM pump may comprise monitoring and control systems such as ones for the current and voltage of the primary winding and feedback control of SunCell power production with pumping parameters. Exemplary measured feedback parameters may be temperature at the reaction cell chamber 5b31 and electricity at MHD converter. The monitoring and control system may comprise corresponding sensors, controllers, and a computer. In an embodiment, the SunCell® may be at least one of monitored and controlled by a wireless device such as a cell phone. The SunCell® may comprise an antenna to send and receive data and control signals.

In an MHD converter embodiment having only one pair of electromagnetic pumps 400, each MHD return conduit 310 is extended and connects to the inlet of the corresponding electromagnetic pump 5kk. The connection may comprise a union such as a Y-union having an input of MHD return conduit 310 and the bosses of the base of the reservoir such as those of the reservoir baseplate assembly 409. In an embodiment comprising a pressurized SunCell® having an MHD converter, the injection side of the EM pumps, the reservoirs, and the reaction cell chamber 5b31 operate under high pressure relative to the MHD return conduit 310. The inlet to each EM pump may comprise only the MHD return conduit 310. The connection may comprise a union such as a Y-union having an input of MHD return conduit 310 and the boss of the base of the reservoir wherein the pump power prevents back flow from the inlet flow from the reservoir to the MHD return conduit 310.

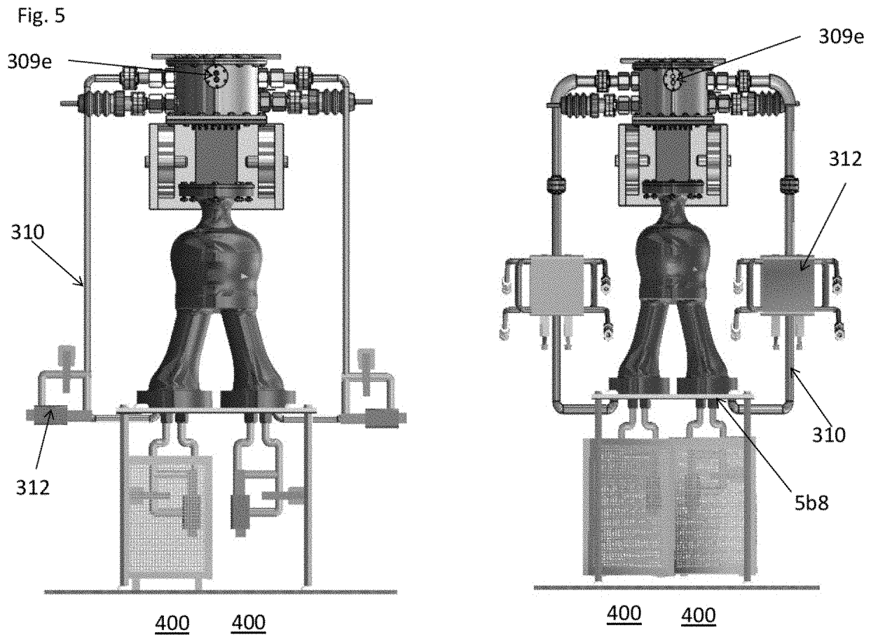

In an MHD power generator embodiment, the injection EM pumps and the MHD return EM pump may comprise any of the disclosure such as DC or AC conduction pumps and AC induction pumps. In an exemplary MHD power generator embodiment (FIG. 5), the injection EM pumps may comprise an induction EM pump 400, and the MHD return EM pump 312 may comprise an induction EM pump or a DC conduction EM pump. In another embodiment, the injection pump may further serve as the MHD return EM pump. The MHD return conduit 310 may input to the EM pump at a lower pressure position than the inlet from the reservoir. The inlet from MHD return conduit 310 may enter the EM pump at a position suitable for the low pressure in the MHD condensation section 309 and the MHD return conduit 310. The inlet from the reservoir 5c may enter at a position of the EM pump tube where the pressure is higher such as at a position wherein the pressure is the desired reaction cell chamber 5b31 operating pressure. The EM pump pressure at the injector section 5k61 may be at least that of the desired reaction cell chamber pressure. The inlets may attach to the EM pump at tube and current loop sections 5k6, 405, or 406.

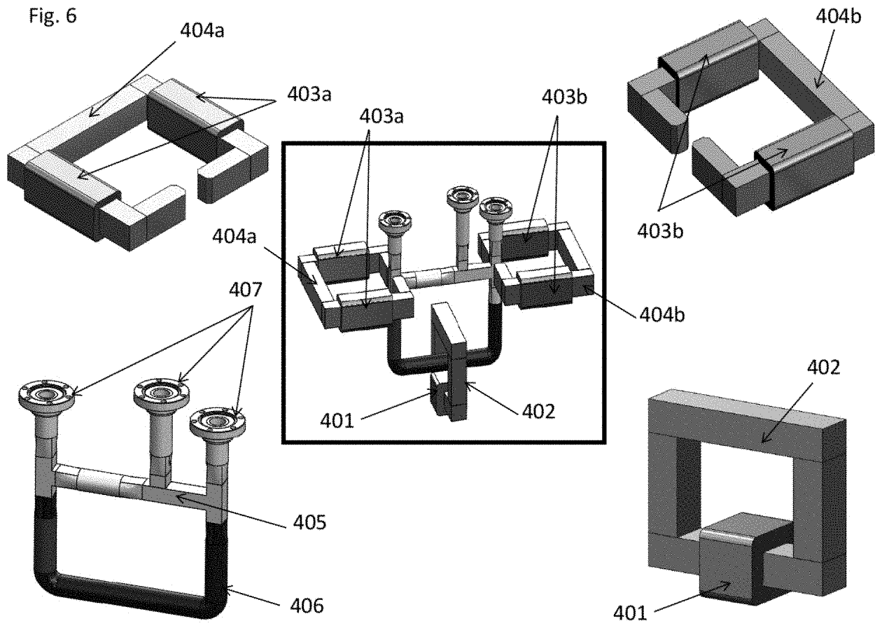

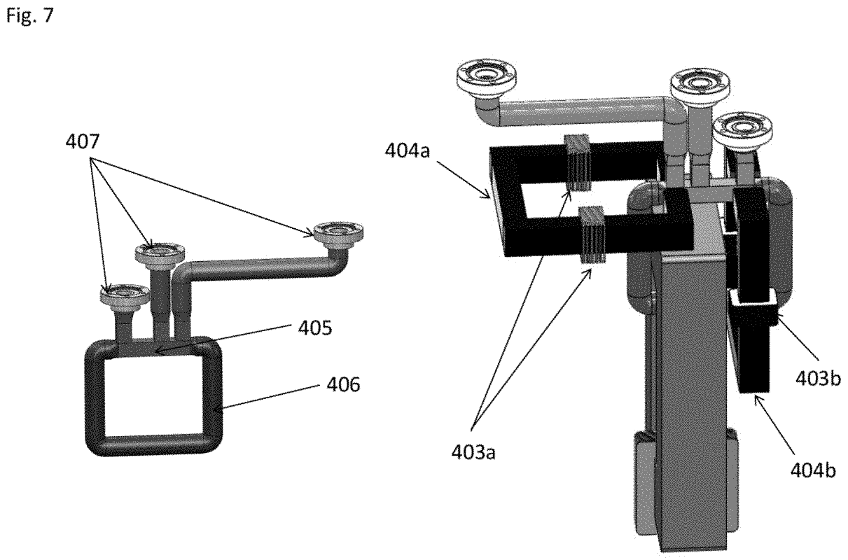

The EM pump may comprise a multistage pump (FIGS. 6-21). The multistage EM pump may receive the input metal flows such as that from the MHD return conduit 310 and that from the base of the reservoir 5c at different pump stages that each correspond to a pressure that permits essentially only forward molten metal flow out the EM pump outlet and injector 5k61. In an embodiment, the multistage EM pump assembly (FIG. 6) comprises at least one EM pump transformer winding circuit 401a comprising a transformer winding 401 and transformer yoke 402 through an induction current loop 405 and 406 and further comprises at least one AC EM pump electromagnetic circuit 403c comprising an AC electromagnet 403 and an EM pump electromagnetic yoke 404. The induction current loop may comprise an EM pump tube section 405 and an EM pump current loop return section 406. The electromagnetic yoke 404 may have a gap at the flattened section of the vessel or EM pump tube section of a current loop 405 containing the pumped molten metal such as silver. In an embodiment shown in FIG. 7, the induction current loop comprising EM pump tube section 405 may have inlets and outlets located offset from the bends for return flow in section 406 such that the induction current may be more transverse to the magnetic flux of the electromagnets 403a and 403b to optimize the Lorentz pumping force that is transverse to both the current and the magnetic flux. The pumped metal may be molten in section 405 and solid in the EM pump current loop return section 406.

In an embodiment, the multistage EM pump may comprise a plurality of AC EM pump electromagnetic circuits 403c that supply magnetic flux perpendicular to both the current and metal flow. The multistage EM pump may receive inlets along the EM pump tube section of a current loop 405 at locations wherein the inlet pressure is suitable for the local pump pressure to achieve forward pump flow wherein the pressure increases at the next AC EM pump electromagnetic circuit 403c stage. In an exemplary embodiment, the MHD return conduit 310 enters the current loop such the EM pump tube section of a current loop 405 at an inlet before a first AC electromagnet circuit 403c comprising AC electromagnets 403a and EM pump electromagnetic yoke 404a. The inlet flow from the reservoir 5c may enter after the first and before a second AC electromagnet circuit 403c comprising AC electromagnets 403b and EM pump electromagnetic yoke 404b wherein the pumps maintain a molten metal pressure in the current loop 405 that maintains a desired flow from each inlet to the next pump stage or to the pump outlet and the injector 5k61. The pressure of each pump stage may be controlled by controlling the current of the corresponding AC electromagnet of the AC electromagnet circuit. An exemplary transformer comprises a silicon steel laminated transformer core 402, and exemplary EM pump electromagnetic yokes 404a and 404b each comprise a laminated silicon steel (grain-oriented steel) sheet stack.

In an embodiment, the EM pump current loop return section 406 such as a ceramic channel may comprise a molten metal flow restrictor or may be filled with a solid electrical conductor such that the current of the current loop is complete while preventing molten metal back flow from a higher pressure to a lower pressure section of the EM pump tube. The solid may comprise a metal such as a stainless steel of the disclosure such as Haynes 230, Pyromet® alloy 625, Carpenter L-605 alloy, BioDur® Carpenter CCM® alloy, Haynes 230, 310 SS, or 625 SS. The solid may comprise a refractory metal. The solid may comprise a metal that is oxidation resistant. The solid may comprise a metal or conductive cap layer or coating such as iridium to avoid oxidation of the solid conductor.

In an embodiment, the solid conductor in the conduit 406 that provides a return current path but prevents silver black flow comprises solid molten metal such as solid silver. The solid silver may be maintained by maintaining a temperature at one or more locations along the path of the conduit 406 that is below the melting point of silver such that it maintains a solid state in at least a portion of the conduit 406 to prevent silver flow in the 406 conduit. The conduit 406 may comprise at least one of a heat exchanger such as a coolant loop, that absence of trace heating or insulation, and a section distanced from hot section 405 such that the temperature of at least one portion of the conduit 406 may be maintained below the melting point of the molten metal.

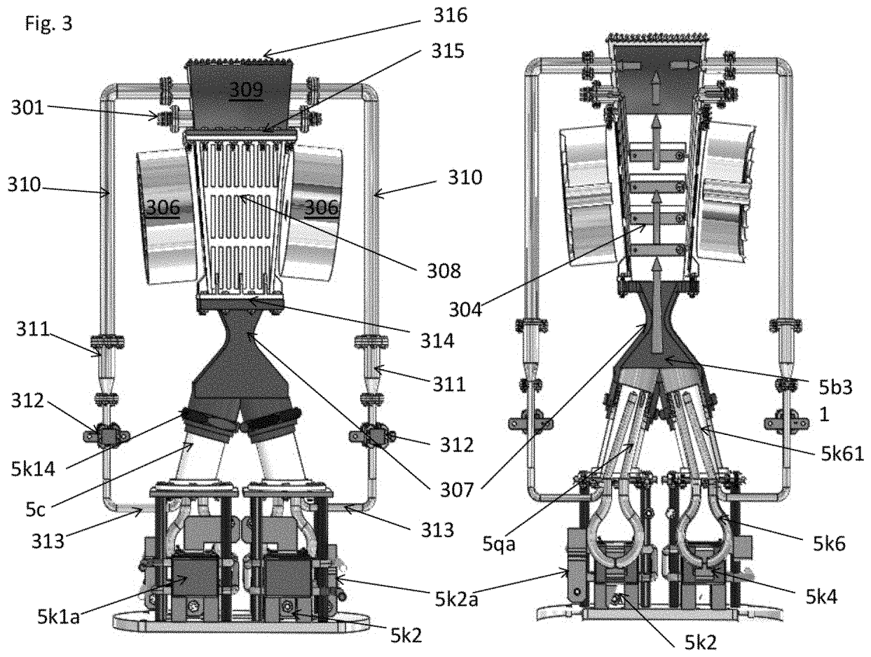

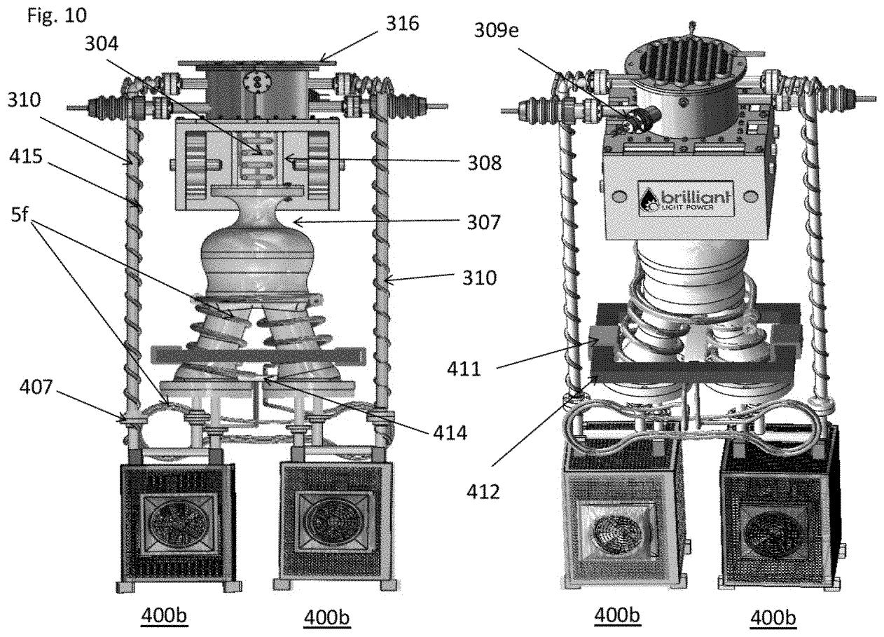

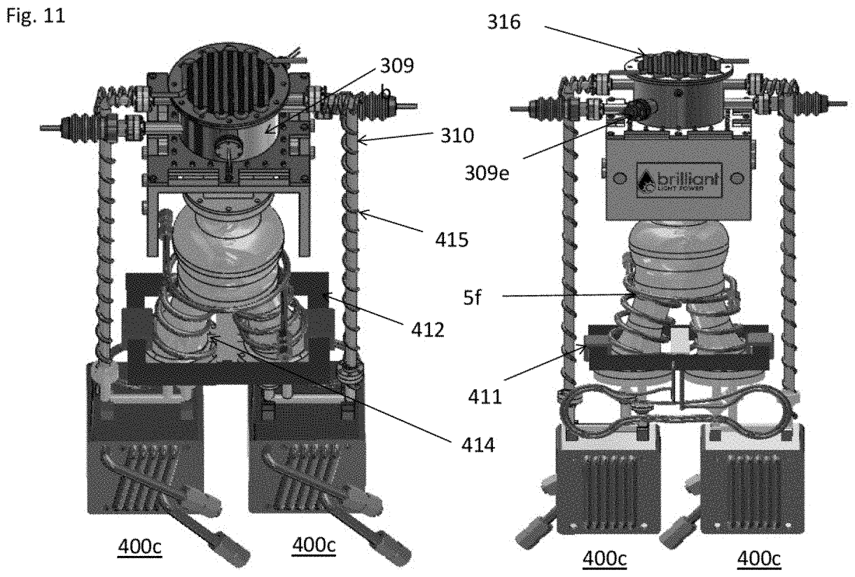

In an embodiment, the magnetic windings of at least one of the transformers and electromagnets are distanced from the EM pump tube section of a current loop 405 containing flowing metal by extension of at least one of the transformer magnetic yoke 402 and the electromagnetic circuit yoke 404. The extensions allow for at least one of more efficient heating such as inductively coupled heating of the EM pump tube 405 and more efficient cooling of at least one of the transformer windings 401, transformer yoke 402, and the electromagnetic circuits 403c comprising AC electromagnets 403 and EM pump electromagnetic yoke 404. In the case of a two-stage EM pump, the magnetic circuits may comprise AC electromagnets 403a and 403b and EM pump electromagnetic yokes 404a and 404b. At least one of the transformer yokes 402 and electromagnetic yokes 404 may comprise a ferromagnetic material with a high Curie temperature such as iron or cobalt. The windings may comprise high temperature insulated wire such as ceramic coated clad wire such as nickel clad copper wire such as Ceramawire HT. At least one of the EM pump transformer winding circuits or assemblies 401a and EM pump electromagnetic circuits or assemblies 403c may comprise a water-cooling system such as one of the disclosure such as one of the magnets 5k4 of the DC conduction EM pump (FIGS. 2-3). At least one of the induction EM pumps 400b may comprise an air-cooling system 400b (FIGS. 9-10). At least one of the induction EM pumps 400c may comprise a water-cooling system (FIG. 11). The cooling system may comprise heat pipe such as one of the disclosure. The cooling system may comprise a ceramic jacket to serve as a coolant conduit. The coolant system may comprise a coolant pump and a heat exchanger to reject heat to a load or ambient. The jacket may at least partially house the component to be cooled. The yoke cooling system may comprise an internal coolant conduit. The coolant may comprise water. The coolant may comprise silicon oil.

An exemplary transformer comprises a silicon steel laminated transformer core. The ignition transformer may comprise (i) a winding number in at least one range of about 10 to 10,000, 100 to 5000, and 500 to 25,000 turns; (ii) a power in at least one range of about 10 W to 1 MW, 100 W to 500 kW, 1 kW to 100 kW, and 1 kW to 20 kW, and (iii) a primary winding current in at least one range of about 0.1 A to 10,000 A, 1 A to 5 kA, 1 A to 1 kA, and 1 to 500 A. In an exemplary embodiment, the ignition current is in a voltage range of about 6 V to 10 V and the current is about 1000 A; so a winding with 50 turns operates at about 500 V and 20 A to provide an ignition current of 10 V at 1000 A. The EM pump electromagnets may comprise a flux in at least one range of about 0.01 T to 10 T, 0.1 T to 5 T, and 0.1 T to 2 T. In an exemplary embodiment, about 0.5 mm diameter magnet wire is maintained under about 200° C.

In an embodiment comprising a SunCell® that does not form an alloy or react with aluminum at the cell operating temperature, the molten metal may comprise aluminum. In an exemplary embodiment, the SunCell® such as one shown in FIGS. 4-21 comprises components that are in contact with the molten aluminum metal such as the reaction cell chamber 5b31 and the EM pump tubes 5k6 that comprise quartz or ceramic wherein the SunCell® further comprises inductive EM pumps and an induction ignition system.

At least one line (FIGS. 9-21) such as at least one of the MHD return conduit 310, EM pump reservoir line 416, and EM pump injection line 417 may be heated by a heater such as a resistive or inductively coupled heater. The inductively coupled heater may comprise an antenna 415 wrapped around the line wherein the antenna may be water-cooled. The components wrapped with the inductively coupled heater antenna such as 5f and 415 may comprise an inner layer of insulation. The inductively coupled heater antenna can serve a dual function or heating and water-cooling to maintain a desired temperature of the corresponding component. The SunCell may further comprise structural supports 418 that secure components such as the MHD magnet housing 306a, the MHD nozzle 307, and MHD channel 308, electrical output, sensor, and control lines 419 that may be mounted on the structural supports 418, and heat shielding such as 420 about the EM pump reservoir line 416, and EM pump injection line 417.

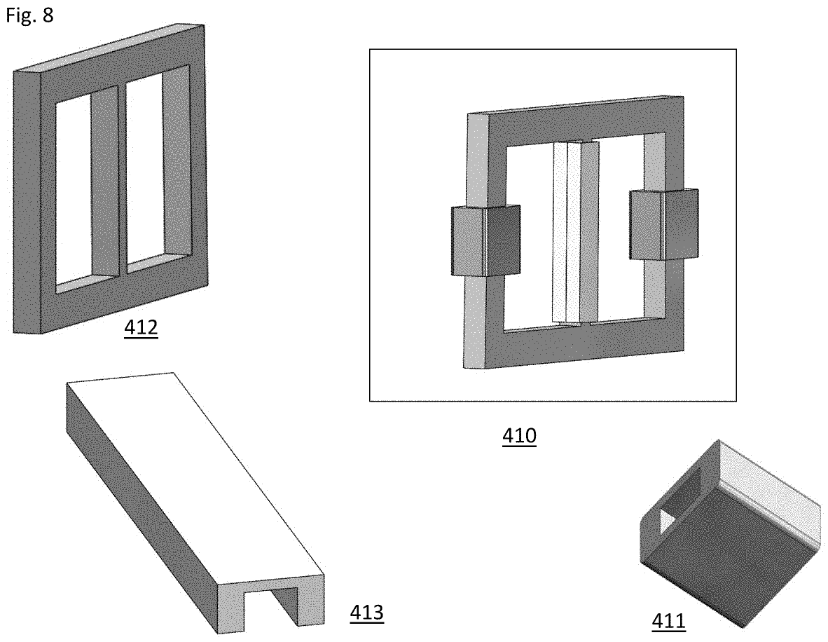

In an embodiment, the ignition bus bar such as 5k2a may comprise an electrode in contact with a portion of the solidified molten metal of a wet seal joint such as one at the reservoirs 5c. In another embodiment, the ignition system comprises an induction system (FIGS. 8-21) wherein the source of electricity applied to the conductive molten metal to cause ignition of the hydrino reaction provides an induction current, voltage, and power. The ignition system may comprise an electrode-less system wherein the ignition current is applied by induction by an induction ignition transformer assembly 410. The induction current may flow through the intersecting molten metal streams from the plurality of injectors maintained by the pumps such as the EM pumps 400. In an embodiment, the reservoirs 5c may further comprise a ceramic cross connecting channel 414 such as a channel between the bases of the reservoirs 5c. The induction ignition transformer assembly 410 may comprise an induction ignition transformer winding 411 and an induction ignition transformer yoke 412 that may extend through the induction current loop formed by the reservoirs 5c, the intersecting molten metal streams from the plurality of molten metal injectors, and the cross-connecting channel 414. The induction ignition transformer assembly 410 may be similar to that of the EM pump transformer winding circuit 401a.

In an embodiment, the ignition current source may comprise an AC, inductive type wherein the current in the molten metal such as silver is produced by Faraday induction of a time-varying magnetic field through the silver. The source of the time-varying magnetic field may comprise a primary transformer winding, an induction ignition transformer winding 411, and the silver may at least partially serve as a secondary transformer winding such as a single turn shorted winding. The primary winding 411 may comprise an AC electromagnet wherein an induction ignition transformer yoke 412 conducts the time-varying magnetic field through a circumferential conducting loop or circuit comprising the molten silver. In an embodiment, the induction ignition system may comprise a plurality of closed magnetic loop yokes 412 that maintain time varying flux through the secondary comprising the molten silver circuit. At least one yoke and corresponding magnetic circuit may comprise a winding 411 wherein the additive flux of a plurality of yokes 412 each with a winding 411 may create induction current and voltage in parallel. The primary winding turn number of each yoke 412 winding 411 may be selected to achieve a desired secondary voltage from that applied to each winding, and a desired secondary current may be achieved by selecting the number of closed loop yokes 412 with corresponding windings 411 wherein the voltage is independent of the number of yokes and windings, and the parallel currents are additive.

The transformer electromagnet may be powered by a single-phase AC power source or other suitable power source known in the art. The transformer frequency may be increased to decrease the size of the transformer yoke 412. The transformer frequency may be in at least range of about 1 Hz to 1 MHz, 1 Hz to 100 kHz, 10 Hz to 10 kHz, and 10 Hz to 1 kHz. The transformer power supply may comprise a VFD-variable frequency drive. The reservoirs 5c may comprise a molten metal channel such as the cross-connecting channel 414 that connects the two reservoirs 5c. The current loop enclosing the transformer yoke 412 may comprise the molten silver contained in the reservoirs 5c, the cross-connecting channel 414, the silver in the injector tube 5k61, and the injected streams of molten silver that intersect to complete the induction current loop. The induction current loop may further at least partially comprise the molten silver contained in at least one of the EM pump components such as the inlet riser 5qa, the EM pump tube 5k6, the bosses, and the injector 5k61.

The cross-connecting channel 414 may be at the desired level of the molten metal such as silver in the reservoirs. Alternatively, the cross-connecting channel 414 may be at a position lower than the desired reservoir molten metal level such that the channel is continuously filled with molten metal during operation. The cross-connecting channel 414 may be located towards the base of the reservoirs 5c. The channel may form part of the induction current loop or circuit and further facilitate molten metal flow from one reservoir with a higher silver level to the other with a lower level to maintain the desired levels in both reservoirs 5c. A differential in molten metal head pressure may cause the metal flow between reservoirs to maintain the desired level in each. The current loop may comprise the intersecting molten metal streams, the injector tubes 5k61, a column of molten metal in the reservoirs 5c, and the cross-connecting channel 414 that connects the reservoirs 5c at the desired molten silver level or one that is lower than the desired level. The current loop may enclose the transformer yoke 412 that generates the current by Faraday induction. In another embodiment, at least one EM pump transformer yoke 402 may further comprise the induction ignition transformer yoke 412 to generate the induction ignition current by additionally supplying the time-varying magnetic field through an ignition molten metal loop such as the one formed by the intersecting molten metal streams and the molten metal contained in the reservoirs and the cross connecting channel 414. The reservoirs 5c and the channel 414 may comprise an electrical insulator such as a ceramic. The induction ignition transformer yoke 412 may comprise a cover 413 that may comprise at least one of an electrical insulator and a thermal insulator such as a ceramic cover. The section of the induction ignition transformer yoke 412 that extends between the reservoirs that may comprise circumferentially wrapped inductively coupled heater antennas such as helical coils may be thermally or electrically shielded by the cover 413. The ceramic of at least one of the reservoirs 5c, the channel 414, and the cover 413 may be one of the disclosure such as silicon nitride (MP 1900° C.), quartz such as fused quartz, alumina, zirconia, magnesia, or hafnia. A protective SiO₂ layer may be formed on silicon nitride by controlled passive oxidation.

In an embodiment, the cross-connecting channel 414 maintains the reservoir silver levels near constant. The SunCell® may further comprise submerged nozzles 5q of the injector 5k61. The depth of each submerged nozzle and therefore the head pressure through which the injector injects may remain essentially constant due to the about constant molten metal level of each reservoir 5c. In an embodiment comprising the cross-connecting channel 414, inlet riser 5qa may be removed and replaced with a port into the reservoir boss or EM pump reservoir line 416.

The SunCell® may comprise a heat source to heat at least one component during operational startup. The heat source may be selected to at least one of avoid excessive heating of the yoke of at least one of the inductive EM pump and the inductive ignition system. The heat source may be permissive of high efficiently heat transfer to an external heat exchanger of a thermal power source embodiment of the SunCell®. The heat may maintain the molten metal for the molten metal injection system such as the dual molten metal injection system comprising EM pumps. In an embodiment, the SunCell® comprises a heater or source of heating such as at least one of a chemical heat source such as a catalytic chemical heat source, a flame or combustion heat source, a resistive heater such as a refractory filament heater, a radiative heating source such as an infrared light source such as a heat lamp or high-power diode light source, and an inductively coupled heater.

The radiative heating source may comprise a means to scan the radiant power over a surface to be heated. The scanning means may comprise a scanning mirror. The scanning means may comprise at least one mirror and may further comprise a means to move the mirror over a plurality of positions such as a mechanical, pneumatic, electromagnetic, piezoelectric, hydraulic, and other actuator known in the art.

In an embodiment, the heater 415 may comprise a resistive heater such as one comprising wire such as Kanthal or other of the disclosure. The resistive heater may comprise a refractory resistive filament or wire that may be wrapped around the components to be heated. Exemplary resistive heater elements and components may comprise high temperature conductors such as carbon, Nichrome, 300 series stainless steels, Incoloy 800 and Inconel 600, 601, 718, 625, Haynes 230, 188, 214, Nickel, Hastelloy C, titanium, tantalum, molybdenum, TZM, rhenium, niobium, and tungsten. The filament or wire may be potted in a potting compound to protect it from oxidation. The heating element as filament, wire, or mesh may be operated in vacuum to protect it from oxidation. An exemplary heater comprises Kanthal A-1 (Kanthal) resistive heating wire, a ferritic-chromium-aluminum alloy (FeCrAl alloy) capable of operating temperatures up to 1400° C. and having high resistivity and good oxidation resistance. Another exemplary filament is Kanthal APM that forms a non-scaling oxide coating that is resistant to oxidizing and carburizing environments and can be operated to 1475° C. The heat loss rate at 1375 K and an emissivity of 1 is 200 kW/m² or 0.2 W/cm². Commercially available resistive heaters that operate to 1475 K have a power of 4.6 W/cm². The heating may be increased using insulation external to the heating element.

An exemplary heater 415 comprises Kanthal A-1 (Kanthal) resistive heating wire, a ferritic-chromium-aluminum alloy (FeCrAl alloy) capable of operating temperatures up to 1400° C. and having high resistivity and good oxidation resistance. Additional FeCrAl alloys for suitable heating elements are at least one of Kanthal APM, Kanthal A F, Kanthal D, and Alkrothal. The heating element such as a resistive wire element may comprise a NiCr alloy that may operate in the 1100° C. to 1200° C. range such as at least one of Nikrothal 80, Nikrothal 70, Nikrothal 60, and Nikrothal 40. Alternatively, the heater 415 may comprise molybdenum disilicide (MoSi₂) such as at least one of Kanthal Super 1700, Kanthal Super 1800, Kanthal Super 1900, Kanthal Super RA, Kanthal Super ER, Kanthal Super HT, and Kanthal Super NC that is capable of operating in the 1500° C. to 1800° C. range in an oxidizing atmosphere. The heating element may comprise molybdenum disilicide (MoSi₂) alloyed with Alumina. The heating element may have an oxidation resistant coating such as an Alumina coating. The heating element of the resistive heater 415 may comprise SiC that may be capable of operating at a temperature of up to 1625° C. The heater may comprise insulation to increase at least one of its efficiency and effectiveness. The insulation may comprise a ceramic such as one known by those skilled in the art such as an insulation comprising alumina-silicate. The insulation may be at least one of removable or reversible. The insulation may be removed following startup to more effectively transfer heat to a desired receiver such as ambient surroundings or a heat exchanger. The insulation may be mechanically removed. The insulation may comprise a vacuum-capable chamber and a pump, wherein the insulation is applied by pulling a vacuum, and the insulation is reversed by adding a heat transfer gas such as a noble gas such as helium. A vacuum chamber with a heat transfer gas such as helium that can be added or pumped off may serve as adjustable insulation.

The resistive heater 415 may be powered by at least one of series and parallel wired circuits to selectively heat SunCell® different components. The resistive heating wire may comprise a twisted pair to prevent interference by systems that cause a time-varying field such as induction systems such as at least one induction EM pump, an induction ignition system, and electromagnets. The resistive heating wires may be oriented such that any linked time-varying magnetic flux is minimized. The wire orientation may be such that any closed loops are in a plane parallel with the magnetic flux.

At least one of the catalytic chemical heat source and flame or combustion heat source may comprise a fuel such as a hydrocarbon such as propane and oxygen or hydrogen and oxygen. The SunCell® may comprise an electrolyzer that may supply about a stoichiometric mixture of H₂ and O₂. The electrolyzer may comprise a gas separator to supply at least one of H₂ or O₂ separately. The electrolyzer may comprise a high-pressure electrolysis unit such as one having a proton-exchange membrane for a separate source of at least one of H₂ and O₂. The electrolysis unit may be powered by a battery during startup. The SunCell® may comprise a gas storage and supply system for H₂ and O₂ gas from H₂O electrolysis. The gas storage may store at least one of the H₂ and O₂ gas from H₂O electrolysis over time. The electrolysis power over time may be provided by the SunCell® or the battery. The storage may release the gases as fuel to the heater at a rate to achieve higher power than that available from the battery. Electrolysis can be better than 90% efficient. Hydrogen-oxygen recombination on a catalyst and combustion can be almost 100% efficient. The flame heater may comprise at least one burner and a means to move or scan the at least one burner over a plurality of positions such that the flame covers a larger area. The scanner may comprise at least one of a cam and a mechanical, pneumatic, electromagnetic, piezoelectric, hydraulic, and other actuator known in the art.

In an embodiment, the heating system comprises at least one of pipes, manifolds, and at least one housing to supply at least one fuel or fuel mixture such as at least one of H₂ and O₂ to a surface impregnated with a catalyst to burn the fuel gases over the surface of at least one component of the SunCell® to serve as the heating source. The maximum temperature of a stoichiometric mixture of hydrogen and oxygen is about 2800° C. The surface of any component to be heated may be coated with a hydrogen-oxygen recombiner catalyst such as Raney nickel, copper oxide, or a precious metal such as platinum, palladium, ruthenium, iridium, rhenium, or rhodium. Exemplary catalytic surfaces are at least one of Pd, Pt, or Ru coated alumina, silica, quartz, and alumina-silicate. The flame heater may comprise a heated filament wherein the elevated temperature of the filament may be at least partially maintained by the hydrogen-oxygen recombination reaction.

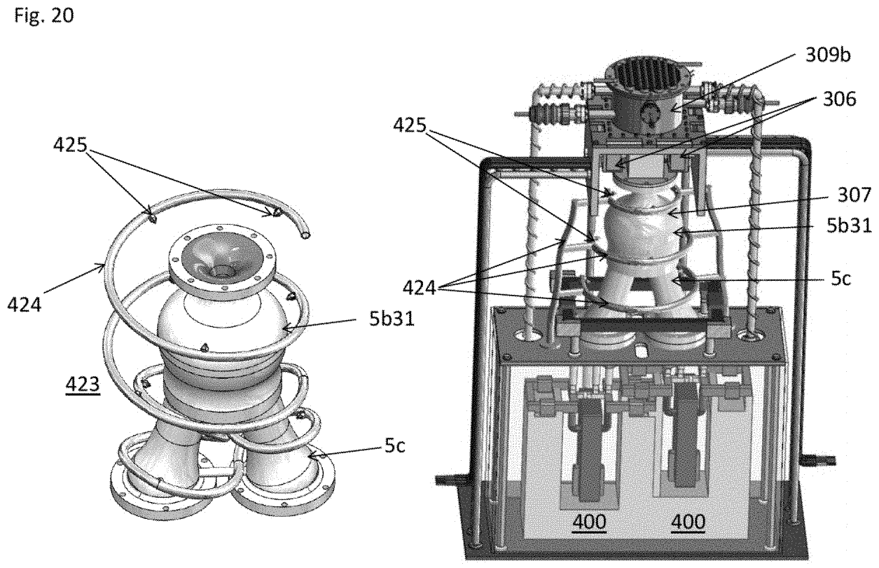

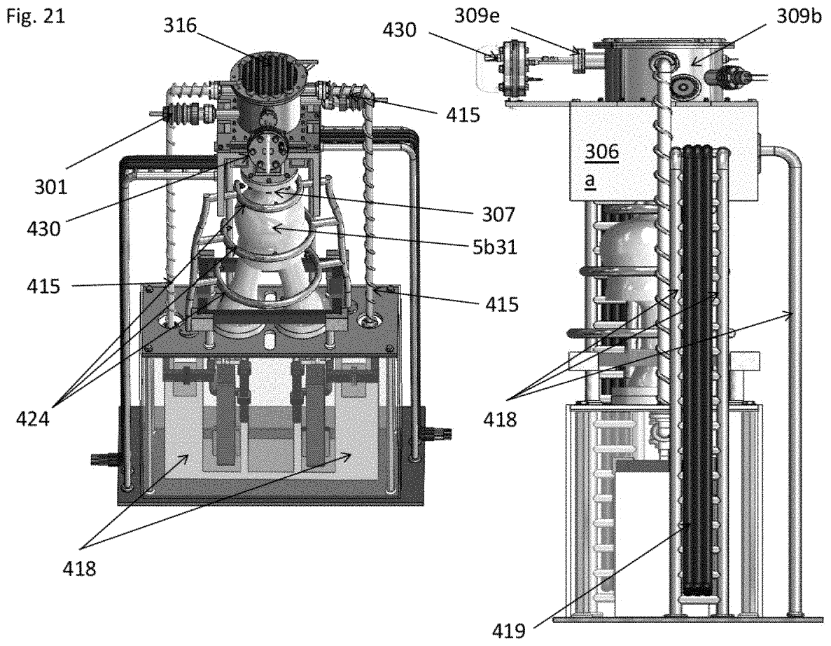

In an embodiment, the source of H₂+O₂ gas may comprise an oxyhydrogen torch system such as one comprising a design like a commercially unit such as Honguang H160 Oxygen Hydrogen HHO Gas Flame Generator. Given the electrolysis voltage of H₂O 1.48 V and a typical electrolysis efficiency of about 90%, the required current is about 0.75 A per 1 W burner. In an embodiment, a plurality of burners may be supplied by a common gas line such as one that supplies a stoichiometric mixture of H₂+O₂. The flame heater may comprise a plurality of such gas lines and burners. The lines and burners may be arranged in a suitable structure to achieve the desired heating of the SunCell® components. The structure may comprise at least one helix such as the single helix oxyhydrogen flame heater 423 shown in FIGS. 20-21 having a gas line 424 and a plurality of burners or nozzles 425. In an alternative design also shown in FIGS. 20-21, the oxyhydrogen flame heater 423 may comprise a plurality of gas lines 424 and a plurality of burners or nozzles 425 to achieve a series of annular rings about the SunCell® components to be heated. A further exemplary structure to give a good heating surface coverage of the SunCell® components is a DNA-like double helix or a triple helix. Linear shaped components such as MHD return conduit 310 may be heated by at least one linear-burner structure.

In an embodiment, the heater such as a resistive, burner, or heat exchanger type may heat from inside of the SunCell component such as inside of the reservoir 5c through an internal well that may be cast in the bottom of the reservoir for example.

The ignition current may be time varying such as about 60 Hz AC, but may have other characteristics and waveforms such as a waveform having a frequency in at least one range of 1 Hz to 1 MHz, 10 Hz to 10 kHz, 10 Hz to 1 kHz, and 10 Hz to 100 Hz, a peak current in at least one range of about 1 A to 100 MA, 10 A to 10 MA, 100 A to 1 MA, 100 A to 100 kA, and 1 kA to 100 kA, and a peak voltage in at least one range of about 1 V to 1 MV, 2V to 100 kV, 3V to 10 kV, 3V to 1 kV, 2V to 100V, and 3V to 30V wherein the waveform may comprise a sinusoid, a square wave, a triangle, or other desired waveform that may comprise a duty cycle such as one in at least one range of 1% to 99%, 5% to 75%, and 10% to 50%. To minimize the skin effect at high frequency, the windings such as 411 of the ignition system may comprise at least one of braided, multiple-stranded, and Litz wire.

In an embodiment, controlling the frequency of the ignition current controls the reaction rate of the hydrino reaction. Controlling the frequency of the power supply of the induction ignition winding 411 may control the frequency of the ignition current. The ignition current may be an induction current caused by a time varying magnetic field. The time varying magnetic field may influence the hydrino reaction rate. In an embodiment, at least one of the strength and the frequency of the time varying magnetic field is controlled to control the hydrino reaction rate. The strength and the frequency of the time varying magnetic field may be controlled by controlling the power supply of the induction ignition winding 411.

In an embodiment, the ignition frequency is adjusted to cause a corresponding frequency of hydrino power generation in a least one of the reaction cell chamber 5b31 and the MHD channel 308. The frequency of the power output such as about 60 Hz AC may be controlled by controlling the ignition frequency. The ignition frequency can be adjusted by varying the frequency of the time-varying magnetic field of the induction ignition transformer assembly 410. The frequency of the induction ignition transformer assembly 410 may be adjusted by varying the frequency of the current of the induction ignition transformer winding 411 wherein the frequency of the power to the winding 411 may be varied. The time-varying power in the MHD channel 308 may prevent shock formation of the aerosol jet flow. In another embodiment, the time-varying ignition may drive a time-varying hydrino power generation that results in a time-varying electrical power output. The MHD converter may output AC electricity that may also comprise a DC component. The AC component may be used to power at least one winding such as at least one of one or more of the transformer and the electromagnet windings such as at least one of the winding of the EM pump transformer winding circuit 401a and the winding of the electromagnets of the EM pump electromagnetic circuit 403c.

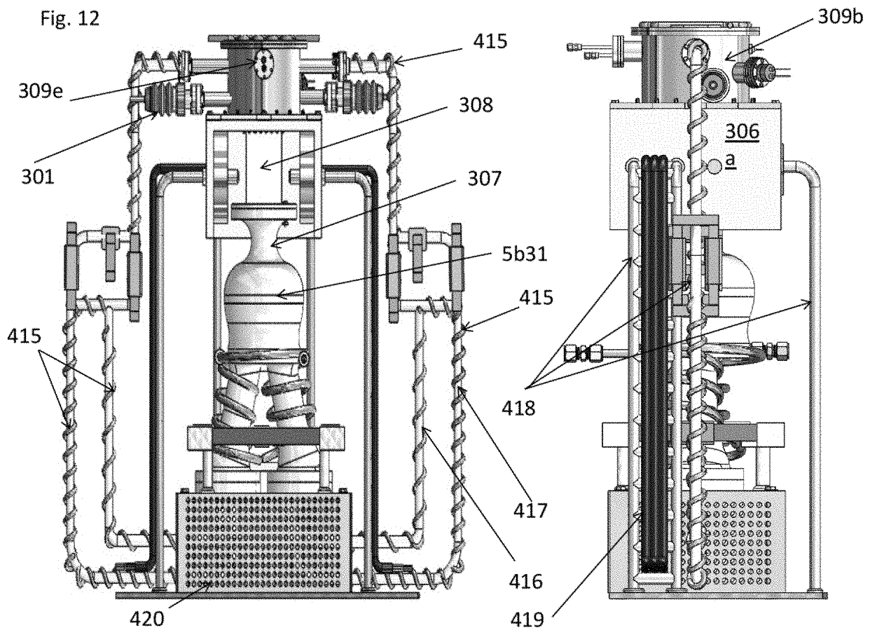

The pressurized SunCell® having an MHD converter may operate without a dependency on gravity. The EM pumps such as 400 such as two-staged air-cooled EM pumps 400b may be located in a position to optimize at least one of the packing and the minimization of the molten metal inlet and outlet conduits or lines. An exemplary packaging is one wherein the EM pumps are located midway between the end of the MHD condensation section 309 and the base of the reservoirs 5c (FIGS. 12-19).

In an embodiment, the working medium comprises a metal and a gas that is soluble in the molten metal at low temperature and insoluble or less soluble in the molten metal at elevated temperature. In an exemplary embodiment, the working medium may comprise at least one of silver and oxygen. In an embodiment, the oxygen pressure in the reaction cell chamber is maintained at a pressure that substantially prevents the molten metal such a silver form undergoing vaporization. The hydrino reaction plasma may heat the oxygen and liquid silver to a desired temperature such as 3500K. The mixture comprising the working medium may flow under pressure such as 25 atm through a tapered MHD channel wherein the pressure and temperature drop as the thermal energy is converted into electricity. As the temperature drops, the molten metal such as silver may absorb the gas such as oxygen. Then, the liquid may be pumped back to the reservoir to be recycled in the reaction cell chamber wherein the plasma heating releases the oxygen to increase the maintain the desired reaction cell chamber pressure and temperature condition to drive the MHD conversion. In an embodiment, the temperature of the silver at the exit of the MHD channel is about the melting point of the molten metal wherein the solubility of oxygen is about 20 cm³ of oxygen (STP) to 1 cm³ of silver at one atm O₂. The recirculation pumping power for the liquid comprising the dissolved gas may be much less than that of the free gas. Moreover, the gas cooling requirements and MHD converter volume to drop the pressure and temperature of the free gas during a thermodynamic power cycle may be substantially reduced.

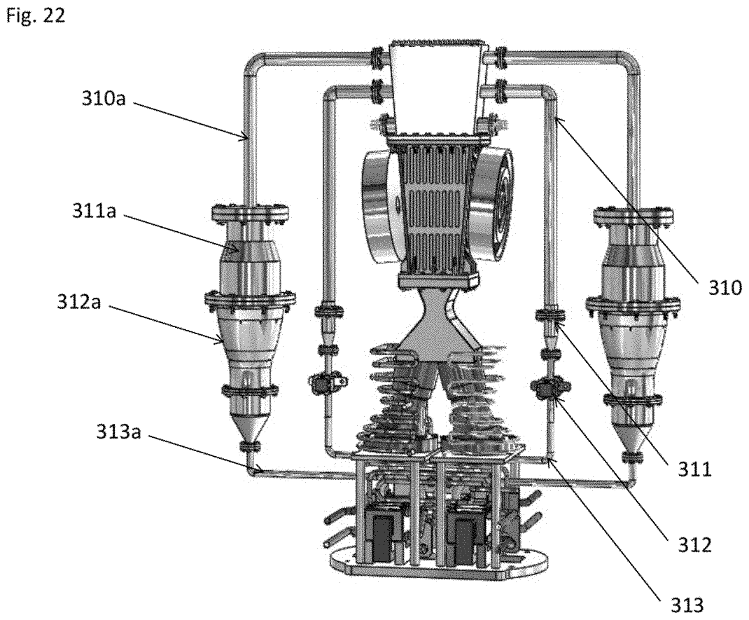

In an embodiment, the working medium metal may form an aerosol of nanoparticles. The nanoparticle formation may be facilitated by the presence of a gas in contact with the working medium. In an embodiment, the molten metal and working medium comprise silver that forms silver nanoparticles in the presence of oxygen. The nanoparticles may be accelerated in the MHD nozzle 307 wherein the kinetic energy of the flowing jet is converted into electricity in the MHD channel 308. The pressure of oxygen may be sufficient to serve as an accelerator gas in the nozzle 307. In an embodiment, the silver aerosol is almost pure liquid plus oxygen at the exit of the MHD nozzle 307. The solubility of oxygen atoms in silver increases as the temperature approaches the melting point wherein the solubility is up to mole fraction of of 25% [J. Assal, B. Hallstedt, and L. J. Gauckler, “Thermodynamic assessment of the silver-oxygen system”, J. Am Ceram. Soc. Vol. 80 (12), (1997), pp. 3054-3060]. The silver absorbs the oxygen at the MHD channel 308 such as at the exit and both the liquid silver and oxygen are recirculated. The oxygen may be recirculated as gas absorbed in molten silver. In an embodiment, the oxygen is released in the reaction chamber 5b31 to regenerate the cycle. The temperature of the silver above the melting point also serves as a means for recirculation or regeneration of thermal power. In an embodiment, silver aerosol is accelerated in a converging-diverging nozzle such as a de Laval nozzle by a gas such as at least one of oxygen and a noble gas such as argon or helium. The MHD working medium, the medium that flows through the MHD channel that possesses kinetic energy and electrical conductivity, may comprise silver aerosol, the accelerating gas, and silver vapor. In the case that the working medium comprises oxygen and silver, the working medium may further comprise oxygen absorbed in liquid silver that may be in the form of fine liquid particles or aerosol. The working medium may be recirculated at the end of the MHD channel by at recirculator such as at least one of a pump such as an EM pump 312 and a compressor (FIG. 22). The recirculator comprising a a MHD return gas pump or compressor 312a may further comprise a MHD return gas conduit 310a, a MHD return gas reservoir 311a, and a MHD return gas tube 313a. The recirculator may recirculate at least one of silver vapor, liquid silver, and accelerating gas in the working medium. The liquid silver may be in the form of aerosol such that the recirculation of about all of the species of the working medium may be recirculated with a gas pump such as a compressor. The accelerating gas may comprise oxygen to cause liquid silver to form or be maintained as silver aerosol to facilitate the recirculation by the gas pump. The accelerating gas such as oxygen may comprise the majority of the mole fraction of the working medium. The accelerating gas mole fraction may be in at least one range of about 50-99 mol %, 50-95 mol %, and 50-90 mol %. In another embodiment, the liquid silver may be recirculated by a liquid metal pump such as one of the disclosure such as an EM pump. In an embodiment at least one of the accelerator gas such as oxygen and the liquid metal such as silver are recirculated by the EM pump wherein the oxygen may be absorbed by the molten silver to facilitate its pumping by the EM pump.

In an embodiment, the MHD converter comprises a type of liquid metal magnetohydrodynamic (LMMHD) converter wherein the kinetic energy of the conductive plasma jet from the nozzle 307 is converted to electricity by the MHD channel 308. The kinetic energy input power Pᵢₙₚᵤₜ at the entrance of the MHD channel is given by the mass flow rate \dot{m} at its velocity ν.

$${P}_{i n p u t} = 0.5 \dot{m} {v}^{2} \qquad ( 39 )$$

The Lorentz force F_{L} is proportional to the flow velocity:

dF_{L}=σvB²(1−W)d²dx (40)

wherein σ is the flow conductivity, ν is the flow velocity, B is the magnetic field strength, W is the loading factor (ratio of the electric field across the load to the open circuit electric field), d is the electrode separation, and dx is the differential distance along the channel axis. Then, the change in velocity with channel distance is proportional to the channel distance

$$\frac{d v}{d x} = - kv \qquad ( 41 )$$

wherein as an approximation k is a treated as a constant determined by the boundary conditions:

$$v = {v}_{0} {e}^{- kx} \qquad ( 42 )$$

The constant is determined from the Lorentz force (Eq. (40)) that can be rearranged as

$$\begin{matrix}\frac{{dF}_{L}}{dx} = \frac{dm}{dt} \frac{dv}{dt} = \dot{m} \frac{dv}{dx} = σ {vB}^{2} ( 1 - W ) {d}^{2} \\ or & ( 43 ) \\ \frac{dv}{dx} = \frac{σ {vB}^{2} ( 1 - W ) {d}^{2}}{\dot{m}} & ( 44 )\end{matrix}$$

By comparing Eq. (6) to Eq. (3) the constant is

$$k = \frac{σ {B}^{2} ( 1 - W ) {d}^{2}}{\dot{m}} \qquad ( 45 )$$

By combining Eq. (42) and Eq. (45), the velocity as a function of channel distance is

$$v = {v}_{0} {e}^{- \frac{σ {B}^{2} ( 1 - W ) {d}^{2}}{\dot{m}} x} \qquad ( 46 )$$

The electrical power P_{electric} conversion in the MHD channel is given by

$$\begin{matrix}{P}_{electic} = VI = ELJ = EL σ ( vB - E ) A \\ = vBWL σ ( vB - WvB ) {d}^{2} = σ {v}^{2} {B}^{2} W ( 1 - W ) {Ld}^{2}\end{matrix} \qquad ( 47 )$$

wherein V is the MHD channel voltage, I is the channel current, E is the channel electric field, J is the channel current density, L is the channel length, and A is the current cross-sectional area (the nozzle exit area). From Eqs. (46-47), the corresponding power of the channel is given by

$$\begin{matrix}P = {\int }_{0}^{L} σ {v}_{0}^{2} {e}^{- \frac{2 σ {B}^{2} ( 1 - W ) {d}^{2}}{\dot{m}} x} {B}^{2} W ( 1 - W ) {d}^{2} dx \\ = 0.5 \dot{m} {v}_{0}^{2} W ( 1 - {e}^{- \frac{2 σ {B}^{2} ( 1 - W ) {d}^{2}}{\dot{m}} L} )\end{matrix} \qquad ( 48 )$$

The conductivity of high-pressure silver vapor plasma was determined by ANSYS modeling to be 10⁶ S/m. In the case that the mass flow \dot{m} is 0.5 kg/s, the conductivity σ is conservatively 500,000 S/m, the velocity is 1200 m/s, the magnetic flux B is 0.1 T, the load factor W is 0.7, the channel width and the electrode separation d of the exemplary straight square rectangular channel is 0.1 m, and the channel length L is 0.25 m, the power parameters are:

$$\begin{matrix}{P}_{input} = 360 kW & ( 49 ) \\ {P}_{electric} = 252 kW & ( 50 ) \\ {P}_{density} = 101 kW \text{/} liter & ( 51 ) \\ η = \frac{{P}_{electric}}{{P}_{input}} = 70 \% & ( 52 )\end{matrix}$$

wherein P_{electric} is the electrical power applied to an external load, P_{density} is the power density, and η is the power conversion efficiency. With high velocity and conductivity, the efficiency converges to loading factor W of the MHD channel, and the load-applied power converges to the kinetic energy power input to the MHD channel 0.5\dot{m}v² times the loading factor W of the MHD channel. The remainder of the power is dissipated in the internal MHD channel resistance.

In an embodiment, the LMMHD-type cycle comprises a powerful, highly-conductive jet flow forms comprising an oxygen and silver nanoparticle aerosol that is facilitated by two unique properties of silver and oxygen at silver's melting point. In the presence of oxygen, molten silver forms nanoparticles at high rates that behave similarly to large molecules that approximately obey the ideal gas law. The aerosol forms at the melting point of silver (962° C.); thus, a molecular gas having thermodynamic properties akin to silver atoms can form at a temperature well below the silver boiling point of 2162° C. This unique property of silver facilitates a thermodynamic cycle avoiding the input of the very high heat of valorization of 254 kJ/mole that is lost at the end MHD channel during condensation and recycling in a traditional gas expansion cycle. Moreover, molten silver at its melting point temperature can absorb an enormous amount of oxygen gas that may dissolve in the melted siliver at the end of MHD channel and be electromagnetically (EM) pumped with the molten silver to be recirculated to the reaction cell chamber. The high temperature in the reaction cell chamber causes the oxygen to be released to serve as the accelerator gas of the resulting oxygen and silver aerosol. The thermal power released by the hydrino reaction in the reaction cell chamber causes a high pressure rise and a high-powder silver plasma jet exists the MHD nozzle and enters the MHD channel wherein MHD kinetic to electric power conversion occurs. The efficiency can be very high since (i) the channel efficiency approaches the loading factor as shown by Eq. (52), (ii) the residual kinetic energy that is dissipated in the channel heats the aerosol that is conserved as an addition to the thermal energy inventory of the aerosol that is condensed or coalesced at the end of the MHD channel and returned with the total thermal inventory to the reaction cell chamber, and (iv) the accelerator gas is returned by very low power electromagnetic pumping of the molten metal carrying the gas in solution rather than by very energy intensive multistage intercooled gas compression of the gas. The pump power Pₚᵤₘₚ for the 0.5 kg/s silver aerosol flow that can provide 252 kW of electricity (Eq. (50)) is given by the product of the mass flow \dot{m}, times the reaction chamber pressure P of 5×10⁵ N/m² (Eq. (56)), divided by the density ρ of silver 10.5 g/cm³:

$${P}_{pump} = \frac{\dot{m} P}{ρ} = 24 W \qquad ( 53 )$$

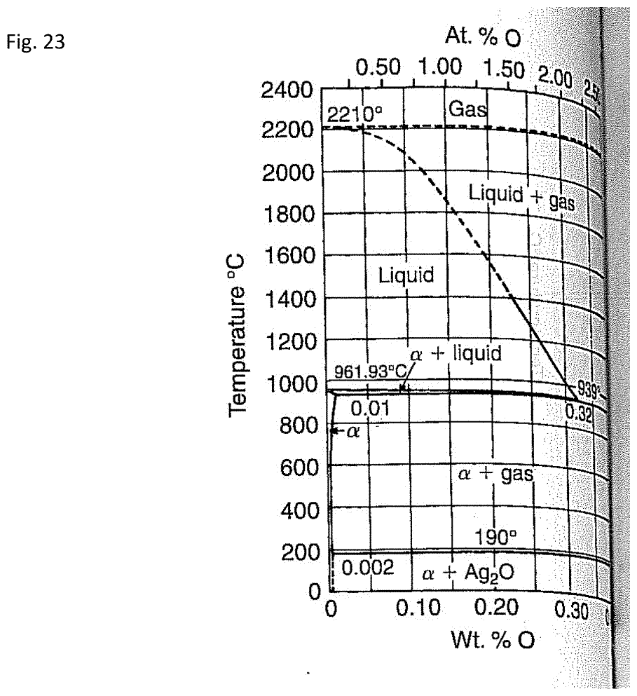

The solubility of atmospheric pressure oxygen in silver increases as the temperature approaches the melting point wherein the solubility is up to about 40 to 50 volumes of oxygen for volume of silver (FIG. 23). Moreover, the solubility of oxygen in silver increases with oxygen atmospheric pressure in equilibrium with the dissolved oxygen. A high mole fraction of oxygen in silver may be achieved at high O₂ pressure as shown by J. Assal, B. Hallstedt, and L. J. Gauckler, “Thermodynamic assessment of the silver-oxygen system”, J. Am Ceram. Soc. Vol. 80 (12), (1997), pp. 3054-3060. For example, there is a eutectic between Ag and Ag₂O at a temperature of 804 K, an oxygen partial pressure of 526 bar (5.26×10⁷ Pa), and an oxygen mole fraction in the liquid phase of 0.25.

The incorporation of oxygen atoms into silver is dramatically increased beyond that which may be achieved by gaseous solvation at a given oxygen pressure and silver temperature by the converting molecular oxygen to atomic oxygen [A. de Rooij, “The oxidation of silver by atomic oxygen”, Product Assurance and Safety Department, ESTEC, Noordwijk, The Netherlands, ESA Journal 1989, (Vol. 13), pp. 363-382]. The relationship of oxygen solubility in liquid silver is about proportional to the gaseous oxygen pressure to the ½ power since oxygen absorbs into silver as atomic. When O atoms instead of O₂ molecules are involved in the oxidation reaction with silver, AgO as well as Ag₂O are thermodynamically stable even at very low O₂ pressures, AgO is more stable than Ag₂O, and it is thermo-dynamically possible to oxidize Ag₂O to AgO, which may be impossible with O₂ molecules. To exploit the superior solubility of 0 atoms during the MHD cycle, the MHD channel plasma jet may be maintained by the hydrino reaction to maintain the formation of O atoms from O₂ molecules. A composition such as the eutectic comprising 0.25 mole fraction oxygen incorporated in molten silver may be formed at the end of the MHD channel and pumped to the reaction cell chamber to recycle the silver and oxygen. The MHD cycle further comprises the release of the oxygen in the reaction cell chamber with a dramatic temperature and pressure increase due to the hydrino plasma reaction followed by isenthalpic expansion in the MIHD nozzle section to form an aerosol jet and nearly isobaric flow of the jet in the MHD channel.

To successfully convert the thermal and pressure-volume energy inventory in the reaction cell chamber into kinetic energy in the MHD channel by isentropic expansion, the oxygen must effectively accelerate the silver in the converging-diverging nozzle. One of the main failure modes of LMMHD is slippage of the accelerator gas past large liquid metal particles. Ideally the metal particles behave as molecules, and the conversion of thermal energy into the kinetic energy of the plasma jet that flows into the MHD channel approximately obeys the ideal gas laws for isentropic expansion, the most efficient means possible. Consider the case wherein the reaction cell chamber atmosphere is oxygen, the injected molten metal is silver, and the oxygen promotes the formation of an aerosol of silver nanoparticles. The silver nanoparticles are in the free molecular regime when they are small compared to the mean free path of the suspending gas. Mathematically, the Knudsen number Kₙ given by

$${K}_{n} = \frac{2 λ}{{d}_{A g}} \qquad ( 54 )$$

is such that Kₙ>>1 wherein λ is the mean path of the suspending oxygen gas and d_{Ag} is the diameter of the silver particle. After Levine [I. Levine, Physical Chemistry, McGraw-Hill Book Company, New York, (1978), pp. 420-421.], the mean path λ_{A} of a gas A of diameter d_{A} colliding with a second gas B of diameter d_{B} and mole fraction f_{B} is given by

$${λ}_{A} = \frac{{k}_{B} T}{{π [ \frac{{d}_{A}}{2} + \frac{{d}_{B}}{2} ]}^{2} {f}_{B} P} \qquad ( 55 )$$

For the gas parameters of 6000 K temperature T, 5 atmospheres (5×10⁵ N/m²) pressure P, 25 mole % oxygen corresponding to a gas fraction f_{O2} of 0.25, and 75 mole % silver corresponding to a silver gas fraction f_{Ag} of 0.75, the mean path λ_{O}_{₂} of the suspending gas oxygen of molecular diameter d_{O}_{₂} of 1.2×10⁻¹⁰ m colliding with a silver particle of diameter d_{Ag} of 5×10⁻⁹ m given by Eq. (55) is

$${λ}_{{O}_{2}} = \frac{{k}_{B} T}{{π [ \frac{{d}_{{O}_{2}}}{2} + \frac{{d}_{A g}}{2} ]}^{2} {f}_{A g} P} = 2.5 \times {10}^{- 9} m \qquad ( 56 )$$

wherein k_{B} is the Boltzmann constant. The molecular regime is about satisfied for silver aerosol particles having a 5 nm diameter corresponding to about 3800 silver atoms. In this regime, particles interact with the suspending gas through elastic collisions with the gas molecules. Thereby, the particles behave similarly to gas molecules wherein the gas molecules and particles are in continuous and random motion, there is no loss or gain of kinetic energy when any particles collide, and the average kinetic energy is the same for both particles and molecules and is a function of the common temperature.

In an exemplary MHD thermodynamic cycle: (i) silver nanoparticles form in the reaction cell chamber wherein the nanoparticles may be transported by at least one of thermophoresis and thermal gradients that select for ones in the molecular regime; (ii) the hydrino plasma reaction in the presence of the released O forms high temperature and pressure 25 mole % O and 70 mole % silver nanoparticle gas that flows into the nozzle entrance; (iii) 25 mole % O and 75 mole % silver nanoparticle gas undergoes nozzle expansion, (iv) the resulting kinetic energy of the jet is converted to electricity in the MHD channel; (v) the nanoparticles increase in size in the MHD channel and coalesce to silver liquid at the end of the MHD channel, (vi) liquid silver absorbs 25 mole % O, and (vii) EM pumps pump the liquid mixture back to the reaction cell chamber.

For a gaseous mixture of oxygen and silver nanoparticles, the temperature of oxygen and silver nanoparticles in the free molecular regime is the same such that the ideal gas equations apply to estimate the acceleration of the gas mixture in nozzle expansion wherein the mixture of O₂ and nanoparticles have a common kinetic energy at the common temperature. The acceleration of the gas mixture comprising molten metal nanoparticles such as silver nanoparticles in a converging-diverging nozzle may be treated as the isentropic expansion of ideal gas/vapor in the converging-diverging nozzle. Given stagnation temperature T₀; stagnation pressure p₀; gas constant Rᵥ; and specific heat ratio k, the thermodynamic parameters may be calculated using the equations of Liepmann and Roshko [Liepmann, H. W. and A. Roshko Elements of Gas Dynamics, Wiley (1957)]. The stagnation sonic velocity c₀ and density ρ₀ are given by

$${c}_{0} = \sqrt{k {R}_{v} {T}_{0}} , {ρ}_{0} = \frac{{p}_{0}}{{R}_{v} {T}_{0}} \qquad ( 57 )$$

The nozzle throat conditions (Mach number Ma*=1) are given by:

$${T}^{*} = \frac{{T}_{0}}{1 + \frac{( k - 1 )}{2}} , {p}^{*} = \frac{{p}_{0}}{{[ 1 + \frac{( k - 1 )}{2} ]}^{k / ( k - 1 )}} , {ρ}^{*} = \frac{{p}^{*}}{{R}_{v} T} * \\ {c}^{*} = \sqrt{k {R}_{v} {T}^{*}} , {u}^{*} = {c}^{*} , {A}^{*} = \frac{m}{{ρ}^{*} {u}^{*}} \qquad ( 58 )$$

where u is the velocity, m is the mass flow, and A is the nozzle cross sectional area. The nozzle exit conditions (exit Mach number=Ma) are given by:

$$T = \frac{{T}_{0}}{1 + \frac{( k - 1 )}{2} M {a}^{2}} , p = \frac{{p}_{0}}{{[ 1 + \frac{( k - 1 )}{2} M {a}^{2} ]}^{k / ( k - 1 )}} , \\ ρ = \frac{p}{{R}_{v} T} \\ c = \sqrt{k {R}_{v} T} , u = cMa , A = \frac{m}{ρ u} \qquad ( 59 )$$

Due to the high molecular weight of the nanoparticles, the MHD conversion parameters are similar to those of LMMHD wherein the MHD working medium is dense and travels at low velocity relative to gaseous expansion.

Given the ability of silver to form suitable nanoparticles in the molecular regime and absorb a suitable mass of oxygen to recycle the accelerator gas, oxygen in this case, without use of turbo machinery, the feasibility of the oxygen and silver nanoparticle aerosol MHD cycle depends on the kinetics of the aerosol formation rate and the rate that oxygen can be absorbed into and degassed from molten silver. Corresponding kinetic studies were performed and the kinetics was found to be adequate. In an embodiment, another metal such as gallium metal and gallium nanoparticles may be substituted for silver metal and silver nanoparticles.

In an embodiment, the solubility of oxygen in silver may be increased beyond that which may be achieved by gaseous solvation at a given oxygen pressure by application of at least one of an electric field, an electric potential, and a plasma to the molten silver. In an embodiment, electrolysis or plasma may be applied to the molten silver to increase the O₂ solubility in the liquid silver wherein the molten silver may comprise as an electrolysis or plasma electrode. The application of at least one of an electric field, an electric potential, and a plasma to the molten silver such as application of O₂ electrolysis or plasma may also increase the rate that O₂ dissolves in silver. In an embodiment, the SunCell® may comprise a source of at least one of an electric field, an electric potential, and a plasma to the molten silver. The source may comprise electrodes and at least one of a source of electrical power and plasma power such as glow discharge, RF, or microwave plasma power. The molten silver may comprise an electrode such as a cathode. Molten or solid silver may comprise the anode. Oxygen may be reduced at the anode and react with silver to be absorbed. In another embodiment, the molten silver may comprise an anode. Silver may be oxidized at the anode and react with oxygen to cause oxygen absorption.

In an embodiment, the SunCell® further comprises an oxygen sensor and an oxygen control system such as a means to at least one of dilute the oxygen with a noble gas and pump away the noble gas. The former may comprise at least one of a noble gas tank, valve, regulator, and pump. The latter may comprise at least one of a valve and pump.

The atmosphere at the MHD condensation section 309 may comprise a very low silver vapor pressure, and may comprise predominantly oxygen. The silver vapor pressure may be low due to a low operating temperature such as in at least one range of about 970° C. to 2000° C., 970° C. to 1800° C., 970° C. to 1600° C., and 970° C. to 1400° C. The SunCell® may comprise a means to remove any silver aerosol in the MHD condensation section 309. The means of aerosol removal may comprise a means to coalesce the silver aerosol such as a cyclone separator. The cyclone separator may comprise the MHD return reservoir 311 or MHD return gas reservoir 311a. The silver comprising dissolved oxygen may be recirculated to the reaction cell chamber 5b31 by pumping wherein the pump may comprise an electromagnetic pump. The higher temperature and absence of at least one of an electric field, an electric potential, and plasma applied to the molten silver may cause oxygen to be released from the silver in the reaction cell chamber. In an exemplary embodiment, the silver pressure is very low at the MHD condensation section due to a low operating temperature such as about 1200° C., and a cyclone separator is used to coalesce the silver aerosol into silver liquid which then serves as a negative electrode to electrolyze O₂ into the liquid silver.

In an embodiment, an MHD cycle comprises isenthalpic expansion in the MHD nozzle section 307 to form an aerosol jet and isobaric flow of the jet in the MHD channel 308. The aerosol may be accelerated in the nozzle 307 by an accelerator gas such as at least one of H₂, O₂, H₂O, or a noble gas. In an embodiment, the pressure of the accelerator gas in the MHD condensation section 309 is capable of maintaining plasma of the accelerator gas wherein the ratio of the pressures of the accelerator gas in the reaction chamber and the MHD condensation section is greater than one. The pressure ratio may be in at least one range of about 1.5 to 1000, 2 to 500, and 10 to 20. Exemplary pressures of the oxygen accelerator gas in the reaction chamber and the MHD condensation section are in the range of about 1 to 10 atmosphere and 0.1 to 1 atmospheres, respectively. The reaction cell chamber may comprise some released and plasma maintained 0 versus O₂ to increase the vapor phase with a corresponding increase in accelerator-caused jet kinetic energy. Some 0 may recombine to O₂ in at least one of the MHD channel 308 and the MHD condensation sections 309 to increase the pressure gradient from the reaction cell chamber 5b31 to the MHD condensation section 309 to increase the jet kinetic energy and converted electrical power. The gas temperature of at least one of the reaction cell chamber and the MHD condensation section may be in a range whereby the metal vapor pressure is low such as below 2200° C. in the case of silver vapor. In an embodiment, the mole fraction of the accelerator gas such as oxygen compared to the molten metal such as silver is in at least one range of about 1 to 95 mole %, 10 to 90 mole %, and 20 to 90 mole %. The higher mole % accelerator gas may provide a higher jet kinetic energy at the exit of the MHD nozzle 307.

In an embodiment, the aerosol may comprise molten metal nanoparticles such as silver or gallium nanoparticles. The particles may have a diameter in at least one range of about 1 nm to 100 microns, 1 nm to 10 microns, 1 nm to 1 micron, 1 nm to 100 nm, and 1 nm to 10 nm. In an embodiment, the working medium of the MHD converter comprises a mixture of the metal nanoparticles such as silver nanoparticles and a gas such as oxygen gas that may at least one of serve as a carrier or expansion assisting gas and assist in forming or maintaining the stability of the nanoparticles. In another embodiment, the working medium may comprise metal nanoparticles. The nanoparticle atmosphere may be maintained by maintaining at least one of the cell and plasma temperatures above that which maintains the vapor pressure of the nanoparticles at a desire vapor pressure such as one in at least one range of about 1 to 100 atm, 1 to 20 atm and 1 to 10 atm. The at least one of the cell and plasma temperatures may be within at least one range of about 1000° C. to 6000° C., 1000° C. to 5000° C., 1000° C. to 4000° C., 1000° C. to 3000° C., and 1000° C. to 2500° C.

In an embodiment, the atmosphere in the reaction cell chamber 5b31 is maintained with parameters such as oxygen partial pressure, total pressure, temperature, gas composition such as the addition of a noble gas in addition to at least one of oxygen, hydrogen, and water vapor, and hydrino reaction flow rate that facilities the formation of aerosol particles of sufficiently small size to be in the molecular regime. In an embodiment, at least one of the suspending gas such a silver and the particles such as silver particles may be electrically charged to inhibit collisions between species such that the gas mixture exhibits molecular regime behavior. The silver may comprise an additive to facilitate the particle charging. In an embodiment, the SunCell® may comprise a size selection means to separate the flow of nanoparticles by size. The size selection means may selectively maintain flow of nanoparticles having a size appropriate for molecular regime behavior into the nozzle 307 entrance. The size selection means to select particles of the molecule regime size may comprise a cyclone separator, a gravity separator, a baffle system, screen, thermophoresis separator, or electric field such as an electric or magnetic field separator before the entrance to nozzle 307. In the case of thermophoresis, the large particles may exhibit a positive thermodiffusion effect wherein the large nanoparticles migrate form the hot central region of the plasma to the colder reaction chamber cell 5b31 walls. The plasma may be selectively directed or ducted to flow from the hot central portion into the nozzle entrance.

The nanoparticles may be formed by the vaporization of the metal by the intense local power density of the hydrino reaction in one section of the reaction cell chamber 5b31 with rapid cooling in another cooler section of the reaction cell chamber wherein the temperature may be below the boiling point of the metal at the ambient pressure. In an embodiment, the nanoparticles such a silver or gallium nanoparticles may form by vaporization and condensation of the metal in an atmosphere that comprises oxygen wherein an oxide layer may form on the surfaces of the nanoparticles. The oxide layer may prevent coalescence of the nanoparticles in the aerosol state. At least one of the oxygen concentration, the rate of metal vaporization, the reaction cell chamber temperature and pressure and temperature and pressure gradients may be controlled to control the size of the nanoparticles. The size may be controlled such that the nanoparticles are of size of the molecular regime. The nanoparticles may be accelerated in the MHD section 307, the corresponding kinetic energy may be converted to electricity in the MHD channel section 308, and the nanoparticles may be caused to coalescence in the MHD condensation section 309. The SunCell® may comprise a coalescence surface in the condensation section. The nanoparticles may impact the coalescence surface, coalesce, and the resulting liquid metal that may comprise absorbed oxygen may flow into the MHD return EM pump 312 to be pumped to the reaction cell chamber 5b31.

In an embodiment, the SunCell® may comprise a reduction means to at least partially reduce the oxide coat on the metal nanoparticles. The reduction may permit the nanoparticles to coagulate or coalesce. The coalescence may permit the resulting liquid to be pumped back to the reaction cell chamber 5b31 by the MHD return EM pump 312. The reduction means may comprise an atomic hydrogen source such as hydrogen plasma or chemical dissociator source of atomic hydrogen. The plasma source may comprise aglow, arc, microwave, RF, or other plasma source of the disclosure or known in the art. The hydrogen plasma source may comprise a glow discharge plasma source comprising a plurality of microhollow cathodes that are capable of operating at high pressure such as one atmosphere such as one of the disclosure. The chemical dissociator to serve as an atomic hydrogen source may comprise a ceramic supported noble metal hydrogen dissociator such as Pt on alumina or silica beads such as one of the disclosure. The chemical dissociator may be capable of recombining H₂+O₂. The hydrogen dissociator may comprise at least one of (i) SiO₂ supported Pt, Ni, Rh, Pd, Ir, Ru, Au, Ag, Re, Cu, Fe, Mn, Co, Mo, or W, (ii) Zeolite supported Pt, Rh, Pd, Ir, Ru, Au, Re, Ag, Cu, Ni, Co, Zn, Mo, W, Sn, In, Ga, and (iii) at least one of Mullite, SiC, TiO₂, ZrO₂, CeO₂, Al₂O₃, SiO₂, and mixed oxides supported noble metals, noble metal alloys, noble metal mixtures, and rare earth metals. The hydrogen dissociator may comprise a supported bimetallic such as one comprising Pt, Pd Ir, Rh and Ru. Exemplary bimetallic catalysts of the hydrogen dissociator are supported Pd—Ru, Pd—Pt, Pd—Ir, Pt—Ir, Pt—Ru and Pt—Rh. The catalytic hydrogen dissociator may comprise a material of a catalytic converter such as supported Pt. The reduction means may be located in at least one of the MHD condensation section 309 and the MHD return reservoir 311.

In an embodiment, the aerosol that is accelerated in the MHD section 307 comprises a mixture of gas such as at least one of oxygen, H₂, and a noble gas, silver or gallium nanoparticles in the molecular regime, and larger particles such as silver or gallium particles in the diameter range of about 10 nm to 1 mm. At least one of the gas and the nanoparticles in the molecular regime may serve as a carrier gas to accelerate the larger particles as at least one of the gas and nanoparticles in the molecular regime accelerates in the MHD nozzle section 307. The gas and nanoparticles in the molecular regime may comprise a sufficient mole fraction to achieve high kinetic energy conversion of the pressure and thermal energy inventory of the aerosol mixture in the reaction cell chamber 5b31. The mole percentage of the gas and nanoparticles in the molecular regime may comprise at least one range of about 1% to 100%, 5% to 90%, 5% to 80%, 5% to 70%, 5% to 60%, 5% to 50%, 5% to 40%, 5% to 30%, 5% to 20%, and 5% to 10%.

In an embodiment, the nanoparticles may be transported by at least one of thermophoresis or thermal gradients and fields such as at least one of electric and magnetic fields. The nanoparticles may be charged so that the electric field is effective. The charging may be achieved by applying a coating such as an oxide coat by the controlled addition of oxygen.

In an embodiment, at least one of the silver aerosol is coalesced and the hydrino reaction plasma is not maintained in the MHD condensation section 309 such that the conductivity of the ambient atmosphere in the MHD condensation section 309 is such that an electric field, potential, or plasma may be applied to the oxygen gas to cause oxygen to be absorbed into silver which is then recycled to the reaction cell chamber. In an embodiment, the SunCell® may comprise a means to apply a discharge to the vapor phase at the MHD condensation section 309. The discharge may comprise at least one of glow, arc, RF, microwave, laser, and other plasma forming means or discharges known in the art that can dissociate O₂ to atomic O. The discharge means may comprise at least one of a discharge power supply or plasma generator, discharge electrodes or at least one antenna, and wall penetrations such as liquid electrode penetrations or induction coupling power connectors. In another embodiment, the source of atomic oxygen may comprise a hyperthermal generator wherein O₂ absorbs onto the surface of a silver membrane, dissociates into atomic O that diffuses through the membrane to provide O atoms on the opposite surface. The oxygen atoms may be desorbed and then absorbed by molten silver. The means of desorption may comprise a low energy electron beam.

In an embodiment, a high-pressure glow discharge may be maintained by means of a microhollow cathode discharge. The microhollow cathode discharge may be sustained between two closely spaced electrodes with openings of approximately 100 micron diameter. Exemplary direct current discharges may be maintained up to about atmospheric pressure. In an embodiment, large volume plasmas at high gas pressure may be maintained through superposition of individual glow discharges operating in parallel. The electron density in the plasma may be increased at a given current by adding a species such as a metal such as cesium having a low ionization potential. The electron density may also be increased by adding a species such as a filament material from which electrons are thermally emitted such as at least one of rhenium metal and other electron gun thermal electron emitters such as thoriated metals or cesium treated metals. In an embodiment, the plasma voltage is elevated such that each electron of the plasma current gives rise to multiple electrons by colliding with at least one of the silver aerosol particles, the accelerator gas, or an added gas or species such as cesium vapor. The plasma current may be at least one of DC or AC. The AC power may be transferred by an induction power source and receiver, outside and inside of the chamber of the MHD condensation section, respectively.

In an embodiment, the MHD converter may comprise a reservoir such as the MHD return reservoir 311 or MHD return gas reservoir 311a to increase at least one of the dwell time and silver area for oxygen to be absorbed in the silver before recycling to the reaction cell chamber 5b31. The size of the reservoir may be selected to achieve the desired oxygen absorption. The MHD return reservoir 311 or MHD return gas reservoir 311a may further comprise a cyclone separator. The cyclone separator may coalesce silver aerosol particles. The reservoir may comprise an electrolysis or plasma discharge chamber.

In an embodiment, the SunCell® may comprise a means to at least partially reduce any oxide coating on the metal nanoparticles such a silver or gallium nanoparticles. The partial removal of the oxide coat may facilitate the coalescence of the nanoparticles in a desired region of the SunCell® such as in the MHD condensation section 309. The reduction may be achieved by reacting the particles with hydrogen. Hydrogen gas may be introduced into the MHD condensation section at a controlled pressure and temperature to achieve the at least partial reduction. The SunCell® may comprise a means of the current disclosure to maintain a plasma comprising hydrogen to at least partially reduce the oxide coatings. Additional oxygen that is not hydrogen reduced may be absorbed into the coalesced molten metal to be retum-pumped to the reaction cell chamber 5b31 to provide oxygen for a cycle of nanoparticle surface oxide formation and reduction.

In an embodiment of a closed liquid magnetohydrodynamic cycle, the simplest application of Lorentz's law to a moving conductor with crossed electrodes and a magnetic field with no moving parts, the potential of MHD power conversion efficiency that approaches the loading factor W (ratio of the electric field across the load to the open circuit electric field). Since the MHD efficiency may approach W=1, the electrical conversion of the power of the plasma into electricity may approach the efficiency of pressure-thermal to kinetic energy conversion wherein the corresponding nozzle efficiencies of 99% have been realized. Exemplary operational parameters are a background O₂ pressure of at least 100 atm, a mole fraction absorption of O in silver at the exit of the MHD channel of 25 mole %, N=20 silver atoms per nanoparticle, W=0.98, a mass flow rate of 1 kg/s, a gas conductivity of 10⁶ S/m, a uniform magnetic field of 2 T, and inlet pressure, temperature, and velocity equal to 1 atm, 1000 K and 1000 m/s, respectively. These parameters result in the extraction of 471 kW of MHD power from a 16 cm long channel with 4 cm² maximum cross section and gas exit temperature of 1800 K wherein the heat inventory is recovered by gas absorption in molten silver. The silver is recycled with insignificant power using electromagnetic pumps having no moving parts. The channel volume is 20.4 cm³ so the corresponding MHD power density is about 23.1 kW/cm³ (23.1 MW/liter) which compares very favorably with typical power densities in the range of only about 30 kW/liter for state-of-the-art high-speed heavy-duty diesel engines. In other embodiments, an increase in N, the number of silver atoms per nanoparticle, results in a longer channel to achieve similar power conversion due to the lower velocity for a fixed kinetic energy inventory and a corresponding reduced decelerating Lorentz force.

In an embodiment, the molten metal may comprise any conductive metal or alloy known in the art. The molten metal or alloy may have a low melting point. Exemplary metals and alloys are gallium, indium, tin, zinc, and Galinstan alloy wherein an example of a typical eutectic mixture is 68% Ga, 22% In, and 10% Sn (by weight) though proportions may vary between 62-95% Ga, 5-22% In, 0-16% Sn (by weight). In an embodiment wherein the metal may be reactive with at least one of oxygen and water to form the corresponding metal oxide, the hydrino reaction mixture may comprise the molten metal, the metal oxide, and hydrogen. The metal oxide may comprise one that thermally decomposes to the metal to release oxygen such as at least one of Sn, Zn, and Fe oxides. The metal oxide may serve as the source of oxygen to form HOH catalyst. The oxygen may be recycled between the metal oxide and HOH catalyst wherein hydrogen consumed to form hydrino may be resupplied. The cell material may be selected such that they are non-reactive at the operating temperature of the cell. Alternatively, the cell may be operated at a temperature below a temperature at which the material is reactive with at lest one of H₂, O₂, and H₂O. The cell material may comprise at least one of stainless steel, a ceramic such as silicon nitride, SiC, BN, a boride such as YB₂, a silicide, and an oxide such as Pyrex, quartz, MgO, Al₂O₃, and ZrO₂. In an exemplary embodiment, the cell may comprise at least one of BN and carbon wherein the operating temperature is less than about 500 to 600° C. In an embodiment, at least one component of the power system may comprise ceramic wherein the ceramic may comprise at least one of a metal oxide, alumina, zirconia, magnesia, hafnia, silicon carbide, zirconium carbide, zirconium diboride, silicon nitride, and a glass ceramic such as Li₂O×AlO₃×nSiO₂ system (LAS system), the MgO×Al₂O₃×nSiO₂ system (MAS system), the ZnO×Al₂O₃×nSiO₂ system (ZAS system).

In an embodiment the injection metal may have a low melting point such as one having a melting point below 700° C. such as at least one of bismuth, lead, tin, indium, cadmium, gallium, antimony, or alloys such as Rose's metal, Cerrosafe, Wood's metal, Field's metal, Cerrolow 136, Cerrolow 117, Bi—Pb—Sn—Cd—In—Tl, and Galinstan. At least one component such as the reservoirs 5c may comprise a ceramic such as zirconia, alumina, quartz, or Pyrex. The end of the reservoirs may be metalized to facilitate connection to a metal reservoir base plate or base of electromagnetic pump assembly 5kk1. The union between the reservoir and the base of electromagnetic pump assembly 5kk1 may comprise braze or solder such as silver solder. Alternatively, the union may comprise a gasketed flange seal. The EM pumps may comprise metal EM pump tubes 5k6, ignition electromagnetic pump bus bars 5k2, and ignition connections such as ignition electromagnetic pump bus bars 5k2a. At least one of the molten metal injection and ignition may be driven by DC current wherein the injection pumps may comprise DC EM pumps. At least one of the DC EM pump tube 5k6, the reservoir support 5kk1, the EM pump bus bars 5k2, and the ignition bus bars 5k2a may comprise metal such as stainless steel. The ignition bus bars 5k2a may connect to at least one of the reservoir support 5kk1 and the DC EM pump tube 5k6. The reaction cell chamber 5b31 may comprise a ceramic such as zirconia, alumina, quartz, or Pyrex. Alternatively, the reaction cell chamber 5b31 may comprise SiC coated carbon. The SunCell® may comprise inlet risers 5qa such as ones with tampered channels or slots from the top to the bottom or a plurality of holes that throttle the inflowing molten metal as the reservoir level drops. The throttling may serve to balance the reservoirs levels while avoiding extremes in disparity on the levels. The initial molten metal fill level and the height of the bottom on the inlet may be selected to set the maximum and minimum reservoirs heights.

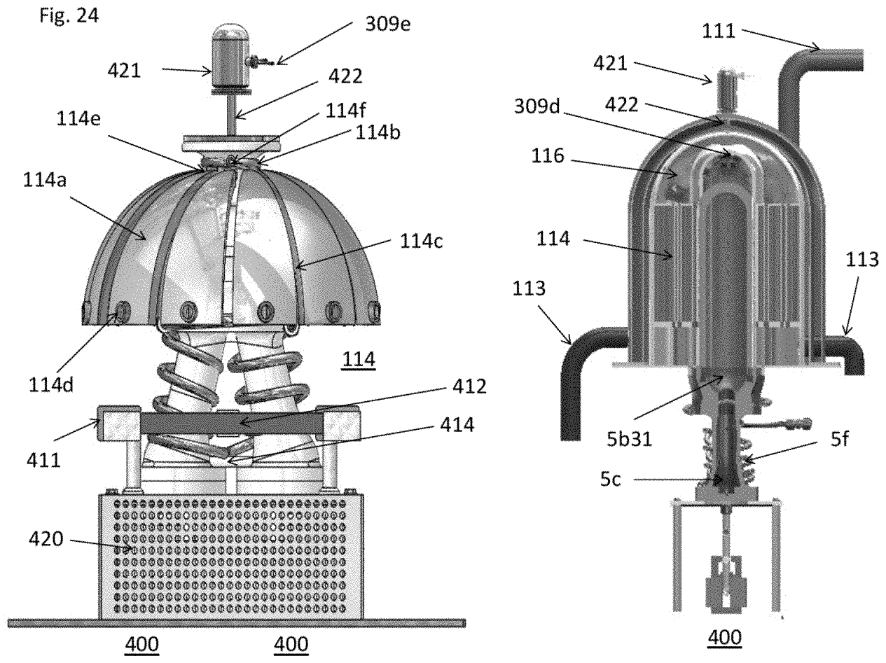

In an embodiment, the molten metal comprises gallium or an alloy such as Ga—In—Sn alloy. The SunCell® having a low-melting point metal such as one that melts below 300° C. may comprise a mechanical pump to inject the molten metal into the reaction cell chamber 5b31. The mechanical pump may replace the EM pump such as induction EM pump 400 for an operating temperature below the maximum capability of a mechanical pump, and an EM pump may be used in case that the operating temperature is higher. Typically, mechanical pumps operate up to a temperature limit of about 300° C.; however, ceramic gear pumps operate as high as 1400° C. Lower temperature operation such as below 300° C. is well suited for hot water and low-pressure steam applications wherein the heater SunCell® comprises a heat exchanger 114 such as one shown in FIG. 24. Reactant gases such as H₂ and O₂ may be added to the cell such as the reaction cell chamber 5b31 by diffusion through a gas permeable membrane 309d from a tank and line.

A SunCell® heater or thermal power generator embodiment (FIG. 24) comprises a spherical reactor cell 5b31 with a spatial separated circumferential half-spherical heat exchanger 114 comprising panels or sections 114a that receive heat by radiation from the spherical reactor 5b4. Each panel may comprise a section of a spherical surface defined by two great circles through the poles of the sphere. The heat exchanger 114 may further comprise a manifold 114b such as a toroid manifold with coolant lines 114c from each of the panels 114a of the heat exchanger and a coolant outlet manifold 114f. Each collant line 114c may comprise a coolant inlet port 114d and a coolant outlet port 114e. The thermal power generator may further comprise a gas cylinder 421 with has inlet and outlet 309e and a gas supply tube 422 that runs through the top of the heat exchanger 114 to the gas permeable membrane 309d on top of the spherical cell 5b31. The gas supply tube 422 can run through the coolant collection manifold 114b at the top of the heat exchanger 114. In another SunCell® heater embodiment (FIG. 24), the reaction cell chamber 5b31 may be cylindrical with a cylindrical heat exchanger 114. The gas cylinder 421 may be outside of the heat exchanger 114 wherein the gas supply tube 422 connects to the semipermeable gas membrane 309d on the top of the reaction cell chamber 5b31 by passing through the heat exchanger 114. At least one of the reaction cell chamber 5b31, the gas membrane 309d on the top of the reaction cell chamber 5b31, and at least a portion of the gas supply tube 422 may comprise ceramic. The gas supply tube 422 that connects to the gas cylinder 421 may comprise metal such a stainless steel. The ceramic and metal portions of the gas supply tube 422 may be joined by a gas supply tube ceramic to metal flange that may comprise a gasket such as a carbon gasket. Cold water may be fed in inlet 113 and heated in heat exchanger 114 to form steam that collects in boiler 116 and exists steam outlet 111. The thermal power generator may further comprise dual molten metals injectors comprising induction EM pumps 400, reservoirs 5c, and reaction cell chamber 5b31.

In an embodiment such as a SunCell® comprising an ignition system comprising ignition bus bars such as ignition electromagnetic pump bus bars 5k2a, the resistance is decreased to increase the ignition current. The SunCell® may comprise ignition bus bars that directly contact the molten metal such as that in the reservoirs 5c. The ignition bus bars may comprise a penetration of the reservoir support plate 5b8 to directly contact the molten metal such as silver or gallium. The SunCell® may comprise submerged electrodes such as submerged EM pump injectors 5k61 that provide direct electrical contact between the reservoir molten metal and the molten metal of the stream created by a corresponding electromagnetic pump. The electrical circuit of at least one injected molten metal stream may comprise ignition bus bars 5k2a that penetrate the reservoir support plate 5b8, the molten metal in the reservoirs 5c, and the reservoir molten metal that contacts the corresponding stream from the submerged EM pump injector wherein the stream penetrates the molten metal to reach the counter stream or corresponding counter electrode. The reservoir may comprise a sufficient area at the top to provide a sufficient molten metal volume to avoid fluctuations in injection wherein the volume is given by the area times the submersion depth. The fluctuations in injection may be due to variations in flow rate of the return molten metal stream that effect at least one of the submersion depth and turbulence at the molten metal surface.

The plasma reaction was observed to be much more intense on the positive electrode as predicted based on the arc current mechanism of ion recombination to greatly increase the hydrino reaction kinetics. In a hydrino reactor, the positive electrode is unique in contrast to a glow discharge wherein the negative electrode is where the plasma power is dissipated and the glow is generated. In an embodiment, an injector reservoir 5c may further comprise a portion of the bottom of the reaction cell chamber 5b31 wherein the counter electrode may comprise a non-injector reservoir comprising an extension or pedestal comprising a raised pedestal electrode that is electrically isolated from the injector reservoir and electrode. The counter electrode or non-injector electrode may comprise an electrical insulator and may further comprise a drip edge to provide the electrical isolation. The injector electrode and counter electrode may be negative and positive, respectively.

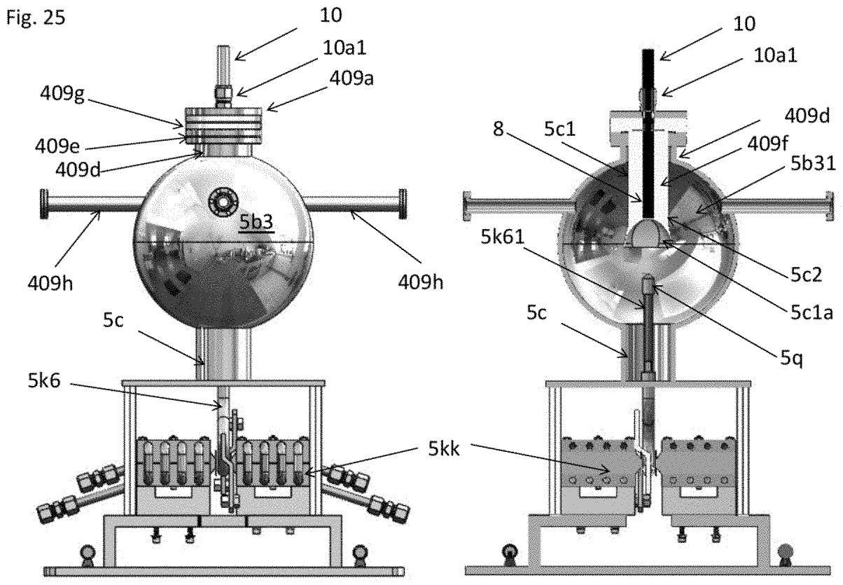

In an exemplary embodiment, the SunCell® having a pedestal electrode shown in FIG. 25 comprises (i) an injector reservoir 5c, EM pump tube 5k6 and nozzle 5q, a reservoir base plate 409a, and a spherical reaction cell chamber 5b31 dome, (ii) a non-injector reservoir comprising a sleeve reservoir 409d that may comprise SS welded to the lower hemisphere with a sleeve reservoir flange 409e at the end of the sleeve reservoir 409d, (iii) an electrical insulator insert reservoir 409f comprising a pedestal 5c1 at the top and an insert reservoir flange 409g at the bottom that mates to the sleeve reservoir flange 409e wherein the insert reservoir 409f, pedestal 5c1 that may further comprise a drip edge 5c1a, and insert reservoir flange 409g may comprise a ceramic such as boron nitride, stabilized BN such as BN—CaO or BN—ZrO₂, silicon carbide, alumina, zirconia, hafnia, or quartz, or a refractory material such as a refractory metal, carbon, or ceramic with a protective coating such as SiC or ZrB₂ such as one comprising SiC or ZrB₂ carbon and (iv) a reservoir base plate 409a such as one comprising SS having a penetration for the ignition bus bar 10a1 and an ignition bus bar 10 wherein the baseplate bolts to the sleeve reservoir flange 409e to sandwich the insert reservoir flange 409g. In an embodiment the SunCell® may comprise a vacuum housing enclosing and hermetically sealing the joint comprising the sleeve reservoir flange 409e, the insert reservoir flange 409g, and the reservoir baseplate 409a wherein the housing is electrically isolated at the electrode bus bar 10.

In an embodiment shown in FIG. 25, an inverted pedestal 5c2 and ignition bus bar and electrode 10 are at least one of oriented in about the center of the cell 5b3 and aligned on the negative z-axis wherein at least one counter injector electrode 5k61 injects molten metal from its reservoir 5c in the positive z-direction against gravity where applicable. The injected molten stream may maintain a coating or pool of liquid metal in the pedestal 5c2 against gravity where applicable. The pool or coating may at least partially cover the electrode 10. The pool or coating may protect the electrode from damage such as corrosion or melting. In the latter case, the EM pumping rate may be increased to increase the electrode cooling by the flowing injected molten metal. The electrode area and thickness may also be increased to dissipate local hot spots to prevent melting. The pedestal may be positively biased and the injector electrode may be negatively biased. In another embodiment, the pedestal may be negatively biased and the injector electrode may be positively biased wherein the injector electrode may be submerged in the molten metal. The molten metal such as gallium may fill a portion of the lower portion of the reaction cell chamber 5b31. In addition to the coating or pool of injected molten metal, the electrode 10 such as a W electrode may be stabilized from corrosion by the applied negative bias. In an embodiment, the electrode 10 may comprise a coating such as an inert conductive coating such as a rhenium coating to protect the electrode from corrosion. In an embodiment the electrode may be cooled. The cooling may reduce at least one of the electrode corrosion rate and the rate of alloy formation with the molten metal. The cooling may be achieved by means such as centerline water cooling. In an embodiment, the surface area of the inverted electrode is increased by increasing the size of the surface in contact with at least one of the plasma and the molten metal stream from the injector electrode. In an exemplary embodiment, a large plate or cup is attached to the end of the electrode 10. In another embodiment, the injector electrode may be submerged to increase the area of the counter electrode. FIG. 25 shows an exemplary spherical reaction cell chamber. Other geometries such a rectangular, cubic, cylindrical, and conical are within the scope of the disclosure. In an embodiment, the base of the reaction cell chamber where it connects to the top of the reservoir may be sloped such as conical to facilitate mixing of the molten metal as it enters the inlet of the EM pump. In an embodiment, at least a portion of the external surface of the reaction cell chamber may be clad in a material with a high heat transfer coefficient such as copper to avoid hot spots on the reaction cell chamber wall. In an embodiment, the SunCell® comprises a plurality of pumps such as EM pumps to inject molten metal on the reaction cell chamber walls to maintain molten metal walls to prevent the plasma in the reaction cell chamber from melting the walls. In another embodiment, the reaction cell chamber wall comprises a liner 5b31a such as a BN, fused silica, or quartz liner to avoid hot spots. An exemplary reaction cell chamber comprises a cubic upper section lined with quartz plates and lower spherical section comprising an EM pump at the bottom wherein the spherical section promotes molten metal mixing.

In an embodiment, the sleeve reservoir 409d may comprise a tight-fitting electrical insulator of the ignition bus bar and electrode 10 such that molten metal is contained about exclusively in a cup or drip edge 5c1a at the end of the inverted pedestal 5c2. The insert reservoir 409f having insert reservoir flange 409g may be mounted to the cell chamber 5b3 by reservoir baseplate 409a, sleeve reservoir 409d, and sleeve reservoir flange 409e. The electrode may penetrate the reservoir baseplate 409a through electrode penetration 10al.

In another embodiment, the insert reservoir flange 409g may be replaced with a feedthrough mounted in the reservoir baseplate 409a that electrically isolates the bus bar 10 of the feedthrough and pedestal 5c1 or insert reservoir 409f from the reservoir baseplate 409a. The feedthrough may be welded to the reservoir baseplate. An exemplary feedthrough comprising the bus bar 10 is Solid Sealing Technology, Inc. #FA10775. The bus bar 10 may be joined to the electrode 8 or the bus bar 10 and electrode 8 may comprise a single piece. The reservoir baseplate may be directly joined to the sleeve reservoir flange. The union may comprise Conflat flanges that are bolted together with an intervening gasket. The flanges may comprise knife edges to seal a soft metallic gasket such as a copper gasket. The ceramic pedestal 5c1 comprising the insert reservoir 409f may be counter sunk into a counter bored reservoir baseplate 409a wherein the union between the pedestal and the reservoir baseplate may be sealed with a gasket such as a carbon gasket or another of the disclosure. The electrode 8 and bus bar 10 may comprise an endplate at the end where plasma discharge occurs. Pressure may be applied to the gasket to seal the union between the pedestal and the reservoir baseplate by pushing on the disc that in turn applies pressure to the gasket. The discs may be threaded on to the end of the electrode 8 such that turning the disc applies pressure to the gasket. The feedthrough may comprise an annular collar that connects to the bus bar and to the electrode. The annular collar may comprise a threshed set screw that when tightened locks the electrode into position. The position may be locked with the gasket under tension applied by the end disc pulling the pedestal upwards. The pedestal 5c1 may comprise a shaft for access to the set screw. The shaft may be threaded so that it can be sealed on the outer surface of the pedestal with a nonconductive set screw such a ceramic one such as a BN one wherein the pedestal may comprise BN such as BN—ZrO₂. In another embodiment, the bus bar 10 and electrode 8 may comprise rods that may butt-end connect. In an embodiment, the pedestal 5c1 may comprise two or more threaded metal shafts each with a set screw that tightens against the bus bar 10 or electrode 8 to lock them in place under tension. The tension may provide at least one of connection of the bus bar 10 and electrode 8 and pressure on the gasket. Alternatively, the counter electrode comprises a shortened insulating pedestal 5c1 wherein at least one of the electrode 8 and bus bar 10 comprise male threads, a washer and a matching female nut such that the nut and washer tighten against the shortened insulating pedestal 5c1. Alternatively, the electrode 8 may comprise male threads on an end that threads into matching female threads at an end of the bus bar 10, and the electrode 8 further comprises a fixed washer that tightens the shortened insulating pedestal 5c1 against the pedestal washer and the reservoir baseplate 409a that may be counter sunk. The counter electrode may comprise other means of fasting the pedestal, bus bar, and electrode that are known to those skilled the art.

In another embodiment, at least one seal such as (i) one between the insert reservoir flange 409g and the sleeve reservoir flange 409e, and (ii) one between the reservoir baseplate 409a and the sleeve reservoir flange 409e may comprise a wet seal (FIG. 25). In the latter case, the insert reservoir flange 409g may be replaced with a feedthrough mounted in the reservoir baseplate 409a that electrically isolates the bus bar 10 of the feedthrough and pedestal 5c1 from the reservoir baseplate 409a, and the wet seal may comprise one between the reservoir baseplate 409a and the feedthrough. Since gallium forms an oxide with a melting point of 1900° C., the wet seal may comprise solid gallium oxide.

In an embodiment, hydrogen may be supplied to the cell through a hydrogen permeable membrane such as a structurally reinforced Pd—Ag or niobium membrane. The hydrogen permeation rate through the hydrogen permeable membrane may be increased by maintaining plasma on the outer surface of the permeable membrane. The SunCell® may comprise a semipermeable membrane that may comprise an electrode of a plasma cell such as a cathode of a plasma cell. The SunCell® such as one shown in FIG. 25 may further comprise an outer sealed plasma chamber comprising an outer wall surrounding a portion of the wall of cell 5b3 wherein a portion of the metal wall of the cell 5b3 comprises an electrode of the plasma cell. The sealed plasma chamber may comprise a chamber around the cell 5b3 such as a housing wherein the wall of cell 5b3 may comprise a plasma cell electrode and the housing or an independent electrode in the chamber may comprise the counter electrode. The SunCell® may further comprise a plasma power source, and plasma control system, a gas source such as a hydrogen gas supply tank, a hydrogen supply monitor and regular, and a vacuum pump.

In an embodiment, the SunCell® comprises an interference eliminator comprising a means to mitigate or eliminate any interference between the source of electrical power to the ignition circuit and the source of electrical power to the EM pump 5kk. The interference eliminator may comprise at least one of, one or more circuit elements and one or more controllers to regulate the relative voltage, current, polarity, waveform, and duty cycle of the ignition and EM pump currents to prevent interference between the two corresponding supplies.

In an embodiment, the SunCell® comprises a means to increase the electrical resistance of the metal stream in the injector section of the EM pump tube 5k61. The means to increase the electrical resistance may comprise an electrical current restrictor that has minimal impact of the metal flow on the EM pump 5kk. The current resistor may be located close to the EM pump magnets 5k4 and bus bars 5k2, so that the current resistor does not interfere with the ignition current that may be supplied to the metal stream post the current resistor. The current resistor may comprise a plurality of vanes or paddles that spin to allow molten metal flow. The paddles or vanes may be mounted on a shaft. The paddles or vanes may comprise an insulator as a ceramic such as boron nitride, quartz, alumina, zirconia, hafnia, or other ceramic of the disclosure or known in the art. In an embodiment, the current resistor comprises an electrical current interrupter to the EM pump stream such as an insulator paddle wheel such as a ceramic such as a BN one. The current interrupter may be housed in a housing that comprises a protrusion in a section of the injector section of the EM pump tube 5k61. The shaft of the paddle wheel may be fixed to the inside wall of the housing. In an embodiment to bias the rotational direction in a desired direction, at least one of the paddles or vanes may be curved or cupped and the paddle wheel may be offset from the center of EM pump tube flow. The housing may accommodate the offset. In an embodiment, the current interrupter may be located in at least one of the inlet and injection outlet side of the EM pump. The EM pump tube may comprise a protrusion or a section with a larger diameter to form a reservoir comprising a flow regulator to mitigate unsteady molten metal flow. The reservoir may receive the flow following its passage through the current interrupter. In an embodiment, the current interrupter may function to interrupt the current through the molten metal in both the inlet and the outlet EM pump tubes. The current interrupter may comprise a single paddle wheel that revives inlet flow on one half and receives out flow on the other half of the wheel. Each of the inlet and outlet tubes may comprise reservoirs downstream of the flow. The outlet flow may help turn the wheel to facilitate inlet flow that may otherwise be obstructed by the current interrupter such as a paddle wheel.

In an embodiment, the electrical current restrictor may comprise an auger inside of the EM pump tube with its axis aligned with the direction of flow and comprising a helical pitch to facilitate a desired auger shaft rotation based on the direction of flow. The electrical current restrictor may comprise an Archimedean screw pump-type wherein the rotation is achieved by the molten metal flow propelled by the EM pump. The auger may comprise an electrical insulator such as a ceramic such as one of the disclosure. The auger may comprise carbon or a metal such as stainless steel that may be coated with an insulator such as a ceramic such as alumina, silica, Mullite, BN or another of the disclosure. For low temperature operation such as below the melting point of the auger, the auger may comprise Teflon, Viton, Delrin, or another high-temperature polymer known by those skilled in the art. In an embodiment, the EM pump tube section housing the auger may comprise a larger diameter with a corresponding larger diameter auger to reduce resistance to molten metal flow. The auger may comprise mounts to secure it in place and permit it to rotate. The auger mounts on each end may each comprise a slip bearing on a shaft across the diameter of the housing of EM pump tube section housing the auger. The mounts may comprise a material resistant to forming an alloy with gallium such as stainless steel, tantalum, or tungsten. In an embodiment, the injection section of the EM pump tube comprises an electrical insulator such as a ceramic. The nozzle may be submerged to preferentially make an electrical contact between the ignition power and the corresponding injected molten metal stream.

In an embodiment, the SunCell® comprises at least one EM pump with a corresponding power supply and at least one ignition system and a corresponding power supply. In an embodiment, the corresponding power sources are of different frequencies, such that the ignition power from its supply is decoupled from the EM pump power form its supply when a common conduction circuit exists such as one having the molten metal as a common electrical contact. In an exemplary embodiment, an AC conduction EM pump may decouple from a DC conduction ignition current, or an DC conduction EM pump may decouple from an AC conduction ignition current. Alternatively, at least one of the EM pump and the ignition current may comprise an induction AC current maintained by corresponding AC transformer wherein multiple transformers are designed not to couple. Electrical coupling may also be eliminated in an embodiment comprising a mechanical pump such as a magnetic coupled, impeller, piston, rotating magnet, peristaltic, or other type of mechanical pump known in the art or a linear induction EM pump wherein the frequency of the ignition current and corresponding supply comprises any frequency and the current may be of conduction or induction type.

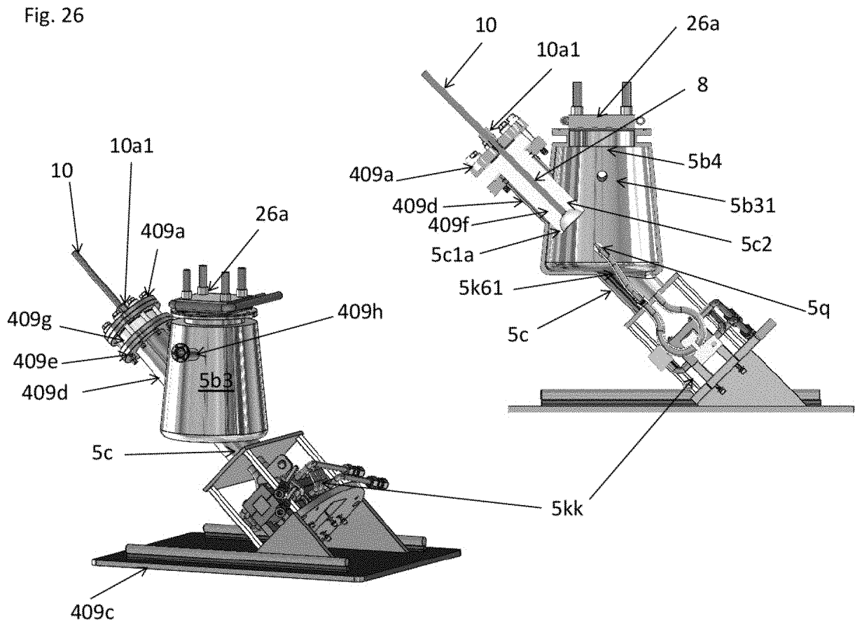

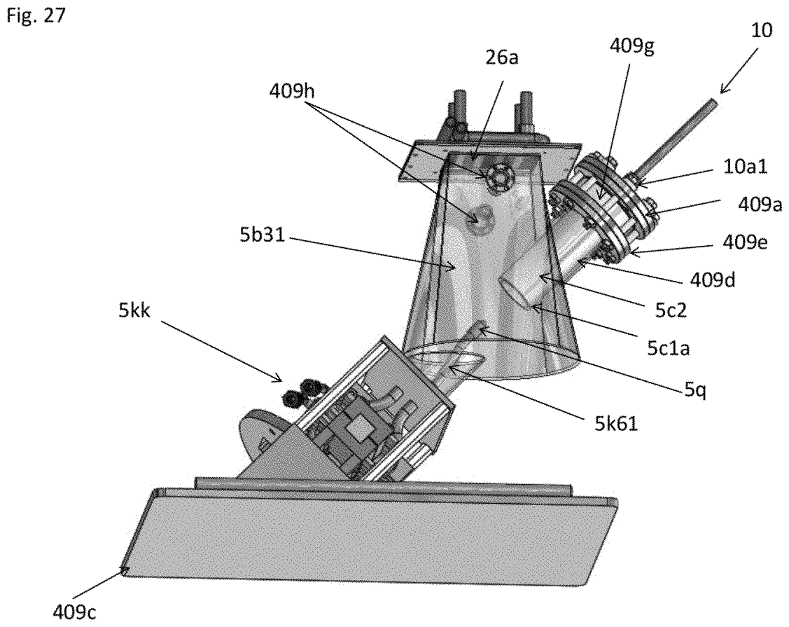

The SunCell® may further comprise a photovoltaic (PV) converter and a window to transmit light to the PV converter. In an embodiment shown in FIGS. 26-27, the SunCell® comprises a reaction cell chamber 5b31 with a tapering cross section along the vertical axis and a PV window 5b4 at the apex of the taper. The window with a mating taper may comprise any desired geometry that accommodates the PV array 26a such as circular (FIG. 26) or square or rectangular (FIG. 27). The taper may suppress metallization of the PV window 5b4 to permit efficient light to electricity conversion by the photovoltaic (PV) converter 26a. The PV converter 26a may comprise a dense receiver array of concentrator PV cells such as PV cells of the disclosure and may further comprise a cooling system such as one comprising microchannel plates. The PV window 5b4 may comprise a coating that suppresses metallization. The PV window may be cooled to prevent thermal degradation of the PV window coating. The SunCell® may comprise at least one partially inverted pedestal 5c2 having a cup or drip edge 5c1a at the end of the inverted pedestal 5c2 similar to one shown in FIG. 25 except that the vertical axis of each pedestal and electrode 10 may be oriented at an angle with respect to the vertical or z-axis. The angle may be in the range of 1° to 90°. In an embodiment, at least one counter injector electrode 5k61 injects molten metal from its reservoir 5c obliquely in the positive z-direction against gravity where applicable. The injection pumping may be provided by EM pump assembly 5kk mounted on EM pump assembly slide table 409c. In exemplary embodiments, the partially inverted pedestal 5c2 and the counter injector electrode 5k61 are aligned on an axis at 135° to the horizontal or x-axis as shown in FIG. 26 or aligned on an axis at 450 to the horizontal or x-axis as shown in FIG. 27. The insert reservoir 409f having insert reservoir flange 409g may be mounted to the cell chamber 5b3 by reservoir baseplate 409a, sleeve reservoir 409d, and sleeve reservoir flange 409e. The electrode may penetrate the reservoir baseplate 409a through electrode penetration 10al. The nozzle 5q of the injector electrode may be submerged in the liquid metal such as liquid gallium contained in the bottom of the reaction cell chamber 5b31 and reservoir 5c. Gases may be supplied to the reaction cell chamber 5b31, or the chamber may be evacuated through gas ports such as 409h.

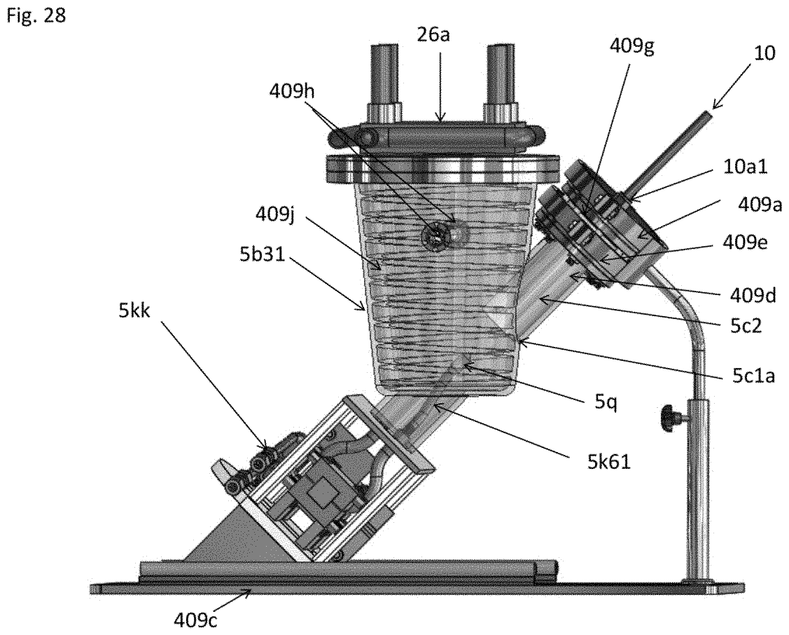

In an alternative embodiment shown in FIG. 28, the SunCell® comprises a reaction cell chamber 5b31 with a tapering cross section along the negative vertical axis and a PV window 5b4 at the larger diameter-end of the taper comprising the top of the reaction cell chamber 5b31, the opposite taper of the embodiment shown in FIGS. 26-27. In an embodiment, the SunCell® comprises a reaction cell chamber 5b31 comprising a right cylinder geometry. The injector nozzle and the pedestal counter electrode may be aligned on the vertical axis at opposite ends of the cylinder or along a line at a slant to the vertical axis.

In an embodiment, the PV window may comprise a plurality narrow channels or tubes that may be bundled together. Each channel may comprise a PV window on the end away from the reaction cell chamber. The channels may be oriented vertically. Molten metal propelled along the axis of the channels may be blocked from reaching the PV window by at least one of the mechanical reactance of the gas in the tube and by gravity. The initial kinetic energy of an upward moving particle may be converted to gravitational energy such that upward motion is stopped. The channel area may be in at least one range of about 0.01 cm² to 10 cm², 0.05 cm² to 5 cm², and 0.1 cm² to 1 cm².

In an embodiment, the PV window comprises a light transparent window and at least one mirror or reflector that physically blocks the molten metal from coating the light transparent window while reflecting the light in a manner such that the light is incident on the light transparent window by traveling an indirect pathway. The light transparent window may comprise a material such as quartz, sapphire, glass or another window material of the disclosure. The molten metal of the cell may comprise one of low emissivity such as molten gallium or molten silver. The reflector may comprise a surface that is coated with the molten metal such that the coated surface predominantly reflects incident light from the cell and directs the light to be incident on the window. The reflector may comprise a plurality of such surfaces such as metal plates that may be smooth. Metal particles may flow along straight trajectories and not bounce off the plurality of reflectors. Thus, the reflectors may block the metal flow to the window. The reflectors may be oriented at any desirable angle in any desirable arrangement that provides an indirect light path to the window while blocking straight-line paths of metal particles to the window. In an exemplary embodiment, the reflectors such as metal plates may be arranged in pairs comprising about parallel-planes with each plate having about the same tilt angle relative to the vertical axis and the second plate of the pair offset in the transverse direction relative to the first plate. A plurality of such pairs may be at least one of offset in the transverse direction relative to each other and offset in the vertical direction relative to each other. The angle of light incidence may about equal the angle of reflection during reflections. The light may be transversely displaced as it travels along a progressive vertical trajectory following a plurality of reflections from at least one pair of reflectors. The reflectors may be arranged to at least partially reverse any transverse light displacement. In an exemplary embodiment, the reflectors may be arranged such that light traveling in the positive z-direction is reflected in the transverse direction from a first reflector, and then reflected in the positive z-direction by a second reflector. In another embodiment, the reflectors may be arranged such that incident light is alternately reflected back and forth in the transverse direction as the trajectory advances in the z-direction. In an exemplary embodiment, light propagating in the z-direction undergoes the following sequence of reflections (i) transverse direction such as x-direction, (ii) positive z-direction, (iii) opposite transverse direction such as negative x-direction, and (iv) positive z-direction. The light may be made to transverse alight path that comprises a vertical zigzag. The zigzag path may be extended vertically by a desired distance using a plurality (integer n) of stacked reflector pairs. The members of each pair may be parallel relative to each other. Each nth successive pair may be oriented perpendicular to the (n −1)th pair to form a zigzag light channel. At least one of the x-width, y-width, and z-height of the zigzag channel may be controlled to selectively separate the light from the metal particles. At least one of the x-width, y-width, and z-height may be in the at least one range of 1 mm to 1 m, 5 mm to 100 cm, and 1 cm to 50 cm. In an embodiment, at least one of the channel x-width or y-width may vary as a function of vertical position or in the z-direction. The channel may at least one of taper, broaden, or vary in at least one width with height. The channel may comprise rectangular channel such as square channel. In an embodiment, at least one reflector may comprise a source of molten metal such as gallium that flows over the surface to maintain a high reflectivity. The source of molten metal may comprise at least one EM pump and one molten metal reservoir. The reservoir may comprise reservoir 5c.

The SunCell may comprise a transparent window to serve as a light source of wavelengths transparent to the window. The SunCell may comprise a blackbody radiator 5b4 that may serve as a blackbody light source. In an embodiment, the SunCell@ comprises a light source (e.g., the plasma from the reaction) wherein the hydrino plasma light emitted through the window is utilized in a desired lighting application such as room, street, commercial, or industrial lighting or for heating or processing such as chemical treatment or lithography.

In an embodiment, the SunCell® comprises an induction ignition system with a cross connecting channel of reservoirs 414, a pump such as an induction EM pump, a conduction EM pump, or a mechanical pump in an injector reservoir, and a non-injector reservoir that serves as the counter electrode. The cross-connecting channel of reservoirs 414 may comprise restricted flow means such that the non-injector reservoir may be maintained about filled. In an embodiment, the cross-connecting channel of reservoirs 414 may contain a conductor that does not flow such as a solid conductor such as solid silver.

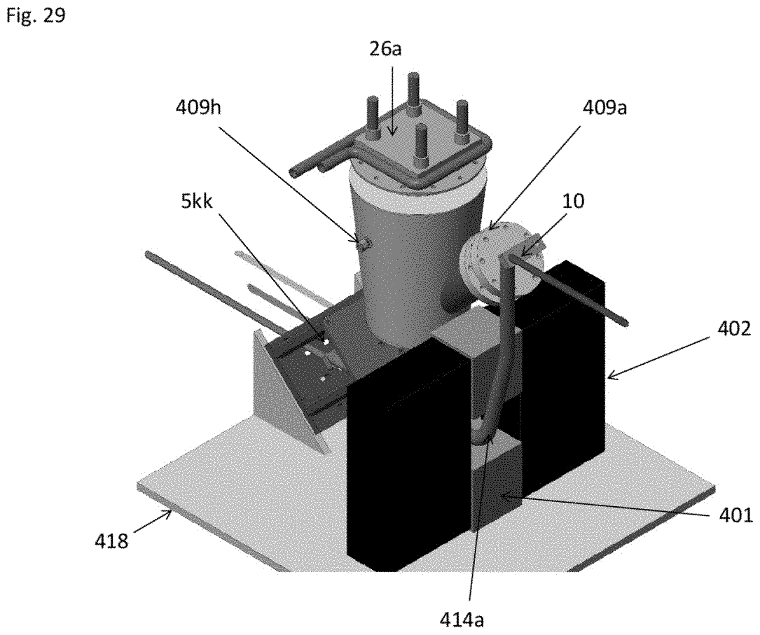

In an embodiment (FIG. 29), the SunCell® comprises a current connector or reservoir jumper cable 414a between the cathode and anode bus bars or current connectors. The cell body 5b3 may comprise a non-conductor, or the cell body 5b3 may comprise a conductor such as stainless steel wherein at least one electrode is electrically isolated from the cell body 5b3 such that induction current is forced to flow between the electrodes. The current connector or jumper cable may connect at least one of the pedestal electrode 8 and at least one of the electrical connectors to the EM pump and the bus bar in contact with the metal in the reservoir 5c of the EM pump. The cathode and anode of the SunCell® such as ones shown in FIGS. 25-28 comprising a pedestal electrode such as an inverted pedestal 5c2 or a pedestal 5c2 at an angle to the z-axis may comprise an electrical connector between the anode and cathode that form a closed current loop by the molten metal stream injected by the at least one EM pump 5kk. The metal stream may close an electrically conductive loop by contacting at least one of the molten metal EM pump injector 5k61 and 5q or metal in the reservoir 5c and the electrode of the pedestal. The SunCell® may further comprise an ignition transformer 401 having its yoke 402 in the closed conductive loop to induce a current in the molten metal of the loop that serves as a single loop shorted secondary. The transformer 401 and 402 may induce an ignition current in the closed current loop. In an exemplary embodiment, the primary may operate in at least one frequency range of 1 Hz to 100 kHz, 10 Hz to 10 kHz, and 60 Hz to 2000 Hz, the input voltage may operate in at least one range of about 10 V to 10 MV, 50 V to 1 MV, 50 V to 100 kV, 50 V to 10 kV, 50 V to 1 kV, and 100 V to 480 V, the input current may operate in at least one range of about 1 A to 1 MA, 10 A to 100 kA, 10 A to 10 kA, 10 A to 1 kA, and 30 A to 200 A, the ignition voltage may operate in at least one range of about 0.1 V to 100 kV, 1 V to 10 kV, 1 V to 1 kV, and 1 V to 50 V, and the ignition current may be in the range of about 10 A to 1 MA, 100 A to 100 kA, 100 A to 10 kA, and 100 A to 5 kA. In an embodiment, the plasma gas may comprise any gas such as at least one of a noble gas, hydrogen, water vapor, carbon dioxide, nitrogen, oxygen and air. The gas pressure may be in at least one range of about 1 microTorr to 100 atm, 1 milliTorr to 10 atm, 100 milliTorr to 5 atm, and 1 Torr to 1 atm.

When the secondary is open circuited due to disruptions or discontinuities in the molten stream between the electrodes caused by mechanisms such as at least one of shock waves from the hydrino plasma reaction and instabilities in the injected metal stream, flux may build up in the primary and cause the voltage to rise in the secondary until the plasma is reestablished. Once the plasma commences, the voltage may drop due to the high current developed in the secondary that opposes the flux in the primary. Thus, in an embodiment, the current loop comprising at least one molten metal stream, at least one EM pump reservoir, at least one molten metal EM pump injector, and the jumper cable connected at each end to the corresponding electrode bus bar and passing through the transformer primary can inherently regulate the voltage to achieve plasma ignition while minimizing the input power.

In an embodiment, the reaction cell chamber comprises walls that are not electrically conductive such that the induction flux penetrates the chamber and causes an induced voltage directly on the molten metal stream in the reaction cell chamber. The direct induction may increase the continuous nature of the ignition current relative to an externally applied AC voltage from a transformer for example. The cell wall may comprise quartz, or a ceramic such as alumina, hafnia, or zirconia, or another material of the disclosure. The SunCell® such as exemplary ones shown in FIGS. 25-32 may comprise an electric insulator such as ceramic or quartz cell chamber 5b3 with metal flanges 409g and one at the reservoir 5c to cell chamber 5b3 connection. The flanges may be attached to the electrical insulator by a metal to quartz or metal to ceramic seal such as one of the disclosure or one known in the art. The electrode bus bar 10 may be welded into a plate 409a that is bolted to the flange 409g and sealed by a gasket such as a copper gasket. The bus bar 10 may be covered by an electrical insulator pedestal 5c1 such as one comprising BN. In another embodiment wherein the chamber walls are electrically conductive, the wall may be at least one of thin and nonmagnetic to allow the magnetic flux to penetrate and link to the injected molten metal stream. The induction frequency may be lowered to permit better flux penetration.

In another embodiment, the cell chamber 5b3 comprises electrically conductive and nonconductive sections. The cell chamber 5b3 may comprise an electrical conductor such as stainless steel for sections that cut minimal amounts of magnetic flux from the ignition transformer primary and may comprise an electrical insulator for sections that are about perpendicular to the magnetic flux lines of the flux from the primary of the induction ignition transformer. The penetration of time-variable magnetic flux is highly dependent on the permeability of the cell chamber wall as reported by Yang et al. (D. Yang, Z. Hu, H. Zhao, H. Hu, Y. Sun, B. Hou, “Through-Metal-Wall Power Delivery and Data Transmission for Enclosed Sensors: A Review”, Sensors, (2015), Vol. 15, pp. 31581-31605; doi:10.3390/s151229870) which is incorporated by reference, especially section 2.1. Relative permeabilities of K˜1.002 to 1.005 are typically reported for 304 and 316 stainless steels in their annealed state (https://www.mtm-inc.com/ac-20110117-how-nonmagnetic-are-304-and-316-stainless-steels.html); whereas, quartz is diamagnetic and the permeability of gallium is −21.6×10⁻⁶ cm³/mol (at 290 K). In an exemplary embodiment comprising a reaction chamber of cubic geometry, the reaction cell chamber comprises windows that pass magnetic flux such as quartz windows mounted in SS flanges on the two opposite sides that maximumly cut the magnetic flux lines of the magnetic flux from the primary of the ignition transformer. Each window may be sealed to the corresponding cell face by a bolted matching flange welded to the SS face. In the case that the molten metal such as gallium coats the window, the effect on the flux penetration is expected to be minimal since exemplary molten metals gallium and silver are diamagnetic and the coatings may each be very thin. The windows may be positioned so that the magnetic flux penetrates the reaction cell chamber may maximumly directly induce an electric field in at least one of the plasma in the reaction cell chamber and the injected molten metal stream from the EM pump.

An exemplary tested embodiment comprised a quartz SunCell® with two crossed EM pump injectors such as the SunCell® shown in FIG. 10. Two molten metal injectors, each comprising an induction-type electromagnetic pump comprising an exemplary Fe based amorphous core, pumped Galinstan streams such that they intersected to create a triangular current loop that linked a 1000 Hz transformer primary. The current loop comprised the streams, two Galinstan reservoirs, and a cross channel at the base of the reservoirs. The loop served as a shorted secondary to the 1000 Hz transformer primary. The induced current in the secondary maintained a plasma in atmospheric air at low power consumption. The induction system is enabling of a silver-based-working-fluid-SunCell®-magnetohydrodynamic power generator of the disclosure wherein hydrino reactants are supplied to the reaction cell chamber according to the disclosure. Specifically, (i) the primary loop of the ignition transformer operated at 1000 Hz, (ii) the input voltage was 100 V to 150 V, and (iii) the input current was 25 A. The 60 Hz voltage and current of the EM pump current transformer were 300 V and 6.6 A, respectively. The electromagnet of each EM pump was powered at 60 Hz, 15-20 A through a series 299 μF capacitor to match the phase of the resulting magnetic field with the Lorentz cross current of the EM pump current transformer.

The transformer was powered by a 1000 Hz AC power supply. In an embodiment, the ignition transformer may be powered by a variable frequency drive such as a single-phase variable frequency drive (VFD). In an embodiment, the VFD input power is matched to provide the output voltage and current that further provides the desired ignition voltage and current wherein the number of turns and wire gauge are selected for the corresponding output voltage and current of the VFD. The induction ignition current may be in at least one range of about 10 A to 100 kA, 100 A to 10 kA, and 100 A to 5 kA. The induction ignition voltage may be in at least one range of 0.5 V to 1 kV, 1 V to 100 V, and 1 V to 10 V. The frequency may be in at least one range of about 1 Hz to 100 kHz, 10 Hz to 10 kHz, and 10 Hz to 1 kHz. An exemplary VFD is the ATO 7.5 kW, 220 V to 240 V output single phase 500 Hz VFD.

Another exemplary tested embodiment comprised a Pyrex SunCell® with one EM pump injector electrode and a pedestal counter electrode with a connecting jumper cable 414a between them such as the SunCell® shown in FIG. 29. The molten metal injector comprising an DC-type electromagnetic pump, pumped a Galinstan stream that connected with the pedestal counter electrode to close a current loop comprising the stream, the EM pump reservoir, and the jumper cable connected at each end to the corresponding electrode bus bar and passing through a 60 Hz transformer primary. The loop served as a shorted secondary to the 60 Hz transformer primary. The induced current in the secondary maintained a plasma in atmospheric air at low power consumption. The induction ignition system is enabling of a silver-or-gallium-based-molten-metal SunCell® power generator of the disclosure wherein hydrino reactants are supplied to the reaction cell chamber according to the disclosure. Specifically, (i) the primary loop of the ignition transformer operated at 60 Hz, (ii) the input voltage was 300 V peak, and (iii) the input current was 29 A peak. The maximum induction plasma ignition current was 1.38 kA.

In an embodiment, the source of electrical power or ignition power source comprises a non-direct current (DC) source such as a time dependent current source such as a pulsed or alternating current (AC) source. The peak current may be in at least one range such as 10 A to 100 MA, 100 A to 10 MA, 100 A to 1 MA, 100 A to 100 kA, 100 A to 10 kA, and 100 A to 1 kA. The peak voltage may be in at least one range of 0.5 V to 1 kV, 1 V to 100 V, and 1 V to 10 V. In an embodiment, the EM pump power source and AC ignition system may be selected to avoid inference that would result in at least one of ineffective EM pumping and distortion of the desired ignition waveform.

In an embodiment, the source of electrical power to supply the ignition current or ignition power source may comprise at least one of a DC, AC, and DC and AC power supply such as one that is powered by at least one of AC, DC, and DC and AC electricity such as a switching power supply, a variable frequency drive (VFD), an AC to AC converter, a DC to DC converter, and AC to DC converter, a DC to AC converter, a rectifier, a full wave rectifier, an inverter, a photovoltaic array generator, magnetohydrodynamic generator, and a conventional power generator such as a Rankine or Brayton-cycle-powered generator, a thermionic generator, and a thermoelectric generator. The ignition power source may comprise at least one circuit element such as a transition, IGBT, inductor, transformer, capacitor, rectifier, bridge such as an H-bridge, resistor, operation amplifier, or another circuit element or power conditioning device known in the art to produce the desired ignition current. In an exemplary embodiment, the ignition power source may comprise a full wave rectified high frequency source such as one that supplies positive square wave pulses at about 50% duty cycle or greater. The frequency may be in the range of about 60 Hz to 100 kHz. An exemplary supply provides about 30-40 V and 3000-5000 A at a frequency of in the range of about 10 kHz to 40 kHz. In an embodiment, the electrical power to supply the ignition current may comprise a capacitor bank charged to an initial offset voltage such as one in the range of 1 V to 100 V that may be in series with an AC transformer or power supply wherein the resulting voltage may comprise DC voltage with AC modulation. The DC component may decay at a rate dependent on its normal discharge time constant, or the discharge time may be increased or eliminated wherein the ignition power source further comprises a DC power supply that recharges the capacitor bank. The DV voltage component may assist to initiate the plasma wherein the plasma may thereafter be maintained with a lower voltage.

In an embodiment, SunCell® comprises means to concentrate the current density between the electrodes such as a set comprising an injector electrode and a counter electrode to increase the hydrino reaction rate. The high current density may form an arc current that additionally lowers the input power to increase the power gain due to the hydrino reaction. In an embodiment such as one shown in FIG. 25, the cell chamber 5b3 or walls or the reaction cell chamber 5b31 are nonconducting such that the hydrino reaction plasma is highly focused with a high ignition current density. At least one of the reservoir 5c, cell chamber 5b3, and the reaction cell chamber 5b31 walls may comprise a non-conductor such as quartz, fused silica, a ceramic such as alumina, hafnia, zirconia, or another non-conductor of the disclosure. The flanges for the counter electrode and the reservoir flange may comprise metal joined to the non-conductor such as metal to quartz or Pyrex as disclosed in the disclosure. In an embodiment such as shown in FIG. 25 wherein the reaction chamber and reservoir may comprise a nonconductor such as quartz or fused silica, at least one of the reaction cell chamber 5b31, reservoir 5c, and gas port 409h may comprise quartz to metal high temperature flanges to connect (i) the reaction cell chamber to a pedestal electrode assembly such as one comprising flange 409g, bus bar 10, electrode 8, and pedestal 5c1, (ii) the bottom of the reservoir 5c to an EM pump assembly comprising a baseplate, an EM pump inlet with an optional screen 5qa1 or riser tube 5qa, and an EM pump ejector tube, and (iii) at least one of the gas supply and vacuum ports to the corresponding gas and vacuum lines. The seals, flanges, connections, gaskets, and fasteners may be ones of the disclosure or ones known in the art. In an embodiment, the reaction cell chamber walls may comprise a conductor such as a metal such as stainless steel comprising a non-conductor coating such as BN, Mullite, alumina, silica, or another of the disclosure wherein the electrical leads that penetrate from outside to inside the reaction cell chamber are electrically isolated.

In an embodiment, at least one of the hydrino plasma and ignition current may comprise an arc current. An arc current may have the characteristic that the higher the current, the lower the voltage. In an embodiment, at least one of the reaction cell chamber walls and the electrodes are selected to form and support at least one of a hydrino plasma current and an ignition current that comprises an arc current, one with a very low voltage at very high current. In an embodiment of a single injector cell design such as one shown in FIG. 25, the non-injector electrode 8 may be the positive electrode. The hydrino reaction may occur at the positive electrode. Making the non-injector electrode the positive electrode may increase the current density at the region in the reaction cell chamber where the hydrino reaction has the highest kinetics. The electrode 8 (FIG. 25), may be concave on the end 5c1a exposed to the hydrino reaction to support gallium pooling to protect the electrode 8 from thermal damage. In an embodiment, the injector electrode may be non-submerged to concentrate the plasma and increase the current density. The injector electrode may comprise a refractory material such as a refractory metal such as tungsten. At least one of the reaction cell chamber volume and the molten metal surface area such as at least one of the reaction cell chamber and the reservoir may be minimized to increase the ignition current density. The current density may be in at least one range of about 1 A/cm² to 100 MA/cm², 10 A/cm² to 10 MA/cm², 100 A/cm² to 10 MA/cm², and 1 kA/cm² to 1 MA/cm². In an exemplary embodiment to increase the current density, the non-injector electrode 8 may be the either the positive or negative electrode and comprise a portion such as a refractory metal portion such as a W or Ta rod at least partially protruding into a concave pedestal drip edge 5c1 of a BN pedestal 5c2. In an embodiment, the concave pedestal drip edge 5c1 of a BN pedestal 5c2 may comprise a refractory material such as a ceramic such as one of the disclosure or a refractory metal such as tungsten, tantalum, or molybdenum or another of the disclosure. The top portion of the pedestal 5c2 may comprise an electrical insulator on the bus bar 10 to prevent it from shorting to the reaction chamber wall. The insulator may comprise a ceramic such as BN or another of the disclosure. The H₂ flow may be increased with the increase in current density to produce at least one of a higher output power and gain. In an exemplary embodiment, a large plate or cup is attached to the end of the electrode 10. In another embodiment, the injector electrode may be submerged to increase the area of the counter electrode. In an embodiment comprising a spherical cell such as the one show in FIG. 25, the electrodes are positioned such that the ignition occurs in center of the spherical reaction cell chamber to reinforce the hydrino reaction plasma by normal incident reflection of outgoing shock waves from the hydrino reaction.

In an embodiment, the molten metal may comprise a metal or alloy with at least one property that supports a high gain from the hydrino reaction. The molten metal may comprise one with at least one attribute of the group of high conductivity to decrease the input voltage and improve the gain, a low viscosity to improve the EM pumping to support a more intense hydrino reaction, resist forming an oxide coat to improve the conductivity between the SunCell® electrodes, and possesses a low propensity to wet the PV window. In an exemplary embodiment, the molten metal may comprise Galinstan. The gallium component of Galinstan may reduce other oxides of the alloy such as at least one of In₂O₃ and SnO₂ to form gallium oxide. The gallium oxide may be converted back to gallium metal or removed by means of the disclosure such as hydrogen reduction. In an embodiment, the molten metal may comprise galinstan plus small amounts (such as less than 2 wt %) of at least one other metal such as one or more of bismuth and antimony. The other metal or metals may at least one of decrease PV window wetting increase fluidity, decrease oxidation, and increase the boiling point of the molten metal. In an exemplary embodiment, the molten metal comprising a eutectic alloy comprises 68-69 wt % Ga, 21-22 wt % In, and 9.5-10.5 wt % Sn, with small amounts of Bi and Sb (0-2 wt %, each), and an impurity level less than 0.001% wherein the melting point is about −19.5° C. and boiling point is higher than 1800° C. In another embodiment, the molten metal comprises Field's alloy comprising a eutectic mixture or bismuth, indium, and tin.

In an embodiment, the ignition system may apply a high starting power to the plasma and then decrease the ignition power after the resistance drops. The resistance may drop due to at least one of an increase in conductivity due to reduction of any oxide in the ignition circuit such as on the electrodes or the molten metal stream, and formation of a plasma. In an exemplary embodiment, the ignition system comprises a capacitor bank in series with AC to produce AC modulation of high-power DC wherein the DC voltage decays with discharge of the capacitors and only lower AC power remains.

In an embodiment, the pedestal electrode 8 may be recessed in the insert reservoir 409f wherein the pumped molten metal fills a pocket such as 5c1a to dynamically form a pool of molten metal in contact with the pedestal electrode 8. The pedestal electrode 8 may comprise a conductor that does not form an alloy with the molten metal such as gallium at the operating temperature of the SunCell®. An exemplary pedestal electrode 8 comprises tungsten, tantalum, stainless steel, or molybdenum wherein Mo does not form an alloy such as Mo₃Ga with gallium below an operating temperature of 600° C. In an embodiment, the inlet of the EM pump may comprise a filter 5qa1 such as a screen or mesh that blocks alloy particles while permitting gallium to enter. To increase the surface area, the filter may extend at least one of vertically and horizontally and connect to the inlet. The filter may comprise a material that resists forming an alloy with gallium such as stainless steel (SS), tantalum, or tungsten. An exemplary inlet filter comprises a SS cylinder having a diameter equal to that of the inlet but vertically elevated. The filter many be cleaned periodically as part of routine maintenance.

In an embodiment, the non-injector elector electrode may be intermittently submerged in the molten metal in order to cool it. In an embodiment, the SunCell® comprises an injector EM pump and its reservoir 5c and at least one additional EM pump and may comprise another reservoir for the additional EM pump. Using the additional reservoir, the additional EM pump may at least one of (i) reversibly pump molten metal into the reaction cell chamber to intermittently submerge the non-injector electrode in order to cool it and (ii) pump molten metal onto the non-injector electrode in order to cool it. The SunCell® may comprise a coolant tank with coolant, a coolant pump to circulate coolant through the non-injector electrode, and a heat exchanger to reject heat from the coolant. In an embodiment, the non-injector electrode may comprise at a channel or cannula for coolant such as water, molten salt, molten metal, or another coolant known in the art to cool the non-injector electrode.

In an inverted embodiment shown in FIG. 25, the SunCell® is rotated by 180° such that the non-injector electrode is at the bottom of the cell and the injector electrode is at the top of the reaction cell chamber such that the molten metal injection is along the negative z-axis. At least one of the noninjector electrode and injector electrode may be mounted in a corresponding plate and may be connected to the reaction cell chamber by a corresponding flange seal. The seal may comprise a gasket that comprises a material that does not form an alloy with gallium such as Ta, W, or a ceramic such as one of the disclosure or known in the art. The reaction cell chamber section at the bottom may serve as the reservoir, the former reservoir may be eliminated, and the EM pump may comprise an inlet riser in the new bottom reservoir that may penetrate the bottom base plate, connect to an EM pump tube, and provide molten metal flow to the EM pump wherein an outlet portion of the EM pump tube penetrates the top plate and connects to the nozzle inside of the reaction cell chamber. During operation, the EM pump may pump molten metal from the bottom reservoir and inject it into the non-injector electrode 8 at the bottom of the reaction cell chamber. The inverted SunCell® may be cooled by a high flow of gallium injected by the injector electrode for the top of the cell. The non-injector electrode 8 may comprise a concave cavity to pool the gallium to better cool the electrode. In an embodiment, the non-injector electrode may serve as the positive electrode; however, the opposite polarity is also an embodiment of the disclosure.

In an embodiment, the electrode 8 may be cooled by emitting radiation. To increase the heat transfer, the radiative surface area may be increased. In an embodiment, the bus bar 10 may comprise attached radiators such as vane radiators such as planar plates. The plates may be attached by fasting the face of an edge along the axis of the bus bar 10. The vanes may comprise a paddle wheel pattern. The vanes may be heated by conductive heat transfer from the bus bar 10 that may be heated by at least one of resistively by the ignition current and heated by the hydrino reaction. The radiators such as vanes may comprise a refractory metal such as Ta or W.

In an embodiment, the SunCell® comprises a means of confining at least one of the ignition current and plasma current to increase the current density. The confinement means may comprise plasma confining magnets. The SunCell® may further comprise magnets to at least one of confine and stabilize the plasma to increase the current density. The confinement means may comprise an ignition current source of sufficiently high current to cause a magnetic pinch effect. The current may be selected such that when the current is pinched an arc current results wherein the voltage drops with increasing current. The arc current may increase the power gain. The pinch plasma may be formed by DC or AC power applied to electrodes or by maintaining an induction current in a current loop such as one comprising dual injected molten metal streams of the induction ignition system of the disclosure. The SunCell® may comprise a dense plasma focus device. In an embodiment, the reaction chamber wall may serve as an electrode and the metal stream formed by the injector electrode may comprise the counter electrode such that the application of ignition power causes a plasma between the two electrodes that behaves as a dense focus plasma. In an embodiment such as the one shown in FIG. 25, at least one of the reaction cell chamber and the reservoir may comprise a non-conductor such as quartz or another ceramic of the disclosure, and the non-injector electrode may comprise a liner 5b31a of the reaction cell chamber that is electrically isolated from the injector electrode. The liner may be electrically connected to the electrode 8. The molten metal stream and the liner electrode may comprise concentric electrodes of a pinch plasma device such as a plasma focus device. The ignition power may provide at least one of sufficient voltage, current, and power to cause a pinch effect in the plasma between the two electrodes. The ignition power may be applied continuously or intermittently by a controller.

In an embodiment, the PV window for the transmission of light generated by the hydrino reaction from the reaction cell chamber 5b31 to a photovoltaic (PV) power converter may be positioned behind the inverted pedestal (FIG. 25). The inverted pedestal may block the flow of metal to the PV window to prevent it from becoming opacified. In an embodiment, the SunCell® may further comprise at least one plasma permeable baffle or screen to block the flow of metal particles to the PV window while permitting the permeation of the light-emitting plasma formed by the hydrino reaction. The baffle or screen may comprise one or more of at least one grating or cloth such as ones comprising stainless steel or other refractory corrosion resistant material such as a metal or ceramic.

In an embodiment, the reaction cell chamber 5b31 may comprise a series of baffles to prevent metal particles from metalizing the photovoltaic (PV) window. The reaction cell chamber may comprise a cylindrical geometry. The baffles may be arranged to preferentially block the trajectory or flow of metal particles while allowing the light emitting plasma a to flow to regions that emit light through the PV window 5b4. In an embodiment, the baffles may be oriented such that at least a portion has a projection in a plane perpendicular to the vertical or z-axis. The PV window may be in a plane perpendicular to the z-axis. The baffles may be arranged in a helix from the base to the PV window. The baffles may comprise a spiral stair case geometry. The plasma may flow around the baffles of the helix while the metal particles are blocked.

In an embodiment, the top of the cell chamber 5b3 may comprise a PV window wherein the gas flow at the top of the reaction cell chamber 5b31 has at least one property such as majority flow parallel to the plane of the window, low axial flow, and low flow. In an embodiment, the cell chamber 5b3 comprises at least one of tapered walls, cylindrical symmetry, and a means such as a helical series of baffles 409j (FIG. 28) to direct the gas flow in the reaction cell chamber 5b31 to create a cyclone. The tapered-wall cell chamber 5b3 may comprise the PV window at the large diameter end located in an orientation with the PV window on top of the cell. In an embodiment, the baffles in the reaction cell chamber 5b31 may create a cyclone wherein the axial gas flow is primarily along the tapered portion of the cell chamber 5b3 to the small diameter end or bottom wherein the gas flow reverses to flow toward the mid-section. The cyclone may force the flow downward again to create an axial circulation between the bottom and the mid-section of the reaction cell chamber 5b31.

In an embodiment comprising a time dependent ignition current such as AC current, at least one of the baffle and PV window comprises a circumferential frame that is charged by the alternating current such that the molten metal is repelled from the vicinity of the PV window to block the PV window from being coated with the molten metal.

In an embodiment, the SunCell® may comprise a molten metal such as gallium. The SunCell® may further comprise a photovoltaic (PV) converter and a window to transmit light to the PV converter, and may further an ignition EM pump such as one disclosed as an electrode EM pump or second electrode EM pump in Mills Prior Applications such as one comprising at least one set of magnets to produce a magnetic field perpendicular to the ignition current to produce a Lorentz force to confine the plasma and molten metal such that the plasma light can transmit through the window to the PV converter. The ignition current may be along the x-axis, the magnetic field may be along the y-axis, and the Lorentz force may be along the negative z-axis. In another embodiment, the SunCell® comprising a photovoltaic (PV) converter and a window to transmit light to the PV converter further comprises at least one of a mechanical window cleaner and a gas jet or air knife to remove molten metal which may accumulate on a window surface during operation. The gas of the gas jet or knife may comprise reaction cell chamber gas such as at least one of reactants, hydrogen, oxygen, water vapor, and noble gas. In an embodiment, the PV window comprises a coating such as one of the disclosure that prevents the molten metal such as gallium from sticking wherein the thickness of the coating is sufficiently thin to be highly transparent to the light to be PV converted into electricity. Exemplary coatings for a quartz reaction cell chamber section are thin-film boron nitride and carbon. Quartz may be a suitable material by itself to serve as a reaction cell chamber wall and PV window material.

In another embodiment, the reaction cell chamber may comprise a solvent or a transport agent, transport reactant, or transport compound such as GaX₃ (X=halide) such as GaCl₃ or GaBr₃ or a long chain hydrocarbon that removes at least one of deposited gallium metal and gallium oxide from the PV window surface. The solvent or a transport agent may at least one of dissolve, suspend, and transport at least one of the deposited gallium metal and gallium oxide to cause their removal. The removal may be enhanced by the gas jet or knife. In an embodiment, the window comprises a material that resists wetting by gallium metal such as quartz and other non-wetting materials of the disclosure. The solvent or transport agent such as GaX₃ (X=halide) may dissolve and remove gallium oxide such that the remaining purified gallium metal beads up and is easily removed by gravity, gas jet, mechanically with a means such as a wiper, vibration, and a centrifugal force. The removal may be by means such as those of the disclosure. The Ga₂O₃ may be selectively removed by reaction with the solvent or transport agent such as GaX₃ (X=halide). The reaction product may comprise an oxyhalide such as gallium oxyhalide. The oxyhalide may be volatile. The PV window may be operated at a temperature to cause the oxyhalide to vaporize from the surface of the PV window.

In an embodiment, the reaction mixture to form hydrinos in the reaction cell chamber 5b31 comprises GaX₃ (X=halide) to form gaseous molecules to react with H₂O dimers to produce nascent HOH that can serve as the hydrino catalyst. The GaX₃+H₂O dimer reaction product may be at least one of gallium oxide or gallium oxy halide. The breaking of the H₂O dimers to form nascent HOH catalyst may increase the hydrino reaction rate. In another embodiment, the GaX₃ such as GaCl₃ may react with water to maintain a regenerative cycle to form nascent HOH that may serve as the catalyst to form hydrinos. The regenerative reaction mixture may comprise at least two of GaX₃, Ga, H₂O and H₂. An exemplary reaction is 2Ga+GaCl₃+3H₂O to 3GaOCl+3H₂ and 3GaOCl+3H₂ to 3H₂O (nascent)+GaCl₃+2Ga. In an embodiment, the SunCell® may comprise a cold trap, cold reservoir, or cold finger comprising a gas connection to the reaction cell chamber 5b31 and a temperature controller wherein the vapor pressure of at least one of gallium halide and gallium oxyhalide may be controlled by controlling the temperature of the cold trap. In an exemplary embodiment, hydrogen is flowed into the reaction cell chamber that contains a source of oxygen such as gallium oxide and gallium chloride or bromide wherein the vapor pressure of the gallium halide is control by controlling the temperature of a cold reservoir for gallium halide that is in gaseous connection, but external to the reaction cell chamber.

In an embodiment, at least one of the reaction cell chamber 5b31 and the PV window may comprise a solvent that may be on or condense on the surface of the PV window to solvate molten metal which may accumulate on the PV window during operation. For example, gallium adhered to the surface of the PV window or baffle due to a gallium oxide coat on the gallium may be removed by the solvent that dissolves the gallium oxide coat. The solvent may comprise a hydroxide such as sodium or potassium hydroxide. The hydroxide may be aqueous. The SunCell® may comprise a PV window or baffle cleaning system comprising at least one of a mean to remove the window, a chamber and means to clean the window, a cleaning solution such as an aqueous hydroxide solution, and mean to separate gallium and any dissolved gallium oxide from the cleaning solution, and a means to replace the window following cleaning. In an embodiment, the PV window or baffle cleaning system may clean the window with a hydroxide solution such as an aqueous solution, the gallium, oxide solvation product, and the solution may be separated, and at least one of the gallium and the oxide solvation product may be is returned to the reaction cell chamber or a gallium regeneration system. The cleaning may occur with the PV window in its permanent position, or it may be removed, cleaned, and returned. The PV window or baffle cleaning system may comprise a plurality of windows wherein one may serve as the acting window while at least one other is being cleaned. The cleaning may occur in a separate chamber or in a chamber in connection with the reaction cell chamber. The means to remove and replace the PV window or baffle may comprise one known in the art such as a mechanical, electromagnetic, pneumatic, or hydraulic system. The means to separate the gallium and solvent may be ones known in the art such as filtration and centrifugation systems.

In an embodiment, metal such as cesium that has a low boiling point, forms an alloy with gallium at a first temperature, and boils separately from the alloy at a higher temperature is added to gallium as a transport agent. The metal such as cesium selectively boils at its boiling point and condenses on the PV window as a liquid that then forms an alloy with gallium deposited on the window to dissolve it. The alloy may be removed from the window by flow or assisted removal by means such as an air jet or a mechanical wiper.

In an embodiment, the molten metal may comprise an alloy that is less wetting of the baffle or PV window than the pure metal. The alloy may comprise gallium and a noble metal or a metal that is not oxidized by H₂O such as at least one of Pt, Pd, Ir, Re, Ru, Rh, Au, Cu, and Ni. In an exemplary embodiment wherein the silver changes the wetting behavior of gallium to prevent adhesion, the pure metal comprises gallium and the alloy comprise gallium silver alloy wherein the silver inhibits the formation of a gallium oxide coat that otherwise results in the high wetting of gallium towards baffle or window materials such as quartz, sapphire, and MgF₂ or another of the disclosure.

In an embodiment, gallium may respond to the application of an electric field as reported by Chrimes et al. [https://www.ncbi.nlm.nih.gov/pubmed/26820807]. The reaction cell 5b3 may comprise at least one of a source of electric field and an external magnet to induce an electric field in the plasma contained the reaction cell chamber 5b31 to direct the plasma in a desired direction. The source of electric field may comprise at least one of one or more induction coils, electric feed throughs, electrodes, power supplies, and power supply controllers. The directional control of the plasma may at least one of direct the plasma heating power to a desire region in the reaction cell chamber and direct gallium metal particle flow from the PV window. The directional control may at least one of prevent the development of hot spots in the reaction cell 5b3 and prevent the PV window from being metalized.

In an embodiment, the plasma may be directed to a desired location by an external field such as a magnetic field, an electric field or an induced electric or magnetic field. The plasma directing may enhance the performance of the baffles to reduce metallization of the PV window. In an embodiment, the SunCell® comprises a means to apply an electrical charge to the PV window 5b4. The electrical charge may repel like-charged metal particles in the reaction cell chamber 5b31 to reduced metallization of the PV window. In an exemplary embodiment, the reaction cell chamber 5b31 may be charged negatively wherein the negative charge may be applied by a connection with a negatively charged injection reservoir, and the PV 5b4 window may be charged negatively to repel molten metal particles such as at least one of gallium or gallium oxide particles in the reaction cell chamber 5b31 to decrease metallization of the PV window. The PV window may comprise an electrical conductor on the inner surface of the window such as at least one electrode such as a metal grid to serve as a means to charge the PV window. Alternatively, the window may comprise a conductive material or coating such as indium tin oxide to charge the window such as negatively charge the window. The electrical conductor such as a metal grid on the inner surface of the window may be in contact with the reaction cell chamber 5b31 to become charged. In another embodiment, the PV window may comprise at least one electrical conductor such as at least one pin that penetrates the PV window. The SunCell® may comprise a power source to charge the conductor.

In an embodiment, the window may comprise a source of repeller field such as a repeller electric field. The source may comprise an inner electrode closest to the plasma and an outer electrode closest to the PV widow. The source may comprise at least one source of electrical potential. The inner electrode may be maintained at one potential, and the outer electrode may be maintained at another potential such as a higher potential such that a potential difference and corresponding field exists between the electrodes. The electrodes may be at least partially open to allow radiation to pass. An exemplary electrode comprises a metal mesh such as a refractory metal mesh such as W mesh. In an exemplary embodiment, the inner electrode is maintained at about 100 V, and the outer electrode is maintained at about 300 V.

In an embodiment, the PV window may comprise at least one transparent piezoelectric crystal such as quartz, gallium phosphate, lead zirconate titanate (PZT), or crystalline boron silicate such as tourmaline. At least one of mechanical strain may be applied to the PV window to produce electricity and electricity may be applied to electrodes in contact with the PV window to cause mechanical motion of the window. At least one of the produced electricity and the caused mechanical motion may cause metallization to be removed from the PV window. In another embodiment, the intense plasma from the hydrino reaction may heat the inner surface of the PV window and vaporize the metallization. In an embodiment, the PV window or baffle comprises a piezoelectric direct discharge (PDD) system. At least one of the high voltage and a plasma formed in the gas of the reaction cell chamber by the PDD system may at least one of inhibit adherence and facilitate removal of gallium particles from the PV window. The PDD system may comprise at least one coronal electrode such as one that does not significantly block the hydrino reaction plasma light incident on the PV window or baffle. The coronal electrode may comprise at least one wire such as a wire that comprises a refractory metal such as tungsten, tantalum, or rhenium. In an embodiment, the reaction cell chamber may comprise hydrogen, and the PPD system may cause hydrogen dissociation. The resulting atomic hydrogen may reduce gallium oxide to reduce its wetting of the PV window.

The PV window may be cooled on the outer surface to prevent thermal window failure. The PV window may be mounted on a reaction cell chamber extension to place it in a location removed from the most intense heating region. In an embodiment, the electrodes of the piezoelectric PV window may comprise grid wires that permit light to penetrate the window. The electrodes may comprise a transparent conductor such as surface coatings of graphene, indium tin oxide (ITO), indium-doped cadmium oxide (ICdO), aluminum-doped zinc oxide (AZO), gallium-doped zinc oxide (GZO), indium-doped zinc oxide (IZO), indium tungsten oxide (IWO), ITO, ICdO, AZO, GZO, IZO, or IWO coated with tungsten oxide, or another transparent conductor known to those skilled in the art. In another embodiment, the electrodes may be along the edges of the PV window. The PV converter may further comprise a chamber such as an evacuated chamber between the PV window and the PV cell array of the PV converter to prevent sound wave propagation to the PV cell array.

In an embodiment, the PV window may comprise a deformable and transparent material such as glass, Pyrex, or Guerilla glass. The deformable window may be mechanically excited or vibrated to remove or prevent the metallization. The mechanical PV window excitation means may comprise at least one of a mechanical, pneumatic, piezoelectric, hydraulic, and other excitation means known by those skilled in the art. The PV window-PV converter may comprise a demagnetizer such as a surface type demagnetizer such as Industrial Magnetics, Inc. DSC423-120. The PV window may comprise at least one ferromagnetic material such as at least one of Fe, Ni, Co, AlNiCo, and rare earth metal and alloy wherein the window may be vibrated by application of the demagnetizer. The ferromagnetic material may comprise at least one strip or wire that is least one of bound or fastened to at least one surface of the window, sandwiched in between window layers, and embedded in the window. An exemplary demagnetizer comprises a solenoidal coil powered by an AC field that produces an alternating upward and downward magnetic force along the z-axis on the ferromagnetic material of the PV window in the xy-plane causing the PV window to deflect alternately upward and downward. The vibrations dislodge material adhered to the surface of the PV window. The demagnetizer may be positioned behind the PV cell array to prevent it from blocking light through the PV window to the PV cells.

In an embodiment, the PV window may comprise a wiper for the surface facing the reaction cell chamber. The wiper may comprise a soft, chemically and thermally resistant material such as graphite. The PV window may further comprise a gas knife. The gas may comprise recycled reaction cell gas. In an embodiment, the PV window further comprises a gas pump, and gas source or gas inlet, and at least one gas jet comprising at least one nozzle to impinge the inner window surface with high velocity gas. The PV window may comprise geometry such as domed to facilitate gas flow over the surface. The gas may comprise cell gas that may be recirculated by the pump through the inlet and out the at least one nozzle. A controller to clear the inlet of any metal or metal oxide that may impede the inlet flow may periodically reverse the gas flow. In an embodiment, the gas of the gas jet may comprise particles to bombard the metal on the PV window and remove it. The particles may be recycled to and from the reaction cell chamber or introduced from outside the reaction cell chamber to be consumed. Exemplary embodiments of the former and the latter cases are fine carbon particles and ice crystals, respectively.

In an embodiment, the SunCell® comprises at least one transparent baffle that rotates to provide a centrifugal force. The baffle may be in front of the PV window and block at least one of molten gallium and gallium oxide from being deposited on the window. The centrifugal force may remove molten gallium and gallium oxide that is deposited on the baffle during operation of the SunCell®. The baffle may comprise a material of the disclosure such as quartz that is resistant to being wetted by at least one of gallium and gallium oxide. The reaction cell chamber 5b31 may comprise at least one of a solvent and a transport agent such as gallium halide or water to facilitate the removal of baffle deposits. The transport agent may react with at least one of the gallium oxide and gallium to form a product that is more readily removed by the centrifugal force. The gallium halide may be a recycled reagent within the reaction cell chamber. The water may be that injected to provide at least one of the source of H and HOH catalyst to form hydrinos. The gas jet may be applied to the transparent baffle to further facilitate removal of deposits. An exemplary transparent baffle comprises a flat disc, but it may comprise other shapes and geometries such as a concave or convex disc, a conical shape, or another cylindrically symmetrical shape. The baffle may comprise a shaft attached to its center, a sealed shaft penetration with a sealed bearing at the PV window, and a shaft drive, motor, and controller outside of the PV window and reaction cell chamber of the SunCell®. In another embodiment, the baffle may be spun electrically or pneumatically. The disc may be turned by DC magnetic coupling or AC magnetic induction. The disc may comprise at least one DC magnet or induction coil with at least one DC magnet or induction coil external to the PV window and cell, respectively. The external DC magnet may be rotated by a rotation means. The induction coil may be at least one of temporally and spatially energized by an induction power source and controller to cause a rotating force on the baffle. In an embodiment, the rotating baffle may comprise the PV window. At least one of the rotating baffle and rotating PV window may comprise an adaptation of a commercial design suitable for the operating conditions of the SunCell®. Exemplary commercial products with adaptable designs are Clear-View-Screens made by Cornell Carr (http://www.cornell-carr.com/products/clear-view-screens.html) or the spin window system by Visiport (http://www.visiport.com/) which are incorporated herein by reference. In an embodiment, (i) the seals, bearings and frame comprise materials resistant to forming an alloy with gallium such as stainless steel, tantalum, and tungsten, (ii) the window comprises a material that is resistant to wetting by gallium such as quartz or other non-wetting materials of the disclosure, and (iii) the seals are capable of at least one of vacuum and elevated pressure at elevated temperature.

In an embodiment, a PV window system comprises at least one of a transparent rotating baffle in front of a stationary sealed window, both in the xy-plane for light propagating along the z-axis and a window that may rotate in the xy-plane for light propagating along the z-axis. An exemplary embodiment comprises a spinning transparent disc such as a clear view screen https://en.wikipedia.org/wiki/Clear_view_screen) that may comprise at least one of the baffle and the window. In another embodiment, a PV window system may comprise a window in the xy-plane and further comprise a paddle-wheel-type or vane-pump-type baffle in front of the window wherein the baffle comprises a plurality of transparent vanes rigidly attached to a rotating shaft oriented along an axis in the xy-plane for light propagating along the z-axis. In another embodiment, a vane-pump-type PV window comprises a plurality of transparent vanes rigidly attached to a rotating shaft oriented along an axis in the xy-plane for light propagating along the z-axis. A PV window system may comprise both a vane-pump-type baffle and a vane-pump-type PV window. In an embodiment, the vane spacing on the rotating shaft provides that the window is always covered by a combination of contiguous vanes as the vanes rotate relative to the window. In an embodiment wherein both the baffle and the window are vane-pump-types that rotate, the vane spacing on each rotating shaft and the shaft rotations are synchronized between the baffle and window such that the window is always covered by a combination of contiguous baffle vanes as both sets of vanes rotate. The vanes may be straight blades, curve blades, or other geometry that facilitates the blocking of the particles, transmission of the light, and pump the removed particles. The transparent vanes may comprise a material of the disclosure that is resistant to being wetted by the particles such as gallium particles. Exemplary materials are quartz and diamond-like carbon (DLC)-coated glass, Pyrex, or guerrilla glass. The centrifugal force from the rotating vanes may cause any particles deposited on the vanes to be removed. The rotation speed may be sufficient to create sufficient centrifugal force to remove deposited particles. The rotational speed may be in at least one range of about 1 RPM to 10,000 RPM, 10 RPM to 5,000 RPM, and 100 RPM to 3,000 RPM.

The rotating disc, vane-pump-type baffle, and vane-pump-type window may each comprise a drive mechanism and controller. The drive system may comprise a pneumatic, mechanical, hydraulic, or electrical drive system, or another known in the art. At least one of the PV window systems may be mounted on top of one channel of a plurality of channels each having a PV window system. The channel may further comprise at least one gas jet to cause a flow of particles away for the PV window system. The channel may comprise a zigzag channel of the disclosure. The reaction cell chamber may further comprise a solvent or transport agent of the disclosure to further clean the PV window system of particles that may adhere to at least one of the baffle and the window.

The vane-pump-type baffle or window may comprise a housing such that the rotation of the vane-pump-type baffle or window pumps the removed particles back into the reaction cell chamber. In an exemplary embodiment, the PV window system comprises a baffle comprising a vane-pump-type having transparent quartz or DLC-coated Pyrex vanes wherein the rotating shaft is along a horizontal axis, the window is in the horizontal plane, the vane spacing is such that a combination of contiguous vanes always cover the window during rotation, the rotation speed is sufficient to remove deposited particles, the baffle may be mounted in a channel with the window on top of the channel such as a zigzag channel, and housed in a housing that facilitates pumping of particles back into the reaction cell chamber.

In an embodiment, the spinning PV window or baffle comprises an applicator such as brushes to apply a thin film of non-wetting material to prevent particles form depositing on the PV window or baffle. In an exemplary embodiment, the applicator comprises at least one of boron nitride, graphite, and molybdenum disulfide brushes to continuously coat the PV window or baffle surface with the corresponding non-wetting thin film.

In an embodiment, the PV window such as the spinning disc may comprise a coating. The coating may comprise a material that reduces or prevent adherence of gallium or gallium oxide on the window. The coating may react with gallium oxide to prevent wetting by gallium wherein the window comprises a material that resists gallium wetting in absence of gallium oxide. An exemplary coating and window are NaOH and quartz, respectively. The coating may comprise at least one of water, acidic water, basic water, and an organic compound such as an alkane or alcohol such as isopropanol. The coating may be applied by an applicator. The application of the coating may be achieved by the spinning action of the window or baffle. The coating may comprise at least one component that may at least one of condense and absorb onto the window or baffle surface. A source of the at least one window or baffle surface coating component may comprise the reaction cell chamber 5b31 gas. In an embodiment, the reaction cell chamber comprises water and a gas comprising an acid anhydride. The window or baffle may be maintained at a temperature that allows water to condense on the surface and the acid anhydride to be absorbed in the water. In an embodiment, the acidic water prevents gallium from adhering to the surface of the PV window or baffle. The acid may react with a gallium oxide coat that is necessary for the gallium to adhere to the surface. The surface coating may be in thermodynamic or dynamic equilibrium with at least one species of the reaction cell chamber gases. The surface coating may comprise an aqueous acid such as H₂SO₃, H₂SO₄, H₂CO₃, HNO₂, HNO₃, HClO₄, H₃PO₃, and H₃PO₄ or a source of an acid such as an acid anhydride or anhydrous acid. The latter may comprise at least one of the group of I₂O₄, I₂O₅, I₂O₉, SO₂, SO₃, CO₂, N₂O, NO, NO₂, N₂O₃, N₂O₄, N₂O₅, Cl₂O, ClO₂, Cl₂O₃, Cl₂O₆, Cl₂O₇, PO₂, P₂O₃, and P₂O₅. The source of acid may comprise a gas such as NO₂, NO, N₂O, CO₂, P₂O₃, P₂O₅, and SO₂.

In another embodiment, the coating may comprise a base. The coating may comprise at least one component that may at least one of condense and absorb onto the window or baffle surface. A source of the at least one window or baffle surface coating component may comprise the reaction cell chamber 5b31 gas. In an embodiment, the reaction cell chamber comprises water and a gas comprising a base anhydride. The window or baffle may be maintained at a temperature that allows water to condense on the surface and the base anhydride to be absorbed in the water. In an embodiment, the basic water prevents gallium from adhering to the surface of the PV window or baffle. The base may react with a gallium oxide coat that is necessary for the gallium to adhere to the surface. The surface coating may be in thermodynamic or dynamic equilibrium with at least one species of the reaction cell chamber gases. The surface coating may comprise an aqueous base such as a base from a basic anhydride such as NH₃, M₂O (M=alkali), M′O (M′=alkaline earth), ZnO or other transition metal oxide, CdO, CoO, SnO, AgO, HgO, or Al₂O₃. Further exemplary anhydrides comprise metals that are stable to H₂O such as Cu, Ni, Pb, Sb, Bi, Co, Cd, Ge, Au, Ir, Fe, Hg, Mo, Os, Pd, Re, Rh, Ru, Se, Ag, Tc, Te, Tl, Sn, W, Al, V, Zr, Ti, Mn, Zn, Cr, and In. The anhydride may be an alkali metal or alkaline earth metal oxide, and the hydrated compound may comprise a hydroxide. In another embodiment, the coating may comprise an oxyhydroxide such as FeOOH, NiOOH, or CoOOH. The source of base may comprise a gas such as NH₃ corresponding to the base NH₄OH.

The reaction mixture may comprise at least one of a source of H₂O and H₂O. The acid, base, oxyhydroxide, or corresponding anhydride may be formed reversibly by hydration and dehydration reactions. The window or baffle may be maintained at a temperature that forms the acid or base wherein the reaction cell chamber temperature is above the acid or base decomposition temperature. A decomposition product may comprise the corresponding acid of base anhydride that may be recycled back to the window coating. In an exemplary embodiment wherein gallium nitrate (Ga(NO₃)₃) decomposes to delta gallium oxide (Ga₂O₃) and NₓO_{y} (x and y are integers) at a temperature above 250° C., the reaction cell chamber 5b31 is maintained above 250° C., and the window or baffle is maintained below 250° C.

In another embodiment, the coating comprises a solid compound that comprises at least one of an acid, acid anhydride, base, and a base anhydride. The coating may react with gallium oxide to prevent it from adhering to the window or baffle. The coating may react with water to be regenerated following reaction with gallium oxide. An exemplary acidic solid compound coating is a proton exchange membrane coating such as Nafion. The source of water to regenerate the coating is reaction cell chamber gas.

In an embodiment, the SunCell® comprises a source of at least one compound comprising nitrogen and oxygen such as NₓO_{y} (x and y are integers) such as NO or NO₂ and a source of H₂O. In an embodiment, the reaction mixture comprises NₓO_{y} and H₂O that may maintain a regenerative cycle between gallium oxides such as that of Ga₂O₃ and gallium nitrate. In an exemplary embodiment, NO₂ gas reacts with water to form nitric acid which reacts with gallium oxide to form water and gallium nitrate that decomposes to gallium oxide and NO₂. The regenerative cycle may at least one of (i) support the removal of gallium from the PV window or baffle by reducing the wetting of gallium by oxide removal and (ii) facilitate formation of nascent HOH that may serve as the catalyst to form hydrinos by reaction with atomic H.

In an embodiment, NOₓ (x=integer) chemistry facilitates at least one of removing gallium oxide-gallium particles from the PV window and accelerates the hydrino reaction rate by catalytically forming HOH catalyst for hydrinos. In an embodiment the SunCell® comprises a source of nitrogen such as N₂ gas and a means such as a gas line and flow controller to controllably supply the nitrogen to the hydrino reaction mixture in the reaction cell chamber 5b31. The hydrino reaction mixture may comprise at least one of molten gallium, gallium oxide, hydrogen, a noble gas such as argon, water vapor, oxygen and nitrogen. The reaction mixture may propagate a hydrino reaction that in turn maintains a plasma in the reaction cell chamber. The plasma and reaction cell mixture may form NOₓ (x=integer). In an exemplary chemistry embodiment, Ga₂O₃ may react with at least one of Ga and hydrogen to form Ga₂O that may act as a powerful reductant with hydrogen to form NH₃ that may further react with oxygen to form NO and NO₂ wherein the source of oxygen may be at least one of O₂ and H₂O. The reaction cell chamber may further comprise a nitrogen chemistry catalyst such as a noble metal such as Pt to facilitate the formation of at least one of NH₃, NO, and NO₂. The nitrogen chemistry catalyst may be protected from molten gallium while being exposed to gases of the reaction mixture to avoid alloying with gallium. In an embodiment, nitrogen of the reaction cell mixture may react with gallium to form gallium nitride which may react with water to form a product such as Ga₂O₃ that can be regenerated to Ga. In an embodiment, the GaN may serve as a photocatalyst using the hydrino plasma light. The photocatalyst reaction may serve to form at least one hydrino reaction reactant such as atomic H and HOH catalyst. A tungsten SunCell® component such as an electrode may react with at least one of oxygen and water to form WO₃ that may serve as the photocatalyst. The reaction cell chamber may further comprise a species added to the reaction mixture that comprises a photocatalyst.

In an embodiment, a hydroxide such as NaOH or KOH that reacts with gallium oxide is crystalized to form a coating on the surface of the PV window or baffle. The crystal may be transparent. The reaction product of gallium oxide and the hydroxide may comprise the metal of the hydroxide and gallate ion (GaO₂⁻) such as sodium gallate (NaGaO₂) or potassium gallate (KGaO₂). An exemplary reaction between NaOH and Ga₂O₃ is

Ga₂O₃+2NaOH to 2NaGaO₂+H₂O

In an embodiment comprising a reaction cell chamber atmosphere that comprises water vapor, the water vapor pressure may be maintained low such as a water vapor pressure in the range of at least one of about 0.01 Torr to 50 Torr, 0.01 Torr to 10 Torr, 0.01 Torr to 5 Torr, and 0.01 Torr to 1 Torr. The reaction of the hydroxide with the gallium oxide may form water as a product. In an embodiment, the hydroxide coating on the PV window may be maintained at an elevated temperature to maintain a desired amount of absorbed or retained water. In an exemplary embodiment, the PV window is maintained at an elevated temperature that prevents water absorption or retention while being below the hydroxide melting point such as that of NaOH (M.P=318° C.) or KOH (M.P.=360° C.). In an embodiment, as routine maintenance, the PV window may be replaced or recoated with hydroxide when the hydroxide has been substantially consumed. In an embodiment, at least one other component of the PV window such as the spinning window, the zigzag channel, and the baffle may be coated with a reactant with gallium oxide such as a base such as NaOH. In an embodiment, the coating such as an NaOH coating may comprise a replaceable plate such as one comprising base such as NaOH embedded in or impregnating a structural support such as a matrix that may be transparent such as agar or other such polymer, a zeolite, a glass frit, and other transparent supports and matrices known in the art. The plate may be replaced during routine maintenance. In an embodiment, the reactant with gallium oxide such as a base such as NaOH may be at least one of solid, liquid or molten, or aqueous wherein the reactant such as NaOH may be absorbed or otherwise bound to the support or matrix to maintain the form of the plate. In an exemplary embodiment, the plate comprises a OH⁻ conductor membrane such as Neosepta® AHA membrane wherein the membrane may be treated with base such as 1 M KOH or NaOH solution to allow substitution of hydroxide ions (OH⁻) for chloride ions (Cl⁻).

In an embodiment, the SunCell® comprises a PV window or baffle electrolysis system comprising a cathode, an anode, a transparent window, and a transparent electrolyte. The electrolyte may comprise a conductor of one of the following ions derived from H₂O or H₂ that may be supplied to the PV window electrolysis cell: H⁺, OH⁻, and H⁻. The electrodes may be separated by the PV window, or both may be on the front face of the PV window comprising the face directed toward the reaction cell chamber. In an embodiment, the electrolyte may comprise a hydride ion conductor such as a molten salt such as a eutectic salt mixture, and the electrolyte may further comprise a hydride. The salt may comprise one or more halides such as the mixture LiCl/KCl that may further comprise a hydride such as LiH. In addition to halides, other suitable molten salt electrolytes that may conduct hydride ions comprise a hydride dissolved in a hydroxide such as KH in KOH, NaH in NaOH, or such a metalorganic systems such as NaH in NaAl(Et)₄. The electrolyte may comprise a eutectic salt of two or more halides such as at least two compounds of the group of the alkali halides and alkaline earth halides. Exemplary salt mixtures include LiF—MgF₂, NaF—MgF₂, KF—MgF₂, and NaF—CaF₂. Other suitable electrolytes are organic chloro aluminate molten salts and systems based on metal borohydrides and metal aluminum hydrides. Additional suitable electrolytes that may be molten mixtures such as molten eutectic mixtures are given in TABLE 1.

TABLE 1
Molten Salt Electrolytes.

| | | | | |
|---|---|---|---|---|
| AlCl3—CaCl2 | AlCl3—CoCl2 | AlCl3—FeCl2 | AlCl3—KCl | AlCl3—LiCl |
| AlCl3—MgCl2 | AlCl3—MnCl2 | AlCl3—NaCl | AlCl3—NiCl2 | AlCl3—ZnCl2 |
| BaCl2—CaCl2 | BaCl2—CsCl | BaCl2—KCl | BaCl2—LiCl | BaCl2—MgCl2 |
| BaCl2—NaCl | BaCl2—RbCl | BaCl2—SrCl2 | CaCl2—CaF2 | CaCl2—CaO |
| CaCl2—CoCl2 | CaCl2—CsCl | CaCl2—FeCl2 | CaCl2—FeCl3 | CaCl2—KCl |
| CaCl2—LiCl | CaCl2—MgCl2 | CaCl2—MgF2 | CaCl2—MnCl2 | CaCl2—NaAlCl4 |
| CaCl2—NaCl | CaCl2—NiCl2 | CaCl2—PbCl2 | CaCl2—RbCl | CaCl2—SrCl2 |
| CaCl2—ZnCl2 | CaF2—KCaCl3 | CaF2—KF | CaF2—LiF | CaF2—MgF2 |
| CaF2—NaF | CeCl3—CsCl | CeCl3—KCl | CeCl3—LiCl | CeCl3—NaCl |
| CeCl3—RbCl | CoCl2—FeCl2 | CoCl2—FeCl3 | CoCl2—KCl | CoCl2—LiCl |
| CoCl2—MgCl2 | CoCl2—MnCl2 | CoCl2—NaCl | CoCl2—NiCl2 | CsBr—CsCl |
| CsBr—CsF | CsBr—CsI | CsBr—CsNO3 | CsBr—KBr | CsBr—LiBr |
| CsBr—NaBr | CsBr—RbBr | CsCl—CsF | CsCl—CsI | CsCl—CsNO3 |
| CsCl—KCl | CsCl—LaCl3 | CsCl—LiCl | CsCl—MgCl2 | CsCl—NaCl |
| CsCl—RbCl | CsCl—SrCl2 | CsF—CsI | CsF—CsNO3 | CsF—KF |
| CsF—LiF | CsF—NaF | CsF—RbF | CsI—KI | CsI—LiI |
| CsI—NaI | CsI—RbI | CsNO3—CsOH | CsNO3—KNO3 | CsNO3—LiNO3 |
| CsNO3—NaNO3 | CsNO3—RbNO3 | CsOH—KOH | CsOH—LiOH | CsOH—NaOH |
| CsOH—RbOH | FeCl2—FeCl3 | FeCl2—KCl | FeCl2—LiCl | FeCl2—MgCl2 |
| FeCl2—MnCl2 | FeCl2—NaCl | FeCl2—NiCl2 | FeCl3—LiCl | FeCl3—MgCl2 |
| FeCl3—MnCl2 | FeCl3—NiCl2 | K2CO3—K2SO4 | K2CO3—KF | K2CO3—KNO3 |
| K2CO3—KOH | K2CO3—Li2CO3 | K2CO3—Na2CO3 | K2SO4—Li2SO4 | K2SO4—Na2SO4 |
| KAlCl4—NaAlCl4 | KAlCl4—NaCl | KBr—KCl | KBr—KF | KBr—KI |
| KBr—KNO3 | KBr—KOH | KBr—LiBr | KBr—NaBr | KBr—RbBr |
| KCl—K2CO3 | KCl—K2SO4 | KCl—KF | KCl—KI | KCl—KNO3 |
| KCl—KOH | KCl—LiCl | KCl—LiF | KCl—MgCl2 | KCl—MnCl2 |
| KCl—NaAlCl4 | KCl—NaCl | KCl—NiCl2 | KCl—PbCl2 | KCl—RbCl |
| KCl—SrCl2 | KCl—ZnCl2 | KF—K2SO4 | KF—KI | KF—KNO3 |
| KF—KOH | KF—LiF | KF—MgF2 | KF—NaF | KF—RbF |
| KFeCl3—NaCl | KI—KNO3 | KI—KOH | KI—LiI | KI—NaI |
| KI—RbI | KMgCl3—LiCl | KMgCl3—NaCl | KMnCl3—NaCl | KNO3—K2SO4 |
| KNO3—KOH | KNO3—LiNO3 | KNO3—NaNO3 | KNO3—RbNO3 | KOH—K2SO4 |
| KOH—LiOH | KOH—NaOH | KOH—RbOH | LaCl3—KCl | LaCl3—LiCl |
| LaCl3—NaCl | LaCl3—RbCl | Li2CO3—Li2SO4 | Li2CO3—LiF | Li2CO3—LiNO3 |
| Li2CO3—LiOH | Li2CO3—Na2CO3 | Li2SO4—Na2SO4 | LiAlCl4—NaAlCl4 | LiBr—LiCl |
| LiBr—LiF | LiBr—LiI | LiBr—LiNO3 | LiBr—LiOH | LiBr—NaBr |
| LiBr—RbBr | LiCl—Li2CO3 | LiCl—Li2SO4 | LiCl—LiF | LiCl—LiI |
| LiCl—LiNO3 | LiCl—LiOH | LiCl—MgCl2 | LiCl—MnCl2 | LiCl—NaCl |
| LiCl—NiCl2 | LiCl—RbCl | LiCl—SrCl2 | LiF—Li2SO4 | LiF—LiI |
| LiF—LiNO3 | LiF—LiOH | LiF—MgF2 | LiF—NaCl | LiF—NaF |
| LiF—RbF | LiI—LiOH | LiI—Nal | LiI—RbI | LiNO3—Li2SO4 |
| LiNO3—LiOH | LiNO3—NaNO3 | LiNO3—RbNO3 | LiOH—Li2SO4 | LiOH—NaOH |
| LiOH—RbOH | MgCl2—MgF2 | MgCl2—MgO | MgCl2—MnCl2 | MgCl2—NaCl |
| MgCl2—NiCl2 | MgCl2—RbCl | MgCl2—SrCl2 | MgCl2—ZnCl2 | MgF2—MgO |
| MgF2—NaF | MnCl2—NaCl | MnCl2—NiCl2 | Na2CO3—Na2SO4 | Na2CO3—NaF |
| Na2CO3—NaNO3 | Na2CO3—NaOH | NaBr—NaCl | NaBr—NaF | NaBr—NaI |
| NaBr—NaNO3 | NaBr—NaOH | NaBr—RbBr | NaCl—Na2CO3 | NaCl—Na2SO4 |
| NaCl—NaF | NaCl—NaI | NaCl—NaNO3 | NaCl—NaOH | NaCl—NiCl2 |
| NaCl—PbCl2 | NaCl—RbCl | NaCl—SrCl2 | NaCl—ZnCl2 | NaF—Na2SO4 |
| NaF—NaI | NaF—NaNO3 | NaF—NaOH | NaF—RbF | NaI—NaNO3 |
| NaI—NaOH | NaI—RbI | NaNO3—Na2SO4 | NaNO3—NaOH | NaNO3—RbNO3 |
| NaOH—Na2SO4 | NaOH—RbOH | RbBr—RbCl | RbBr—RbF | RbBr—RbI |
| RbBr—RbNO3 | RbCl—RbF | RbCl—RbI | RbCl—RbOH | RbCl—SrCl2 |
| RbF—RbI | RbNO3—RbOH | CaCl2—CaH2 | | |

The molten salt electrolyte such as the exemplary salt mixtures given in TABLE 1 are H⁻ ion conductors. In embodiments, it is implicit in the disclosure that a source of H⁻ such as an alkali hydride such as LiH, NaH, or KH may be added to the molten salt electrolyte to improve the H⁻ ion conductivity.

In an embodiment, H⁻ is a migrating ion of the electrolyte. H⁻ may form at the cathode and migrate to the anode. The electrolyte may be a hydride ion conductor such as a molten salt such as a eutectic mixture such as a mixture of alkali halides such as LiCl—KCl. The cathode may be a hydrogen permeable membrane such as Ni (H₂). The anode may oxidize gallium oxide and H⁻ to gallium and H₂O whereby the gallium wetting of the PV window is eliminated with the consumption of wetting agent gallium oxide. In an embodiment, the PV electrolysis cell may comprise a molten hydroxide-halide electrolyte that is an H⁻ conductor, a source of H to form hydride ions such as a hydrogen permeable cathode such as Ni(H₂), and an anode that selectively oxidizes at gallium oxide and hydride ion to gallium and H₂O. The reactions may be

6H⁻+Ga₂O₃ to 2Ga+3H₂O+6e⁻ Anode:

3H₂+6e⁻to 6H⁻ Cathode:

Exemplary cells are [Pt/MOH-M′X/M″(H₂)] wherein the cathode M″ may comprise a hydrogen permeable metal such as Ni, Ti, V, Nb, Pt, and PtAg, the electrolyte comprises a mixture of a hydroxide and a halide such as MOH-M′X (M, M′=alkali; X=halide) and other noble metals and supports may substitute for the Pt anode. The electrolyte may further comprise at least one other salt such as an alkali metal hydride. In an alternative embodiment, the electrolyte may comprise a hydride ion conducting solid-electrolyte such as CaCl₂—CaH₂. Exemplary hydride ion-conducting solid electrolytes are CaCl₂—CaH₂ (5 to 7.5 mol %) and CaCl₂—LiCl—CaH₂.

In an alternative embodiment, the SunCell@ window or baffle comprises an electrolysis system comprising at least two electrodes, a power source, and a controller for the reduction of gallium oxide to prevent the gallium oxide from causing gallium to adhere to the window or baffle. The window or baffle may comprise grid electrodes or a patterned transparent electrically conductive thin film such as one comprising indium-tin-oxide. At least one electrode may comprise a mesh or screen. In an embodiment, the electrolyte may comprise at least one of an acid and a base. In an exemplary embodiment, the electrolyte may comprise a hydroxide such as NaOH. In another embodiment, the electrolyte may comprise a solid such as beta alumina that may comprise at least one of a thin film and transparency. The electrolysis voltage may be in at least one range of about 0.1 V to 50 V, 0.25 V to 5 V, and 0.5 V to 2 V.

The window or baffle may comprise an electrolysis system comprising a negative and positive electrode separated by an electrolyte and powered by a source of electrical power wherein gallium that adheres to the surface of the window or baffle contacts the negative electrode on the window, and current is carried through the electrolyte to the separated positive electrode to reduce gallium oxide of the adhering gallium. In an embodiment of the window or baffle electrolysis system to reduce gallium oxide to prevent adherence of gallium to the surface of the window or baffle, the window or baffle may comprise a back electrolysis electrode or a composite of electrodes such as an anode or a composite of anodes on the back surface of the window or baffle, the side way from the plasma. To minimize the shadowing effect, the back electrolysis electrode may be at least one of (i) located circumferentially to the window or baffle, (ii) comprise grid wires, and (iii) comprise a transparent conductor such as indium-tin-oxide. The electrolyte may comprise a transparent layer or film on the back surface of the window or baffle. The electrolyte may be transparent and comprise at least one of a base such as MOH (M=alkali) such as NaOH or KOH or water and ammonia wherein gaseous ammonia is equilibrium with solvated ammonia, and the ammonia gas may be contained in a transparent chamber housing the anode. The front surface may comprise a front electrolysis electrode or a composite of electrodes such as a cathode or a composite of cathodes comprising electrical connections such as grid wires or electrodes or a conductive layer or film on at least a portion of the front surface. The film may be a transparent conductor such as indium-tin-oxide that may cover the surface or be in the form of grid leads or electrodes of the composite. The electrodes may comprise a transparent conductor such as surface coatings of graphene, indium tin oxide (ITO), indium-doped cadmium oxide (ICdO), aluminum-doped zinc oxide (AZO), gallium-doped zinc oxide (GZO), indium-doped zinc oxide (IZO), indium tungsten oxide (IWO), ITO, ICdO, AZO, GZO, IZO, or IWO coated with tungsten oxide, or another transparent conductor known to those skilled in the art. In the case that the coating is electrochromic, a current may be applied to remove the gallium by reduction of its oxide coat, and the colorless PV coating may be regenerated by reversing the current for an intermittent regeneration period. In another embodiment, the electrolysis electrode or a composite of electrodes that contacts the gallium may comprise a material that resists forming an alloy with gallium such as stainless steel (SS), tungsten (W), or tantalum (TA). The electrodes may be resistant to gallium wetting such as SS, Ta, or W. The electrodes may be stable to reaction with the electrolyte such as a noble metal such as Pt, Ir, Rh, Re, Pd, or Au in case of an acidic electrolyte such as Nafion. The electrolysis electrode or a composite of electrodes that contacts the basic electrolyte may comprise a material that resists corrosion with base such as copper, stainless steel, nickel, a noble metal, or carbon. The electrode may comprise elements such as wires that may comprise a grid, mesh, or screen. The elements such as wires may be shaped to minimize shadowing of the light transmitted through the PV window to the PV converter. An exemplary shape is pyramidal with the apex towards the light source wherein the light may be reflected to another non-shadowed region of the PV window or baffle. The window or baffle may comprise non-conductive fasteners such as ceramic or plastic bolts to attach at least one electrode. The window of baffle may comprise at least one penetration such as a plurality of small diameter penetrations over at least a portion of the window or baffle to serve as a plurality of conduits for the electrical contact of the electrolyte between the anode and cathode.

In another embodiment, the electrolysis system components in order from the direction of the plasma may be the anode, the electrolyte, and the cathode wherein the anode and cathode are spatially separated, the anode may be circumferential to the window or baffle, and the electrolyte may be adhered to the surface of the window or baffle. The electrolyte may comprise a base such as MOH (M=alkali) such as NaOH or KOH. The window or baffle may comprise a rough surface that may assist in bonding of the electrolyte to the surface. The window or baffle may comprise a hydroscopic coating to bind the electrolyte. The electrolyte may have a low water vapor pressure. The electrolyte may comprise at least one of a high concentration of base and at least one compound such as a hydroscopic compound to reduce the water vapor pressure. The electrolyte may comprise a slurry or paste such as one of NaOH or KOH. The electrolyte may comprise a binding compound such as a polymer or a ceramic oxide such as MgO or a salt doped matrix such as agar or a polymer such as polyethylene oxide.

The electrolyte may comprise a solid electrolyte. The electrolyte may comprise an ion conductor suitable for the desired anode oxidation and cathode reduction chemistries that remove the particles adhered to the PV window. Exemplary solid electrolyte are Na⁺ conductor beta-alumina solid electrolyte (BASE), Na⁺ or OH⁻ conductor sodium gallate, K⁺ or OH⁻ conductor potassium gallate, oxide ion conductor yttria-stabilized zirconia, sodium ion conductor NASICON (Na₃Zr₂Si₂PO₁₂), H⁺ conductor Nafion wherein the oxidation and reduction reactions are matched to the electrolyte. The solid electrolyte may comprise the OH⁻ conductor, a layered double hydroxide (LDH). In an embodiment, LDHs comprise anionic clay and the general formula for LDHs is [M^{II}₁₋ₓ M^{III}ₓ(OH)₂][(Aⁿ⁻)_{x/n}.mH₂O], where M^{II} is a divalent cation such as Ni²⁺, Mg²⁺, Zn²⁺, etc., and M^{III} is a trivalent cation such as Al³⁺, Fe³⁺, Cr³⁺, etc., and Aⁿ⁻ is an anion such as CO₃²⁻, Cl⁻, OH⁻, etc. Exemplary solid electrolytes that are OH— conductors are layered double hydroxides (LDH) such as KOH—Al—Mg layered double hydroxide Mg₆Al₂CO₃(OH)₁₆, ion exchange membranes such as Neosepta® AHA membrane wherein the membrane may be treated with base such as 1 M KOH solution to allow substitution of hydroxide ions (OH—) for chloride ions (Cl—), and nanoparticles composed of SiO₂/densely quaternary ammonium-functionalized polystyrene embedded in a polysulfone matrix such as (20-70 wt %), and tetraethylammonium hydroxide (TEAOH) poly acrylamide (PAM). In an embodiment wherein the molten metal may comprise silver or an alloy such as gallium-silver, the electrolyte may comprise an advanced superionic conductor for silver ion such as at least one of RbAg₄I₅, KAg₄I₅, NH₄Ag₄I₅, K₁₋ₓCsₓAg₄I₅, Rb₁₋ₓCsₓAg₄I₅, CsAg₄Br₁₋ₓI₂₊ₓ, CsAg₄ClBr₂I₂, CsAg₄Cl₃I₂, RbCu₄Cl₃I₂, KCu₄I₅, and silver sulfide.

In an embodiment, the electrolyte such as an alkali halide such as NaF may have about a neutral pH. The about neutral pH electrolyte may avoid the dissolution of the gallium oxide coat on the gallium adhered to the window.

In an embodiment, the PV window electrolyte such as NaOH is replenished, and electrolyte lost to the reaction mixture may be recovered during recycling of the gallium by means such as electrolysis.

An exemplary electrolysis system to reduce gallium oxide to prevent gallium wetting comprises (i) an annular SS anode on the back side of the window; (ii) NaOH slurry electrolyte on the back of the window; (iii) a window with many small channels for the electrolyte, and (iv) a SS mesh or screen cathode on the front surface of the window that contacts that gallium and reduces it. In an embodiment wherein (i) the gallium does not adhere to a metal with an oxide coat such as stainless steel, tantalum, or tungsten, (ii) the metal comprising the oxide coat comprises the cathode, and (iii) the metal oxide coat is reduced during operation, the polarity of the electrolysis cell may be reversed periodically to regenerate the oxide coat on the metal of the cathode.

In an embodiment, the front electrode may comprise the anode, and the cathode may be at least one of circumferential on the front or be on the back of the PV window. In the latter case, the PV window may comprise perforations for the electrolyte. The application of a positive potential on the front anode in contact with gallium adhered to the PV window and the application of a negative potential on the cathode may cause the gallium to migrate to the cathode where the collected gallium may be removed and recycled. The SunCell® may comprise a removal means, a transport means that may further comprise corresponding channels, and a recycle means for the collected gallium. Exemplary removal means are a mechanical means such as by a scrapper, a gas jet, a pump, and other removal means of the disclosure. The gallium may be removed and transported to at least one of the reaction cell chamber, the reservoir, and the gallium regeneration system of the disclosure using the transport means and corresponding channels.

In an embodiment, the window or baffle comprises a plasma discharge system to maintain a plasma at the surface of the window or baffle. The plasma discharge system may comprise electrode grid wires, mesh or screen on or in close proximity to the window or baffle surface, a counter electrode, and a discharge power source such as a glow discharge source. In other embodiments, the plasma source comprises other known plasma sources such as microwave, inductively or capacitively coupled RF discharge, dielectric barrier discharge, piezoelectric direct discharge, and acoustic discharge cell plasma sources. The plasma system may be configured so that the corresponding plasma reduces gallium oxide to cause adhering gallium particles to be removed from the window or baffle surface. Alternatively, the plasma may form atomic hydrogen from a source of hydrogen wherein the atomic hydrogen reduces gallium oxide to gallium to cause it to be non-wetting. In another embodiment, the window or baffle comprises a source of magnetic field such as a permanent magnet or an electromagnet that directs plasma maintained by the hydrino reaction in proximity of the surface of the window or baffle. The plasma may form atomic hydrogen from a source of hydrogen wherein the atomic hydrogen reduces gallium oxide to gallium to cause it to be non-wetting. In an embodiment, the window or baffle comprises a hydrogen dissociator such one of the disclosure such as a hot filament or a metallic dissociator such as rhenium, tantalum, niobium, titanium, or another of the disclosure. The reaction chamber gas such a reaction mixture comprising hydrogen such as an argon-hydrogen-trace H₂O gas mixture may reduce the oxide coat on gallium particles and at least one of prevent gallium from adhering to the PV window and removing the particles from the PV window. The window or baffle may comprise a gas jet that flows hydrogen over the filament to further cause atomic hydrogen to flow onto the PV window.

In an embodiment, the baffle or PV window further comprises a dissociator chamber that houses a hydrogen dissociator such as Pt, Pd, Ir, Re, or other dissociator metal on a support such as carbon, or ceramic beads such as Al₂O₃, silica, or zeolite beads, Raney Ni, or Ni, niobium, titanium, or other dissociator metal of the disclosure in a form to provide a high surface area such as powder, mat, weave, or cloth. The dissociator chamber may be connected to the reaction cell chamber at the location of the baffle or PV window by a gallium blocking channel such as the zigzag channel of the disclosure that inhibits the flow of gallium from the reaction cell chamber to the dissociator chamber while permitting gas exchange. Hydrogen gas may flow from the reaction cell chamber into the dissociation chamber wherein hydrogen molecules are dissociated to atoms, and the atomic hydrogen may flow back into the reaction cell chamber to serve as a reactant to reduce gallium oxide on the PV window. In other embodiments, the dissociation chamber may house the plasma dissociator or filament dissociator of the disclosure. In an embodiment, a gas jet that flows hydrogen over the dissociator such that the resulting H atoms flow to impinge the surface of the baffle or PV window.

The PV window may comprise at least one piezoelectric transformer (PT) and optionally at least one adjacent electrode such as at least one wire electrode wherein the inherent electromechanical resonance of the PT is used to produce voltage amplification, such that the surface of the piezoelectric exhibits a large surface voltage that can generate corona-like discharges on its corners or on adjacent electrodes. An exemplary voltage amplification is less than 7 V to kV's. The configuration of the so-called piezoelectric direct discharge may be used to generate a bulk airflow called an ionic wind as reported by Johnson end Go [M. Johnson, D. B. Go, “Piezoelectric transformers for low-voltage generation of gas discharges and ionic winds in atmospheric air”, Journal of Applied Physics, Vol. 118, December, (2015), pp. 243304-1-243304-10, doi: 10.1063/1.493849]. In an embodiment, the piezoelectric direct discharge comprises an electrode configuration to produce an ion wind that either removes or reduces the adherence of gallium particles to the PV window. In an embodiment, the gas jet to at least one of prevent gallium particles from adhering the PV window and clean adhering gallium particles from the PV window may comprise the recirculator such as one comprising a blower and at least one gas nozzle. The at least one of the scrubbed, recirculated noble gas and the makeup hydrogen comprising hydrogen that is added to the scrubbed, recirculated noble gas and injected into the reaction cell chamber may be directed to a region in the reaction cell chamber that causes the gas flow to at least one of force gallium particles away from the PV window and provide atomic hydrogen to reduce any oxide coat on the gallium particles to at least one of prevent the particles from adhering and cause the particles to be removed from the PV window. In the latter case, at least one of the recirculated noble gas and makeup hydrogen may be made to impinge on the PV window wherein the gas comprising hydrogen may be caused to flow over the hydrogen dissociator such as a dissociator metal, plasma source, or hot filament. In an embodiment, at least one of the reaction cell chamber gas, the recirculated gas, and the makeup gas that replaces depleted reactants may comprise the ionic wind generated by the piezoelectric transformer that may comprise at least one adjacent wire electrode. In an embodiment, the PV window may comprise at least one transparent piezoelectric crystal such as quartz, gallium phosphate, lead zirconate titanate (PZT), crystalline boron silicate such as tourmaline, or another known in the art. At least one electrode of the piezoelectric transducer may comprise a transparent conductor such as indium tin oxide (ITO) or another of the disclosure. In another embodiment, the piezoelectric transducer and corresponding piezoelectric direct discharge may be replaced by a barrier electrode discharge system and barrier electrode discharge to prevent adherence or facilitate removal of gallium oxide particles from the PV window.

In another embodiment, the spinning baffle or spinning window comprises a device to physically remove particles that have deposited on the baffle or window during SunCell® operation. The device may comprise a surface mounted abrasion device such as a brush or blade such as a sharp-edged blade that rides on the surface of the baffle or window. The surface of the baffle or window may be polished, and the blade may comprise a precision edge to provide optimized contact between the edge and surface. The blade may have a length equal to the radius of the baffle or window such that the corresponding surface is scraped during each revolution of the baffle or window. The blade may comprise a controllable device for applying adjustable pressure on the blade towards the surface such as a mechanical, hydraulic, pneumatic, or electromagnetic pressure applying device. An exemplary mechanical pressure applying device comprises a spring.

In an embodiment, at least one of the baffle and PV window comprises at least one molten metal injector to pump molten metal onto the at least one of the baffle and PV window to serve as a solvent to remove deposited particles such as the oxide of the metal. In an embodiment, the at least one of the baffle and PV window comprises a material or surface that resists wetting by the molten metal. In an exemplary embodiment, the molten metal comprises gallium, the metal oxide comprises gallium oxide, the material or surface comprises at least one of quartz, BN, carbon, or another material or surface that resists wetting by gallium, and the molten metal injector comprises at least one EM pump and at least one jet nozzle to inject molten gallium from a source such as at least one of the reservoir 5c and the reaction cell chamber 5b31 onto the surface of the at least one of the baffle and PV window to serve a as solvent of gallium oxide to remove it from the surface of the at least one of the baffle and PV window. In another exemplary embodiment, the molten metal comprises silver, the baffle or PV window comprises a transparent material with a high melting point such as quartz, sapphire, or an alkaline earth halide crystal such as MgF₂, and the molten metal injector comprises at least one EM pump and at least one jet nozzle to inject molten silver from a source such as at least one of the reservoir 5c and the reaction cell chamber 5b31 onto the surface of the at least one of the baffle and PV window to serve to remove silver particles such as silver nanoparticles from the surface of the at least one of the baffle and PV window. The baffle or PV window may further comprise a transparent sacrificial layer to protect the baffle or window from pitting by melting caused by hot silver particles.

In an embodiment, the at least one of the baffle and PV window may further comprise at least one means such as a wiper to remove the gallium with the oxide. The wiper may comprise at least one wiper blade and a means to move the wiper blade over the surface of the at least one of the baffle and PV window. The means to move the blade may comprise at least one of a mechanical, pneumatic, hydraulic, electromagnetic, or other such movement means known in the art. Alternatively, at least one of the baffle and PV window may comprise a spinning baffle or PV window and a fixed wiper blade.

In an exemplary embodiment, a plurality of injector jets such as an array inject molten gallium onto the surface of the at least one of the spinning baffle and spinning PV with sufficient velocity and flow to dislodge gallium oxide particles that may adhere to the surface of the at least one of the baffle and PV window, and the blade may remove the injected gallium and oxide from the at least one of the baffle and PV window as it spins. In another embodiment, the gallium and gallium oxide are removed by the centrifugal force of the spinning at least one of the baffle and PV window alone.

In another exemplary embodiment, the window or baffle comprises an array of high-pressure jets such as ones supplied at least one mechanical or EM pump to remove gallium oxide from a surface not wetted by gallium such as a quartz surface or a transparent surface coated with a base such as NaOH or KOH. The array of molten metal jets may inject high-velocity molten gallium onto a spinning window to clean off deposited particles such as ones comprising gallium with gallium oxide. The high-velocity gallium may act as a liquid cleaner to remove the gallium oxide. Since gallium oxide causes gallium wetting of surfaces, its removal eliminates the wetting by gallium that may bead-up and be removed by the centrifugal force of the spinning window.

In an embodiment, the molten metal comprises an abrasive additive such as small hard particles that are injected with the molten metal to assist in dislodging adhere material for the surface of the at least one of the baffle and PV window. The additive may comprise abrasive particle such as small ceramic particles such as one comprising alumina, zirconia, ceria, of thoria. The particle size may be below the size that clogs the pump of the baffle or PV window injectors or the ignition injection pump.

In an embodiment, magnetic particles such as magnetic nanoparticles may be added to the molten metal such as gallium to form a ferrofluid. The nanoparticles may be ferromagnetic such as at least one of Fe, Fe₂O₃, Co, Ni, CoSm, and AlNiCo nanoparticles, and other ferromagnetic nanoparticles know in the art. An exemplary ferrofluid comprises gallium or gallium alloy as a solvent or suspension medium for magnetic nanoparticles such as gadolinium nanoparticles as given by Castro et al. [I. A. de Castro et al., “A gallium-based magnetocaloric liquid metal ferrofluid”, Nano Lett., (2017), Vol. 17, No. 12, pp. 7831-7838] which is herein incorporated by reference in its entirety. The magnetic nanoparticles may be coated with a coating to prevent corrosion by the reaction cell chamber gases or alloy formation with gallium. The coating may comprise a ceramic such as silica, alumina, zirconia, hafnia, or another of the disclosure. At least one of the baffle and PV window may comprise a source of magnetic field gradient to prevent the molten metal from coating the at least one of the baffle and PV window. The at least one of the baffle and PV window may be maintained in a temperature range below the Curie temperature of the magnetic nanoparticles. The source of magnetic field gradient may be at least one of permanent and electromagnets. In an exemplary embodiment, the at least one of the baffle and PV window may comprise a Helmholtz coil electromagnet such as a superconducting coil circumferential to the reaction cell chamber before the at least one of the baffle and PV window to provide a magnet gradient from the at least one of the baffle and PV window towards he coil. In an embodiment, the at least one of the baffle and PV window may comprise a series of coils such as those of an induction electromagnetic pump wherein the coils produce a traveling force of the magnetic molten metal to cause it to be pumped from the surface of the at least one of the baffle and PV window. In an embodiment, injection pump may comprise at least one of a mechanical pump and a linear induction type wherein a traveling magnetic field gradient created by at least one of a plurality of synchronized activated electromagnets or moving permanent magnets create the force to pump the molten metal. The synchronization may be of the type used in electric motors and known in the art. Since magnetic fields penetrate metals such as stainless steel, the EM pump tube may comprise such metals in addition to the ceramics of the induction EM pump of the disclosure.

The PV window may be resistant to being wetted by the molten metal such as gallium. The window may be resistant to adhesion of compounds present in the reaction cell chamber such as metal oxides such as gallium oxide in the case that gallium is the molten metal. The PV window may comprise a transparent coating. In an exemplary embodiment at least one of the PV window and PV coating comprise quartz, diamond, gallium nitride (GaN), gallium phosphate (GaPO₄), cubic zirconium, sapphire, an alkali or alkaline earth halide such as MgF₂, graphene, transparent lithium intercalated multilayer graphene, a thin layer of carbon such as graphite, Teflon or other non-wetting fluoropolymer, polyethylene, polypropylene or other non-wetting transparent polymer, a thin layer of boron nitride, either hexagonal or cubic BN, transparent hexagonal boron nitride, transparent silicon nitride such as cubic silicon nitride, a thin-film transparent non-wetting metal coat such as W, Ta, or a thin-film metal oxide or transparent non-wetting metal oxide such as tantalum pentoxide (Ta₂O₅), indium tin oxide that may be further coated or doped with tungsten oxide, or indium tungsten oxide that may be further coated or doped with tungsten oxide. The PV window may comprise a graphite mesh with perforations for light or a carbon fiber grid or screen that has a close-packed weave that resists adhesion of the molten metal while permitting light penetration. The PV window may comprise a diamond like carbon (DLC) or diamond coating. A structure material such as a transparent structural material such as quartz, Pyrex, sapphire, zirconia, hafnia, or gallium phosphate, may support the DLC or diamond coating. The PV window may comprise self-cleaning glass such as TiO₂ coated or wax or other hydrophobic surface coated glass. The PV window may comprise gallium nitride (GaN) entirely or as a coating. GaN may be deposited as a thin film of GaN via metal-organic vapor phase epitaxy (MOVPE) on sapphire, zinc oxide, and silicon carbide (SiC).

In an embodiment, the PV window comprises a transparent material such as quartz, fused silica, sapphire, or MgF₂ that is capable of being operated at elevated temperature and a means such as at least one of thermal insulation and a heater to maintain the PV window at a high temperature at which gallium-oxide coated gallium does not adhere. An exemplary temperature range is one of about 300° C. to 2000° C.

In an embodiment, at least one of the PV window and baffle may be coated with Ga₂O₃. At least one of the PV window and baffle may comprise Ga₂O₃ such as transparent beta-Ga₂O₃. At least one of the PV window and baffle may comprise a transparent beta-Ga₂O₃ pane that may be flat, domed, or in another desired geometrical form. In another embodiment, the PV window and baffle may each be operated under conditions which avoid the formation of a composition or phase of gallium oxide that results in wetting by gallium. In an embodiment, a surface coating of Ga₂O is avoided. In an embodiment, the window is operated under condition that cause the decomposition of Ga₂O. The window and baffle may each be operated at a temperature above the decomposition temperature of Ga₂O such as above 500° C.

In an embodiment, at least one of the PV window and baffle may be coated with a thin transparent layer of a metal that does it react with gallium. Exemplary coatings may comprise at least one of tungsten and tantalum. In an embodiment, the metal surface may be textured by methods such as sputtering to control non-wetting of the surface. In an embodiment, the metal comprises a metal oxide coat to avoid wetting by gallium.

The PV window may be cooled by at least one of direct cooling and indirect cooling. Indirect cooling may comprise secondary cooling by heat transfer to the PV cell array cooling system such as a water-cooled heat exchanger. The heat exchanger may comprise at least one multichannel plate. The PV window temperature may be controlled by the cooling to one range below the failure temperature of the window such as a temperature below the failure temperature of at least one of the structural material of the window and the coating if present. The temperature may be maintained in at least one range of about 50° C. to 1500° C., 100° C. to 1000° C., and 100° C. to 500° C.

The PV window may comprise a coating having a super-lyophobic property against liquid gallium by minimizing the contact area between the solid surface and the liquid metal that retards surface wetting by the molten or liquid metal such as gallium. The coating may further impede the surface wetting of gallium having a gallium oxide coat which otherwise would enhance the wetting. Exemplary super-lyophobic coatings are one with a multi-scale surface patterned with polydimethylsiloxane (PDMS) micro pillar array and one with a vertically aligned carbon nanotube having hierarchical micro/nano scale combined structures. The carbon nanotubes may be transferred onto flexible PDMS by imprinting such that the super-lyophobic property is maintained even under the mechanical deformation such as stretching and bending. Alternatively, the oxide coat of liquid gallium may be manipulated by modifying the surface of liquid metal itself. For example, the chemical reaction with HCl vapor causes the conversion of the oxidized surface (mainly Ga₂O₃/Ga₂O) of liquid gallium to GaCl₃ resulting in the recovery of non-wetting characteristics. In another embodiment, non-wetting by the liquid metal may be achieved by at least one of coating the PV window surface with a ferromagnetic material such as Co, Ni, Fe, or CoNiMnP and applying a magnetic field.

In an embodiment, the window or baffle may comprise a coating that is not wetted with gallium but may wet when gallium oxide forms by reaction with a source of oxygen such as oxygen gas or water vapor. The vapor pressure of the source of oxygen such as O₂ or H₂O vapor in the reaction cell chamber may be maintained at a desired pressure that is below a pressure which results in the formation of sufficient oxide to cause gallium wetting. The pressure of the source of oxygen may in maintained below at least one pressure of about 10 torr, 1 Torr, 0.1 Torr, and 0.01 Torr. In an embodiment wherein water absorbs on the window or baffle surface such as one comprising quartz, the window or baffle temperature is maintained at a desired temperature that is above a temperature which results in sufficient water surface absorption to cause wetting by gallium. The gallium wetting due to water may be caused by the formation of sufficient gallium oxide that facilitates the wetting. The maintained desired temperature to prevent an absorbed water concentration to permit gallium wetting is adjusted for the vapor pressure of water in the reaction cell chamber 5b31. Window or baffle may comprise a heater and a controller to maintain the desired temperature to prevent over absorption of water. Alternatively, the window or baffle may comprise a cooler or chiller such as a heat exchanger wherein the heat removal is decreased to achieve the elevated desired temperature that prevents gallium wetting. The desired temperature may be above at least one temperature of about 50° C., 100° C., 150° C., 200° C., 300° C., 400° C., and 500° C.

The PV window may comprise at thin coating of an anti-wetting agent that may be non-transparent such as a polymer comprising fluorine such as transparent Teflon, fluorinated ethylene propylene (FEP), polytetrafluoroethylene-perfluoroalkoxy co-polymer (Teflon-PFA), and polymers or copolymers based on fluorine, carbon or silicon such as allylalkoxysilane, fluoroaliphatic alkoxy silanes, fluoroaliphatic silyl ether and fluorinated trimethoxysilane. The thin coating such as a long-chain hydrocarbon such as Vaseline or wax may be translucent. At least one of the PV window and the PV window coating may comprise a transparent thermoplastic such as at least one of polycarbonate (Lexan), acrylic glass or Plexiglas comprising poly(methyl methacrylate) (PMMA), also known as acrylic or acrylic glass as well as by the trade names Crylux, Plexiglas, Acrylite, Lucite, and Perspex, polyethylene terephthalate (PET), amorphous coployester (PETG), polyvinylchloride (PVC), liquid silicone rubber (LSR), cyclic olefin copolymers, polyethylene, ionomer resin, transparent polypropylene, fluorinated ethylene propylene (FEP), perfluoroalkoxy (PFA), styrene methyl methacrylate (SMMA), styrene acrylonitrile resin (SAN), polystyrene (general purpose-GPPS), and polymeric methyl methacrylate acrylonitrile butadiene styrene (MABS (transparent ABS)).

The zigzag channel may prevent the direct bombardment of the PV window or baffle with particles that have at least one of high kinetic energy and high temperature that would damage a soft coating. In an embodiment of a PV window or baffle comprising a zigzag channel, the PV window or baffle may be coated with a surface non-wetted by gallium such as a polyethylene or Teflon.

In an embodiment, the reaction cell chamber contains a transport reactant that reacts with at least one of gallium and gallium oxide to from a volatile compound at a first temperature that thermally decomposes at a second, high temperature. In an embodiment, the volatile compound from on the PV window at the first temperature and decomposes one or more of on the reaction cell chamber walls, in the reaction chamber gases, and in the hydrino reaction plasma. The formation of the volatile compound serves to clean the PV window in a catalytic cycle. The transport reactant may be continuously consumed and regenerated as it removes at least one of gallium and gallium oxide from the surface of the PV window. The transport reactant may form a volatile halide such as GaCl₃ that has a boiling point of 201° C. The transport reactant may comprise HCl, Cl₂, or an organohalide such as methyl chloride. The transport reactant may form a volatile halide such as GaI₃ or Ga₂I₆ that has a boiling point of 345° C. The transport reactant may comprise HI, I₂, or an organohalide such as methyl iodide. The transport reactant may comprise an organic molecule that forms a volatile organometallic gallium complex or compound. The organic transport compound may comprise N, O, or S. In an embodiment, the transport reactant comprises a gallium halide such as GaCl₃ that react with at least one of gallium and gallium oxide. The product may be volatile. In an exemplary embodiment, GaCl₃ reacts with gallium to form gallium gallium tetrachloride (Ga₂Cl₄). Since the M.P.=164° C. and the B.P=535° C., the widow may be operated at a temperature to maintain sufficient Ga₂Cl₄ to clean the window such as near and above the boiling point (BP). The transport compound may react with Ga₂O₃ to form Ga₂O that is volatile. The transport compound may comprise H₂. The H₂ may be supplied by a gas jet that may further serve to clean the PV window. In an embodiment, the transport compound is an atom, ion, or element. The element may be gallium. Gallium may react with Ga₂O₃ to form Ga₂O that is volatile. The reaction to form gallium suboxide is favored at the lower temperature of the window. Ga₂O may decompose to Ga and Ga₂O₃ at the higher temperature of the plasma in the reaction cell chamber such as at a temperature over 660° C. In an embodiment, the transport element is aluminum added to gallium. The aluminum may form gaseous Al₂O. In another embodiment, aluminum may be substituted for gallium. Aluminum may comprise the molten metal. The transport reactant may be flowed from a hot zone where it is formed to the PV window surface by gas jet system wherein the transport reactant reacts with at least one of gallium and gallium oxide on the PV window surface. The product volatilizes to clean the window. The SunCell® components that are in contact with the transport compound or the solvent such as the reaction cell chamber and EM pump tube may comprise a material that is resistant to corrosion by the transport agent or solvent such as GaCl₃ or GaBr₃. The SunCell® components may comprise exemplary materials quartz or an austenitic stainless steel such as 316 or SS 625 that is resistant to corrosion by halides. The embodiment comprising a quartz EM pump tube may comprise an induction EM pump.

In an embodiment, the reaction cell chamber comprises a cleaning compound that removes deposited material such as gallium and gallium oxide from the PV window. The cleaning compound may comprise a solvent for at least one of gallium and gallium oxide. The solvent may comprise a compound that is a liquid at the operating temperature of the PV window. The cleaning compound may comprise a gas at the operating temperature of the reaction cell chamber. The cleaning compound may condense on the PV window. The cleaning compound may at least one of dissolve, suspend, and transport the material deposited on the PV window. The SunCell® may further comprise a gas jet system such as one comprising a gas pump with a gas inlet and at least one gas outlet comprising at least one gas nozzle that causes the gas to impinge onto the inner surface of the PV window wherein the gas may have a high velocity to ablate the deposited material from the PV window. The gas jet system may recirculate reaction cell chamber gas. The cleaning compound may also be removed with the suspended or dissolved deposited material by the gas jet. The cleaning compound may comprise an inorganic compound such as GaX₃ wherein X is a halide, at least one of F, Cl, Br or I. In an exemplary embodiment, the solubility of gallium metal in gallium bromide (MP=121.5° C., BP=278.8° C.) is 14 mole % [M. A. Bredig, “Mixtures of metals with molten salts”, Oak Ridge National Laboratory, Chemistry Division, U.S. Atomic Energy Commission, 1963, http://moltensalt.org/references/static/downloads/pdf/ORNL-3391.pdf]. So, gallium bromide may dissolve gallium deposited on the PV window. The solution may be removed by evaporation or by flow. Alternatively, the cleaning compound may comprise an organic compound such as a solvent. Exemplary solvents are long-chain hydrocarbon such as nonane (BP=151° C.), decane (BP=174° C.), undecane (BP=196° C.), dodecane (BP=216° C.), hexamethylphosphoramide, dimethylsulfoxide, N,N′-tetraalkylureas DMPU (dimethylpropyleneurea), DMI (1,3-dimethyl-2-imidazolidinone), methanol, isopropyl alcohol, or other solvent such as one with at least one property from the list of suitably high boiling point, ability to dissolve or suspend species deposited on the PV window, and low surface tension such that it wets the PV window and displaces the deposited species. The cleaning compound may comprise a metal hydroxide or metal oxide such as such as an alkali metal hydroxide or oxide or Mg, Zn, Co, Ni, or Cu hydroxide or oxide to form MGaO₂ (wherein M is one of Li, Na, K, Rb, Cs) or a spinel such as MgGa₂O₄, respectively. The cleaning compound may comprise a plurality of compounds such as a metal hydroxide or oxide and solvent of the reaction product of the metal oxide and gallium oxide such as water or an alcohol. In an embodiment, the vapor pressure of the cleaning compound in the reaction cell chamber may be controlled by at least one of limiting the number of moles of the cleaning compound and controlling the temperature of the PV window. The vapor pressure of the cleaning compound may be determined by the coldest temperature surface in contact with the vapor such as the surface of the PV window. The vapor pressure may be that of the corresponding liquid at the temperature of the PV window.

In an embodiment, the ignition source of electrical power may comprise at least one capacitor to provide a burst of high current through the injected molten metal. The high current may cause a powerful blast that may interrupt the injected molten metal stream. In an embodiment, the injector tube 5k61 comprises a plurality of nozzles at different positions and angles to reduce interruption of the injected molten metal stream by the hydrino reaction blast. In an embodiment, the reaction cell chamber provides confinement to the pressure wave created by the hydrino reaction. The confinement may increase the hydrino reaction rate.

In an embodiment, high ignition current may cause an instability of at least one of the plasma and the injected molten metal stream. The instability may be due to at least one of Lorentz deflection and high-current pinch effect. The injection current may be limited to avoid the instability. Alternatively, the injector may comprise at least one of a nozzle design and a plurality of nozzles to avoid the instability. For example, the plurality of nozzles may divide the current to avoid the instability. Alternatively, the current may be directed along at least one of parallel and anti-parallel paths to eliminate the instability. In another embodiment, the molten metal injection rate be may at least one of increased, decreased, and terminated to at least one of control the hydrino reaction rate, dampen plasma instabilities, and reduce the division of current between the molten metal stream and the plasma. In an embodiment, it is favorable for the current to flow through the plasma to enhance the hydrino reaction. The shunting of the current from the plasma by the molten metal stream may achieved by reducing or eliminating the EM pumping once the plasma is initiated. In another embodiment, the hydrino reaction rate may be increased by increasing the molten metal injection rate which may favor ion-recombination. The SunCell® may comprise a plurality of molten metal injectors such as EM pumps wherein at least one pump injects to the counter electrode and at least one injector may inject into the reaction cell chamber. The plurality of injectors may circulate the molten gallium and remove heat from hot spots in the reaction cell chamber to avoid damage to the SunCell®. Additionally, the hydrino reaction rate may be controlled by controlling the ignition power that may be increased, decreased, or terminated to control the power output and power gain relative to input power. The hydrino reaction rate may be increased with increased input power, but the gain may decrease.

In an embodiment, at least one of the ignition plasma parameters such as voltage, current, and power may be initially maintained at a higher value than after the plasma has formed and the reaction cell chamber has increased in temperature. At least one ignition power parameter such as voltage and current may be maintained at a high initial level and then decreased following the startup of the plasma to improve the power gain of output over input power. In an embodiment, the ignition current may be terminated once the plasma becomes sufficiently hot for the hydrino reaction to maintain the plasma in the absence of ignition power. To decrease the ignition voltage by decreasing the cell resistance, the SunCell® may comprise at least one of (i) a highly conductive bus bar to supply electrical power directly to the molten metal in the reservoir 5c, (ii) a highly conductive counter electrode 8 or 10, (iii) submerged electrodes, (iv) a nozzle 5q having a large diameter, and (v) a shorter electrode separation. In an embodiment comprising gallium as the molten metal wherein the ignition current crosses the injector pump tube, the pump tube may comprise a metal or coating to avoid the formation of a gallium alloy layer of high resistance by reaction with the metal of the EM pump tube. Exemplary metals and metal coating are stainless steel, tantalum, tungsten, and rhenium. In an embodiment, at least one SunCell® component that contacts gallium such as the EM pump tube 5k6, the injector tube 5k61, the bus bar in the gallium reservoir 5c, and the electrode 8 may comprise or be coated with a metal that has a slow rate of gallium alloy formation or gallium alloy formation is unfavorable such as at least one of stainless steel, rhenium (Re), tantalum, and tungsten (W).

In an embodiment, the SunCell® comprises a vacuum system comprising an inlet to a vacuum line, a vacuum line, a trap, and a vacuum pump. The vacuum pump may comprise one with a high pumping speed such as a root pump or scroll pump and may further comprise a trap for water vapor that may be in series or parallel connection with the vacuum pump such as in series connection preceding the vacuum pump. The water trap may comprise a water absorbing material such as a solid desiccant or a cryotrap. In an embodiment, the pump may comprise at least one of a cryopump, cryofilter, or cooler to at least one of cool the gases before entering the pump and condense at least one gas such as water vapor. To increase the pumping capacity and rate, the pumping system may comprise a plurality of vacuum lines connected to the reaction cell chamber and a vacuum manifold connected to the vacuum lines wherein the manifold is connected to the vacuum pump. In an embodiment, the inlet to vacuum line comprises a shield for stopping molten metal particles in the reaction cell chamber from entering the vacuum line. An exemplary shield may comprise a metal plate or dome over the inlet but raised from the surface of the inlet to provide a selective gap for gas flow from the reaction cell chamber into the vacuum line. The vacuum system that may further comprise a particle flow restrictor to the vacuum line inlet such as a set of baffles to allow gas flow while blocking particle flow.

The vacuum system may be capable of at least one of ultrahigh vacuum and maintaining a reaction cell chamber operating pressure in at least one low range such as about 0.01 Torr to 500 Torr, 0.1 Torr to 50 Torr, 1 Torr to 10 Torr, and 1 Torr to 5 Torr. The pressure may be maintained low in the case of at least one of (i) H₂ addition with trace HOH catalyst supplied as trace water or as O₂ that reacts with H₂ to form HOH and (ii) H₂O addition. In the case that noble gas such as argon is also supplied to the reaction mixture, the pressure may be maintained in at least one high operating pressure range such as about 100 Torr to 100 atm, 500 Torr to 10 atm, and 1 atm to 10 atm wherein the argon may be in excess compared to other reaction cell chamber gases. The argon pressure may increase the lifetime of at least one of HOH catalyst and atomic H and may prevent the plasma formed at the electrodes from rapidly dispersing so that the plasma intensity is increased.

In an embodiment, the reaction cell chamber comprises a means to control the reaction cell chamber pressure within a desired range by changing the volume in response to pressure changes in the reaction cell chamber. The means may comprise a pressure sensor, a mechanical expandable section, an actuator to expand and contract the expandable section, and a controller to control the differential volume created by the expansion and contraction of the expandable section. The expandable section may comprise a bellows. The actuator may comprise a mechanical, pneumatic, electromagnetic, piezoelectric, hydraulic, and other actuators known in the art.

In an embodiment, the SunCell® may comprise a (i) gas recirculation system with a gas inlet and an outlet, (ii) a gas separation system such as one capable of separating at least two gases of a mixture of at least two of a noble gas such as argon, O₂, H₂, H₂O, a volatile species of the reaction mixture such as GaX₃ (X=halide) or NₓO_{y} (x, y=integers), and hydrino gas, (iii) at least one noble gas, O₂, H₂, and H₂O partial pressure sensors, (iv) flow controllers, (v) at least one injector such as a microinjector such as one that injects water, (vi) at least one valve, (vii) a pump, (viii) an exhaust gas pressure and flow controller, and (ix) a computer to maintain at least one of the noble gas, argon, O₂, H₂, H₂O, and hydrino gas pressures. The recirculation system may comprise a semipermeable membrane to allow at least one gas such as molecular hydrino gas to be removed from the recirculated gases. In an embodiment, at least one gas such as the noble gas may be selectively recirculated while at least one gas of the reaction mixture may flow out of the outlet and may be exhausted through an exhaust. The noble gas may at least one of increase the hydrino reaction rate and increase the rate of the transport of at least one species in the reaction cell chamber out the exhaust. The noble gas may increase the rate of exhaust of excess water to maintain a desired pressure. The noble gas may increase the rate that hydrinos are exhausted. In an embodiment, a noble gas such as argon may be replaced by a noble-like gas that is at least one of readily available from the ambient atmosphere and readily exhausted into the ambient atmosphere. The noble-like gas may have a low reactivity with the reaction mixture. The noble-like gas may be acquired from the atmosphere and exhausted rather than be recirculated by the recirculation system. The noble-like gas may be formed from a gas that is readily available from the atmosphere and may be exhausted to the atmosphere. The noble gas may comprise nitrogen that may be separated from oxygen before being flowed into the reaction cell chamber. Alternatively, air may be used as a source of noble gas wherein oxygen may be reacted with carbon from a source to form carbon dioxide. At least one of the nitrogen and carbon dioxide may serve as the noble-like gas. Alternatively, the oxygen may be removed by reaction with the molten metal such as gallium. The resulting gallium oxide may be regenerated in a gallium regeneration system such as one that forms sodium gallate by reaction of aqueous sodium hydroxide with gallium oxide and electrolyzes sodium gallate to gallium metal and oxygen that is exhausted.

In an embodiment, the SunCell® may be operated prominently closed with addition of at least one of the reactants H₂, O₂, and H₂O wherein the reaction cell chamber atmosphere comprises the reactants as well as a noble gas such as argon. The noble gas may be maintained at an elevated pressure such as in the range of 10 Torr to 100 atm. The atmosphere may be at least one of continuously and periodically or intermittently exhausted or recirculated by the recirculation system. The exhausting may remove excess oxygen. The addition of reactant O₂ with H₂ may be such that O₂ is a minor species and essentially forms HOH catalyst as it is injected into the reaction cell chamber with excess H₂. A torch may inject the H₂ and O₂ mixture that immediately reacts to form HOH catalyst and excess H₂ reactant. In an embodiment, the excess oxygen may be at least partially released from gallium oxide by at least one of hydrogen reduction, electrolytic reduction, thermal decomposition, and at least one of vaporization and sublimation due to the volatility of Ga₂O. In an embodiment, at least one of the oxygen inventory may be controlled and the oxygen inventory may be at least partially permitted to form HOH catalyst by intermittently flowing oxygen into the reaction cell chamber in the presence of hydrogen. In an embodiment, the oxygen inventory may be recirculated as H₂O by reaction with the added H₂. In another embodiment, excess oxygen inventor may be removed as Ga₂O₃ and regenerated by means of the disclosure such as by at least one of the skimmer and electrolysis system of the disclosure. The source of the excess oxygen may be at least one of O₂ addition and H₂O addition.

In an embodiment, the gas pressure in the reaction cell chamber may be at least partially controlled by controlling at least one of the pumping rate and the recirculation rate. At least one of these rates may be controlled by a valve controlled by a pressure sensor and a controller. Exemplary valves to control gas flow are solenoid valves that are opened and closed in response to an upper and a lower target pressure and variable flow restriction vales such as butterfly and throttle valves that are controlled by a pressure sensor and a controller to maintain a desired gas pressure range.

In an embodiment, gallium oxide such as Ga₂O may be removed from the reaction cell chamber by at least one of vaporization and sublimation due to the volatility of Ga₂O. The removal may be achieved by at least one method of flowing gas through the reaction cell chamber and maintaining a low pressure such as one below atmospheric. The gas flow may be maintained by the recirculator of the disclosure. The low pressure may be maintained by the vacuum pumping system of the disclosure. The gallium oxide may be condensed in the condenser of the disclosure and returned to the reaction cell chamber. Alternatively, the gallium oxide may be trapped in a filter or trap such as a cryotrap from which it may be removed and regenerated by systems and methods of the disclosure. The trap may be in at least one gas line of the recirculator. In an embodiment, the Ga₂O may be trapped in the trap of the vacuum system wherein the trap may comprise at least one of a filter, a cryotrap, and an electrostatic precipitator. The electrostatic precipitator may comprise high voltage electrodes to maintain a plasma to electrostatically charge Ga₂O particles and to trap the charged particles. In an exemplary embodiment, each set of at least one set of electrodes may comprise a wire that may produce a coronal discharge that negatively electrostatically charges the Ga₂O particles and a positively charged collection electrode such as a plate or tube electrode that precipitates the charged particles from the gas stream from the reaction cell chamber. The Ga₂O particles may be removed from each collector electrode by a means known in the art such as mechanically, and the Ga₂O may be converted to gallium and recycled. The gallium may be regenerated from the Ga₂O by systems and methods of the such as by electrolysis in NaOH solution.

The electrostatic precipitator (ESP) may further comprise a means to precipitate at least one desired species from the gas stream from the reaction cell chamber and return it to the reaction cell chamber. The precipitator may comprise a transport mean such as an auger, conveyor belt, pneumatic, electromechanical, or other transport means of the disclosure or known in the art to transport particles collected by the precipitator back to the reaction cell chamber. The precipitator may be mounted in a portion of the vacuum line that comprises a refluxer that returns desired particles to the reaction cell chamber by gravity flow wherein the particles may be precipitated and flow back to the reaction cell chamber by gravity flow such as flow in the vacuum line. The vacuum line may be oriented vertically in at least one portion that allows the desired particles to undergo gravity return flow.

In an exemplary tested embodiment, the reaction cell chamber was maintained at a pressure range of about 1 to 2 atm with 4 ml/min H₂O injection. The DC voltage was about 30 V and the DC current was about 1.5 kA. The reaction cell chamber was a 6-inch diameter stainless steel sphere such as one shown in FIG. 25 that contained 3.6 kg of molten gallium. The electrodes comprised a 1-inch submerged SS nozzle of a DC EM pump and a counter electrode comprising a 4 cm diameter, 1 cm thick W disc with a 1 cm diameter lead covered by a BN pedestal. The EM pump rate was about 30-40 ml/s. The gallium was polarized positive with a submerged nozzle, and the W pedestal electrode was polarized negative. The gallium was well mixed by the EM pump injector. The SunCell® output power was about 85 kW measured using the product of the mass, specific heat, and temperature rise of the gallium and SS reactor.

In another tested embodiment, 2500 sccm of H₂ and 25 sccm O₂ was flowed through about 2 g of 10% Pt/Al₂O₃ beads held in an external chamber in line with the H₂ and O₂ gas inlets and the reaction cell chamber. Additionally, argon was flowed into the reaction cell chamber at a rate to maintain 50 Torr chamber pressure while applying active vacuum pumping. The DC voltage was about 20 V and the DC current was about 1.25 kA. The SunCell® output power was about 120 kW measured using the product of the mass, specific heat, and temperature rise of the gallium and SS reactor.

In an embodiment, the recirculation system or recirculator such as the noble gas recirculatory system capable of operating at one or more of under atmospheric pressure, at atmospheric pressure, and above atmospheric pressure may comprise (i) a gas mover such as at least one of a vacuum pump, a compressor, and a blower to recirculate at least one gas from the reaction cell chamber, (ii) recirculation gas lines, (iii) a separation system to remove exhaust gases such as hydrino and oxygen, and (iv) a reactant supply system. In an embodiment, the gas mover is capable of pumping gas from the reaction cell chamber, pushing it through the separation system to remove exhaust gases, and returning the regenerated gas to the reaction cell chamber. The gas mover may comprise at least two of the pump, the compressor, and the blower as the same unit. In an embodiment, the pump, compressor, blower or combination thereof may comprise at least one of a cryopump, cryofilter, or cooler to at least one of cool the gases before entering the gas mover and condense at least one gas such as water vapor. The recirculation gas lines may comprise a line from the vacuum pump to the gas mover, a line from the gas mover to the separation system to remove exhaust gases, and line from the separation system to remove exhaust gases to the reaction cell chamber that may connect with the reactant supply system. An exemplary reactant supply system comprises at least one union with the line to the reaction cell chamber with at least one reaction mixture gas makeup line for at least one of the noble gas such as argon, oxygen, hydrogen, and water. The addition of reactant O₂ with H₂ may be such that O₂ is a minor species and essentially forms HOH catalyst as it is injected into the reaction cell chamber with excess H₂. A torch may inject the H₂ and O₂ mixture that immediately reacts to form HOH catalyst and excess H₂ reactant. The reactant supply system may comprise a gas manifold connected to the reaction mixture gas supply lines and an outflow line to the reaction cell chamber.

The separation system to remove exhaust gases may comprise a cryofilter or cryotrap. The separation system to remove hydrino product gas from the recirculating gas may comprise a semipermeable membrane to selectively exhaust hydrino by diffusion across the membrane from the recirculating gas to atmosphere or to an exhaust chamber or stream. The separation system of the recirculator may comprise an oxygen scrubber system that removes oxygen from the recirculating gas. The scrubber system may comprise at least one of a vessel and a getter or absorbent in the vessel that reacts with oxygen such as a metal such as an alkali metal, an alkaline earth metal, or iron. Alternatively, the absorbent such as activated charcoal or another oxygen absorber known in the art may absorb oxygen. The charcoal absorbent may comprise a charcoal filter that may be sealed in a gas permeable cartridge such as one that is commercially available. The cartridge may be removable. The oxygen absorbent of the scrubber system may be periodically replaced or regenerated by methods known in the art. A scrubber regeneration system of the recirculation system may comprise at least one of one or more absorbent heaters and one or more vacuum pumps. In an exemplary embodiment, the charcoal absorbent is at least one of heated by the heater and subjected to an applied vacuum by the vacuum pump to release oxygen that is exhausted or collected, and the resulting regenerated charcoal is reused. The heat from the SunCell® may be used to regenerate the absorbent. In an embodiment, the SunCell® comprises at least one heat exchanger, a coolant pump, and a coolant flow loop that serves as a scrubber heater to regenerate the absorbent such as charcoal. The scrubber may comprise a large volume and area to effectively scrub while not significantly increasing the gas flow resistance. The flow may be maintained by the gas mover that is connected to the recirculation lines. The charcoal may be cooled to more effectively absorb species to be scrubbed from the recirculating gas such as a mixture comprising the noble gas such as argon. The oxygen absorbent such as charcoal may also scrub or absorb hydrino gas. The separation system may comprise a plurality of scrubber systems each comprising (i) a chamber capable of maintaining a gas seal, (ii) an absorbent to remove exhaust gases such as oxygen, (iii) inlet and outlet valves that may isolate the chamber from the recirculation gas lines and isolate the recirculation gas lines from the chamber, (iv) a means such as a robotic mechanism controlled by a controller to connect and disconnect the chamber from the recirculation lines, (v) a means to regenerate the absorbent such as a heater and a vacuum pump wherein the heater and vacuum pump may be common to regenerate at least one other scrubber system during its regeneration, (v) a controller to control the disconnection of the nth scrubber system, connection of the n+1th scrubber system, and regeneration of the nth scrubber system while the n+1th scrubber system serves as an active scrubber system wherein at least one of the plurality of scrubber systems may be regenerated while at least one other may be actively scrubbing or absorbing the desired gases. The scrubber system may permit the SunCell® to be operated under closed exhaust conditions with periodic controlled exhaust or gas recovery. In an exemplary embodiment, hydrogen and oxygen may be separately collected from the absorbent such as activated carbon by heating to different temperatures at which the corresponding gases are about separately released.

In an embodiment comprising a reaction cell chamber gas mixture of a noble gas, hydrogen, and oxygen wherein the partial pressure of the noble gas of the reaction cell chamber gas exceeds that of hydrogen, the oxygen partial pressure may be increased to compensate for the reduced reaction rate between hydrogen and oxygen to form HOH catalyst due to the reactant concentration dilution effect of the noble gas such as argon. In an embodiment, the HOH catalyst may be formed in advance of combining with the noble gas such as argon. The hydrogen and oxygen may be caused to react by a recombiner or combustor such as a recombiner catalyst, a plasma source, or a hot surface such as a filament. The recombiner catalyst may comprise a noble metal supported on a ceramic support such as Pt, Pd, or Ir on alumina, zirconia, hafnia, silica, or zeolite power or beads, another supported recombiner catalyst of the disclosure, or a dissociator such as Raney Ni, Ni, niobium, titanium, or other dissociator metal of the disclosure or one known in the art in a form to provide a high surface area such as powder, mat, weave, or cloth. An exemplary recombiner comprises 10 wt % Pt on Al₂O₃ beads. The plasma source may comprise a glow discharge, microwave plasma, plasma torch, inductively or capacitively coupled RF discharge, dielectric barrier discharge, piezoelectric direct discharge, acoustic discharge, or another discharge cell of the disclosure or known in the art. The hot filament may comprise a hot tungsten filament, a Pt or Pd black on Pt filament, or another catalytic filament known in the art.

The inlet flow of reaction mixture species such as at least one of water, hydrogen, oxygen, and a noble gas may be continuous or intermittent. The inlet flow rates and an exhaust or vacuum flow rate may be controlled to achieve a desired pressure range. The inlet flow may be intermittent wherein the flow may be stopped at the maximum pressure of a desired range and commenced at a minimum of the desire range. In a case that reaction mixture gases comprises high pressure noble gas such as argon, the reaction cell chamber may be evacuated, filled with the reaction mixture, and run under about static exhaust flow conditions wherein the inlet flows of reactants such as at least one of water, hydrogen, and oxygen are maintained under continuous or intermittent flow conditions to maintain the pressure in the desired range. Additionally, the noble gas may be flowed at an economically practical flow rate with a corresponding exhaust pumping rate, or the noble gas may be regenerated or scrubbed and recirculated by the recirculation system or recirculator.

The reaction cell chamber 5b31 gases may comprise at least one of H₂, a noble gas such as argon, O₂, and H₂O, and oxide such as CO₂. In an embodiment, the pressure in the reaction cell chamber 5b31 may be below atmospheric. The pressure may be in a least one range of about 1 milliTorr to 750 Torr, 10 milliTorr to 100 Torr, 100 milliTorr to 10 Torr, and 250 milliTorr to 1 Torr. The SunCell® may comprise a water vapor supply system comprising a water reservoir with heater and a temperature controller, a channel or conduit, and a value. In an embodiment, the reaction cell chamber gas may comprise H₂O vapor. The water vapor may be supplied by the external water reservoir in connection with the reaction cell chamber through the channel by controlling the temperature of the water reservoir wherein the water reservoir may be the coldest component of the water vapor supply system. The temperature of the water reservoir may control the water vapor pressure based on the partial pressure of water as a function of temperature. The water reservoir may further comprise a chiller to lower the vapor pressure. The water may comprise an additive such as a dissolved compound such as a salt such as NaCl or other alkali or alkaline earth halide, an absorbent such as zeolite, a material or compound that forms a hydrate, or another material or compound known to those skilled in the art that reduces the vapor pressure. Exemplary mechanisms to lower the vapor pressure are by colligative effects or bonding interaction. In an embodiment, the source of water vapor pressure may comprise ice that may be housed in a reservoir and supplied to the reaction cell chamber 5b31 through a conduit. The ice may have a high surface area to increase at least one of the rate of the formation of HOH catalyst and H from ice and the hydrino reaction rate. The ice may be in the form of fine chips to increase the surface area. The ice may be maintained at a desired temperature below 0° C. to control the water vapor pressure. A carrier gas such as at least one of H₂ and argon may be flowed through the ice reservoir and into the reaction cell chamber. The water vapor pressure may also be controlled by controlling the carrier gas flow rate.

The molarity equivalent of H₂ in liquid H₂O is 55 moles/liter wherein H₂ gas at STP occupies 22.4 liters. In an embodiment, H₂ is supplied to the reaction cell chamber 5b31 as a reactant to form hydrino in a form that comprises at least one of liquid water and steam. The SunCell® may comprise at least one injector of the at least one of liquid water and steam. The injector may comprise at least one of water and steam jets. The injector orifice into the reaction cell chamber may be small to prevent backflow. The injector may comprise an oxidation resistant, refractory material such as a ceramic or another or the disclosure. The SunCell® may comprise a source of at least one of water and steam and a pressure and flow control system. In an embodiment, the SunCell® may further comprise a sonicator, atomizer, aerosolizer, or nebulizer to produce small water droplets that may be entrained in a carrier gas stream and flowed into the reaction cell chamber. The sonicator may comprise at least one of a vibrator and a piezoelectric device. The vapor pressure of water in a carrier gas flow may be controlled by controlling the temperature of the water vapor source or that of a flow conduit from the source to the reaction cell chamber. In an embodiment, the SunCell® may further comprise a source of hydrogen and a hydrogen recombiner such as a CuO recombiner to add water to the reaction cell chamber 5b31 by flowing hydrogen through the recombiner such as a heated copper oxide recombiner such that the produced water vapor flows into the reaction cell chamber. In another embodiment, the SunCell® may further comprise a steam injector. The steam injector may comprise at least one of a control valve and a controller to control the flow of at least one of steam and cell gas into the steam injector, a gas inlet to a converging nozzle, a converging-diverging nozzle, a combining cone that may be in connection with a water source and an overflow outlet, a water source, an overflow outlet, a delivery cone, and a check valve. The control value may comprise an electronic solenoid or other computer-controlled value that may be controlled by a timer, sensor such as a cell pressure or water sensor, or a manual activator. In an embodiment, the SunCell® may further comprise a pump to inject water. The water may be delivered through a narrow cross section conduit such as a thin hypodermic needle so that heat from the SunCell® does not boil the water in the pump. The pump may comprise a syringe pump, peristaltic pump, metering pump, or other known in the art. The syringe pump may comprise a plurality of syringes such that at least one may be refilling as another is injecting. The syringe pump may amplify the force of the water in the conduit due to the much smaller cross-section of the conduit relative to the plunger of the syringe. The conduit may be at least one of heat sunk and cooled to prevent the water in the pump from boiling.

In an embodiment, the reaction cell chamber reaction cell mixture is controlled by controlling the reaction cell chamber pressure by at least one means of controlling the injection rate of the reactants and controlling the rate that excess reactants of the reaction mixture and products are exhausted from the reaction cell chamber 5b31. In an embodiment, the SunCell® comprises a pressure sensor, a vacuum pump, a vacuum line, a valve controller, and a valve such as a pressure-activated valve such as a solenoid valve or a throttle valve that opens and closes to the vacuum line from the reaction cell chamber to the vacuum pump in response to the controller that processes the pressure measured by the sensor. The valve may control the pressure of the reaction cell chamber gas. The valve may remain closed until the cell pressure reaches a first high setpoint, then the value may be activated to be open until the pressure is dropped by the vacuum pump to a second low setpoint which may cause the activation of the valve to close. In an embodiment, the controller may control at least one reaction parameter such as the reaction cell chamber pressure, reactant injection rate, voltage, current, and molten metal injection rate to maintain a non-pulsing or about steady or continuous plasma.

In an embodiment, the SunCell® comprises a pressure sensor, a source of at least one reactant or species of the reaction mixture such as a source of H₂O, H₂, O₂, and noble gas such a argon, a reactant line, a valve controller, and a valve such as a pressure-activated valve such as a solenoid valve or a throttle valve that opens and closes to the reactant line from the source of at least one reactant or species of the reaction mixture and the reaction cell chamber in response to the controller that processes the pressure measured by the sensor. The valve may control the pressure of the reaction cell chamber gas. The valve may remain open until the cell pressure reaches a first high setpoint, then the value may be activated to be close until the pressure is dropped by the vacuum pump to a second low setpoint which may cause the activation of the valve to open.

In an embodiment, the SunCell® may comprise an injector such as a micropump. The micropump may comprise a mechanical or non-mechanical device. Exemplary mechanical devices comprise moving parts which may comprise actuation and microvalve membranes and flaps. The driving force of the micropump mat be generated by utilizing at least one effect form the group of piezoelectric, electrostatic, thermos-pneumatic, pneumatic, and magnetic effects. Non-mechanical pumps may be unction with at least one of electro-hydrodynamic, electro-osmotic, electrochemical, ultrasonic, capillary, chemical, and another flow generation mechanism known in the art. The micropump may comprise at least one of a piezoelectric, electroosmotic, diaphragm, peristaltic, syringe, and valveless micropump and a capillary and a chemically powered pump, and another micropump known in the art. The injector such as a micropump may continuously supply reactants such as water, or it may supply reactants intermittently such as in a pulsed mode. In an embodiment, a water injector comprises at least one of a pump such as a micropump, at least one valve, and a water reservoir, and may further comprise a cooler or an extension conduit to remove the water reservoir and valve for the reaction cell chamber by a sufficient distance, either to avoid over heating or boiling of the preinjected water.

The SunCell® may comprise an injection controller and at least one sensor such as one that records pressure, temperature, plasma conductivity, or other reaction gas or plasma parameter. The injection sequence may be controlled by the controller that uses input from the at least one sensor to deliver the desired power while avoiding damage to the SunCell® due to overpowering. In an embodiment, the SunCell@ comprises a plurality of injectors such as water injectors to inject into different regions within the reaction cell chamber wherein the injectors are activated by the controller to alternate the location of plasma hot spots in time to avoid damage to the SunCell®. The injection may be intermittent, periodic intermittent, continuous, or comprise any other injection pattern that achieves the desired power, gain, and performance optimization.

The SunCell® may comprise valves such as pump inlet and outlet valves that open and close in response to injection and filling of the pump wherein the inlet and outlet valve state of opening or closing may be 1800 out of phase from each other. The pump may develop a higher pressure than the reaction cell chamber pressure to achieve injection. In the event that the pump injection is prone to influence by the reaction cell chamber pressure, the SunCell® may comprise a gas connection between the reaction cell chamber and the reservoir that supplies the water to the pump to dynamically match the head pressure of the pump to that of the reaction cell chamber.

In an embodiment wherein the reaction cell chamber pressure is lower than the pump pressure, the pump may comprise at least one valve to achieve stoppage of flow to the reaction cell chamber when the pump is idle. The pump may comprise the at least one valve. In an exemplary embodiment, a peristaltic micropump comprises at least three microvalves in series. These three valves are opened and closed sequentially in order to pull fluid from the inlet to the outlet in a process known as peristalsis. In an embodiment, the valve may be active such as a solenoidal or piezoelectric check valve, or it may act passively whereby the valve is closed by backpressure such as a check valve such as a ball, swing, diagram, or duckbill check valve.

In an embodiment wherein a pressure gradient exists between the source of water to be injected into the reaction cell chamber and the reaction cell chamber, the pump may comprise two valves, a reservoir valve and a reaction cell chamber valve, that may open and close periodically 180° out of phase. The valves may be separated by a pump chamber having a desired injection volume. With the reaction cell chamber valve closing, the reservoir valve may be opening to the water reservoir to fill the pump chamber. With the reservoir valve closing, the reaction cell chamber valve may be opening to cause the injection of the desired volume of water into the reaction cell chamber. The flow into and out of the pump chamber may be driven by the pressure gradient. The water flow rate may be controlled by controlling the volume of the pump chamber and the period of the synchronized valve openings and closings. In an embodiment, the water microinjector may comprise two valves, an inlet and outlet valve to a microchamber or about 10 ul to 15 ul volume, each mechanically linked and 180° out of phase with respect to opening and closing. The valves may be mechanically driven by a cam.

In another embodiment, another species of the reaction cell mixture such as at least one of H₂, O₂, a noble gas, and water may replace water or be in addition to water. In the case that the species that is flowed into the reaction cell chamber is a gas at room temperature, the SunCell® may comprise a mass flow controller to control the input flow of the gas.

In another embodiment wherein a pressure gradient exists between the source of water to be injected into the reaction cell chamber and the reaction cell chamber, the inlet flow of water may be continuously supplied through a flow rate controller or restrictor such as at least one of (i) a needle valve, (ii) a narrow or small ID tube, (iii) a hydroscopic materials such as cellulose, cotton, polyethene glycol, or another hydroscopic materials known in the art, and (iv) a semipermeable membrane such as ceramic membrane, a frit, or another semipermeable membrane known in the art. The hydroscopic material such as cotton may comprise a packing and may serve to restrict flow in addition to another restrictor such as a needle valve. The SunCell® may comprise a holder for the hydroscopic material or semipermeable membrane. The flow rate of the flow restrictor may be calibrated, and the vacuum pump and the pressure-controlled exhaust valve may further maintain a desired dynamic chamber pressure and water flow rate. In another embodiment, another species of the reaction cell mixture such as at least one of H₂, O₂, a noble gas, and water may replace water or be in addition to water. In the case that the species that is flowed into the reaction cell chamber is a gas at room temperature, the SunCell® may comprise a mass flow controller to control the input flow of the gas.

In an embodiment, the injector operated under a reaction cell chamber vacuum, may comprise a flow restrictor such as a needle valve or narrow tube wherein the length and diameter are controlled to control the water flow rate. An exemplary small diameter tube injector comprises one similar to one used for ESI-ToF injection systems such as one having an ID in the range of about 25 um to 300 um. The flow restrictor may be combined with at least one other injector element such as a value or a pump. In an exemplary embodiment, the water head pressure of the small diameter tube is controlled with a pump such as a syringe pump. The injection rate may further be controlled with a valve from the tube to the reaction cell chamber. The head pressure may be applied by pressurizing a gas over the water surface wherein gas is compressible and water is incompressible. The gas pressurization may be applied by a pump. The water injection rate may be controlled by at least one of the tube diameter, length, head pressure, and valve opening and closing frequency and duty cycle. The tube diameter may be in the range of about 10 um to 10 mm, the length may be in the range of about 1 cm to 1 m, the head pressure may be in the range of about 1 Torr to 100 atm, the valve opening and closing frequency may in the range of about 0.1 Hz to 1 kHz, and the duty cycle may be in the range of about 0.01 to 0.99.

In an embodiment, the SunCell® comprises a source of hydrogen such as hydrogen gas and a source of oxygen such as oxygen gas. The source of at least one of hydrogen and oxygen sources comprises at least one or more gas tanks, flow regulators, pressure gauges, valves, and gas lines to the reaction cell chamber. In an embodiment, the HOH catalyst is generated from combustion of hydrogen and oxygen. The hydrogen and oxygen gases may be flowed into the reaction cell chamber. The inlet flow of reactants such as at least one of hydrogen and oxygen may be continuous or intermittent. The flow rates and an exhaust or vacuum flow rate may be controlled to achieve a desired pressure. The inlet flow may be intermittent wherein the flow may be stopped at the maximum pressure of a desired range and commenced at a minimum of the desire range. At least one of the H₂ pressure and flow rate and O₂ pressure and flow rate may be controlled to maintain at least one of the HOH and H₂ concentrations or partial pressures in a desired range to control and optimize the power from the hydrino reaction. In an embodiment, at least one of the hydrogen inventory and flow many be significantly greater than the oxygen inventory and flow. The ratio of at least one of the partial pressure of H₂ to O₂ and the flow rate of H₂ to O₂ may be in at least one range of about 1.1 to 10,000, 1.5 to 1000, 1.5 to 500, 1.5 to 100, 2 to 50 and 2 to 10. In an embodiment, the total pressure may be maintained in a range that supports a high concentration of nascent HOH and atomic H such as in at least one pressure range of about 1 mTorr to 500 Torr, 10 mTorr to 100 Torr, 100 mTorr to 50 Torr, and 1 Torr to 100 Torr. In an embodiment, at least one of the reservoir and reaction cell chamber may be maintained at an operating temperature that is greater than the decomposition temperature of at least one of gallium oxyhydroxide and gallium hydroxide. The operating temperature may be in at least one range of about 200° C. to 2000° C., 200° C. to 1000° C., and 200° C. to 700° C. The water inventory may be controlled in the gaseous state in the case that gallium oxyhydroxide and gallium hydroxide formation is suppressed.

In an embodiment, the SunCell® comprises a gas mixer to mix at least two gases such as hydrogen and oxygen that are flowed into the reaction cell chamber. In an embodiment, the micro-injector for water comprises the mixer that mixes hydrogen and oxygen wherein the mixture forms HOH as it enters the reaction cell chamber. The mixer may further comprise at least one mass flow controller, such as one for each gas or a gas mixture such as a premixed gas. The premixed gas may comprise each gas in its desired molar ratio such as a mixture comprising hydrogen and oxygen. The H₂ molar percent of a H₂— O₂ mixture may be in significant excess such as in a molar ratio range of about 1.5 to 1000 times the molar percent of O₂. The mass flow controller may control the hydrogen and oxygen flow and subsequent combustion to form HOH catalyst such that the resulting gas flow into the reaction cell chamber comprises hydrogen in excess and HOH catalyst. In an exemplary embodiment, the H₂ molar percentage is in the range of about 1.5 to 1000 times the molar percent of HOH. The mixer may comprise a hydrogen-oxygen torch. The torch may comprise a design known in the art such as a commercial hydrogen-oxygen torch. In exemplary embodiments, O₂ with H₂ are mixed by the torch injector to cause O₂ to react to form HOH within the H₂ stream to avoid oxygen reacting with the gallium cell components or the electrolyte to dissolve gallium oxide to facilitate its regeneration to gallium by in situ electrolysis such as NaI electrolyte or another of the disclosure. Alternatively, a H₂— O₂ mixture comprising hydrogen in at least ten times molar excess is flowed into the reaction cell chamber by a single flow controller versus two supplying the torch.

The supply of hydrogen to the reaction cell chamber as H₂ gas rather than water as the source of H₂ by reaction of H₂O with gallium to form H₂ and Ga₂O₃ may reduce the amount of Ga₂O₃ formed. The water micro-injector comprising a gas mixer may have a favorable characteristic of allowing the capability of injecting precise amounts of water at very low flow rates due to the ability to more precisely control gas flow over liquid flow. Moreover, the reaction of the O₂ with excess H₂ may form about 100% nascent water as an initial product compared to bulk water and steam that comprise a plurality of hydrogen-bonded water molecules. In an embodiment, the gallium is maintained at a temperature of less than 100° C. such that the gallium may have a low reactivity to consume the HOH catalyst by forming gallium oxide. The gallium may be maintained at low temperature by a cooling system such as one comprising a heat exchanger or a water bath for at least one of the reservoir and reaction cell chamber. In an exemplary embodiment, the SunCell® is operated under the conditions of high flow rate H₂ with trace O₂ flow such as 99% H_{2/1}% O₂ wherein the reaction cell chamber pressure may be maintained low such as in the pressure range of about 1 to 30 Torr, and the flow rate may be controlled to produce the desired power wherein the theoretical maximum power by forming H₂(¼) may be about 1 kW/30 sccm. Any resulting gallium oxide may be reduced by in situ hydrogen plasma and electrolytically reduction. In an exemplary embodiment capable of generating a maximum excess power of 75 kW wherein the vacuum system is capable of achieving ultrahigh vacuum, the operating condition are about oxide free gallium surface, low operating pressure such as about 1-5 Torr, and high H₂ flow such as about 2000 sccm with trace HOH catalyst supplied as about 10-20 sccm oxygen through a torch injector.

In an embodiment, at least one of the liner, reaction cell chamber wall, and reservoir wall comprise a material that is at least one of performs as a hydrogen dissociator, has a low hydrogen recombination coefficient or low capacity for recombination, and is resistant to attack from gallium at the operating temperature range of the SunCell® such as in at least one range of about 25° C. to 3500° C., 75° C. to 2000° C., 100° C. to 1500° C., 100° C. to 1000° C., 100° C. to 600° C., and 100° C. to 400° C. Since different materials have different H atom recombination rates that change as a function of temperature, the SunCell® may be operated in a temperature range that optimizes the concentration of atomic hydrogen. Exemplary materials that are resistant to attack by gallium that may serve as SunCell® components such as at least one of the reaction cell chamber walls, reservoir, and EM pump tube, or coatings, plated metals, or cladding of SunCell® components comprise stainless steel, Inconel 625, Nb-5 Mo-1 Zr alloy, Zirconium705, SS comprising about 0.04 wt % C, 0.4 wt % Si, 1.4 wt % Mn, 0.03 wt % P, 18 wt % Cr, 8.1 wt % Ni, and 0.045% N, Type 347 Cr—Ni steel and 430 Cr steel, Ta, W, niobium, zirconium, rhenium, a ceramic such as BN, quartz, alumina, hafnia, zirconia, silica, Mullite, graphite, and silicon carbide, and others resistant materials known in the art such as those given in L. R. Kelman, W. D. Wilkinson, and F. L. Yagee, in Resistance of Materials to Attack by Liquid Metals, Argonne National Laboratory Report #ANL-4417 (1950); P. R. Luebbers, W. F. Michaud, and O. K. Chopra, Compatibility of ITER Candidate Structural Material with Static Gallium, Argonne National Laboratory Report #ANL-93/31, December 1993 which are herein incorporated by reference. In an embodiment, at least one of the reaction cell chamber wall material, a wall coating, or liner is selected for promoting atomic hydrogen by at least one mechanism of increasing dissociation and decreasing H recombination into H₂ molecules. In an embodiment, the material may comprise a molecular hydrogen dissociator such as a noble metal such as Raney nickel, Pt, Pd, Ir, Ru, Rh, or Re, a rare earth metal, Co, quartz supported Co, Raney Ni, Ni, Cr, Ti, Co, Nb, or Zr. The dissociator metal may be supported by a ceramic or another metal such as dimensionally stable anodes such as rhenium supported on titanium or another known in the art that may be at least one of resistant to forming an alloy with gallium and capable of operating at the operating temperature of the reaction cell chamber where it is mounted. Exemplary dissociators that may comprise at least one of the liner, reaction cell chamber wall, and reservoir wall that may also have resistance to forming an alloy with gallium are tantalum, titanium, niobium, rhenium, chromium, stainless steels (SS), type 347 SS, type 430 SS, martensitic stainless steel that has high chromium content such as Fe-17Cr-1Mn-1Si—0.75Mo-1.1C, stainless steels (SS) with high nickel content such as Inconel such as Inconel 625, SS 316, SS 625, and Nb-5 Mo-1 Zr alloy.

In an embodiment, the SunCell® components or surfaces of components that contact gallium such as at least one of the reaction cell chamber walls, the top of the reaction cell chamber, inside walls of the reservoir, and inside walls of the EM pump tube may be coated with a coating that does not form an alloy readily with gallium such as a ceramic such as Mullite, BN, or another of the disclosure, or a metal such as W, Ta, Nb, Zr, Mo, TZM, or another of the disclosure. In another embodiment, the surfaces may be clad with a material that does not readily form an alloy with gallium such as carbon, a ceramic such as BN, alumina, zirconia, quartz, or another of the disclosure, or a metal such as W, Ta, or another of the disclosure. In an embodiment, the coating may be applied by at least one of electrodeposition, vapor deposition, and chemical deposition. In the latter case, a tungsten coating may be applied by thermal decomposition of tungsten hexacarbonyl on the surfaces. Tungsten may be electroplated using methods known in the art such as those given by Fink and Jones [C. Fink, F. Jones, “The Electrodeposition of Tungsten from Aqueous Solutions”, Journal of the Electrochemical Society, (1931), pp. 461-481] which is incorporated by reference. W may be coated by methods such as vapor deposition on the SunCell® components such as the walls of the reaction cell chamber, reservoir, and EM pump tube that are in contact with molten gallium wherein the W coated components comprise Mo. In an embodiment, at least one of the reaction cell chamber, reservoir, and EM pump tube may comprise Nb, Zr, W, Ta, Mo, or TZM. In an embodiment, SunCell® components or portions of the components such as the reaction cell chamber, reservoir, and EM pump tube may comprise a material that does not form an alloy except when the temperature of contacting gallium exceeds an extreme such as at least one extreme of over about 400° C., 500° C., 600° C., 700° C., 800° C., 900° C., and 1000° C. The SunCell® may be operated at a temperature wherein portions of components do not reach a temperature at which gallium alloy formation occurs. The SunCell® operating temperature may be controlled with cooling by cooling means such as a heat exchanger or water bath. The water bath may comprise impinging water jets such as jets off of a water manifold wherein at least one of the number of jets incident on the reaction chamber and the flow rate or each jet are controlled by a controller to maintain the reaction chamber within a desired operating temperature range. In an embodiment such as one comprising water jet cooling of at least one surface, the exterior surface of at least one component of the SunCell® may be clad with insulation such as carbon to maintain an elevated internal temperature while permitting operational cooling. The surfaces that form a gallium alloy above a temperature extreme achieved during SunCell® operation may be selectively coated or clad with a material that does not readily form an alloy with gallium. The portions of the SunCell® components that both contact gallium and exceed the alloy temperature for the component's material such as stainless steel may be clad with the material that does not readily form an alloy with gallium. In an exemplary embodiment, the reaction cell chamber walls may be clad with W, Ta, Mo, TZM, niobium, or zirconium plate, or a ceramic such as quartz, especially at the region near the electrodes wherein the reaction cell chamber temperature is the greatest. The cladding may comprise a reaction cell chamber liner 5b31a. The liner may comprise a gasket or other gallium impervious material such as a ceramic paste positioned between the liner and the walls of the reaction cell chamber to prevent gallium from seeping behind the liner. The liner may be attached to the wall by at least one of welds, bolts, or another fastener or adhesive known in the art.

In an embodiment, the bus bas such as at least one of 10, 5k2, and the corresponding electrical leads from the bus bars to at least one of the ignition and EM pump power supplies may serve as a means to remove heat from the reaction cell chamber 5b31 for applications. The SunCell® may comprise a heat exchanger to remove heat from at least one of the bus bars and corresponding leads. In a SunCell® embodiment comprising a MHD converter, heat lost on the bus bars and their leads may be returned to the reaction cell chamber by a heat exchanger that transfers heat from the bus bars to the molten silver that is returned to the reaction cell chamber from the MHD converter by the EM pump.

In an embodiment, the side walls of the reaction cell chamber such as the four vertical sides of a cubic reaction cell chamber may be clad in a refractory metal such as W or Ta or covered by a refractory metal such as W or Ta liner. The metal may be resistant to alloy formation with gallium. The top of the reaction cell chamber may be clad or coated with an electrical insulator or comprise an electrically insulating liner. Exemplary cladding, coating, and liner materials are at least one of BN, quartz, titania, alumina, yttria, hafnia, zirconia, silicon carbide, or mixtures such as TiO₂-Yr₂O₃—Al₂O₃. The top liner may have a penetration for the pedestal 5c1 (FIG. 25). The top liner may prevent the top electrode 8 from electrically shorting to the top of the reaction cell chamber.

The temperature of at least one of the reaction chamber walls and the liner may be maintained within a range that optimizes the concentration of atomic hydrogen by at least one mechanism of increasing molecular hydrogen dissociation and decreasing atomic hydrogen recombination. The operating temperature of the dissociator may be above that at which the metal is catalytic for dissociating hydrogen and below the temperature at which substantial reaction with gallium occurs. The optimizing range may be maintained with at least one of a reaction chamber wall and liner cooling system such as one comprising a heat exchanger and chiller. In an embodiment, the dissociator may comprise a heater such as a resistive heater, an inductively coupled heater, or another heater known in the art. In an exemplary embodiment, the reaction cell chamber wall is maintained at sufficient temperature to cause hydrogen dissociation such as within the range of about 440±100° C. in the case of Ni or a stainless steel (SS) with a high Ni content such as SS 316.

In an embodiment, the reaction cell chamber further comprises a dissociator chamber that houses a hydrogen dissociator such as Pt, Pd, Ir, Re, or other dissociator metal on a support such as carbon, or ceramic beads such as Al₂O₃, silica, or zeolite beads, Raney Ni, or Ni, niobium, titanium, or other dissociator metal of the disclosure in a form to provide a high surface area such as powder, mat, weave, or cloth. The dissociator chamber may be connected to the reaction cell chamber by a gallium blocking channel such as the zigzag channel of the disclosure that inhibits the flow of gallium from the reaction cell chamber to the dissociator chamber while permitting gas exchange. Hydrogen gas may flow from the reaction cell chamber into the dissociation chamber wherein hydrogen molecules are dissociated to atoms, and the atomic hydrogen may flow back into the reaction cell chamber to serve as a reactant to form hydrinos. In other embodiments, the dissociation chamber may house the plasma dissociator or filament dissociator of the disclosure. In an embodiment, the recombiner or combustor that forms HOH catalyst in advance of flowing into the reaction cell chamber may further comprise the dissociator chamber. The gas input to the dissociator chamber may comprise at least one of hydrogen, oxygen, and a carrier gas. The carrier gas may serve to preserve at least one of atomic H and HOH as it flows into the reaction cell chamber. The carrier gas may comprise a noble gas such as argon. The dissociator may comprise a plurality of dissociation chambers that may be in series or parallel flow with at least one recombiner or combustor chamber. In an embodiment, hydrogen and oxygen, and optimally a carrier gas are flowed into a first chamber comprising a recombiner, combustor, or dissociation chamber wherein the hydrogen gas may be in excess of the oxygen gas. At least one of HOH, excess hydrogen, and carrier gas flow from the first chamber into a second chamber such as a dissociation chamber to form H atoms wherein H atoms and HOH are carried from the second chamber into the reaction cell chamber by the carrier gas. The carrier gas may be introduced into the second chamber independently of the flow into the first through a separate input line into the second chamber.

In another embodiment, the hydrogen source such as a H₂ tank may be connected to a manifold that may be connected to at least two mass flow controllers (MFC). The first MFC may supply H₂ gas to a second manifold that accepts the H₂ line and a noble gas line from a noble gas source such as an argon tank. The second manifold may output to a line connected to a dissociator such as a catalyst such as Pt/Al₂O₃, Pt/C, or another of the disclosure in a housing wherein the output of the dissociator may be a line to the reaction cell chamber. The second MFC may supply H₂ gas to a third manifold that accepts the H₂ line and an oxygen line from an oxygen source such as an O₂ tank. The third manifold may output to a line to a recombiner such as a catalyst such as Pt/Al₂O₃, Pt/C, or another of the disclosure in a housing wherein the output of the recombiner may be a line to the reaction cell chamber.

Alternatively, the second MFC may be connected to the second manifold supplied by the first MFC. In another embodiment, the first MFC may flow the hydrogen directly to the recombiner or to the recombiner and the second MFC. Argon may be supplied by a third MFC that receives gas from a supply such as an argon tank and outputs the argon directly into the reaction cell chamber.

In another embodiment, H₂ may flow from its supply such as a H₂ tank to a first MFC that outputs to a first manifold. O₂ may flow from its supply such as an O₂ tank to a second MFC that outputs to the first manifold. The first manifold may output to recombiner/dissociator that outputs to a second manifold. A noble gas such as argon may flow from its supply such as an argon tank to the second manifold that outputs to the reaction cell chamber. Other flow schemes are within the scope of the disclosure wherein the flows deliver the reactant gases in the possible ordered permutations by gas supplies, MFCs, manifolds, and connections known in the art.

In an embodiment, a hydrogen dissociator is added to the reaction cell chamber that has one or more characteristics of being less dense than gallium, not wetted by gallium, an does not form an alloy with gallium. The dissociator may be conductive. The catalyst may comprise a hydrogen dissociator such as nickel, niobium, tantalum, titanium, or a noble metal such Pt, Pd, Ru, Rh, Re, Ir, or Au. The hydrogen dissociator may be supported. The catalyst may comprise a support that is less dense than gallium such as carbon, Al₂O₃, silica, or zeolite. An exemplary catalyst that is less dense than gallium, not wetted by gallium, and does not form an alloy with gallium is Re/carbon catalyst such as 10% Re/C made by Riogen (https://shop.riogeninc.com/category.sc?categoryld=4). The hydrogen dissociator may float on the surface of the gallium. In an embodiment wherein the support is not wetted by gallium, the dissociator such as nickel that may form an alloy with gallium is protected from contacting the gallium by the non-wetting support such that the alloy does not form. An exemplary dissociator is 20% Ni/C made by Riogen.

In an embodiment, the dissociator such as one that may float or be suspended on molten metal may reduce gallium oxide than may also be on the molten gallium surface. An exemplary dissociator such as Re/C may comprise a hydrogen spillover catalyst wherein the atomic hydrogen may spill over onto the support such as carbon and then undergo a H reduction reaction of gallium oxide.

In an embodiment, the dissociator may comprise a noble metal such as Pt, Pd, Ir, or rhenium supported by a support such as carbon, alumina, or silica wherein the dissociator may comprise a liner or the dissociator may comprise a gas permeable vessel suspended in the reaction cell chamber that houses a dissociator such as one that resists gallium alloy formation such as rhenium supported on a support such as carbon that resists wetting by gallium. The gas permeable vessel may comprise a mesh, weave, foam or other open housing for the dissociator. The gas permeable vessel may comprise a metal that resists gallium alloy formation such as tungsten or tantalum, of a rhenium or ceramic-coated metal.

In an embodiment, the molten metal such as at least one of gallium, silver, silver copper alloy or another alloy such as one comprising gallium such as gallium silver alloy serves as the hydrogen dissociator. The characteristics of a metal that are favorable for hydrogen dissociation are a high exchange current density of a corresponding hydrogen electrode and a metal-H bond that is similar to that of the precious metals. Metals of the group of Ni, Co, Cu, Fe, and Ag have reasonable current densities but a have lower metal-H bond energies; whereas, the metals W, Mo, Nb, and Ta have higher metal-H bond energies. In an embodiment, the molten metal such as gallium or indium is alloyed with at least one other metal such as at least one of Ni, Co, Cu, Fe, Ag, W, Mo, Nb, Ta, and Zr to increase the dissociation rate. The rate may be increased by moving the M-H binding energy of the molten metal in the appropriate direction closer to that of precious metals. Exemplary alloys to increase the rate that the molten metal dissociates hydrogen are at least one of Ga—Nb, Ga—Ti, and an In—Ni—Nb system. Low melting point molten metals and metals that form alloys with the molten metal to increase the hydrogen dissociation rate are given by Datta et al. [Ravindra Datta, Yi Hua Ma, Pei-Shan Yen, Nicholas D. Deveau, Ilie Fishtik Ivan Mardilovich, “Supported Molten Metal Membranes for Hydrogen Separation”, Feb. 20, 2014, United States: N. p., 2013. Web. doi:10.2172/1123819] which is incorporated by reference especially section 2.

In an embodiment, the SunCell® comprises at least one of a source of hydrogen such as water or hydrogen gas such as a hydrogen tank, a means to control the flow from the source such as a hydrogen mass flow controller, a pressure regulator, a line such as a hydrogen gas line from the hydrogen source to at least one of the reservoir or reaction cell chamber below the molten metal level in the chamber, and a controller. A source of hydrogen or hydrogen gas may be introduced directly into the molten metal wherein the concentration or pressure may be greater than that achieved by introduction outside of the metal. The higher concentration or pressure may increase the solubility of hydrogen in the molten metal. The hydrogen may dissolve as atomic hydrogen wherein the molten metal such as gallium or Galinstan may serve as a dissociator. In another embodiment, the hydrogen gas line may comprise a hydrogen dissociator such as a noble metal on a support such as Pt on Al₂O₃ support. The atomic hydrogen may be released from the surface of the molten metal in the reaction cell chamber to support the hydrino reaction. The gas line may have an inlet from the hydrogen source that is at a higher elevation than the outlet into the molten metal to prevent the molten metal from back flowing into the mass flow controller. The hydrogen gas line may extend into the molten metal and may further comprise a hydrogen diffuser at the end to distribute the hydrogen gas. The line such as the hydrogen gas line may comprise a U section or trap. The line may enter the reaction cell chamber above the molten metal and comprise a section that bends below the molten metal surface. At least one of the hydrogen source such as a hydrogen tank, the regulator, and the mass flow controller may provide sufficient pressure of the source of hydrogen or hydrogen to overcome the head pressure of the molten metal at the outlet of the line such as a hydrogen gas line to permit the desired source of hydrogen or hydrogen gas flow.

In an embodiment, the SunCell® comprises a source of hydrogen such as a tank, a valve, a regulator, a pressure gauge, a vacuum pump, and a controller, and may further comprise at least one means to form atomic hydrogen from the source of hydrogen such as at least one of a hydrogen dissociator such as one of the disclosure such as Re/C or Pt/C and a source of plasma such as the hydrino reaction plasma, a high voltage power source that may be applied to the SunCell® electrodes to maintain a glow discharge plasma, an RF plasma source, a microwave plasma source, or another plasma source of the disclosure to maintain a hydrogen plasma in the reaction cell chamber. The source of hydrogen may supply pressurized hydrogen. The source of pressurized hydrogen may at least one of reversibly and intermittently pressurize the reaction cell chamber with hydrogen. The pressurized hydrogen may dissolve into the molten metal such as gallium. The means to form atomic hydrogen may increase the solubility of hydrogen in the molten metal. The reaction cell chamber hydrogen pressure may be in at least one range of about 0.01 atm to 1000 atm, 0.1 atm to 500 atm, and 0.1 atm to 100 atm. The hydrogen may be removed by evacuation after a dwell time that allows for absorption. The dwell time may be in at least one range of about 0.1 s to 60 minutes, 1 s to 30 minutes, and 1 s to 1 minute. The SunCell® may comprise a plurality of reaction cell chambers and a controller that may be at least one of intermittently supplied with atomic hydrogen and pressured and depressurized with hydrogen in a coordinated manner wherein each reaction cell chamber may be absorbing hydrogen while another is being pressurized or supplied atomic hydrogen, evacuated, or in operation maintaining a hydrino reaction. Exemplary systems and conditions for causing hydrogen to absorb into molten gallium are given by Carreon [M. L. Carreon, “Synergistic interactions of H₂ and N₂ with molten gallium in the presence of plasma”, Journal of Vacuum Science & Technology A, Vol. 36, Issue 2, (2018), 021303 pp. 1-8; https://doi.org/10.1116/1.5004540] which is herein incorporated by reference. In an exemplary embodiment, the SunCell® is operated at high hydrogen pressure such as 0.5 to 10 atm wherein the plasma displays pulsed behavior with much lower input power than with continuous plasma and ignition current. Then, the pressure is maintained at about 1 Torr to 5 Torr with 1500 sccm H₂+15 sccm O₂ flow through 1 g of Pt/Al₂O₃ at greater than 90° C. and then into the reaction cell chamber wherein high output power develops with additional H₂ outgassing from the gallium with increasing gallium temperature. The corresponding H₂ loading (gallium absorption) and unloading (H₂ off gassing from gallium) or may be repeated.

In an embodiment, the source of hydrogen or hydrogen gas may be injected directly into molten metal in a direction that propels the molten metal to the opposing electrode of a pair of electrodes wherein the molten metal bath serves as an electrode. The gas line may serve as an injector wherein the source of hydrogen or hydrogen injection such as H₂ gas injection may at least partially serve as a molten metal injector. An EM pump injector may serve as an additional molten metal injector of the ignition system comprising at least two electrodes and a source of electrical power.

The molten metal surface in the reaction cell chamber may be maintained in a reduced or clean metallic state by at least one method and system of the disclosure such as by one or more of (i) mechanical removal by the skimmer apparatus and (ii) oxide reduction by at least one of electrolysis and hydrogen reduction, and oxide removal by means such as a cycle of the disclosure such as the HCl cycle. For example, HCl may selectively remove Ga₂O₃ as volatile GaCl₃ (B.P.=201° C.); whereas, silver is retained since AgCl has a boiling point of 1547° C. In an embodiment wherein silver as well as other metals of a gallium alloy are not soluble in base such as NaOH, the other metal or its oxide may be precipitated and collected before the gallium is regenerated by electrolysis. In an embodiment wherein the other metal or its oxide is soluble, it may be electrolyzed with the gallium to regenerate the alloy. In an embodiment wherein gallium oxide is more stable than the oxide of the other metal of the alloy, only gallium need be regenerated from the gallium oxide by means such as given in the disclosure wherein any unoxidized alloying metal may be handled as part of the unoxidized gallium fraction of a mixture further comprising gallium oxide. Exemplary metals that alloy with gallium and have an oxide that reacts with gallium to form gallium oxide and the corresponding metal are Ni, Co, Cu, Fe, Ag, W, and Mo. In contrast, exemplary oxides of Nb, Ta, and Zr are more stable than gallium oxide.

In an embodiment, the SunCell® comprises a molecular hydrogen dissociator. The dissociator may be housed in the reaction cell chamber or in a separate chamber in gaseous communication with the reaction cell chamber. The separate housing may prevent the dissociator from failing due to being exposed to the molten metal such as gallium. The dissociator may comprise a dissociating material such as supported Pt such as Pt on alumina beads or another of the disclosure or known in the art. Alternatively, the dissociator may comprise a hot filament or plasma discharge source such as a glow discharge, microwave plasma, plasma torch, inductively or capacitively coupled RF discharge, dielectric barrier discharge, piezoelectric direct discharge, acoustic discharge, or another discharge cell of the disclosure or known in the art. The hot filament may be heated resistively by a power source that flows current through electrically isolated feed through the penetrate the reaction cell chamber wall and then through the filament.

In another embodiment, the ignition current may be increased to increase at least one of the hydrogen dissociation rate and the plasma ion-electron recombination rate. In an embodiment, the ignition waveform may comprise a DC offset such as one in the voltage range of about 1 V to 100 V with a superimposed AC voltage in the range of about 1 V to 100 V. The DC voltage may increase the AC voltage sufficiently to form a plasma in the hydrino reaction mixture, and the AC component may comprise a high current in the presence of plasma such as in a range of about 100 A to 100,000 A. The DC current with the AC modulation may cause the ignition current to be pulsed at the corresponding AC frequency such as one in at least one range of about 1 Hz to 1 MHz, 1 Hz to 1 kHz, and 1 Hz to 100 Hz. In an embodiment, the EM pumping is increased to decrease the resistance and increase the current and the stability of the ignition power.

In an embodiment, a high-pressure glow discharge may be maintained by means of a microhollow cathode discharge. The microhollow cathode discharge may be sustained between two closely spaced electrodes with openings of approximately 100 micron diameter. Exemplary direct current discharges may be maintained up to about atmospheric pressure. In an embodiment, large volume plasmas at high gas pressure may be maintained through superposition of individual glow discharges operating in parallel. The electron density in the plasma may be increased at a given current by adding a species such as a metal such as cesium having a low ionization potential. The electron density may also be increased by adding a species such as a filament material from which electrons are thermally emitted such as at least one of rhenium metal and other electron gun thermal electron emitters such as thoriated metals or cesium treated metals. In an embodiment, the plasma voltage is elevated such that each electron of the plasma current gives rise to multiple electrons by colliding with at least one gaseous species. The plasma current may be at least one of DC or AC.

In an embodiment, the atomic hydrogen concentration is increased by supplying a source of hydrogen that is easier to dissociate than H₂O or H₂. Exemplary sources are those having at least one of lower enthalpies and lower free energies of formation per H atom such as methane, a hydrocarbon, methanol, an alcohol, another organic molecule comprising H.

In an embodiment, the dissociator may comprise the electrode 8 such as the one shown in FIG. 25. The electrode 8 may comprise a dissociator capable of operating at high temperature such as one up to 3200° C. and may further comprise a material that is resistant to alloy formation with the molten metal such as gallium. Exemplary electrodes comprise at least one of W and Ta. In an embodiment, the bus bar 10 may comprise attached dissociators such as vane dissociators such as planar plates. The plates may be attached by fasting the face of an edge along the axis of the bus bar 10. The vanes may comprise a paddle wheel pattern. The vanes may be heated by conductive heat transfer from the bus bar 10 which may be heated by at least one of resistively by the ignition current and heated by the hydrino reaction. The dissociators such as vanes may comprise a refractory metal such as Hf, Ta, W, Nb, or Ti.

In an embodiment, the SunCell® comprises a source of about monochromatic light (e.g., light having a spectral bandwidth of less than 50 nm or less than 25 nm or less than 10 nm or less than 5 nm) and a window for the about monochromatic light. The light may be incident on hydrogen gas such as hydrogen gas in the reaction cell chamber. The fundamental vibration frequency of H₂ is 4161 cm⁻¹. At least one frequency of a potential plurality of frequencies may be about resonant with the vibrational energy of H₂. The about resonant irradiation may be absorbed by H₂ to cause selective H₂ bond dissociation. In another embodiment, the frequency of the light may be about resonant with at least one of (i) the vibrational energy of the OH bond of H₂O such as 3756 cm⁻¹ and others known by those skilled in the art such as those given by Lemus [R. Lemus, “Vibrational excitations in H₂O in the framework of a local model,” J. Mol. Spectrosc., Vol. 225, (2004), pp. 73-92] which is incorporated by reference, (ii) the vibrational energy of the hydrogen bond such between hydrogen bonded H₂O molecules, and (iii) the hydrogen bond energy between hydrogen bonded H₂O molecules wherein the absorption of the light causes H₂O dimers and other H₂O multimers to dissociate into nascent water molecules. In an embodiment, the hydrino reaction gas mixture may comprise an additional gas such as ammonia from a source that is capable of H-bonding with H₂O molecules to increase the concentration of nascent HOH by competing with water dimer H bonding. The nascent HOH may serve as the hydrino catalyst.

In an embodiment, the hydrino reaction creates at least one reaction signature from the group of power, thermal power, plasma, light, pressure, an electromagnetic pulse, and a shock wave. In an embodiment, the SunCell® comprises at least one sensor and at least one control system to monitor the reaction signature and control the reaction parameters such as reaction mixture composition and conditions such as pressure and temperature to control the hydrino reaction rate. The reaction mixture may comprise at least one of, or a source of H₂O, H₂, O₂, a noble gas such as argon, and GaX₃ (X=halide). In an exemplary embodiment, the intensity and the frequency of electromagnetic pulses (EMPs) are sensed, and the reaction parameters are controlled to increase the intensity and frequency of the EMPs to increase the reaction rate and vice versa. In another exemplary embodiment, at least one of shock wave frequencies, intensities, and propagation velocities such as those between two acoustic probes are sensed, and the reaction parameters are controlled to increase at least one of the shock wave frequencies, intensities, and propagation velocities to increase the reaction rate and vice versa.

The H₂O may react with the molten metal such as gallium to form H₂(g) and at least one of the corresponding oxide such as Ga₂O₃ and Ga₂O, oxyhydroxide such as GaO(OH), and hydroxide such as Ga(OH)₃. The gallium temperature may be controlled to control the reaction with H₂O. In an exemplary embodiment, the gallium temperature may be maintained below 100° C. to at least one of prevent the H₂O from reacting with gallium and cause the H₂O-gallium reaction to occur with a slow kinetics.

In another exemplary embodiment, the gallium temperature may be maintained above about 100° C. to cause the H₂O-gallium reaction to occur with a fast kinetics. The reaction of H₂O with gallium in the reaction cell chamber 5b31 may facilitate the formation of at least one hydrino reactant such as H or HOH catalyst. In an embodiment, water may be injected into the reaction cell chamber 5b31 and may react with gallium that may be maintained at a temperature over 100° C. to at least one of (i) form H₂ to serve as a source of H, (ii) cause H₂O dimers to form HOH monomers or nascent HOH to serve as the catalyst, and (iii) reduce the water vapor pressure.

In an embodiment, GaOOH may serve as a solid fuel hydrino reactant to form at least one of HOH catalyst and H to serve as reactants to form hydrinos. In an embodiment, at least one of oxide such as Ga₂O₃ or Ga₂O, hydroxide such as Ga(OH)₃, and oxyhydroxide such as such as GaOOH, AlOOH, or FeOOH may serve as a matrix to bind hydrino such as H₂(¼). In an embodiment, at least one of GaOOH and metal oxides such as those of stainless steel and stainless steel-gallium alloys are added to the reaction cell chamber to serve as getters for hydrinos. The getter may be heated to a high temperature such as one in the range of about 100° C. to 1200° C. to release molecular hydrino gas such as H₂(¼).

The gallium oxide formed in reaction cell chamber by the reaction of molten gallium with at least one of water and oxygen may be reduced to gallium metal. The reduction may be achieved by reacting gallium oxide with at least one of molecular and atomic hydrogen. The oxygen may be removed in a form such as O₂ or H₂O. The gallium oxide may be reduced in the reaction cell chamber 5b31, and the product of the Ga₂O₃ reduction reaction comprising oxygen may be removed from the reaction cell chamber. Alternatively, Ga₂O₃ may be removed from the reaction cell chamber and reduced externally with the gallium metal returned to reaction cell chamber 5b31. Gallium oxide (MP=1900° C.) may decompose at high temperature such as one above its melting point. The released oxygen may be evaluated from the reaction cell chamber by a means such as a vacuum pump. In an embodiment, the surface of the reservoir may be maintained above the decomposition temperature of gallium oxide. The gallium and gallium oxide surface on the molten metal may serve as the positive electrode to facilitate the maintenance of the high temperature. The surface area of the molten metal may be selected to concentrate the plasma sufficiently to achieve the desired surface temperature to cause the decomposition of gallium oxide. In an embodiment, the surface area may be adjustable. The means of adjustment may comprise movable cell walls. In an embodiment, the cell pressure may be maintained low such as in the range of 0.01 Torr to 50 Torr to allow the high-energy light produced by the hydrino reaction to decompose the gallium oxide. In an embodiment, Ga₂O₃ reacts with gallium to form Ga₂O that may thermally decompose. The reaction temperature may be about 700° C., so the gallium surface temperature may be maintained at a temperature greater than 700° C. Additionally, the temperature of at least one of the reaction cell chamber, reservoir, and pedestal where Ga₂O may be present may be maintained above 500° C. since Ga₂O may begin to decompose at 500° C.

A reductant such as hydrogen gas may be added to the reaction cell chamber to facilitate at least one of reduction and decomposition of gallium oxide such as at least one of Ga₂O₃ and Ga₂O. The hydrogen reduction reaction temperature may be about 700° C., so the gallium surface temperature may be maintained at a temperature greater than 700° C. In another embodiment, the temperature of at least one of the reaction cell chamber, reservoir, and pedestal where Ga₂O may be present may be maintained below about 600° C. since Ga₂O may undergo hydrogen reduction below about 600° C. versus undergoing the reaction of Ga₂O to Ga+Ga₂O₃. In an embodiment, at least one of the bus bar 10 and electrode 8 may comprise a dissociator such as Ta or W. The pedestal 2cl (FIG. 25) may be shortened to partially expose the bus bar to facilitate the production of atomic hydrogen to reduced gallium oxide. In an embodiment, the bus bar 10 may comprise attached dissociators such as vane dissociators such as planar plates. The plates may be attached by fasting the face of an edge along the axis of the bus bar 10. The vanes may comprise a paddle wheel pattern. The vanes may be heated by conductive heat transfer from the bus bar 10 which may be heated by at least one of resistively by the ignition current and heated by the hydrino reaction. The dissociators such as vanes may comprise a refractory metal such as Hf, Ta, W, Nb, or Ti. A noble gas may be added in addition to hydrogen. The mole percentages of noble gas and hydrogen may be any desired ratio. An exemplary gas mixture comprises argon in the range of about 80 to 99 mole percent and hydrogen in the range of about 1 to 20 mole percent. The pressure of the reaction cell chamber may be maintained low to facilitate the decomposition of gallium oxide. In another embodiment, the hydrogen pressure may be maintained high to favor the hydrogen reduction of gallium oxide. Another species, compound, element, or composition of matter such as a base such a NaOH may be added to the reaction cell chamber to form a product with gallium oxide such as sodium gallate to increase the rate of at least one of thermal decomposition and reduction of gallium oxide.

In another embodiment, the reaction mixture in the reaction cell chamber comprises a molten metal additive such as a material or compound such as an inorganic compound such as an alkali halide such as NaCl to stabilize gallium against oxidation. In another embodiment, the molten metal additive comprises a metal such as one that forms an alloy with the molten metal to stabilize it against oxidation. In an exemplary embodiment comprising the molten metal gallium, silver is added to the gallium to enhance at least one of the thermal decomposition and thermal, hydrogen, and electrolytic reduction of the gallium oxide film. In an exemplary embodiment about 5.6 wt % silver is added to gallium to form an alloy that melts at about 30-40° C. Gallium-Ag may inhibit oxidation of gallium.

In an embodiment, a source of halide such as the additive such as HCl, a metal halide, a Group 13, 14, 15, or 16 halide, or a halogen gas is added to the reaction mixture to form a reaction product with gallium oxide such as a volatile product that may be removed from the reaction cell chamber by volatilization and condensation. The product of the additive may comprise a gallium halide such as GaCl₃ (MP=77.9° C., BP=201° C.). The gallium halide may be volatile at the SunCell® operating temperature and pressure. At least one of a volatile product such as gallium halide may be flowed into a condenser and condensed. The gallium metal may be regenerated by mean such as electrolysis. In an embodiment, the additive forms at least one product with gallium oxide that may be removed from the reaction cell chamber by means such as volatilization and by the means of the disclosure to remove gallium oxide such as ones comprising a skimmer. The reactions of the solid fuels of the disclosure and others known in the art further comprise reactions to remove the oxide inventory of the reaction cell chamber formed by reaction of gallium with at least one of added water and oxygen.

In an exemplary embodiment, the additive that comprises a source of halide is ZnCl₂ that reacts with injected water to form anhydrous HCl and zinc hydroxide or oxide. At least one of HCl and ZnCl₂ may react with Ga₂O₃ to form GaCl₃ (MP=77.9° C., BP=201° C.). The zinc products may be selectively removed from the cells by the means of the disclosure to remove gallium oxide. GaCl₃ may be exhausted from the cell and condensed. The GaCl₃ may then be reacted with water to form at least one of HCl and Ga(OH)Cl, GaO(OH), Ga(OH)₃, and Ga₂O₃. The HCl may be separated from the water by distillation or evaporation, and the product comprising gallium and oxygen may be electrolyzed to gallium metal in basic aqueous solution such as in an NaOH electrolyte. The gallium metal may be recycled. HCl may be reacted with at least one of zinc oxide and zinc hydroxide to form zinc chloride that may be recycled.

In another exemplary embodiment, FeCl₂ is the additive that reacts with injected water and O₂ to form HCl and Fe₂O₃. At least one of HCl and FeCl₂ may react with Ga₂O₃ to form GaCl₃. Fe₂O₃ may be selectively removed from the cells by the means of the disclosure to remove gallium oxide. GaCl₃ may be exhausted from the cell and condensed. The GaCl₃ may then be reacted with water to form at least one of HCl and Ga(OH)Cl, GaO(OH), Ga(OH)₃, and Ga₂O₃. The HCl may be separated from the water by distillation or evaporation, and the product comprising gallium and oxygen may be electrolyzed to gallium metal in basic aqueous solution such as in an NaOH electrolyte. The gallium metal may be recycled. HCl may be reacted with Fe₂O₃ to form FeCl₂ that may be recycled.

In another exemplary embodiment, sulfuryl chloride (SO₂Cl₂) is the additive that reacts with injected water to form HCl and SO₃. At least one of HCl and SO₂Cl₂ may react with Ga₂O₃ to form GaCl₃. Both GaCl₃ and SO₃ may be exhausted from the cell and selectivley condensed. Gallium may be regenerated from the GaCl₃ by electrolysis of GaCl₃ melt to Ga and Cl₂. SO₂Cl₂ may be regenerated from SO₃ by decomposition of SO₃ to SO₂ followed by reaction of SO₂ with Cl₂ to SO₂Cl₂. Ga and SO₂Cl₂ may also be regenerated by other methods known in the art.

In another exemplary embodiment, the halide additive may comprise phosphorous rather than sulfur wherein PX₃ or PX₅ (X is halide) such as PCl₃ or PCl₅ reacts with injected water to form HCl and PO₂. At least one of HCl and PCl₃ or PCl₅ reacts with Ga₂O₃ to form GaCl₃. Both GaCl₃ and PO₂ may be exhausted from the cell and selectivley condensed. Gallium may be regenerated from the GaCl₃ by electrolysis of GaCl₃ melt to Ga and Cl₂. PCl₃ or PCl₅ may be regenerated from PO₂ by reduction of PO₂ followed by reaction of P₄ with Cl₂ to PCl₃ or PCl₅.

In the case of HCl addition, the HCl is selectively reacted with the gallium oxide film. The SunCell® may comprise a means such as a corrosion resistant directional nozzle such as an alumina nozzle to selectively apply the HCl to the gallium oxide film. The molten metal injector may be terminated during the HCl reaction with the gallium oxide film and any coat on gallium to minimize the reaction of gallium with HCl. The HCl may react with gallium oxide to form volatile GaCl₃ and H₂O. The GaCl₃ may be exhausted from the reaction cell chamber. The H₂O may be recycled in situ. Any H₂O that is exhausted may be replaced by a source of H₂O such as liquid water or H₂ and O₂ gases from a source of H₂ gas and a source of O₂ gas. The gallium halide product may be condensed and may be dissolved in water to form at least one of HCl, Ga(OH)Cl, GaO(OH), Ga(OH)₃, and Ga₂O₃. HCl may be further produced through electrolysis at the anode. In an embodiment, HCl can be formed at the anode by water electrolysis of a solution comprising aqueous chloride ion by using an oxygen evolution catalyst such as Mn_{0.84}Mo_{0.16}O_{2.23} oxygen evolution electrode during water electrolysis as described by Lin et al. [“Direct anodic hydrochloric acid and cathodic caustic production during water electrolysis”, Scientific reports, (2016); 6: 20494, doi: 10.1038/srep20494] which is incorporated by reference. The HCl may be removed as a gas. Gallium metal may be produced at the cathode of an electrolysis cell by electrolysis of at least one of Ga(OH)Cl, GaO(OH), Ga(OH)₃, and Ga₂O₃ wherein the electrolyte may comprise NaOH. The regenerated products such as Ga, metal halide, and HCl may be recycled.

In an embodiment, the source of halide comprises a compound that comprises a halide and a species that at least one of comprises a source of H⁺ and reacts with gallium oxide to form gallium halide which may vaporize and a gas at the operating temperature of the reaction cell chamber. The source of halide may comprise an ammonium halide salt such as one formed by reacting an ammonium compound such as an amine or ammonia with a hydrogen halide such as HCl. In an embodiment, a method to remove Ga₂O₃ as GaCl₃, regenerate Ga, and recycle the Ga comprises a NH₄Cl cycle. In an exemplary embodiment, ammonia may be reacted with HCl to form NH₄Cl. The gallium oxide may react with the source of halide such as NH₄Cl to form gallium halide such as GaCl₃ that may be removed from the reaction cell chamber by vaporization. The gallium halide such as GaCl₃ may be selectively condensed in a condenser such as one in a line to a vacuum pump such as a cold trap. The condensed GaCl₃ may be converted to gallium by direct electrolysis of the melt according to the exemplary reactions:

2GalCl₃(melt) electrolysis to 2Ga↓(cathode)+3Cl₂↑(anode)

The chlorine gas may be reacted with H₂ using UV light irradiation or by reaction of Cl₂ and H₂ in an HCl oven:

Cl₂+H₂ to 2HCl

Ammonia and HCl may be reacted to form ammonium chloride

NH₃+HCl to NH₄Cl

In another embodiment, HCl rather than NH₄Cl may be added directly to the gallium oxide on the surface of the gallium in the reaction cell chamber. The site of delivery of the NH₄Cl may be maintained in a temperature range of greater than the boiling point of GaCl₃ (BP=201° C. at STP) and below the decomposition temperature of NHCl (338° C.). Alternatively, the reaction cell chamber may be maintained at a temperature greater than the decomposition temperature of NH₄Cl wherein released HCl may react with the gallium oxide

An alternative recycle pathway for HCl addition to form GaCl₃ is to add GaCl₃ to water to release HCl according to the exemplary reaction:

GaCl₃+2H₂O(vapor)=GaO(OH)+3HCl(350° C.).

The HCl gas may be evolved and recycled, and the gallium oxyhydroxide may be electrolyzed in aqueous base such as NaOH solution. In an embodiment, HCl can be formed at the anode by water electrolysis of a solution comprising aqueous chloride ion by using an oxygen evolution catalyst such as Mn_{0.84}Mo_{0.16}O_{2.23} oxygen evolution electrode during water electrolysis as described by Lin et al. [“Direct anodic hydrochloric acid and cathodic caustic production during water electrolysis”, Scientific reports, (2016); 6: 20494, doi: 10.1038/srep20494] which is incorporated by reference.

Alternatively, at least one of the gallium halide such as GaCl₃ and ammonia formed by the reaction of gallium oxide with ammonium chloride may be reacted with water to form gallium oxyhydroxide or gallium hydroxide by the exemplary reactions:

Ga₂O₃+6NH₄Cl=2GaCl₃+6NH₃+3H₂O(250° C.)

GaCl₃+3(NH₃.H₂O)[diluted]=Ga(OH)₃↓+3NH₄Cl

The Ga(OH)₃ precipitate may be separated from the mixture of gallium hydroxide and ammonium chloride by means such as decanting the aqueous liquid or filtering and collecting the solid. The isolated gallium hydroxide may be dissolved an aqueous base such as an aqueous NaOH solution and electrolyzed to release oxygen at the anode and deposit gallium metal at the cathode. The gallium metal may be recycled. Exemplary reactions are

Ga(OH)₃+NaOH(conc.,hot)=Na[Ga(OH)₄]

Na[Ga(OH)₄] electrolysis to Ga(cathode)+O₂(anode)

The NH₄Cl remaining following separation of the gallium hydroxide may be concentrated by evaporation, allowed to crystalize under suitable condition such as a lowered temperature such as one near 0° C., and collected by filtration, or the NH₄Cl may be collected following evaporation of the water solvent. The NH₄Cl nay be recycled. The NH₄Cl may be added to the reaction cell chamber under conditions of temperature and injection velocity to avoid its decomposition at about 337.6° C. before it contacts the gallium oxide. The NH₄Cl cycle of these reactions mas be performed as a continuous or batch process.

HCl from a source of HCl may be anhydrous. HCl may remain anhydrous following delivery into the reaction cell chamber wherein any water inventory in the reaction cell chamber may be gaseous water. In an embodiment, the SunCell® comprises components that are resistant to at least one of the formation of an alloy with gallium and reaction with HCl, hydrochloric acid, or NH₄Cl. In an exemplary embodiment, the inverted electrode may comprise tantalum, and the reaction cell chamber may comprise at least one of stainless steel, nickel, nickel alloy, zirconium, tantalum, and nickel molybdenum alloy, such as B-2 and B-3®. Alternatively, the reaction cell chamber may comprise quartz, a ceramic liner, or be coated with a ceramic coating such as alumina, Mullite, or silica. In an embodiment, at least one of a HCl gas tank, valve, line, pressure regulator, and reaction cell chamber may be coated with an HCl corrosion resistant coating known in the art such as SilcoNert®. An exemplary HCl resistant metal is Monel metal such as Monel 400.

In an embodiment, the SunCell® comprises a variable heat transfer jacket. The variable insulation may be adjusted to permit the reaction cell chamber 5b31 to be operated at a desired temperature such as one that permits one or more of (i) the decomposition of any gallium oxide such as Ga₂O₃ or Ga₂O that may form, (ii) the conversion of Ga₂O₃ to Ga₂O by reaction with gallium, and (iii) the reduction of gallium oxide by hydrogen. The SunCell® comprising the variable heat transfer jacket may be cooled by a heat exchanger such as a water bath into which the SunCell® is immersed. The heat variable heat transfer jacket may comprise at least one chamber between the heat exchanger and the outside of the reaction cell chamber that may be capable of vacuum. The variable heat transfer jacket may comprise at a pumping system to reversibly and controllably add a heat transfer coolant such as a gas or fluid one to the chamber. The pumping system may comprise a coolant source such a as a tank, a pump, and a controller. The pumping system may increase or decrease the amount of coolant in response to the reaction cell chamber temperature to control it to be within a desired range by controlling the corresponding heat transfer. The coolant may comprise at least one of a noble gas such as helium, a molten salt such as one of the disclosure, and a molten metal such as gallium.

In an alternative embodiment, the SunCell® comprises a coolant flow heat exchanger comprising the pumping system whereby the reaction cell chamber is cooled by a flowing coolant wherein the flow rate may be varied to control the reaction cell chamber to operate within a desired temperature range. The heat exchanger may comprise plates with channels such as microchannel plates. In an embodiment, the SunCell® comprises a cell comprising the reaction cell chamber 531, reservoir 5c, pedestal 5c1, and all components in contact with the hydrino reaction plasma wherein one or more components may comprise a cell zone. In an embodiment, the heat exchanger such as one comprising a flowing coolant may comprise a plurality of heat exchangers organized in cell zones to maintain the corresponding cell zone at an independent desired temperature.

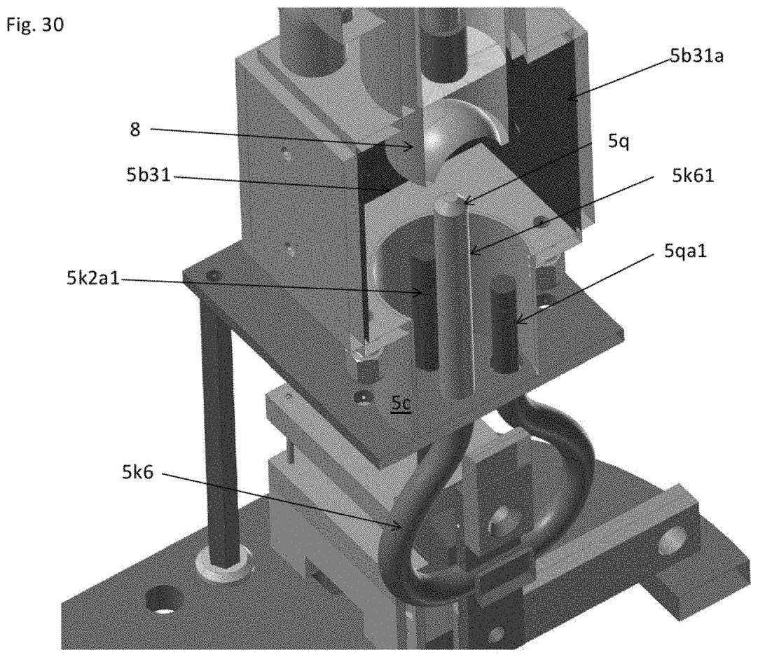

In an embodiment such as one shown in FIG. 30, the SunCell® comprises thermal insulation or a liner 5b31a fastened on the inside of the reaction cell chamber 5b31 at the molten gallium level to prevent the hot gallium from directly contacting the chamber wall. The thermal insulation may comprise at least one of a thermal insulator, an electrical insulator, and a material that is resistant to wetting by the molten metal such as gallium. The insulation may at least one of allow the surface temperature of the gallium to increase and reduce the formation of localized hot spots on the wall of the reaction cell chamber that may melt the wall. In addition, a hydrogen dissociator such as one of the disclosure may be clad on the surface of the liner. In another embodiment, at least one of the wall thickness is increased and heat diffusers such a copper blocks are clad on the external surface of the wall to spread the thermal power within the wall to prevent localized wall melting. The higher temperature may favor at least one of (i) thermal decomposition of Ga₂O₃ or Ga₂O, (ii) reaction of Ga with Ga₂O₃ to form Ga₂O, (iii) hydrogen reduction of at least one of Ga₂O₃ and Ga₂O, and at least one of vaporization and sublimation due to the volatility of Ga₂O. The thermal insulation may comprise a ceramic such as BN, SiC, carbon, Mullite, quartz, fused silica, alumina, zirconia, hafnia, others of the disclosure, and ones known to those skilled in the art. The thickness of the insulation may be selected to achieve a desired area of the molten metal and gallium oxide surface coating wherein a smaller area may increase temperature by concentration of the hydrino reaction plasma. Since a smaller area may reduce the electron-ion recombination rate, the area may be optimized to favor elimination of the gallium oxide film while optimizing the hydrino reaction power. In an exemplary embodiment comprising a rectangular reaction cell chamber, rectangular BN blocks are bolted onto to threaded studs that are welded to the inside walls of the reaction cell chamber at the level of the surface of the molten gallium. The BN blocks form a continuous raised surface at this position on the inside of the reaction cell chamber.

In an embodiment, the hydrino reaction plasma is maintained in about a symmetrical distribution within the reaction cell chamber. The symmetrical distribution may avoid the formation of a localized hot spot on the reaction cell chamber wall. The symmetrical plasma distribution may be achieved by straight alignment of the injected molten metal along the central symmetry axis of reaction cell chamber having an element of cylindrically symmetry. The corresponding ignition current alignment may result in a desired pinch-type magnetic field without kinks that cause a plasma instability due to an unbalanced Lorentz force.

The plasma may preferentially contact the reaction chamber wall over the molten gallium surface due to an oxide coat on the gallium. The location of the wall may be determined by the thickness of the oxide coat that increases the electrical resistance. In an embodiment, the oxide coat on the walls is removed by at least one means such as mechanical abrasion such as bead blasting and wire brushing and by chemical etching such as weak acid etching. In another embodiment, the reservoir may comprise at least one electrical lead such as one that penetrates a baseplate of the bottom on the reservoir and extends above the molten metal level. The electrical lead may be connected to the source of ignition current. The electrical lead may comprise an alternative path for the ignition current that comprises a second current in addition to the ignition current to the injector. The second current may maintain the symmetrical plasma distribution in the reaction cell chamber by providing at least one of the second electrical path and by providing a magnetic field generated by the second current. In an embodiment, the reaction cell chamber comprises at least one current connection that may have a corresponding switch the connects the reaction cell chamber to at least one of the ground and the ignition power supply. The switch may be closed to cause the ignition current to at least partially flow through the current connection wherein the current flows through the reaction cell chamber wall where it is connected. The current flow may cause the plasma to be directed at least partially to the region of current flow. The switches of the at the least one current connection may be controlled by a controller to maintain the symmetrical plasma distribution. The controller may receive input from at least one plasma distribution sensor such as at least one thermocouple. In another embodiment, the reaction cell chamber may comprise additional reaction mixture inlet ports to balance fuel injection and achieve symmetrical plasma distribution in the reaction cell chamber.

In an embodiment (FIG. 25 and FIG. 30), the SunCell® comprises a bus bar 5k2al through a baseplate of the EM pump at the bottom of the reservoir 5c. The bus bar may be connected to the ignition current power supply. The bus bar may extend above the molten metal level. The bus bar may serve as the positive electrode in addition to the molten metal such as gallium. The molten metal may heat sink the bus bar to cool it. The bus bar may comprise a refractory metal that does not form an alloy with the molten metal such as W or Ta in the case that the molten metal comprises gallium. The bus bar such as a W rod protruding from the gallium surface may concentrate the plasma at the gallium surface. The injector nozzle such as one comprising W may be submerged in the molten metal in the reservoir to protect it from thermal damage.

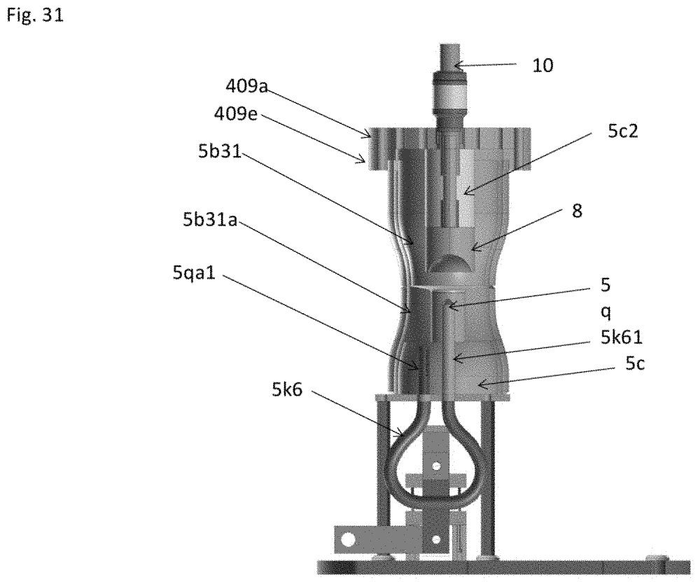

In an embodiment (FIG. 25), such as one wherein the molten metal serves as an electrode, the cross-sectional area that serves as the molten electrode may be minimized to increase the current density. The molten metal electrode may comprise the injector electrode. The injection nozzle may be submerged. The molten metal electrode may be positive polarity. The area of the molten metal electrode may be about the area of the counter electrode. The area of the molten metal surface may be minimized to serve as an electrode with high current density. The area may be in at least one range of about 1 cm² to 100 cm², 1 cm² to 50 cm², and 1 cm² to 20 cm². At least one of the reaction cell chamber and reservoir may be tapered to a smaller cross section area at the molten metal level. At least a portion of at least one of the reaction cell chamber and the reservoir may comprise a refractory material such as tungsten, tantalum, or a ceramic such as BN at the level of the molten metal. In an exemplary embodiment, the area of at least one of the reaction cell chamber and reservoir at the molten metal level may be minimized to serve as the positive electrode with high current density. In an exemplary embodiment, the reaction cell chamber may be cylindrical and may further comprise a reducer, conical section, or transition to the reservoir wherein the molten metal such as gallium fills the reservoir to a level such that the gallium cross sectional area at the corresponding molten metal surface is small to concentrate the current and increase the current density. In an exemplary embodiment (FIG. 31), at least one of the reaction cell chamber and the reservoir may comprise an hourglass shape or a hyperboloid of one sheet wherein the molten metal level is at about the level of the smallest cross-sectional area. This area may comprise a refectory material or comprise a liner 5b31a of a refractory material such as carbon, a refractory metal such as W or Ta, or a ceramic such as BN, SiC, or quartz. In exemplary embodiment, the reaction cell chamber may comprise stainless steel such as 347 SS and liner may comprise W or BN.

In an embodiment, the SunCell® comprises a reversible insulation such as a plurality of thermally insulating particles such as beads such as alumina beads and an insulator container or housing wherein the particles are in the container that is circumferential to the SunCell® component to be thermally insulated such as at least one of the reaction cell chamber and the reservoir. The container may comprise inlet and outlet ports for filling and emptying the bead container, respectively, and may further comprise a means to transport the beads in and out of the container such as a mechanical conveyor such as an auger. In an embodiment, the beads may flow out of the container by gravity.

In an embodiment, at least one of the ignition current and voltage may be intermittently increased sufficiently for a sufficient duration to cause at least one of (i) the decomposition of any gallium oxide such as Ga₂O₃ or Ga₂O that may form in the reaction cell chamber or reservoir, (ii) the conversion of Ga₂O₃ to Ga₂O by reaction with gallium, and (iii) the reduction of gallium oxide by hydrogen. The gallium oxide film may comprise a mixture a gallium metal and gallium oxide particles wherein the mixture film forms because gallium oxide is wetted by gallium metal and gallium oxide is less dense than gallium. Since gallium oxide is an electrical insulator and gallium metal is an electrical conductor, the electrical resistance of the film increases with increasing gallium oxide content wherein the ignition current is forced through gallium channels of decreasing area and increasing length. The intermittent pulsed ignition current may selectively heat the gallium of these high electrical resistance metallic gallium channels to cause the gallium and mixed-in gallium oxide to heat. The intermittent increase of at least one of the ignition current and voltage may comprise a pulse of applied power. The duty cycle of the intermittent pulse of ignition power may be in a range of at least one of about 1% to 99%, 1% to 75%, 1% to 50%, 1% to 25%, and 1% to 10%. The voltage may be increased to at least one of about 1000 V, 100 V, 75 V, and 50V, or by about 10 times, 5 times, 2 times, 1.5 times, or 1.25 times the pre-increase voltage. The current may be increased to at least one of about 100 kA V, 50 kA, 10 kA, 5 kA, 1 kA, and 500 A, or by about 10 times, 5 times, 2 times, 1.5 times, or 1.25 times the pre-increase amperage. In an embodiment, the hydrino reaction is favored at the positive electrode of the ignition pair of electrodes such that the heating by the hydrino reaction selectively occurs at the positive electrode. The gallium comprising a gallium oxide film may be biased positively to selectively heat the gallium oxide film by the hydrino reaction. In an embodiment, the cathode and anode of the SunCell® comprise a pedestal electrode such as an inverted pedestal 5c2 and an opposing injector nozzle 5q such as the ones shown in FIG. 25. The inverted electrode such as one comprising tungsten may comprise the positive electrode that is selectively heated by the hydrino reaction to a very elevated temperature such as in the temperature range of about 1000° C. to 3000° C., and the heated electrode heats the gallium oxide film. The polarity of the electrodes may be alternated by an AC ignition source of electrical power to avoid overheating the inverted electrode and thereby prevent it from melting. The heating of the film by the inverted electrode may be increased by decreasing its separation distance from the gallium surface. The reaction cell chamber may comprise a ceramic liner 5b31a such as a BN, quartz, or fused silica liner to focus the hydrino reaction plasma on the electrodes. The heating may facilitate at least one of (i) the decomposition of any gallium oxide such as Ga₂O₃ or Ga₂O that may form in the reaction cell chamber or reservoir, (ii) the conversion of Ga₂O₃ to Ga₂O by reaction with gallium, and (iii) the reduction of gallium oxide by hydrogen.

In an embodiment, the SunCell® comprises a gallium regeneration system to convert gallium oxide to gallium comprising an electrolysis system comprising a cathode, an anode, a power supply such as a DC power supply, and an electrolyte comprising gallium oxide electrolyzes gallium oxide or a species comprising gallium oxide such as sodium gallate to gallium metal directly at the surface of at least one of the molten metal of the reservoir and the reaction cell chamber. The electrolyte may comprise molten gallium oxide wherein the ions comprise gallium and oxide ions. The electrolyte may comprise an oxide such as one that is at least one of (i) stable under SunCell® operating conditions such as alumina or an alkali or alkaline earth oxide, (ii) forms a mixture with a lower melting point than gallium oxide alone, and (iii) is more thermodynamically stable than gallium oxide such that oxide and gallium ions of the melted film may be selectively electrolyzed to gallium metal and oxygen gas wherein the molten salt mixture comprises the electrolyte. The electrolyte may comprise an ion source such as a base such as NaOH such as molten NaOH, Na₂O, LiOH, or Li₂O, a metal halide such as an alkali metal halide such as NaF or CsF electrolyte on the surface of the gallium, or another stable electrolyte known in the art. The electrolyte may comprise a mixture of salts that lower the melting point of gallium oxide as a mixture. The electrolyte may comprise gallium oxide dissolved in a salt or salt mixture such as one comprising at least one of gallium, aluminum, and a halide such as NaF, LiF, KF, CsF, NaI (MP=661° C.), a halide salt mixture, AlF₃, cryolite (Na₃AlF₆), or Na₃GaF₆. The solvent salt such as an alkali halide such as NaI may be thermodynamically stable to the gallium and H₂O of the reaction cell mixture. The electrolyte that dissolves Ga₂O₃ and serves as the electrolyte to electrolytically reduce gallium oxide to gallium may comprise at least one of an oxide, hydroxide, halide, and a mixture such as NaOH—NaCl. The electrolyte may comprise a salt or salt mixture such a as eutectic salt mixture that dissolves gallium oxide and is stable to gallium oxide. Exemplary eutectic mixtures are (i) the ternary eutectic metal fluoride mixture LiF—NaF—KF such as FLiNaK in the ratios 46.5-11.5-42 mol % that has a melting point of 454° C. and a boiling point of 1570° C., (ii) the ternary eutectic metal chloride mixture LiCl—KCl—CsCl in the ratios 57.5-13.3-29.2 mol % that has a melting point of 265° C., (iii) CsI—NaI in a molar ratio of NaI/(CsI+NaI)=0.484 that has a melting point of 420° C., (iv) KI—LiI in a molar ratio of LiI/(KI+LiI)=0.635 that has a melting point of 283° C., and (v) CsI—LiI in a molar ratio of LiI/(CsI+LiI)=0.657 that has a melting point of 209° C. Further exemplary electrolyte salts comprising fluoride ion are 2LiF—BeF2, LiF-BeF2-ZrF4 (64.5-30.5-5), NaF—BeF2 (57-43), LiF—NaF—BeF2 (31-31-38), LiF—ZrF4 (51-49), NaF—ZrF4 (59.5-40.5), LiF—NaF—ZrF4 (26-37-37), KF—ZrF4 (58-42), RbF—ZrF4 (58-42), LiF—KF (50-50), LiF—RbF (44-56), LiF—NaF—KF (46.5-11.5-42), and LiF—NaF—RbF (42-6-52). In an embodiment, the ratio of the moles of electrolyte to moles of gallium oxide are in at least one range of about 0.1 to 1000, 0.5 to 100, 0.5 to 50, 0.75 to 10, 0.75 to 5, and 0.75 to 2. In an exemplary embodiment wherein NaI is the electrolyte and the steady state moles of Ga₂O₃ corresponds to 1 ml of H₂O or oxygen equivalent that produces 3.44 g Ga₂O₃ (MW=188), a ratio of moles of NaI (MW=150) electrolyte to moles of Ga₂O₃ of 1 corresponds to 2.74 g of NaI added to the reaction cell chamber. The reduction of each 1 ml of H₂O or oxygen equivalent requires an electrolytic current provided by the ignition current of 180 A.

In the case that the anion of the electrolyte such as halide ion such as I⁻ is oxidized at the electrolysis anode over O²⁻, the anion may be selected to be more stable to oxidation than O²⁻. CsF (M.P.=682° C.) is an exemplary salt having F⁻ as the stable halide anion. In an embodiment, the reaction cell chamber may comprise at least one of molecular and atomic hydrogen wherein O²⁻ electrolytic oxidation at the anode is made more thermodynamically favorable due to the reaction of the oxygen product reacting with at least one of molecular and atomic hydrogen to form water. The anode reaction may comprise O²⁻+2H to H₂O+2e⁻. In the case that the anion of the electrolyte such as halide ion such as I⁻ is oxidized or reacts at elevated temperature, at least one of the reaction cell chamber may be operated below the anion reaction or decomposition temperature such as less than about 700° C. in the case of iodide, and the anion may be selected to be stable at the elevated temperature. F⁻ is an exemplary more stable halide anion. In an embodiment wherein the anion is oxidized by means such as electrolysis by the ignition current as well as thermally, the resulting gas, liquid or solid may be recycled by a halogen recycler. The halogen recycler may comprise a condenser. The condenser may be in line with the vacuum line of the vacuum system. The vacuum system that may further comprise a particle flow restrictor to the vacuum line inlet such as a set of baffles to allow gas flow while blocking particle flow. In an exemplary embodiment, the halide ion is I⁻ that is oxidized to I₂ (M.P.=113.7°, B.P.=184.3° C.) that condenses in the condenser and flows back into the reaction cell chamber by gravity, or condensed iodine is actively transported to contact the molten metal by a transporter such as a conveyor for solid iodine or a pump for liquid iodine. In an exemplary embodiment, the reaction cell chamber may be periodically allowed to cool so that the iodine may flow back as a liquid to contract the molten metal and react with sodium to regenerate NaI.

The SunCell® may comprise components such as the reaction cell chamber that is resistant to corrosion by the electrolyte such as one comprising at least one alkali metal halide such as FLiNaK. The reaction cell chamber may comprise a liner 5b31a such as a ceramic liner such as a BN, quartz, fused silica, MgO, HfO₂, ZrO₂, Al₂O₃. The reaction cell chamber may comprise a corrosion resistant metal such as Monel metal such as Monel 400, a corrosion resistant stainless steel such as Hastelloy N or Inconel, carbon composites, molybdenum alloys such as titanium-zirconium-molybdenum alloy (TZM) composed of 0.5% titanium and 0.08% of zirconium with molybdenum being the rest, carbides, and refractory metal based or oxide dispersion strengthened alloys (ODS) alloys. In an embodiment, the molten metal such as gallium wets the walls of the reaction cell chamber which in conjunction with the lower density of the electrolyte prevents contact of the electrolyte with that wall to protect the wall from corrosion by the electrolyte.

The SunCell® may comprise a trap for halogen or hydrogen halogen gas exhausted from the reaction cell chamber or gallium regeneration system. Exemplary trap comprising a base such as NaOH may react with volatile HF to form NaF that is trapped. The trap may be connected post vacuum pump. In an embodiment, gallium oxide may be converted into another oxide that is electrolyzed such as the conversion of Ga₂O₃ to Al₂O₃ that is electrolyzed to Al wherein the electrolyte may comprise cryolite. Exemplary migrating ions may comprise at least one of oxide, peroxide, superoxide, OH⁻, alkali ion such as Na⁺, hydroxide complex such as Ga(OH)₄⁻, and an oxyhalide complex such as GaF(OH)₃⁻ or GaFO(OH)⁻.

In an embodiment, the cathode wherein gallium metal is electrolytically formed comprises the molten metal surface. The electrolyte may comprise at least one of (i) gallium oxide, (ii) gallium oxyhydroxide, (iii) gallium hydroxide, (iv) at least one of gallium oxide, gallium oxyhydroxide, and gallium hydroxide and at least one added ion source such as NaOH, KOH, a metal halide, and a mixture such as a hydroxide-halide salt mixture such as NaOH—NaCl. The anode may comprise a conductor on the surface of the gallium oxide film on the molten metal surface. The electrolyte may comprise a hydroxide ion conductor such as sodium gallate, or it may comprise potassium gallate which may comprise a K⁺ ion conductor. In an embodiment, the electrolyte may comprise an additive comprising at least one of an oxide, a hydroxide, and an oxyhydroxide. The additive oxide such as alumina may be more stable than gallium oxide wherein a salt mixture forms between the additive oxide and the gallium oxide surface film wherein the mixture may have a lower melting point than gallium oxide. The oxide and gallium ions of the film may be selectively electrolyzed to gallium metal and oxygen gas wherein the molten salt mixture comprises the electrolyte. In an embodiment, the SunCell® operating condition such as at least one of the reaction cell chamber temperature, pressure, voltage, current, and water injection rate support formation of gallium oxyhydroxide wherein hydroxide may serve as the migrating electrolyte ion. In an embodiment, the water injection rate and location may be controlled to maintain a steady state concentration of gallium oxyhydroxide. In an embodiment, the water injection may be directed to the molten gallium surface to support formation of hydroxide ions that may serve as the migrating ion of the electrolyte. The ignition system may provide either a positive or negative bias to the molten metal that serves as an electrode of the gallium regeneration system. In an exemplary embodiment, the negative bias of the cathode may be provided by the ignition system wherein the injector may comprise the negative electrode and may be submerged below the molten gallium metal surface. The anode may comprise a conductor such as carbon or stainless steel that floats on the surface of the molten gallium. Alternatively, the electrolysis cell may comprise a carbon anode that is consumed by reaction with oxygen from at least one of gallium oxide and water to form at least one of CO and CO₂ that are exhausted by means such as a vacuum pump.

In an embodiment, the electrolysis system cathode and anode may comprise the ignition system electrodes. The plasma in the reaction cell chamber may comprise the electrolyte that transports ions between the electrodes while electrons carry ignition current in an external circuit between the electrodes and the source of electrical power for ignition. In an embodiment, the plasma may comprise an electrolysis electrode in contract with the gallium oxide film on at least one of the surface of the molten gallium in the reaction cell chamber and the reservoir, and the gallium supporting the gallium oxide film may comprise the counter electrode. The ignition current may be DC, AC, or any combination of DC and AC, and may comprise any waveform that facilitates the electrolytic reduction of the gallium oxide film. In an embodiment, the electrode separation may be adjusted to at least one of increase the voltage to assist in electrolytic reaction of the gallium oxide film and increase the plasma reaction volume and thereby increase the SunCell® power output.

In an embodiment, the SunCell® comprises a vacuum system comprising a vacuum line to the reaction cell chamber and a vacuum pump to evacuate the gases from the reaction cell chamber on an intermittent or continuous basis. In an embodiment, the SunCell® comprises condenser to condense at least one hydrino reaction reactant or product. The condenser may be in-line with the vacuum pump or comprise a gas conduit connection with the vacuum pump. The vacuum system may further comprise a condenser to condense at least one reactant or product flowing from the reaction cell chamber. The condenser may cause the condensate, condensed reactant or product, to selectively flow back into the reaction cell chamber. The condenser may be maintained in a temperature range to cause the selective flow of the condensate back to the reaction cell chamber. The flow may be means of active or passive transport such as by pumping or by gravity flow, respectively. In an embodiment, the condenser may comprise a means to prevent particle flow such as gallium or gallium oxide nanoparticles from the reaction cell chamber into the vacuum system such as at least one of a filter, zigzag channel, and an electrostatic precipitator.

In an embodiment, the electrolyte comprises a base that reacts with gallium oxide to form gallium ions and ions that comprise oxygen such as oxide or hydroxide ions capable of migration and participation in the electrolysis reaction to reduce gallium oxide to gallium metal. The base may be selected such that at least one of (i) the melting point of the base is below the operating temperature of the reaction cell chamber, (ii) the boiling point of the base is above the operating temperature of the vacuum system, (iii) the melting point of the base is below the boiling point of any corresponding metal of the base, (iv) any corresponding metal of the base is capable of reacting with H₂O or oxygen to regenerate the base, (v) the melting point of the base is above the boiling point of water, (vi) the boiling point of any corresponding metal of the base is above the boiling point of water. In an exemplary embodiment, the electrolyte comprises NaOH having a melting point of 323° C. and a boiling point of 1388° C., and the corresponding metal, sodium, has a melting point of 97.8° C. and a boiling point of 883° C. compared to the boiling point of water of 100° C. The condenser may condense NaOH and Na and return these condensates to the reaction cell chamber while permitting more volatile gases such as excess water vapor to be evacuated from the reaction cell chamber. The returned Na may react with at least one of H₂O or oxygen in the reaction cell chamber or in the condenser to be at least one of be regenerated and recycled wherein the condenser may be maintained in a temperature range of 324° C. to 882° C. The condenser may be maintained in a temperature range of about greater than 324° C. to less than 882° C. to selectively return the sodium to the reaction cell chamber in at least one form of molten metallic sodium and molten NaOH.

In an embodiment, the gallium regeneration system may further comprise a salt bridge that crosses the molten metal surface and penetrates into the molten metal to electrically separate the anode and cathode except by ion conduction through the salt bridge. The salt bridge may comprise one of the disclosure such as beta solid alumina electrolyte (BASE) or potassium gallate.

In an embodiment, the molten gallium metal surface is biased negative to provide a reducing potential to the molten gallium to inhibit its oxidation reaction such as its reaction with water. The negative bias may be provided by the ignition system wherein the injector may comprise the negative electrode and may be submerged below the molten gallium metal surface.

In an embodiment, the reaction cell chamber comprises electrically insulating walls or electrical-insulator-coated walls to cause the ignition current to flow at least partially through the gallium oxide coat. The walls or coating may further resist wetting by gallium. Exemplary walls or coatings comprise BN, sapphire, MgF₂, SiC, or quartz. In another embodiment, the electrodes are located at a sufficient distance from the walls so that the ignition current favors a path between the electrodes that avoids the walls. The ignition current may flow through the plasma in the reaction cell chamber to the gallium oxide surface wherein the electrode 8 of the pedestal 5c1 and plasma may serve as the electrolysis anode, the molten gallium metal under the oxide coat and the injector that may be submerged may comprise the electrolysis cathode, and the ignition current may at least partially serve as the electrolysis current to reduce gallium oxide to gallium at the cathode. Alternatively, the polarity may be reversed, and the oxygen released at the anode may diffuse through the gallium oxide to be exhausted with the cell gas. The ignition current may be maintained a sufficient level that can electrolyze the gallium oxide formed from water addition to gallium. In an embodiment, the reaction cell chamber may comprise a getter such as carbon for the oxygen. In an exemplary embodiment, each 1 ml per minute H₂O addition forms 3.44 g or 0.533 ml of Ga₂O₃ per minute that requires a current of 180 A to reduce the gallium oxide to gallium. An electrolyte ion source such as an ionic compound may be added to the reaction cell chamber to provide ion migration to complete the electrolysis circuit. The ionic compound may comprise a base such as NaOH or alkali halide such as NaF. In an embodiment, the injection current may be reduced or terminated to favor current flow through the gallium oxide. The rate or pattern of water injection may be controlled to control the rate of gallium oxide formation such that the rate of gallium oxide reduction may be sufficient to maintain a desired plasma condition such as a continuous versus intermittent plasma. In an exemplary embodiment, water is injected intermittently to permit the gallium oxide to be about reduced between injections. In an embodiment, hydrogen is added to catalyze at least one of electrolytic reduction and thermal decomposition of the gallium oxide surface film. The hydrino reaction plasma may provide active H to enhance the reaction of gallium oxide to gallium.

In another embodiment with electrical insulating walls, a high current is flowed through the gallium oxide layer to super heat it and cause the gallium oxide to at least one of undergo hydrogen reduction with added H₂ and thermal decomposition. The injection pump such as the EM injection pump may be turned down or off to increase the current flow through the gallium oxide. The voltage of the plasma may be adjusted for the reduced pumping or pump off condition possibly due to the corresponding reduction in conductivity. In an exemplary embodiment, the voltage is increased about 5 to 10 V to maintain about the same current as that before the pump decrease or termination. In addition to or in lieu of the conductivity provided by the injected molten metal, silver may be added to the gallium to form silver nanoparticles that maintain a high gas conductivity and corresponding high ion-electron recombination rate to maintain a high hydrino reaction rate. In an embodiment, a hydrogen dissociator such as a noble metal, Ni, Ti, Nb, a carbon, ceramic, or zeolite supported noble metal, a rare earth metal, and another hydrogen dissociator known in the art may be added to the reaction cell chamber to provide atomic H as an activated form of hydrogen to reduce gallium oxide. In another embodiment, the hydrino reaction plasma may provide the atomic hydrogen to reduce gallium oxide. The hydrogen pressure may be maintained in at least one range of about 0.1 Torr to 10 atm, 0.5 Torr to 5 atm, and 0.5 Torr to 1 atm. The hydrogen may be flowed, and the rate may be in at least one range of about 0.1 standard cubic centimeter per minute (sccm) to 100 liters per minute, 1 sccm to 10 liters per minute, and 10 sccm to 1 liter per minute.

In an exemplary tested embodiment, the reaction cell chamber was maintained at a pressure range of about 1 Torr to 20 Torr while flowing 10 sccm of H₂ and injecting 4 ml of H₂O per minute while applying active vacuum pumping. The DC voltage was about 28 V and the DC current was about 1 kA. The reaction cell chamber was a SS cube with edges of 9-inch length that contained 47 kg of molten gallium. The electrodes comprised a 1-inch submerged SS nozzle of a DC EM pump and a counter electrode comprising a 4 cm diameter, 1 cm thick W disc with a 1 cm diameter lead covered by a BN pedestal. The EM pump rate was about 30-40 ml/s. The gallium was polarized positive and the W pedestal electrode was polarized negative. The SunCell® output power was about 150 kW measured using the product of the mass, specific heat, and temperature rise of the gallium and SS reactor.

In an embodiment of the SunCell® comprising two reservoirs and injectors that serve as electrodes of opposite polarity such as the SunCells® shown in FIGS. 5 and 9, the pumping of a first injector may be reduced or terminated while that of a second is sufficiently maintained to pump molten metal into the reservoir of the first so that any gallium oxide coat in the first may be eliminated by the flow of current through the film. Conversely, the pumping of the second injector may be reduced or terminated while that of the first is sufficiently maintained to pump molten metal into the reservoir of the second so that any gallium oxide coat in the second may be eliminated by the flow of current through the film. Alternatively, the pumping of both injectors may be reduced or terminated so that the current flows from through the gallium oxide film of at least one of the reservoirs with the hydrino reaction plasma at least partially providing a current connection between the electrodes. An electrolyte may be added to the gallium oxide film to promote its reduction.

In an embodiment, the EM pump injector comprises a plurality of nozzles submerged beneath the molten gallium metal surface comprising a gallium oxide surface film. The plurality of submerged nozzles may be located different positions in the reservoir and at different angles relative to the molten metal surface to break up the gallium oxide film as the corresponding injected streams penetrate the oxide film during ignition. In an embodiment, the SunCell® comprises a plurality of molten metal injection pumps and corresponding nozzles that may be submerged wherein the injected molten metal may break up the surface gallium oxide film. The depth of submersion may be adjusted to optimize the breakup of the gallium oxide film. In an embodiment, at least one non-submerged nozzle may comprise at least one outlet directed towards the counter electrode, and at least one other directed towards the gallium oxide surface to assist in breaking up the oxide film.

In an embodiment, a reactant is added to at least one of the reservoir and the reaction cell chamber to react with any electrically insulating film that may form on the molten metal wherein the reaction product is at least one of less electrically insulating and less prone to forming a continuous electrically insulating film. In an embodiment, a base such as NaOH is added to at least one of the reservoir and the reaction cell chamber to react with gallium oxide to form a product such as NaGaO₂ to reduce or eliminate any continuous electrically insulating surface layer surface on the molten gallium oxide. In an exemplary embodiment, the reaction of NaOH with gallium oxide may break up the electrically insulating Ga₂O₃ film on molten gallium. In another embodiment, at least one of the pump injection nozzle diameter and depth and an increased EM pumping rate are adjusted to break up the electrically insulating film on molten gallium such as an gallium oxide coat on the surface of the molten gallium sufficiently to prevent it from interfering with the plasma ignition current.

In an embodiment, the SunCell® comprises a source of carbon such as carbon powder such as graphite, coke, or charcoal powder. The carbon source may comprise a carbon reservoir, a valve, and a connection or conduit between the carbon reservoir and the reaction cell chamber and may further comprise a means to mechanically transport the carbon to the reaction cell chamber in addition to gravity flow or feed. The carbon may coat the gallium surface to reduce the reaction of any oxidizing species of the hydrino reaction mixture such as at least one of oxygen and water with the gallium to form gallium oxide. As an alternative to NaOH addition, hydrogen reduction, electrolytic reduction, thermal decomposition, or at least one of vaporization and sublimation due to the volatility of Ga₂O to remove the gallium oxide surface coat on molten gallium, the reaction mixture in the reaction cell chamber comprises carbon from the source. The carbon may react with at least one of added H₂O and Ga₂O₃ to form at least one of CO and CO₂ that may be exhausted by a vacuum pump. The carbon reaction may comprise at least one of the water syngas reaction, the water-gas shift reaction, and the carbothermal reduction reaction of gallium oxide to gallium metal and CO and CO₂ that may be exhausted. Exemplary reactions are

2H₂O+C to CO₂+2H₂

and the carbo-reduction reaction of gallium oxide

Ga₂O₃+3C to 2Ga+3CO

Ga₂O₃+3/2C to 2Ga+3/2CO₂

In another embodiment, the carbothermal reduction of gallium oxide may be coupled with another reaction to comprise a combination of reactions such as a combination of carbothermal reactions to reduce gallium oxide to gallium.

In an embodiment, the SunCell® comprises systems to reduce the Ga₂O₃ to gallium metal while exhausting the Ga₂O₃ reduction product such as one comprising oxygen and returning the gallium metal to the reaction cell chamber. In an embodiment, the SunCell® comprises means to remove a Ga₂O₃ film or layer from the reaction cell chamber, a gallium regeneration system, a gallium oxide channel from the reaction cell chamber 5c1 to a gallium regeneration system, a transporter to transport the gallium oxide from the reaction cell chamber 5b31 to the gallium regeneration system, a means to vent the other products from the regeneration of gallium from gallium oxide such as oxygen, a reservoir for regenerated gallium, a gallium channel, conduit, or tube from the gallium regeneration reservoir to the reaction cell chamber, a gallium transporter from the reservoir for regenerated gallium to the reservoir 5c or reaction cell chamber 5b31, and a control system for each of the means. At least one of (i) the means to remove the Ga₂O₃ film from the surface of the liquid gallium in the reservoir 5c or reaction cell chamber 5b31, (ii) the transporter to transport the gallium oxide in its channel, and (iii) the transporter to transport gallium in its channel may comprise at least one of a mechanical, electromagnetic, hydraulic, or pneumatic mover or skimmer, a pump such as a mechanical or EM pump, ajet such as at least one gas jet, molten metal jet, water jet, at least one auger, a shaker or vibrator such as an electromagnetic or piezoelectric vibrator, and at least one conveyor such as a conveyor belt or mesh. In an embodiment, the jet to remove the Ga₂O₃ film from the surface of the liquid gallium in the reservoir 5c or reaction cell chamber 5b31 such as the molten metal jet may impinge on the surface at an angle that is favorable to the selectively moving the gallium oxide on the surface of the molten gallium. In an exemplary embodiment, the jet may impinge from below the gallium surface.

In an embodiment, the means to remove the Ga₂O₃ film from the surface of the liquid gallium in the reservoir 5c or reaction cell chamber 5b31 comprises an actuator that moves a mechanical surface skimmer or scraper that may be manipulated or driven with at least one magnet external to the cell such as an electromagnet or cooled permanent magnet wherein the actuator may comprise a ferromagnetic material having a high Curie temperature such as iron or cobalt. In another embodiment, the skimmer may comprise a vacuum-capable-sealed penetration and an external drive mechanism such as one known in the art.

In an embodiment, the SunCell® may comprise a surface mechanical wave generator to produce waves in the gallium oxide to push the Ga₂O₃ film from the surface of the liquid gallium in the reservoir 5c or reaction cell chamber 5b31 and cause a flow of oxide into the gallium oxide channel. The source such as a sound wave source such as a sonar device such as an electromagnetic drive sonar source such as a sonar boomer. The source may be located on at least of one or more external walls of the reservoir and reaction cell chamber and inside of at least one of the reservoir and reaction cell chamber. In an embodiment, the SunCell® may further comprise a filter or sieve that receives at least one of the gallium oxide removed from the molten gallium surface and some molten gallium and selectively retains the gallium oxide while returning the gallium to its source such as the reservoir or reaction cell chamber. The filter or sieve may comprise a trough that may be elevated from the surface. The trough may receive the at least one of the gallium oxide and gallium by action of the source of surface waves. The trough may run along one side of the reaction cell chamber. The trough may have perforations in the bottom that allow gallium to drain back to its source. The trough may further comprise a transporter such as an auger. The auger may comprise a vacuum-capable-sealed penetration or magnetic coupler and an external drive mechanism such as one known in the art. The auger may transport the gallium oxide to the gallium oxide channel from the reaction cell chamber 5c1 to a gallium regeneration system.

In an embodiment, the means to remove the Ga₂O₃ film from the surface of the liquid gallium in the reservoir 5c or reaction cell chamber 5b31 comprises a series of electrodes that deliver electrical power to the surface oxide. The electrodes may push gallium oxide with time-delayed sequential high voltage pulses into the oxide covered surface to create a traveling wave of arc currents with a corresponding traveling thermal wave on the reservoir surface. The thermal wave in turn generates a force wave that pushes the gallium oxide into the oxide channel. The mechanism to remove the gallium oxide surface may comprise thermophoresis.

In an embodiment, the transporter from the reaction cell chamber 5c1 to the gallium regeneration system may comprise a pump such as an electromagnetic pump that maintains a seal such as a seal comprising a molten metal column between the reaction cell chamber 5c1 and the gallium regeneration system. In an embodiment, the transporter from the gallium regeneration system to the reaction cell chamber 5c1 may comprise a pump such as an electromagnetic pump that maintains a seal such as a seal comprising a molten metal column between the gallium regeneration system and the reaction cell chamber 5c1. The seal may permit the separation of at least one of the gases and pressures of the reaction cell chamber 5c1 and the gallium regeneration system. In another embodiment, the transporter from the reaction cell chamber 5c1 to the gallium regeneration system may comprise a passive device such as a channel that permits gravity flow. The channel such as one comprising a P trap may maintain a seal such as a seal comprising a molten metal column between the reaction cell chamber 5c1 and the gallium regeneration system. The channel may further comprise a heat recuperator or heat exchanger to at least one of recover heat from the transported gallium and to cool the gallium.

The means to remove the Ga₂O₃ film from the surface of the liquid gallium in the reservoir 5c or reaction cell chamber 5b31 may cause a flow of the molten metal with the flow of oxide into the gallium oxide channel or conduit from the reaction cell chamber 5c1 to a gallium regeneration system. The molten metal flow may be sufficient to flush the oxide into the channel or conduit and permit its transport to the regeneration system by the transporter without clogging. The regeneration system may comprise an electrolysis system such as one comprising an aqueous base electrolyte, two electrodes such as stainless steel electrodes, and an electrolysis cell having a floor that slopes toward the cathode and the inlet of the gallium channel, conduit, or tube from the gallium regeneration reservoir to the reaction cell chamber. The molten metal that serves to flush the oxide may flow along the sloped floor and into the inlet of the gallium channel and may be transported to the reservoir or reaction cell chamber. The transport may be with regenerated gallium. In an exemplary embodiment, the means to remove the Ga₂O₃ film from the surface of the liquid gallium in the reservoir 5c or reaction cell chamber 5b31 comprises a molten metal jet that may be supplied by an electromagnetic pump wherein the supply of molten metal may comprise at least one of the regeneration system and the reservoir. The rate of molten metal pumping to the jet may be adjusted by a controller based on the amount needed to flush the gallium oxide. The amount needed to flush the gallium oxide may be dependent on the amount formed. A parameter input to the controller regarding the amount of gallium oxide formed comprises the water injection rate. In an alternative embodiment, the means to remove the Ga₂O₃ film from the surface of the liquid gallium comprises a shaker table on which the SunCell® is mounted. The rocking action of the shaker table may force the gallium oxide into the gallium oxide channel from the reaction cell chamber 5c1 to a gallium regeneration system. In another embodiment, the means to remove the Ga₂O₃ film from the surface of the liquid gallium may comprise a rotating platform on which the SunCell® is mounted wherein the centrifugal force from the rotation of the table forces the gallium oxide into the gallium oxide channel from the reaction cell chamber 5c1 to a gallium regeneration system.

In an embodiment, the transporter from the reaction cell chamber 5c1 to the gallium regeneration system may comprise the gallium transporter from the reservoir for regenerated gallium to the reservoir 5c or reaction cell chamber 5b31. The latter transporter may create suction in the gallium oxide channel. In an exemplary embodiment, the pumping of gallium from the regenerated gallium reservoir by the corresponding EM pump transporter creates a partial vacuum along the gallium oxide channel to cause the gallium oxide to be sucked from the reservoir 5c or reaction cell chamber 5b31 to the gallium regeneration system. The flow resistance in at least one conduit connecting the SunCell® components comprising the reaction cell chamber or reservoir and the regeneration system may be sufficient to maintain the seal between the corresponding chambers.

In an embodiment comprising a molten metal that oxidizes, the plasma reaction favors a metal surface relative to a less conductive oxidized metal surface. For example, arc current formation which favors ion-electron recombination with a vast increase in hydrino reaction kinetics may favor a metallic gallium surface rather than a gallium oxide surface that forms over time due to reaction of added water vapor with the metallic gallium. To refresh the gallium surface from gallium oxide, the SunCell® may comprise the means to remove the Ga₂O₃ film from the surface of the liquid gallium in the reservoir 5c or reaction cell chamber 5b31. An exemplary means to remove the oxide surface coat comprises (i) a collector such as tilted perforated platform such as a tilted planar screen inside of the reaction cell chamber at the gallium liquid level of the reservoir and (ii) an inert gas or molten gallium jet on the opposite side of the reaction cell chamber to force gallium oxide onto the screen which selectively collects the gallium oxide while the gallium flows through the screen and returns to the reservoir. The collected gallium oxide may be further transported to the gallium regeneration system by the transporter.

In an embodiment the means to remove the Ga₂O₃ film from the surface of the liquid gallium in the reservoir 5c or reaction cell chamber 5b31 comprises a molten metal jet. In an embodiment, at least one molten metal jet that may comprise the outlet nozzle of a molten metal pump such as an electromagnetic pump that applies at least one injected molten metal stream to an oxide surface coating on the reservoir metal such as molten gallium. The force of the injected stream may push the oxide coating to a desired location such as the transporter to the gallium regeneration system. The inlet of the molten metal jet pump may be in continuity with at least one of the molten metal of the reservoir and the molten metal of the gallium regeneration system. In an exemplary embodiment, the molten metal jet forces the surface layer of the reservoir comprising at least one of Ga₂O₃, Ga₂O, and Ga into a conduit to the gallium regeneration system that may comprise a basic electrolyte such as aqueous NaOH and an electrolysis system. Ga₂O may be oxidized to Ga₂O₃ by reaction with oxygen evolved at an anode of the electrolysis system, Ga₂O₃ may form the corresponding gallate such as sodium gallate, Ga may flow into a reservoir at the cathode, the gallium may be at least one of transported to the reservoir and reaction cell chamber, and flowed into the inlet of the molten metal jet pump. In an embodiment, a chemical such as NaOH may be added at least one of the reservoir and the reaction cell chamber to react with gallium oxide to form a product such as sodium gallate that is more readily removed from the surface of the reservoir molten metal by the means to remove the Ga₂O₃ film from the surface of the liquid gallium in the reservoir 5c or reaction cell chamber 5b31.

In an embodiment, the Ga₂O₃ may be reduced to a lesser oxide such as Ga₂O that is more readily removed from the surface of the molten metal by the means to remove the Ga₂O₃ film from the surface of the liquid gallium in the reservoir 5c or reaction cell chamber 5b31. Ga₂O₃ may be converted to another oxide such as Ga₂O by one or more of (i) the thermal decomposition of any gallium oxide such as Ga₂O₃ to Ga₂O, (ii) the conversion of Ga₂O₃ to Ga₂O by reaction with gallium, (iii) the reduction of Ga₂O₃ by hydrogen, (iv) the reduction of Ga₂O₃ by carbothermal reduction, (v) the reduction of Ga₂O₃ by in situ electrolysis, and reduction of Ga₂O₃ by other methods of the disclosure wherein the corresponding reductant such as hydrogen, carbon, and electrolysis electrolyte and electrolysis current are added to the reaction cell chamber and the temperature is maintained at one that permits at least one of the desired reduction reactions and thermal decomposition. In an embodiment, Ga₂O may form particles that are embedded in the Ga₂O₃ film on the surface of the molten gallium. The Ga₂O particles may carry the Ga₂O₃ film along as they are transported by the means to remove the Ga₂O₃ film from the surface of the liquid gallium. In an exemplary embodiment, Ga₂O particles embedded in the Ga₂O₃ film on the surface of the molten gallium cause the film to be transported with them by a jet or flow created by at least one EM pump. Any gallium metal used to cause the jet or flow may be separated from the gallium oxide and recirculated.

The pump to remove the gallium oxide film may apply suction to the gallium oxide and selectively remove the gallium oxide surface layer due to its lower density. An exemplary mechanical skimmer is one comprising a shaft, and mechanical linkage and external drive motor with a power supply and controller. Another exemplary skimmer embodiment comprises a stirring bar inside of the reaction cell chamber that is spun by an external spinning magnetic in phase with the internal stirring bar. The stirring bar may comprise a magnetic or ferromagnetic material such a cobalt or iron that has a high Curie temperature. The reaction cell chamber may comprise at least one flat vertical wall such as one of the walls of a cubic or rectangular reaction cell chamber wherein the stirring bar operates in the plane parallel to the wall. The stirring bar may propel the Ga₂O₃ into its channel to the gallium regeneration system. In another exemplary embodiment, the SunCell® comprises a gas jet to provide at least a horizontal component of force across the surface of the liquid metal in the reservoir 5c. In an embodiment, the gallium oxide layer floating on top of the gallium in the reservoir 5c is forced into the channel to the gallium regeneration system such an electrolysis system by the gas jet such as a gas jet of the reaction cell chamber 5b31 gas. The gas jet may comprise a gas inlet, a gas outlet, at least one nozzle wherein the direction of the nozzle may be controllable, and a control system of at least one of the gas flows and the nozzle direction. In another embodiment, the SunCell® comprises a means to cause a centrifugal force at the floating gallium oxide layer to case the gallium oxide layer to flow circumferentially and into the channel to the electrolysis system. The SunCell® may comprise and rotational means such as a rotating table on which the SunCell® is mounted. The gallium regeneration system may comprise an electrolysis cell. The electrolysis cell may comprise at least two electrodes, an electrolyte, an electrolysis power supply, an electrolysis controller, and reservoir for gallium metal, an inlet and outlet channel comprising the channel from and to at least one of the reservoir and reaction cell chamber.

The gallium regeneration system may comprise a Ga₂O₃ reduction system. The gallium regeneration system may comprise a Ga₂O₃ electrolysis cell such as an aqueous or molten salt electrolysis cell. The Ga₂O₃ may undergo electrolysis to gallium metal at the cathode and at least one of O₂, H₂O, or another oxide such as a volatile or gaseous oxide such as CO₂ at the anode that is selectively vented from the Ga₂O₃ electrolysis cell. In the latter case, at least one electrode such as the anode may comprise carbon. The O₂, H₂O, or another oxide such as a volatile or gaseous oxide such as CO₂ may be selectively vented. The means to vent the other products such as oxygen from the regeneration of gallium from gallium oxide may comprise a vent tube to a tank or exhaust and housing at least partially covering the anode that allows the gas to collect and flow into the vent tube. The housing may be comprising at least a section that is permeable to electrolyte ion flow such as a selective salt bridge of open lower end that may comprise a bell jar. In an embodiment, Ga₂O₃ is treated with a hydroxide such as an alkali hydroxide such as sodium hydroxide solution to form sodium gallate that may be reduced to gallium metal at the cathode by electrolysis of the sodium gallate solution at the cathode such as a stainless steel cathode. In an embodiment, at least one electrode may comprise at least one of stainless steel, nickel, carbon, a precious metal such as Pd, Pt, Au, Ru, Rh, Ir, a dimensionally stabilized electrode, and other anodes stable in base known to those skilled in the art. In an exemplary embodiment, the gallium metal may be returned to at least one of the reservoir 5c and the reaction cell chamber 5b31 by an EM pump that selectively return pumps the gallium metal.

An exemplary skimmer system to move gallium oxide may comprise a perforated movable plate that spans a cross section of the molten metal surface that accumulates gallium oxide and may further comprise a transverse transporter to move gallium oxide in a direction about perpendicular to the direction that the skimmer moves it. The skimmer may be electrically nonconductive to avoid shorting the ignition current or the plasma such as a ceramic skimmer such a as BN skinner or ceramic-coated metallic skimmer such as a Mullite, alumina, or BN coated stainless steel, tungsten, or tantalum skimmer. An EM pump may serve as a hydraulic skimmer driver that avoids a non-welded penetration. The EM pump may drive a hydraulic piston as the actuator or drive a hydraulic motor. The skimmer may be driven by a reversible motor such as a hydraulic motor such as one comprising an EM pump. The skimmer may push gallium oxide to one wall and then reverse direction and push gallium oxide to the opposing wall. The skimmer may comprise a transverse transporter along at least one wall to move the skimmed gallium oxide in a perpendicular direction to the direction of the skimmer. The transporter may comprise a screw or open auger suspended partially in the liquid gallium that selectively pushes the oxide to a corner while allowing the liquid gallium to flow around the auger. The skimmer system may comprise at least one mechanical linkage between the skimmer and at least one transverse transporter so that the transverse transporter may be driven by the same driver such as an EM pump hydraulic motor. In an embodiment, the skimmer comprises an auger such as an open auger. The transverse transporter may comprise a skimmer of the disclosure that comprises a transverse skimmer. The motion of transverse skimmer motion may be synchronized with that of the skimmer so that it is in proper position to receive oxide from the skimmer and move it into the oxide channel without interference between the two skimmers.

In an embodiment, the skimmer may comprise a hub and spoke gallium oxide film skimmer wherein the injection may occur through the open hub. The skimmer may rotate about the hub powered by a motor such as a hydraulic motor such as an EM pump-driven motor. The skimmer may span the surface of a cylindrical reaction cell chamber that may comprise a peripheral gallium oxide channel to which the gallium oxide is skimmed. The rotation may be at a high speed to create a centrifugal force to cause the skimmed gallium oxide to flow along the spokes of the skimmer into the gallium oxide channel.

In an embodiment, the SunCell® comprises a gallium oxide storage reservoir into which the gallium oxide is transported, and the SunCell® may further comprise a makeup gallium reservoir to replenish gallium that forms gallium oxide during operation. The SunCell® may comprise a gallium return transporter at the bottom of the gallium oxide storage reservoir to return any gallium that accumulates in this reservoir back to the reactor reservoir 5c or the reaction cell chamber 5b31. The gallium return transporter may comprise a pump such as an EM pump that may further comprise an inlet filter to block gallium oxide. The gallium oxide collected in the gallium oxide storage reservoir over time may be batch regenerated in the regeneration system of the disclosure such as the sodium gallate electrolysis system. The SunCell® may further comprise a tank discharge transporter such as one of the disclosure to transport gallium oxide from the gallium oxide storage reservoir into the gallium regeneration system. In an exemplary embodiment, the accumulation rate of gallium oxide per milliliter of water injected per minute corresponding to a theoretical hydrino power of about 50 kW is 3.4 g/minute (0.54 ml/minute).

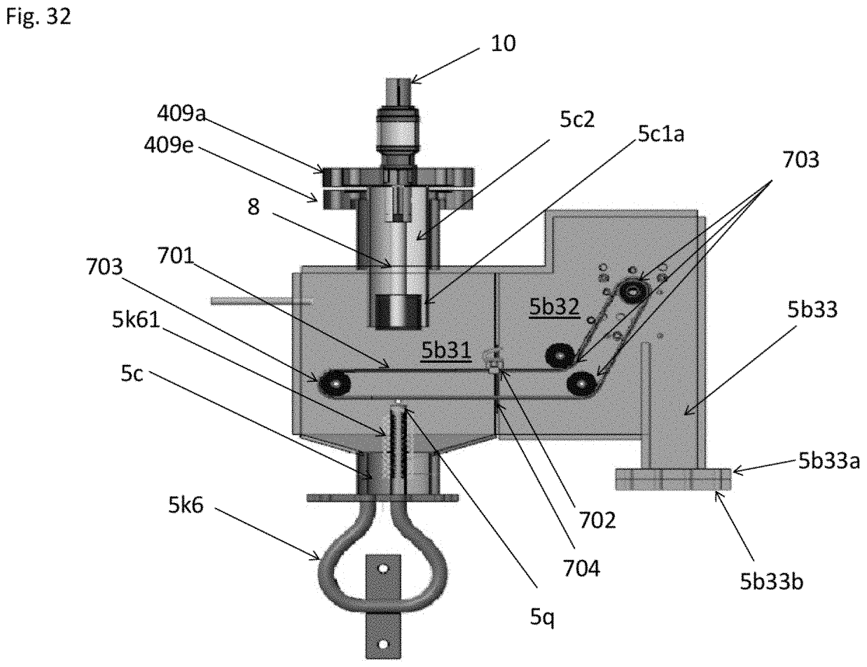

In an embodiment, the skimmer may comprise a conveyor such as one comprising at least one belt or set of cables or set of chains 701 having at least one perforated bucket or paddle 702 attached to the belt or between the cables or chain (FIG. 32). The bucket serves as at least one of the skimmer and a bucket elevator to lift skimmed gallium oxide into the gallium oxide storage reservoir 5b33. The bucket may comprise a refractory material that does not alloy or react with gallium such as a ceramic, W, or Ta. Tantalum and the ceramic BN are machinable exemplary materials. The belt or each cable or chain of opposing members of a pair may be driven and guided on at least one of sprockets, cogs, or pulleys 703 wherein at least one of sprockets, cogs, or pulleys is turned by a motor such as an electrical, pneumatic, hydraulic, or electromagnetic pump motor. The conveyor belt, cables, or chains may cause the at least one bucket to travel along the molten gallium surface from a first wall to an opposing wall of the reaction cell chamber 5b31 or reservoir, then up an incline to the top of the conveyor wherein the skimmed gallium oxide is dumped into the gallium oxide storage reservoir 5b33. The conveyor may return the bucket to the first wall to repeat the skimming cycle. The molten metal injector such as one comprising a nozzle 5q may be sufficiently submerged in the molten gallium of the reaction cell chamber 5b31 or reservoir 5c to permit the bucket to be submerged at a lesser depth and pass over the nozzle 5q. The reaction cell chamber may comprise a housing 5b32 for the inclined or bucket elevator section of the conveyor and the gallium oxide storage reservoir 5b33. The gallium oxide storage reservoir 5b33 may comprise an opening at the top to receive gallium oxide from the bucket elevator section of the conveyor. The opposing wall of the reaction cell chamber 5b31 or reservoir may comprise a bucket passage 704 comprising an opening to allow passage of the bucket skimmer while partially blocking the molten gallium in the reaction cell chamber or reservoir. The height to the top opening of the gallium oxide storage reservoir 5b33 may be sufficient to block the breaching its wall towards the bucket elevator by any flowing molten gallium that may pass through the bucket passage due to any mechanical waves generated in the molten gallium. The gallium oxide storage reservoir 5b33 may comprise a flange 5b33a and mating flange plate 5b33b that is removable to remove the gallium oxide storage reservoir 5b33 so that the collected gallium oxide may be removed and regenerated wherein the empty gallium oxide storage reservoir 5b33 is reassembled.

In an embodiment, the formation of the gallium oxide film increases the ignition current resistance such that the ignition current decreases at constant ignition voltage or the ignition voltage increases to maintain ignition current constant. In an embodiment, the skimmer comprises a controller that monitors at least one of the ignition parameters of the current, ignition voltage, and ignition current resistance and activates the skimmer to remove the oxide coat to maintain the ignition parameter in a desired range.

In an embodiment, at least one of the reservoir and reaction cell chamber may be maintained at an operating temperature that is greater than the decomposition temperature of at least one of gallium oxyhydroxide and gallium hydroxide. The operating temperature may be in at least one range of about 200° C. to 2000° C., 200° C. to 1000° C., and 200° C. to 700° C. The species to be skimmed may be limited to gallium oxide in the case that gallium oxyhydroxide and gallium hydroxide formation is suppressed.

The reaction mixture may comprise an additive capable of reacting with some of the oxygen or water present in situ (i.e., in the reaction chamber) in order to remove a portion of these components from the reaction mixture. In some embodiments, the additive may be used to transport these components to the regeneration system. Ultimately, oxygen and water reacted with the additive may be exhausted (i.e., expelled from the entire system) via the regeneration system. In particular embodiments, the additive is capable of being oxidized by oxygen and/or water. For example, an oxidized additive (e.g., metal oxide such as gallium oxide) may be formed in the reaction chamber from the addition of the additive to the reaction chamber (e.g., gallium additive in silver molten metal). Following its production, the oxidized additive may be transported to the regeneration system (e.g., a reducing system). Once transported to the regeneration system, the oxidized additive may be reduced resulting in regenerated additive and oxygen and/or water previously present in the reaction chamber. The additive may then be returned to the reaction chamber for further use, and the oxygen and/or water previously present in the reaction chamber may be expelled.

In an embodiment, the reaction mixture may comprise an additive comprising a species such as a metal or compound that reacts with at least one of oxygen and water. The additive may be regenerated. The regeneration may be achieved by at least one system of the SunCell®. The regeneration system may comprise at least one of a thermal, plasma, and electrolysis system. The additive may be added to a reaction mixture comprising molten silver. In an embodiment, the additive may comprise gallium that may be added to molten silver that comprises the molten metal. In an embodiment, water may be supplied to the reaction cell chamber. The water may be supplied by an injector. The gallium may react with water supplied to the reaction mixture to form hydrogen and gallium. The hydrogen may react with some residual HOH that serves as the hydrino catalyst. The gallium oxide may be regenerated by the electrolysis system of the disclosure. The gallium metal and oxygen produced reduced by the electrolysis system may be pumped back to the reaction cell chamber and exhausted for the cell, respectively.

In an embodiment, the electrolyte to perform electrolysis on Ga₂O₃ comprises an alkali halide and gallium halide such as GaF₃. The electrolyte may comprise a molten salt such as an analogue of cryolite with Ga substituting for Al such as Na₃GaF₆. In an embodiment, Ga₂O₃ may be reacted with HX (x=halide) such as HCl to form GaCl₃. The melt of GaCl₃ may be electrolyzed to form Ga metal at the cathode and Cl₂ gas at the anode. The chlorine gas may be reacted with hydrogen from a source such as H₂ from the electrolysis of water to form HCl.

In an embodiment, the SunCell® comprises systems to react Ga₂O₃ with at least one reactant to form a volatile product, a volatile product condenser, a gallium regeneration system such as an electrolysis cell, and channels and transporters to transport the volatile product and regenerated gallium to and from the gallium regeneration system, respectively. The reactant may comprise an acid such as HX (X=halide). Ga₂O₃ may be reacted with an acid such as HX (X=halide) to form GaX₃ that may be volatile. The gaseous GaX₃ may be condensed in the condenser that may comprise a component of the gallium regeneration system. GaX₃ such as GaCl₃ or GaBr₃ may be electrolyzed to form Ga metal at the cathode and X₂ gas at the anode. The X₂ gas may be reacted with hydrogen from a source such as H₂ from the electrolysis of H₂O to form HX. The SunCell® may further comprise a gallium regeneration reservoir wherein Ga₂O₃ is transported and reacted with HX to form gallium metal. The HX gas may be released into at least one of the reservoir, the reaction cell chamber, and a regeneration reservoir to form GaX₃ and H₂O.

In an embodiment, the molten metal may comprise any molten metal. In the case that the molten metal forms a product by reaction with a component of the hydrino reaction mixture such as a metal oxide product, the molten metal may comprise one that is capable of being regenerated. In an embodiment, the SunCell® comprises a means to regenerate and recycle the molten metal. In an embodiment, the molten metal may comprise one that forms an oxide that can be regenerated by at least one of hydrogen reduction and electrolysis wherein the metal regeneration means comprises at least one of an electrolysis cell and a hydrogen reduction reactor. The system to regenerate the metal may comprise the electrolysis regeneration system of the disclosure that may further comprise a source of hydrogen to reduce the metal oxide to the metal and recirculate or recycle the regenerated molten metal. Exemplary metals that may be regenerated by hydrogen reduction are copper and nickel. In an embodiment, the electrolysis chamber may be replaced with a hydrogen reduction chamber. In another embodiment, gallium may be replaced by aluminum, and the regeneration system may comprise an alumina electrolysis cell such as one comprising carbon electrodes and a molten salt electrolyte such as cryolite (Na₃AlF₆).

In an embodiment, hydrogen gas may be added to the reaction mixture to eliminate the gallium oxide film formed by the reaction of injected water with gallium. In another embodiment, an additive gas such as a noble gas such as argon, nitrogen, CO₂, a hydrocarbon such as methane or propane, or another gas of the disclosure may be added to support elimination the gallium oxide film. The additive gas may increase the atomic H from the H₂O+Ga to Ga₂O₃+H₂ reaction. The additive gas such as argon may increase the hydrino reaction rate wherein the high energy released facilitates decomposition of the gallium oxide film. The additive gas may react with a species in the reaction cell chamber such as at least one of H₂O, OH⁻, Ga₂O₃, OH, and Ga₂O to form an electrolyte that enhances the electrolytic reduction of the gallium oxide film. The additive gas such as a noble gas may increase the ionization fraction of the plasma to increase its conductivity and increase the reduction current flowing through the gallium oxide. The additive gas may have a longer half-life in the reaction cell chamber relative to other gases due to properties such as higher mass. The added hydrogen or additive gas may be in any desired amount to achieve the reduction of the gallium oxide film. At least one of the hydrogen or additive gas in the reaction cell chamber may be in at least one pressure range of about 0.1 Torr to 100 atm, 1 Torr to 1 atm, and 1 Torr to 10 Torr. At least one of the hydrogen or additive gas may be flowed into the reaction cell chamber at a rate per liter of reaction cell chamber volume in at least range of about 0.001 sccm to 10 liter per minute, 0.001 sccm to 10 liter per minute, and 0.001 sccm to 10 liter per minute.

In an embodiment, the H₂O injector may inject the H₂O into the hydrino plasma region of the reaction cell chamber such as in the region between the electrodes. The plasma injection may be near positive electrode where the hydrino plasma is most intense. The injection of the H₂O into the plasma may at least one of enhance the power released, prevent the water from forming an oxide with the gallium, and contribute to gallium oxide reduction or decomposition. The injector may comprise an orifice at the reaction cell chamber wall or a nozzle inside of the reaction cell chamber that may direct the water to a desired location such as on the gallium surface above the molten metal injector. The nozzle may enter at a position and angle to achieve the desired delivery to the desired location. In exemplary embodiments, the nozzle may be located at the top of the cell and direct the injected water downward to the center of the plasma at the gallium surface, or a refractory nozzle may comprise a conduit through the molten gallium and further comprise an arc to direct the water to the gallium surface. The nozzle may comprise a small aperture, a converging-diverging nozzle, or other nozzle known in the art to direct the water to the desired location. The nozzle can comprise a means such as a heater and heat exchanger to heat and convert liquid to at least some gaseous water. The conversion to gaseous water may cause a pressure increase that may serve as a propellant to inject the water to a desired location. In an embodiment, the injected water droplets or particles may be charged such as negatively charged by means such as electrostatically. The particles may be charged by at least one of an electrode at the nozzle exit, a coronal discharge through which the particles pass when injected, and by friction of the particles with a charging material or structure such as the nozzle. The gallium may be oppositely charged such as positively charged so that the injected water is attracted to the gallium surface. The injected particles may be directed to the area about along the axis of the electrodes.

In an embodiment, hydrogen may serve as the catalyst. The source of hydrogen to supply nH (n is an integer) as the catalyst and H atoms to form hydrino may comprise H₂ gas that may be supplied through a hydrogen permeable membrane such as a Pd or Pd—Ag such as 23% Ag/77% Pd alloy membrane in the EM pump tube 5k4 wall using a mass flow controller to control the hydrogen flow from a high-pressure water electrolyzer. The use of hydrogen as the catalyst as a replacement for HOH catalyst may avoid the oxidation reaction of at least one cell component such as a carbon reaction cell chamber 5b31. Plasma maintained in the reaction cell chamber may dissociate the H₂ to provide the H atoms. The carbon may comprise pyrolytic carbon to suppress the reaction between the carbon and hydrogen.

### Solid Fuel SunCell®

In an embodiment, the SunCell® comprises a solid fuel that reacts to form at least one reactant to form hydrinos. The hydrino reactants may comprise atomic H and a catalyst to form hydrinos. The catalyst may comprise nascent water, HOH. The reactant may be at least partially regenerated in situ in the SunCell®. The solid fuel may be regenerated by a plasma or thermal driven reaction in the reaction cell chamber 5b31. The regeneration may be achieved by at least one of the plasma and thermal power maintained and released in the reaction cell chamber 5b31. The solid fuel reactants may be regenerated by supplying a source of the element that is consumed in the formation of hydrino or products comprising hydrinos such as lower energy hydrogen compounds and compositions of matter. The SunCell® may comprise at least one of a source of H and oxygen to replace any lost by the solid fuel during propagation of the hydrino reaction in the SunCell®. The source of at least one of H and O may comprise at least one of H₂, H₂O, and O₂. In an exemplary regenerative embodiment, H₂ that is consumed to form H₂(¼) is replaced by addition of at least one of H₂ and H₂O wherein H₂O may further serve as the source of at least one of HOH catalyst and O₂. Optimally, at least one of CO₂ and a noble gas such as argon may be a component of the reaction mixture wherein CO₂ may serve as a source of oxygen to form HOH catalyst.

In an embodiment, the SunCell® further comprises an electrolysis cell to regenerate at least some of at least one starting material from any products formed in the reaction cell chamber. The starting material may comprise at least one of the reactants of the solid fuel wherein the product may form by the solid fuel reaction to form hydrino reactants. The starting material may comprise the molten metal such as gallium or silver. In an embodiment, the molten metal is non-reactive with the molten metal. An exemplary non-reactive molten metal comprises silver. The electrolysis cell may comprise at least one of the reservoirs 5c, the reaction cell chamber 5b31, and a separate chamber external to at least one of the reservoir 5c and the reaction cell chamber 5b31. The electrolysis cell may comprise at least (i) two electrodes, (ii) inlet and outlet channels and transporters for a separate chamber, (iii) an electrolyte that may comprise at least one of the molten metal, and the reactants and the products in at least one of the reservoir, the reaction cell chamber, and the separate chamber, (iv) an electrolysis power supply, and (v) controller for the electrolysis and controllers and power sources for the transporters into and out of the electrolysis cell where applicable. The transporter may comprise one of the disclosure.

In an embodiment, a solid fuel reaction forms H₂O and H as products or intermediate reaction products. The H₂O may serve as a catalyst to form hydrinos. The reactants comprise at least one oxidant and one reductant, and the reaction comprises at least one oxidation-reduction reaction. The reductant may comprise a metal such as an alkali metal. The reaction mixture may further comprise a source of hydrogen, and a source of H₂O, and may optionally comprise a support such as carbon, carbide, boride, nitride, carbonitrile such as TiCN, or nitrile. The support may comprise a metal powder. The source of H may be selected from the group of alkali, alkaline earth, transition, inner transition, rare earth hydrides, and hydrides of the present disclosure. The source of hydrogen may be hydrogen gas that may further comprise a dissociator such as those of the present disclosure such as a noble metal on a support such as carbon or alumina and others of the present disclosure. The source of water may comprise a compound that dehydrates such as a hydroxide or a hydroxide complex such as those of Al, Zn, Sn, Cr, Sb, and Pb. The source of water may comprise a source of hydrogen and a source of oxygen. The oxygen source may comprise a compound comprising oxygen. Exemplary compounds or molecules are O₂, alkali or alkali earth oxide, peroxide, or superoxide, TeO₂, SeO₂, PO₂, P₂O₅, SO₂, SO₃, M₂SO₄, MHSO₄, CO₂, M₂S₂O₈, MMnO₄, M₂Mn₂O₄, MₓH_{y}PO₄ (x, y=integer), POBr₂, MClO₄, MNO₃, NO, N₂O, NO₂, N₂O₃, Cl₂O₇, and O₂ (M=alkali; and alkali earth or other cation may substitute for M). Other exemplary reactants comprise reagents selected from the group of Li, LiH, LiNO₃, LiNO, LiNO₂, Li₃N, Li₂NH, LiNH₂, LiX, NH₃, LiBH₄, LiAlH₄, Li₃AlH₆, LiOH, Li₂S, LiHS, LiFeSi, Li₂CO₃, LiHCO₃, Li₂SO₄, LiHSO₄, Li₃PO₄, Li₂HPO₄, LiH₂PO₄, Li₂MoO₄, LiNbO₃, Li₂B₄O₇ (lithium tetraborate), LiBO₂, Li₂WO₄, LiAlCl₄, LiGaCl₄, Li₂CrO₄, Li₂Cr₂O₇, Li₂TiO₃, LiZrO₃, LiAlO₂, LiCoO₂, LiGaO₂, Li₂GeO₃, LiMn₂O₄, Li₄SiO₄, Li₂SiO₃, LiTaO₃, LiCuCl₄, LiPdCl₄, LiVO₃, LiIO₃, LiBrO₃, LiXO₃ (X═F, Br, Cl, I), LiFeO₂, LiIO₄, LiBrO₄, LiIO₄, LiXO₄ (X═F, Br, Cl, I), LiScOₙ, LiTiOₙ, LiVOₙ, LiCrOₙ, LiCr₂Oₙ, LiMn₂Oₙ, LiFeOₙ, LiCoOₙ, LiNiOₙ, LiNi₂Oₙ, LiCuOₙ, and LiZnOₙ, where n=1, 2, 3, or 4, an oxyanion, an oxyanion of a strong acid, an oxidant, a molecular oxidant such as V₂O₃, I₂O₅, MnO₂, Re₂O₇, CrO₃, RuO₂, AgO, PdO, PdO₂, PtO, PtO₂, and NH₄X wherein X is a nitrate or other suitable anion given in the CRC, and a reductant. Another alkali metal or other cation may substitute for Li. Additional sources of oxygen may be selected from the group of MCoO₂, MGaO₂, M₂GeO₃, MMn₂O₄, M₄SiO₄, M₂SiO₃, MTaO₃, MVO₃, MIO₃, MFeO₂, MIO₄, MClO₄, MScOₙ, MTiOₙ, MVOₙ, MCrOₙ, MCr₂Oₙ, MMn₂Oₙ, MFeOₙ, MCoOₙ, MNiOₙ, MNi₂Oₙ, MCuOₙ, and MZnOₙ, where M is alkali and n=1, 2, 3, or 4, an oxyanion, an oxyanion of a strong acid, an oxidant, a molecular oxidant such as V₂O₃, I₂O₅, MnO₂, Re₂O₇, CrO₃, RuO₂, AgO, PdO, PdO₂, PtO, PtO₂, I₂O₄, I₂O₅, I₂O₉, SO₂, SO₃, CO₂, N₂O, NO, NO₂, N₂O₃, N₂O₄, N₂O₅, Cl₂O, ClO₂, Cl₂O₃, Cl₂O₆, Cl₂O₇, PO₂, P₂O₃, and P₂O₅. The reactants may be in any desired ratio that forms hydrinos. An exemplary reaction mixture is 0.33 g of LiH, 1.7 g of LiNO₃ and the mixture of 1 g of MgH₂ and 4 g of activated C powder. Additional suitable exemplary reactions to form at least one of the reacts H₂O catalyst and H₂ are given in TABLES 2, 3, and 4.

TABLE 2
Thermally reversible reaction cycles regarding H₂O catalyst and H₂. [L. C. Brown, G. E.
Besenbruch, K. R. Schultz, A. C. Marshall, S. K. Showalter, P. S. Pickard and J. F. Funk,
Nuclear Production of Hydrogen Using Thermochemical Water-Splitting Cycles, a preprint of
a paper to be presented at the International Congress on Advanced Nuclear Power Plants (ICAPP)
in Hollywood, Florida, Jun. 19-13, 2002, and published in the Proceedings.]

| | Name | | | |
|---|---|---|---|---|
| Cycle | Reaction | T/E* | | T(° C.) |
| 1 | Westinghouse | T | 850 | 2H₂SO₄(g) → 2SO₂(g) + 2H₂O(g) + O₂(g) |
| | | E | 77 | SO₂(g) + 2H₂O(a) → → H₂SO₄(a) + H₂(g) |
| 2 | Ispra Mark 13 | T | 850 | 2H₂SO₄(g) → 2SO₂(g) + 2H₂O(g) + O₂(g) |
| | | E | 77 | 2HBr(a) → Br₂(a) + H₂(g) |
| | | T | 77 | Br₂(l) + SO₂(g) + 2H₂O(l) → 2HBr(g) + H₂SO₄(a) |
| 3 | UT-3 Univ. of | T | 600 | 2Br₂(g) + 2CaO → 2CaBr₂ + O₂(g) |
| | Tokyo | T | 600 | 3FeBr₂ + 4H₂O → Fe₃O₄ + 6HBr + H₂(g) |
| | | T | 750 | CaBr₂ + H₂O → CaO + 2HBr |
| | | T | 300 | Fe₃O4 + 8HBr → Br₂ + 3FeBr₂ + 4H₂O |
| 4 | Sulfur-Iodine | T | 850 | 2H₂SO₄(g) → 2SO₂(g) + 2H₂O(g) + O₂(g) |
| | | T | 450 | 2HI → I₂(g) + H₂(g) |
| | | T | 120 | I₂ + SO₂(a) + 2H₂O → 2HI(a) + H₂SO₄(a) |
| 5 | Julich Center EOS | T | 800 | 2Fe₃O₄ + 6FeSO₄ → 6Fe₂O₃ + 6SO₂ + O₂(g) |
| | | T | 700 | 3FeO + H₂O → Fe₃O₄ + H₂(g) |
| | | T | 200 | Fe₂O₃ + SO₂ → FeO + FeSO₄ |
| 6 | Tokyo Inst. | T | 1000 | 2MnFe₂O₄ + 3Na₂CO₃ + H₂O → 2Na₃MnFe₂O₆ + 3CO₂(g) + H [symbol] |
| | Tech. Ferrite | T | 600 | 4Na₃MnFe₂O₆ + 6CO₂(g) → 4MnFe₂O₄ + 6Na₂CO₃ + O₂(g) |
| 7 | Hallett Air | T | 800 | 2Cl₂(g) + 2H₂O(g) → 4HCl(g) + O₂(g) |
| | Products 1965 | E | 25 | 2HCl → Cl₂(g) + H₂(g) |
| 8 | Gaz de France | T | 725 | 2K + 2KOH → 2K₂O + H₂(g) |
| | | T | 825 | 2K₂O → 2K + K₂O₂ |
| | | T | 125 | 2K₂O₂ + 2H₂O → 4KOH + O₂(g) |
| 9 | Nickel Ferrite | T | 800 | NiMnFe₄O₆ + 2H₂O → NiMnFe₄O₆ + 2H₂(g) |
| | | T | 800 | NiMnFe₄O₈ → NiMnFe₄O₆ + O₂(g) |
| 10 | Aachen Univ | T | 850 | 2Cl₂(g) + 2H₂O(g) → 4HCl(g) + O₂(g) |
| | Julich 1972 | T | 170 | 2CrCl₂ + 2HCl → 2CrCl₃ + H₂(g) |
| | | T | 800 | 2CrCl₃ → 2CrCl₂ + Cl₂(g) |
| 11 | Ispra Mark 1C | T | 100 | 2CuBr₂ + Ca(OH)₂ → 2CuO + 2CaBr₂ + H₂O |
| | | T | 900 | 4CuO(s) → 2Cu₂O(s) + O₂(g) |
| | | T | 730 | CaBr₂ + 2H₂O → Ca(OH)₂ + 2HBr |
| | | T | 100 | Cu₂O + 4HBr → 2CuBr₂ + H₂(g) + H₂O |
| 12 | LASL- U | T | 25 | 3CO₂ + U₃O₈ + H₂O → 3UO₂CO₃ + H₂(g) |
| | | T | 250 | 3UO₂CO₃ → 3CO₂(g) + 3UO₃ |
| | | T | 700 | 6UO₃(s) → 2U₃O₈(s) + O₂(g) |
| 13 | Ispra Mark 8 | T | 700 | 3MnCl₂ + 4H₂O → Mn₃O₄ + 6HCl + H₂(g) |
| | | T | 900 | 3MnO₂ → Mn₃O₄ + O₂(g) |
| | | T | 100 | 4HCl + Mn₃O₄ → 2MnCl₂(a) + MnO₂ + 2H₂O |
| 14 | Ispra Mark 6 | T | 850 | 2Cl₂(g) + 2H₂O(g) → 4HCl(g) + O₂(g) |
| | | T | 170 | 2CrCl₂ + 2HCl → 2CrCl₃ + H₂(g) |
| | | T | 700 | 2CrCl₃ + 2FeCl₂ → 2CrCl₂ + 2FeCl₃ |
| | | T | 420 | 2FeCl₃ → Cl₂(g) + 2FeCl₂ |
| 15 | Ispra Mark 4 | T | 850 | 2Cl₂(g) + 2H₂O(g) → 4HCl(g) + O₂(g) |
| | | T | 100 | 2FeCl₂ + 2HCl + S → 2FeCl₃ + H₂S |
| | | T | 420 | 2FeCl₃ → Cl₂(g) + 2FeCl₂ |
| | | T | 800 | H₂S → S + H₂(g) |
| 16 | Ispra Mark 3 | T | 850 | 2Cl₂(g) + 2H₂O(g) → 4HCl(g) + O₂(g) |
| | | T | 170 | 2VOCl₂ + 2HCl → 2VOCl₃ + H₂(g) |
| | | T | 200 | 2VOCl₃ → Cl₂(g) + 2VOCl₂ |
| 17 | Ispra Mark 2 | T | 100 | Na₂O•MnO₂ + H₂O → 2NaOH(a) + MnO₂ |
| | (1972) | T | 487 | 4MnO₂(s) → 2Mn₂O₃(s) + O₂(g) |
| | | T | 800 | Mn₂O₃ + 4NaOH → 2Na₂O•MnO₂ + H₂(g) + H₂O |
| 18 | Ispra CO/Mn3O4 | T | 977 | 6Mn₂O₃ → 4Mn₃O₄ + O₂(g) |
| | | T | 700 | C(s) + H₂O(g) → CO(g) + H₂(g) |
| | | T | 700 | CO(g) + 2Mn₃O₄ → C + 3Mn₂O₃ |
| 19 | Ispra Mark 7B | T | 1000 | 2Fe₂O₃ + 6Cl₂(g) → 4FeCl₃ + 3O₂(g) |
| | | T | 420 | 2FeCl₃ → Cl₂(g) + 2FeCl₂ |
| | | T | 650 | 3FeCl₂ + 4H₂O → Fe₃O₄ + 6HCl + H₂(g) |
| | | T | 350 | 4Fe₃O₄ + O₂(g) → 6Fe₂O₃ |
| | | T | 400 | 4HCl + O₂(g) → 2Cl₂(g) + 2H₂O |
| 20 | Vanadium | T | 850 | 2Cl₂(g) + 2H₂O(g) → 4HCl(g) + O₂(g) |
| | Chloride | T | 25 | 2HCl + 2VCl₂ → 2VCl₃ + H₂(g) |
| | | T | 700 | 2VCl₃ → VCl₄ + VCl₂ |
| | | T | 25 | 2VCl₄ → Cl₂(g) + 2VCl₃ |
| 21 | Ispra Mark 7A | T | 420 | 2FeCl₃(l) → Cl₂(g) + 2FeCl₂ |
| | | T | 650 | 3FeCl₂ + 4H₂O(g) → Fe₃O₄ + 6HCl(g) + H₂(g) |
| | | T | 350 | 4Fe₃O₄ + O₂(g) → 6Fe₂O₃ |
| | | T | 1000 | 6Cl₂(g) + 2Fe₂O₃ → 4FeCl₃(g) + 3O₂(g) |
| | | T | 120 | Fe₂O₃ + 6HCl(a) → 2FeCl₃(a) + 3H₂O(l) |
| 22 | GA Cycle 23 | T | 800 | H₂S(g) → S(g) + H₂(g) |
| | | T | 850 | 2H₂SO₄(g) → 2SO₂(g) + 2H₂O(g) + O₂(g) |
| | | T | 700 | 3S + 2H₂O(g) → 2H₂S(g) + SO₂(g) |
| | | T | 25 | 3SO₂(g) + 2H₂O(l) → 2H₂SO₄(a) + S |
| | | T | 25 | S(g) + O₂(g) → SO₂(g) |
| 23 | US -Chlorine | T | 850 | 2Cl₂(g) + 2H₂O(g) → 4HCl(g) + O₂(g) |
| | | T | 200 | 2CuCl + 2HCl → 2CuCl₂ + H₂(g) |
| | | T | 500 | 2CuCl₂ → 2CuCl + Cl₂(g) |
| 24 | Ispra Mark | T | 420 | 2FeCl₃ → Cl₂(g) + 2FeCl₂ |
| | | T | 150 | 3Cl₂(g) + 2Fe₃O₄ + 12HCl → 6FeCl₃ + 6H₂O + O₂(g) |
| | | T | 650 | 3FeCl₂ + 4H₂O → Fe₃O₄ + 6HCl + H₂(g) |
| 25 | Ispra Mark 6C | T | 850 | 2Cl₂(g) + 2H₂O(g) → 4HCl(g) + O₂(g) |
| | | T | 170 | 2CrCl₂ + 2HCl → 2CrCl₃ + H₂(g) |
| | | T | 700 | 2CrCl₃ + 2FeCl₂ → 2CrCl₂ + 2FeCl₃ |
| | | T | 500 | 2CuCl₂ → 2CuCl + Cl₂(g) |
| | | T | 300 | CuCl + FeCl₃ → CuCl₂ + FeCl₂ |

*T = thermochemical, E = electrochemical. [symbol]
indicates data missing or illegible when filed

TABLE 3
Thermally reversible reaction cycles regarding H₂O catalyst and H₂. [C.
Perkins and A. W. Weimer, Solar-Thermal Production of Renewable Hydrogen, AIChE
Journal, 55 (2), (2009), pp. 286-293.]

| Cycle | Reaction Steps |
|---|---|
| High Temperature Cycles | |
| Zn/ZnO | $ZnO {\to }^{ 1600 - 18 \; 0 {0}^{∘} C . } Zn + \frac{1}{2} {O}_{2}$ |
| | $Zn + {H}_{2} O {\to }^{ {400}^{∘} C . } ZnO + {H}_{2}$ |
| FeO/Fe₃O₄ | ${Fe}_{3} {O}_{4} {\to }^{ 2000 - {2300}^{∘} C . } 3 FeO + \frac{1}{2} {O}_{2}$ |
| | $3 FeO + {H}_{2} O {\to }^{ {400}^{∘} C . } {Fe}_{3} {O}_{4} + {H}_{2}$ |
| Cadmium carbonate | $CdO {\to }^{ 1450 - {1500}^{∘} C . } Cd + \frac{1}{2} {O}_{2}$ |
| | $Cd + {H}_{2} O + {CO}_{2} {\to }^{ {350}^{∘} C . } {CdCO}_{3} + {H}_{2}$ |
| | ${CdCO}_{3} {\to }^{ {500}^{∘} C . } {CO}_{2} + CdO$ |
| Hybrid cadmium | $CdO {\to }^{ 1450 - {1500}^{∘} C . } Cd + \frac{1}{2} {O}_{2}$ |
| | $Cd + 2 {H}_{2} O {\to }^{ {25}^{∘} C . , electrochemical } {Cd ( OH )}_{2} + {H}_{2}$ |
| | ${Cd ( OH )}_{2} {\to }^{ {375}^{∘} C . } CdO + {H}_{2} O$ |
| Sodium manganese | ${Mn}_{2} {O}_{3} {\to }^{ 1400 - {1600}^{∘} C . } 2 MnO + \frac{1}{2} {O}_{2}$ |
| | $2 MnO + 2 NaOH {\to }^{ {627}^{∘} C . } 2 {NaMnO}_{2} + {H}_{2}$ |
| | $2 {NaMnO}_{2} + {H}_{2} O {\to }^{ {25}^{∘} C . } {Mn}_{2} {O}_{3} + 2 NaOH$ |
| M-Ferrite (M = Co, Ni, Zn) | ${Fe}_{3 - x} {M}_{x} {O}_{4} {\to }^{ 1200 - {1400}^{∘} C . } {Fe}_{3 - x} {M}_{x} {O}_{4 - δ} + \frac{δ}{2} {O}_{2}$ |

${Fe}_{3 - x} {M}_{x} {O}_{4 - δ} + {δ H}_{2} O {\to }^{ 1000 - {1200}^{∘} C . } {Fe}_{3 - x} {M}_{x} {O}_{4} + δ {H}_{2}$

| | |
|---|---|
| Low Temperature Cycles | |
| Sulfur-Iodine | ${H}_{2} {SO}_{4} {\to }^{ {850}^{∘} C . } {SO}_{2} + {H}_{2} O + \frac{1}{2} {O}_{2}$ |
| | ${I}_{2} + {SO}_{4} + 2 {H}_{2} O {\to }^{ {100}^{∘} C . } 2 HI + {H}_{2} {SO}_{4}$ |
| | $2 HI {\to }^{ {300}^{∘} C . } {I}_{2} + {H}_{2}$ |
| Hybrid sulfur | ${H}_{2} {SO}_{4} {\to }^{ {850}^{∘} C . } {SO}_{2} + {H}_{2} O + \frac{1}{2} {O}_{2}$ |
| | ${SO}_{2} + 2 {H}_{2} O {\to }^{ {77}^{∘} C . , electrochemical } {H}_{2} {SO}_{4} + {H}_{2}$ |
| Hybrid copper chloride | ${Cu}_{2} {OCl}_{2} {\to }^{ {5 \; 50}^{∘} C . } 2 CuCl + \frac{1}{2} {O}_{2}$ |
| | $2 Cu + 2 HCl {\to }^{ {425}^{∘} C . } {H}_{2} + 2 CuCl$ |
| | $4 CuCl {\to }^{ {25}^{∘} C . , electrochemical } 2 Cu + 2 {CuCl}_{2}$ |
| | $2 {CuCl}_{2} + {H}_{2} O {\to }^{ {3 \; 25}^{∘} C . } {Cu}_{2} {OCl}_{2} + 2 HCl$ |

TABLE 4
Thermally reversible reaction cycles regarding H₂O catalyst and H₂. [S. Abanades, P. Charvin, G. Flamant, P. Neveu, Screening of Water-Splitting
Thermochemical Cycles Potentially Attractive for Hydrogen Production by Concentrated Solar Energy, Energy, 31, (2006), pp. 2805-2822.]

| | | | Number of | Maximum | | |
|---|---|---|---|---|---|---|
| | Name of | List of | chemical | temperature | | |
| No ID | the cycle | elements | steps | (° C.) | Reactions | |
| 6 | ZnO/Zn | Zn | 2 | 2000 | ZnO → Zn + ½O₂ | (2000° C.) |
| | | | | | Zn + H₂O → ZnO + H₂ | (1100° C.) |
| 7 | Fe₃O₄/FeO | Fe | 2 | 2200 | Fe₃O₄ → FeO + ½O₂ | (2200° C.) |
| | | | | | 3FeO + H₂O → Fe₃O₄ + H₂ | (400° C.) |
| 194 | In₂O₃/In₂O | In | 2 | 2200 | In₂O₃ → In₂O₃ + O₂ | (2200° C.) |
| | | | | | In2O + 2H₂O → In₂O₃ + 2H₂ | (800° C.) |
| 194 | SnO₂/Sn | Sn | 2 | 2650 | SnO₂ → Sn + O₂ | (2650° C.) |
| | | | | | Sn + 2H₂O → SnO₂ + 2H₂ | (600° C.) |
| 83 | MnO/MnSO₄ | Mn, S | 2 | 1100 | MnSO₄ → MnO + SO₂ + ½O₂ | (1100° C.) |
| | | | | | MnO + H₂O + SO₂ → MnSO₄ + H₂ | (250° C.) |
| 84 | FeO/FeSO₄ | Fe, S | 2 | 1100 | FeSO₄ → FeO + SO₂ + ½O₂ | (1100° C.) |
| | | | | | FeO + H₂O + SO₂ → FeSO₄ + H₂ | (250° C.) |
| 86 | CoO/CoSO₄ | Co, S | 2 | 1100 | CoSO₄ → CoO + SO₂ + ½O₂ | (1100° C.) |
| | | | | | CoO + H₂O + SO₂ → CoSO₄ + H₂ | (200° C.) |
| 200 | Fe₃O₄/FeCl₂ | Fe, Cl | 2 | 1500 | Fe₃O₄ + 6HCl → 3FeCl₂ + 3H₂O + ½O₂ | (1500° C.) |
| | | | | | 3FeCl₂ + 4H₂O → Fe₃O₄ + 6HCl + H₂ | (700° C.) |
| 14 | FeSO₄ Julich | Fe, S | 3 | 1800 | 3FeO(s) + H₂O → Fe₃O₄(s) + H₂ | (200° C.) |
| | | | | | Fe₃O₄(s) + FeSO₄ → 3Fe₂O₃(s) + 3SO₂(g) + ½O₂ | (800° C.) |
| | | | | | 3Fe₂O₃(s) + 3SO₂ → 3FeSO₄ + 3FeO(s) | (1800° C.) |
| 85 | FeSO₄ | Fe, S | 3 | 2300 | 3FeO(s) + H₂O → Fe₃O₄(s) + H₂ | (200° C.) |
| | | | | | Fe₃O₄(s) + 3SO₃(g) → 3FeSO₄ + ½O₂ | (300° C.) |
| | | | | | FeSO₄ → FeO + SO₃ | (2300° C.) |
| 109 | C7 IGT | Fe, S | 3 | 1000 | Fe₃O₃(s) + 2SO₂(g) + H₂O → 2FeSO₄(s) + H₂ | (125° C.) |
| | | | | | 2FeSO₄(s) → Fe₃O₃(s) + SO₂(g) + SO₃(g) | (700° C.) |
| | | | | | SO₃(g) → SO₂(g) + ½O₂(g) | (1000° C.) |
| 21 | Shell Process | Cu, S | 3 | 1750 | 6Cu(s) + 3H₂O → 3Cu₂O(s) + 3H₂ | (500° C.) |
| | | | | | Cu₂O(s) + 2SO₂ + 3/2O₂ → 2CuSO₄ | (300° C.) |
| | | | | | 2Cu₂O(s) + 2CuSO₄ → 6CU + 2SO₂ + 3O₂ | (1750° C.) |
| 87 | CuSO₄ | Cu, S | 3 | 1500 | Cu₂O(s) + H₂O(g) → Cu(s) + Cu(OH)₂ | (1500° C.) |
| | | | | | Cu(OH)₂ + SO₂(g) → CuSO₄ + H₂ | (100° C.) |
| | | | | | CuSO₄ + Cu(s) → Cu₂O(s) + SO₂ + ½O₂ | (1500° C.) |
| 110 | LASL BaSO₄ | Ba, Mo, S | 3 | 1300 | SO₂ + H₂O + BaMoO₄ → BaSO₃ + MoO₃ + H₂O | (300° C.) |
| | | | | | BaSO₃ + H₂O → BaSO₄ + H₂ | |
| | | | | | BaSO₄(s) + MoO₃(s) → BaMoO₄(s) + SO₂(g) + ½O₂ | (1300° C.) |
| 4 | Mark 9 | Fe, Cl | 3 | 900 | 3FeCl₂ + 4H₂O → Fe₃O₄ + 6HCl + H₂ | (680° C.) |
| | | | | | Fe₃O₄ + 3/2Cl₂ + 6HCl → 3FeCl₃ + 3H₂O + ½O₂ | (900° C.) |
| | | | | | 3FeCl₃ → 3FeCl₂ + 3/2Cl₂ | (420° C.) |
| 16 | Euratom 1972 | Fe, Cl | 3 | 1000 | H₂O + Cl₂ → 2HCl + ½O₂ | (1000° C.) |
| | | | | | 2HCl + 2FeCl₂ → 2FeCl₃ + H₂ | (600° C.) |
| | | | | | 2FeCl₃ → 2FeCl₂ + Cl₂ | (350° C.) |
| 20 | Cr, Cl Julich | Cr, Cl | 3 | 1600 | 2CrCl₂(s, T_{f} = 815° C.) + 2HCl → 2CrCl₃(s) + H₂ | (200° C.) |
| | | | | | 2CrCl₃ (s, T_{f} = 1150° C.) → 2CrCl₂(s) + Cl₂ | (1600° C.) |
| | | | | | H₂O + Cl₂ → 2HCl + ½O₂ | (1000° C.) |
| 27 | Mark 8 | Mn, Cl | 3 | 1000 | 6MnCl₂(l) + 8H₂O → 2Mn₃O₄ + 12HCl + 2H₂ | (700° C.) |
| | | | | | 3Mn₃O₄(s) + 12HCl → 6MnCl₂(s) + 3MnO₂(s) + 6H₂O | (100° C.) |
| | | | | | 3MnO₂(s) → Mn₃O₄(s) + O₂ | (1000° C.) |
| 37 | Ta Funk | Ta, Cl | 3 | 2200 | H₂O + Cl₂ → 2HCl + ½O₂ | (1000° C.) |
| | | | | | 2TaCl₂ + 2HCl → 2TaCl₃ + H₂ | (100° C.) |
| | | | | | 2TaCl₃ → 2TaCl₂ + Cl₂ | (2200° C.) |
| 78 | Mark 3 | V, Cl | 3 | 1000 | Cl₂(g) + H₂O(g) → 2HCl(g) + ½O₂(g) | (1000° C.) |
| | Euratom JRC | | | | 2VOCl₂(s) + 2HCl(g) → 2VOCl₃(g) + H₂(g) | (170° C.) |
| | Ispra (Italy) | | | | 2VOCl₃(g) → Cl₂(g) + 2VOCl₂(s) | (200° C.) |
| 144 | Bi, Cl | Bi, Cl | 3 | 1700 | H₂O + Cl₂ → 2HCl + ½O₂ | (1000° C.) |
| | | | | | 2BiCl₂ + 2HCl → 2BiCl₃ + H₂ | (300° C.) |
| | | | | | 2BiCl₃(T_{f} = 233° C., T_{eb} = 441° C.) → 2BiCl₂ + Cl₂ | (1700° C.) |
| 146 | Fe, Cl Julich | Fe, Cl | 3 | 1800 | 3Fe(s) + 4H₂O → Fe₃O₄(s) + 4H₂ | (700° C.) |
| | | | | | Fe₃O₄ + 6HCl → 3FeCl₂(g) + 3H₂O + ½O₂ | (1800° C.) |
| | | | | | 3FeCl₂ + 3H₂ → 3Fe(s) + 6HCl | (1300° C.) |
| 147 | Fe, Cl Cologne | Fe, Cl | 3 | 1800 | 3/2FeO(s) + 3/2Fe(s) + 2.5H₂O → Fe₃O₄(s) + 2.5H₂ | (1000° C.) |
| | | | | | Fe₃O₄ + 6HCl → 3FeCl₂(g) + 3H₂O + ½O₂ | (1800° C.) |
| | | | | | 3FeCl₂ + H₂O + 3/2H₂ → _{3/2}FeO(s) + 3/2Fe(s) + 6HCl | (700° C.) |
| 25 | Mark 2 | Mn, Na | 3 | 900 | Mn₂O₃(s) + 4NaOH → 2Na₂O•MnO₂ + H₂O + H₂ | (900° C.) |
| | | | | | 2Na₂O•MnO₂ + 2H₂O → 4NaOH + 2MnO₂(s) | (100° C.) |
| | | | | | 2MnO₂(s) → Mn₂O₃(s) + ½O₂ | (600° C.) |
| 28 | Li, Mn LASL | Mn, Li | 3 | 1000 | 6LiOH + 2Mn₃O₄ → 3Li₂O•Mn₂O₃ + 2H₂O + H₂ | (700° C.) |
| | | | | | 3Li₂O•Mn₂O₃ + 3H₂O → 6LiOH + 3 Mn₂O₃ | (80° C.) |
| | | | | | 3Mn₂O₃ → 2Mn₃O₄ + ½O₂ | (1000° C.) |
| 199 | Mn PSI | Mn, Na | 3 | 1500 | 2MnO + 2NaOH → 2NaMnO₂ + H₂ | (800° C.) |
| | | | | | 2NaMnO₂ + H₂O → Mn₂O₃ + 2NaOH | (100° C.) |
| | | | | | Mn₂O₃(l) → 2MnO(s) + ½O₂ | (1500° C.) |
| 178 | Fe, M ORNL | Fe, | 3 | 1300 | 2Fe₃O₄ + 6MOH → 3MFeO₂ + 2H₂O + H₂ | (500° C.) |
| | | (M = Li, | | | 3MFeO₂ + 3H₂O → 6MOH + 3Fe₂O₃ | (100° C.) |
| | | K, Na) | | | 3Fe₂O₃(s) → 2Fe₃O₄(s) + ½O₂ | (1300° C.) |
| 33 | Sn Souriau | Sn | 3 | 1700 | Sn(l) + 2H₂O → SnO₂ + 2H₂ | (400° C.) |
| | | | | | 2SnO₂(s) → 2SnO + O₂ | (1700° C.) |
| | | | | | 2SnO(s) → SnO₂ + Sn(l) | (700° C.) |
| 177 | Co ORNL | Co, Ba | 3 | 1000 | CoO(s) + xBa(OH)₂(s) → BaₓCoO_{y}(s) + (y − x − 1)H₂ + | (850° C.) |
| | | | | | (1 + 2x − y) H₂O | |
| | | | | | BaₓCoO_{y}(s) + xH₂O → xBa(OH)₂(s) + CoO(y − x)(s) | (100° C.) |
| | | | | | CoO(y − x)(s) → CoO(s) + (y − x − 1)/2O₂ | (1000° C.) |
| 183 | Ce, Ti ORNL | Ce, Ti, Na | 3 | 1300 | 2CeO₂(s) + 3TiO₂(s) → Ce₂O₃•3TiO₂ + 1/2O₂ | (800-1300° C.) |
| | | | | | Ce₂O₃•3TiO₂ + 6NaOH → 2CeO₂ + 3Na₂TiO₃ + 2H₂O + H₂ | (800° C.) |
| | | | | | CeO₂ + 3NaTiO₃ + 3H₂O → CeO₂(s) + 3TiO₂(s) + 6NaOH | (150° C.) |
| 269 | Ce, Cl GA | Ce, Cl | 3 | 1000 | H₂O + Cl₂ → 2HCl + ½O₂ | (1000° C.) |
| | | | | | 2CeO₂ + 8HCl → 2CeCl₃ + 4H₂O + Cl₂ | (250° C.) |
| | | | | | 2CeCl₃ + 4H₂O → 2CeO₂ + 6HCl + H₂ | (800° C.) |

Reactants to form H₂O catalyst may comprise a source of O such as an O species and a source of H. The source of the O species may comprise at least one of O₂, air, and a compound or admixture of compounds comprising O. The compound comprising oxygen may comprise an oxidant. The compound comprising oxygen may comprise at least one of an oxide, oxyhydroxide, hydroxide, peroxide, and a superoxide. Suitable exemplary metal oxides are alkali oxides such as Li₂O, Na₂O, and K₂O, alkaline earth oxides such as MgO, CaO, SrO, and BaO, transition oxides such as NiO, Ni₂O₃, FeO, Fe₂O₃, and CoO, and inner transition and rare earth metals oxides, and those of other metals and metalloids such as those of Al, Ga, In, Si, Ge, Sn, Pb, As, Sb, Bi, Se, and Te, and mixtures of these and other elements comprising oxygen. The oxides may comprise a oxide anion such as those of the present disclosure such as a metal oxide anion and a cation such as an alkali, alkaline earth, transition, inner transition and rare earth metal cation, and those of other metals and metalloids such as those of Al, Ga, In, Si, Ge, Sn, Pb, As, Sb, Bi, Se, and Te such as MM′₂ₓO₃ₓ₊₁ or MM′₂ₓO₄ (M=alkaline earth, M′=transition metal such as Fe or Ni or Mn, x=integer) and M₂M′₂ₓO₃ₓ₊₁ or M₂M′₂ₓO₄ (M=alkali, M′=transition metal such as Fe or Ni or Mn, x=integer). Suitable exemplary metal oxyhydroxides are AlO(OH), ScO(OH), YO(OH), VO(OH), CrO(OH), MnO(OH) (α-MnO(OH) groutite and γ-MnO(OH) manganite), FeO(OH), CoO(OH), NiO(OH), RhO(OH), GaO(OH), InO(OH), Ni_{1/2}Co_{1/2}O(OH), and Ni_{1/3}Co_{1/3}Mn_{1/3}O(OH). Suitable exemplary hydroxides are those of metals such as alkali, alkaline earth, transition, inner transition, and rare earth metals and those of other metals and metalloids such as such as Al, Ga, In, Si, Ge, Sn, Pb, As, Sb, Bi, Se, and Te, and mixtures. Suitable complex ion hydroxides are Li₂Zn(OH)₄, Na₂Zn(OH)₄, Li₂Sn(OH)₄, Na₂Sn(OH)₄, Li₂Pb(OH)₄, Na₂Pb(OH)₄, LiSb(OH)₄, NaSb(OH)₄, LiAl(OH)₄, NaAl(OH)₄, LiCr(OH)₄, NaCr(OH)₄, Li₂Sn(OH)₆, and Na₂Sn(OH)₆. Additional exemplary suitable hydroxides are at least one from Co(OH)₂, Zn(OH)₂, Ni(OH)₂, other transition metal hydroxides, Cd(OH)₂, Sn(OH)₂, and Pb(OH). Suitable exemplary peroxides are H₂O₂, those of organic compounds, and those of metals such as M₂O₂ where M is an alkali metal such as Li₂O₂, Na₂O₂, K₂O₂, other ionic peroxides such as those of alkaline earth peroxides such as Ca, Sr, or Ba peroxides, those of other electropositive metals such as those of lanthanides, and covalent metal peroxides such as those of Zn, Cd, and Hg. Suitable exemplary superoxides are those of metals MO₂ where M is an alkali metal such as NaO₂, KO₂, RbO₂, and CsO₂, and alkaline earth metal superoxides. In an embodiment, the solid fuel comprises an alkali peroxide and hydrogen source such as a hydride, hydrocarbon, or hydrogen storage material such as BH₃NH₃. The reaction mixture may comprise a hydroxide such as those of alkaline, alkaline earth, transition, inner transition, and rare earth metals, and Al, Ga, In, Sn, Pb, and other elements that form hydroxides and a source of oxygen such as a compound comprising at least one an oxyanion such as a carbonate such as one comprising alkaline, alkaline earth, transition, inner transition, and rare earth metals, and Al, Ga, In, Sn, Pb, and others of the present disclosure. Other suitable compounds comprising oxygen are at least one of oxyanion compound of the group of aluminate, tungstate, zirconate, titanate, sulfate, phosphate, carbonate, nitrate, chromate, dichromate, and manganate, oxide, oxyhydroxide, peroxide, superoxide, silicate, titanate, tungstate, and others of the present disclosure. An exemplary reaction of a hydroxide and a carbonate is given by

Ca(OH)₂+Li₂CO₃ to CaO+H₂O+Li₂O+CO₂ (60)

In other embodiments, the oxygen source is gaseous or readily forms a gas such as NO₂, NO, N₂O, CO₂, P₂O₃, P₂O₅, and SO₂. The reduced oxide product from the formation of H₂O catalyst such as C, N, NH₃, P, or S may be converted back to the oxide again by combustion with oxygen or a source thereof as given in Mills Prior Applications. The cell may produce excess heat that may be used for heating applications, or the heat may be converted to electricity by means such as a Rankine or Brayton system. Alternatively, the cell may be used to synthesize lower-energy hydrogen species such as molecular hydrino and hydrino hydride ions and corresponding compounds.

In an embodiment, the reaction mixture to form hydrinos for at least one of production of lower-energy hydrogen species and compounds and production of energy comprises a source of atomic hydrogen and a source of catalyst comprising at least one of H and O such those of the present disclosure such as H₂O catalyst. The reaction mixture may further comprise an acid such as H₂SO₃, H₂SO₄, H₂CO₃, HNO₂, HNO₃, HClO₄, H₃PO₃, and H₃PO₄ or a source of an acid such as an acid anhydride or anhydrous acid. The latter may comprise at least one of the group of SO₂, SO₃, CO₂, NO₂, N₂O₃, N₂O₅, Cl₂O₇, PO₂, P₂O₃, and P₂O₅. The reaction mixture may comprise at least one of a base and a basic anhydride such as M₂O (M=alkali), M′O (M′=alkaline earth), ZnO or other transition metal oxide, CdO, CoO, SnO, AgO, HgO, or Al₂O₃. Further exemplary anhydrides comprise metals that are stable to H₂O such as Cu, Ni, Pb, Sb, Bi, Co, Cd, Ge, Au, Ir, Fe, Hg, Mo, Os, Pd, Re, Rh, Ru, Se, Ag, Tc, Te, Tl, Sn, W, Al, V, Zr, Ti, Mn, Zn, Cr, and In. The anhydride may be an alkali metal or alkaline earth metal oxide, and the hydrated compound may comprise a hydroxide. The reaction mixture may comprise an oxyhydroxide such as FeOOH, NiOOH, or CoOOH. The reaction mixture may comprise at least one of a source of H₂O and H₂O. The H₂O may be formed reversibly by hydration and dehydration reactions in the presence of atomic hydrogen. Exemplary reactions to form H₂O catalyst are

Mg(OH)₂ to MgO+H₂O (61)

2LiOH to Li₂O+H₂O (62)

H₂CO₃ to CO₂+H₂O (63)

2FeOOH to Fe₂O₃+H₂O (64)

In an embodiment, H₂O catalyst is formed by dehydration of at least one compound comprising phosphate such as salts of phosphate, hydrogen phosphate, and dihydrogen phosphate such as those of cations such as cations comprising metals such as alkali, alkaline earth, transition, inner transition, and rare earth metals, and those of other metals and metalloids such as those of Al, Ga, In, Si, Ge, Sn, Pb, As, Sb, Bi, Se, and Te, and mixtures to form a condensed phosphate such as at least one of polyphosphates such as [Pₙ O₃ₙ₊₁]⁽ⁿ⁺²⁾⁻, long chain metaphosphates such as [(PO₃)ₙ]ⁿ⁻, cyclic metaphosphates such as [(PO₃)ₙ]ⁿ⁻ with n≥3, and ultraphosphates such as P₄O₁₀. Exemplary reactions are

$$\begin{matrix}( n - 2 ) {NaH}_{2} {PO}_{4} + 2 {Na}_{2} {HPO}_{4} {\to }^{heat} {Na}_{n + 2} {P}_{n} {O}_{3 n + 1} ( polyphosphate ) + ( n - 1 ) {H}_{2} O & ( 65 ) \\ n {Na}_{2} {H}_{2} {PO}_{4} {\to }^{heat} {( {NaPO}_{3} )}_{n} ( metaphosphate ) + n {H}_{2} O & ( 66 )\end{matrix}$$

The reactants of the dehydration reaction may comprise R—Ni that may comprise at least one of Al(OH)₃, and Al₂O₃. The reactants may further comprise a metal M such as those of the present disclosure such as an alkali metal, a metal hydride MH, a metal hydroxide such as those of the present disclosure such as an alkali hydroxide and a source of hydrogen such as H₂ as well as intrinsic hydrogen. Exemplary reactions are

2Al(OH)₃+ to Al₂O₃+3H₂O (67)

Al₂O₃+2NaOH to 2NaAlO₂+H₂O (68)

3MH+Al(OH)₃+ to M₃Al+3H₂O (69)

MoCu+2MOH+4O₂ to M₂MoO₄+CuO+H₂O(M=Li,Na,K,Rb,Cs) (70)

The reaction product may comprise an alloy. The R—Ni may be regenerated by rehydration. The reaction mixture and dehydration reaction to form H₂O catalyst may comprise and involve an oxyhydroxide such as those of the present disclosure as given in the exemplary reaction:

3Co(OH)₂ to 2CoOOH+Co+2H₂O (71)

The atomic hydrogen may be formed from H₂ gas by dissociation. The hydrogen dissociator may be one of those of the present disclosure such as R—Ni or a noble metal or transition metal on a support such as Ni or Pt or Pd on carbon or Al₂O₃. Alternatively, the atomic H may be from H permeation through a membrane such as those of the present disclosure. In an embodiment, the cell comprises a membrane such as a ceramic membrane to allow H₂ to diffuse through selectively while preventing H₂O diffusion. In an embodiment, at least one of H₂ and atomic H are supplied to the cell by electrolysis of an electrolyte comprising a source of hydrogen such as an aqueous or molten electrolyte comprising H₂O. In an embodiment, H₂O catalyst is formed reversibly by dehydration of an acid or base to the anhydride form. In an embodiment, the reaction to form the catalyst H₂O and hydrinos is propagated by changing at least one of the cell pH or activity, temperature, and pressure wherein the pressure may be changed by changing the temperature. The activity of a species such as the acid, base, or anhydride may be changed by adding a salt as known by those skilled in the art. In an embodiment, the reaction mixture may comprise a material such as carbon that may absorb or be a source of a gas such as H₂ or acid anhydride gas to the reaction to form hydrinos. The reactants may be in any desired concentrations and ratios. The reaction mixture may be molten or comprise an aqueous slurry.

In another embodiment, the source of the H₂O catalyst is the reaction between an acid and a base such as the reaction between at least one of a hydrohalic acid, sulfuric, nitric, and nitrous, and a base. Other suitable acid reactants are aqueous solutions of H₂SO₄, HCl, HX (X-halide), H₃PO₄, HClO₄, HNO₃, HNO, HNO₂, H₂S, H₂CO₃, H₂MoO₄, HNbO₃, H₂B₄O₇ (M tetraborate), HBO₂, H₂WO₄, H₂CrO₄, H₂Cr₂O₇, H₂TiO₃, HZrO₃, MAlO₂, HMn₂O₄, HIO₃, HIO₄, HClO₄, or an organic acidic such as formic or acetic acid. Suitable exemplary bases are a hydroxide, oxyhydroxide, or oxide comprising an alkali, alkaline earth, transition, inner transition, or rare earth metal, or Al, Ga, In, Sn, or Pb.

In an embodiment, the reactants may comprise an acid or base that reacts with base or acid anhydride, respectively, to form H₂O catalyst and the compound of the cation of the base and the anion of the acid anhydride or the cation of the basic anhydride and the anion of the acid, respectively. The exemplary reaction of the acidic anhydride SiO₂ with the base NaOH is

4NaOH+SiO₂ to Na₄SiO₄+2H₂O (72)

wherein the dehydration reaction of the corresponding acid is

H₄SiO₄ to 2H₂O+SiO₂ (73)

Other suitable exemplary anhydrides may comprise an element, metal, alloy, or mixture such as one from the group of Mo, Ti, Zr, Si, Al, Ni, Fe, Ta, V, B, Nb, Se, Te, W, Cr, Mn, Hf, Co, and Mg. The corresponding oxide may comprise at least one of MoO₂, TiO₂, ZrO₂, SiO₂, Al₂O₃, NiO, Ni₂O₃, FeO, Fe₂O₃, TaO₂, Ta₂O₅, VO, VO₂, V₂O₃, V₂O₅, B₂O₃, NbO, NbO₂, Nb₂O₅, SeO₂, SeO₃, TeO₂, TeO₃, WO₂, WO₃, Cr₃O₄, Cr₂O₃, CrO₂, CrO₃, MnO, Mn₃O₄, Mn₂O₃, MnO₂, Mn₂O₇, HfO₂, CO₂O₃, CoO, CO₃O₄, CO₂O₃, and MgO. In an exemplary embodiment, the base comprises a hydroxide such as an alkali hydroxide such as MOH (M=alkali) such as LiOH that may form the corresponding basic oxide such as M₂O such as Li₂O, and H₂O. The basic oxide may react with the anhydride oxide to form a product oxide. In an exemplary reaction of LiOH with the anhydride oxide with the release of H₂O, the product oxide compound may comprise Li₂MoO₃ or Li₂MoO₄, Li₂TiO₃, Li₂ZrO₃, Li₂SiO₃, LiAlO₂, LiNiO₂, LiFeO₂, LiTaO₃, LiVO₃, Li₂B₄O₇, Li₂NbO₃, Li₂SeO₃, Li₃PO₄, Li₂SeO₄, Li₂TeO₃, Li₂TeO₄, Li₂WO₄, Li₂CrO₄, Li₂Cr₂O₇, Li₂MnO₄, Li₂HfO₃, LiCoO₂, and MgO. Other suitable exemplary oxides are at least one of the group of As₂O₃, As₂O₅, Sb₂O₃, Sb₂O₄, Sb₂O₅, Bi₂O₃, SO₂, SO₃, CO₂, NO₂, N₂O₃, N₂O₅, Cl₂O₇, PO₂, P₂O₃, and P₂O₅, and other similar oxides known to those skilled in the art. Another example is given by Eq. (91). Suitable reactions of metal oxides are

2LiOH+NiO to Li₂NiO₂+H₂O (74)

3LiOH+NiO to LiNiO₂+H₂O+Li₂O+½H₂ (75)

4LiOH+Ni₂O₃ to 2Li₂NiO₂+2H₂O+½O₂ (76)

2LiOH+Ni₂O₃ to 2LiNiO₂+H₂O (77)

Other transition metals such as Fe, Cr, and Ti, inner transition, and rare earth metals and other metals or metalloids such as Al, Ga, In, Si, Ge, Sn, Pb, As, Sb, Bi, Se, and Te may substitute for Ni, and other alkali metal such as Li, Na, Rb, and Cs may substitute for K. In an embodiment, the oxide may comprise Mo wherein during the reaction to form H₂O, nascent H₂O catalyst and H may form that further react to form hydrinos. Exemplary solid fuel reactions and possible oxidation reduction pathways are

3MoO₂+4LIOH→2Li₂MoO₄+Mo+2H₂O (78)

2MoO₂+4LIOH→2Li₂MoO₄+2H₂ (79)

O²⁻→½O₂+2e⁻ (80)

2H₂O+2e⁻2OH⁻+H₂ (81)

2H₂O+2e⁻→2OH⁻+H+H(¼) (82)

Mo⁴⁺+4e⁻→Mo (83)

The reaction may further comprise a source of hydrogen such as hydrogen gas and a dissociator such as Pd/Al₂O₃. The hydrogen may be any of proteium, deuterium, or tritium or combinations thereof. The reaction to form H₂O catalyst may comprise the reaction of two hydroxides to form water. The cations of the hydroxides may have different oxidation states such as those of the reaction of an alkali metal hydroxide with a transition metal or alkaline earth hydroxide. The reaction mixture and reaction may further comprise and involve H₂ from a source as given in the exemplary reaction:

LiOH+2Co(OH)₂+½H₂ to LiCoO₂+3H₂O+Co (84)

The reaction mixture and reaction may further comprise and involve a metal M such as an alkali or an alkaline earth metal as given in the exemplary reaction:

M+LiOH+Co(OH)₂ to LiCoO₂+H₂O+MH (85)

In an embodiment, the reaction mixture comprises a metal oxide and a hydroxide that may serve as a source of H and optionally another source of H wherein the metal such as Fe of the metal oxide can have multiple oxidation states such that it undergoes an oxidation-reduction reaction during the reaction to form H₂O to serve as the catalyst to react with H to form hydrinos. An example is FeO wherein Fe²⁺ can undergo oxidation to Fe³⁺ during the reaction to form the catalyst. An exemplary reaction is

FeO+3LiOH to H₂O+LiFeO₂+H(1/p)+Li₂O (86)

In an embodiment, at least one reactant such as a metal oxide, hydroxide, or oxyhydroxide serves as an oxidant wherein the metal atom such as Fe, Ni, Mo, or Mn may be in an oxidation state that is higher than another possible oxidation state. The reaction to form the catalyst and hydrinos may cause the atom to undergo a reduction to at least one lower oxidation state. Exemplary reactions of metal oxides, hydroxides, and oxyhydroxides to form H₂O catalyst are

2KOH+NiO to K₂NiO₂+H₂O (87)

3KOH+NiO to KNiO₂+H₂O+K₂O+½H₂ (88)

2KOH+Ni₂O₃ to 2KNiO₂+H₂O (89)

4KOH+Ni₂O₃ to 2K₂NiO₂+2H₂O+½O₂ (90)

2KOH+Ni(OH)₂ to K₂NiO₂+2H₂O (91)

2LiOH+MoO₃ to Li₂MoO₄+H₂O (92)

3KOH+Ni(OH)₂ to KNiO₂+2H₂O+K₂O+½H₂ (93)

2KOH+2NiOOH to K₂NiO₂+2H₂O+NiO+½O₂ (94)

KOH+NiOOH to KNiO₂+H₂O (95)

2NaOH+Fe₂O₃ to 2NaFeO₂+H₂O (96)

Other transition metals such as Ni, Fe, Cr, and Ti, inner transition, and rare earth metals and other metals or metalloids such as Al, Ga, In, Si, Ge, Sn, Pb, As, Sb, Bi, Se, and Te may substitute for Ni or Fe, and other alkali metals such as Li, Na, K, Rb, and Cs may substitute for K or Na. In an embodiment, the reaction mixture comprises at least one of an oxide and a hydroxide of metals that are stable to H₂O such as Cu, Ni, Pb, Sb, Bi, Co, Cd, Ge, Au, Ir, Fe, Hg, Mo, Os, Pd, Re, Rh, Ru, Se, Ag, Tc, Te, Tl, Sn, W, Al, V, Zr, Ti, Mn, Zn, Cr, and In. Additionally, the reaction mixture comprises a source of hydrogen such as H₂ gas and optionally a dissociator such as a noble metal on a support. In an embodiment, the solid fuel or energetic material comprises mixture of at least one of a metal halide such as at least one of a transition metal halide such as a bromide such as FeBr₂ and a metal that forms a oxyhydroxide, hydroxide, or oxide and H₂O. In an embodiment, the solid fuel or energetic material comprises a mixture of at least one of a metal oxide, hydroxide, and an oxyhydroxide such as at least one of a transition metal oxide such as Ni₂O₃ and H₂O.

The exemplary reaction of the basic anhydride NiO with acid HCl is

2HCl+NiO to H₂O+NiCl₂ (97)

wherein the dehydration reaction of the corresponding base is

Ni(OH)₂ to H₂O+NiO (98)

The reactants may comprise at least one of a Lewis acid or base and a Bronsted-Lowry acid or base. The reaction mixture and reaction may further comprise and involve a compound comprising oxygen wherein the acid reacts with the compound comprising oxygen to form water as given in the exemplary reaction:

2HX+POX₃ to H₂O+PX₅ (99)

(X=halide). Similar compounds as POX₃ are suitable such as those with P replaced by S. Other suitable exemplary anhydrides may comprise an oxide of an element, metal, alloy, or mixture that is soluble in acid such as an hydroxide, oxyhydroxide, or oxide comprising an alkali, alkaline earth, transition, inner transition, or rare earth metal, or Al, Ga, In, Sn, or Pb such as one from the group of Mo, Ti, Zr, Si, Al, Ni, Fe, Ta, V, B, Nb, Se, Te, W, Cr, Mn, Hf, Co, and Mg. The corresponding oxide may comprise MoO₂, TiO₂, ZrO₂, SiO₂, Al₂O₃, NiO, FeO or Fe₂O₃, TaO₂, Ta₂O₅, VO, VO₂, V₂O₃, V2O₅, B₂O₃, NbO, NbO₂, Nb₂O₅, SeO₂, SeO₃, TeO₂, TeO₃, WO₂, WO₃, Cr₃O₄, Cr₂O₃, CrO₂, CrO₃, MnO, Mn₃O₄, Mn₂O₃, MnO₂, Mn₂O₇, HfO₂, CO₂O₃, CoO, CO₃O₄, CO₂O₃, and MgO. Other suitable exemplary oxides are of those of the group of Cu, Ni, Pb, Sb, Bi, Co, Cd, Ge, Au, Ir, Fe, Hg, Mo, Os, Pd, Re, Rh, Ru, Se, Ag, Tc, Te, Ti, Sn, W, Al, V, Zr, Ti, Mn, Zn, Cr, and In. In an exemplary embodiment, the acid comprises a hydrohalic acid and the product is H₂O and the metal halide of the oxide. The reaction mixture further comprises a source of hydrogen such as H₂ gas and a dissociator such as Pt/C wherein the H and H₂O catalyst react to form hydrinos.

In an embodiment, the solid fuel comprises a H₂ source such as a permeation membrane or H₂ gas and a dissociator such as Pt/C and a source of H₂O catalyst comprising an oxide or hydroxide that is reduced to H₂O. The metal of the oxide or hydroxide may form metal hydride that serves as a source of H. Exemplary reactions of an alkali hydroxide and oxide such as LiOH and Li₂O are

LiOH+H₂ to H₂O+LiH (100)

Li₂O+H₂ to LiOH+LiH (101)

The reaction mixture may comprise oxides or hydroxides of metals that undergo hydrogen reduction to H₂O such as those of Cu, Ni, Pb, Sb, Bi, Co, Cd, Ge, Au, Ir, Fe, Hg, Mo, Os, Pd, Re, Rh, Ru, Se, Ag, Tc, Te, Tl, Sn, W, Al, V, Zr, Ti, Mn, Zn, Cr, and In and a source of hydrogen such as H₂ gas and a dissociator such as Pt/C.

In another embodiment, the reaction mixture comprises a H₂ source such as H₂ gas and a dissociator such as Pt/C and a peroxide compound such as H₂O₂ that decomposes to H₂O catalyst and other products comprising oxygen such as O₂. Some of the H₂ and decomposition product such as O₂ may react to also form H₂O catalyst.

In an embodiment, the reaction to form H₂O as the catalyst comprises an organic dehydration reaction such as that of an alcohol such as a polyalcohol such as a sugar to an aldehyde and H₂O. In an embodiment, the dehydration reaction involves the release of H₂O from a terminal alcohol to form an aldehyde. The terminal alcohol may comprise a sugar or a derivative thereof that releases H₂O that may serve as a catalyst. Suitable exemplary alcohols are meso-erythritol, galactitol or dulcitol, and polyvinyl alcohol (PVA). An exemplary reaction mixture comprises a sugar+hydrogen dissociator such as Pd/Al₂O₃+H₂. Alternatively, the reaction comprises a dehydration of a metal salt such as one having at least one water of hydration. In an embodiment, the dehydration comprises the loss of H₂O to serve as the catalyst from hydrates such as aqua ions and salt hydrates such as BaI₂ 2H₂O and EuBr₂ nH₂O.

In an embodiment, the reaction to form H₂O catalyst comprises the hydrogen reduction of a compound comprising oxygen such as CO, an oxyanion such as MNO₃ (M=alkali), a metal oxide such as NiO, Ni₂O₃, Fe₂O₃, or SnO, a hydroxide such as Co(OH)₂, oxyhydroxides such as FeOOH, CoOOH, and NiOOH, and compounds, oxyanions, oxides, hydroxides, oxyhydroxides, peroxides, superoxides, and other compositions of matter comprising oxygen such as those of the present disclosure that are hydrogen reducible to H₂O. Exemplary compounds comprising oxygen or an oxyanion are SOCl₂, Na₂S₂O₃, NaMnO₄, POBr₃, K₂S₂O₈, CO, CO₂, NO, NO₂, P₂O₅, N₂O₅, N₂O, SO₂, I₂O₅, NaClO₂, NaClO, K₂SO₄, and KHSO₄. The source of hydrogen for hydrogen reduction may be at least one of H₂ gas and a hydride such as a metal hydride such as those of the present disclosure. The reaction mixture may further comprise a reductant that may form a compound or ion comprising oxygen. The cation of the oxyanion may form a product compound comprising another anion such as a halide, other chalcogenide, phosphide, other oxyanion, nitride, silicide, arsenide, or other anion of the present disclosure. Exemplary reactions are

4NaNO₃(c)+5MgH₂(c) to 5MgO(c)+4NaOH(c)+3H₂O(l)+2N₂(g) (102)

P₂O₅(c)+6NaH(c) to 2Na₃PO₄(c)+3H₂O(g) (103)

NaClO₄(c)+2MgH₂(c) to 2MgO(c)+NaCl(c)+2H₂O (l) (104)

KHSO₄+4H₂ to KHS+4H₂O (105)

K₂SO₄+4H₂ to 2KOH+2H₂O+H₂S (106)

LiNO₃+4H₂ to LiNH₂+3H₂O (107)

GeO₂+2H₂ to Ge+2H₂O (108)

CO₂+H₂ to C+2H₂O (109)

PbO₂+2H₂ to 2H₂O+Pb (110)

V₂O₅+5H₂ to 2V+5H₂O (111)

Co(OH)₂+H₂ to Co+2H₂O (112)

Fe₂O₃+3H₂ to 2Fe+3H₂O (113)

3Fe₂O₃+H₂ to 2Fe₃O₄+H₂O (114)

Fe₂O₃+H₂ to 2FeO+H₂O (115)

Ni₂O₃+3H₂ to 2Ni+3H₂O (116)

3Ni₂O₃+H₂ to 2Ni₃O₄+H₂O (117)

Ni₂O₃+H₂ to 2NiO+H₂O (118)

3FeOOH+½H₂ to Fe₃O₄+2H₂O (119)

3NiOOH+½H₂ to Ni₃O₄+2H₂O (120)

3CoOOH+½H₂ to CO₃O₄+2H₂O (121)

FeOOH+½H₂ to FeO+H₂O (122)

NiOOH+½H₂ to NiO+H₂O (123)

CoOOH+½H₂ to CoO+H₂O (124)

SnO+H₂ to Sn+H₂O (125)

The reaction mixture may comprise a source of an anion or an anion and a source of oxygen or oxygen such as a compound comprising oxygen wherein the reaction to form H₂O catalyst comprises an anion-oxygen exchange reaction with optionally H₂ from a source reacting with the oxygen to form H₂O. Exemplary reactions are

2NaOH+H₂+S to Na₂S+2H₂O (126)

2NaOH+H₂+Te to Na₂Te+2H₂O (127)

2NaOH+H₂+Se to Na₂Se+2H₂O (128)

LiOH+NH₃ to LiNH₂+H₂O (129)

In another embodiment, the reaction mixture comprises an exchange reaction between chalcogenides such as one between reactants comprising O and S. An exemplary chalcogenide reactant such as tetrahedral ammonium tetrathiomolybdate contains the ([MoS₄]²⁻) anion. An exemplary reaction to form nascent H₂O catalyst and optionally nascent H comprises the reaction of molybdate [MoO₄]²⁻ with hydrogen sulfide in the presence of ammonia:

[NH₄]₂[MoO₄]+4H₂S to [NH₄]₂[MoS₄]+4H₂O (130)

In an embodiment, the reaction mixture comprises a source of hydrogen, a compound comprising oxygen, and at least one element capable of forming an alloy with at least one other element of the reaction mixture. The reaction to form H₂O catalyst may comprise an exchange reaction of oxygen of the compound comprising oxygen and an element capable of forming an alloy with the cation of the oxygen compound wherein the oxygen reacts with hydrogen from the source to form H₂O. Exemplary reactions are

NaOH+½H₂+Pd to NaPb+H₂O (131)

NaOH+½H₂+Bi to NaBi+H₂O (132)

NaOH+½H₂+2Cd to Cd₂Na+H₂O (133)

NaOH+½H₂+4Ga to Ga₄Na+H₂O (134)

NaOH+½H₂+Sn to NaSn+H₂O (135)

NaAlH₄+Al(OH)₃+5Ni to NaAlO₂+Ni₅Al+H₂O+5/2H₂ (136)

In an embodiment, the reaction mixture comprises a compound comprising oxygen such as an oxyhydroxide and a reductant such as a metal that forms an oxide. The reaction to form H₂O catalyst may comprise the reaction of an oxyhydroxide with a metal to from a metal oxide and H₂O. Exemplary reactions are

2MnOOH+Sn to 2MnO+SnO+H₂O (137)

4MnOOH+Sn to 4MnO+SnO₂+2H₂O (138)

2MnOOH+Zn to 2MnO+ZnO+H₂O (139)

In an embodiment, the reaction mixture comprises a compound comprising oxygen such as a hydroxide, a source of hydrogen, and at least one other compound comprising a different anion such as halide or another element. The reaction to form H₂O catalyst may comprise the reaction of the hydroxide with the other compound or element wherein the anion or element is exchanged with hydroxide to from another compound of the anion or element, and H₂O is formed with the reaction of hydroxide with H₂. The anion may comprise halide. Exemplary reactions are

2NaOH+NiCl₂+H₂ to 2NaCl+2H₂O+Ni (140)

2NaOH+I₂+H₂ to 2NaI+2H₂O (141)

2NaOH+XeF₂+H₂ to 2NaF+2H₂O+Xe (142)

BiX₃(X=halide)+4Bi(OH)₃ to 3BiOX+Bi₂O₃+6H₂O (143)

The hydroxide and halide compounds may be selected such that the reaction to form H₂O and another halide is thermally reversible. In an embodiment, the general exchange reaction is

NaOH+½H₂+1/yMₓCl_{y}=NaCl+6H₂O+x/yM (171)

wherein exemplary compounds MₓCl_{y} are AlCl₃, BeCl₂, HfCl₄, KAgCl₂, MnCl₂, NaAlCl₄, ScCl₃, TiCl₂, TiCl₃, UCl₃, UCl₄, ZrCl₄, EuCl₃, GdCl₃, MgCl₂, NdCl₃, and YCl₃. At an elevated temperature the reaction of Eq. (171) such as in the range of about 100° C. to 2000° C. has at least one of an enthalpy and free energy of about 0 kJ and is reversible. The reversible temperature is calculated from the corresponding thermodynamic parameters of each reaction. Representative are temperature ranges are NaCl—ScCl₃ at about 800K-900K, NaCl—TiCl₂ at about 300K-400K, NaCl—UCl₃ at about 600K-800K, NaCl—UCl₄ at about 250K-300K, NaCl—ZrCl₄ at about 250K-300K, NaCl—MgCl₂ at about 900K-1300K, NaCl—EuCl₃ at about 900K-1000K, NaCl—NdCl₃ at about >1000K, and NaCl—YCl₃ at about >1000K.

In an embodiment, the reaction mixture comprises an oxide such as a metal oxide such a alkali, alkaline earth, transition, inner transition, and rare earth metal oxides and those of other metals and metalloids such as those of Al, Ga, In, Si, Ge, Sn, Pb, As, Sb, Bi, Se, and Te, a peroxide such as M₂O₂ where M is an alkali metal such as Li₂O₂, Na₂O₂, and K₂O₂, and a superoxide such as MO₂ where M is an alkali metal such as NaO₂, KO₂, RbO₂, and CsO₂, and alkaline earth metal superoxides, and a source of hydrogen. The ionic peroxides may further comprise those of Ca, Sr, or Ba. The reaction to form H₂O catalyst may comprise the hydrogen reduction of the oxide, peroxide, or superoxide to form H₂O. Exemplary reactions are

Na₂O+2H₂ to 2NaH+H₂O (144)

Li₂O₂+H₂ to Li₂O+H₂O (145)

KO₂+3/2H₂ to KOH+H₂O (146)

In an embodiment, the reaction mixture comprises a source of hydrogen such as at least one of H₂, a hydride such as at least one of an alkali, alkaline earth, transition, inner transition, and rare earth metal hydride and those of the present disclosure and a source of hydrogen or other compound comprising combustible hydrogen such as a metal amide, and a source of oxygen such as O₂. The reaction to form H₂O catalyst may comprise the oxidation of H₂, a hydride, or hydrogen compound such as metal amide to form H₂O. Exemplary reactions are

2NaH+O₂ to Na₂O+H₂O (147)

H₂+½O₂ to H₂O (148)

LiNH₂+2O₂ to LiNO₃+H₂O (149)

2LiNH₂+3/2O₂ to 2LiOH+H₂O+N₂ (150)

In an embodiment, the reaction mixture comprises a source of hydrogen and a source of oxygen. The reaction to form H₂O catalyst may comprise the decomposition of at least one of source of hydrogen and the source of oxygen to form H₂O. Exemplary reactions are

NH₄NO₃ to N₂O+2H₂O (151)

NH₄NO₃ to N₂+½O₂+2H₂O (152)

H₂O₂ to ½O₂+H₂O (153)

H₂O₂+H₂ to 2H₂O (154)

The reaction mixtures disclosed herein further comprise a source of hydrogen to form hydrinos. The source may be a source of atomic hydrogen such as a hydrogen dissociator and H₂ gas or a metal hydride such as the dissociators and metal hydrides of the present disclosure. The source of hydrogen to provide atomic hydrogen may be a compound comprising hydrogen such as a hydroxide or oxyhydroxide. The H that reacts to form hydrinos may be nascent H formed by reaction of one or more reactants wherein at least one comprises a source of hydrogen such as the reaction of a hydroxide and an oxide. The reaction may also form H₂O catalyst. The oxide and hydroxide may comprise the same compound. For example, an oxyhydroxide such as FeOOH could dehydrate to provide H₂O catalyst and also provide nascent H for a hydrino reaction during dehydration:

4FeOOH to H₂O+Fe₂O₃+2 FeO+O₂+2H(¼) (155)

wherein nascent H formed during the reaction reacts to hydrino. Other exemplary reactions are those of a hydroxide and an oxyhydroxide or an oxide such as NaOH+FeOOH or Fe₂O₃ to form an alkali metal oxide such as NaFeO₂+H₂O wherein nascent H formed during the reaction may form hydrino wherein H₂O serves as the catalyst. The oxide and hydroxide may comprise the same compound. For example, an oxyhydroxide such as FeOOH could dehydrate to provide H₂O catalyst and also provide nascent H for a hydrino reaction during dehydration:

4FeOOH to H₂O+Fe₂O₃+2FeO+O₂+2H(¼) (156)

wherein nascent H formed during the reaction reacts to hydrino. Other exemplary reactions are those of a hydroxide and an oxyhydroxide or an oxide such as NaOH+FeOOH or Fe₂O₃ to form an alkali metal oxide such as NaFeO₂+H₂O wherein nascent H formed during the reaction may form hydrino wherein H₂O serves as the catalyst. Hydroxide ion is both reduced and oxidized in forming H₂O and oxide ion. Oxide ion may react with H₂O to form OH⁻. The same pathway may be obtained with a hydroxide-halide exchange reaction such as the following

2M(OH)₂+2M′X₂→H₂O+2MX₂+2M′O+1/20₂+2H(¼) (157)

wherein exemplary M and M′ metals are alkaline earth and transition metals, respectively, such as Cu(OH)₂+FeBr₂, Cu(OH)₂+CuBr₂, or Co(OH)₂+CuBr₂. In an embodiment, the solid fuel may comprise a metal hydroxide and a metal halide wherein at least one metal is Fe. At least one of H₂O and H₂ may be added to regenerate the reactants. In an embodiment, M and M′ may be selected from the group of alkali, alkaline earth, transition, inner transition, and rare earth metals, Al, Ga, In, Si, Ge, Sn, Pb, Group 13, 14, 15, and 16 elements, and other cations of hydroxides or halides such as those of the present disclosure. An exemplary reaction to form at least one of HOH catalyst, nascent H, and hydrino is

4MOH+4M′X→H₂O+2M′₂O+M₂O+2MX+X₂+2H(¼) (158)

In an embodiment, the reaction mixture comprises at least one of a hydroxide and a halide compound such as those of the present disclosure. In an embodiment, the halide may serve to facilitate at least one of the formation and maintenance of at least one of nascent HOH catalyst and H. In an embodiment, the mixture may serve to lower the melting point of the reaction mixture.

An acid-base reaction is another approach to H₂O catalyst. Exemplary halides and hydroxides mixtures are those of Bi, Cd, Cu, Co, Mo, and Cd and mixtures of hydroxides and halides of metals having low water reactivity of the group of Cu, Ni, Pb, Sb, Bi, Co, Cd, Ge, Au, Ir, Fe, Hg, Mo, Os, Pd, Re, Rh, Ru, Se, Ag, Tc, Te, Tl, Sn, W, and Zn. In an embodiment, the reaction mixture further comprises H₂O that may serves as a source of at least one of H and catalyst such as nascent H₂O. The water may be in the form of a hydrate that decomposes or otherwise reacts during the reaction.

In an embodiment, the solid fuel comprises a reaction mixture of H₂O and an inorganic compound that forms nascent H and nascent H₂O. The inorganic compound may comprise a halide such as a metal halide that reacts with the H₂O. The reaction product may be at least one of a hydroxide, oxyhydroxide, oxide, oxyhalide, hydroxyhalide, and hydrate. Other products may comprise anions comprising oxygen and halogen such as XO⁻, XO₂⁻, XO₃⁻, and XO₄⁻ (X=halogen). The product may also be at least one of a reduced cation and a halogen gas. The halide may be a metal halide such as one of an alkaline, alkaline earth, transition, inner transition, and rare earth metal, and Al, Ga, In, Sn, Pb, S, Te, Se, N, P, As, Sb, Bi, C, Si, Ge, and B, and other elements that form halides. The metal or element may additionally be one that forms at least one of a hydroxide, oxyhydroxide, oxide, oxyhalide, hydroxyhalide, hydrate, and one that forms a compound having an anion comprising oxygen and halogen such as XO⁻, XO₂⁻, XO₃⁻, and XO₄⁻ (X=halogen). Suitable exemplary metals and elements are at least one of an alkaline, alkaline earth, transition, inner transition, and rare earth metal, and Al, Ga, In, Sn, Pb, S, Te, Se, N, P, As, Sb, Bi, C, Si, Ge, and B. An exemplary reaction is

5MX₂+7H₂O to MXOH+M(OH)₂+MO+M₂O₃+11H(¼)+9/2X₂ (159)

wherein M is a metal such as a transition metal such as Cu and X is halogen such as Cl.

In an embodiment, the solid fuel or energetic material comprises a source of singlet oxygen. An exemplary reaction to generate singlet oxygen is

NaOCl+H₂O₂ to O₂+NaCl+H₂O (160)

In another embodiment, the solid fuel or energetic material comprises a source of or reagents of the Fenton reaction such as H₂O₂.

The solid fuels and reactions may be at least one of regenerative and reversible by at least one the SunCell® plasma or thermal power and the methods disclosed herein and in Mills Prior Applications such as Hydrogen Catalyst Reactor, PCT/US08/61455, filed PCT 4/24/2008; Heterogeneous Hydrogen Catalyst Reactor, PCT/US09/052072, filed PCT 7/29/2009; Heterogeneous Hydrogen Catalyst Power System, PCT/US10/27828, PCT filed Mar. 18, 2010; Electrochemical Hydrogen Catalyst Power System, PCT/US11/28889, filed PCT 3/17/2011; H₂O-Based Electrochemical Hydrogen-Catalyst Power System, PCT/US12/31369 filed Mar. 30, 2012, and CIHT Power System, PCT/US13/041938 filed May 21, 2013 herein incorporated by reference in their entirety.

In an embodiment, the regeneration reaction of a hydroxide and halide compound mixture such as Cu(OH)2+CuBr₂ may by addition of at least one H₂ and H₂O. Exemplary, thermally reversible solid fuel cycles are

T 100 2CuBr₂+Ca(OH)₂→2CuO+2CaBr₂+H₂O (161)

T 730 CaBr₂+2H₂O→Ca(OH)₂+2HBr (162)

T 100 CuO+2HBr→CuBr₂+H₂O (163)

T 100 2CuBr₂+Cu(OH)₂→2CuO+2CaBr₂+H₂O (164)

T 730 CuBr₂+2H₂O→Cu(OH)₂+2HBr (165)

T 100 CuO+2HBr→CuBr₂+H₂O (166)

In an embodiment, wherein at least one of an alkali metal M such as K or Li, and nH (n=integer), OH, O, 2O, O₂, and H₂O serve as the catalyst, the source of H is at least one of a metal hydride such as MH and the reaction of at least one of a metal M and a metal hydride MH with a source of H to form H. One product may be an oxidized M such as an oxide or hydroxide. The reaction to create at least one of atomic hydrogen and catalyst may be an electron transfer reaction or an oxidation-reduction reaction. The reaction mixture may further comprise at least one of H₂, a H₂ dissociator such as at least one of the SunCell® and those of the present disclosure such as Ni screen or R—Ni and an electrically conductive support such as these dissociators and others as well as supports of the present disclosure such as carbon, and carbide, a boride, and a carbonitride. An exemplary oxidation reaction of M or MH is

4MH+Fe₂O₃ to +H₂O+H(1/p)+M₂O+MOH+2Fe+M (167)

wherein at least one of H₂O and M may serve as the catalyst to form H(1/p).

In an embodiment, the source of oxygen is a compound that has a heat of formation that is similar to that of water such that the exchange of oxygen between the reduced product of the oxygen source compound and hydrogen occurs with minimum energy release. Suitable exemplary oxygen source compounds are CdO, CuO, ZnO, SO₂, SeO₂, and TeO₂. Others such as metal oxides may also be anhydrides of acids or bases that may undergo dehydration reactions as the source of H₂O catalyst are MnOₓ, AlOₓ, and SiOₓ. In an embodiment, an oxide layer oxygen source may cover a source of hydrogen such as a metal hydride such as palladium hydride. The reaction to form H₂O catalyst and atomic H that further react to form hydrino may be initiated by heating the oxide coated hydrogen source such as metal oxide coated palladium hydride. In an embodiment, the reaction to form the hydrino catalyst and the regeneration reaction comprise an oxygen exchange between the oxygen source compound and hydrogen and between water and the reduced oxygen source compound, respectively. Suitable reduced oxygen sources are Cd, Cu, Zn, S, Se, and Te. In an embodiment, the oxygen exchange reaction may comprise those used to form hydrogen gas thermally. Exemplary thermal methods are the iron oxide cycle, cerium(IV) oxide-cerium(III) oxide cycle, zinc zinc-oxide cycle, sulfur-iodine cycle, copper-chlorine cycle and hybrid sulfur cycle and others known to those skilled in the art. In an embodiment, the reaction to form hydrino catalyst and the regeneration reaction such as an oxygen exchange reaction occurs simultaneously in the same reaction vessel. The conditions such a temperature and pressure may be controlled to achieve the simultaneity of reaction. Alternately, the products may be removed and regenerated in at least one other separate vessel that may occur under conditions different than those of the power forming reaction as given in the present disclosure and Mills Prior Applications.

The solid fuel may comprise different ions such as alkali, alkaline earth, and other cations with anions such as halides and oxyanions. The cation of the solid fuel may comprise at least one of alkali metals, alkaline earth metals, transition metals, inner transition metals, rare earth metals, Li, Na, K, Rb, Cs, Mg, Ca, Sr, Ba, Ga, Al, V, Zr, Ti, Mn, Zn, Li, Na, K, Rb, Cs, Mg, Ca, Sr, Ba, Al, V, Zr, Ti, Mn, Zn, Cr, Sn, In, Cu, Ni, Pb, Sb, Bi, Co, Cd, Ge, Au, Ir, Fe, Hg, Mo, Os, Pd, Re, Rh, Ru, Se, Ag, Tc, Te, Tl, W, and other cations known in the art that form ionic compounds. The anion may comprise at least one of a hydroxide, a halide, oxide, chalcogenide, sulfate, phosphate, phosphide, nitrate, nitride, carbonate, chromate, silicide, arsenide, boride, perchlorate, periodate, cobalt magnesium oxide, nickel magnesium oxide, copper magnesium oxide, aluminate, tungstate, zirconate, titanate, manganate, carbide, metal oxide, nonmetal oxide; oxide of alkali, alkaline earth, transition, inner transition, and earth metals, and Al, Ga, In, Sn, Pb, S, Te, Se, N, P, As, Sb, Bi, C, Si, Ge, and B, and other elements that form an oxide or oxyanion; LiAlO₂, MgO, CaO, ZnO, CeO₂, CuO, CrO₄, Li₂TiO₃, or SrTiO₃, an oxide comprising an element, metal, alloy, or mixture of the group of Mo, Ti, Zr, Si, Al, Ni, Fe, Ta, V, B, Nb, Se, Te, W, Cr, Mn, Hf, and Co; MoO₂, TiO₂, ZrO₂, SiO₂, Al₂O₃, NiO, FeO or Fe₂O₃, TaO₂, Ta₂O₅, VO, VO₂, V₂O₃, V2O₅, B₂O₃, NbO, NbO₂, Nb₂O₅, SeO₂, SeO₃, TeO₂, TeO₃, WO₂, WO₃, Cr₃O₄, Cr₂O₃, CrO₂, CrO₃, MnO, Mn₃O₄, Mn₂O₃, MnO₂, Mn₂O₇, HfO₂, CoO, CO₂O₃, CO₃O₄, Li₂MoO₃ or Li₂MoO₄, Li₂TiO₃, Li₂ZrO₃, Li₂SiO₃, LiAlO₂, LiNiO₂, LiFeO₂, LiTaO₃, LiVO₃, Li₂B₄O₇, Li₂NbO₃, Li₂PO₄, Li₂SeO₃, Li₂SeO₄, Li₂TeO₃, Li₂TeO₄, Li₂WO₄, Li₂CrO₄, Li₂Cr₂O₇, Li₂MnO₃, Li₂MnO₄, Li₂HfO₃, LiCoO₂, Li₂MoO₄, MoO₂, Li₂WO₄, Li₂CrO₄, and Li₂Cr₂O₇, S, Li₂S, MoO₂, TiO₂, ZrO₂, SiO₂, Al₂O₃, NiO, FeO or Fe₂O₃, TaO₂, Ta₂O₅, VO, VO₂, V₂O₃, V2O₅, P₂O₃, P₂O₅, B₂O₃, and other anions known in the art that form ionic compounds.

In an embodiment, the NH₂ group of an amide such as LiNH₂ serves as the catalyst wherein the potential energy is about 81.6 eV or about 3×27.2 eV. Similar to the reversible H₂O elimination or addition reaction of between acid or base to the anhydride and vice versa, the reversible reaction between the amide and imide or nitride results in the formation of the NH₂ catalyst that further reacts with atomic H to form hydrinos. The reversible reaction between amide, and at least one of imide and nitride may also serve as a source of hydrogen such as atomic H.

### Solid Fuel Molten and Electrolysis Cells

In an embodiment, a reactor to form thermal power and lower energy hydrogen species such as H(1/p) and H₂(1/p) wherein p is an integer comprises a molten salt that serves as a source of at least one of H and HOH catalyst. The molten salt may comprise a mixture of salts such as a eutectic mixture. The mixture may comprise at least one of a hydroxide and a halide such as a mixture of at least one of alkaline and alkaline earth hydroxides and halides such as LiOH—LiBr or KOH—KCl. The reactor may further comprise a heater, a heater power supply, and a temperature controller to maintain the salt in a molten state. The source of at least one of H and HOH catalyst may comprise water. The water may be dissociated in the molten salt. The molten salt may further comprise an additive such as at least one of an oxide and a metal such as a hydrogen dissociator metal such as at least one comprising Ti, Ni, and a noble metal such as Pt or Pd to provide at least one of H and HOH catalyst. In an embodiment, H and HOH may be formed by reaction of at least one of the hydroxide, the halide, and water present in the molten salt. In an exemplary embodiment, at least one of H and HOH may be formed by dehydration of MOH (M=alkali): 2MOH to M₂O+HOH; MOH+H₂O to MOOH+2H; MX+H₂O (X=halide) to MOX+2H wherein dehydration and exchange reaction may be catalyzed by MX. Other embodiments of the reactions of the molten salt are given in the solid fuels disclosure wherein these reactions may comprise SunCell® solid fuel reactants and reactions as well.

In an embodiment, a reactor to form thermal power and lower energy hydrogen species such as H(1/p) and H₂(1/p) wherein p is an integer comprises an electrolysis system comprising at least two electrodes, and electrolysis power supply, an electrolysis controller, a molten salt electrolyte, a heater, a temperature sensor, and a heater controller to maintain a desired temperature, and a source at least one of H and HOH catalyst. The electrodes may be stable in the electrolyte. Exemplary electrodes are nickel and noble metal electrodes. Water may be supplied to the cell and a voltage such as a DC voltage may be applied to the electrodes. Hydrogen may form at the cathode and oxygen may form at the anode. The hydrogen may react with HOH catalyst also formed in the cell to form hydrino. The HOH catalyst may be from added water. The energy from the formation of hydrino may produce heat in the cell. The cell may be well insulated such that the heat from the hydrino reaction may reduce the amount of power required for the heater to maintain the molten salt. The insulation may comprise a vacuum jacket or other thermal insulation known in the art such as ceramic fiber insulation. The reactor may further comprise a heat exchanger. The heat exchanger may remove excess heat to be delivered to an external load.

The molten salt may comprise a hydroxide with at least one other salt such as one chosen from one or more other hydroxides, halides, nitrates, sulfates, carbonates, and phosphates. In an embodiment, the salt mixture may comprise a metal hydroxide and the same metal with another anion of the disclosure such as halide, nitrate, sulfate, carbonate, and phosphate. The molten salt may comprise at least one salt mixture chosen from CsNO₃—CsOH, CsOH—KOH, CsOH—LiOH, CsOH—NaOH, CsOH—RbOH, K₂CO₃—KOH, KBr—KOH, KCl—KOH, KF—KOH, KI—KOH, KNO₃—KOH, KOH—K₂SO₄, KOH—LiOH, KOH—NaOH, KOH—RbOH, Li₂CO₃—LiOH, LiBr—LiOH, LiCl—LiOH, LiF—LiOH, LiI—LiOH, LiNO₃—LiOH, LiOH—NaOH, LiOH—RbOH, Na₂CO₃—NaOH, NaBr—NaOH, NaCl—NaOH, NaF—NaOH, NaI—NaOH, NaNO₃—NaOH, NaOH—Na₂SO₄, NaOH—RbOH, RbCl—RbOH, RbNO₃—RbOH, LiOH—LiX, NaOH—NaX, KOH—KX, RbOH—RbX, CsOH—CsX, Mg(OH)₂—MgX₂, Ca(OH)₂—CaX₂, Sr(OH)₂—SrX₂, or Ba(OH)₂—BaX₂ wherein X═F, Cl, Br, or I, and LiOH, NaOH, KOH, RbOH, CsOH, Mg(OH)₂, Ca(OH)₂, Sr(OH)₂, or Ba(OH)₂ and one or more of AlX₃, VX₂, ZrX₂, TiX₃, MnX₂, ZnX₂, CrX₂, SnX₂, InX₃, CuX₂, NiX₂, PbX₂, SbX₃, BiX₃, CoX₂, CdX₂, GeX₃, AuX₃, IrX₃, FeX₃, HgX₂, MoX₄, OsX₄, PdX₂, ReX₃, RhX₃, RuX₃, SeX₂, AgX₂, TcX₄, TeX₄, TlX, and WX₄ wherein X═F, Cl, Br, or I. The molten salt may comprise a cation that is common to the anions of the salt mixture electrolyte; or the anion is common to the cations, and the hydroxide is stable to the other salts of the mixture. The mixture may be a eutectic mixture. The cell may be operated at a temperature of about that of the melting point of the eutectic mixture but may be operated at higher temperatures. The electrolysis voltage may be at least one range of about 1V to 50 V, 2 V to 25 V, 2V to 10 V, 2 V to 5 V, and 2 V to 3.5 V. The current density may be in at least one range of about 10 mA/cm² to 100 A/cm², 100 mA/cm² to 75 A/cm², 100 mA/cm² to 50 A/cm², 100 mA/cm² to 20 A/cm², and 100 mA/cm² to 10 A/cm².

In another embodiment, the electrolysis thermal power system further comprises a hydrogen electrode such as a hydrogen permeable electrode. The hydrogen electrode may comprise H₂ gas permeated through a metal membrane such as Ni, V, Ti, Nb, Pd, PdAg, or Fe designated by Ni(H₂), V(H₂), Ti(H₂), Nb(H₂), Pd(H₂), PdAg(H₂), Fe(H₂), or 430 SS(H₂). Suitable hydrogen permeable electrodes for a alkaline electrolyte comprise Ni and alloys such as LaNi5, noble metals such as Pt, Pd, and Au, and nickel or noble metal coated hydrogen permeable metals such as V, Nb, Fe, Fe—Mo alloy, W, Mo, Rh, Zr, Be, Ta, Rh, Ti, Th, Pd, Pd-coated Ag, Pd-coated V, Pd-coated Ti, rare earths, other refractory metals, stainless steel (SS) such as 430 SS, and others such metals known to those skilled in the Art. The hydrogen electrode designated M(H₂) wherein M is a metal through which H₂ is permeated may comprise at least one of Ni(H₂), V(H₂), Ti(H₂), Nb(H₂), Pd(H₂), PdAg(H₂), Fe(H₂), and 430 SS(H₂). The hydrogen electrode may comprise a porous electrode that may sparge H₂. The hydrogen electrode may comprise a hydride such as a hydride chosen from R—Ni, LaNi₅H₆, La₂CoiNi₉H₆, ZrCr₂H_{3.8}, LaNi_{3.55}Mn_{0.4}Al_{0.3}Co_{0.75}, ZrMn_{0.5}Cr_{0.2}V_{0.1}Ni_{1.2}, and other alloys capable of storing hydrogen, AB₅ (LaCePrNdNiCoMnAl) or AB₂ (VTiZrNiCrCoMnAlSn) type, where the “ABx” designation refers to the ratio of the A type elements (LaCePrNd or TiZr) to that of the B type elements (VNiCrCoMnAlSn), AB₅-type: MmNi_{3.2}Co_{1.0}Mn_{0.6}Al_{0.11}Mo_{0.09} (Mm=misch metal: 25 wt % La, 50 wt % Ce, 7 wt % Pr, 18 wt % Nd), AB₂-type: Ti_{0.51}Zr_{0.49}V_{0.70}Ni_{1.18}Cr_{0.12} alloys, magnesium-based alloys, Mg_{1.9}Al_{0.1}Ni_{0.8}Co_{0.1}Mn_{0.1} alloy, Mg_{0.72}Sc_{0.28}(Pd_{0.012}+Rh_{0.012}), and Mg₈₀Ti₂₀, Mg₈₀V₂₀, La_{0.8}Nd_{0.2}Ni_{2.4}Co_{2.5}Si_{0.1}, LaNi₅₋ₓMx (M=Mn, Al), (M=Al, Si, Cu), (M=Sn), (M=Al, Mn, Cu) and LaNi₄Co, MmNi_{3.55}Mn_{0.44}Al_{0.3}Co_{0.75}, LaNi_{3.55}Mn_{0.44}Al_{0.3}Co_{0.75}, MgCu₂, MgZn₂, MgNi₂, AB compounds, TiFe, TiCo, and TiNi, ABₙ compounds (n=5, 2, or 1), AB₃₋₄ compounds, ABₓ (A=La, Ce, Mn, Mg; B═Ni, Mn, Co, Al), ZrFe₂, Zr_{0.5}Cs_{0.5}Fe₂, Zr_{0.8}Sc_{0.2}Fe₂, YNi₅, LaNi₅, LaNi_{4.5}Co_{0.5}, (Ce, La, Nd, Pr)Ni₅, Mischmetal-nickel alloy, Ti_{0.98}Zr_{0.02}V_{0.43}Fe_{0.09}Cr_{0.05}Mn_{1.5}, La₂Co₁Ni₉, FeNi, and TiMn₂. In an embodiment, the electrolysis cathode comprises at least one of a H₂O reduction electrode and the hydrogen electrode. In an embodiment, the electrolysis anode comprises at least one of a OH-oxidation electrode and the hydrogen electrode.

In an embodiment of the disclosure, the electrolysis thermal power system comprises at least one of [M′″/MOH-M′halide/M″(H₂)], [M″′/M(OH)₂-M′halide/M″(H₂)], [M″(H₂)/MOH-M′halide/M″′], and [M″(H₂)/M(OH)₂-M′halide/M″′], wherein M is an alkali or alkaline earth metal, M′ is a metal having hydroxides and oxides that are at least one of less stable than those of alkali or alkaline earth metals or have a low reactivity with water, M″ is a hydrogen permeable metal, and M″′ is a conductor. In an embodiment, M′ is metal such as one chosen from Cu, Ni, Pb, Sb, Bi, Co, Cd, Ge, Au, Ir, Fe, Hg, Mo, Os, Pd, Re, Rh, Ru, Se, Ag, Tc, Te, Tl, Sn, W, Al, V, Zr, Ti, Mn, Zn, Cr, In, Pt, and Pb. Alternatively, M and M′ may be metals such as ones independently chosen from Li, Na, K, Rb, Cs, Mg, Ca, Sr, Ba, Al, V, Zr, Ti, Mn, Zn, Cr, Sn, In, Cu, Ni, Pb, Sb, Bi, Co, Cd, Ge, Au, Ir, Fe, Hg, Mo, Os, Pd, Re, Rh, Ru, Se, Ag, Tc, Te, Tl, and W. Other exemplary systems comprise [M″/MOH M″X/M′(H₂)] and [M′(H₂)/MOH M′X/M″)] wherein M, M′, M″, and M″′ are metal cations or metal, X is an anion such as one chosen from hydroxides, halides, nitrates, sulfates, carbonates, and phosphates, and M′ is H₂ permeable. In an embodiment, the hydrogen electrode comprises a metal such as at least one chosen from V, Zr, Ti, Mn, Zn, Cr, Sn, In, Cu, Ni, Pb, Sb, Bi, Co, Cd, Ge, Au, Ir, Fe, Hg, Mo, Os, Pd, Re, Rh, Ru, Se, Ag, Tc, Te, Ti, W, and a noble metal. In an embodiment, the electrochemical power system comprises a hydrogen source, a hydrogen electrode capable of providing or forming atomic H, an electrode capable of forming at least one of H, H₂, OH, OH⁻, and H₂O catalyst, a source of at least one of O₂ and H₂O, a cathode capable of reducing at least one of H₂O and O₂, an alkaline electrolyte, and a system to collect and recirculate at least one of H₂O vapor, N₂, and O₂, and H₂. The sources of H₂, water, and oxygen may comprise ones of the disclosure.

In an embodiment, H₂O supplied to the electrolysis system may serve as the HOH catalyst that catalyzes H atoms formed at the cathode to hydrinos. H provided by the hydrogen electrode may also serve as the H reactant to form hydrino such as H(¼) and H₂ (¼). In another embodiment, the catalyst H₂O may be formed by the oxidation of OH⁻ at the anode and the reaction with H from a source. The source of H may be from at least one of the electrolysis of the electrolyte such as one comprising at least one of hydroxide and H₂O and the hydrogen electrode. The H may diffuse from the cathode to the anode. Exemplary cathode and anode reactions are:

Cathode Electrolysis Reaction

2H₂O+2e− to H₂+2OH— (168)

Anode Electrolysis Reactions

½H₂+OH⁻to H₂O+e⁻ (169)

H₂+OH⁻to H₂O+e⁻+H(¼) (170)

OH⁻+2H to H₂O+e⁻+H(¼) (171)

Regarding the oxidation reaction of OH⁻ at the anode to form HOH catalyst, the OH⁻ may be replaced by reduction of a source of oxygen such as O₂ at the cathode. In an embodiment, the anion of the molten electrolyte may serve as a source of oxygen at the cathode. Suitable anions are oxyanions such as CO₃²⁻, SO₄²⁻, and PO₄³⁻. The anion such as CO₃²⁻ may form a basic solution. An exemplary cathode reaction is

Cathode

CO₃²⁻+4e⁻+3H₂O to C+6OH⁻ (172)

The reaction may involve a reversible half-cell oxidation-reduction reaction such as

CO₃²⁻+H₂O to CO₂+2O H⁻ (173)

The reduction of H₂O to OH⁻+H may result in a cathode reaction to form hydrinos wherein H₂O serves as the catalyst. In an embodiment, CO₂, SO₂, NO, NO₂, PO₂ and other similar reactants may be added to the cell as a source of oxygen.

In addition to molten electrolytic cells, the possibility exists to generate H₂O catalyst in molten or aqueous alkaline or carbonate electrolytic cells wherein H is produced on the cathode. Electrode crossover of H formed at the cathode by the reduction of H₂O to OH⁻+H can give rise to the reaction of Eq. (171). Alternatively, there are several reactions involving carbonate that can give rise H₂O catalyst such as those involving a reversible internal oxidation-reduction reaction such as

CO₃²⁻+H₂O→CO₂+2OH⁻ (174)

as well as half-cell reactions such as

CO₃²⁻+2H→H₂O+CO₂+2e⁻ (175)

CO₂+1/2O₂+2e⁻→CO₃²⁻ (176)

### Hydrino Compounds or Compositions of Matter

The hydrino compounds comprising lower-energy hydrogen species such as molecular hydrino may be identified by (i) time of flight secondary ion mass spectroscopy (ToF-SIMS) and electrospray time of flight secondary ion mass spectroscopy (ESI-ToF) that may record the unique metal hydrides, hydride ion, and clusters of inorganic ions with bound H₂(¼) such as in the form of an M+2 monomer or multimer units such as K⁺[H₂(¼):K₂CO₃]ₙ and K+[H₂(¼): KOH]ₙ wherein n is an integer; (ii) Fourier transform infrared spectroscopy (FTIR) that may record at least one of the H₂(¼) rotational energy at about 1940 cm⁻¹ and libation bands in the finger print region wherein other high energy features of known functional groups may be absent, (iii) proton magic-angle spinning nuclear magnetic resonance spectroscopy (¹H MAS NMR) that may record an upfield matrix peak such as one in the −4 ppm to −6 ppm region, (iv) X-ray diffraction (XRD) that may record novel peaks due to the unique composition that may comprise a polymeric structure, (v) thermal gravimetric analysis (TGA) that may record a decomposition of the hydrogen polymers at very low temperature such as in the region of 200° C. to 900° C. and provide the unique hydrogen stoichiometry or composition such as FeH or K₂CO₃H₂, (vi) e-beam excitation emission spectroscopy that may record the H₂(¼) ro-vibrational band in the 260 nm region comprising peaks spaced at 0.25 eV; (vii) photoluminescence Raman spectroscopy that may record the second order of the H₂(¼) ro-vibrational band in the 260 nm region comprising peaks spaced at 0.25 eV; (viii) at least one of the first order H₂(¼) ro-vibrational band in the 260 nm region comprising peaks spaced at 0.25 eV recorded by e-beam excitation emission spectroscopy and the second order of the H₂(¼) ro-vibrational band recorded by photoluminescence Raman spectroscopy may reversibly decrease in intensity with temperature when thermal cooled by a cryocooler; (ix) ro-vibrational emission spectroscopy wherein the ro-vibrational band of H₂(1/p) such as H₂(¼) may be excited by high-energy light such as light of at least the energy of the ro-vibrational emission; (x) Raman spectroscopy that may record at least one of a continuum Raman spectrum in the range of 40 to 8000 cm⁻¹ and a peak in the range of 1500 to 2000 cm⁻¹ due to at least one of paramagnetic and nanoparticle shifts; (xi) spectroscopy on the ro-vibrational band of H₂(¼) in the gas phase or embedded in a liquid or solid such as a crystalline matrix such as one comprising KCl that is excited with a plasma such as a helium or hydrogen plasma such as a microwave, RF, or glow discharge plasma; (xii) Raman spectroscopy that may record the H₂(¼) rotational peak at about one or more of 1940 cm⁻¹±10% and 5820 cm⁻¹±10%, (xiii) X-ray photoelectron spectroscopy (XPS) that may record the total energy of H₂(¼) at about 495-500 eV, (xiv) gas chromatography that may record a negative peak wherein the peak may have a faster migration time than helium or hydrogen, (xv) electron paramagnetic resonance (EPR) spectroscopy that may record at least one of an H₂(¼) peak with a g factor of about 2.0046±20% and proton splitting such as a proton-electron dipole splitting energy of about 1.6×10⁻² eV±20% and a hydrogen product comprising a hydrogen molecular dimer [H₂(¼)]₂ wherein the EPR spectrum shows an electron-electron dipole splitting energy of about 9.9×10⁻⁵ eV±20% and a proton-electron dipole splitting energy of about 1.6×10⁻² eV+20%, (xvi) quadrupole moment measurements such as magnetic susceptibility and g factor measurements that record a H₂(1/p) quadrupole moment/e of about

$$\frac{1.70127 {a}_{0}^{2}}{{p}^{2}} ,$$

and (xvii) high pressure liquid chromatography (HPLC) that shows chromatographic peaks having retention times longer than that of the carrier void volume time using an organic column with a solvent such as one comprising water or water-methanol-formic acid and eluents such as a gradient water+ammonium acetate+formic acid and acetonitrile/water+ammonium acetate+formic acid wherein the detection of the peaks by mass spectroscopy such as ESI-ToF shows fragments of at least one ionic or inorganic compound such as NaGaO₂-type fragments from a sample prepared by dissolving Ga₂O₃ from the SunCell® in NaOH. Hydrino molecules may form at least one of dimers and solid H₂(1/p). In an embodiment, the end over end rotational energy of integer J to J+1 transition of H₂(¼) dimer ([H₂(¼)]2) and D₂(¼) dimer ([D₂(¼)]2) are about (J+1)44.30 cm⁻¹ and (J+1)22.15 cm⁻¹, respectively. In an embodiment, at least one parameter of [H₂(¼)]2) is (i) a separation distance between H₂(¼) molecules of about 1.028 A, (ii) a vibrational energy between H₂(¼) molecules of about 23 cm⁻¹, and (iii) a van der Waals energy between H₂(¼) molecules of about 0.0011 eV. In an embodiment, at least one parameter of solid H₂(¼) is (i) a separation distance between H₂(¼) molecules of about 1.028 Å, (ii) a vibrational energy between H₂(¼) molecules of about 23 cm⁻¹, and (iii) a van der Waals energy between H₂(¼) molecules of about 0.019 eV. At least one of the rotational and vibrational spectra may be recorded by at least one of FTIR and Raman spectroscopy wherein the bond dissociation energy and separation distance may also be determined from the spectra. The solution of the parameters of hydrino products is given in Mills GUTCP [which is herein incorporate by reference, available at https://brilliantlightpower.com] such as in Chapters 5-6, 11-12, and 16.

In an embodiment, an apparatus to collect molecular hydrino in gaseous, physi-absorbed, liquefied, or in other state comprises a source of macro-aggregates or polymers comprising lower-energy hydrogen species, a chamber to contain the macro-aggregates or polymers comprising lower-energy hydrogen species, a means to thermally decompose the macro-aggregates or polymers comprising lower-energy hydrogen species in the chamber, and a means to collect the gas released from the macro-aggregates or polymers comprising lower-energy hydrogen species. The decomposition means may comprise a heater. The heater may heat the first chamber to a temperature greater than the decomposition temperature of the macro-aggregates or polymers comprising lower-energy hydrogen species such as a temperature in at least one range of about 10° C. to 3000° C., 100° C. to 2000° C., and 100° C. to 1000° C. The means to collect the gas from decomposition of macro-aggregates or polymers comprising lower-energy hydrogen species may comprise a second chamber. The second chamber may comprise at least one of a gas pump, a gas valve, a pressure gauge, and a mass flow controller to at least one of store and transfer the collected molecular hydrino gas. The second chamber may further comprise a getter to absorb molecular hydrino gas or a chiller such as a cryogenic system to liquefy molecular hydrino. The chiller may comprise a cryopump or dewar containing a cryogenic liquid such as liquid helium or liquid nitrogen.

The means to form macro-aggregates or polymers comprising lower-energy hydrogen species may further comprise a source of field such as a source of at least one of an electric field or a magnetic field. The source of the electric field may comprise at least two electrodes and a source of voltage to apply the electric field to the reaction chamber wherein the aggregate or polymers are formed. Alternatively, the source of electric field may comprise an electrostatically charged material. The electrostatically charged material may comprise the reaction cell chamber such as a chamber comprising carbon such as a Plexiglas chamber. The detonation of the disclosure may electrostatically charge the reaction cell chamber. The source of the magnetic field may comprise at least one magnet such as a permanent, electromagnet, or a superconducting magnet to apply the magnetic field to the reaction chamber wherein the aggregate or polymers are formed.

The equations of the EPR calculations herein of the form (#.#) and the referenced sections correspond to those of MILLS GUT. Molecular hydrino H₂ (1/p) comprises (i) two electrons bound in a minimum energy, equipotential, prolate spheroidal, two-dimensional current membrane comprising a molecular orbital (MO), (ii) two Z=1 nuclei such as two protons at the foci of the prolate spheroid, and (iii) a photon wherein the photon equation of each state is different from that of an excited H₂ state given in the Excited States of the Hydrogen Molecule section, in that the photon increases the central field by an integer rather than decreasing the central prolate spheroidal field to that of a reciprocal integer of the fundamental charge at each nucleus centered on the foci of the spheroid, and the electrons of H₂(1/p) are paired in the same shell at the same position ξ versus being in separate ξ positions. The interaction of the hydrino state photon electric field with each electron gives rise to a nonradiative radial monopole such that the state is stable. In contrast, by the same mechanism, the excited H₂ state photon gives rise to a radiative radial dipole at the outer excited state electron resulting in the state being unstable to radiation. For exited states, the photon electric field comprises a prolate spheroidal harmonic in space and time that modulates the constant prolate spheroidal current of the outer electron in-phase. The former corresponds to orbital angular momentum and the latter corresponds to spin angular momentum. Due to the unique stable state of molecular hydrino comprising two nonradiative electrons in a single MO, the nature of the trapped photon field, the nature of the vector photon propagation inside the molecular hydrino serving as a resonator cavity, and the nature of the electron currents are unique.

Consider the formation of a nonradiative state H₂ molecule from two non-radiative n=1 state H atoms requiring the bond energy to be removed by a third body collision:

H+H+M→H₂+M* (16.216)

wherein M* denotes the third body in an energetic state. Molecular hydrino may form by the same nonradiative mechanism wherein, hydrino atoms and hydrino molecules comprise an additional photon component of the central field that is nonradiative by virtue of being equivalent to an integer multiple of the central field of a proton at the origin and at each focus of the prolate spheroid MO, respectively. The combination of two electrons into a single molecular orbital while maintaining the radiationless integer photonic central field gives rise to the special case of a doublet MO state in molecular hydrino rather than a singlet state. The singlet state is nonmagnetic; whereas, the doublet state has a net magnetic moment of a Bohr magneton μ_{B}.

Specifically, the basis element of the current of each hydrogen-type atom is a great circle as shown in the Generation of the Atomic Orbital-CVFS section, and the great circle current basis elements transition to elliptic current basis elements in hydrogen-type molecules as shown in the Force Balance of Hydrogen-Type Molecules section. As shown in the Equation of the Electric Field inside the Atomic Orbital section, (i) photons carry electric field and comprise closed field line loops, (ii) a hydrino or a molecular hydrino each comprises a trapped photon wherein the photon field-line loops each travel along a mated great circle or elliptic current loop basis element in the same vector direction, (iii) the direction of each field line increases in the direction perpendicular to the propagation direction with relative motion as required by special relativity, and (iv) since the linear velocity of each point along a field line loop of a trapped photon is light speed c, the electric field direction relative to the laboratory frame is purely perpendicular to its mated current loop and it exists only at δ(r−rₙ) The paired electrons of the hydrogen molecular orbital comprise a singlet state having no net magnetic moment. However, the photon field lines of two hydrino atoms that superimpose during the formation of a molecular hydrino can only propagate in one direction to avoid cancellation and give rise to a central field to provide force balance between the centrifugal and central forces (Eq. (11.200)). This special case gives rise to a doublet state in molecular hydrino.

The MO may be treated as a linear combination of the great ellipses that comprise the current density function of each electron as given in the Generation of the Orbitsphere-CVFS section and the Force Balance of Hydrogen-Type Molecules section. To meet the boundary conditions that the photon is matched in direction with the electron current and that the electron angular momentum is ℏ are satisfied, one half of electron 1 and one half of electron 2 may be spin up and matched with the two photons, and the other half of electron 1 may be spin up and the other half of electron 2 may be spin down such that one half of the currents are paired and one half of the currents are unpaired. Given the indivisibility of each electron and the condition that the MO comprises two identical electrons, the force of the two photons is transferred to the totality of the electron MO comprising the two identical electrons to satisfy Eq. (11.200). The resulting angular momentum and magnetic moment of the unpaired current density are ℏ and a Bohr magneton μ_{B}, respectively.

As given in the Electron g Factor section, flux is linked by an unpaired electron in quantized units of the fluxon or magnetic flux quantum

$$\frac{h}{2 e} .$$

The electric energy, the magnetic energy, and the dissipated energy of a fluxon treading the atomic orbital given by Eqs. (1.226-1.227) is

$$Δ {E}_{mag}^{spin} = 2 ( 1 + \frac{α}{2 π} + \frac{2}{3} {α}^{2} ( \frac{α}{2 π} ) - \frac{4}{3} {( \frac{α}{2 π} )}^{2} ) {μ}_{B} B = g {μ}_{B} B \qquad ( 16.217 )$$

In the case of the molecular hydrino, the unpaired electron is a linear combination of two electrons of the MO wherein one half of the current density is paired and one half is unpaired. The fluxon links both interlocked electrons such that the contribution of the flux linkage terms are doubled. The corresponding g factor is

$$g = 2 ( 1 + 2 ( \frac{α}{2 π} + \frac{2}{3} {α}^{2} ( \frac{α}{2 π} ) - \frac{4}{3} {( \frac{α}{2 π} )}^{2} ) ) = 2.004 \; 6386 \qquad ( 16.218 )$$

The energy between parallel and antiparallel levels of the unpaired electron in an applied magnetic field is

$$Δ {E}_{mag}^{spin} = g {μ}_{B} B = 2.0046386 {μ}_{B} B \qquad ( 16.219 )$$

The prediction of Eq. (16.218) was confirmed wherein the electron paramagnetic resonance peak was observed with g factor of 2.0047.

Interactions with other molecular hydrino electron magnetic moments and the nuclear magnetic moments of the protons of the molecule result in the splitting of the quantized energy levels (Eq. (16.219)) by the energy corresponding to the interaction. As shown by Eq. (16.220), the energy of the electron is decreased in the case that the coaxially applied or interacting magnetic flux is parallel to the magnetic moment, and the energy of the electron is increased in the case that the magnetic flux is antiparallel to the magnetic moment. The energy shift of a molecular hydrino dimer [H₂ (1/p)]₂ such as [H₂(¼)]₂ may be calculated by considering the interaction energy of the magnetic moment of a first H₂(¼) molecule and that of the second colinear H₂(¼) molecule of a hydrino dimer having the parameters calculated in the Geometrical Parameters and Energies due to the Intermolecular van der Waals Cohesive Energies of H₂ Dimer, H₂(1/p) Dimer, Solid H₂, and Solid H₂(1/p) section. In general, the potential energy of interaction E_{mag dipole} of two quantized magnetic dipoles m₁ and m₂ separated by a distance|r| is given by

$${E}_{mag dipole} = - \frac{{μ}_{0}}{4 π {\vert r \vert}^{3}} ( 3 ( {m}_{1} \cdot \hat{r} ) ( {m}_{2} \cdot \hat{r} ) - {m}_{1} \cdot {m}_{2} ) \qquad ( 16.220 )$$

where μ₀ is the permeability of free space and \hat{r} is a unit vector parallel to the line joining the centers of the two dipoles. Consider the splitting energy of interaction with two axially aligned magnetic moments of a H₂(¼) dimer. With the substitution of a Bohr magneton μ_{B} for each axially aligned magnetic moment and the H₂(¼) dimer separation given by Eq. (16.202) for |r| into Eq. (16.220), the energy E_{mag e-dipole} to flip the spin direction of two electron magnetic moments of [H₂(¼)]₂ is

$$\begin{matrix}{E}_{mag e \text{-} dipole} = - \frac{2 {μ}_{0} {μ}_{B}^{2}}{4 π {r}^{3}} \\ = - \frac{{{μ}_{0} ( 9.27400949 \times {10}^{- 24} {JT}^{- 1} )}^{2}}{2 {π ( 1.028 \times {10}^{- 10} m )}^{3}}\end{matrix} \qquad ( 16.221 )$$

The magnetic energy given by Eq. (16.221) is also split by the proton nuclear magnetic moments of a given H₂ (¼) wherein the nuclear magnetic moments may be parallel or antiparallel to the electron magnetic moment. The magnetic field inside the ellipsoidal MO, Hₓ⁻, (Eq. (12.31)) is:

$${B}_{x}^{-} = {μ}_{0} \frac{e ℏ}{2 {m}_{e}} \frac{1}{{{a}^{3} ( 1 - \frac{{b}^{2}}{{a}^{2}} )}^{3 \text{/} 2}} ( 2 \sqrt{1 - \frac{{b}^{2}}{{a}^{2}}} + ln \frac{1 + \sqrt{1 - \frac{{b}^{2}}{{a}^{2}}}}{1 - \sqrt{1 - \frac{{b}^{2}}{{a}^{2}}}} ) \qquad ( 16.222 )$$

Substitution of the H₂ (¼) semimajor axis a (Eq. (11.202)) and the H₂(¼) semiminor axis b (Eq. (11.205)) into Eq. (16.222) gives

Bₓ⁻=4.52×10⁴ T (16.223)

The corresponding energy to flip the proton magnetic moments E_{mag N-dipole} is given by

$$( 16.224 )$$

$$\begin{matrix}{E}_{mag N - dipole} = ( 2 ) ( 2 ) {μ}_{P} B = 4 ( 1.4106 \times {10}^{- 26} J {T}^{- 1} ) ( 4 .52 \times {10}^{4} T ) \\ = 2.55 \times {10}^{- 21} J = 1.59 \times {10}^{- 2} eV = 3851 GHz = 128 {cm}^{- 1}\end{matrix}$$

The energy (Eq. (16.219)) may be further influenced by presence of multimers of greater order than two, such as trimmers, quadramers, pentamers, hexamers, etc. and by internal bulk magnetism of the hydrino compound. The energy shift due to a plurality of multimers may be determined by vector addition of the superimposed magnetic dipole interactions given by Eq. (16.220) with the corresponding distances and angles. Molecular hydrino may give rise to non-zero or finite bulk magnetism such as paramagnetism, superparamagnetism and even ferromagnetism when the magnetic moments of a plurality of hydrino molecules interact cooperatively. Superparamagnetism was confirmed by vibrating-sample magnetometry. Superparamagnetism and ferromagnetism are favored when a molecular hydrino macroaggregate additionally comprises ferromagnetic atoms such as iron. Macroaggregates that are stable beyond room temperature may form by magnetic assembly and bonding. The magnetic energies become on the order of 0.01 eV, comparable to ambient laboratory thermal energies. The corresponding infrared absorption band in the region of about 100 cm⁻¹ has been confirmed by Fourier Transform Infrared (FTIR) spectroscopy and Raman spectroscopy.

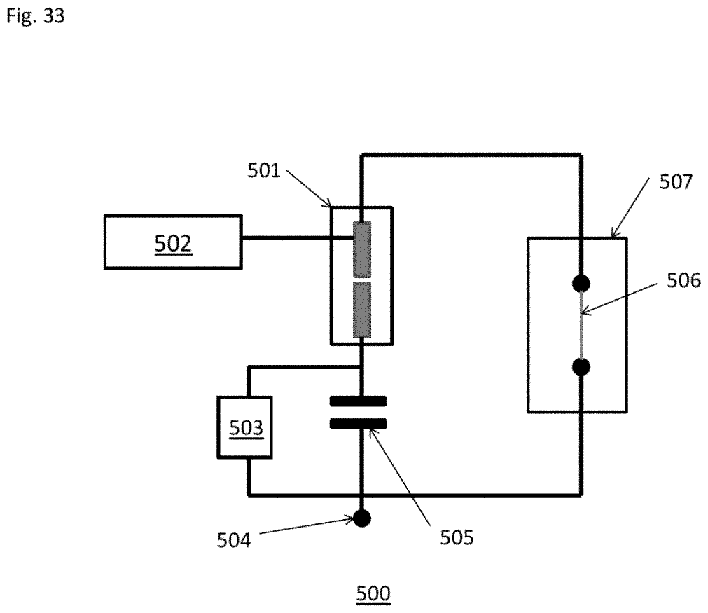

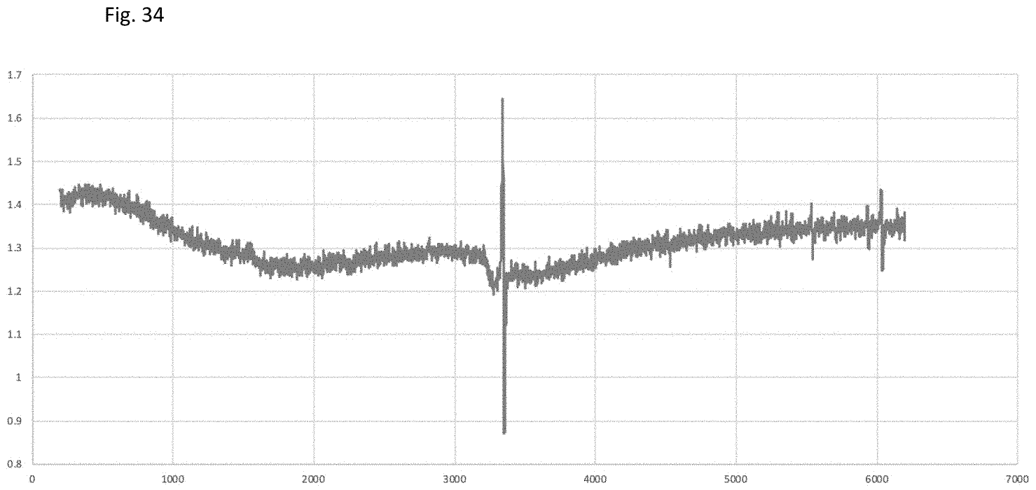

Molecular hydrino may be uniquely identified by electron paramagnetic resonance spectroscopy (EPR) as well as electron nuclear double resonance spectroscopy (ENDOR). In an embodiment, the lower-energy hydrogen product may comprise a metal in a diamagnetic chemical state such as a metal oxide, and is further absent any free non-hydrino radical species wherein an electron paramagnetic resonance (EPR) spectroscopy peak is observed due to the presence of H₂(1/p) such as H₂(¼). A hydrino reaction cell chamber comprising a means to detonate a wire to serve as at least one of a source of reactants and a means to propagate the hydrino reaction to form at least one of H₂(¼) molecules, inorganic compounds such as metal oxides, hydroxides, hydrated inorganic compounds such as hydrated metal oxides and hydroxides further comprising H₂(1/p) such as H₂(¼), and macro-aggregates or polymers comprising lower-energy hydrogen species such as molecular hydrino comprises a wire detonation system 500 is shown in FIG. 33. In exemplary embodiments, EPR spectra of the reaction products comprising lower-energy hydrogen species such as molecular hydrino formed by the detonation of 99.999% Sn and Zn wires in an atmosphere comprising water vapor in air and formed by the ball milling NaOH—KCl comprising H₂O that serves as a source of H and HOH catalyst to form H₂(¼) each showed an EPR peaks with a g factor of about 2 wherein no conventional EPR species could be present. In the case of the wire detonation samples, a web-like product was observed to form over a 30-minute period post detonation in the humid air. The web product was not observed in the absence of the water vapor. The web compound was collected and suspended in toluene, and EPR was performed on an instrument at Princeton University having a microwave frequency of 9.368 GHz (3343 G). NaOH—KCl was run neat. The EPR peak at g=2.0045 matched that predicted for H₂(¼). Sn, SnO, Zn, ZnO, NaOH, and KCl are not EPR active. The electron paramagnetic resonance spectroscopy (EPR) spectrum of a hydrino reaction product comprising lower-energy hydrogen comprising a white polymeric compound formed by dissolving Ga₂O₃ collected from a hydrino reaction run in the SunCell® in aqueous KOH, allowing fibers to grow, and float to the surface where they were collected by filtration is shown in FIG. 34. The EPR peak at g=2.0045 matched that predicted for H₂(¼). Control gallium oxide and potassium hydroxide are diamagnetic and were observed to be EPR inactive. Control KGa(OH)₄ was prepared by dissolving commercial reagent Ga₂O₃ in aqueous KOH, and rotary evaporating the water under vacuum. The EPR spectrum of the control was absent any feature in the region 0 to 6000 G region. The single peak is typical of an organic free radical and is not characteristic of a transition metal. The possibility of the presence of any radical was eliminated due to the observation that the compound was stable in concentrated base (pH=14) and concentrated HCl (pH ˜ 0).

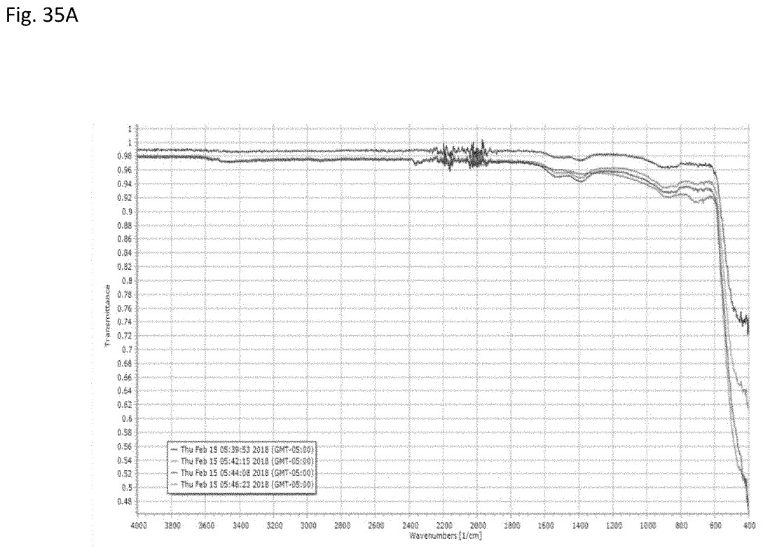

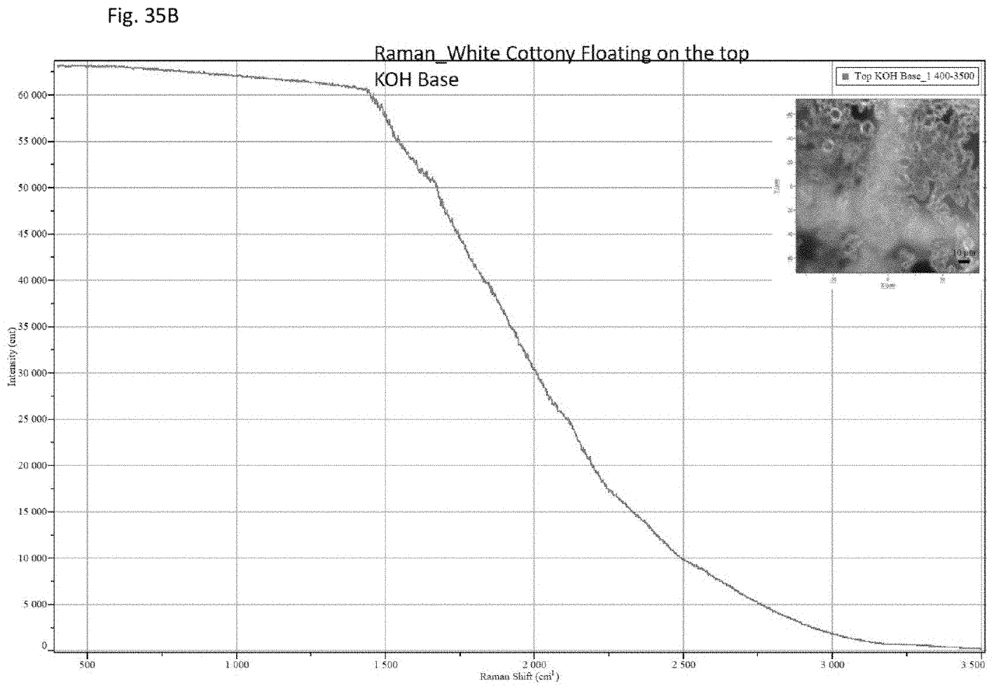

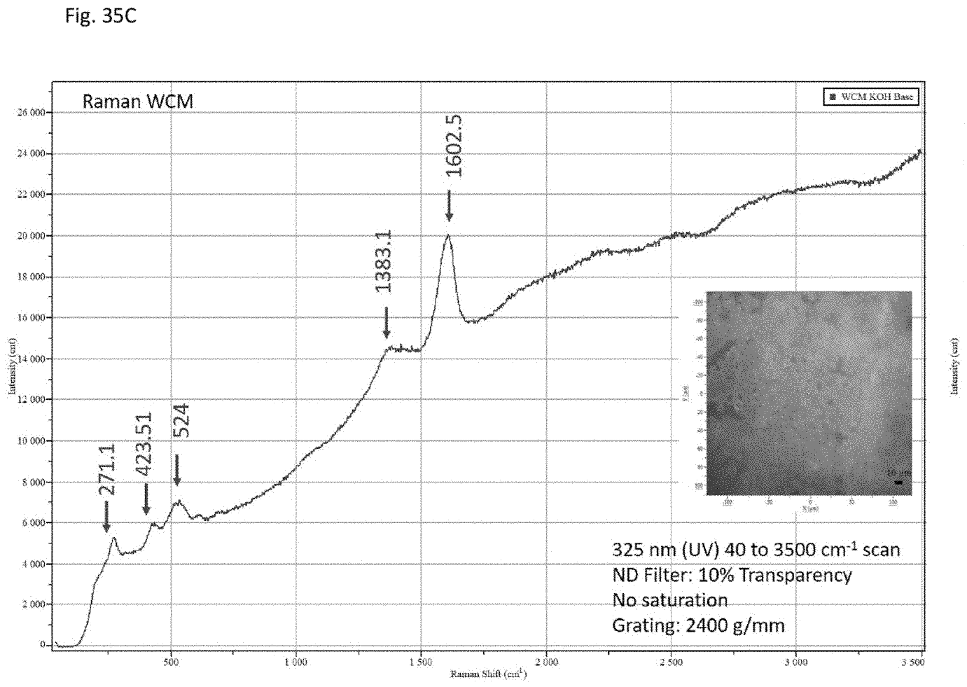

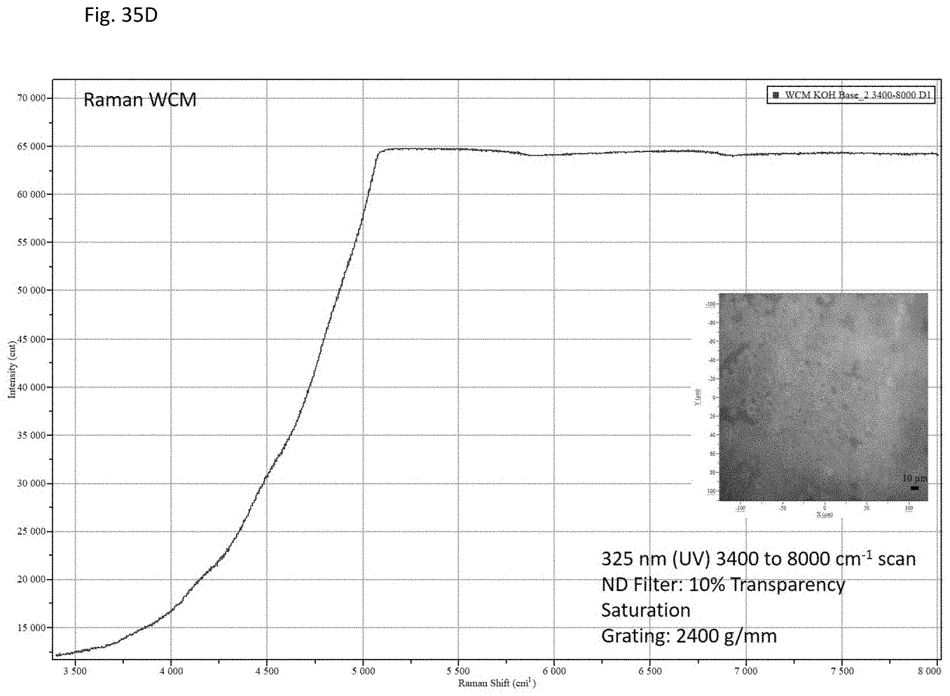

Compounds comprising molecular hydrino such as [H₂(¼)] may give rise to a broad IR band or Raman band in the very low energy fingerprint region. As shown in Mills GUTCP, [H₂(¼)]₂ has a low vibrational energy and end-over-end rotational energy which when excited as modes involving an ensemble of [H₂(¼)]₂ dimers as a macroaggregate, the superimposed energies give rise to a band of IR or Raman absorption as observed in FIGS. 35A and 35B. The FTIR spectrum of the product of the detonation of Zn wire in an atmosphere comprising water vapor is remarkable in that it is absent any functional group features (FIG. 35A). The same features are observed in the case of the Raman spectrum of a white polymeric compound formed by dissolving Ga₂O₃ collected from a hydrino reaction run in the SunCell® in aqueous KOH, allowing fibers to grow, and float to the surface where they were collected by filtration (FIG. 35B). The Raman continuum was observed at high wavenumbers with a 325 nm laser as shown in FIGS. 35C and 35D. The continuum Raman spectrum may be due to magnetic displacement of phonons, nanoparticle effects, and disorder due to random aggregation by magnetic molecular hydrino linkages. The peak at 1602 cm⁻¹ is assigned to the H₂(¼) rotation with paramagnetic and nanoparticle shifting. Molecular hydrino has an unpaired electron; so, hyperfine structure is predicted. In an embodiment an integer such as 1, 2, 3, 4 times the hyperfine structure energy is observed when the hydrino molecules are spin (magnetically) coupled. Peaks were peaks of n×128 cm⁻¹ were observed in the 785 nm laser Raman on the molecular hydrino compound of FIGS. 35C and 35D in agreement with Eq. (16.224).

The electron magnetic moments of a plurality of hydrino molecules such as H₂(¼) may give rise to permanent magnetization. Molecular hydrinos may give rise to bulk magnetism when magnetic moments of a plurality of hydrino molecules interact cooperatively and wherein multimers such as dimers may occur. Magnetism of dimers, aggregates, or polymers comprising molecular hydrino may arise from interactions of the cooperatively aligned magnetic moments. The magnetism may be much greater in the case that the magnetism is due to the interaction of the permanent electron magnetic moment of an additional species having at least one unpaired electrons such as iron atoms.

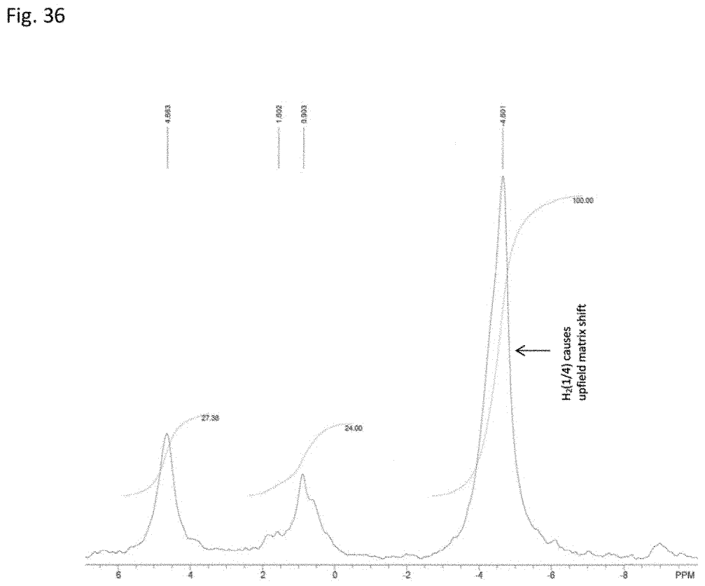

The magnetic characteristic of molecular hydrino is demonstrated by proton magic angle spinning nuclear magnetic resonance spectroscopy (¹H MAS NMR) as shown by Mills et al. in the case of electrochemical cells that produce hydrinos called CIHT cells [R. Mills, X Yu, Y. Lu, G Chu, J. He, J. Lotoski, “Catalyst induced hydrino transition (CIHT) electrochemical cell,” (2012), Int. J. Energy Res., (2013), DOI: 10.1002/er.3142]. The presence of molecular hydrino in a solid matrix such as an alkali hydroxide-alkali halide matrix that may further comprise some waters of hydration gives rise to an upfield ¹H MAS NMR peak, typically at −4 to −5 ppm due to the molecular hydrinos' paramagnetic matrix effect; whereas, the initial matrix devoid of hydrino shows the known down-field shifted matrix peak at +4.41 ppm. Ga₂O₃:H₂(¼) collected from a stainless steel SunCell® was dissolved in NaOH, filter, and the filtrate comprising stainless steel oxide and GaOOH was heated to 900° C. in a pressure vessel and the decomposition gas was flowed through hydrated KCl getter packed in a tube connected to the pressure vessel. The ¹H MAS NMR spectrum relative to external TMS of the KCl getter exposed to hydrino gas shows an upfield shifted matrix peak at −4.6 ppm due to the magnetism of molecular hydrino (FIG. 36).

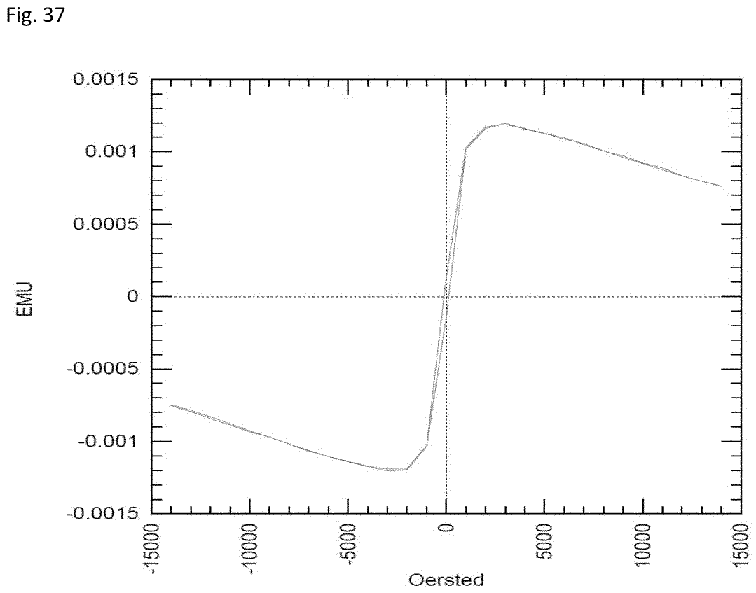

A convenient method to produce molecular hydrinos is by wire detonation in the presence of H₂O to serve as the hydrino catalyst and source of H. Wire detonations in an atmosphere comprising water vapor produces magnetic linear chains comprising hydrino hydrogen such as molecular hydrino with metal atoms or ions that may aggregate to forms webs. Paramagnetic material responds linearly with the induced magnetism; whereas, an observed “S” shape is characteristic of super paramagnetic, a hybrid of ferromagnetism and para magnetism. In an embodiment the polymeric web compound such as the compound formed by detonating molybdenum wire in air comprising water vapor is superparamagnetic. The vibrating sample magnetosusceptometer recording may show an S-shaped curve as shown in FIG. 37. It is exception that the induced magnetism peaks at 5K Oe and declines with higher applied field. The superparamagnetic hydrino compound may comprise magnetic nanoparticles that may be oriented in a magnetic field.

A self-assembly mechanism may comprise a magnetic ordering in addition to van der Waals forces. It is well known that the application of an external magnetic field causes colloidal magnetic nanoparticles such as magnetite (Fe₂O₃) suspended in a solvent such as toluene to assemble into linear structures. Due to the small mass and high magnetic moment molecular hydrino magnetically self assembles even in the absence of a magnetic field. In an embodiment to enhance the self-assembly and to control the formation of alternative structures of the hydrino products, an external magnetic field is applied to the hydrino reaction such as the wire detonation. The magnetic field may be applied by placing at least one permanent magnet in the reaction chamber. Alternatively, the detonation wire may comprise a metal that serves as a source of magnetic particles such as magnetite to drive the magnetic self-assembly of molecular hydrino wherein the source may be the wire detonation in water vapor or another source.

In an embodiment, hydrino products such as hydrino compounds or macroaggregates may comprise at least one other element of the periodic chart other than hydrogen. The hydrino products may comprise hydrino molecules and at least one other element such as at least one a metal atom, metal ion, oxygen atom, and oxygen ion. Exemplary hydrino products may comprise H₂(1/p) such as H₂(¼) and at least one of Sn, Zn, Ag, Fe, Ga, Ga₂O₃, GaOO, SnO, ZnO, AgO, FeO, and Fe₂O₃.

The bonding of molecular hydrino molecules H₂ (¼) to form a solid at room to elevated temperatures is due to van der Waals forces that are much greater for molecular hydrino than molecular hydrogen due to the decreased dimensions and greater packing as shown in Mills GUTCP. Due to its intrinsic magnetic moment and van der Waals forces, molecular hydrino may self assemble into macroaggregates. In an embodiment, hydrino such as H₂(1/p) such as H₂(¼) may form polymers, tubes, chains, cubes, fullerene, and other macrostructures such as one with formula Hₙ wherein n is an integer that is greater than the integer of a known form of hydrogen. In an exemplary embodiment, H₆₀ having an absolute mass of m/e=60.35 was observed in the TOF-SIMS of the filamentous product from the high voltage detonation of a Zn wire in an air atmosphere comprising water vapor by the method given in the disclosure. In an embodiment, molecular hydrino such as H₂(¼) may assemble into linear chains bound by magnetic dipole forces as well as van der Waals forces. In another embodiment, molecular hydrino can assemble into three-dimensional structures such as a cube having H₂(1/p) such as H₂(¼) at each of the eight vertices. In an embodiment, eight H₂(1/p) molecules such as H₂(¼) molecules are bound into a cube wherein the center of each molecule is at one of the eight vertices of the cube, and each inter-nuclear axis is parallel to an edge of the cube centered on a vertex.

H₁₆ may serve as a unit or moiety for more complex macrostructures formed by self-assembly. In another embodiment, units of H₈ comprising H₂(1/p) such as H₂(¼) at each of the four vertices of a square may be added to the cuboid H₁₆ to comprise H₁₆₊₈ₙ wherein n is an integer. Exemplary additional macroaggregates are H₁₆, H₂₄, and H₃₂. The hydrogen macroaggregate neutrals and ions may combine with other species such as O, OH, C, and N as neutrals or ions. In an embodiment, the resulting structure gives rise to an H₁₆ peak in the time-of-flight secondary ion mass spectrum (ToF-SIMS) wherein fragments may be observed masses corresponding to integer H loss from H₁₆ such as H₁₆, H₁₄, H₁₃, and H₁₂. Due to the mass of H of 1.00794 u, the corresponding+1 or −1 ion peaks have masses of 16.125, 15.119, 14.111, 13.103, 12.095 . . . . The hydrogen macroaggregate ions such as H₁₆⁻ or H₁₆⁺ may comprise metastables. The hydrogen macroaggregate ions H₁₆⁻ and H₁₆⁺ having metastable features of broad peaks were observed by ToF-SIMS at 16.125 in the positive and negative spectra. H₁₅⁻ was observed in the negative ToF-SIMS spectrum at 15.119. H₂₄ metastable species H₂₃⁺ and H₂₅⁻ were observed in the positive and negative ToF-SIMS spectra, respectively.

In an embodiment, the compositions of matter comprising lower-energy hydrogen species such as molecular hydrino (“hydrino compound”) may be separated magnetically. The hydrino compound may be cooled to further enhance the magnetism before being separated magnetically. The magnetic separation method may comprise moving a mixture of compounds containing the desired hydrino compound through a magnetic field such that the hydrino compound is preferentially retarded in mobility relative to the remainder of the mixture or moving a magnet over the mixture to separate the hydrino compound from the mixture. In an exemplary embodiment, hydrino compound is separated from nonhydrino products of the wire detonations by immersing the detonation product material in liquid nitrogen and using magnetic separation wherein the cryo-temperature increases the magnetism of the hydrino compound product. The separation may be enhanced at the boiling surface of the liquid nitrogen.

In addition to being negatively charged, in an embodiment, the hydrino hydride ion H-(1/p) comprises a doublet state with an unpaired electron that gives rise to a Bohr magneton of magnetic moment. A hydrino hydride ion separator may comprise at least one of a source of electric field and magnetic field to separate hydrino hydride ions from a mixture of ions based on the differential and selective forces maintained on the hydrino hydride ion based on at least one of the charge and magnetic moment of the hydrino hydride ion. In an embodiment, the hydrino hydride ion may be accelerated in an electric field and deflected to a collector based on the unique mass to charge ratio of the hydrino hydride ion. The separator may comprise a hemispherical analyzer or a time of flight analyzer type device. In another embodiment, the hydrino hydride ion may be collected by magnetic separation wherein a magnetic field is applied to a sample by a magnet and the hydrino hydride ions selectively stick to the magnet to be separated. The hydrino hydride ions may be separated together with a counter ion.

In an embodiment, a hydrino species such as atomic hydrino, molecular hydrino, or hydrino hydride ion is synthesized by the reaction of H and at least one of OH and H₂O catalyst. In an embodiment, the product of at least one of the SunCell® reaction and the energetic reactions such as ones comprising shot or wire ignitions of the disclosure to form hydrinos is a hydrino compound or species comprising a hydrino species such as H₂(1/p) complexed with at least one of (i) an element other than hydrogen, (ii) an ordinary hydrogen species such as at least one of H⁺, ordinary H₂, ordinary H⁻, and ordinary H₃⁺, an organic molecular species such as an organic ion or organic molecule, and (iv) an inorganic species such as an inorganic ion or inorganic compound. The hydrino compound may comprise an oxyanion compound such as an alkali or alkaline earth carbonate or hydroxide, oxyhydroxides such as GaOOH, AlOOH, and FeOOH, or other such compounds of the present disclosure. In an embodiment, the product comprises at least one of M₂CO₃.H₂(¼) and MOH.H₂ (¼) (M=alkali or other cation of the present disclosure) complex. The product may be identified by ToF-SIMS or electrospray time of flight secondary ion mass spectroscopy (ESI-ToF) as a series of ions in the positive spectrum comprising M(M₂CO₃. H₂ (¼))ₙ⁺ and M(MOH.H₂ (¼)ₙ⁺, respectively, wherein n is an integer and an integer and integer p>1 may be substituted for 4. In an embodiment, a compound comprising silicon and oxygen such as SiO₂ or quartz may serve as a getter for H₂(¼). The getter for H₂(¼) may comprise a transition metal, alkali metal, alkaline earth metal, inner transition metal, rare earth metal, combinations of metals, alloys such as a Mo alloy such as MoCu, and hydrogen storage materials such as those of the present disclosure.

The compounds comprising hydrino species synthesized by the methods of the present disclosure may have the formula MH, MH₂, or M₂H₂, wherein M is an alkali cation and H is a hydrino species. The compound may have the formula MHₙ wherein n is 1 or 2, M is an alkaline earth cation and H is hydrino species. The compound may have the formula MHX wherein M is an alkali cation, X is one of a neutral atom such as halogen atom, a molecule, or a singly negatively charged anion such as halogen anion, and H is a hydrino species. The compound may have the formula MHX wherein M is an alkaline earth cation, X is a singly negatively charged anion, and H is H is a hydrino species. The compound may have the formula MHX wherein M is an alkaline earth cation, X is a double negatively charged anion, and H is a hydrino species. The compound may have the formula M₂HX wherein M is an alkali cation, X is a singly negatively charged anion, and H is a hydrino species. The compound may have the formula MHₙ wherein n is an integer, M is an alkaline cation and the hydrogen content Hₙ of the compound comprises at least one hydrino species. The compound may have the formula M₂Hₙ wherein n is an integer, M is an alkaline earth cation and the hydrogen content Hₙ of the compound comprises at least one hydrino species. The compound may have the formula M₂XHₙ wherein n is an integer, M is an alkaline earth cation, X is a singly negatively charged anion, and the hydrogen content Hₙ of the compound comprises at least one hydrino species. The compound may have the formula M₂X₂Hₙ wherein n is 1 or 2, M is an alkaline earth cation, X is a singly negatively charged anion, and the hydrogen content Hₙ of the compound comprises at least one hydrino species. The compound may have the formula M₂X₃H wherein M is an alkaline earth cation, X is a singly negatively charged anion, and H is a hydrino species. The compound may have the formula M₂XHₙ wherein n is 1 or 2, M is an alkaline earth cation, X is a double negatively charged anion, and the hydrogen content Hₙ of the compound comprises at least one hydrino species. The compound may have the formula M₂XX′H wherein M is an alkaline earth cation, X is a singly negatively charged anion, X′ is a double negatively charged anion, and H is hydrino species. The compound may have the formula MM¹Hₙ wherein n is an integer from 1 to 3, M is an alkaline earth cation, M′ is an alkali metal cation and the hydrogen content Hₙ of the compound comprises at least one hydrino species. The compound may have the formula MM′XHₙ wherein n is 1 or 2, M is an alkaline earth cation, M′ is an alkali metal cation, X is a singly negatively charged anion and the hydrogen content Hₙ of the compound comprises at least one hydrino species. The compound may have the formula MM′XH wherein M is an alkaline earth cation, M′ is an alkali metal cation, X is a double negatively charged anion and H is a hydrino species. The compound may have the formula MM′XX′H wherein M is an alkaline earth cation, M′ is an alkali metal cation, X and X′ are singly negatively charged anion and H is a hydrino species. The compound may have the formula MXX¹Hₙ wherein n is an integer from 1 to 5, M is an alkali or alkaline earth cation, X is a singly or double negatively charged anion, X′ is a metal or metalloid, a transition element, an inner transition element, or a rare earth element, and the hydrogen content Hₙ of the compound comprises at least one hydrino species. The compound may have the formula MHₙ wherein n is an integer, M is a cation such as a transition element, an inner transition element, or a rare earth element, and the hydrogen content Hₙ of the compound comprises at least one hydrino species. The compound may have the formula MXHₙ wherein n is an integer, M is an cation such as an alkali cation, alkaline earth cation, X is another cation such as a transition element, inner transition element, or a rare earth element cation, and the hydrogen content Hₙ of the compound comprises at least one hydrino species. The compound may have the formula (MHₘMCO₃)ₙ wherein M is an alkali cation or other +1 cation, m and n are each an integer, and the hydrogen content Hₘ of the compound comprises at least one hydrino species. The compound may have the formula (MHₘMNO₃)ₙ⁺nX⁻ wherein M is an alkali cation or other +1 cation, m and n are each an integer, X is a singly negatively charged anion, and the hydrogen content Hₘ of the compound comprises at least one hydrino species. The compound may have the formula (MHMNO₃)ₙ wherein M is an alkali cation or other +1 cation, n is an integer and the hydrogen content H of the compound comprises at least one hydrino species. The compound may have the formula (MHMOH)ₙ wherein M is an alkali cation or other +1 cation, n is an integer, and the hydrogen content H of the compound comprises at least one hydrino species. The compound including an anion or cation may have the formula (MHₘM′X)ₙ wherein m and n are each an integer, M and M′ are each an alkali or alkaline earth cation, X is a singly or double negatively charged anion, and the hydrogen content Hₘ of the compound comprises at least one hydrino species. The compound including an anion or cation may have the formula (MHₘM′X′)ₙ⁺X⁻ wherein m and n are each an integer, M and M′ are each an alkali or alkaline earth cation, X and X′ are a singly or double negatively charged anion, and the hydrogen content Hₘ of the compound comprises at least one hydrino species. The anion may comprise one of those of the disclosure. Suitable exemplary singly negatively charged anions are halide ion, hydroxide ion, hydrogen carbonate ion, or nitrate ion. Suitable exemplary double negatively charged anions are carbonate ion, oxide, or sulfate ion.

In an embodiment, the hydrino compound or mixture comprises at least one hydrino species such as a hydrino atom, hydrino hydride ion, and dihydrino molecule embedded in a lattice such as a crystalline lattice such as in a metallic or ionic lattice. In an embodiment, the lattice is non-reactive with the hydrino species. The matrix may be aprotic such as in the case of embedded hydrino hydride ions. The compound or mixture may comprise at least one of H(1/p), H₂(1/p), and H⁻(1/p) embedded in a salt lattice such as an alkali or alkaline earth salt such as a halide. Exemplary alkali halides are KCl and KI. The salt may be absent any H₂O in the case of embedded H⁻(1/p). Other suitable salt lattices comprise those of the present disclosure.

The hydrino compounds of the present invention are preferably greater than 0.1 atomic percent pure. More preferably, the compounds are greater than 1 atomic percent pure. Even more preferably, the compounds are greater than 10 atomic percent pure. Most preferably, the compounds are greater than 50 atomic percent pure. In another embodiment, the compounds are greater than 90 atomic percent pure. In another embodiment, the compounds are greater than 95 atomic percent pure.

In an embodiment, hydrino compounds may be purified by recrystallization in a suitable solvent. Alternatively, the compounds may be purified by chromatography such as high-performance liquid chromatography (HPLC) or gas chromatography in the case of a gas comprising molecular hydrino. In an embodiment, molecular hydrino may be purified by cryofiltration. The purification system may comprise a selective absorbent for molecular hydrino such as activated charcoal or zeolite. The absorbent may be contained in a vessel that is heated to cause impurities to be degased from the absorbent. The impurities may be removed under vacuum. The degassed absorbent may be cooled to a low temperature such a as cryotemperature such as that of liquid nitrogen. The vessel may be submerged in a dewar of a cryogen such as liquid nitrogen. The gas mixture comprising molecular hydrino may be flowed through the cold absorbent such that molecular hydrino is selectively absorbed. The absorbent may be heated to cause purified molecular hydrino gas to flow out of the absorbent to be collected.

Superparamagnetic hydrino compounds may comprise magnetic nanoparticles that may be oriented in a magnetic field. Applications of the magnetic hydrino compounds such as one comprising at least one of molecular hydrino and hydrino hydride ion comprises magnetic storage material such as the memory storage material of computer hard drives, contrast agents in magnetic resonance imaging, a ferrofluid such as one with tunable viscosity, magnetic cell separation such as cell, DNA or protein separation or RNA fishing, and treatments such as targeted drug delivery, magnetic hyperthermia, and magnetofection. In an embodiment, the magnetic, light absorption, light scattering, properties of compounds comprising molecular hydrino may be used for stealth coatings, light sensors, solar cells, magnetic separation, MRI imaging as contrast media, and hyperthermia treatment.

In an embodiment wherein a hydrino hydride links flux in units of the magnetic flux quantum similarly to the behavior of a superconducting quantum interference device (SQUID), an electronic devise such as a magnetometer, logic gate, sensor, or switch comprises at least one hydrino hydride ion and at least one of an input current and input voltage circuit and an output current and output voltage circuit to at least one of sense and change the flux linkage state of the at least one hydrino hydride ion.

In an embodiment, a power and light emitting cell that forms hydrino products comprises at least one ultrasonic transducer, a liquid medium to form cavitation bubbles, a source of HOH catalyst and a source of H. The liquid medium may comprise at least one of a hydrocarbon such as dodecane, an acid such as sulfuric acid, and water that may further serve as the source of at least one of HOH and H. The liquid may comprise a noble gas such as argon or xenon and may further comprise at least one of a source of oxygen, oxygen, a source of hydrogen, and hydrogen. The noble gas may saturate the liquid. The noble gas may serve as a source of electrons. The liquid may be maintained at low temperature such as one near the liquid freezing point. The H may be formed by reaction of carbon with water to form at least one of CO and CO₂. The H may be formed by reduction of H⁺ by a source of electrons such as the noble gas. The carbon source may be at least one of hydrocarbons and carbon that may be at least one of suspended in the water and coating the ultrasonic transducer. Sonication of the liquid medium by the ultrasonic transducer may cause water hydrogen bonding to break and may further cause the source of carbon or carbon to react with water to form CO and H that further react with HOH to form hydrino. The corresponding reaction to form hydrino may cause the release of at least one of heat and light such as blackbody radiation that may be in the visible region.

In an embodiment, a hydrino species such as H₂(1/p) is isolated from a compound or material comprising the hydrino species bound in the compound or material such as a metal oxide, an alkali halide, an alkali halide-alkali hydroxide mixture, and carbonate such as K₂CO₃ by sublimation. The sublimation may be achieved by cooling the compound or material to a low temperature such as cryogenic temperature and maintaining a vacuum.

In an embodiment, molecular hydrino of a mixture such as a liquid or gaseous mixture such as one comprising argon may be purified by diffusion across a permeation selective membrane such a as metal, glass, or ceramic membrane. The permeation may be into a collection cavity. In an exemplary embodiment, the permeation membrane may comprise a thin-walled, hollow, evacuated cavity, chamber, or tubing that may be immersed in liquid argon to allow molecular hydrino to diffuse into the cavity. The pressure and amount of the collected gas may be increased by condensing the gas cryogenically. In an exemplary embodiment, the cavity may be suspended in a liquid helium dewar and the condensed gas may then transfer to a smaller volume gas bottle and allowed to evaporate.

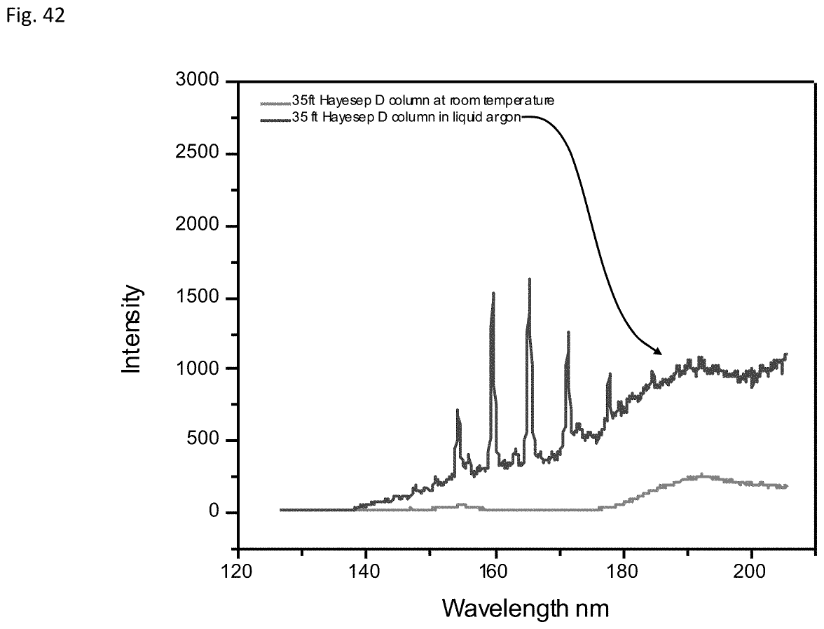

In an embodiment, molecular hydrino gas such as H₂(¼) is soluble in condensed gases such as a noble gas such are liquid argon, liquid nitrogen, liquid CO₂ or a solid gas such as solid CO₂. The solubility is confirmed by the observation of the ro-vibrational band of H₂(¼) (FIGS. 41-42) recorded on vaporized liquid argon gas. H₂ and O₂ are also present in trace amounts confirming the solubility of these gases in liquid argon as well. In the case that hydrino is more soluble than hydrogen, liquid argon may be used to selectively collect and enrich molecular hydrino gas from a source such as one comprising a mixture of H₂ and molecular hydrino gas such as gas from the SunCell®. In an embodiment, the gas from the SunCell® is bubbled through liquid argon that serves as a getter due to the solubility of molecular hydrino in liquid argon. In another embodiment, a solid material getter may be used alone or immersed in a liquid gas such as liquid argon. Exemplary solid getters may comprise at least one of carbon, zeolite, KCl, KOH, RbCl, K₂CO₃, LiBr, FeOOH, In foil, MoCu foil, silicon wafer, other oxides, alkali halides, and alkali hydroxides. The getter may be cooled by means such as a cryogen. The cryogen may comprise a cryotrap. In an exemplary embodiment, the cryotrap is cooled to liquid nitrogen temperature. To release hydrino from getters, the getter comprising hydrino may be at least one of heated to release hydrino gas and dissolved in a solvent such as water, acid, base, or organic solvent to release the hydrino gas. In an embodiment, hydrino gas may be bubbled into the solvent such as a cryogenic liquid such as a liquid noble gas such as argon or liquid nitrogen, supercritical CO₂, liquid oxygen, liquid nitrogen, liquid O₂/N₂ mixture, another supercritical liquid known in the art, or another liquid such as water, acid, base, or organic solvent such as a fluorocarbon. In an embodiment, the solvent may be magnetic such as paramagnetic such that molecular hydrino has some absorption interaction due to the magnetism of molecular hydrino. Exemplary solvents are liquid oxygen and oxygen dissolved in another liquid such as water. Alternatively, hydrino gas may be bubbled through a solid solvent such as a solid that is a gas at room temperature such as solid CO₂. The hydrino gas may be directly collected. Alternatively, the resulting solution may be filtered, skimmed, decanted, or centrifuged to collect the non-soluble compounds comprising hydrino such as hydrino macroaggregates.

In an embodiment, H₂O may comprise the molecular hydrino solvent. H₂O may be placed in a trap wherein gas product from the hydrino reaction is bubbled through the water to cause molecular hydrino to be dissolved in the water. The molecular hydrino gas may be released by heating the water. The heating may be to a temperature such as less than 100° C. that selectively releases hydrino relative to water vapor. The released gas may be passed through a cold trap such as a CO₂ cryotrap to selective condense water vapor of a gas mixture relative to molecular hydrino gas. The molecular hydrino gas may be identified by at least one of gas chromatography and electron beam excitation spectroscopy.

In an exemplary embodiment to at least one of isolate and identify molecular hydrino gas, the hydrino getter such as gallium oxide from the SunCell® may be dissolved in water such as concentrated aqueous base such as aqueous NaOH such that trapped molecular hydrino is then either in the gas or liquid phase. The gas can be injected on a gas chromatographic column using hydrogen as the carrier gas or bubbled through liquid argon to dissolve molecular hydrino, and the argon-hydrino gas can then be introduced onto a gas chromatographic column with argon carrier gas wherein liquid argon serves to enrich molecular hydrino over normal hydrogen. The water can be analyzed analytically. It can further be heated below the boiling point to selectively release molecular hydrino gas wherein water vapor may be selectively condensed by a cryotrap such as a CO₂ trap to remove water to selectively introduce the molecular hydrino gas onto the gas chromatographic column.

In an embodiment, gaseous product collected directly from the SunCell® or gaseous product collected from that released from solid products of the SunCell® are flowed through a recombiner such as a CuO recombiner to remove hydrogen gas, and the enriched hydrino gas is condensed in a valved, sealable cryochamber on a cryofinger or cold stage of a cryopump. Molecular hydrino gas may be co-condensed with at least one other gas or absorbed in a co-condensed gas such as one or more of argon, nitrogen, and oxygen that may serve as a solvent. When sufficient liquid is accumulated, the cryochamber may be sealed and allowed to warn to vaporize the condensed liquid. The resulting gas may be used for industrial or analytical purposes. For example, the gas may be injected through a chamber valve into a gas chromatograph or into a cell for electron beam emission spectroscopy. In an alternative embodiment, the molecular hydrino gas may be directly flowed into the cryofinger chamber and condensed wherein the cryofinger may be operated at a temperature above 20.3 K (the boiling point of H₂ at atm pressure) so that hydrogen is not co-condensed.

Two different nuclear spin configurations for H₃ are possible, called ortho and para. Ortho-H₃ has all three proton spins parallel, yielding a total nuclear spin of 3/2. Para-H⁺ has two proton spins parallel while the other is anti-parallel, yielding a total nuclear spin of ½. Similarly, H₂ also has ortho and para states, with ortho-H₂ having a total nuclear spin 1 and para-H₂ having a total nuclear spin of 0. When an ortho-H₃⁺ and a para-H₂ collide, proton spin change may occur, yielding instead a para-H₃⁺ and an ortho-H₂. In an embodiment, ortho H₃⁺ is prepared by means such as a hydrogen plasma and optionally a source of magnetic field to increase the spin polarization yield of ortho-H₃⁺. The ortho-H₃⁺ may be made to collide with molecular hydrino gas to create ortho-H₂(1/p) which is NMR active. The collision may be achieved by forming beams of ortho-H₃⁺ and H₂(1/p) or by mixing the gases. Ortho H₂(1/p) may be identified by proton NMR.

In an embodiment, a macroaggregate hydrino compound may be isolated for gallium oxide skimmed from the SunCell® and dissolved in base such as NaOH. The compound may comprise a high temperature superconductor.

In an embodiment, gallium oxide from SunCell is dissolved in base such as NaOH. The non-soluble material may be filtered to serve as a source of hydrino gas. Alternatively, the solution may be decanted to isolate the non-soluble particles to serve as a source of hydrino gas. The solution may be filtered and the filtrate may be allowed to stand to form white cottony hydrino product that is collected by means such as at least one of filtration, centrifugation, and drying.

In another embodiment, hydrino gas may be purified on a chromatographic column. In the case that the carrier gas comprises a mixture comprising hydrino such as an argon/H₂(¼) mixture, the hydrino gas may be enriched by flowing the mixture through a chromatographic column such as a as HayeSep® D column cooled to a cryogenic temperature such as liquid nitrogen or argon temperature. The argon may partially liquefy to permit the flowing hydrino gas to be enriched. The hydrino gas may be analyzed by analytical means of the disclosure such as gas chromatography and e-beam excitation emission spectroscopy. In an embodiment, molecular hydrino of a mixture with another gas such as argon may be separated and enriched from the mixture by cryogenic liquid chromatography. In an embodiment, molecular hydrino may be identified by gas chromatography using helium or hydrogen carrier gas wherein molecular hydrino may more readily form a chromatographic band in these carrier gases. The detector may comprise a thermal conductivity detector. In another embodiment, molecular hydrino may be enriched or purified chromatographically using superfluid CO₂ as the carrier liquid. In another embodiment, molecular hydrino may be enriched or purified by differential liquefaction at cryogenic temperatures. Hydrogen may be removed from a H₂-molecular hydrino mixture by flame combustion that may be achieved by flowing the hydrogen-molecular hydrino gas mixture through a the H₂ inlet of an H₂— O₂ gas torch. Alternatively, hydrogen may be removed by a recombiner such as a CuO recombiner or by catalytic recombination with oxygen. Exemplary catalytic recombiners are a noble metal such as Pt or Pd on a solid support such as alumina, silica, or carbon.

In an embodiment, molecular hydrino gas is increased in pressure by at least one method of (i) condensation to a liquid such as cryogenic condensation followed by heating to cause vaporization in a pressure vessel, (ii) absorption in an absorber such as carbon or zeolite or other getter of the disclosure followed by heating to cause vaporization in a pressure vessel, and (iii) collection of gas comprising molecular hydrino in a pressure vessel followed by mechanical or hydraulic compression. The cryogenic condensation may be achieved in a condensation vessel with a cryotrap or a cryopump capable of achieving a temperature sufficient to condense hydrino. Cryogenic condensation may be achieved at least one of liquid argon, liquid nitrogen, and liquid helium temperature. In an embodiment, a magnetic field may be applied to the condensation vessel to raise the condensation temperature. The magnetic field may be applied with at least one of electromagnets and permanent magnets such a neodymium or cobalt samarium magnets that may be positioned inside or outside of the condensation vessel. The hydraulic compression may be achieved by pumping a liquid such as an incompressible liquid such as water into the vessel to displace volume and compress the molecular hydrino gas. The molecular hydrino, may have a low solubility in the liquid. The liquid may be pumped into the base of the vessel to avoid diffusion losses of the molecular hydrino gas through the liquid delivery system such as a conduit to the vessel and a pump. In the case that the compressed gas comprising hydrino gas comprise at least one other undesired gas, the undesired gases may be removed by means such as flowing the mixture through a chromatography column such as HayeSep® D column. In an exemplary embodiment, molecular hydrino is separated from argon by flowing the mixture through a HayeSep® D column at cryogenic temperature such as at liquid argon temperature.

In an embodiment, hydrino is formed by catalytically by recombining hydrogen and oxygen in argon with the reactants in a gaseous or liquid state using a recombination catalyst. Exemplary recombination catalysts are noble metals such as Pt or Pd that may be supported on a support such as a ceramic. The ceramic support may comprise alumina such as alumina beads. Hydrino may be formed in liquid argon with co-condensed oxygen that is then removed by H₂ addition in the presence of a recombination catalyst such Pd or Pt.

The argon comprising hydrino such as H₂(¼) may be used as fuel to form hydrino H(1/p) and H₂(1/p) with p>4 wherein the argon comprising H₂(¼) is flowed into the reaction cell chamber of the SunCell® as a reactant. The hydrino plasma maintained in the reaction cell chamber may break the bond of H₂(¼) to form H(¼) that may serve as a catalyst and reactant to form lower energy hydrino states.

In an embodiment, a high-voltage discharge into water such as an arc discharge with a voltage greater than 1 kV results in the formation of hydrino species such as H₂(¼). The hydrino species may interact with at least one of water and mutually interact. The interaction may form a surface coating on water that may change its surface tension. The surface coating may act as a surfactant. The surfactant may decrease the surface tension of water. The surface coating may be manifest as the ability of water to form bridges between two displaced water reservoirs. Soap for example can reduce the surface tension of water and cause the formation of deformable bridges between two water reservoirs.

In an embodiment, the energetic hydrino plasma may drive the reaction of at least one of H₂O and H₂ with of at least one of carbon, CO, and CO₂ to form methane. At least one of atomic hydrino and molecular hydrino may catalyze the reaction of at least one of H₂O and H₂ with of at least one of carbon, CO, and CO₂ to form methane. The energetic hydrino plasma may drive the reaction of H₂O to H₂+½ O2 to form hydrogen gas. The hydrogen and oxygen gases may be separated and collected to use as industrial gases. The power of the hydrino reaction may be converted into other forms of fuel such as at least one of H₂, methane, and hydrocarbons.

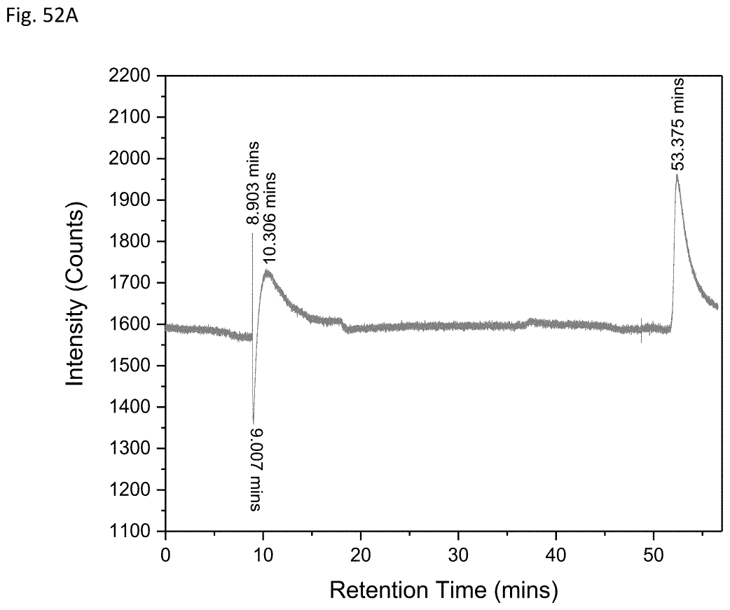

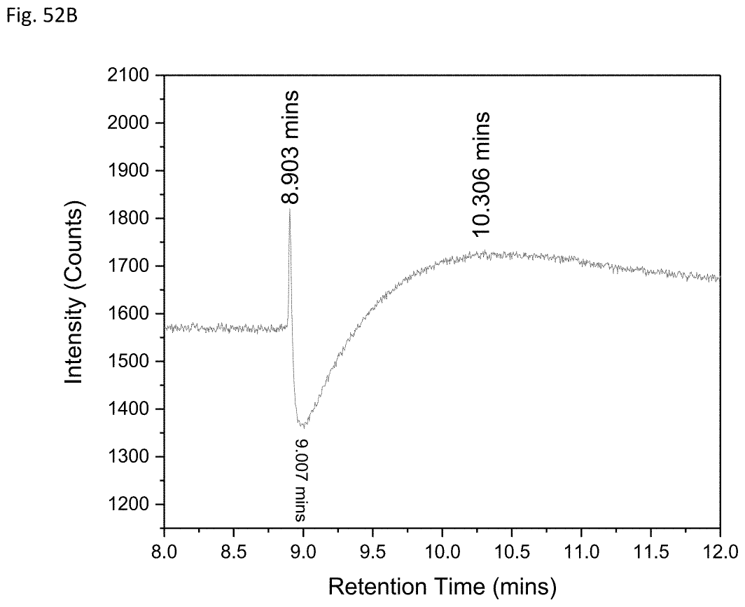

In an embodiment, the molecular hydrino gas chromatography peak such as that of H₂(¼) (FIG. 52A) is observed with methane such that the identification of methane or carbon by means such as XRD, EDS, NMR, and mass spectroscopy comprises a means to screen for samples that comprise molecular hydrino. Exemplary samples to screen are gallium oxide and samples of aqueous NaOH treated gallium oxide from the SunCell®. In an embodiment, carbon may be added to the hydrino reaction mixture to trap molecular hydrino. Methane may form in the reaction as well that may further assist the carbon trapping of hydrino by methane intercalation that enhances the carbon-molecular hydrino bonding. In an embodiment, additional signatures unique to molecular hydrino such as the EPR, FTIR, Raman, XPS, and other molecular hydrino signatures of the disclosure may be used to screen samples for the presence of molecular hydrino.

In an embodiment, a reactor to form lower energy hydrogen species such as H(1/p) and H₂(1/p) wherein p is an integer comprises a molten salt that serves as a source of at least one of H and HOH catalyst. The molten salt may comprise a mixture of salts such as a eutectic mixture. The mixture may comprise at least one of a hydroxide and a halide such as a mixture of at least one of alkaline and alkaline earth hydroxides and halides such as LiOH—LiBr or KOH—KCl. The reactor may further comprise a heater, a heater power supply, and a temperature controller to maintain the salt in a molten state. The reactor may further comprise an electrolysis system comprising at least two electrodes and a power supply. The electrodes may be stable in the electrolyte. Exemplary electrodes are nickel and noble metal electrodes. Water may be supplied to the cell and a voltage such as a DC voltage may be applied to the electrodes. Hydrogen may form at the cathode and oxygen may form at the anode. The hydrogen may react with HOH catalyst also formed in the cell to form hydrino. The energy from the formation of hydrino may produce heat in the cell. The cell may be well insulated such that the heat from the hydrino reaction may reduce the amount of power required for the heater to maintain the molten salt. The reactor may further comprise a heat exchanger. The heat exchanger may remove excess heat to be delivered to an external load.

### Experimental

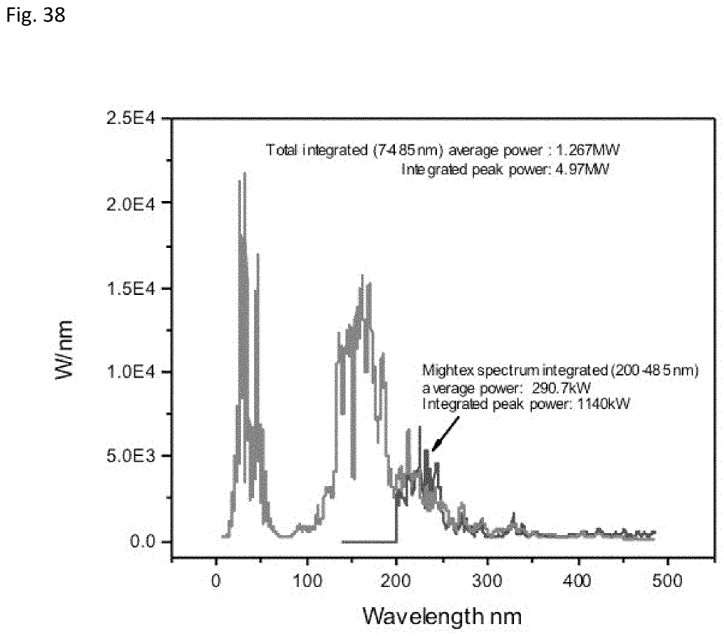

The SunCell® power generation system typically includes a photovoltaic power converter configured to capture plasma photons generated by the fuel ignition reaction and convert them into useable energy. In some embodiments, high conversion efficiency may be desired. The reactor may expel plasma in multiple directions, e.g., at least two directions, and the radius of the reaction may be on the scale of approximately several millimeters to several meters, for example, from about 1 mm to about 25 cm in radius. Additionally, the spectrum of plasma generated by the ignition of fuel may resemble the spectrum of plasma generated by the sun and/or may include additional short wavelength radiation. FIG. 38 shows an exemplary the absolute spectrum in the 5 nm to 450 nm region of the ignition of a 80 mg shot of silver comprising absorbed H₂O from water addition to melted silver as it cooled into shots showing an average optical power of 1.3 MW, essentially all in the ultraviolet and extreme ultraviolet spectral region. The ignition was achieved with a low voltage, high current using a Taylor-Winfield model ND-24-75 spot welder. The voltage drop across the shot was less than 1 V and the current was about 25 kA. The high intensity UV emission had duration of about 1 ms. The control spectrum was flat in the UV region. The radiation of the solid fuel such as at least one of line and blackbody emission may have an intensity in at least one range of about 2 to 200,000 suns, 10 to 100,000 suns, 100 to 75,000 suns. In an embodiment, the inductance of the welder ignition circuit may be increased to increase the current decay time following ignition. The longer decay time may maintain the hydrino plasma reaction to increase the energy production. The continuum radiation with the predicted 10.1 nm cutoff confirms the production of H(¼).

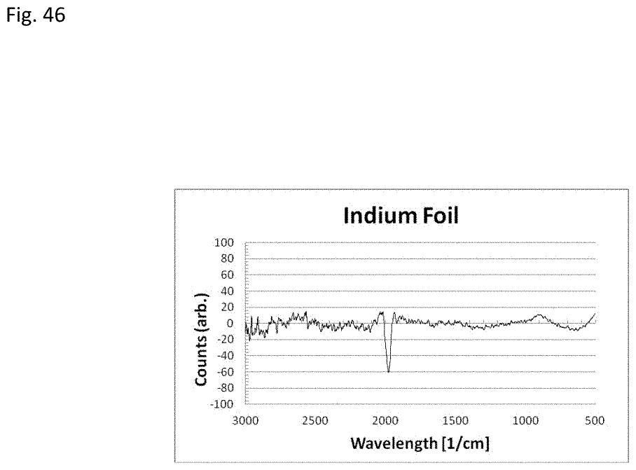

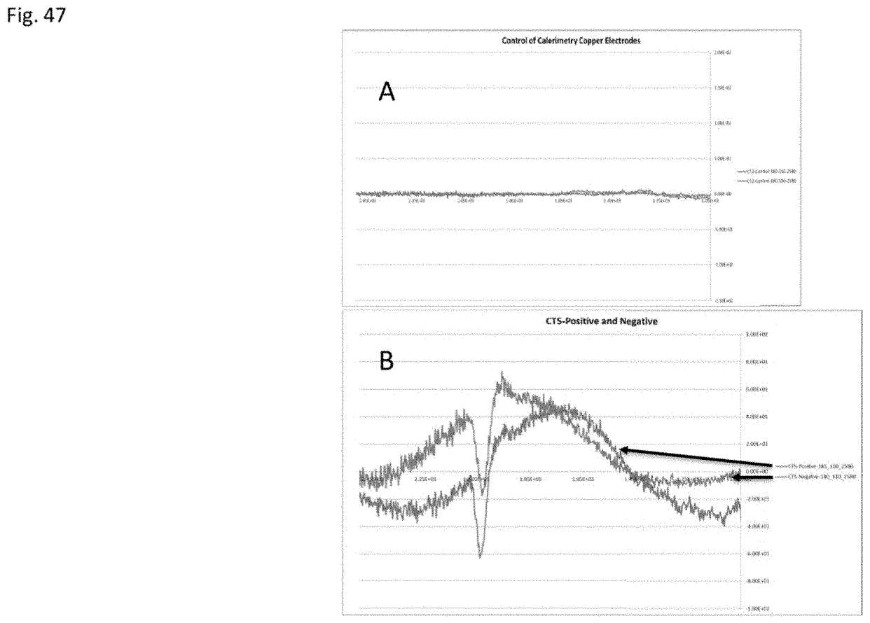

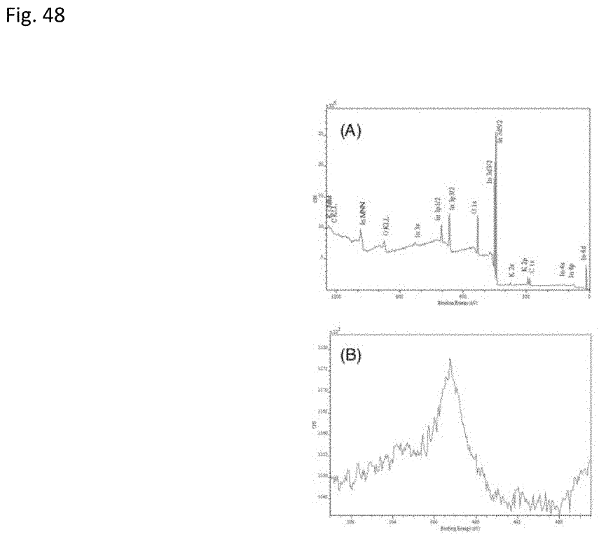

XPS and Raman were performed on the electrodes pre and post detonation. The post-detonation electrodes each showed a very large 1940 cm⁻¹ Raman peak such as that shown in FIGS. 46 and 47, panel B. The post detonation XPS showed a large 496 eV peak such as that shown in FIG. 48, panels A-B that matched the total energy of H₂(¼). No other primary element peaks of the only alternative assignments, Na, Sn, or Zn, were present confirming that H₂(¼) was the product of the extraordinarily energetic reaction. No Raman or XPS peaks were observed in the 1940 cm⁻¹ or 496 eV regions in the Raman or XPS spectra, respectively, of the per-detonation electrodes.

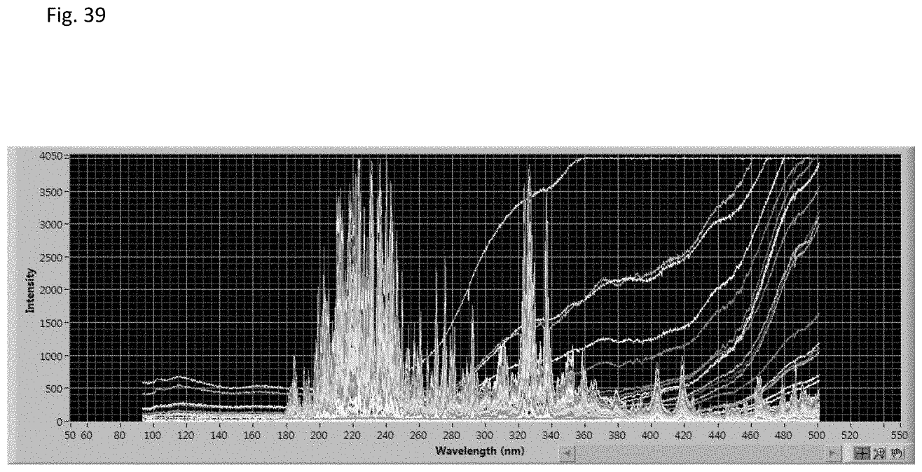

The UV and EUV spectrum may be converted to blackbody radiation. The conversion may be achieved by causing the cell atmosphere to be optically thick for the propagation of at least one of UV and EUV photons. The optical thickness may be increased by causing metal such as the fuel metal to vaporize in the cell. The optically thick plasma may comprise a blackbody. The blackbody temperature may be high due to the extraordinarily high power density capacity of the hydrino reaction and the high energy of the photons emitted by the hydrino reaction. The spectrum (100 nm to 500 nm region with a cutoff at 180 nm due to the sapphire spectrometer window) of the ignition of molten silver pumped into W electrodes in atmospheric argon with an ambient H₂O vapor pressure of about 1 Torr is shown in FIG. 39. The source of electrical power 2 comprised two sets of two capacitors in series (Maxwell Technologies K2 Ultracapacitor 2.85V/3400F) that were connected in parallel to provide about 5 to 6 V and 300 A of constant current with superimposed current pulses to 5 kA at frequency of about 1 kHz to 2 kHz. The average input power to the W electrodes (1 cm×4 cm) was about 75 W. The initial UV line emission transitioned to 5000K blackbody radiation when the atmosphere became optically thick to the UV radiation with the vaporization of the silver by the hydrino reaction power. The power density of a 5000K blackbody radiator with an emissivity of vaporized silver of 0.15 is 5.3 MW/m². The area of the observed plasma was about 1 m². The blackbody radiation may heat a component of the cell 26 such as top cover 5b4 that may serve as a blackbody radiator to the PV converter 26a in a thermophotovoltaic embodiment of the disclosure.

An exemplary test of a melt comprising a source of oxygen comprised the ignition an 80 mg silver/1 wt % borax anhydrate shot in an argon/5 mole % H₂ atmosphere with the optical power determined by absolute spectroscopy. Using a welder (Acme 75 KVA spot welder) to apply a high current of about 12 kA at a voltage drop of about 1 V 250 kW of power was observed for duration of about 1 ms. In another exemplary test of a melt comprising a source of oxygen comprised the ignition an 80 mg silver/2 mol % Na₂O anhydrate shot in an argon/5 mole % H₂ atmosphere with the optical power determined by absolute spectroscopy. Using a welder (Acme 75 KVA spot welder) to apply a high current of about 12 kA at a voltage drop of about 1 V 370 kW of power was observed for duration of about 1 ms. In another exemplary test of a melt comprising a source of oxygen comprised the ignition an 80 mg silver/2 mol % Li₂O anhydrate shot in an argon/5 mole % H₂ atmosphere with the optical power determined by absolute spectroscopy. Using a welder (Acme 75 KVA spot welder) to apply a high current of about 12 kA at a voltage drop of about 1 V 500 kW of power was observed for duration of about 1 ms.

Based on the size of the plasma recorded with an Edgertronics high-speed video camera, the hydrino reaction and power depends on the reaction volume. The volume may need to be a minimum for optimization of the reaction power and energy such as about 0.5 to 10 liters for the ignition of a shot of about 30 to 100 mg such as a silver shot and a source of H and HOH catalyst such as hydration. From the shot ignition, the hydrino reaction rate is high at very high silver pressure. In an embodiment, the hydrino reaction may have high kinetics with the high plasma pressure. Based on high-speed spectroscopic and Edgertronics data, the hydrino reaction rate is highest at the initiation when the plasma volume is the lowest and the Ag vapor pressure is the highest. The 1 mm diameter Ag shot ignites when molten (T=1235 K). The initial volume for the 80 mg (7.4×10⁻⁴ moles) shot is 5.2×10⁻⁷ liters. The corresponding maximum pressure is about 1.4×10⁵ atm. In an exemplary embodiment, the reaction was observed to expand at about sound speed (343 m/s) for the reaction duration of about 0.5 ms. The final radius was about 17 cm. The final volume without any backpressure was about 20 liters. The final Ag partial pressure was about 3.7E-3 atm. Since the reaction may have higher kinetics at higher pressure, the reaction rate may be increased by electrode confinement by applying electrode pressure and allowing the plasma to expand perpendicular to the inter-electrode axis.

The power released by the hydrino reaction caused by the addition of one mole % or 0.5 mole % bismuth oxide to molten silver injected into ignition electrodes of a SunCell® at 2.5 ml/s in the presence of a 97% argon/3% hydrogen atmosphere was measured. The relative change in slope of the temporal reaction cell water coolant temperature before and after the addition of the hydrino reaction power contribution corresponding to the oxide addition was multiplied by the constant initial input power that served as an internal standard. For duplicate runs, the total cell output powers with the hydrino power contribution following oxygen source addition were determined by the products of the ratios of the slopes of the temporal coolant temperature responses of 97, 119, 15, 538, 181, 54, and 27 corresponding to total input powers of 7540 W, 8300 W, 8400 W, 9700 W, 8660 W, 8020 W, and 10,450 W. The thermal burst powers were 731,000 W, 987,700 W, 126,000 W, 5,220,000 W, 1,567,000 W, 433,100 W, and 282,150 W, respectively.

The power released by the hydrino reaction caused by the addition of one mole % bismuth oxide (Bi₂O₃), one mole % lithium vanadate (LiVO₃), or 0.5 mole % lithium vanadate to molten silver injected into ignition electrodes of a SunCell® at 2.5 ml/s in the presence of a 97% argon/3% hydrogen atmosphere was measured. The relative change in slope of the temporal reaction cell water coolant temperature before and after the addition of the hydrino reaction power contribution corresponding to the oxide addition was multiplied by the constant initial input power that served as an internal standard. For duplicate runs, the total cell output powers with the hydrino power contribution following oxygen source addition were determined by the products of the ratios of the slopes of the temporal coolant temperature responses of 497, 200, and 26 corresponding to total input powers of 6420 W, 9000 W, and 8790 W. The thermal burst powers were 3.2 MW, 1.8 MW, and 230,000 W, respectively.

In an exemplary embodiment, the ignition current was ramped from about 0 A to 2000 A corresponding to a voltage increase from about 0 V to 1 V in about 0.5, at which voltage the plasma ignited. The voltage is then increased as a step to about 16 V and held for about 0.25 s wherein about 1 kA flowed through the melt and 1.5 kA flowed in series through the bulk of the plasma through another ground loop other than the electrode 8. With an input power of about 25 kW to a SunCell® comprising Ag (0.5 mole % LiVO₃) and argon-H₂ (3%) at a flow rate of 9 liters/s, the power output was over 1 MW. The ignition sequence repeated at about 1.3 Hz.

In an exemplary embodiment, the ignition current was about 500 A constant current and the voltage was about 20 V. With an input power of about 15 kW to a SunCell® comprising Ag (0.5 mole % LiVO₃) and argon-H₂ (3%) at a flow rate of 9 liters/s, the power output was over 1 MW.

In an embodiment, operating parameters such as the gas flow, the gas composition such as the composition of an argon-hydrogen mixture, gas flow rate, scale, geometry, EM pumping rate, operating temperature, and ignition waveform, current, voltage, and power are optimized. A set of experimental SunCells® were tested with a DC ignition voltage of 25-30 V and a current of 1500 A-3000 A wherein each comprised (i) an inverted pedestal such as one shown in FIG. 25 with the pedestal electrode positive, (ii) gallium as the molten metal pumped at 200 g/s, (iii) H₂ flowed at 3000 sccm and O₂ flowed at 30 sccm with mixing in a torch and flowed through 1 g of 10% Pt/Al₂O₃ at over 90° C. as the source of HOH catalyst and H in the reaction cell chamber. The optimal scale rank order was found to be a 6-inch diameter sphere>8-inch diameter sphere>12-inch diameter sphere, and 4 inch-sided cube>6 inch-sided cube >9 inch-sided cube.

In an embodiment of the 6-inch diameter spherical cell comprising Galinstan as the molten metal, the hydrino reaction was supplied with 750 sccm H₂ and 30 O₂ sccm mixed in an oxyhydrogen torch and flowed through a recombiner chamber comprising 1 g of 10% Pt/Al₂O₃ at greater than 90° C. before flowing into the cell. In addition, the reaction cell chamber was supplied with 1250 sccm of H₂ that was flowed through a second recombiner chamber comprising 1 g of 10% Pt/Al₂O₃ at greater than 90° C. before flowing into the cell. Each of the three gas supplies was controlled by a corresponding mass flow controller. The combined flow of H₂ and O₂ provided HOH catalyst and atomic H, and the second H₂ supply provided additional atomic H. The hydrino reaction plasma was maintained with a DC input of about 30-35 V and about 1000 A. The input power measured by VI integration was 34.6 kW, and the output power of 129.4 kW was measured by molten metal bath calorimetry wherein the gallium in the reservoir and the reaction cell chamber served as the bath.

In an embodiment of the 4 inch-sided cell preloaded with 2500 sccm H₂ and 70 sccm O₂ and comprising a Ta liner on the walls of the reaction cell chamber, a current in the range of 3000 A to 1500 A was supplied by a capacitor bank charged to 50 V. The capacitor bank comprised 3 parallel banks of 18 capacitors (Maxwell Technologies K2 Ultracapacitor 2.85V/3400 F) in series that provided a total bank voltage capability of 51.3V with a total bank capacitance of 566.7 Farads. The input power was 83 kW, and the output power was 338 kW. In an embodiment of the 6-inch diameter spherical cell supplied with 4000 sccm H₂ and 60 sccm O₂, a current in the range of 3000 A to 1500 A was supplied by the capacitor bank charged to 50 V. The input power was 104 kW, and the output power was 341 kW.

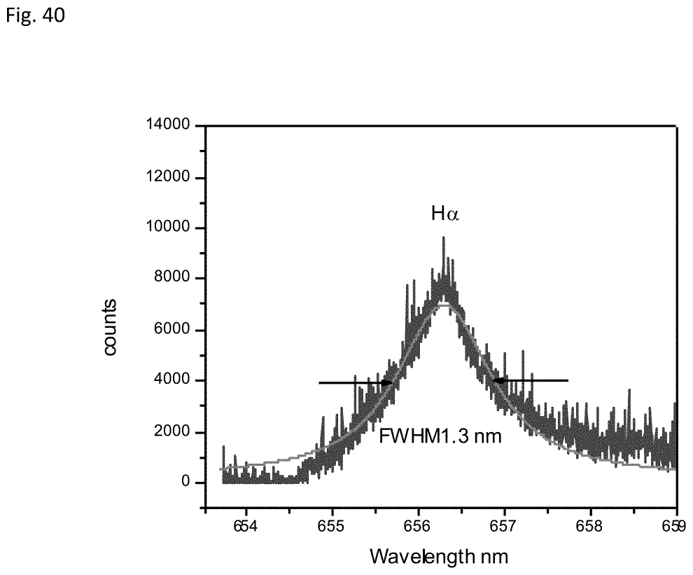

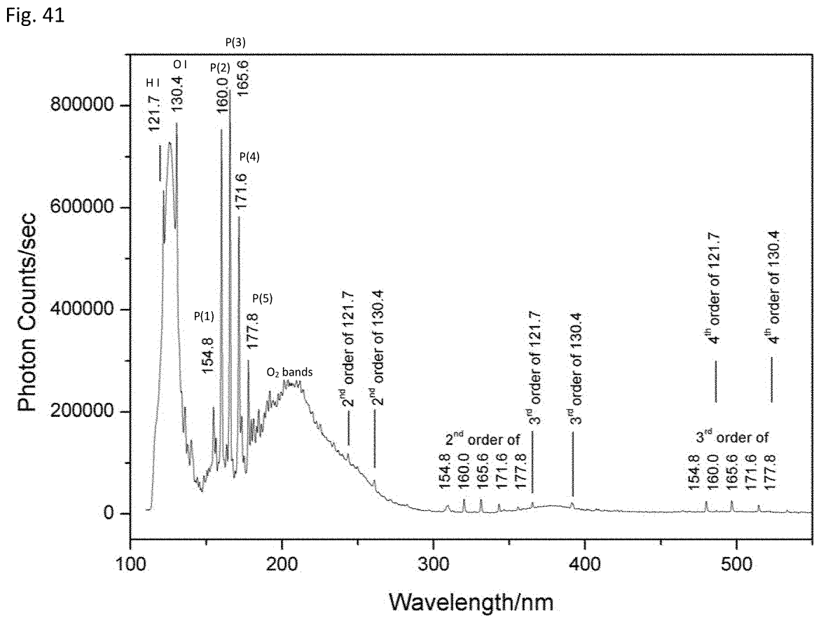

The extraordinary power density produced by the hydrino reaction run in a 2-liter Pyrex SunCell® is evident from the observed extreme Stark broadening of the H alpha line of 1.3 nm shown in FIG. 40. The broadening corresponds to an electron density of 3.5×10²³/m³. The SunCell® gas density was calculated to be 2.5×10²⁵ atoms/m³ based on an argon-H₂ pressure of 800 Torr and temperature of 3000K. The corresponding ionization fraction was about 10%. Given that argon and H₂ have ionization energies of about 15.5 eV and a recombination lifetime of less than 100 us at high pressure, the power density to sustain the ionization is

$$P = ( \frac{3.5 \times {10}^{23} electrons}{{m}^{3}} ) ( 15. 5 eV ) ( \frac{1.6 \times {10}^{- 19} J}{ eV} ) ( \frac{1}{1 {0}^{- 4 } s} ) = \frac{8.7 \times {10}^{9} W}{{m}^{3}} .$$

In an embodiment shown in FIG. 34, the system 500 to form macro-aggregates or polymers comprising lower-energy hydrogen species comprises a chamber 507 such as a Plexiglas chamber, a metal wire 506, a high voltage capacitor 505 with ground connection 504 that may be charged by a high voltage DC power supply 503, and a switch such as a 12 V electric switch 502 and a triggered spark gap switch 501 to close the circuit from the capacitor to the metal wire 506 inside of the chamber 507 to cause the wire to detonate. The chamber may comprise water vapor and a gas such as atmospheric air or a noble gas.

An exemplary system to form macro-aggregates or polymers comprising lower-energy hydrogen species comprises a closed rectangular cuboid Plexiglas chamber having a length of 46 cm and a width and height of 12.7 cm, a 10.2 cm long, 0.22˜0.5 mm diameter metal wire mounted between two stainless poles with stainless nuts at a distance of 9 cm from the chamber floor, a 15 kV capacitor (Westinghouse model 5PH349001AAA, 55 uF) charged to about 4.5 kV corresponding to 557 J, a 35 kV DC power supply to charge the capacitor, and a 12 V switch with a triggered spark gap switch (Information Unlimited, model-Trigatron10, 3 kJ) to close the circuit from the capacitor to the metal wire inside of the chamber to cause the wire to detonate. The wire may comprise a Mo (molybdenum gauze, 20 mesh from 0.305 mm diameter wire, 99.95%, Alpha Aesar), Zn (0.25 mm diameter, 99.993%, Alpha Aesar), Fe—Cr—Al alloy (73%-22%-4.8%, 31 gauge, 0.226 mm diameter, KD Cr—Al—Fe alloy wire Part No #1231201848, Hyndman Industrial Products Inc.), or Ti (0.25 mm diameter, 99.99%, Alpha Aesar) wire. In an exemplary run, the chamber contained air comprising about 20 Torr of water vapor. The high voltage DC power supply was turned off before closing the trigger switch. The peak voltage of about 4.5 kV discharged as a damped harmonic oscillator over about 300 us at a peak current of 5 kA. Macro-aggregates or polymers comprising lower-energy hydrogen species formed in about 3-10 minutes after the wire detonation. Analytical samples were collected from the chamber floor and wall, as well as on a Si wafer placed in the chamber. The analytical results matched the hydrino signatures of the disclosure.

In an embodiment shown in FIG. 41, the hydrino ro-vibrational spectrum is observed by electron-beam excitation of a mixture gas comprising inert gas such as argon gas and H₂(¼) formed by the recombination of H and O as the source of HOH catalyst for atomic hydrogen (OH band 309 nm, O 130.4 nm, H 121.7 nm). The argon may be in a pressure range of about 100 Torr to 10 atm. The water vapor may be in the range of about 1 micro-Torr to 10 Torr. The electron beam energy may be in the range of about 1 keV to 100 keV. Rotational lines were observed in the 145-300 nm region from atmospheric pressure argon plasmas comprising H₂(¼) excited by a 12 keV to 16 keV electron-beam incident the gas in a chamber through a silicon nitride window. The emission was observed through MgF₂ another window of the reaction gas chamber. The energy spacing of 4² times that of hydrogen established the internuclear distance as ¼ that of H₂ and identified H₂(¼) (Eqs. (29-31)). The series matched the P branch of H₂(¼) for the H₂(¼) vibrational transition v=1→v=0 comprising P(1), P(2), P(3), P(4), and P(5) that were observed at 154.8, 160.0, 165.6, 171.6, and 177.8, respectively. In another embodiment, a composition of matter comprising hydrino such as one of the disclosure is thermally decomposed and the decomposition gas comprising hydrino such as H₂(¼) is introduced into the reaction gas chamber wherein the hydrino gas is excited with the electron beam and the ro-vibrational emission spectrum is recorded.

H₂(¼) gas of an argon/H₂(¼) mixture formed by recombination of hydrogen and oxygen on a supported noble metal catalyst in an argon atmosphere was enriched by flowing the mixture through a 35 m long, 2.5 mm ID HayeSep® D chromatographic column cooled to a cryogenic temperature in a liquid argon. The argon was partially liquefied to permit the flowing molecular hydrino gas to be enriched as indicated by the dramatic increase in the ro-vibrational P branch of H₂(¼) observed by e-beam excitation emission spectroscopy as shown in FIG. 42.

The argon gas was treated with a hot titanium ribbon that removes impurities. The e-beam spectrum was repeated with the purified argon, and the P branch of H₂(¼) was not observed. Raman spectroscopy was performed on the Ti ribbon that was used to remove the H₂(¼) gas, and at peak was observed at 1940 cm⁻¹ that matches the rotational energy of H₂(¼) confirming that it was the source of the series of lines in the 150-180 nm region shown in FIG. 41. The 1940 cm⁻¹ peak matched that shown in FIG. 46.

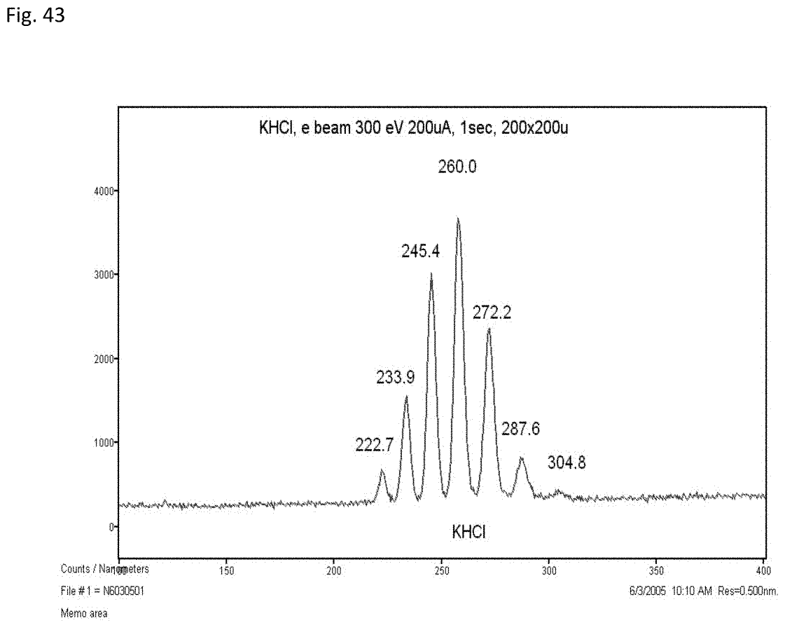

In another embodiment, hydrino gas such as H₂(¼) is absorbed in a getter such as an alkali halide or alkali halide alkali hydroxide matrix. The rotational vibrational spectrum may be observed by electron beam excitation of the getter in vacuum (FIG. 43). The electron beam energy may be in the range of about 1 keV to 100 keV. The rotational energy spacing between peaks may be given by Eq. (30). The vibrational energy given by Eq. (29) may be shifted to lower energy due to a higher effective mass caused by the crystalline matrix. In an exemplary experimental example, ro-vibrational emission of H₂ (¼) trapped in the crystalline lattice of getters was excited by an incident 6 KeV electron gun with a beam current of 10-20 μA in at a pressure range of about 5×10⁻⁶ Torr, and recorded by windowless UV spectroscopy. The resolved ro-vibrational spectrum of H₂(¼) (so called 260 nm band) in the UV transparent matrix KCl that served as a getter in a 5 W CIHT cell stack of Mills et al. (R. Mills, X Yu, Y. Lu, G Chu, J. He, J. Lotoski, “Catalyst induced hydrino transition (CIHT) electrochemical cell,” (2012), Int. J. Energy Res., (2013), DOI: 10.1002/er.3142 which is incorporated by reference) comprised a peak maximum at 258 nm with representative positions of the peaks at 222.7, 233.9, 245.4, 258.0, 272.2, and 287.6 nm, having an equal spacing of 0.2491 eV. In general, the plot of the energy versus peak number yields a line given by y=−0.249 eV±5.8 eV at R2=0.999 or better in very good agreement with the predicted values for H₂(¼) for the transitions ν=1→ν=0 and Q(0), R(0), R(1), R(2), P(1), P(2), P(3), and P(4) wherein Q(0) is identifiable as the most intense peak of the series.

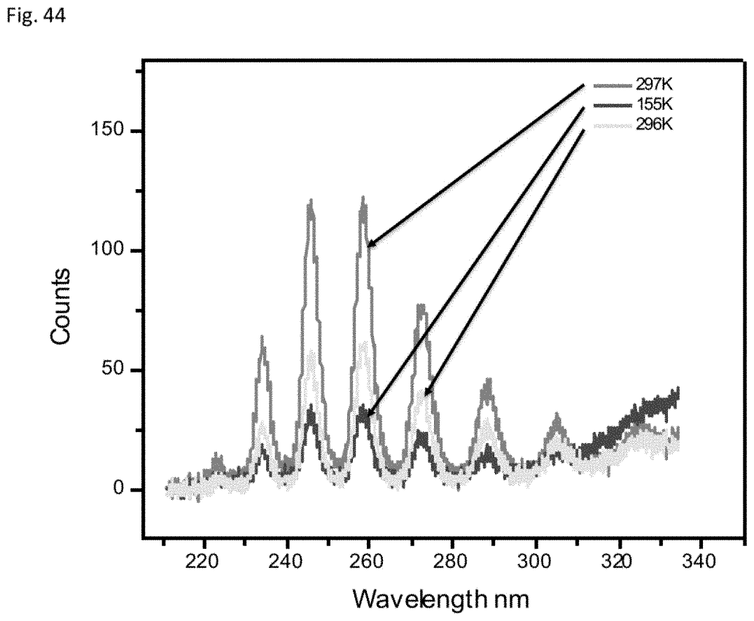

Ro-vibrational excitation bands are de-populated and inhibited from excitation by cooling the sample. Molecular hydrino was formed in a KCl crystal that comprised waters of hydration that served as sources of H and HOH hydrino catalyst. The familiar ro-vibrational emission of H₂ (¼) trapped in the crystalline lattice (260 nm band) was observed by windowless UV spectroscopy (FIG. 44) wherein the pellet sample was excited by an incident 6 KeV electron gun with a beam current of 25 μA. The e-beam pellet sample was thermally cycled from 297 K-155 K-296 K wherein the sample cooling was performed using a cryopump system (Helix Corp., CTI-Cryogenics Model SC compressor; TRI-Research Model T-2000D-IEEE controller; Helix Corp., CTI-Cryogenics model 22 cryodyne). The 0.25 eV-spaced series of peaks reversibly decreased in intensity at the cold temperature with the e-beam current maintained constant. The intensity decrease was due to a change in the 260 nm band emitter since the background in the spectral region above 310 nm actually increased at the cryotemperature. These results confirm that the origin of the emission is due to ro-vibration with a near perfect match to the rotational energy of H₂(¼). It was shown by Mills [R. Mills, X Yu, Y. Lu, G Chu, J. He, J. Lotoski, “Catalyst induced hydrino transition (CIHT) electrochemical cell,” (2012), Int. J. Energy Res., (2013), DOI: 10.1002/er.3142] that there was no structure to the lines assigned to H₂(¼) using high resolution visible spectroscopy in second order with an accuracy od±1 Å, further confirming the assign to H₂(¼) ro-vibration.

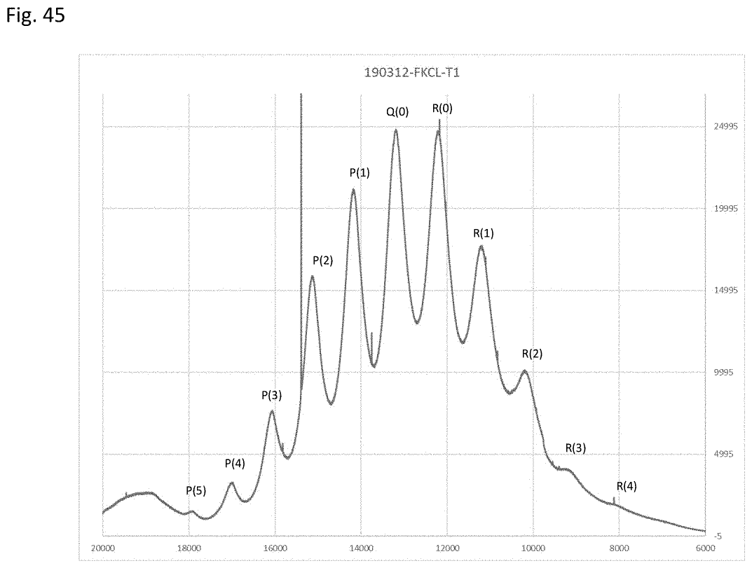

Another successful cross-confirmatory technique in the search for hydrino spectra involved the use of the Raman spectrometer to record the ro-vibration of H₂(¼) as second order fluorescence matching the previously observed first order spectrum in the ultraviolet, the 260 nm e-beam band [R. Mills, X Yu, Y. Lu, G Chu, J. He, J. Lotoski, “Catalyst induced hydrino transition (CIHT) electrochemical cell,” (2012), Int. J. Energy Res., (2013), DOI: 10.1002/er.3142]. H₂(¼) formed in a stainless steel SunCell® was released as a gas for analysis by two methods: (i) 900° C. heating of the oxide mixture formed by water addition to the SunCell® to maintain a hydrino plasma reaction wherein the heating caused decomposition of Ga₂O₃:H₂(¼) of the mixture and (ii) 900° C. heating of the filtrate of the oxide mixture dissolved in NaOH. The Raman spectrum of KCl getter of the gas from the thermal decomposition of at least one of the filtrate of the NaOH dissolution product of gallium oxide or gallium oxide comprising van der Waals bound H₂(¼) gas was recorded using the Horiba Jobin Yvon LabRAM Aramis Raman spectrometer with a HeCd 325 nm laser in microscope mode with a magnification of 40×. Specifically, KCl was packed in a tube connected to a pressure vessel containing Ga₂O₃:H₂(¼) collected from the SunCell®, and the decomposition gas from heating the Ga₂O₃:H₂(¼) to 900° C. was flowed through the KCl getter. The Raman spectrum on KCl starting material was unremarkable; whereas, the KCl getter Raman comprised a series of 1000 cm⁻¹ (0.1234 eV) equal-energy spaced Raman peaks observed in the 8000 cm⁻¹ to 18,000 cm⁻¹ region. The conversion of the Raman spectrum into the fluorescence or photoluminescence spectrum revealed a match as the second order ro-vibrational spectrum of H₂(¼) corresponding to the 260 nm band first observed by e-beam excitation [R. Mills, X Yu, Y. Lu, G Chu, J. He, J. Lotoski, “Catalyst induced hydrino transition (CIHT) electrochemical cell,” (2012), Int. J. Energy Res., (2013), DOI: 10.1002/er.3142]. Assigning Q(0) to the most intense peak, the peak assignments given in TABLE 5 to the Q, R, and P branches for the spectra shown in FIG. 45 are Q(0), R(0), R(1), R(2), R(3), R(4), P(1), P(2), P(3), P(4), and P(5) observed at 13,188, 12,174, 11,172, 10,159, 9097, 8090, 14,157, 15,106, 16,055, 16,975, and 17,873 cm⁻¹, respectively. The theoretical transition energies with peak assignments compared with the observed Raman spectrum are shown in TABLE 5.

TABLE 5
Comparison of the theoretical transition energies and
transition assignments with the observed Raman peaks.

| | Calculated | Experimental | Difference |
|---|---|---|---|
| Assignment | (cm⁻¹) | (cm⁻¹) | (%) |
| P(5) | 18,056 | 17,873 | −1.0 |
| P(4) | 17,082 | 16,975 | −0.6 |
| P(3) | 16,109 | 16,055 | −0.3 |
| P(2) | 15,135 | 15,106 | −0.2 |
| P(1) | 14,162 | 14,157 | 0 |
| Q(0) | 13,188 | 13,188 | 0 |
| R(0) | 12,214 | 12,174 | −0.3 |
| R(1) | 11,241 | 11,172 | −0.6 |
| R(2) | 10,267 | 10,159 | −1.1 |
| R(3) | 9,294 | 9,097 | −2.1 |
| R(4) | 8,320 | 8,090 | −2.8 |

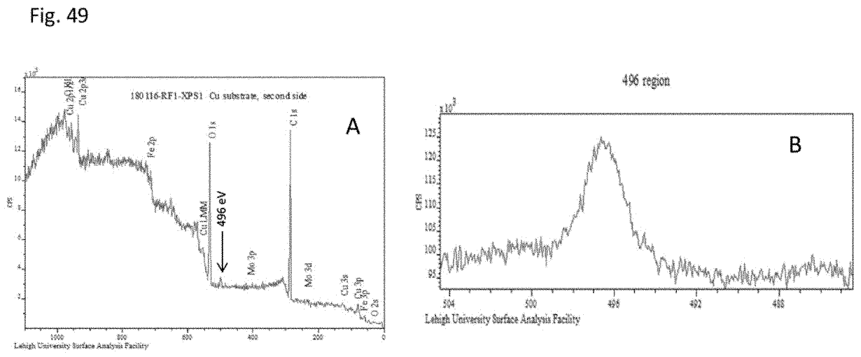

In foil was exposed to the gases from the ignition of the solid fuel comprising 100 mg Cu+30 mg deionized water sealed in the aluminum DSC pan. The predicted hydrino product H₂(¼) was identified by Raman spectroscopy and XPS. Using a Thermo Scientific DXR SmartRaman with a 780 nm diode laser, an absorption peak at 1982 cm⁻¹ having a width of 40 cm⁻¹ was observed (FIG. 46) on the indium metal foil that matched the free space rotational energy of H₂(¼) (0.2414 eV) wherein only O and In were observed present by XPS and no compound of these elements could produce the observed peak. Moreover, the XPS spectrum confirmed the presence of hydrino. Using a Scienta 300 XPS spectrometer, XPS was performed on the In foil sample at Lehigh University. A strong peak was observed at 498.5 eV (FIG. 48, panels A-B) that could not be assigned to any known elements. The peak matched the energy of the theoretically allowed double ionization of molecular hydrino H₂(¼). The 496 eV XPS peak of H₂(¼) was also recorded on polymeric hydrino compounds formed for the wire detonation of Mo wires in the presence of an argon atmosphere comprising water vapor as shown in FIG. 49, panels A-B.

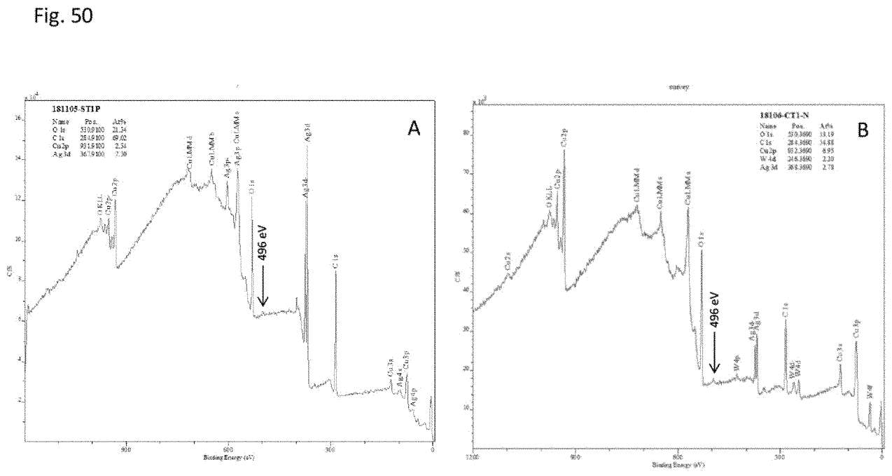

The H₂(¼) rotation energy transition was further confirmed on copper electrodes before and the ignition of 80 mg silver shots comprising 1 mole % H₂O as shown in FIG. 47, panels A-B. The Raman spectra obtained using the Thermo Scientific DXR SmartRaman spectrometer and the 780 nm laser showed an inverse Raman effect peak at 1940 cm⁻¹ formed by the ignition that matches the free rotor energy of H₂(¼) (0.2414 eV). The peak power of 20 MW was measured on the ignited shots using absolute spectroscopy over the 22.8-647 nm region wherein the optical emission energy was 250 times the applied energy [R. Mills, Y. Lu, R. Frazer, “Power Determination and Hydrino Product Characterization of Ultra-low Field Ignition of Hydrated Silver Shots”, Chinese Journal of Physics, Vol. 56, (2018), pp. 1667-1717, incorporated by reference]. The corresponding XPS spectra on copper electrodes post ignition of a 80 mg silver shot comprising 1 mole % H₂O, wherein the detonation was achieved by applying a 12 V 35,000 A current with a spot welder are shown in FIG. 50, panels A-B. The peak at 496 eV was assigned to H₂(¼) wherein other possibilities such Na, Sn, and Zn were eliminated since the corresponding peaks of these candidates are absent.

The excitation of the H₂(¼) ro-vibrational spectrum observed in FIG. 45 was deemed to be by the high-energy UV and EUV He and Cd emission of the laser. Overall, the Raman results such as the observation of the 0.241 eV (1940 cm⁻¹) Raman inverse Raman effect peak and the 0.2414 eV-spaced Raman photoluminescence band that matched the 260 nm e-beam spectrum is strong confirmation of molecular hydrino having an internuclear distance that is ¼ that of H₂. The molecular hydrino assignment by Raman spectroscopy, the inverse Raman effect absorption peak centered at 1982 cm⁻¹, as well as the double ionization of molecular hydrino H₂(¼) observed by XPS at 498.5 eV multiply confirm the hydrino product of HOH catalysis of H.

Furthermore, positive ion ToF-SIMS spectra of the getter having absorbed hydrino reaction product gas showed multimer clusters of matrix compounds with di-hydrogen as part of the structure, M:H₂(1/p) (M=KOH or K₂CO₃). Specifically, the positive ion spectra of prior hydrino reaction products comprising KOH and K₂CO₃ [R. Mills, X Yu, Y. Lu, G Chu, J. He, J. Lotoski, “Catalyst induced hydrino transition (CIHT) electrochemical cell,” (2012), Int. J. Energy Res., (2013), DOI: 10.1002/er.3142] or having these compounds as getters of hydrino reaction product gas showed K+(H₂:KOH), and K+(H₂:K₂CO₃) consistent with H₂(1/p) as a complex in the structure.

In an embodiment, molecular hydrino gas may be formed by reaction of hydrogen and oxygen wherein H and HOH catalyst are maintained by the reaction. Hydrogen and oxygen may be recombined by combustion or by catalytic recombination such as by a recombination catalyst such as Pt/Al₂O₃ or another of the disclosure. A reaction mixture may comprise hydrogen, oxygen, a combustor or a recombiner, and optionally an inert gas to increase at least one of the lifetime and concentration of at least one of atomic H and HOH catalyst. In an embodiment, the reactor to produce hydrino gas comprises an aqueous electrolysis cell and a recombiner and may further comprise an inert gas to support the production of a stoichiometric mixture of hydrogen and oxygen that undergoes recombination with the production of H and HOH by the recombiner and electrolysis wherein the H and HOH form molecular hydrino. To enrich the reactor atmosphere in hydrino gas, the reactor may be closed and operated continuously for a desired duration wherein gas enriched in hydrino gas may be collected from the reactor through a valved outlet by a collection system, and optionally, further enriched in hydrino gas by a gas purification system such as a chromatographic column.

In an exemplary embodiment, molecular hydrino in argon is produced by catalytic recombination of oxygen and hydrogen. Of the noble gases, argon uniquely contains trace hydrino gas due to contamination during purification. Argon and oxygen co-condense during cryo-distillation of air, and the oxygen is removed by reaction with hydrogen on a recombination catalyst such as platinum/Al₂O₃ whereby hydrino is formed during the recombination reaction due to the subsequent reaction of HOH catalyst with H. Electron beam excitation emission of argon gas shows the known peaks of H I, O I, and O₂ bands (FIG. 41). The unknown peaks match molecule hydrino (H₂(¼) P branch) with no other unassigned peaks present in the spectrum. In another embodiment, hydrino gas such as H₂(¼) may be enriched from atmospheric gas or another source such as the SunCell® by cryro-distillation. Alternatively, hydrino gas may be at least one of formed in situ by maintaining a plasma comprising H₂O such as H₂O in a noble gas such as argon. The plasma may be in a pressure range of about 0.1 mTorr to 1000 Torr. The H₂O plasma may comprise another gas such as a noble gas such as argon. In an exemplary embodiment, atmospheric pressure argon plasma comprising 1 Torr H₂O vapor is maintained by a plasma source such as one of the disclosure such as an electron beam, glow, RF, or microwave discharge source.

In an embodiment, a composition of matter comprising hydrino such as one of the disclosure is thermally decomposed, and gas chromatography is performed on the decomposition gas comprising hydrino gas such as H₂(¼). In an exemplary embodiment, H₂(¼) gas may be obtained from thermal decomposition of hydrino compounds such as one from the detonation of a Zn or Sn wire in an atmosphere comprise water vapor according to the disclosure. The gas sample may require rapid loading on the GC due to the observed rapid drop in pressure at elevated temperature such as about 800° C. due to the rapid diffusion of the very small H₂(¼) gas from the vacuum tight pressure vessel. Due to the smaller size and greater mean free path H₂(1/p) may be more thermally conductive than H₂ carrier gas such that a negative peak is observed. There is no gas known that is more thermally conductive than hydrogen; thus, a peak that is faster and negative compared to hydrogen is characteristic and uniquely identifies molecular hydrino such as H₂(¼).

Using an HP 5890 Series II gas chromatograph with thermal conductivity detector (TCD), chromatography was performed on gases released by thermal decomposition of hydrino gas bound to NaOH-treated Ga₂O₃ collected from SunCell® plasma runs and compared to control gases that identified the migration times of known gases. The pressure controller was manually set at 10 PSI for the flow of helium carrier gas at 2.13 ml/min on a capillary column (Agilent molecular sieve 5 Å, (50 m×0.32, df=30 μm) at 303 K (30° C.) with the TCD at 60° C. The gas sample was directly injected from a pressurized gas sample vessel onto the column using a six-way valve. Gas samples having a controlled injection volume of 1.74 ml were provided by a filled 0.065″ ID copper tube having a length of 8″.

The plasma reactor to produce molecular hydrino gas shown in FIG. 25 comprised an 6 inch diameter stainless steel sphere with a DC electromagnetic (EM) pump injector having a stainless steel injection tube and a molybdenum nozzle at the negative z-axis pole of the sphere that served as the anode and a boron nitride pedestal having a central molybdenum rod at the positive z-axis pole of the sphere that served as the cathode. The reactor contained 3.5 kg of gallium that was molten during operating and was injected by the EM pump injector. The SunCell® was pressurized to 800 Torr with argon, H₂ gas was flowed at 100 sccm, and 250 ul of H₂O was injected. About 10 mg of gallium oxide in the cell served as the source of oxygen for HOH catalyst with the H₂ gas wherein the latter also serve as the source of the hydrino reactant atomic hydrogen. The gallium pumping rate was about 30 cm³/s and the plasma DC ignition voltage and current to maintain a plasma of about 100 kW excess power were 50 V and 1000 A, respectively.

Following a 5 minute plasma run, 3 grams of gallium oxide was collected from the SunCell®, the solid was mixed with excess 1 M NaOH for 24 hours, the aquesous solution was decanted, and the insoluble solid was placed in a porous thin-walled ceramic crucible. The crucible was placed into a sixty-five milliliter stainless steel vessel was vacuum-sealed using a copper gasket and stainless steel knife-edge flanged plate having two welded-in ports, one inlet/outlet port and a port for monitoring pressure changes during and after the test. The sealed steel vessel was evacuated, leak checked, and loaded into a smelting furnace (ProCast™ 3 kg 110 Volt U.S. Electric Melting Furnace 2102° F.) and heated to 950° C. over a time interval of 25 to 40 minutes wherein the pressure rose from −30 in Hg to between 15 to 25 PSI. The stainless steel vessel was then connected to the copper sample tube and six-way valve of the gas chromatograph. Optimally, the pressure inside the copper sample tube maintained at least 1000 Torr. Gallium was also subjected to the same protocol as the NaOH-treated Ga₂O₃ to serve as control gas.

In addition to hydrino gas from the heating of the NaOH-treated oxide from the SunCell® and air comprising oxygen (20%), nitrogen (80%), and trace H₂O, the following control gases from Atlantic State Specialty Gas were tested with the helium carrier gas: hydrogen ultrahigh purity (UHP), methane (UHP), and hydrogen (HUP)/methane (UHP) (90/10%). Mass spectroscopy was performed on the hydrino gas following GC analysis using a residual gas analyzer (Ametek Dycor Residual Gas Analyzer Model: Q100M). The hydrino gas sample was repeat analyzed by gas chromatography after sitting at room temperature for at least 24 hours to determine if any species diffused out of the vacuum tight vessel.

As shown by Snavely and Subramaniam [K. Snavely, B. Subramaniam, ‘Thermal conductivity detector analysis of hydrogen using helium carrier gas and HayeSep® D columns”, Journal of Chromatographic Science, Vol. 36, ((1998), pp. 191-196], the hydrogen peak run on the HP5890 with a TCD at a temperature less that 130° C. is positive for all peak intensities. Molecular hydrino gas H₂(1/p) such as H₂(¼) has a volume of that is p³ smaller than ordinary H₂ such that the mean free path for ballistic collisions is p² smaller giving rise to a higher thermal conductivity that H₂. Due to the smaller size and higher thermal conductivity of molecular hydrino gas relative to ordinary H₂, the chromatographic peak of H₂(¼) is anticipated to have a decreased retention time and be positive at low concentration and negative at higher concentration. Thus, a peak before the H₂ peak that may have positive leading and trailing edges and have a negative intensity at it maximum corresponding to maximum concentration of the molecular hydrino band in the helium carrier gas can only be hydrino since helium does not produce a peak in helium carrier gas and no known gas has a shorter retention time and higher thermal conductivity than hydrogen or helium.

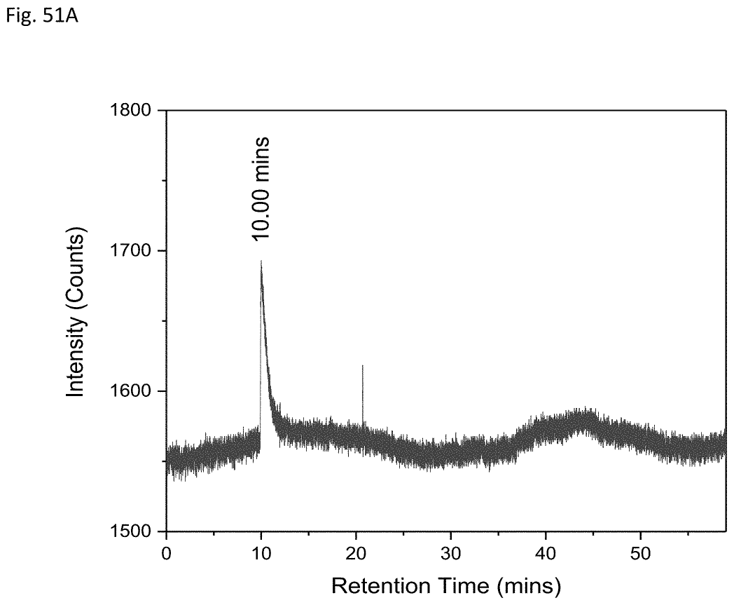

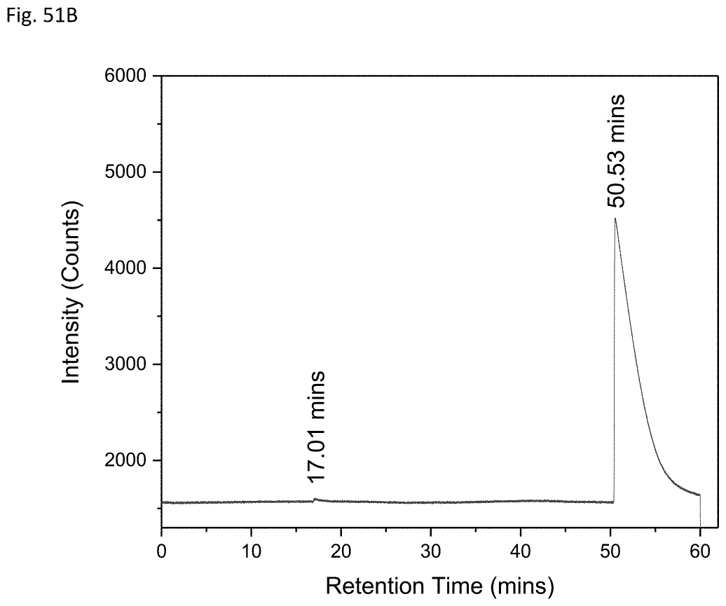

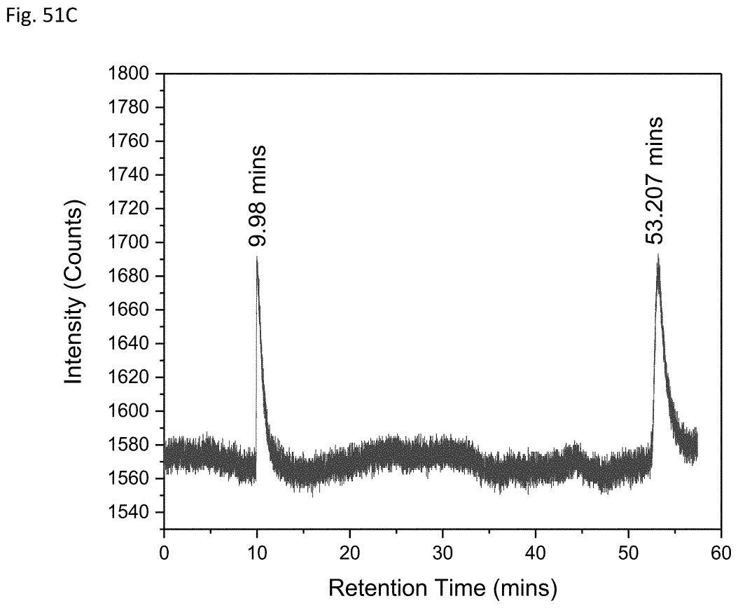

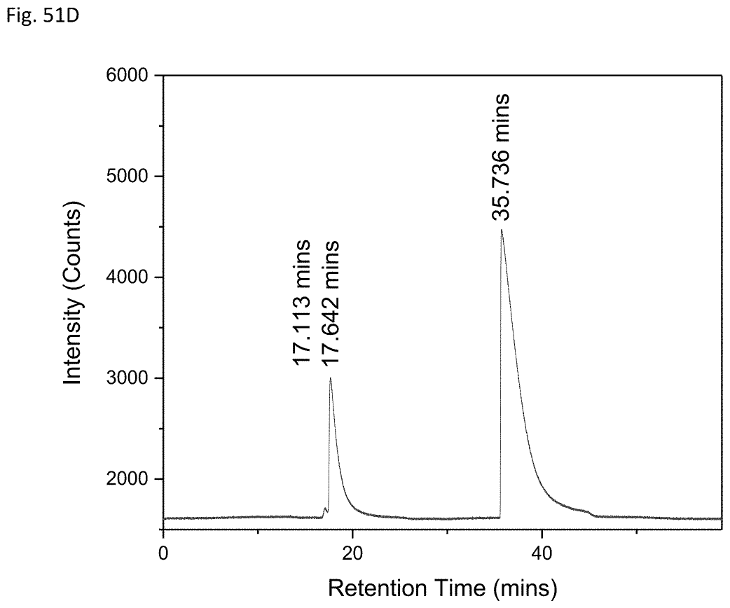

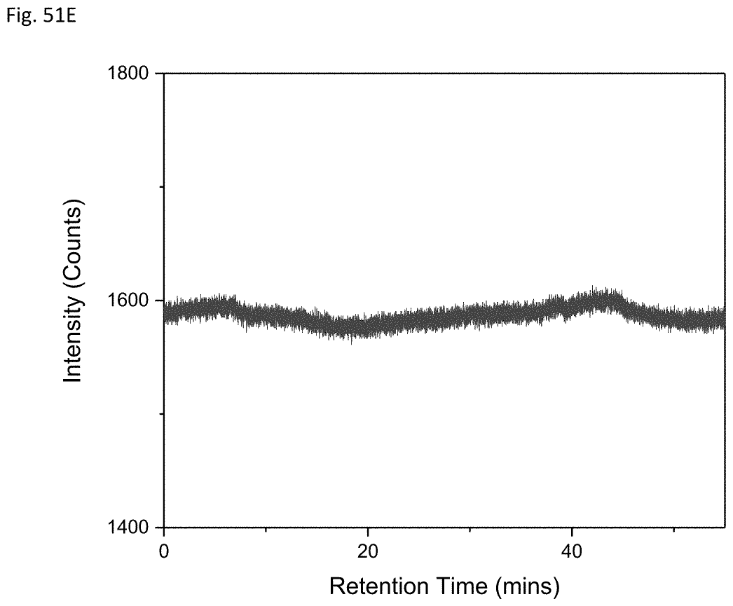

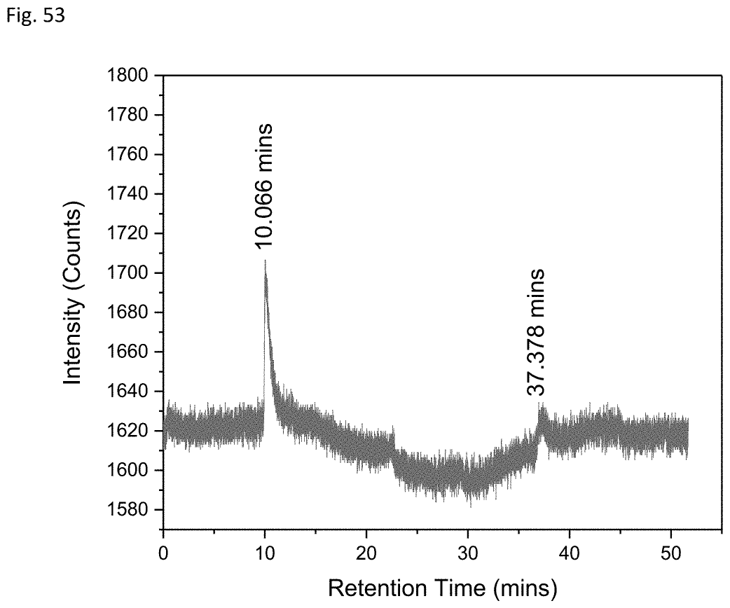

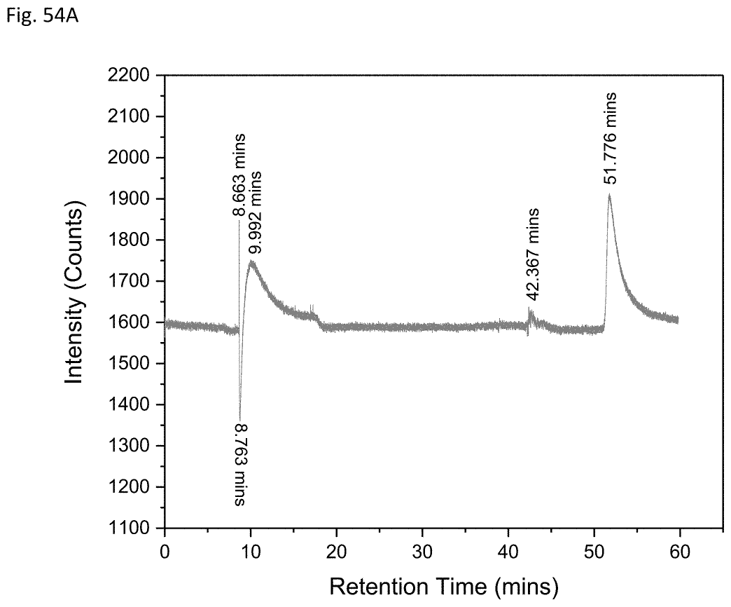

The control gas chromatographs recorded with the HP 5890 Series II gas chromatograph using an Agilent molecular sieve column with helium carrier gas and a thermal conductivity detector (TCD) set at 60° C. so that any H₂ peak was positive are shown in FIGS. 51A-E wherein 1000 Torr hydrogen showed a positive peak at 10 minutes, 1000 Torr methane showed a small positive H₂O contamination peak at 17 minutes and a positive methane peak at 50.5 minutes, 1000 Torr hydrogen (90%) and methane (10%) mixture showed a positive hydrogen peak at 10 minutes and a positive methane peak at 50.2 minutes, 760 Torr air showed a very small positive H₂O peak at 17.1 minutes, a positive oxygen peak at 17.6 minutes, and a positive nitrogen peak at 35.7 minutes, and gas from heating gallium metal to 950° C. showed no peaks. The gas chromatographs of hydrino gas evolved from the NaOH-treated Ga₂O₃ collected from a hydrino reaction run in the SunCell® and heated to 950° C. are shown in FIGS. 52A-B. The known positive hydrogen peak was observed at 10 minutes, and a novel negative peak observed at 9 minutes having positive leading and trailing edges at 8.9 minutes and 9.3 minutes, respectively, was assigned to H₂(¼). No known gas has a faster migration time and higher thermal conductivity than H₂ or He which is characteristic of and identifies hydrino since it has a much greater mean free path due to exemplary H₂(¼) having 64 times smaller volume and 16 times smaller ballistic cross section. The gas comprising hydrogen and H₂(¼) was allowed to stand in the vessel for over 24 hours following the time of the recording of the gas chromatograph shown in FIGS. 52A-B. The hydrogen peak was observed again at 10 minutes with a small N₂ contamination peak at 37.4 minutes, but the novel negative peak with shorter retention time than hydrogen was absent as shown in FIG. 53, consistent with the smaller size and corresponding high diffusivity of H₂(¼) even compared to H₂.

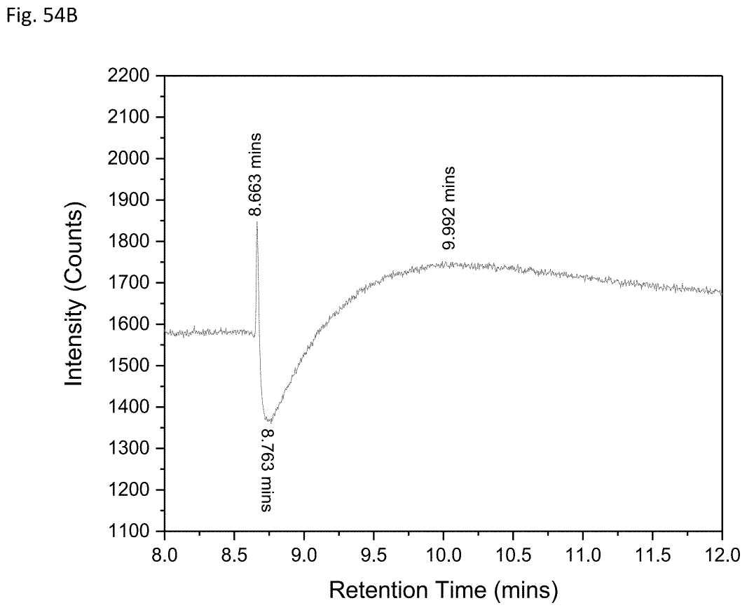

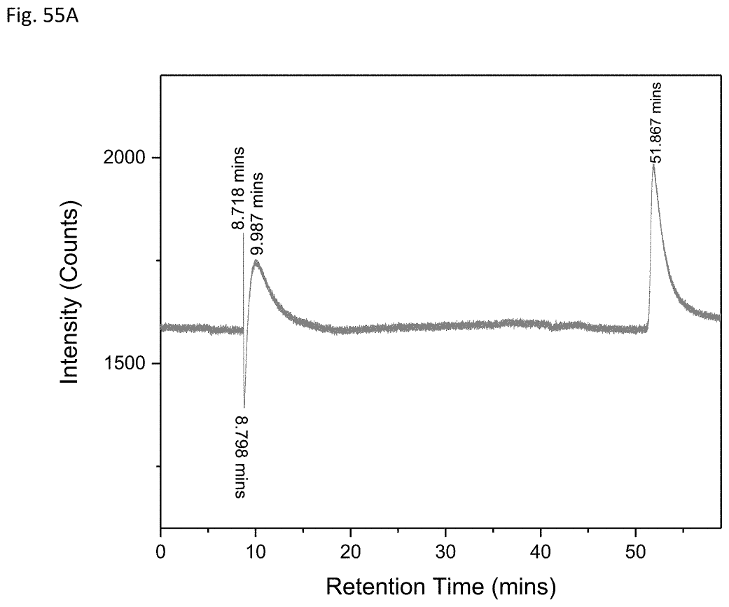

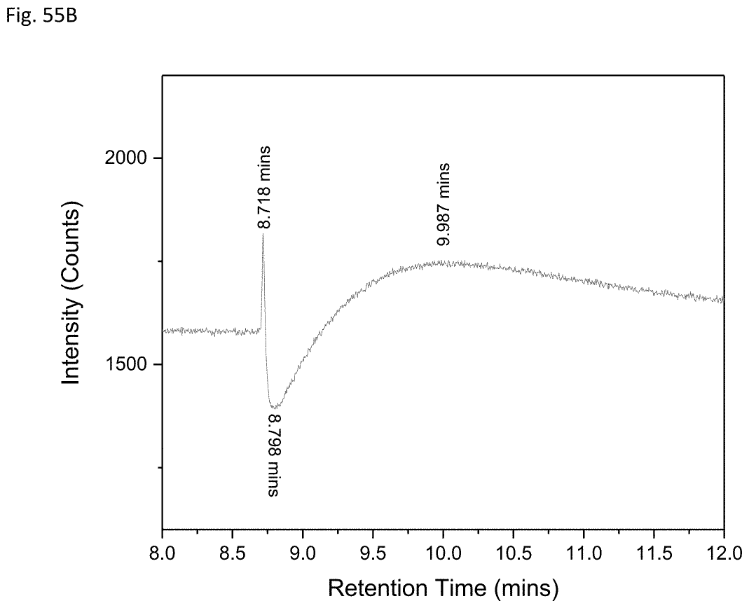

The gas chromatographic results of an early negative peak corresponding to a faster migration time and high thermal conductivity that H₂ or helium and assigned to H₂(¼) was repeated for a second and third hydrino reaction run in the SunCell®. The results of the gas chromatographs of hydrino gas evolved from NaOH-treated Ga₂O₃ collected from a second hydrino reaction run in the SunCell® are shown in FIGS. 54A-B. The known positive hydrogen peak was observed at 10 minutes, a positive unknown peak was observed at 42.4 minutes, the positive methane peak was observed at 51.8 minutes, and the novel negative peak assigned to H₂(¼) was observed at 8.76 minutes having positive leading and trailing edges at 8.66 minutes and 9.3 minutes, respectively. The results of the gas chromatographs of hydrino gas evolved from NaOH-treated Ga₂O₃ collected from a third hydrino reaction run in the SunCell® are shown in FIGS. 55A-B. The known positive hydrogen peak was observed at 10 minutes, the positive methane peak was observed at 51.9 minutes, and the novel negative peak assigned to H₂(¼) was observed at 8.8 minutes having positive leading and trailing edges at 8.7 minutes and 9.3 minutes, respectively.

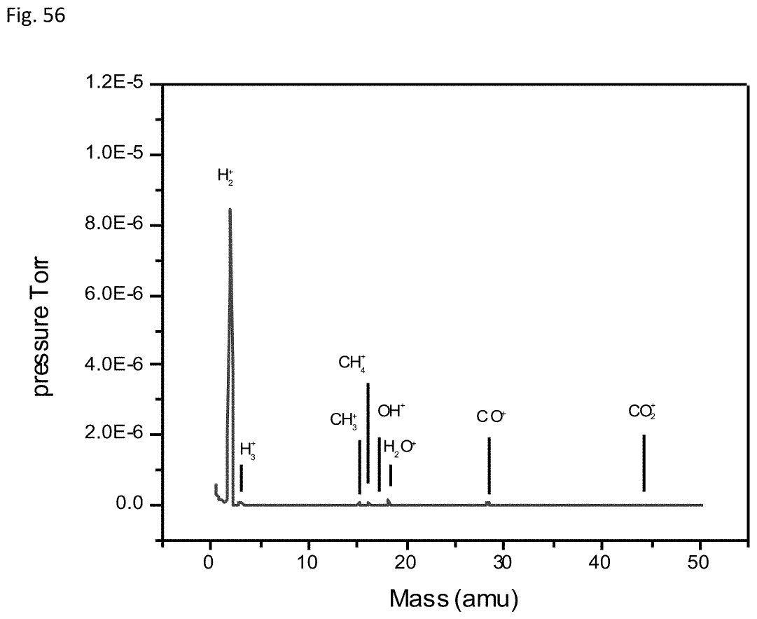

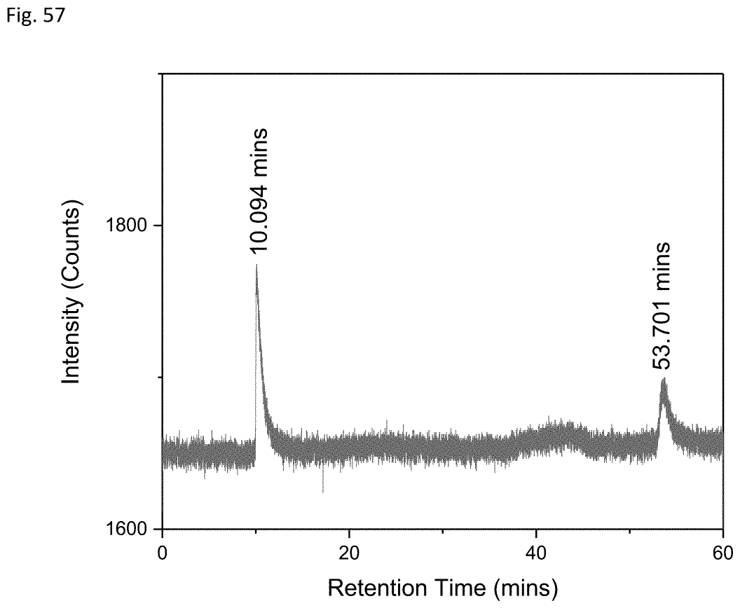

The mass spectrum (FIG. 56) of gas evolved from NaOH-treated Ga₂O₃ collected from a hydrino reaction run in the SunCell® and heated to 950° C. that was recorded after the recording of the gas chromatograph shown in FIGS. 55A-B confirmed the presence of hydrogen and methane. The formation of methane is extraordinary and attributed to the energetic hydrino plasma causing reaction of hydrogen with trace CO₂ or carbon from the stainless steel reactor. The gas comprising hydrogen and H₂(¼) was allowed to stand in the vessel for over 24 hours following the time of the recording of the gas chromatograph shown in FIGS. 55A-B. The hydrogen peak at 10 minutes and the methane peak at 53.7 minutes were observed again, but the novel negative peak with shorter retention time than hydrogen was absent as shown in FIG. 57, consistent with the smaller size and corresponding high diffusivity of H₂(¼) even compared to H₂.

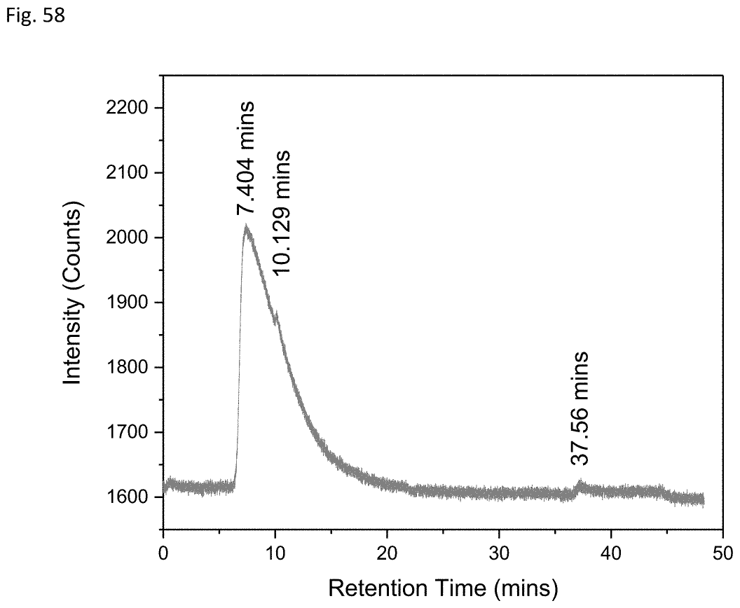

The results of the gas chromatograph of hydrino gas evolved from NaOH-treated Ga₂O₃ collected from a fourth hydrino reaction run in the SunCell® are shown in FIG. 58. The known positive hydrogen peak observed at 10 minutes was preceded by a novel positive peak at 7.4 minutes. The fast peak was assigned to H₂(¼) since no known gas has a faster migration time than H₂ or He. The positive nature of the H₂(¼) peak was indicative of a lower concentration of hydrino gas in the helium carrier gas for that sample. The fast peak as well as that fast peak being negative peak at high concentration eliminates any other gas assignment other than hydrino.

In an embodiment, water may be injected into the reaction cell chamber at low pressure such as under 10 Torr maintained by a dynamic vacuum to generate power and form gallium oxide on the surface that may be collected to serve as a source of hydrino gas. In an exemplary embodiment, gallium oxide was skimmed from the molten gallium surface following operation of a SunCell® comprising (i) a 15.24 cm diameter 304 stainless steel reaction cell chamber and a reservoir on the bottom having a 6 cm inner diameter and 6.35 cm height that contained about 3.5 kg of molten gallium, (ii) a molten gallium injector comprising an DC EM pump on the bottom with a W nozzle and (iii) a BN insulated pedestal counter electrode on top comprising a 1.27 cm diameter W bus bar connected to a vacuum-capable feed-through mounted on a flange at the top end and a concave parabolic cavity of about 2.54 cm deep at the center and 3.8 cm in diameter at the bottom end. To prevent melting of the reaction chamber, the SunCell was run three times for intervals of 30 s at 1000 A and 25-30 V DC with a 200 g/s EM pumping rate allowing for cooling in between runs. Using a needle valve to a water reservoir and a solenoid with a controller to control flow, water was injected into the reaction cell chamber at about 4 ml/min under dynamic vacuum that maintained a pressure of under 10 Torr. The cell output about 120 kW with an input of about 28 kW. About 15 g of gallium oxide was dissolved in about 500 ml of aqueous 1 M NaOH and allowed to stand for 72 hours at room temperature. Insoluble material that was suspended in the solution was removed by skimming. The solid was place in a sealed 65 cm³ SS vessel and heated to 600° C. to release 6.8 atm of gas. 2 atm of the gas was injected onto the gas chromatograph using the six-way valve. The spectrum was equivalent to that shown in FIG. 52A wherein the early negative peak assigned to H₂(¼) was observed at a 9-minute retention time. The early peak was also observed before the hydrogen peak as a positive peak wherein the carrier gas was argon and the TCD was at 85° C.

In another experimental embodiment, the HOH catalyst and a source of H atomic were provided by flowing 3000 sccm of H₂ and 30 sccm O₂ through 1 g of Pt/Al₂O₃ recombiner catalyst maintained at over 90° C. and into the reaction cell chamber. The input power was about 25 kW and the output power was about 100 kW. Ga₂O₃ skimmed from the molten gallium surface following operating the SunCell® was dissolved in 1 M NaOH, the insoluble solid was collected by decanting the liquid, and the resulting sample was heated in the evacuated 65 cm³ SS vessel to release hydrino gas onto the gas chromatographic column wherein the early negative peak assigned to H₂(¼) was observed at about a 9-minute retention time. In an embodiment, the Hayesep column at cryogenic temperature to may be used separate H₂(¼) gas from H₂ gas. The ro-vibration spectrum of hydrino may be observed by e-beam excitation emission in a chamber comprising argon at about 1 atm to form argon excimers to excite the ro-vibrational band such as shown in FIG. 41.

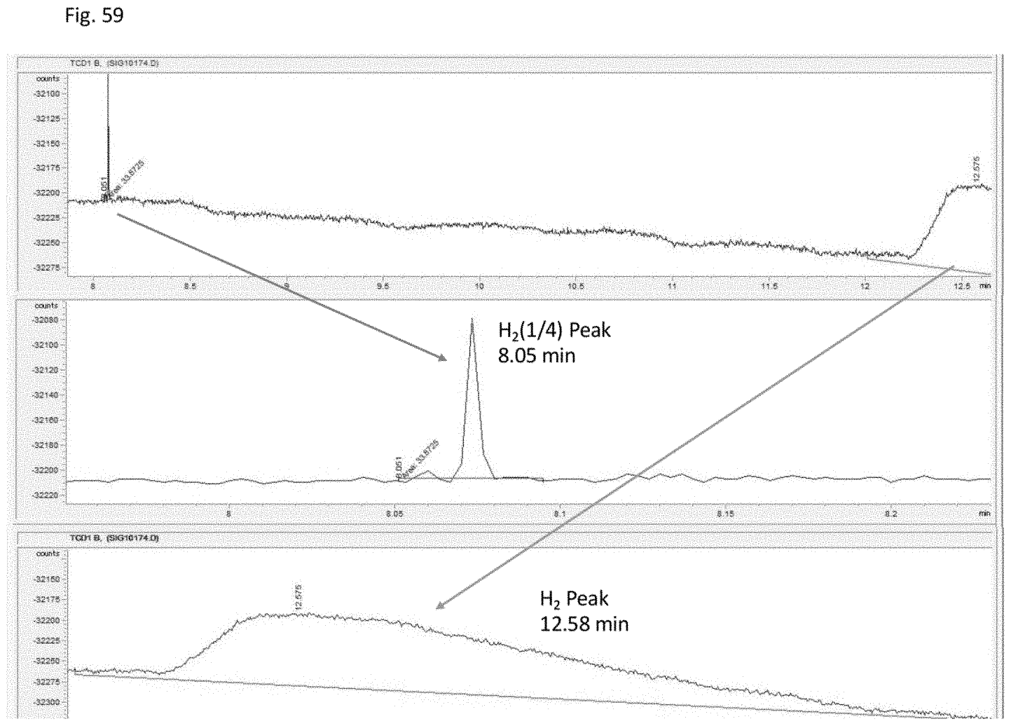

A SunCell® (FIG. 25) was operated by flowing 1200 sccm of H₂ and 20 sccm O₂ through 1 g of Pt/Al₂O₃ recombiner catalyst maintained at over 90° C. and into the reaction cell chamber. The cell was operated at a pressure of 1-5 Torr while flowing the gases out an exhaust port, bubbling them through a thin layer of liquid argon in vessel in series with a vacuum line cooled by an external liquid nitrogen dewar, and evacuating them using a vacuum pump. Molecular hydrino has a higher solubility in liquid argon than H₂ which provides a means of H₂(¼) gas enrichment. FIG. 59 shows the gas chromatograph of molecular hydrino gas flowed from the SunCell®, absorbed into the liquid argon as a solvent, and then released by allowing liquid argon to vaporize upon warming to 27° C. The hydrino peak was observed at 8.05 minutes compared to hydrogen that was observed later at 12.58 minutes on the Agilent column (Agilent molecular sieve 5 Å, (50 m×0.32, df=30 μm) at 303 K (30° C.) using a second HP 5890 Series II gas chromatograph with a thermal conductivity detector at 85° C. and argon carrier gas at 19 PSI.

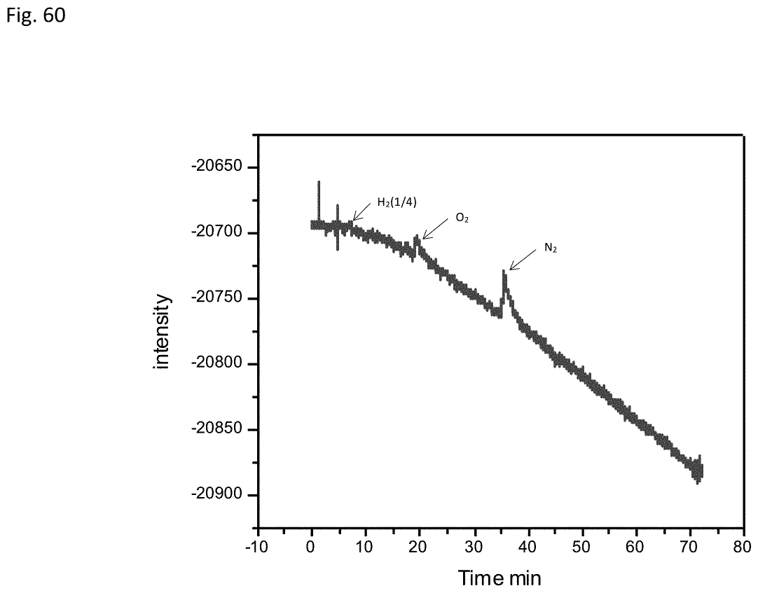

H₂(¼) gas of an argon/H₂(¼) mixture formed by recombination of hydrogen and oxygen on a supported noble metal catalyst in an argon atmosphere was enriched by flowing the mixture through a 35 m long, 2.5 mm ID HayeSep® D chromatographic column cooled to a cryogenic temperature in a liquid argon. The argon was partially liquefied to permit the flowing molecular hydrino gas to be enriched as indicated by the dramatic increase in the ro-vibrational P branch of H₂(¼) observed by e-beam excitation emission spectroscopy as shown in FIG. 42. The molecular hydrino gas from the chromatographic column was also liquified with trace air as it was flowed into a valved microchamber cooled to 55 K by a cryopump system (Helix Corp., CTI-Cryogenics Model SC compressor; TRI-Research Model T-2000D-IEEE controller; Helix Corp., CTI-Cryogenics model 22 cryodyne). The liquefied gas was warmed to room temperature to achieve 1000 Torr chamber pressure and was injected on to the Agilent column with argon carrier gas. Oxygen and nitrogen were observed at 19 and 35 minutes, respectively. H₂(¼) was observed at 6.9 minutes (FIG. 60).

The equations of the hydrino hydride ion calculations herein of the form (#.#) and the referenced sections correspond to those of MILLS GUT. For the ordinary hydride ion H⁻, a continuum is observed at shorter wavelengths of the ionization or binding energy referred to as the bound-free continuum. For typical conditions in the photosphere, FIG. 4.5 of Stix [M. Stix, The Sun, Springer-Verlag, Berlin, (1991), p. 136] shows the continuous absorption coefficient κ_{C} (λ) of the Sun. In the visible and infrared spectrum, the hydride ion H⁻ is the dominant absorber. Its free-free continuum starts at λ=1.645 μm, corresponding to the ionization energy of 0.745 eV for H⁻ with strongly increasing absorption towards the far infrared. The ordinary hydride spectrum recorded on the Sun is representative of the hydride spectrum in a very hot plasma.

The reaction of a hydrogen atom with a second electron to form ordinary hydride ion comprising two paired electrons in a single shell releases continuum radiation to longer wavelengths with a cutoff of the binding energy of the second electron of the hydride ion as shown by Stix [M. Stix, The Sun, Springer-Verlag, Berlin, (1991), p. 136]. However, hydrino hydride ion and the corresponding emission of a hydrino atom binding a second electron are unique. Hydrino hydride ion comprises an unpaired electron which results the emission of the binding energy of the second electron being released with additional quantized units of energy based on linkage of flux increments of the fluxon or magnet flux quantum

$$\frac{h}{2 e} .$$

Specifically, hydrino H⁻ (1/p) comprises (i) two electrons bound in a minimum energy, equipotential, spherical, two-dimensional current membrane wherein the electrons of H⁻ (1/p) are unpaired in the same shell at the same position r and (ii) a photon that increases the central field by an integer of the fundamental charge at the nucleus centered on the origin of the sphere. The interaction of the hydrino state photon electric field with each electron gives rise to a nonradiative radial monopole such that the state is stable. The combination of two electrons into a single atomic orbital (AO) while maintaining the radiationless integer photonic central field gives rise to the special case of a doublet AO state in hydrino hydride ion rather than a singlet state as in the case of ordinary hydride ion. The singlet state is nonmagnetic; whereas, the doublet state has a net magnetic moment of a Bohr magneton μ_{B}.

Specifically, the basis element of the current of the atomic orbital is a great circle as shown in the Generation of the Atomic Orbital-CVFS section. As shown in the Equation of the Electric Field inside the Atomic Orbital section, (i) photons carry electric field and comprise closed field line loops, (ii) a hydrino atom comprises a trapped photon wherein the photon field-line loops each travel along a mated great circle current loop basis element in the same vector direction, (iii) the direction of each field line increases in the direction perpendicular to the propagation direction with relative motion as required by special relativity, and (iv) since the linear velocity of each point along a field line loop of a trapped photon is light speed c, the electric field direction relative to the laboratory frame is purely perpendicular to its mated current loop and it exists only at δ(r-rₙ). The paired electrons of the H⁻ atomic orbital comprise a singlet state having no net magnetic moment. However, the photon field lines of a hydrino hydride ion can only propagate in one direction to avoid cancellation and give rise to a central field to provide force balance between the centrifugal and central forces (Eq. (7.72)). This special case gives rise to a doublet state in hydrino hydride ion.

The hydrino hydride AO may be treated as a linear combination of the great circles that comprise the current density function of each electron as given in the Generation of the Orbitsphere-CVFS section. To meet the boundary conditions that the photon is matched in direction with the electron current and that the electron angular momentum is ℏ are satisfied, one half of electron 1 and one half of electron 2 may be spin up and matched with the photon, and the other half of electron 1 may be spin up and the other half of electron 2 may be spin down such that one half of the currents are paired and one half of the currents are unpaired. Given the indivisibility of each electron and the condition that the AO comprises two identical electrons, the force of the photon is transferred to the totality of the electron AO comprising the two identical electrons to satisfy Eq. (7.72). The resulting angular momentum and magnetic moment of the unpaired current density are ℏ and a Bohr magneton μ_{B}, respectively. As given in the Electron g Factor section, flux is linked by an unpaired electron in quantized units of the fluxon or magnetic flux quantum

$$\frac{h}{2 e} .$$

Hydride ions formed by the reaction of hydrogen or hydrino atoms with free electrons with a kinetic energy distribution give rise to the bound-free emission band to shorter wavelengths than the ionization or binding energy due to the release of the electron kinetic energy and the hydride ion binding energy. As shown by Eq. (7.74) compared to Eq. (7.71), the energies for the formation of hydrino hydride ions are much greater, and with sufficient spectroscopic resolution, it may be possible to resolve the unique hyperfine structure in the corresponding bound-free band due to interactions of the free and bound electrons during the formation of hydrino hydride ion. The derivation of the hyperfine lines of the unique doublet state is given in the Hydrino Hydride Ion Hyperfine Lines section.

Ionization of two O, ionization of two H, ionization of Rb⁺, and an electron transfer between two K⁺ ions (Eqs. (5.6-5.9)) provide a reaction with a net enthalpy of an integer multiple of the potential energy of atomic hydrogen, 27.2 eV. The corresponding Group I nitrates provide these reactants as volatilized ions directly or as atoms by undergoing decomposition or reduction to the corresponding metals that are ionized in a plasma. The presence of each of the reactants identified as providing an enthalpy of 27.2 eV formed a low-applied temperature, extremely-low-voltage plasma in atomic hydrogen called a resonant transfer or rt-plasma having strong vacuum ultraviolet (VUV) emission. The catalyst product of Rb⁺ and two K⁺, H(½), was predicted to be a highly reactive intermediate which further reacts to form a hydrino hydride ion H⁻ (½).

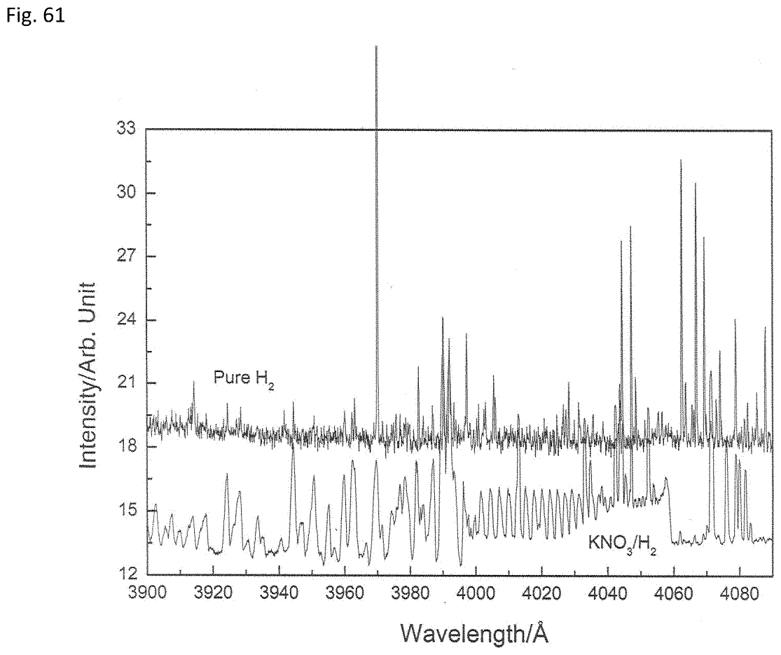

H⁻(½) ions form by the reaction of H(½) atoms with free electrons that have a kinetic energy distribution. The release of the electron kinetic energies and the hydrino hydride ion binding energy gives rise to the bound-free emission band to shorter wavelengths than the ionization or binding energy of the corresponding hydride ion. Due to the requirement that flux is linked by H(½) in integer units of the magnetic flux quantum, the energy is quantized, and the emission due to H⁻(½) formation comprises a series of hyperfine lines in the corresponding bound-free band. From the electron g factor and using the observed binding energy peak E_{B}*, the bound-free hyperfine structure lines due to interactions of the free and bound electrons have predicted energies E_{HF} given by the sum of the fluxon energy E_{Φ}, the spin-spin energy Eₛₛ, and the observed binding energy peak E_{B}*.

$$\begin{matrix}{E}_{H F} = {E}_{Φ} + {E}_{s s} + {E}_{B}^{*} \\ = {j}^{2} 2 ( g - 2 ) \frac{{μ}_{B}}{\sqrt{s ( s + 1 )}} \frac{{μ}_{0}}{{r}^{3}} ( \frac{e ℏ}{2 {m}_{e}} ) + g \frac{{μ}_{0}}{{r}^{3}} {( \frac{e ℏ}{2 {m}_{e}} )}^{2} + {E}_{B}^{*} \\ = ( {j}^{2} 3 .00213 \times {10}^{- 5} + 0.011223 + 3.0451 ) eV \\ = ( {j}^{2} 3 .00213 \times {10}^{- 5} + 3.0563 ) eV\end{matrix} \qquad ( 7.97 )$$

where j=integer. This is compared to E_{HF}=(j²3.00213×10⁻⁵+3.0583 eV with the unperturbed E_{B} given by Eqs. (7.73) and (7.74). The predicted spectrum is an inverse Rydberg-type series that converges at increasing wavelengths and terminates at 3.0563 eV, the hydride binding energy with the fine structure plus the spin-pairing energies. The high-resolution visible plasma emission spectra in the region of 4000 Å to 4060 Å shown in FIG. 61 matched the predicted emission lines to 1 part in 10⁵.

Specifically, the predicted 3.0471 eV binding energy of H⁻(½) was observed as a continuum threshold at 3.047 eV (λₐᵢᵣ=4068 Å). The experimental H⁻(½) peak E_{B}* at 4070.6 Å (air wavelength) was used to calculate the peak positions of the bound-free hyperfine lines by substitution of the corresponding energy of 3.0451 eV into Eq. (7.97) for E_{B} to give the bound-free hyperfine structure lines of H⁻ (½). The high resolution visible plasma emission lines in the region of 3995 Å to 4060 Å, comprising an inverse Rydberg-type series from 3.0563 eV to 3.1012 eV matched the predicted hyperfine splitting emission energies E_{HF} given by Eq. (7.97) for j=1 to j=39 with the series edge at 3996.3 Å up to 1 part in 10⁵ [R. L. Mills, P. Ray, “A Comprehensive Study of Spectra of the Bound-Free Hyperfine Levels of Novel Hydride Ion H⁻ (½), Hydrogen, Nitrogen, and Air”, Int. J. Hydrogen Energy, Vol. 28, No. 8, (2003), pp. 825-871; R. Mills, W. Good, P. Jansson, J. He, “Stationary Inverted Lyman Populations and Free-Free and Bound-Free Emission of Lower-Energy State Hydride Ion formed by and Exothermic Catalytic Reaction of Atomic Hydrogen and Certain Group I Catalysts,” Cent. Eur. J. Phys., Vol. 8, (2010), 7-16, doi: 10.2478/s11534-009-0052-6; R. L. Mills, P. Ray, “Stationary Inverted Lyman Population and a Very Stable Novel Hydride Formed by a Catalytic Reaction of Atomic Hydrogen and Certain Catalysts,” J. Opt. Mat., 27, (2004), 181-186, and R. L. Mills, P. C. Ray, R. M. Mayo, M. Nansteel, W. Good, P. Jansson, B. Dhandapani, J. He, “Hydrogen Plasmas Generated Using Certain Group I Catalysts Show Stationary Inverted Lyman Populations and Free-Free and Bound-Free Emission of Lower-Energy State Hydride,” Res. J. Chem Env., Vol. 12(2), (2008), 42-72 which are herein incorporated by reference in their entirety]. The flat intensity profile matches that of Josephson junctions such as ones of superconducting quantum interference devices (SQUIDs) that also link magnetic flux in quantized units of the magnetic flux quantum

$$\frac{h}{2 e} .$$

What is claimed is:

1. A power system that generates at least one of electrical energy and thermal energy comprising:
at least one vessel capable of maintaining a pressure below atmospheric;
reactants capable of undergoing a reaction that produces enough energy to form a plasma in the vessel comprising:
a) a mixture of hydrogen gas and oxygen gas, and/or
water vapor, and/or
a mixture of hydrogen gas and water vapor;
b) a molten metal;
a mass flow controller to control the flow rate of at least one reactant into the vessel;
a vacuum pump to maintain the pressure in the vessel below atmospheric pressure when one or more reactants are flowing into the vessel;
a molten metal injector system comprising at least one reservoir that contains some of the molten metal, a molten metal pump system (e.g., one or more electromagnetic pumps) configured to deliver the molten metal in the reservoir and through an injector tube to provide a molten metal stream, and at least one non-injector molten metal reservoir for receiving the molten metal stream;
at least one ignition system comprising a source of electrical power or ignition current to supply electrical power to the at least one stream of molten metal to ignite the reaction when the hydrogen gas and/or oxygen gas and/or water vapor are flowing into the vessel;
a reactant supply system to replenish reactants that are consumed in the reaction;
a power converter or output system to convert a portion of the energy produced from the reaction (e.g., light and/or thermal output from the plasma) to electrical power and/or thermal power.

2. The power system of claim 1 further comprising a gas mixer for mixing the hydrogen and oxygen gases and a hydrogen and oxygen recombiner and/or a hydrogen dissociator.

3. The power system of claim 1 wherein the hydrogen and oxygen recombiner comprises a recombiner catalytic metal supported by an inert support material.

4. The power system of claim 1 wherein an inert gas (e.g., argon) is injected into the vessel.

5. The power system of claim 1 further comprising a water micro-injector configured to inject water into the vessel (e.g., resulting in a plasma comprising water vapor).

6. The power system of claim 1 wherein molten metal injection system further comprises electrodes in the molten metal reservoir and the non-injection molten metal reservoir; and the ignition system comprises a source of electrical power or ignition current to supply opposite voltages to the injector and non-injector reservoir electrodes; wherein the source of electrical power supplies current and power flow through the stream of molten metal to cause the reaction of the reactants to form a plasma inside of the vessel.

7. The power system of claim 1 wherein the molten metal pump system is one or more electromagnetic pumps and each electromagnetic pump comprises one of a
a) DC or AC conduction type comprising a DC or AC current source supplied to the molten metal through electrodes and a source of constant or in-phase alternating vector-crossed magnetic field, or
b) induction type comprising a source of alternating magnetic field through a shorted loop of molten metal that induces an alternating current in the metal and a source of in-phase alternating vector-crossed magnetic field.

8. The power system of claim 1 wherein the injector reservoir comprises an electrode in contact with the molten metal therein, and the non-injector reservoir comprises an electrode that makes contact with the molten metal provided by the injector system.

9. The power system of claim 1 wherein the non-injector reservoir is aligned above (e.g., vertically with) the injector and the injector is configured to produce the molten stream orientated towards the non-injector reservoir such that molten metal from the molten metal stream may collect in the reservoir and the molten metal stream makes electrical contact with the non-injector reservoir electrode; and wherein the molten metal pools on the non-injector reservoir electrode.

10. The power system of claim 1 wherein the vessel comprises an hourglass geometry (e.g., a geometry wherein a middle portion of the internal surface area of the vessel has a smaller cross section than the cross section within 20% or 10% or 5% of each distal end along the major axis) and oriented in a vertical orientation (e.g., the major axis of the vessel is approximately parallel with the force of gravity) in cross section wherein the injector reservoir is below the waist and configured such that the level of molten metal in the reservoir is about proximal to the waist of the hourglass to increase the ignition current density.

11. The power system of claim 1 wherein the molten metal reacts with water to form atomic hydrogen.

12. The power system of claim 1 wherein the molten metal is gallium and the power system further comprises a gallium regeneration system to regenerate gallium from gallium oxide (e.g., gallium oxide produced in the reaction).

13. The power system of claim 1 wherein the vessel comprises a light transparent photovoltaic (PV) window to transmit light from the inside of the vessel to a photovoltaic converter and at least one of a vessel geometry and at least one baffle comprising a spinning window.

14. The power system of claim 1 wherein the power converter or output system is a magnetohydrodynamic converter comprising a nozzle connected to the vessel, a magnetohydrodynamic channel, electrodes, magnets, a metal collection system, a metal recirculation system, a heat exchanger, and optionally a gas recirculation system.

15. The power system of claim 1, wherein the molten metal pump system comprises a first stage electromagnetic pump and a second stage electromagnetic pump, wherein the first stage comprises a pump for a metal recirculation system, and the second stage that comprises the pump of the metal injector system.

16. The power system of claim 1 wherein the reaction produces a hydrogen product characterized as one or more of:
a) a hydrogen product with a Raman peak at one or more range of 1900 to 2000 cm⁻¹ and 5500 to 6200 cm⁻¹;
b) a hydrogen product with a plurality of Raman peaks spaced at an integer multiple of 0.23 to 0.25 eV;
c) a hydrogen product with an infrared peak at 1900 to 2000 cm⁻¹;
d) a hydrogen product with a plurality of infrared peaks spaced at an integer multiple of 0.23 to 0.25 eV;
e) a hydrogen product with at a plurality of UV fluorescence emission spectral peaks in the range of 200 to 300 nm having a spacing at an integer multiple of 0.23 to 0.3 eV;
f) a hydrogen product with a plurality of electron-beam emission spectral peaks in the range of 200 to 300 nm having a spacing at an integer multiple of 0.2 to 0.3 eV;
g) a hydrogen product with a plurality of Raman spectral peaks in the range of 5000 to 20,000 cm⁻¹ having a spacing at an integer multiple of 1000±200 cm 1;
h) a hydrogen product with a continuum Raman spectrum in the range of 40 to 8000 cm⁻¹;
i) a hydrogen product with a Raman peak in the range of 1500 to 2000 cm⁻¹ due to at least one of paramagnetic and nanoparticle shifts;
j) a hydrogen product with a X-ray photoelectron spectroscopy peak at an energy in the range of 490 to 525 eV;
k) a hydrogen product that causes an upfield MAS NMR matrix shift;
l) a hydrogen product that has an upfield MAS NMR or liquid NMR shift of greater than −5 ppm relative to TMS;
m) a hydrogen product comprising macro-aggregates or polymers Hₙ(n is an integer greater than 3);
n) a hydrogen product comprising macro-aggregates or polymers Hₙ(n is an integer greater than 3) having a time of flight secondary ion mass spectroscopy (ToF-SIMS) peak of 16.12 to 16.13;
o) a hydrogen product comprising a metal hydride wherein the metal comprises at least one of Zn, Fe, Mo, Cr, Cu, and W;
p) a hydrogen product comprising at least one of H₁₆ and H₂₄;
q) a hydrogen product comprising an inorganic compound MₓX_{y} and H₂ wherein M is a cation and X is an anion having at least one of electrospray ionization time of flight secondary ion mass spectroscopy (ESI-ToF) and time of flight secondary ion mass spectroscopy (ToF-SIMS) peaks of M(MₓX_{y}H₂)n wherein n is an integer;
r) a hydrogen product comprising at least one of K₂CO₃H₂ and KOHH₂ having at least one of electrospray ionization time of flight secondary ion mass spectroscopy (ESI-ToF) and time of flight secondary ion mass spectroscopy (ToF-SIMS) peaks of K(K₂H₂CO₃)ₙ⁺ and K(KOHH₂)ₙ⁺, respectively;
s) a magnetic hydrogen product comprising at least one of a metal hydride and a metal oxide further comprising hydrogen wherein the metal comprises at least one of Zn, Fe, Mo, Cr, Cu, W, and a diamagnetic metal;
t) a hydrogen product comprising at least one of a metal hydride and a metal oxide further comprising hydrogen wherein the metal comprises at least one of Zn, Fe, Mo, Cr, Cu, W, and a diamagnetic metal that demonstrates magnetism by magnetic susceptometry;
u) a hydrogen product comprising a metal that is not active in electron paramagnetic resonance (EPR) spectroscopy wherein the EPR spectrum comprises at least one of a g factor of about 2.0046±20% and proton splitting such as a proton-electron dipole splitting energy of about 1.6×10⁻² eV±20%;
v) a hydrogen product comprising a hydrogen molecular dimer [H₂]₂ wherein the EPR spectrum shows at least an electron-electron dipole splitting energy of about 9.9×10⁻⁵ eV±20% and a proton-electron dipole splitting energy of about 1.6×10⁻² eV±20%;
w) a hydrogen product comprising a gas having a negative gas chromatography peak with hydrogen or helium carrier;
x) a hydrogen product having a quadrupole moment/e of
$$\frac{1.701 \; 27 {a}_{0}^{2}}{{p}^{2}} \pm 10 \%$$
wherein p is an integer;
y) a protonic hydrogen product comprising a molecular dimer having an end over end rotational energy for the integer J to J+1 transition in the range of (J+1)44.30 cm⁻¹±20 cm⁻¹ wherein the corresponding rotational energy of the molecular dimer comprising deuterium is ½ that of the dimer comprising protons;
z) a hydrogen product comprising molecular dimers having at least one parameter from the group of (i) a separation distance of hydrogen molecules of 1.028 Å±10%, (ii) a vibrational energy between hydrogen molecules of 23 cm⁻¹±10%, and (iii) a van der Waals energy between hydrogen molecules of 0.0011 eV±10%;
aa) a hydrogen product comprising a solid having at least one parameter from the group of (i) a separation distance of hydrogen molecules of 1.028 Å±10%, (ii) a vibrational energy between hydrogen molecules of 23 cm⁻¹±10%, and (iii) a van der Waals energy between hydrogen molecules of 0.019 eV±10%;
bb) a hydrogen product having FTIR and Raman spectral signatures of (i) (J+1)44.30 cm⁻¹±20 cm⁻¹, (ii) (J+1)22.15 cm⁻¹±10 cm⁻¹ and (iii) 23 cm⁻¹±10% and/or an X-ray or neutron diffraction pattern showing a hydrogen molecule separation of 1.028 Å±10% and/or a calorimetric determination of the energy of vaporization of 0.0011 eV±10% per molecular hydrogen;
cc) a solid hydrogen product having FTIR and Raman spectral signatures of (i) (J+1)44.30 cm⁻¹±10% cm⁻¹, (ii) (J+1)22.15 cm⁻¹±10% cm⁻¹ and (iii) 23 cm⁻¹+10% and/or an X-ray or neutron diffraction pattern showing a hydrogen molecule separation of 1.028 Å±10% and/or a calorimetric determination of the energy of vaporization of 0.019 eV±10% per molecular hydrogen;
dd) a hydrogen product comprising a hydrogen hydride ion that is magnetic and links flux in units of the magnetic flux quantum in its bound-free binding energy region;
ee) a hydrogen product wherein the high pressure liquid chromatography (HPLC) that shows chromatographic peaks having retention times longer than that of the carrier void volume time using an organic column with a solvent comprising water wherein the detection of the peaks by mass spectroscopy such as ESI-ToF shows fragments of at least one inorganic compound.

17. An electrode system comprising:
a) a first electrode and a second electrode;
b) a stream of molten metal (e.g., molten silver, molten gallium) in electrical contact with said first and second electrodes;
c) a circulation system comprising a pump to draw said molten metal from a reservoir and convey it through a conduit (e.g., a tube) to produce said stream of molten metal exiting said conduit;
d) a source of electrical power configured to provide an electrical potential difference between said first and second electrodes;
wherein said stream of molten metal is in simultaneous contact with said first and second electrodes to create an electrical current between said electrodes.

18. An electrical circuit comprising:
a) a heating means for producing molten metal;
b) a pumping means for conveying said molten metal from a reservoir through a conduit to produce a stream of said molten metal exiting said conduit;
c) a first electrode and a second electrode in electrical communication with a power supply means for creating an electrical potential difference across said first and second electrode;
wherein said stream of molten metal is in simultaneous contact with said first and second electrodes to create an electrical circuit between said first and second electrodes.

19. In an electrical circuit comprising a first and second electrode, the improvement comprising passing a stream of molten metal across said electrodes to permit a current to flow there between.

20. A system for producing a plasma comprising:
a) a molten metal injector system configured to produce a stream of molten metal from a metal reservoir;
b) an electrode system for inducing a current to flow through said stream of molten metal;
c) at least one of a (i) water injection system configured to bring a metered volume of water in contact with molten metal, wherein a portion of said water and a portion of said molten metal react to form an oxide of said metal and hydrogen gas, (ii) a mixture of excess hydrogen gas an oxygen gas, and (iii) a mixture of excess hydrogen gas and water vapor, and
d) a power supply configured to supply said current;
wherein said plasma is produced when current is supplied through said metal stream.

21. The system according to claim 20, further comprising:
a) a pumping system configured to transfer metal collected after the production of said plasma to said metal reservoir; and
b) a metal regeneration system configured to collect said metal oxide and convert said metal oxide to said metal; wherein said metal regeneration system comprises an anode, a cathode, electrolyte; wherein an electrical bias is supplied between said anode and cathode to convert said metal oxide to said metal;
wherein metal regenerated in said metal regeneration system is transferred to said pumping system.
